(19) United States
(12) Patent Application Publication
(10) Pub. No.: US 2026/0157028 A1
(43) Pub. Date: Jun. 4, 2026

(54) LIGHT-EMITTING DEVICE INCLUDING HETEROCYCLIC COMPOUND, ELECTRONIC APPARATUS INCLUDING THE LIGHT-EMITTING DEVICE, AND THE HETEROCYCLIC COMPOUND

(71) Applicant: Samsung Display Co., Ltd., Yongin-si (KR)

(72) Inventors: Hankyu Pak, Yongin-si (KR); Dongjun Kim, Yongin-si (KR); Hyunbin Park, Yongin-si (KR); Jinyoung Yun, Yongin-si (KR); Sanghyun Han, Yongin-si (KR)

(21) Appl. No.: 19/177,398

(22) Filed: Apr. 11, 2025

(30) Foreign Application Priority Data
Apr. 12, 2024 (KR) 10-2024-0049403

(51) Int. Cl. H10K 50/16; H10K 85/30; H10K 85/40; H10K 85/60

(52) U.S. Cl. CPC H10K 50/16; H10K 85/324; H10K 85/342; H10K 85/346; H10K 85/348; H10K 85/40; H10K 85/622; H10K 85/623; H10K 85/626; H10K 85/633; H10K 85/636; H10K 85/654; H10K 85/6572; H10K 85/6574; H10K 85/6576; H10K 85/658

(57) ABSTRACT

A light-emitting device including a heterocyclic compound represented by Formula 1, an electronic apparatus including the light-emitting device, and the heterocyclic compound represented by Formula 1 are provided:

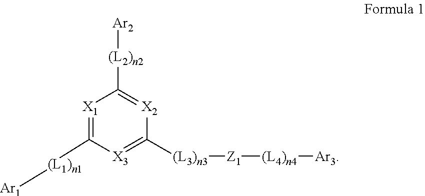

### CROSS-REFERENCE TO RELATED APPLICATION

The present application claims priority to and the benefit of Korean Patent Application No. 10-2024-0049403, filed on Apr. 12, 2024, in the Korean Intellectual Property Office, the entire disclosure of which is incorporated herein by reference.

### BACKGROUND

### 1. Field

One or more embodiments of the present disclosure relate to a light-emitting device including a heterocyclic compound, an electronic apparatus including the light-emitting device, and the heterocyclic compound.

### 2. Description of the Related Art

Among light-emitting devices, self-emissive devices (e.g., organic light-emitting devices) have relatively wide viewing angles, high contrast ratios, short response times, and excellent or suitable characteristics in terms of luminance, driving voltage, and response speed. That is, self-emissive devices, such as organic light-emitting devices, stand out among light-emitting devices due to their wide viewing angles, high contrast ratios, quick response times, and excellent characteristics in luminance, driving voltage, and response speed.

In a light-emitting device, a first electrode is arranged on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as the holes and the electrons, recombine in the emission layer to produce excitons. The excitons transition and decay from an excited state to a ground state, thereby generating light (e.g., to display an image).

### SUMMARY

One or more aspects of embodiments of the present disclosure are directed toward a light-emitting device including a heterocyclic compound, an electronic apparatus including the light-emitting device, and the heterocyclic compound.

Additional aspects will be set forth in part in the description which follows and, in part, will be apparent from the description, or may be learned by practice of the presented embodiments of the disclosure.

According to one or more embodiments of the present disclosure, a light-emitting device includes:
a first electrode;
a second electrode opposite to (e.g., facing) the first electrode;
an interlayer between the first electrode and the second electrode and including an emission layer, and
a heterocyclic compound represented by Formula 1:

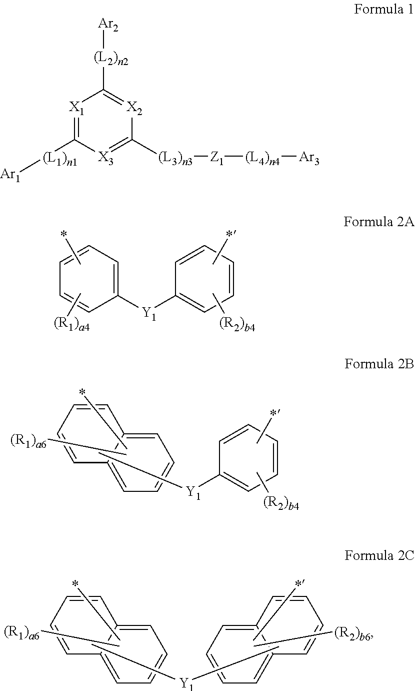

wherein, in Formulae 1, 2A, 2B, and 2C,
X₁ may be C(R₁₁) or N, X₂ may be C(R₁₂) or N, and X₃ may be C(R₁₃) or N,
Z₁ may be a group represented by any one (e.g., one) selected from among Formulae 2A, 2B, and 2C,
Y₁ may be a C₁-C₃₀ alkylene group unsubstituted or substituted with at least one R₁₀ₐ, a C₃-C₃₀ cycloalkylene group unsubstituted or substituted with at least one R₁₀ₐ, or a C₁-C₃₀ heterocycloalkylene group unsubstituted or substituted with at least one R₁₀ₐ, wherein Y₁ may not include an (e.g., may exclude any) unsubstituted or substituted adamantane group,
Ar₁ to Ar₃ may each independently be deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
L₁ to L₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
n1 to n4 may each independently be an integer from 0 to 4, wherein, if (e.g., when) n1 is 0, *-(L₁)ₙ₁-*′ may be a single bond, if (e.g., when) n2 is 0, *-(L₂)ₙ₂-*′ may be a single bond, if (e.g., when) n3 is 0, *-(L₃)ₙ₃-*′ may be a single bond, and if (e.g., when) n4 is 0, *-(L₄)ₙ₄-*′ may be a single bond,
R₁ and R₂ may each independently be deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a
C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a4 and b4 may each independently be an integer from 0 to 4, and a6 and b6 may each independently be an integer from 0 to 6,
if (e.g., when) Z₁ is a group represented by Formula 2A, the sum of a4 and b4 may be 1 or more,
if (e.g., when) a4 is 2 or more, or if (e.g., when) a6 is 2 or more, two or more of R₁(s) may optionally be bonded to each other to form a C₃-C₃₀ carbocyclic group unsubstituted or substituted with at least one R₁₀ₐ or a C₁-C₃₀ heterocyclic group unsubstituted or substituted with at least one R₁₀ₐ,
if (e.g., when) b4 is 2 or more, or if (e.g., when) b6 is 2 or more, two or more of R₂(s) may optionally be bonded to each other to form a C₃-C₃₀ carbocyclic group unsubstituted or substituted with at least one R₁₀ₐ or a C₁-C₃₀ heterocyclic group unsubstituted or substituted with at least one R₁₀ₐ,
R₁ and R₂ may each independently optionally be bonded to L₃ or L₄ or Ar₃ to form a C₃-C₃₀ carbocyclic group unsubstituted or substituted with at least one R₁₀ₐ or a C₁-C₃₀ heterocyclic group unsubstituted or substituted with at least one R₁₀ₐ,
R₁₁ to R₁₃ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a
C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ may be:
hydrogen, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
and *′ each indicate a binding site to a neighboring atom.

According to one or more embodiments of the present disclosure, an electronic apparatus includes the light-emitting device.

According to one or more embodiments of the present disclosure, electronic equipment includes the light-emitting device.

According to one or more embodiments of the present disclosure, provided is the heterocyclic compound represented by Formula 1.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIG. 1 is a schematic view of the structure of a light-emitting device according to one or more embodiments of the present disclosure;

FIG. 2 is a schematic view of the structure of a light-emitting apparatus according to one or more embodiments of the present disclosure;

FIG. 3 is a schematic view of the structure of a light-emitting apparatus according to one or more embodiments of the present disclosure;

FIG. 4 is a block diagram of electronic equipment according to one embodiment of the present disclosure;

FIG. 5 is a schematic diagram of electronic equipment according to one or more embodiments of the present disclosure;

FIG. 6 is a schematic perspective view of electronic equipment including an organic light-emitting device according to one or more embodiments of the present disclosure;

FIG. 7 is a schematic view of an exterior of a vehicle as electronic equipment including an organic light-emitting device according to one or more embodiments of the present disclosure; and

FIGS. 8A-8C are each a schematic view of an interior of a vehicle as electronic equipment including an organic light-emitting device according to one or more embodiments of the present disclosure.

### DETAILED DESCRIPTION

Reference will now be made in more detail to embodiments, examples of which are illustrated in the accompanying drawings, wherein like reference numerals refer to like elements throughout the present disclosure, and duplicative descriptions thereof may not be provided for conciseness. In this regard, the presented embodiments may have different forms and should not be construed as being limited to the descriptions set forth herein. Accordingly, the embodiments of the present disclosure are merely described, by referring to the drawings, to explain aspects of the present disclosure. As used herein, the term “and/or” or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

According to one or more embodiments of the present disclosure, a heterocyclic compound is represented by Formula 1:

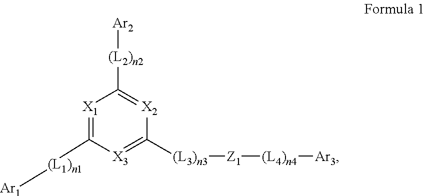

wherein, in Formula 1, X₁ may be C(R₁₁) or N, X₂ may be C(R₁₂) or N, and X₃ may be C(R₁₃) or N.

In one or more embodiments, at least one selected from among X₁ to X₃ may be N.

In one or more embodiments, at least two selected from among X₁ to X₃ may each be N.

In one or more embodiments, X₁ to X₃ may each be N.

In Formula 1, Z₁ may be a group represented by any one selected from among Formulae 2A, 2B, and 2C:

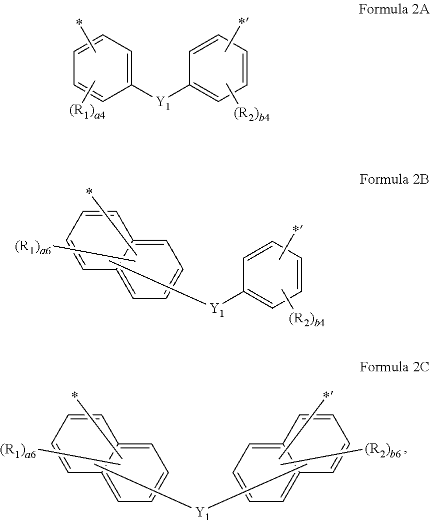

wherein, in Formulae 2A, 2B, and 2C, Y₁ may be a C₁-C₃₀ alkylene group unsubstituted or substituted with at least one R₁₀ₐ, a C₃-C₃₀ cycloalkylene group unsubstituted or substituted with at least one R₁₀ₐ, or a C₁-C₃₀ heterocycloalkylene group unsubstituted or substituted with at least one R₁₀ₐ, wherein Y₁ may not include an (e.g., may exclude any) unsubstituted or substituted adamantane group.

For example, Y₁ may not include a (e.g., may exclude any) group represented by unsubstituted or substituted

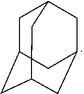

In one or more embodiments, Y₁ may be a C₁-C₁₀ alkylene group unsubstituted or substituted with at least one R₁₀ₐ, a C₃-C₉ cycloalkylene group unsubstituted or substituted with at least one R₁₀ₐ, or a C₁-C₉ heterocycloalkylene group unsubstituted or substituted with at least one R₁₀ₐ.

In one or more embodiments, Y₁ may be a C₁-C₁₀ alkylene group unsubstituted or substituted with at least one R₁₀ₐ or may be a group represented by any one selected from among Formulae 3-1 to 3-15:

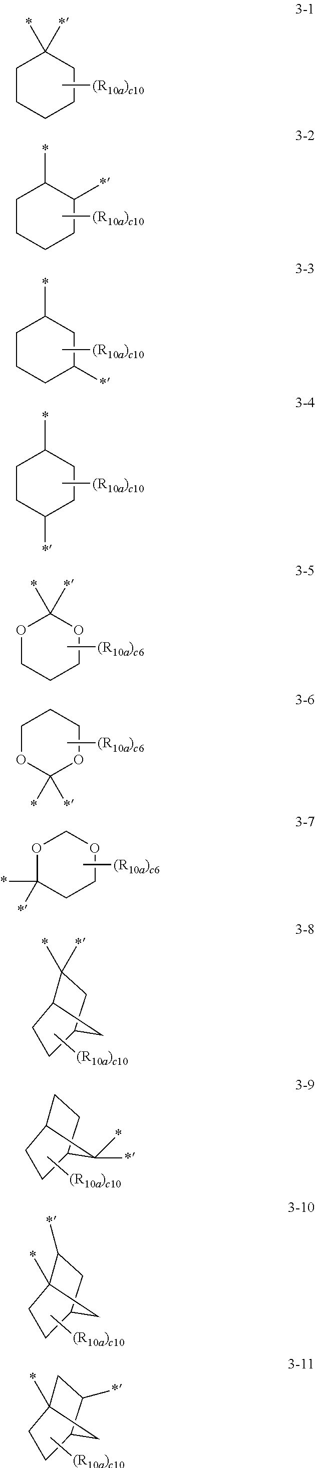

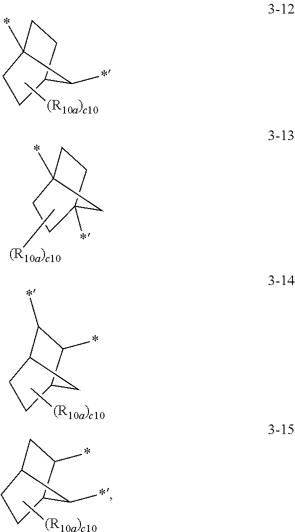

wherein, in Formulae 3-1 to 3-15,
R₁₀ₐ is the same as described herein,
c6 may be an integer from 0 to 6,
c10 may be an integer from 0 to 10, and
* and *′ each indicate a binding site to a neighboring atom.

In Formula 1, Ar₁ to Ar₃ may each independently be deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and R₁₀ₐ and Q₁ to Q₃ are each the same as described herein.

In one or more embodiments, Ar₁ to Ar₃ may each independently be:
a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —P(═O)(Q₃₁)(Q₃₂), or any combination thereof; or
—C(Q₁)(Q₂)(Q₃), —Si(Q₁)(Q₂)(Q₃), —N(Q₁)(Q₂), or —P(═O)(Q₁)(Q₂), and
Q₁ to Q₃ and Q₃₁ to Q₃₃ may each independently be: hydrogen; deuterium; —F; —Cl; —Br; —I; a C₁-C₆₀ alkyl group; a C₂-C₆₀ alkenyl group; a C₂-C₆₀ alkynyl group; a C₁-C₆₀ alkoxy group; a C₁-C₆₀ alkylthio group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

In one or more embodiments, Ar₁ to Ar₃ may each independently be a group represented by any one selected from among Formulae 4-1 to 4-6:

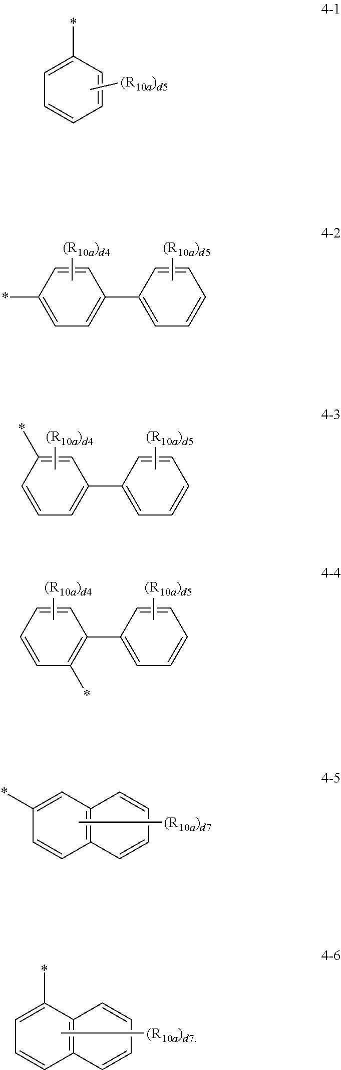

wherein, in Formulae 4-1 to 4-6,
R₁₀ₐ is the same as described herein,
d4 may be an integer from 0 to 4,
d5 may be an integer from 0 to 5,
d7 may be an integer from 0 to 7, and
* indicates a binding site to a neighboring atom.

In one or more embodiments, at least one selected from among Ar₁ to Ar₃ may be substituted with —F, a cyano group, —P(═O)(Q₁)(Q₂), or any combination thereof.

In one or more embodiments, Ar₃ may not include a (e.g., may exclude any) triazine group.

In Formula 1, L₁ to L₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ.

In one or more embodiments, L₁ to L₄ may each independently be
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phthalazine group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzooxasiline group, a dibenzothiasiline group, a dibenzodihydroazasiline group, a dibenzodihydrodisiline group, a dibenzodihydrosiline group, a dibenzodioxin group, a dibenzooxathiin group, a dibenzooxazine group, a dibenzopyran group, a dibenzodithiin group, a dibenzothiazine group, a dibenzothiopyran group, a dibenzocyclohexadiene group, a dibenzodihydropyridine group, or a dibenzodihydropyrazine group, each unsubstituted or substituted with at least one R₁₀ₐ.

In one or more embodiments, L₄ may not include a (e.g., may exclude any) triazine group.

In Formula 1, n1 to n4 may each independently be an integer from 0 to 4, wherein, if (e.g., when) n1 is 0, *-(L₁)ₙ₁-*′ may be a single bond, if (e.g., when) n2 is 0, *-(L₂)ₙ₂-*′ may be a single bond, if (e.g., when) n3 is 0, *-(L₃)ₙ₃-*′ may be a single bond, and if (e.g., when) n4 is 0, *-(L₄)ₙ₄-*′ may be a single bond.

In Formulae 2A, 2B, and 2C, R₁ and R₂ may each independently be deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

In one or more embodiments, in Formulae 2A, 2B, and 2C, R₁ and R₂ may each independently be:
deuterium, —F, —Cl, —Br, —I, a cyano group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, a C₁-C₂₀ alkylthio group, a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —P(═O)(Q₃₁)(Q₃₂), or any combination thereof; or
—C(Q₁)(Q₂)(Q₃), —Si(Q₁)(Q₂)(Q₃), —N(Q₁)(Q₂), or —P(═O)(Q₁)(Q₂), and
Q₁ to Q₃ and Q₃₁ to Q₃₃ may each independently be: hydrogen; deuterium; —F; —Cl; —Br; —I; a cyano group; a C₁-C₆₀ alkyl group; a C₂-C₆₀ alkenyl group; a C₂-C₆₀ alkynyl group; a C₁-C₆₀ alkoxy group; a C₁-C₆₀ alkylthio group; or a C₅-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

In one or more embodiments, in Formulae 2A, 2B, and 2C, a4 and b4 may each independently be an integer from 0 to 4, and a6 and b6 may each independently be an integer from 0 to 6, wherein, if (e.g., when) Z₁ is a group represented by Formula 2A, the sum of a4 and b4 may be 1 or more.

In Formulae 2A, 2B, and 2C, if (e.g., when) a4 is 2 or more, or if (e.g., when) a6 is 2 or more, two or more of R₁(s) may optionally be bonded to each other to form a C₃-C₃₀ carbocyclic group unsubstituted or substituted with at least one R₁₀ₐ or a C₁-C₃₀ heterocyclic group unsubstituted or substituted with at least one R₁₀ₐ.

In Formulae 2A, 2B, and 2C, if (e.g., when) b4 is 2 or more, or if (e.g., when) b6 is 2 or more, two or more of R₂(s) may optionally be bonded to each other to form a C₃-C₃₀ carbocyclic group unsubstituted or substituted with at least one R₁₀ₐ or a C₁-C₃₀ heterocyclic group unsubstituted or substituted with at least one R₁₀ₐ.

In Formulae 1, 2A, 2B, and 2C, R₁ and R₂ may each independently optionally be bonded to L₃ or L₄ or Ar₃ to form a C₃-C₃₀ carbocyclic group unsubstituted or substituted with at least one R₁₀ₐ or a C₁-C₃₀ heterocyclic group unsubstituted or substituted with at least one R₁₀ₐ.

In Formula 1, R₁₁ to R₁₃ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

In one or more embodiments, in Formula 1, R₁₁ to R₁₃ may each independently be:
hydrogen, deuterium, —F, —Cl, —Br, —I, a cyano group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, a C₁-C₂₀ alkylthio group, a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —P(═O)(Q₃₁)(Q₃₂), or any combination thereof; or
—C(Q₁)(Q₂)(Q₃), —Si(Q₁)(Q₂)(Q₃), —N(Q₁)(Q₂), or —P(═O)(Q₁)(Q₂), and
Q₁ to Q₃ and Q₃₁ to Q₃₃ may each independently be: hydrogen; deuterium; —F; —Cl; —Br; —I; a cyano group; a C₁-C₆₀ alkyl group; a C₂-C₆₀ alkenyl group; a C₂-C₆₀ alkynyl group; a C₁-C₆₀ alkoxy group; a C₁-C₆₀ alkylthio group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

In one or more embodiments, a group represented by *-(L₃)ₙ₃-Z₁-(L₄)ₙ₄-* in Formula 1 may be a group represented by any one selected from among Formulae 5-1 to 5-10:

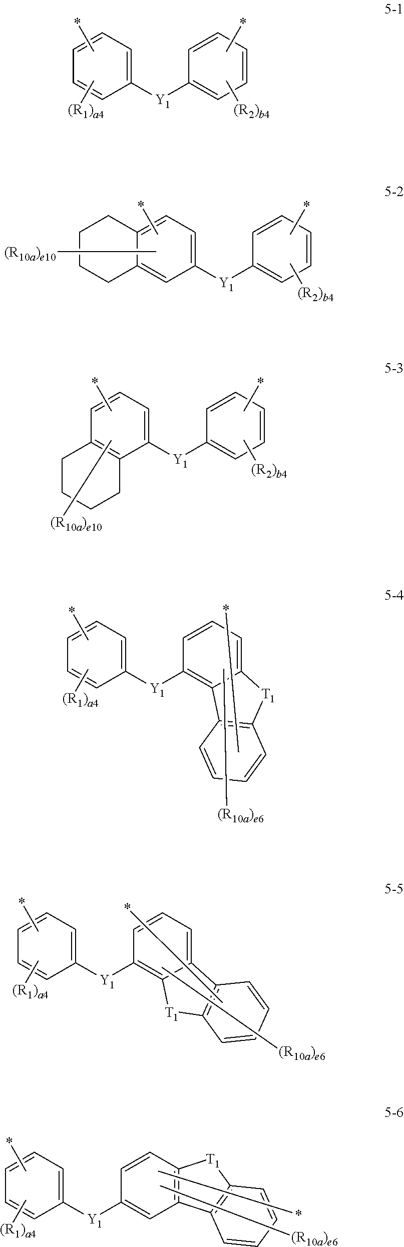

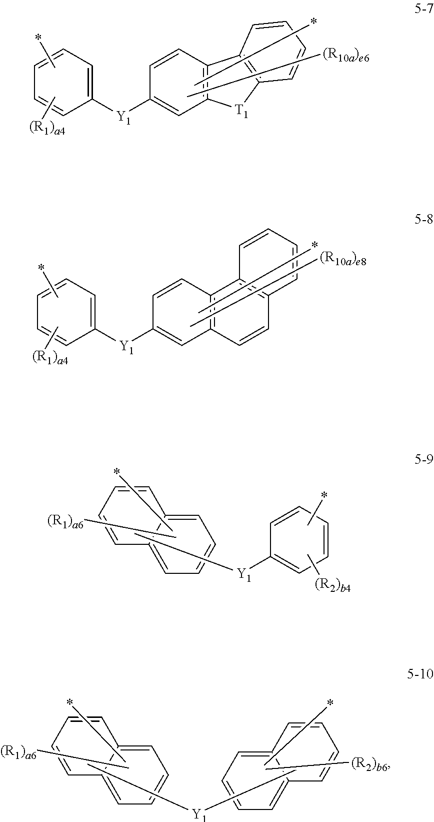

wherein, in Formulae 5-1 to 5-10,
T₁ may be O, S, N(R_{10b}), or C(R_{10b})(R_{10c}),
e6 may be an integer from 0 to 6,
e8 may be an integer from 0 to 8,
e10 may be an integer from 0 to 10,
R_{10b} and R_{10c} are each independently the same as described with respect to R₁₀ₐ,
Y₁, R₁, R₂, a4, b4, a6, b6, and R₁₀ₐ are each the same as described herein, and
* indicates a binding site to a neighboring atom.

In one or more embodiments, the heterocyclic compound represented by Formula 1 may have an asymmetric structure.

Unless defined otherwise, R₁₀ₐ may be:
hydrogen, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Unless defined otherwise, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In Formulae 1, 2A, 2B, and 2C, R₁ and R₂ may each independently be:
deuterium, —F, —Cl, —Br, —I, a cyano group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, a C₁-C₂₀ alkylthio group, a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —P(═O)(Q₃₁)(Q₃₂), or any combination thereof; or
—C(Q₁)(Q₂)(Q₃), —Si(Q₁)(Q₂)(Q₃), —N(Q₁)(Q₂), or —P(═O)(Q₁)(Q₂), and
Q₁ to Q₃ and Q₃₁ to Q₃₃ may each independently be: hydrogen; deuterium; —F; —Cl; —Br; —I; a cyano group; a C₁-C₆₀ alkyl group; a C₂-C₆₀ alkenyl group; a C₂-C₆₀ alkynyl group; a C₁-C₆₀ alkoxy group; a C₁-C₆₀ alkylthio group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

In one or more embodiments, the heterocyclic compound represented by Formula 1 may be any one selected from among Compounds 1 to 1092:

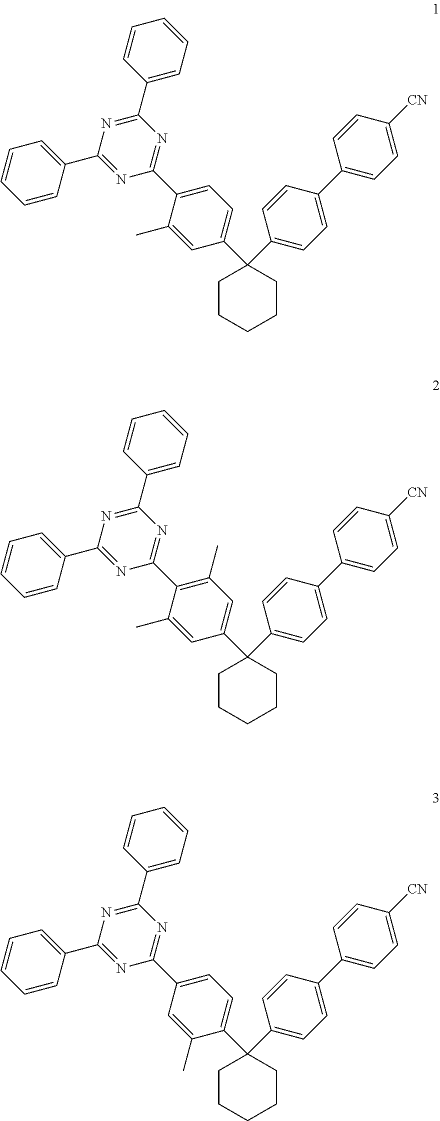 [SMILES: Cc1cc(C2(c3ccc(-c4ccc(C#N)cc4)cc3)CCCCC2)ccc1-c1nc(-c2ccccc2)nc(-c2ccccc2)n1 ; Cc1cc(C2(c3ccc(-c4ccc(C#N)cc4)cc3)CCCCC2)cc(C)c1-c1nc(-c2ccccc2)nc(-c2ccccc2)n1 ; Cc1cc(-c2nc(-c3ccccc3)nc(-c3ccccc3)n2)ccc1C1(c2ccc(-c3ccc(C#N)cc3)cc2)CCCCC1]

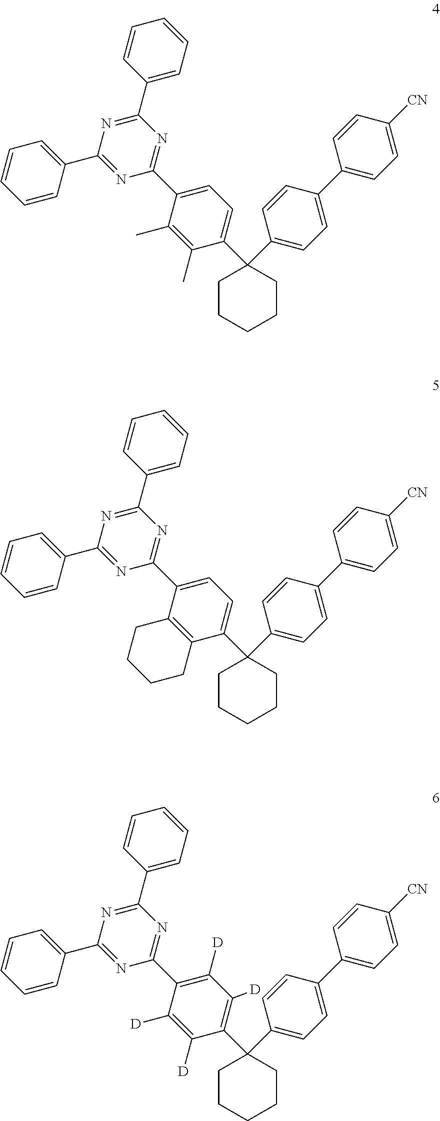 [SMILES: Cc1c(-c2nc(-c3ccccc3)nc(-c3ccccc3)n2)ccc(C2(c3ccc(-c4ccc(C#N)cc4)cc3)CCCCC2)c1C ; N#Cc1ccc(-c2ccc(C3(c4ccc(-c5nc(-c6ccccc6)nc(-c6ccccc6)n5)c5c4CCCC5)CCCCC3)cc2)cc1 ; [2H]c1c([2H])c(C2(c3ccc(-c4ccc(C#N)cc4)cc3)CCCCC2)c([2H])c([2H])c1-c1nc(-c2ccccc2)nc(-c2ccccc2)n1]

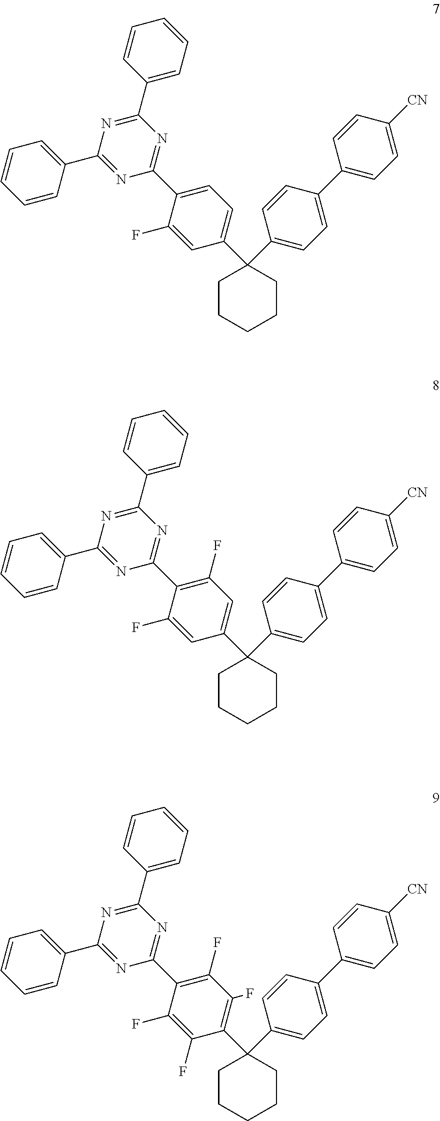 [SMILES: N#Cc1ccc(-c2ccc(C3(c4ccc(-c5nc(-c6ccccc6)nc(-c6ccccc6)n5)c(F)c4)CCCCC3)cc2)cc1 ; N#Cc1ccc(-c2ccc(C3(c4cc(F)c(-c5nc(-c6ccccc6)nc(-c6ccccc6)n5)c(F)c4)CCCCC3)cc2)cc1 ; N#Cc1ccc(-c2ccc(C3(c4c(F)c(F)c(-c5nc(-c6ccccc6)nc(-c6ccccc6)n5)c(F)c4F)CCCCC3)cc2)cc1]

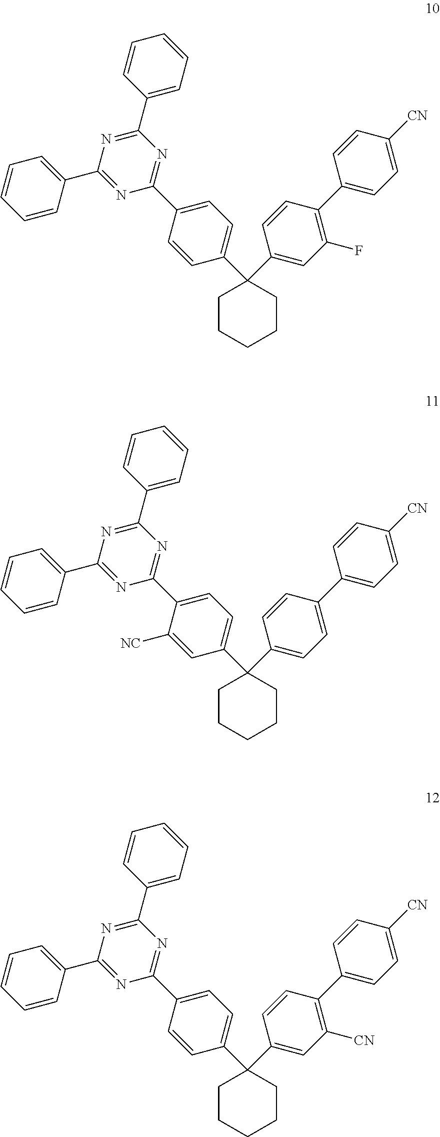 [SMILES: N#Cc1ccc(-c2ccc(C3(c4ccc(-c5nc(-c6ccccc6)nc(-c6ccccc6)n5)cc4)CCCCC3)cc2F)cc1 ; N#Cc1ccc(-c2ccc(C3(c4ccc(-c5nc(-c6ccccc6)nc(-c6ccccc6)n5)c(C#N)c4)CCCCC3)cc2)cc1 ; N#Cc1ccc(-c2ccc(C3(c4ccc(-c5nc(-c6ccccc6)nc(-c6ccccc6)n5)cc4)CCCCC3)cc2C#N)cc1]

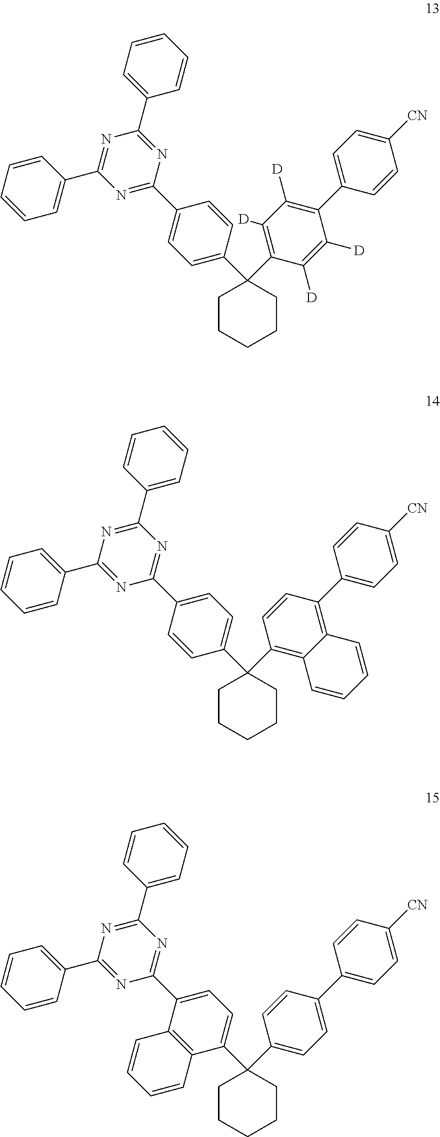 [SMILES: [2H]c1c([2H])c(C2(c3ccc(-c4nc(-c5ccccc5)nc(-c5ccccc5)n4)cc3)CCCCC2)c([2H])c([2H])c1-c1ccc(C#N)cc1 ; N#Cc1ccc(-c2ccc(C3(c4ccc(-c5nc(-c6ccccc6)nc(-c6ccccc6)n5)cc4)CCCCC3)c3ccccc23)cc1 ; N#Cc1ccc(-c2ccc(C3(c4ccc(-c5nc(-c6ccccc6)nc(-c6ccccc6)n5)c5ccccc45)CCCCC3)cc2)cc1]

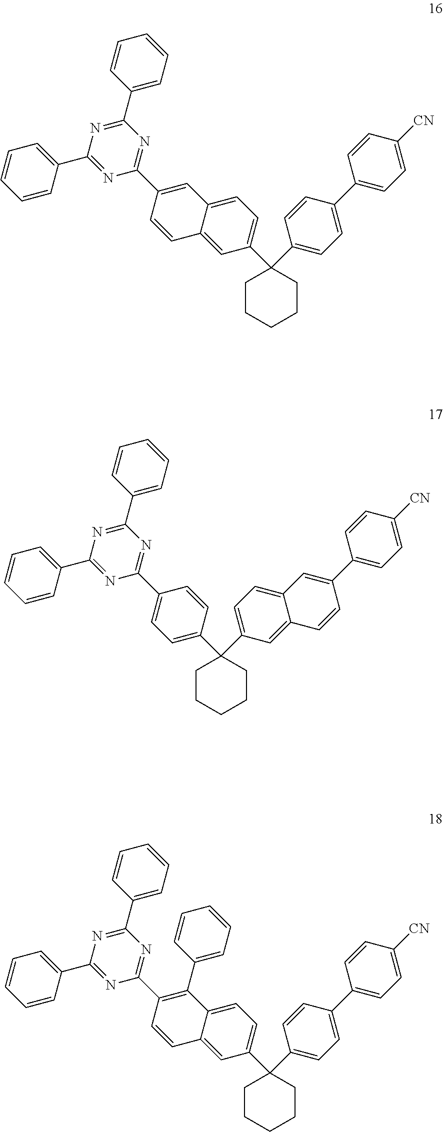 [SMILES: N#Cc1ccc(-c2ccc(C3(c4ccc5cc(-c6nc(-c7ccccc7)nc(-c7ccccc7)n6)ccc5c4)CCCCC3)cc2)cc1 ; N#Cc1ccc(-c2ccc3cc(C4(c5ccc(-c6nc(-c7ccccc7)nc(-c7ccccc7)n6)cc5)CCCCC4)ccc3c2)cc1 ; N#Cc1ccc(-c2ccc(C3(c4ccc5c(-c6ccccc6)c(-c6nc(-c7ccccc7)nc(-c7ccccc7)n6)ccc5c4)CCCCC3)cc2)cc1]

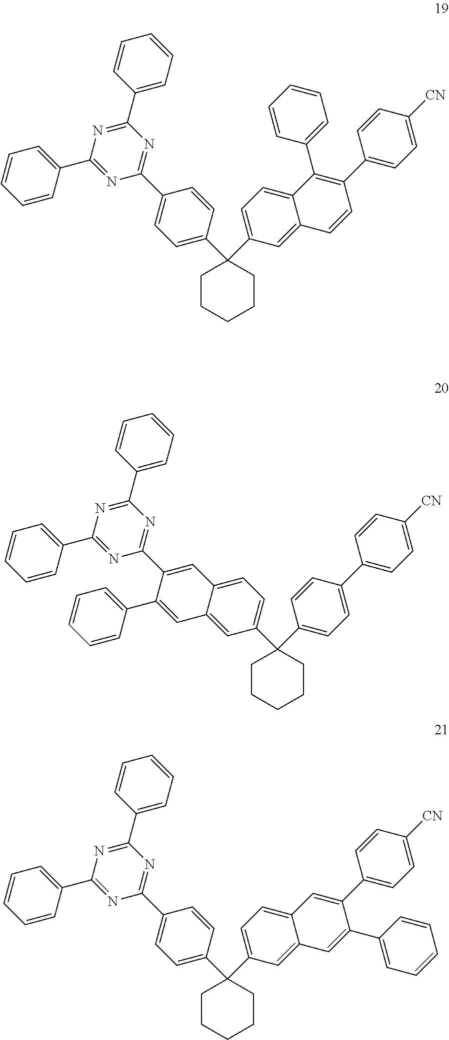 [SMILES: N#Cc1ccc(-c2ccc3cc(C4(c5ccc(-c6nc(-c7ccccc7)nc(-c7ccccc7)n6)cc5)CCCCC4)ccc3c2-c2ccccc2)cc1 ; N#Cc1ccc(-c2ccc(C3(c4ccc5cc(-c6nc(-c7ccccc7)nc(-c7ccccc7)n6)c(-c6ccccc6)cc5c4)CCCCC3)cc2)cc1 ; N#Cc1ccc(-c2cc3ccc(C4(c5ccc(-c6nc(-c7ccccc7)nc(-c7ccccc7)n6)cc5)CCCCC4)cc3cc2-c2ccccc2)cc1]

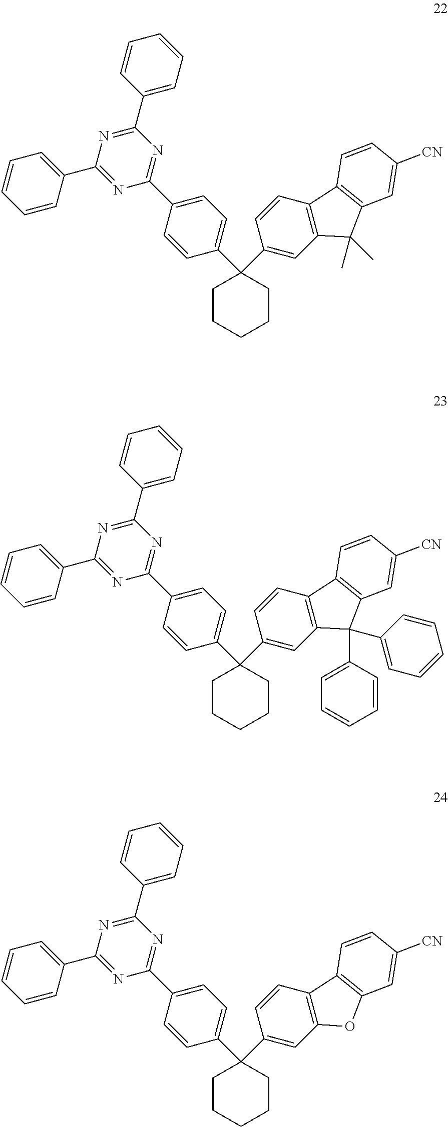 [SMILES: CC1(C)c2cc(C#N)ccc2-c2ccc(C3(c4ccc(-c5nc(-c6ccccc6)nc(-c6ccccc6)n5)cc4)CCCCC3)cc21 ; N#Cc1ccc2c(c1)C(c1ccccc1)(c1ccccc1)c1cc(C3(c4ccc(-c5nc(-c6ccccc6)nc(-c6ccccc6)n5)cc4)CCCCC3)ccc1-2 ; N#Cc1ccc2c(c1)oc1cc(C3(c4ccc(-c5nc(-c6ccccc6)nc(-c6ccccc6)n5)cc4)CCCCC3)ccc12]

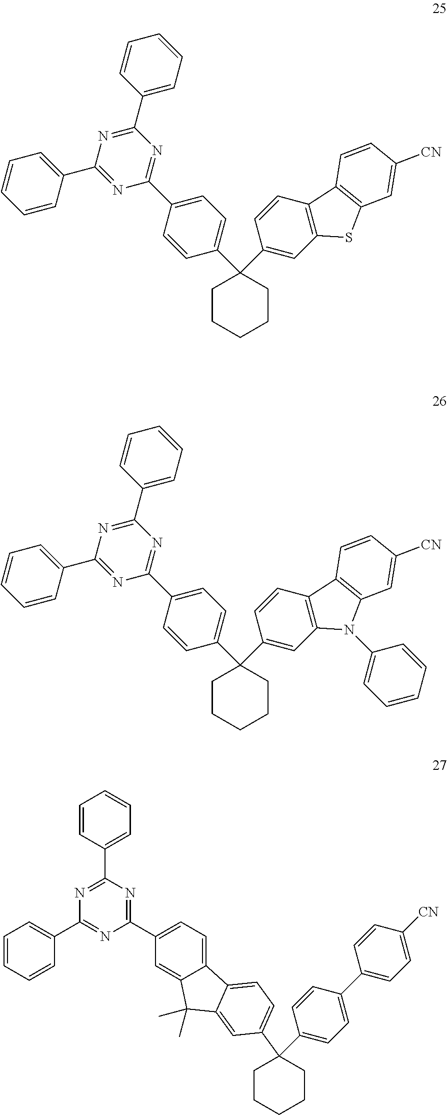 [SMILES: N#Cc1ccc2c(c1)sc1cc(C3(c4ccc(-c5nc(-c6ccccc6)nc(-c6ccccc6)n5)cc4)CCCCC3)ccc12 ; N#Cc1ccc2c3ccc(C4(c5ccc(-c6nc(-c7ccccc7)nc(-c7ccccc7)n6)cc5)CCCCC4)cc3n(-c3ccccc3)c2c1 ; CC1(C)c2cc(-c3nc(-c4ccccc4)nc(-c4ccccc4)n3)ccc2-c2ccc(C3(c4ccc(-c5ccc(C#N)cc5)cc4)CCCCC3)cc21]

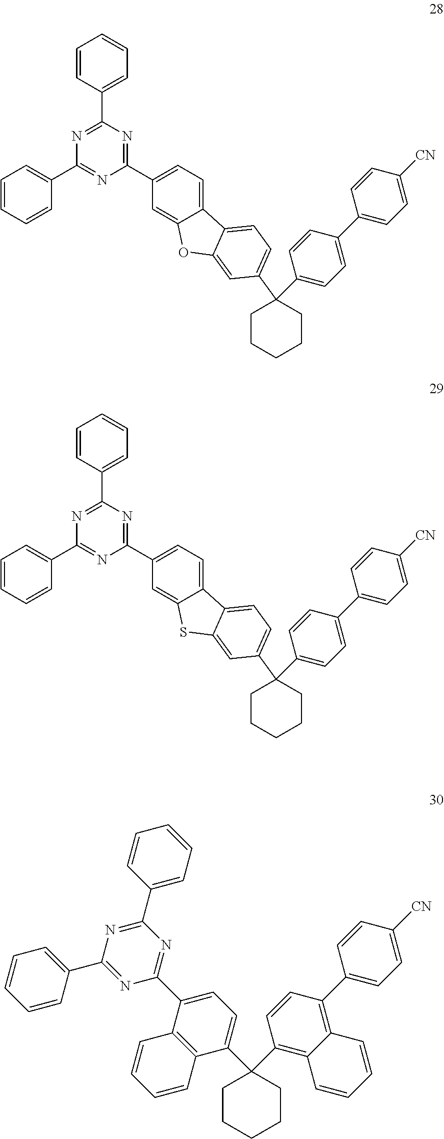 [SMILES: N#Cc1ccc(-c2ccc(C3(c4ccc5c(c4)oc4cc(-c6nc(-c7ccccc7)nc(-c7ccccc7)n6)ccc45)CCCCC3)cc2)cc1 ; N#Cc1ccc(-c2ccc(C3(c4ccc5c(c4)sc4cc(-c6nc(-c7ccccc7)nc(-c7ccccc7)n6)ccc45)CCCCC3)cc2)cc1 ; N#Cc1ccc(-c2ccc(C3(c4ccc(-c5nc(-c6ccccc6)nc(-c6ccccc6)n5)c5ccccc45)CCCCC3)c3ccccc23)cc1]

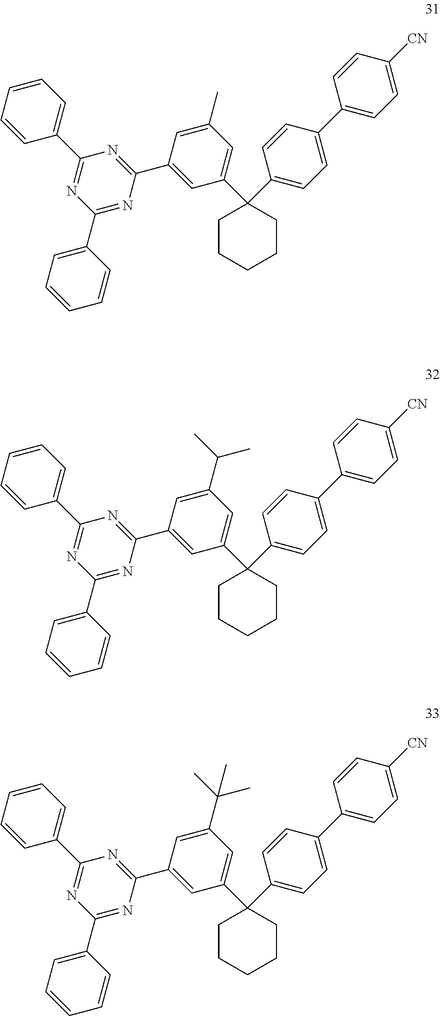 [SMILES: Cc1cc(-c2nc(-c3ccccc3)nc(-c3ccccc3)n2)cc(C2(c3ccc(-c4ccc(C#N)cc4)cc3)CCCCC2)c1 ; CC(C)c1cc(-c2nc(-c3ccccc3)nc(-c3ccccc3)n2)cc(C2(c3ccc(-c4ccc(C#N)cc4)cc3)CCCCC2)c1 ; CC(C)(C)c1cc(-c2nc(-c3ccccc3)nc(-c3ccccc3)n2)cc(C2(c3ccc(-c4ccc(C#N)cc4)cc3)CCCCC2)c1]

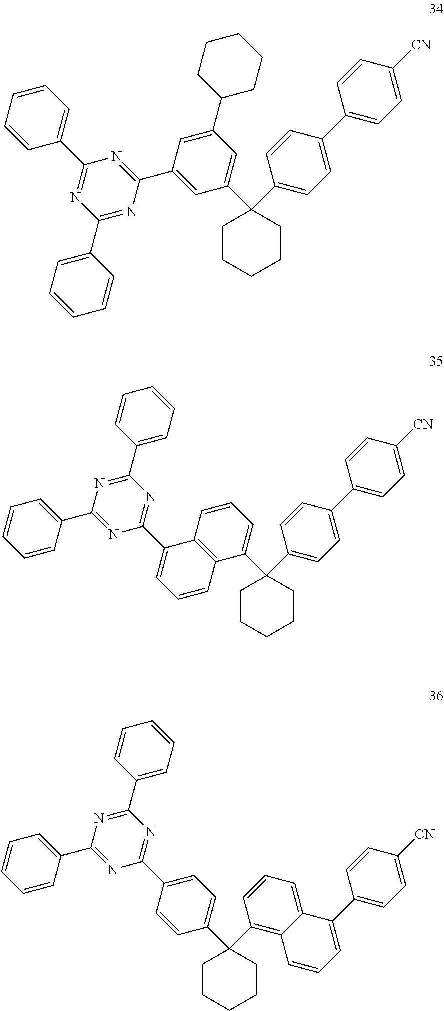 [SMILES: N#Cc1ccc(-c2ccc(C3(c4cc(-c5nc(-c6ccccc6)nc(-c6ccccc6)n5)cc(C5CCCCC5)c4)CCCCC3)cc2)cc1 ; N#Cc1ccc(-c2ccc(C3(c4cccc5c(-c6nc(-c7ccccc7)nc(-c7ccccc7)n6)cccc45)CCCCC3)cc2)cc1 ; N#Cc1ccc(-c2cccc3c(C4(c5ccc(-c6nc(-c7ccccc7)nc(-c7ccccc7)n6)cc5)CCCCC4)cccc23)cc1]

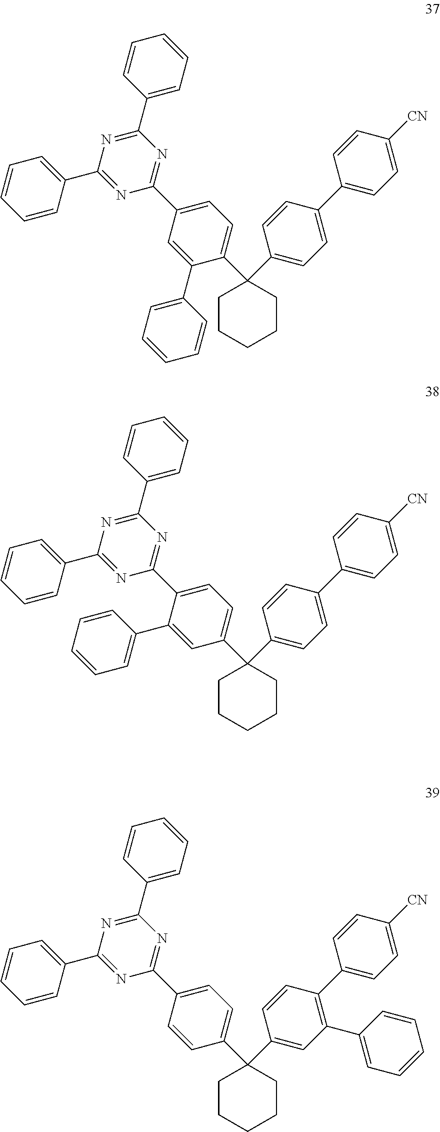 [SMILES: N#Cc1ccc(-c2ccc(C3(c4ccc(-c5nc(-c6ccccc6)nc(-c6ccccc6)n5)cc4-c4ccccc4)CCCCC3)cc2)cc1 ; N#Cc1ccc(-c2ccc(C3(c4ccc(-c5nc(-c6ccccc6)nc(-c6ccccc6)n5)c(-c5ccccc5)c4)CCCCC3)cc2)cc1 ; N#Cc1ccc(-c2ccc(C3(c4ccc(-c5nc(-c6ccccc6)nc(-c6ccccc6)n5)cc4)CCCCC3)cc2-c2ccccc2)cc1]

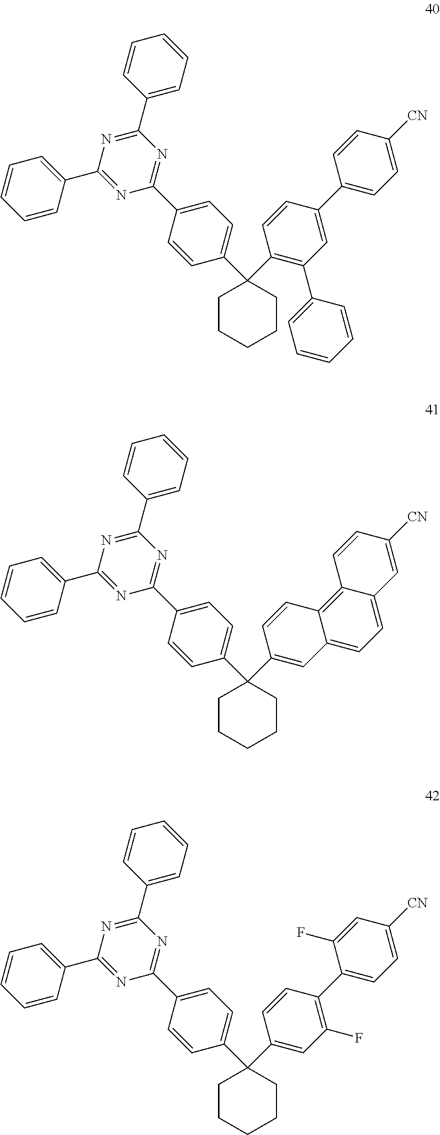 [SMILES: N#Cc1ccc(-c2ccc(C3(c4ccc(-c5nc(-c6ccccc6)nc(-c6ccccc6)n5)cc4)CCCCC3)c(-c3ccccc3)c2)cc1 ; N#Cc1ccc2c(ccc3cc(C4(c5ccc(-c6nc(-c7ccccc7)nc(-c7ccccc7)n6)cc5)CCCCC4)ccc32)c1 ; N#Cc1ccc(-c2ccc(C3(c4ccc(-c5nc(-c6ccccc6)nc(-c6ccccc6)n5)cc4)CCCCC3)cc2F)c(F)c1]

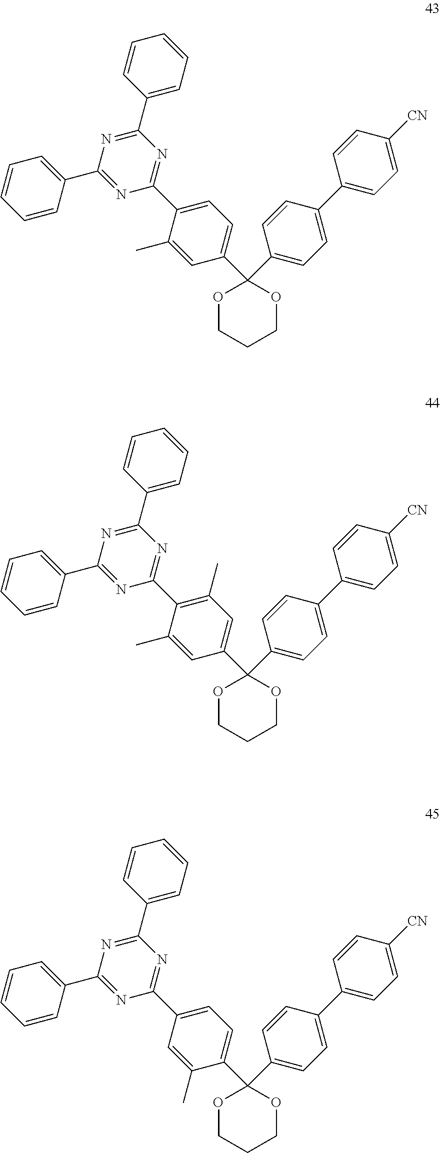 [SMILES: Cc1cc(C2(c3ccc(-c4ccc(C#N)cc4)cc3)OCCCO2)ccc1-c1nc(-c2ccccc2)nc(-c2ccccc2)n1 ; Cc1cc(C2(c3ccc(-c4ccc(C#N)cc4)cc3)OCCCO2)cc(C)c1-c1nc(-c2ccccc2)nc(-c2ccccc2)n1 ; Cc1cc(-c2nc(-c3ccccc3)nc(-c3ccccc3)n2)ccc1C1(c2ccc(-c3ccc(C#N)cc3)cc2)OCCCO1]

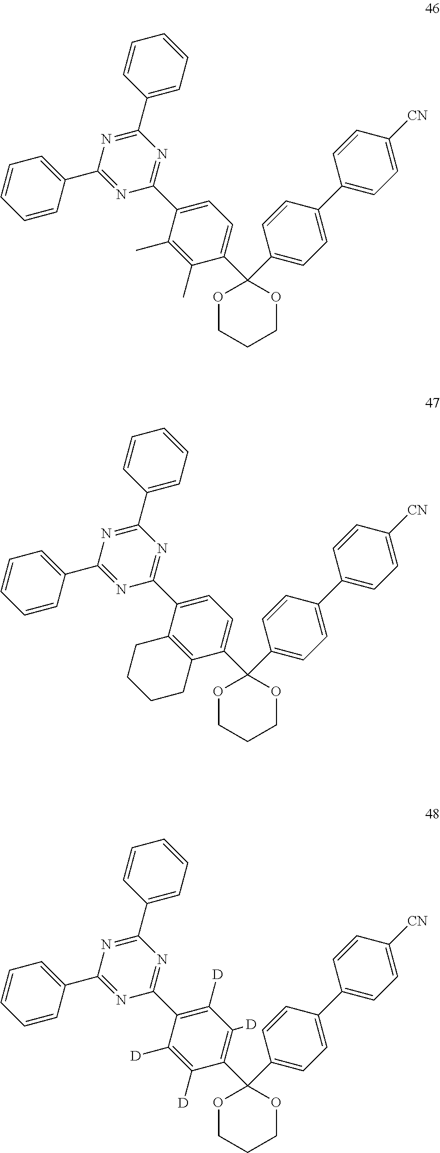 [SMILES: Cc1c(-c2nc(-c3ccccc3)nc(-c3ccccc3)n2)ccc(C2(c3ccc(-c4ccc(C#N)cc4)cc3)OCCCO2)c1C ; N#Cc1ccc(-c2ccc(C3(c4ccc(-c5nc(-c6ccccc6)nc(-c6ccccc6)n5)c5c4CCCC5)OCCCO3)cc2)cc1 ; [2H]c1c([2H])c(C2(c3ccc(-c4ccc(C#N)cc4)cc3)OCCCO2)c([2H])c([2H])c1-c1nc(-c2ccccc2)nc(-c2ccccc2)n1]

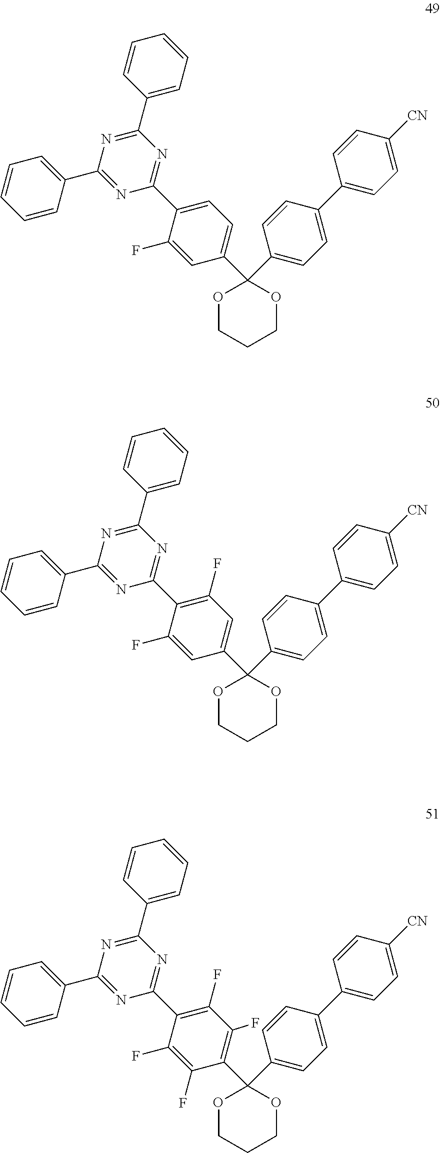 [SMILES: N#Cc1ccc(-c2ccc(C3(c4ccc(-c5nc(-c6ccccc6)nc(-c6ccccc6)n5)c(F)c4)OCCCO3)cc2)cc1 ; N#Cc1ccc(-c2ccc(C3(c4cc(F)c(-c5nc(-c6ccccc6)nc(-c6ccccc6)n5)c(F)c4)OCCCO3)cc2)cc1 ; N#Cc1ccc(-c2ccc(C3(c4c(F)c(F)c(-c5nc(-c6ccccc6)nc(-c6ccccc6)n5)c(F)c4F)OCCCO3)cc2)cc1]

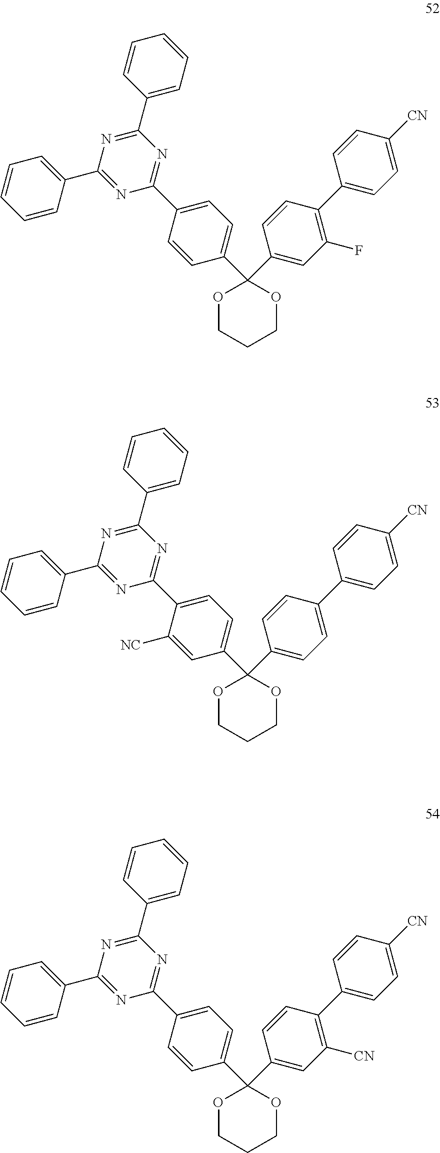 [SMILES: N#Cc1ccc(-c2ccc(C3(c4ccc(-c5nc(-c6ccccc6)nc(-c6ccccc6)n5)cc4)OCCCO3)cc2F)cc1 ; N#Cc1ccc(-c2ccc(C3(c4ccc(-c5nc(-c6ccccc6)nc(-c6ccccc6)n5)c(C#N)c4)OCCCO3)cc2)cc1 ; N#Cc1ccc(-c2ccc(C3(c4ccc(-c5nc(-c6ccccc6)nc(-c6ccccc6)n5)cc4)OCCCO3)cc2C#N)cc1]

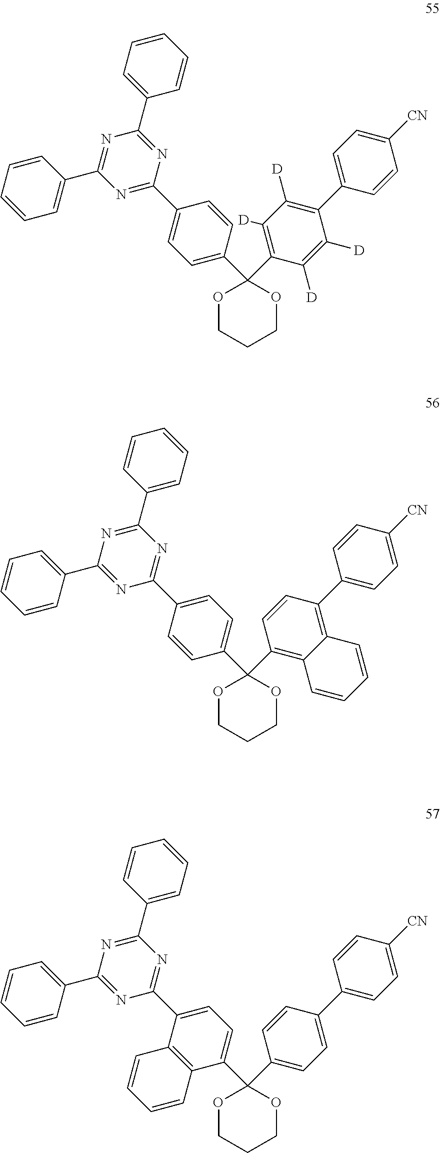 [SMILES: [2H]c1c([2H])c(C2(c3ccc(-c4nc(-c5ccccc5)nc(-c5ccccc5)n4)cc3)OCCCO2)c([2H])c([2H])c1-c1ccc(C#N)cc1 ; N#Cc1ccc(-c2ccc(C3(c4ccc(-c5nc(-c6ccccc6)nc(-c6ccccc6)n5)cc4)OCCCO3)c3ccccc23)cc1 ; N#Cc1ccc(-c2ccc(C3(c4ccc(-c5nc(-c6ccccc6)nc(-c6ccccc6)n5)c5ccccc45)OCCCO3)cc2)cc1]

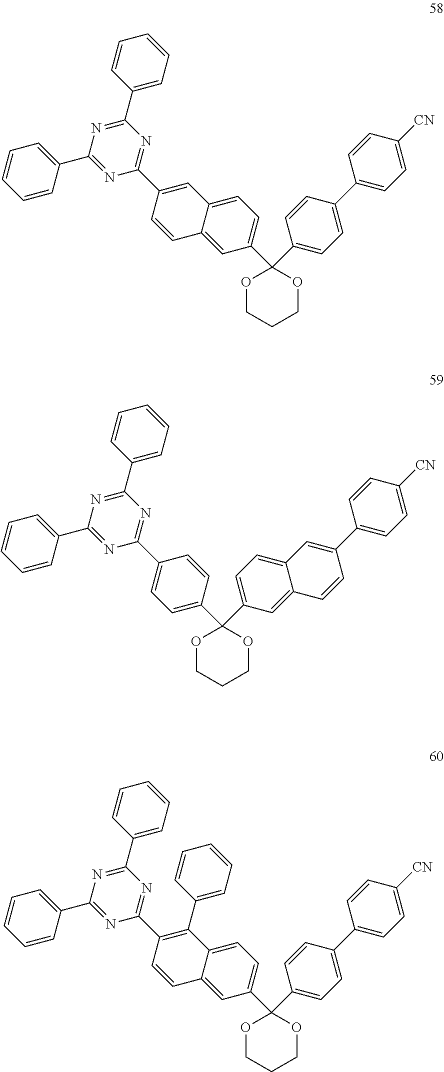 [SMILES: N#Cc1ccc(-c2ccc(C3(c4ccc5cc(-c6nc(-c7ccccc7)nc(-c7ccccc7)n6)ccc5c4)OCCCO3)cc2)cc1 ; N#Cc1ccc(-c2ccc3cc(C4(c5ccc(-c6nc(-c7ccccc7)nc(-c7ccccc7)n6)cc5)OCCCO4)ccc3c2)cc1 ; N#Cc1ccc(-c2ccc(C3(c4ccc5c(-c6ccccc6)c(-c6nc(-c7ccccc7)nc(-c7ccccc7)n6)ccc5c4)OCCCO3)cc2)cc1]

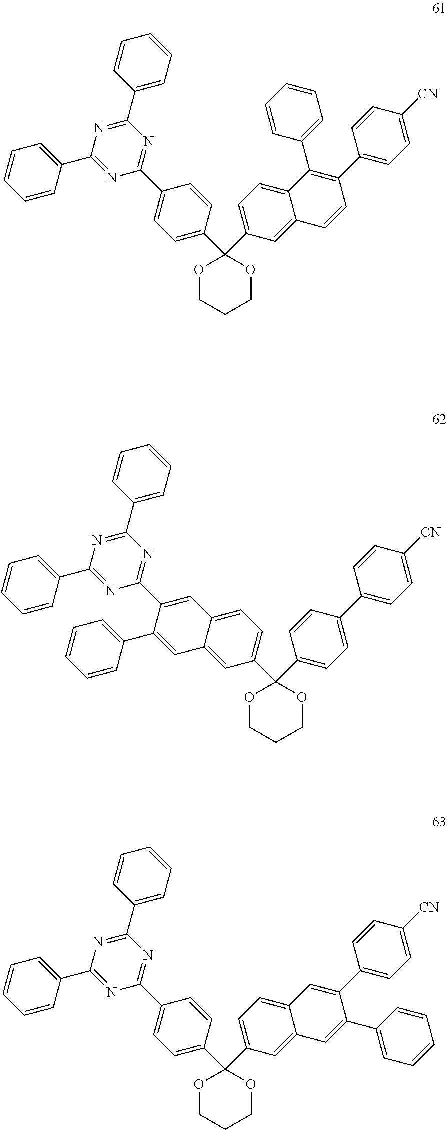 [SMILES: N#Cc1ccc(-c2ccc3cc(C4(c5ccc(-c6nc(-c7ccccc7)nc(-c7ccccc7)n6)cc5)OCCCO4)ccc3c2-c2ccccc2)cc1 ; N#Cc1ccc(-c2ccc(C3(c4ccc5cc(-c6nc(-c7ccccc7)nc(-c7ccccc7)n6)c(-c6ccccc6)cc5c4)OCCCO3)cc2)cc1 ; N#Cc1ccc(-c2cc3ccc(C4(c5ccc(-c6nc(-c7ccccc7)nc(-c7ccccc7)n6)cc5)OCCCO4)cc3cc2-c2ccccc2)cc1]

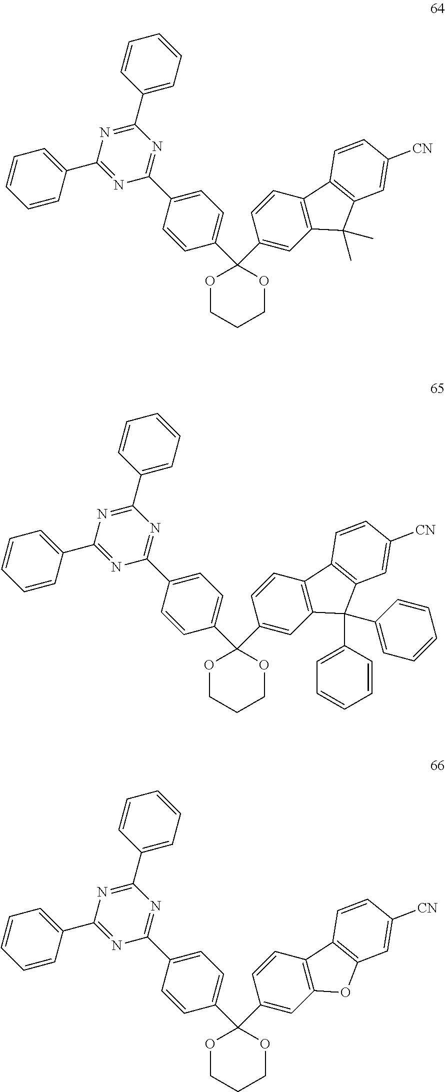 [SMILES: CC1(C)c2cc(C#N)ccc2-c2ccc(C3(c4ccc(-c5nc(-c6ccccc6)nc(-c6ccccc6)n5)cc4)OCCCO3)cc21 ; N#Cc1ccc2c(c1)C(c1ccccc1)(c1ccccc1)c1cc(C3(c4ccc(-c5nc(-c6ccccc6)nc(-c6ccccc6)n5)cc4)OCCCO3)ccc1-2 ; N#Cc1ccc2c(c1)oc1cc(C3(c4ccc(-c5nc(-c6ccccc6)nc(-c6ccccc6)n5)cc4)OCCCO3)ccc12]

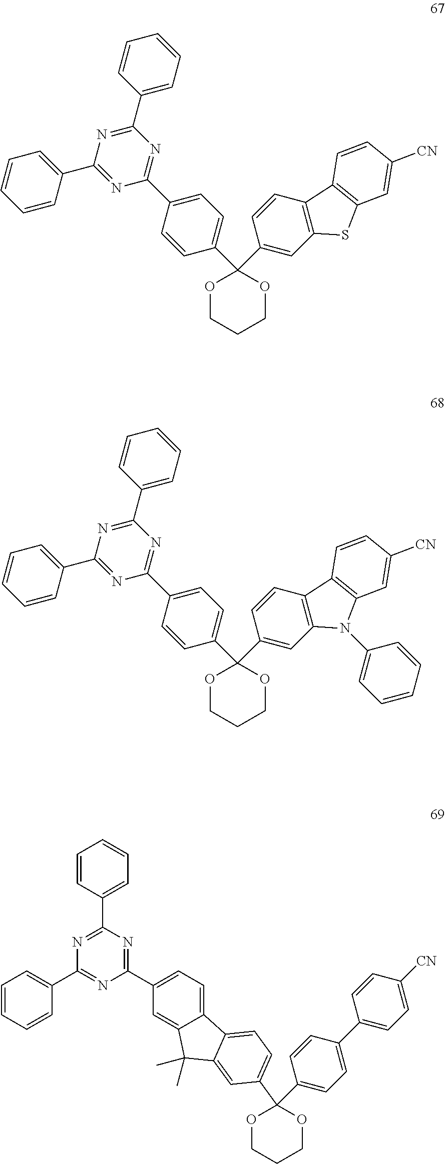 [SMILES: N#Cc1ccc2c(c1)sc1cc(C3(c4ccc(-c5nc(-c6ccccc6)nc(-c6ccccc6)n5)cc4)OCCCO3)ccc12 ; N#Cc1ccc2c3ccc(C4(c5ccc(-c6nc(-c7ccccc7)nc(-c7ccccc7)n6)cc5)OCCCO4)cc3n(-c3ccccc3)c2c1 ; CC1(C)c2cc(-c3nc(-c4ccccc4)nc(-c4ccccc4)n3)ccc2-c2ccc(C3(c4ccc(-c5ccc(C#N)cc5)cc4)OCCCO3)cc21]

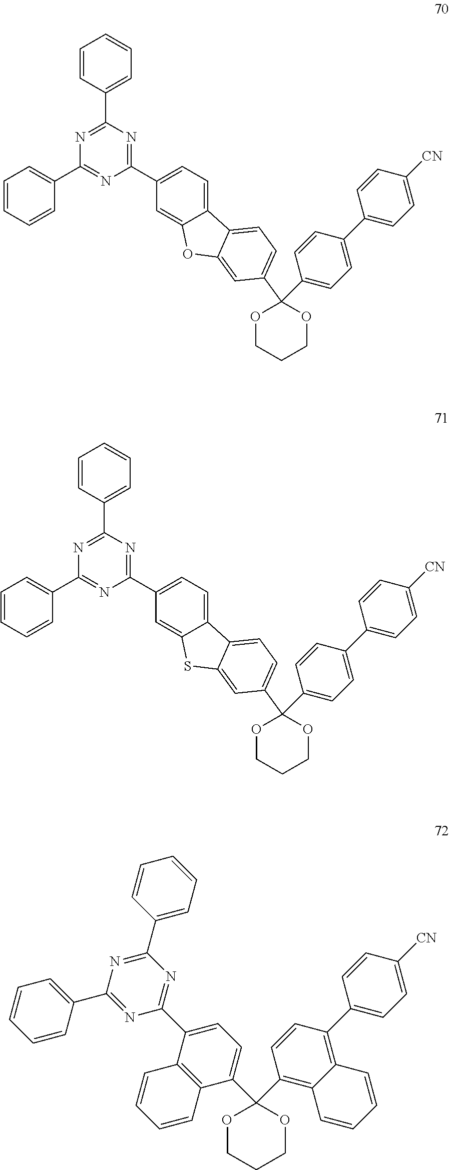 [SMILES: N#Cc1ccc(-c2ccc(C3(c4ccc5c(c4)oc4cc(-c6nc(-c7ccccc7)nc(-c7ccccc7)n6)ccc45)OCCCO3)cc2)cc1 ; N#Cc1ccc(-c2ccc(C3(c4ccc5c(c4)sc4cc(-c6nc(-c7ccccc7)nc(-c7ccccc7)n6)ccc45)OCCCO3)cc2)cc1 ; N#Cc1ccc(-c2ccc(C3(c4ccc(-c5nc(-c6ccccc6)nc(-c6ccccc6)n5)c5ccccc45)OCCCO3)c3ccccc23)cc1]

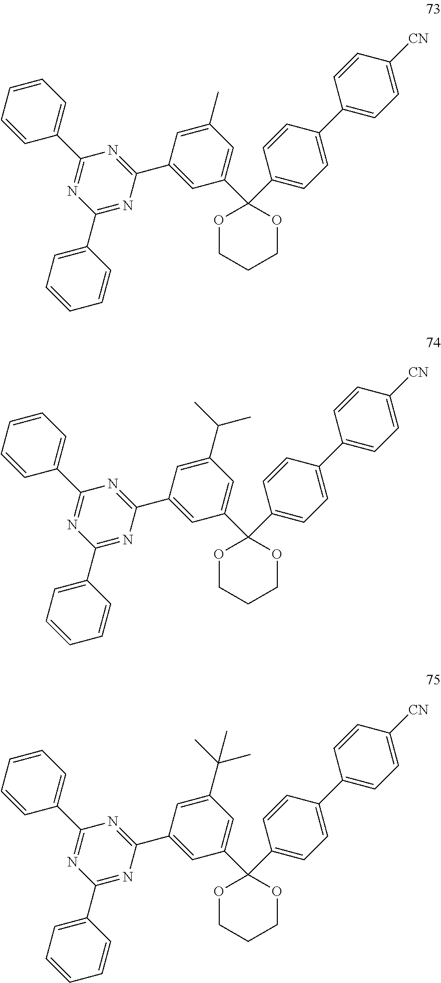 [SMILES: Cc1cc(-c2nc(-c3ccccc3)nc(-c3ccccc3)n2)cc(C2(c3ccc(-c4ccc(C#N)cc4)cc3)OCCCO2)c1 ; CC(C)c1cc(-c2nc(-c3ccccc3)nc(-c3ccccc3)n2)cc(C2(c3ccc(-c4ccc(C#N)cc4)cc3)OCCCO2)c1 ; CC(C)(C)c1cc(-c2nc(-c3ccccc3)nc(-c3ccccc3)n2)cc(C2(c3ccc(-c4ccc(C#N)cc4)cc3)OCCCO2)c1]

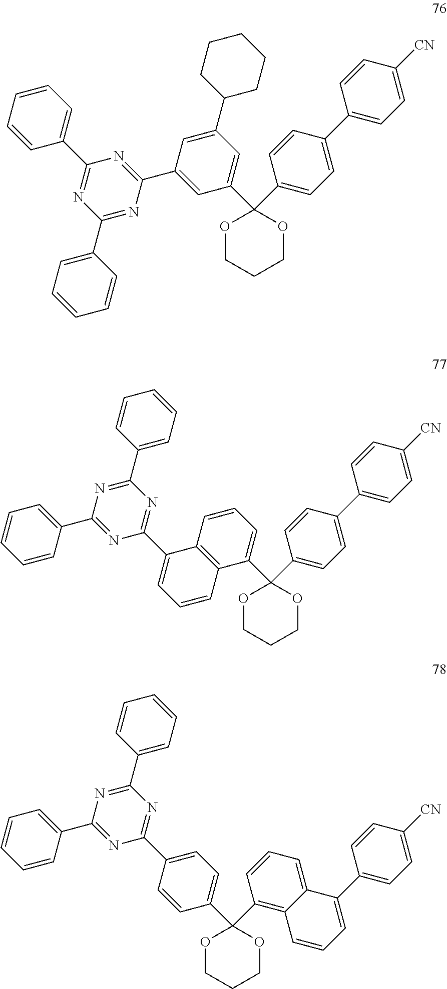 [SMILES: N#Cc1ccc(-c2ccc(C3(c4cc(-c5nc(-c6ccccc6)nc(-c6ccccc6)n5)cc(C5CCCCC5)c4)OCCCO3)cc2)cc1 ; N#Cc1ccc(-c2ccc(C3(c4cccc5c(-c6nc(-c7ccccc7)nc(-c7ccccc7)n6)cccc45)OCCCO3)cc2)cc1 ; N#Cc1ccc(-c2cccc3c(C4(c5ccc(-c6nc(-c7ccccc7)nc(-c7ccccc7)n6)cc5)OCCCO4)cccc23)cc1]

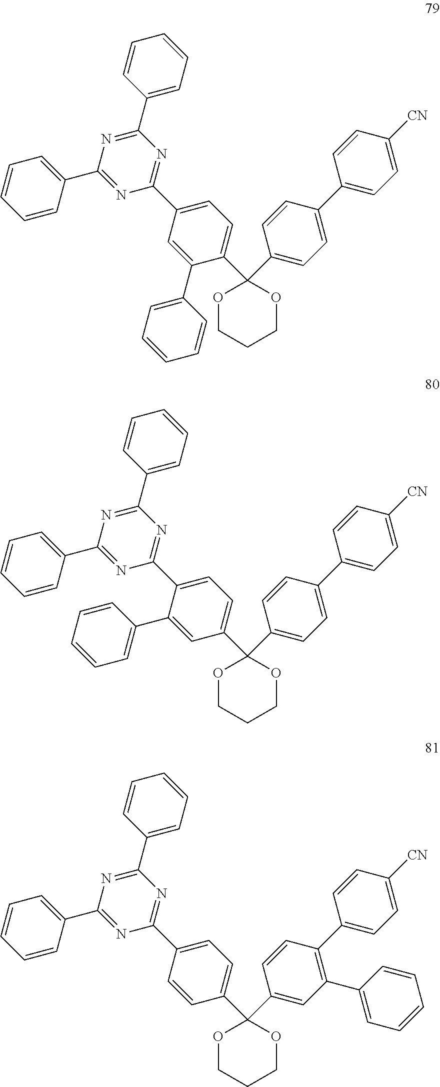 [SMILES: N#Cc1ccc(-c2ccc(C3(c4ccc(-c5nc(-c6ccccc6)nc(-c6ccccc6)n5)cc4-c4ccccc4)OCCCO3)cc2)cc1 ; N#Cc1ccc(-c2ccc(C3(c4ccc(-c5nc(-c6ccccc6)nc(-c6ccccc6)n5)c(-c5ccccc5)c4)OCCCO3)cc2)cc1 ; N#Cc1ccc(-c2ccc(C3(c4ccc(-c5nc(-c6ccccc6)nc(-c6ccccc6)n5)cc4)OCCCO3)cc2-c2ccccc2)cc1]

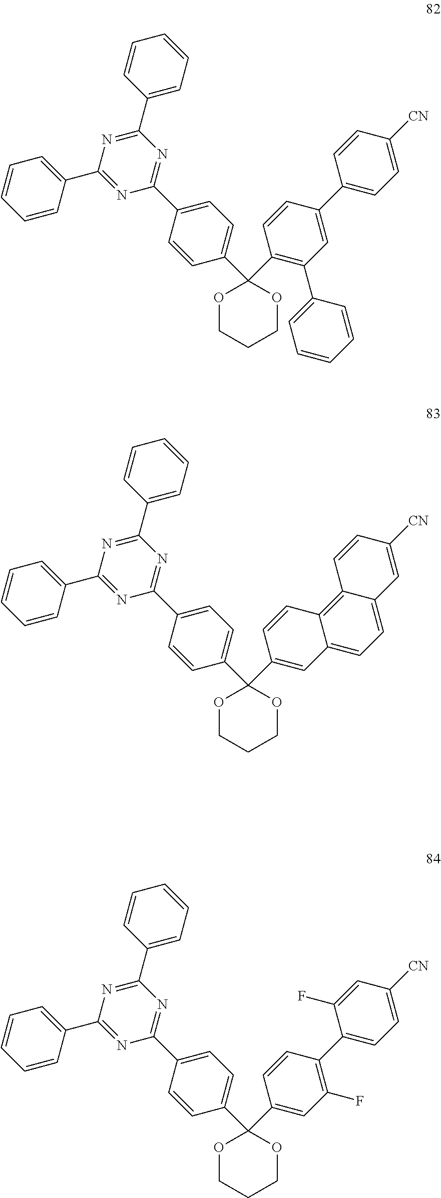 [SMILES: N#Cc1ccc(-c2ccc(C3(c4ccc(-c5nc(-c6ccccc6)nc(-c6ccccc6)n5)cc4)OCCCO3)c(-c3ccccc3)c2)cc1 ; N#Cc1ccc2c(ccc3cc(C4(c5ccc(-c6nc(-c7ccccc7)nc(-c7ccccc7)n6)cc5)OCCCO4)ccc32)c1 ; N#Cc1ccc(-c2ccc(C3(c4ccc(-c5nc(-c6ccccc6)nc(-c6ccccc6)n5)cc4)OCCCO3)cc2F)c(F)c1]

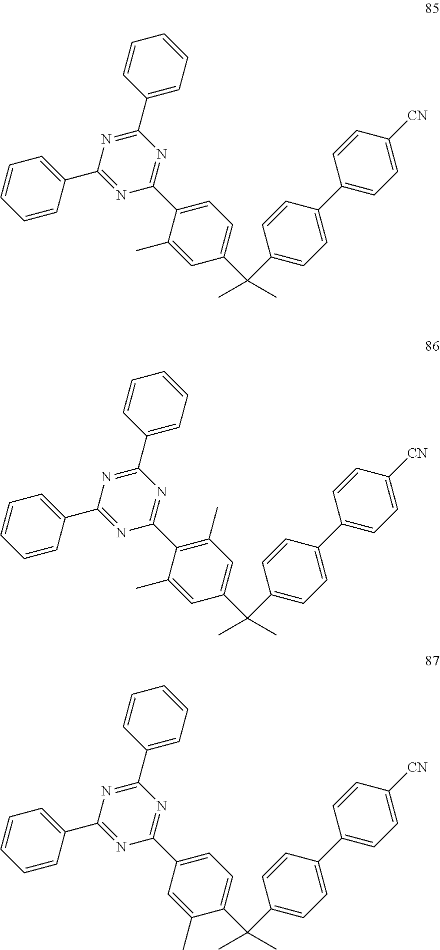 [SMILES: Cc1cc(C(C)(C)c2ccc(-c3ccc(C#N)cc3)cc2)ccc1-c1nc(-c2ccccc2)nc(-c2ccccc2)n1 ; Cc1cc(C(C)(C)c2ccc(-c3ccc(C#N)cc3)cc2)cc(C)c1-c1nc(-c2ccccc2)nc(-c2ccccc2)n1 ; Cc1cc(-c2nc(-c3ccccc3)nc(-c3ccccc3)n2)ccc1C(C)(C)c1ccc(-c2ccc(C#N)cc2)cc1]

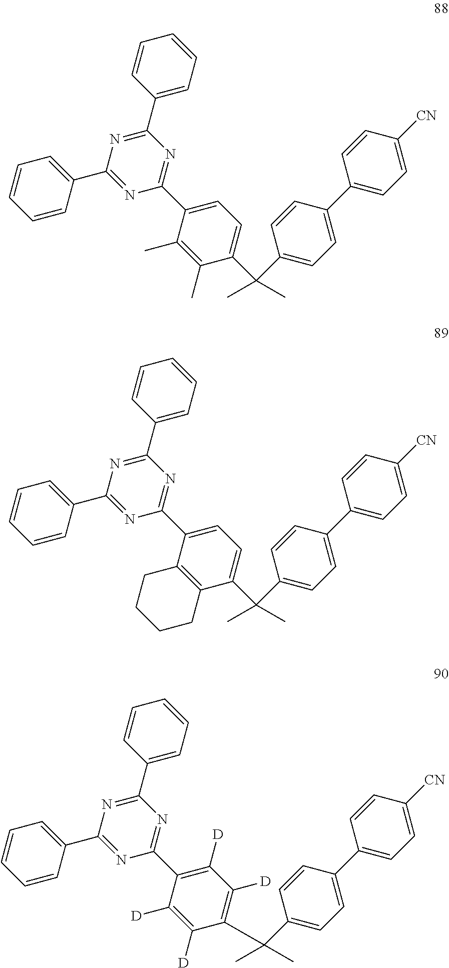 [SMILES: Cc1c(-c2nc(-c3ccccc3)nc(-c3ccccc3)n2)ccc(C(C)(C)c2ccc(-c3ccc(C#N)cc3)cc2)c1C ; CC(C)(c1ccc(-c2ccc(C#N)cc2)cc1)c1ccc(-c2nc(-c3ccccc3)nc(-c3ccccc3)n2)c2c1CCCC2 ; [2H]c1c([2H])c(C(C)(C)c2ccc(-c3ccc(C#N)cc3)cc2)c([2H])c([2H])c1-c1nc(-c2ccccc2)nc(-c2ccccc2)n1]

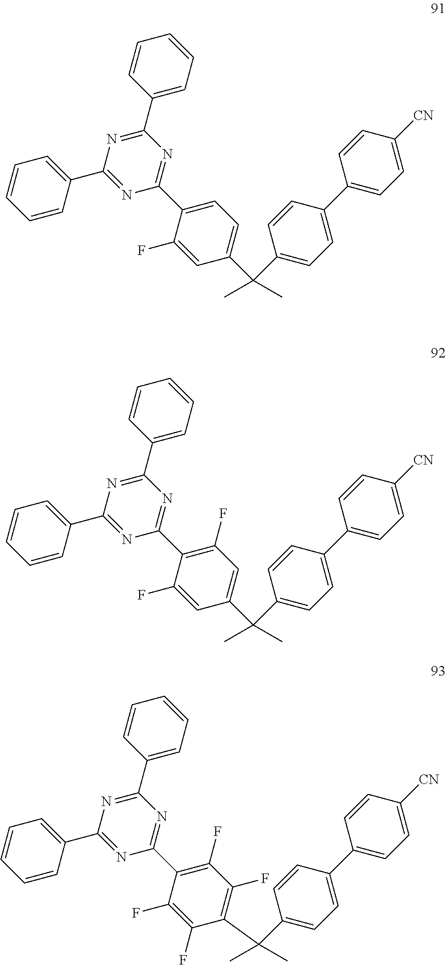 [SMILES: CC(C)(c1ccc(-c2ccc(C#N)cc2)cc1)c1ccc(-c2nc(-c3ccccc3)nc(-c3ccccc3)n2)c(F)c1 ; CC(C)(c1ccc(-c2ccc(C#N)cc2)cc1)c1cc(F)c(-c2nc(-c3ccccc3)nc(-c3ccccc3)n2)c(F)c1 ; CC(C)(c1ccc(-c2ccc(C#N)cc2)cc1)c1c(F)c(F)c(-c2nc(-c3ccccc3)nc(-c3ccccc3)n2)c(F)c1F]

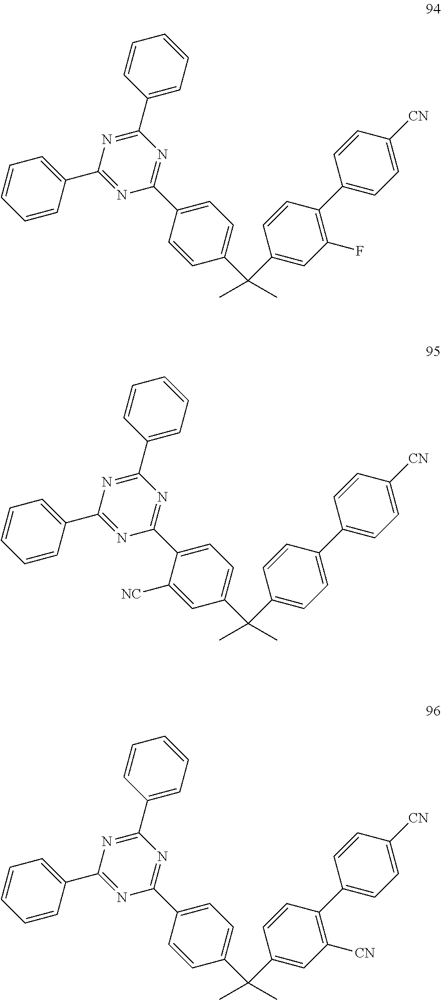 [SMILES: CC(C)(c1ccc(-c2nc(-c3ccccc3)nc(-c3ccccc3)n2)cc1)c1ccc(-c2ccc(C#N)cc2)c(F)c1 ; CC(C)(c1ccc(-c2ccc(C#N)cc2)cc1)c1ccc(-c2nc(-c3ccccc3)nc(-c3ccccc3)n2)c(C#N)c1 ; CC(C)(c1ccc(-c2nc(-c3ccccc3)nc(-c3ccccc3)n2)cc1)c1ccc(-c2ccc(C#N)cc2)c(C#N)c1]

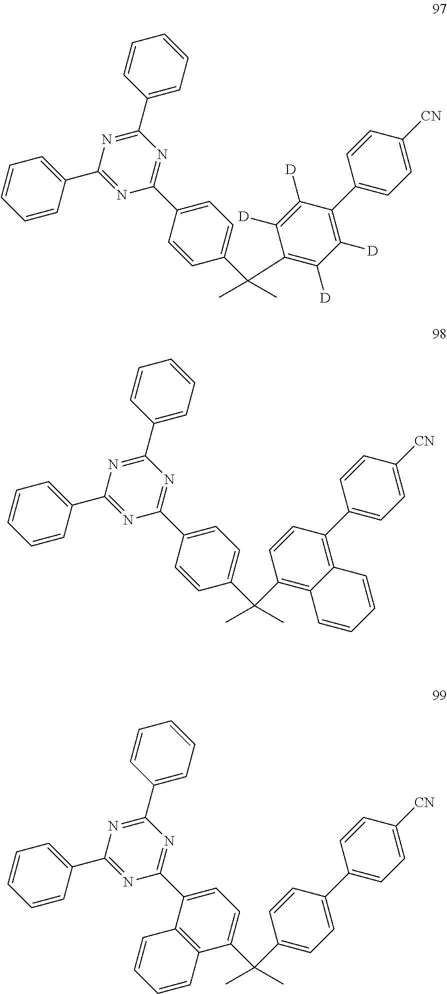 [SMILES: [2H]c1c([2H])c(C(C)(C)c2ccc(-c3nc(-c4ccccc4)nc(-c4ccccc4)n3)cc2)c([2H])c([2H])c1-c1ccc(C#N)cc1 ; CC(C)(c1ccc(-c2nc(-c3ccccc3)nc(-c3ccccc3)n2)cc1)c1ccc(-c2ccc(C#N)cc2)c2ccccc12 ; CC(C)(c1ccc(-c2ccc(C#N)cc2)cc1)c1ccc(-c2nc(-c3ccccc3)nc(-c3ccccc3)n2)c2ccccc12]

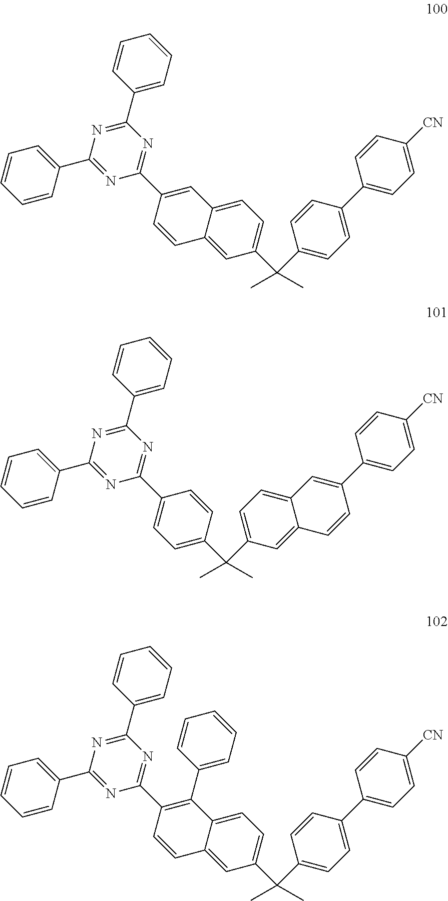 [SMILES: CC(C)(c1ccc(-c2ccc(C#N)cc2)cc1)c1ccc2cc(-c3nc(-c4ccccc4)nc(-c4ccccc4)n3)ccc2c1 ; CC(C)(c1ccc(-c2nc(-c3ccccc3)nc(-c3ccccc3)n2)cc1)c1ccc2cc(-c3ccc(C#N)cc3)ccc2c1 ; CC(C)(c1ccc(-c2ccc(C#N)cc2)cc1)c1ccc2c(-c3ccccc3)c(-c3nc(-c4ccccc4)nc(-c4ccccc4)n3)ccc2c1]

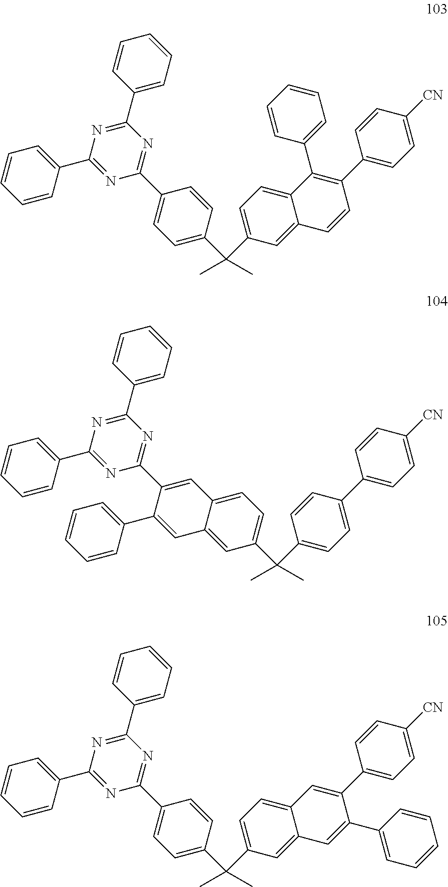 [SMILES: CC(C)(c1ccc(-c2nc(-c3ccccc3)nc(-c3ccccc3)n2)cc1)c1ccc2c(-c3ccccc3)c(-c3ccc(C#N)cc3)ccc2c1 ; CC(C)(c1ccc(-c2ccc(C#N)cc2)cc1)c1ccc2cc(-c3nc(-c4ccccc4)nc(-c4ccccc4)n3)c(-c3ccccc3)cc2c1 ; CC(C)(c1ccc(-c2nc(-c3ccccc3)nc(-c3ccccc3)n2)cc1)c1ccc2cc(-c3ccc(C#N)cc3)c(-c3ccccc3)cc2c1]

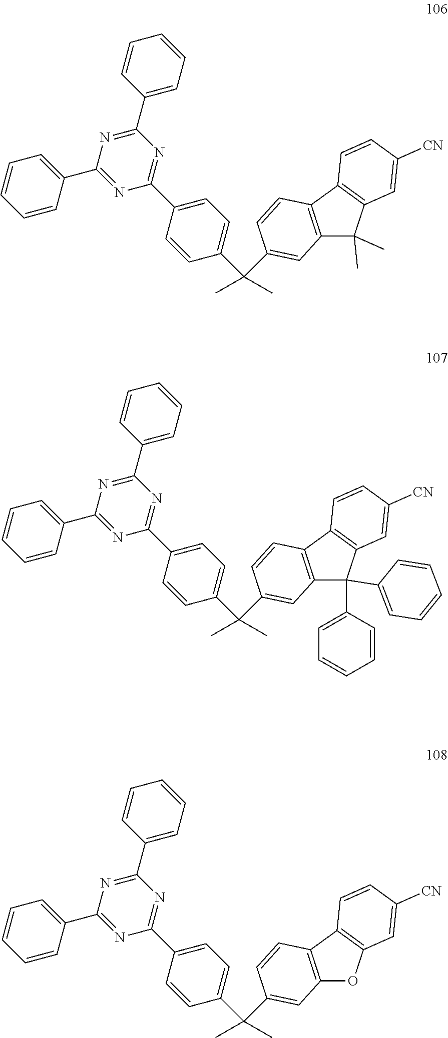 [SMILES: CC(C)(c1ccc(-c2nc(-c3ccccc3)nc(-c3ccccc3)n2)cc1)c1ccc2c(c1)C(C)(C)c1cc(C#N)ccc1-2 ; CC(C)(c1ccc(-c2nc(-c3ccccc3)nc(-c3ccccc3)n2)cc1)c1ccc2c(c1)C(c1ccccc1)(c1ccccc1)c1cc(C#N)ccc1-2 ; CC(C)(c1ccc(-c2nc(-c3ccccc3)nc(-c3ccccc3)n2)cc1)c1ccc2c(c1)oc1cc(C#N)ccc12]

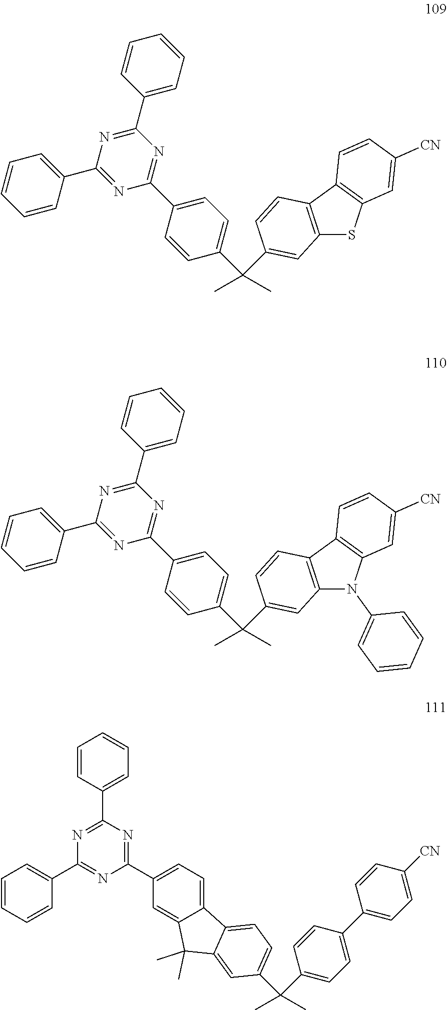 [SMILES: CC(C)(c1ccc(-c2nc(-c3ccccc3)nc(-c3ccccc3)n2)cc1)c1ccc2c(c1)sc1cc(C#N)ccc12 ; CC(C)(c1ccc(-c2nc(-c3ccccc3)nc(-c3ccccc3)n2)cc1)c1ccc2c3ccc(C#N)cc3n(-c3ccccc3)c2c1 ; CC(C)(c1ccc(-c2ccc(C#N)cc2)cc1)c1ccc2c(c1)C(C)(C)c1cc(-c3nc(-c4ccccc4)nc(-c4ccccc4)n3)ccc1-2]

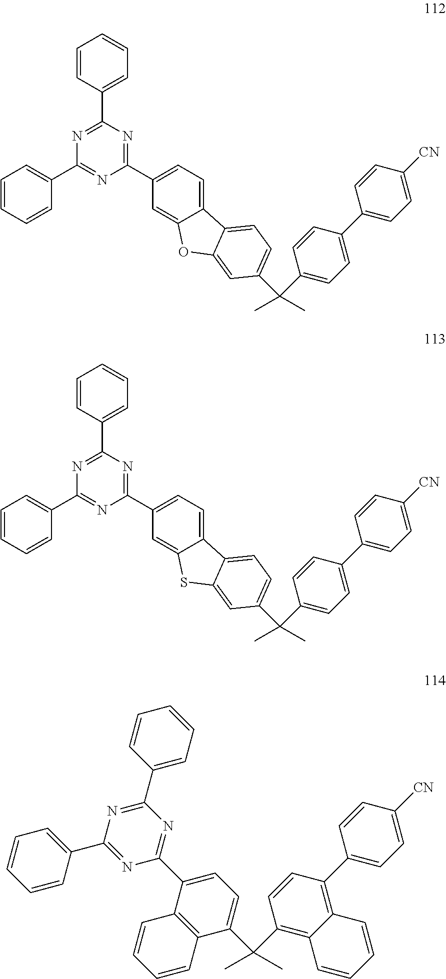 [SMILES: CC(C)(c1ccc(-c2ccc(C#N)cc2)cc1)c1ccc2c(c1)oc1cc(-c3nc(-c4ccccc4)nc(-c4ccccc4)n3)ccc12 ; CC(C)(c1ccc(-c2ccc(C#N)cc2)cc1)c1ccc2c(c1)sc1cc(-c3nc(-c4ccccc4)nc(-c4ccccc4)n3)ccc12 ; CC(C)(c1ccc(-c2ccc(C#N)cc2)c2ccccc12)c1ccc(-c2nc(-c3ccccc3)nc(-c3ccccc3)n2)c2ccccc12]

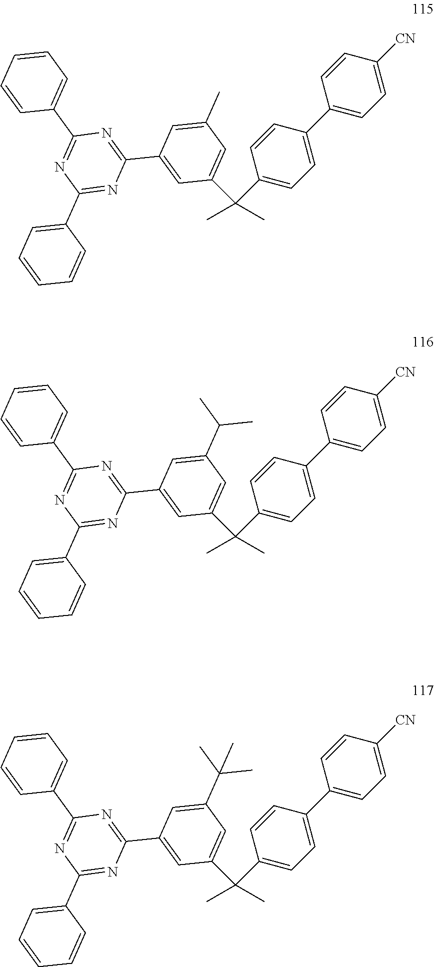 [SMILES: Cc1cc(-c2nc(-c3ccccc3)nc(-c3ccccc3)n2)cc(C(C)(C)c2ccc(-c3ccc(C#N)cc3)cc2)c1 ; CC(C)c1cc(-c2nc(-c3ccccc3)nc(-c3ccccc3)n2)cc(C(C)(C)c2ccc(-c3ccc(C#N)cc3)cc2)c1 ; CC(C)(C)c1cc(-c2nc(-c3ccccc3)nc(-c3ccccc3)n2)cc(C(C)(C)c2ccc(-c3ccc(C#N)cc3)cc2)c1]

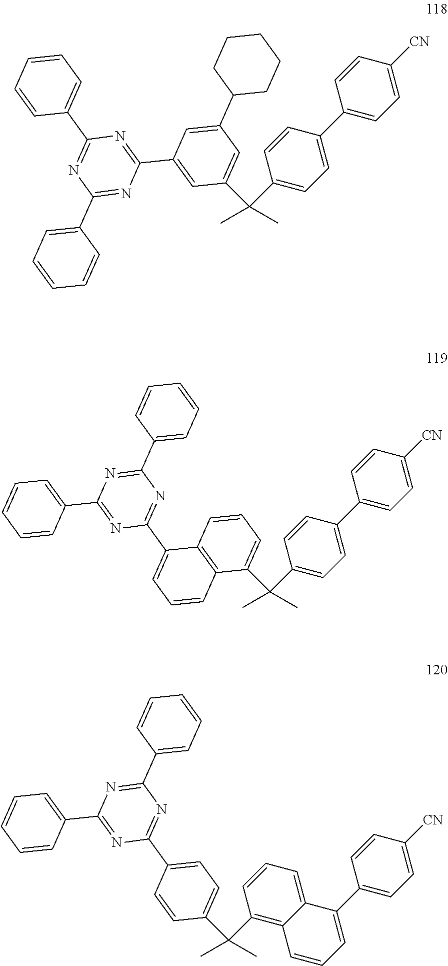 [SMILES: CC(C)(c1ccc(-c2ccc(C#N)cc2)cc1)c1cc(-c2nc(-c3ccccc3)nc(-c3ccccc3)n2)cc(C2CCCCC2)c1 ; CC(C)(c1ccc(-c2ccc(C#N)cc2)cc1)c1cccc2c(-c3nc(-c4ccccc4)nc(-c4ccccc4)n3)cccc12 ; CC(C)(c1ccc(-c2nc(-c3ccccc3)nc(-c3ccccc3)n2)cc1)c1cccc2c(-c3ccc(C#N)cc3)cccc12]

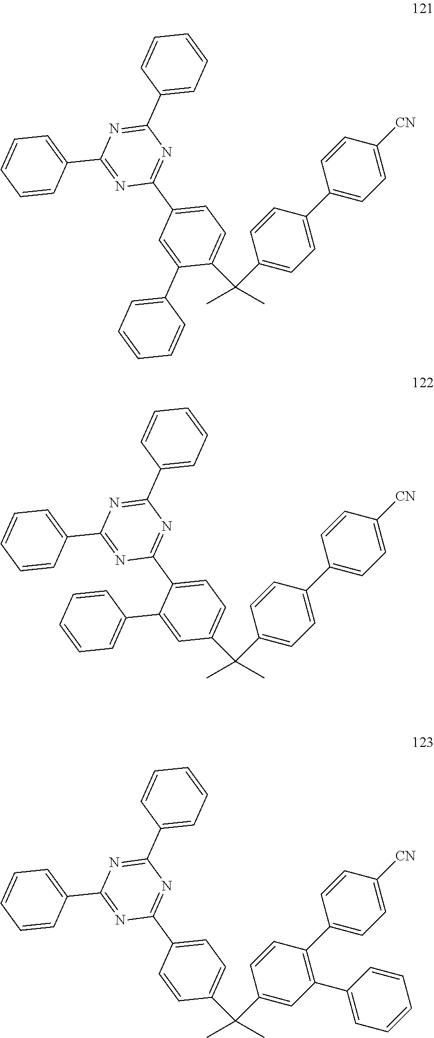 [SMILES: CC(C)(c1ccc(-c2ccc(C#N)cc2)cc1)c1ccc(-c2nc(-c3ccccc3)nc(-c3ccccc3)n2)cc1-c1ccccc1 ; CC(C)(c1ccc(-c2ccc(C#N)cc2)cc1)c1ccc(-c2nc(-c3ccccc3)nc(-c3ccccc3)n2)c(-c2ccccc2)c1 ; CC(C)(c1ccc(-c2nc(-c3ccccc3)nc(-c3ccccc3)n2)cc1)c1ccc(-c2ccc(C#N)cc2)c(-c2ccccc2)c1]

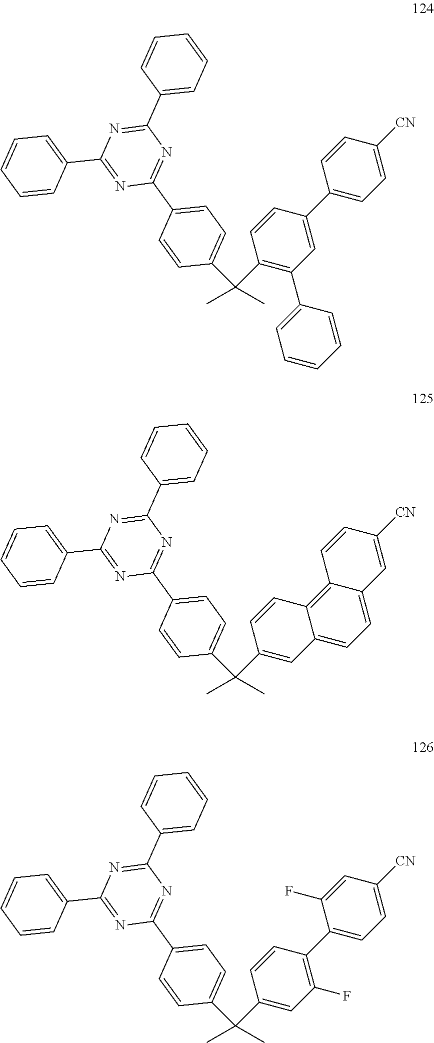 [SMILES: CC(C)(c1ccc(-c2nc(-c3ccccc3)nc(-c3ccccc3)n2)cc1)c1ccc(-c2ccc(C#N)cc2)cc1-c1ccccc1 ; CC(C)(c1ccc(-c2nc(-c3ccccc3)nc(-c3ccccc3)n2)cc1)c1ccc2c(ccc3cc(C#N)ccc32)c1 ; CC(C)(c1ccc(-c2nc(-c3ccccc3)nc(-c3ccccc3)n2)cc1)c1ccc(-c2ccc(C#N)cc2F)c(F)c1]

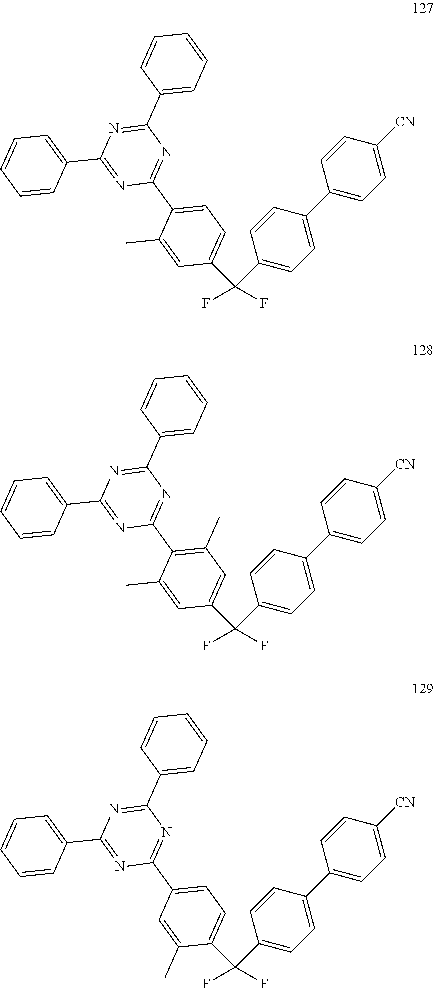 [SMILES: Cc1cc(C(F)(F)c2ccc(-c3ccc(C#N)cc3)cc2)ccc1-c1nc(-c2ccccc2)nc(-c2ccccc2)n1 ; Cc1cc(C(F)(F)c2ccc(-c3ccc(C#N)cc3)cc2)cc(C)c1-c1nc(-c2ccccc2)nc(-c2ccccc2)n1 ; Cc1cc(-c2nc(-c3ccccc3)nc(-c3ccccc3)n2)ccc1C(F)(F)c1ccc(-c2ccc(C#N)cc2)cc1]

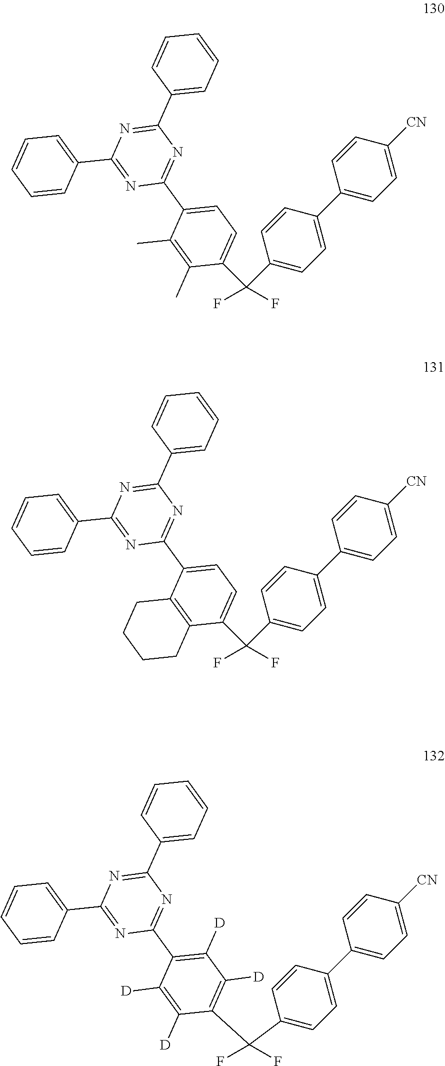 [SMILES: Cc1c(-c2nc(-c3ccccc3)nc(-c3ccccc3)n2)ccc(C(F)(F)c2ccc(-c3ccc(C#N)cc3)cc2)c1C ; N#Cc1ccc(-c2ccc(C(F)(F)c3ccc(-c4nc(-c5ccccc5)nc(-c5ccccc5)n4)c4c3CCCC4)cc2)cc1 ; [2H]c1c([2H])c(C(F)(F)c2ccc(-c3ccc(C#N)cc3)cc2)c([2H])c([2H])c1-c1nc(-c2ccccc2)nc(-c2ccccc2)n1]

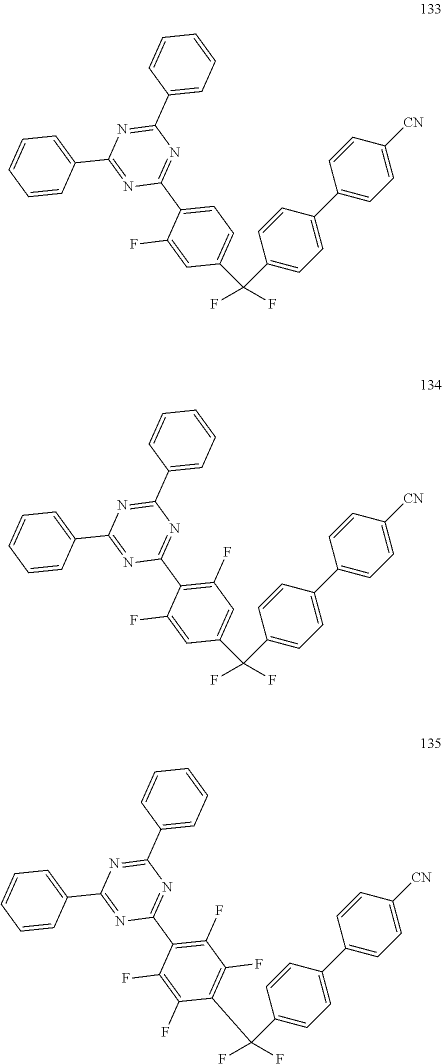 [SMILES: N#Cc1ccc(-c2ccc(C(F)(F)c3ccc(-c4nc(-c5ccccc5)nc(-c5ccccc5)n4)c(F)c3)cc2)cc1 ; N#Cc1ccc(-c2ccc(C(F)(F)c3cc(F)c(-c4nc(-c5ccccc5)nc(-c5ccccc5)n4)c(F)c3)cc2)cc1 ; N#Cc1ccc(-c2ccc(C(F)(F)c3c(F)c(F)c(-c4nc(-c5ccccc5)nc(-c5ccccc5)n4)c(F)c3F)cc2)cc1]

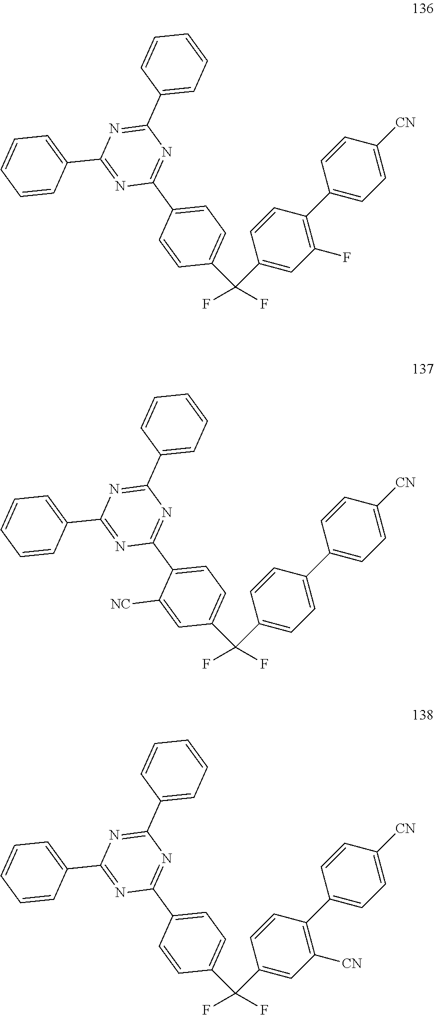 [SMILES: N#Cc1ccc(-c2ccc(C(F)(F)c3ccc(-c4nc(-c5ccccc5)nc(-c5ccccc5)n4)cc3)cc2F)cc1 ; N#Cc1ccc(-c2ccc(C(F)(F)c3ccc(-c4nc(-c5ccccc5)nc(-c5ccccc5)n4)c(C#N)c3)cc2)cc1 ; N#Cc1ccc(-c2ccc(C(F)(F)c3ccc(-c4nc(-c5ccccc5)nc(-c5ccccc5)n4)cc3)cc2C#N)cc1]

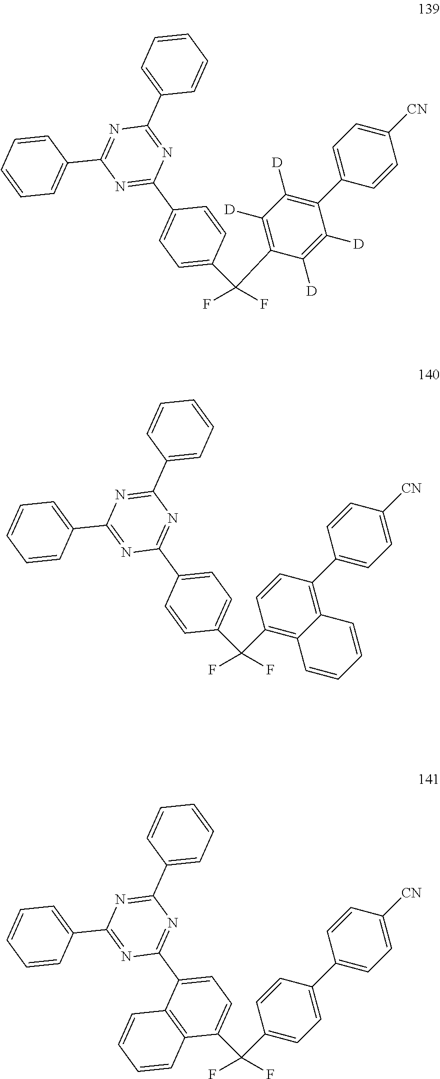 [SMILES: [2H]c1c([2H])c(C(F)(F)c2ccc(-c3nc(-c4ccccc4)nc(-c4ccccc4)n3)cc2)c([2H])c([2H])c1-c1ccc(C#N)cc1 ; N#Cc1ccc(-c2ccc(C(F)(F)c3ccc(-c4nc(-c5ccccc5)nc(-c5ccccc5)n4)cc3)c3ccccc23)cc1 ; N#Cc1ccc(-c2ccc(C(F)(F)c3ccc(-c4nc(-c5ccccc5)nc(-c5ccccc5)n4)c4ccccc34)cc2)cc1]

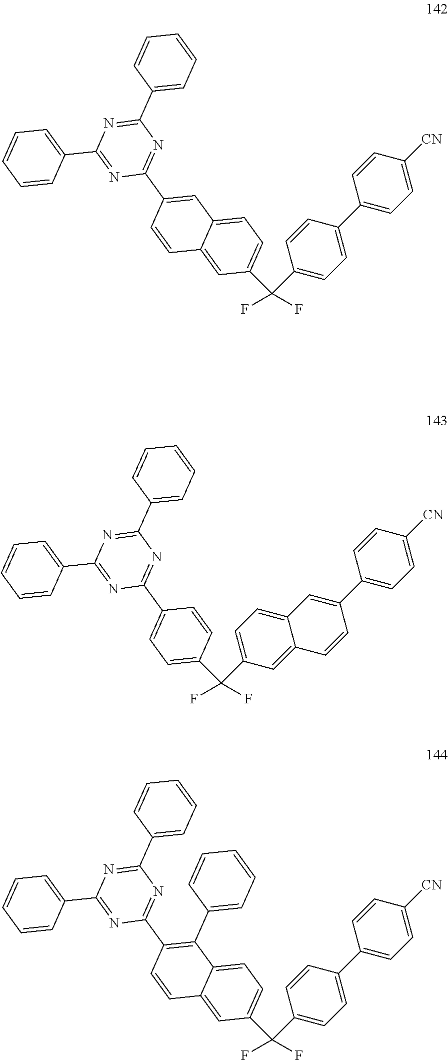 [SMILES: N#Cc1ccc(-c2ccc(C(F)(F)c3ccc4cc(-c5nc(-c6ccccc6)nc(-c6ccccc6)n5)ccc4c3)cc2)cc1 ; N#Cc1ccc(-c2ccc3cc(C(F)(F)c4ccc(-c5nc(-c6ccccc6)nc(-c6ccccc6)n5)cc4)ccc3c2)cc1 ; N#Cc1ccc(-c2ccc(C(F)(F)c3ccc4c(-c5ccccc5)c(-c5nc(-c6ccccc6)nc(-c6ccccc6)n5)ccc4c3)cc2)cc1]

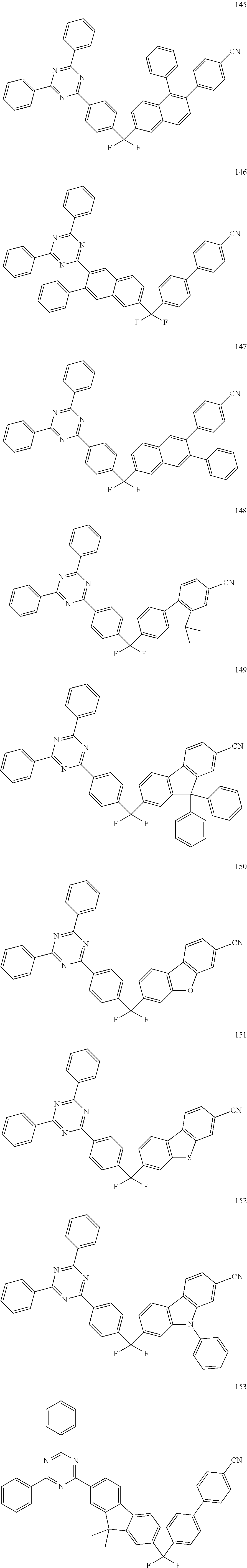

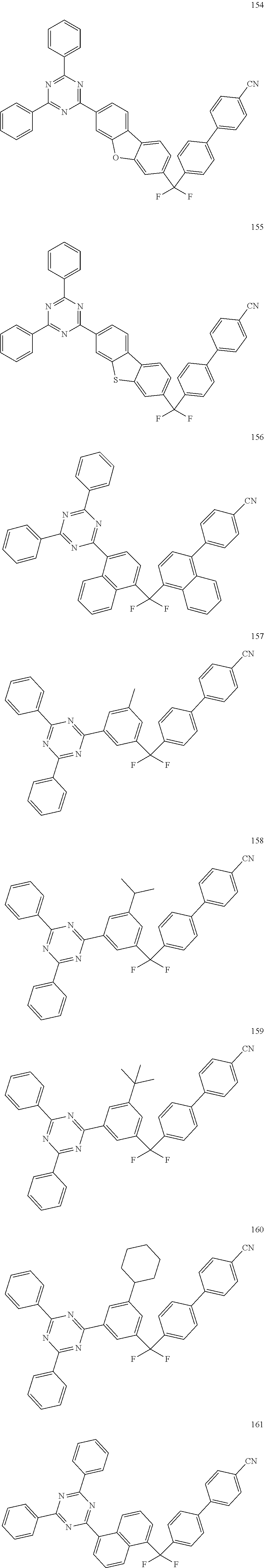

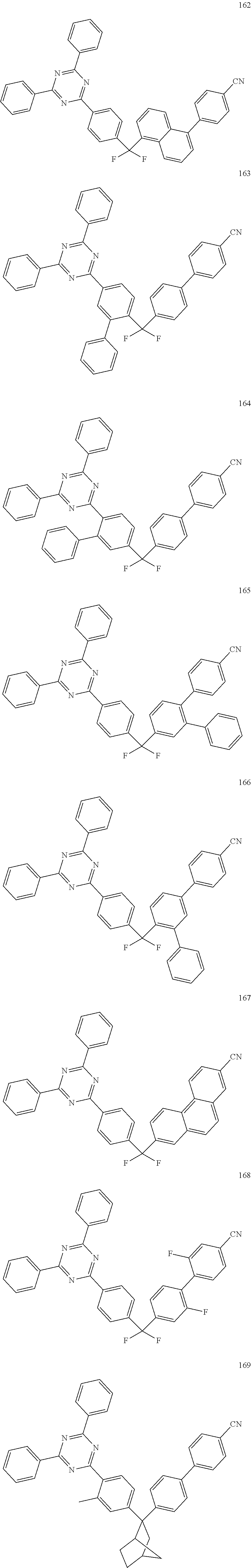

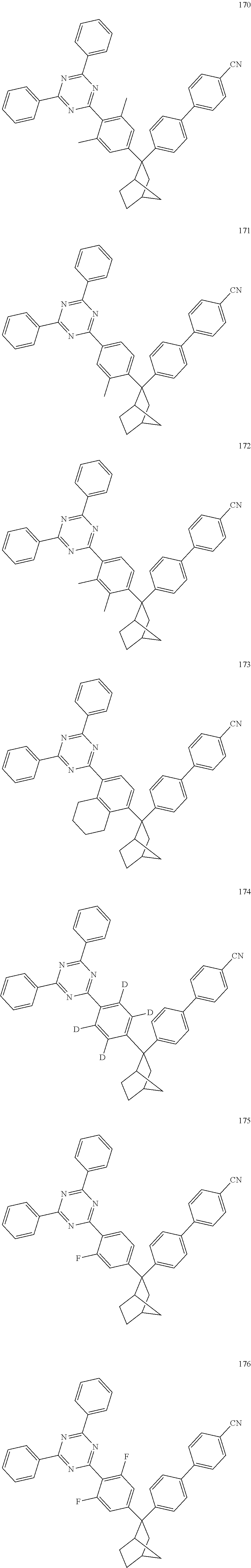

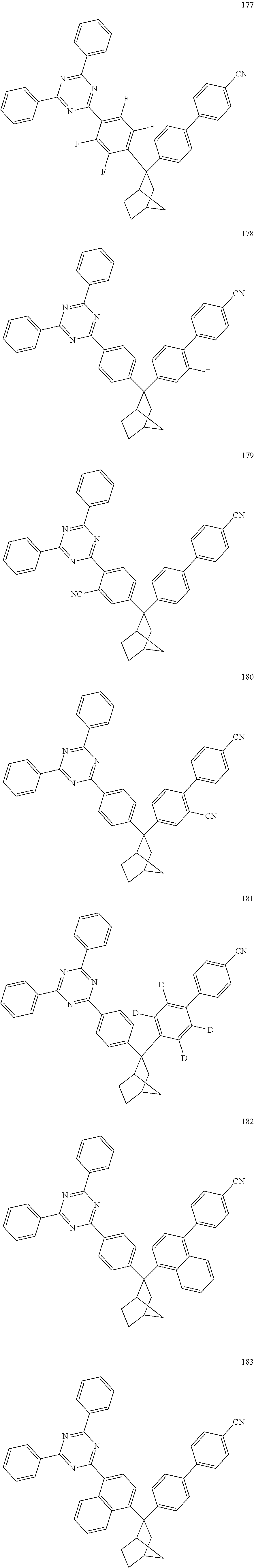

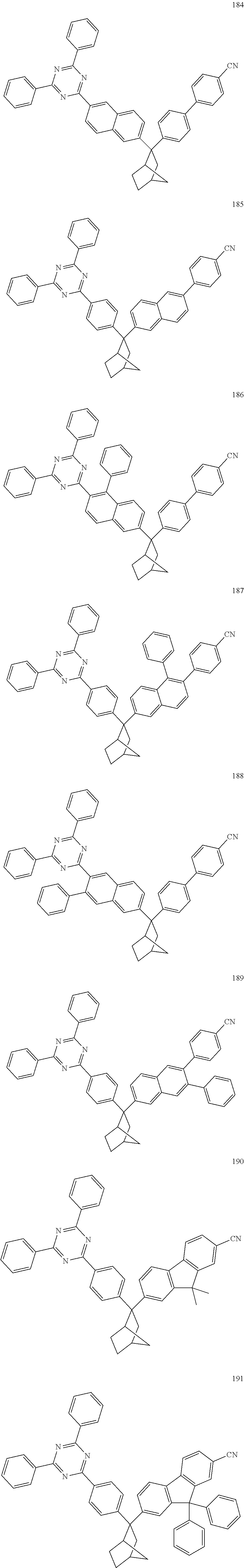

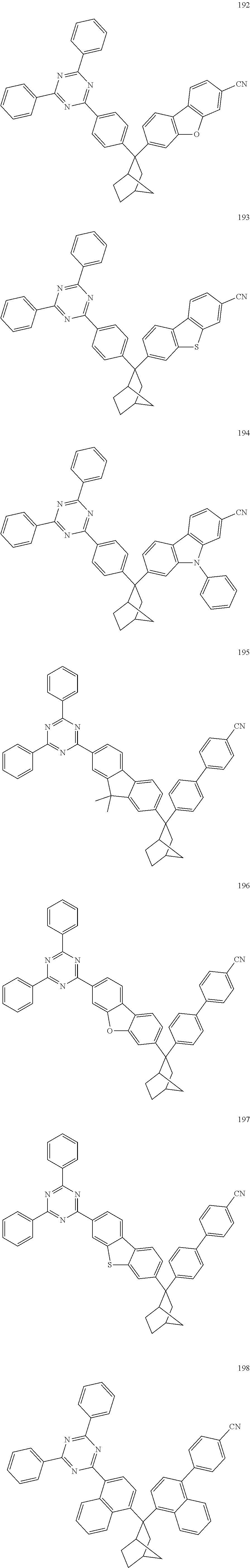

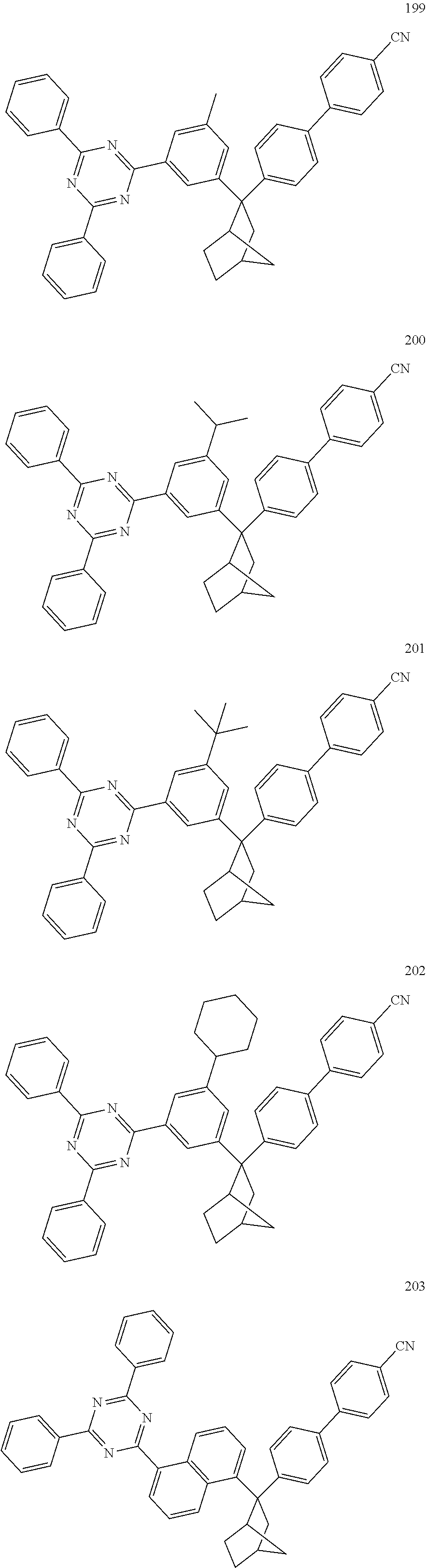 [SMILES: Cc1cc(-c2nc(-c3ccccc3)nc(-c3ccccc3)n2)cc(C2(c3ccc(-c4ccc(C#N)cc4)cc3)CC3CCC2C3)c1 ; CC(C)c1cc(-c2nc(-c3ccccc3)nc(-c3ccccc3)n2)cc(C2(c3ccc(-c4ccc(C#N)cc4)cc3)CC3CCC2C3)c1 ; CC(C)(C)c1cc(-c2nc(-c3ccccc3)nc(-c3ccccc3)n2)cc(C2(c3ccc(-c4ccc(C#N)cc4)cc3)CC3CCC2C3)c1 ; N#Cc1ccc(-c2ccc(C3(c4cc(-c5nc(-c6ccccc6)nc(-c6ccccc6)n5)cc(C5CCCCC5)c4)CC4CCC3C4)cc2)cc1 ; N#Cc1ccc(-c2ccc(C3(c4cccc5c(-c6nc(-c7ccccc7)nc(-c7ccccc7)n6)cccc45)CC4CCC3C4)cc2)cc1]

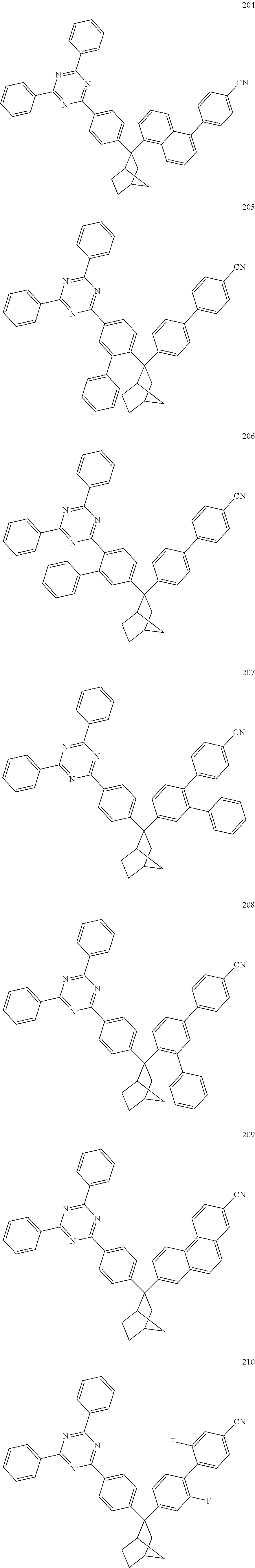

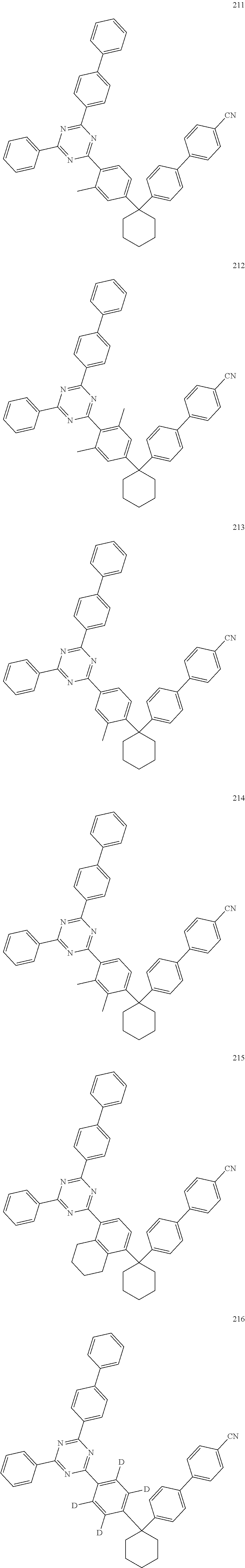

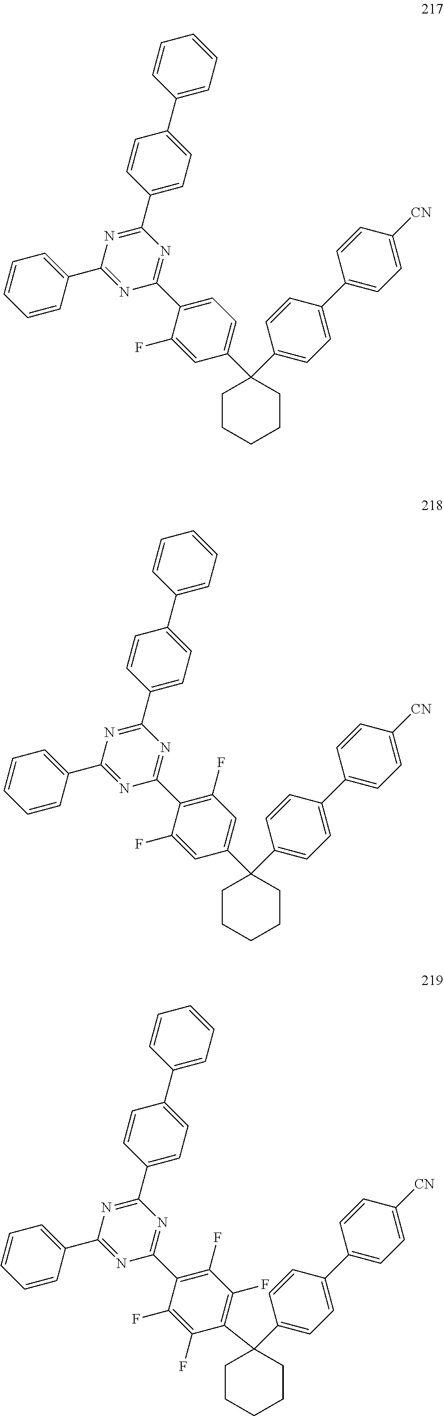 [SMILES: N#Cc1ccc(-c2ccc(C3(c4ccc(-c5nc(-c6ccccc6)nc(-c6ccc(-c7ccccc7)cc6)n5)c(F)c4)CCCCC3)cc2)cc1 ; N#Cc1ccc(-c2ccc(C3(c4cc(F)c(-c5nc(-c6ccccc6)nc(-c6ccc(-c7ccccc7)cc6)n5)c(F)c4)CCCCC3)cc2)cc1 ; N#Cc1ccc(-c2ccc(C3(c4c(F)c(F)c(-c5nc(-c6ccccc6)nc(-c6ccc(-c7ccccc7)cc6)n5)c(F)c4F)CCCCC3)cc2)cc1]

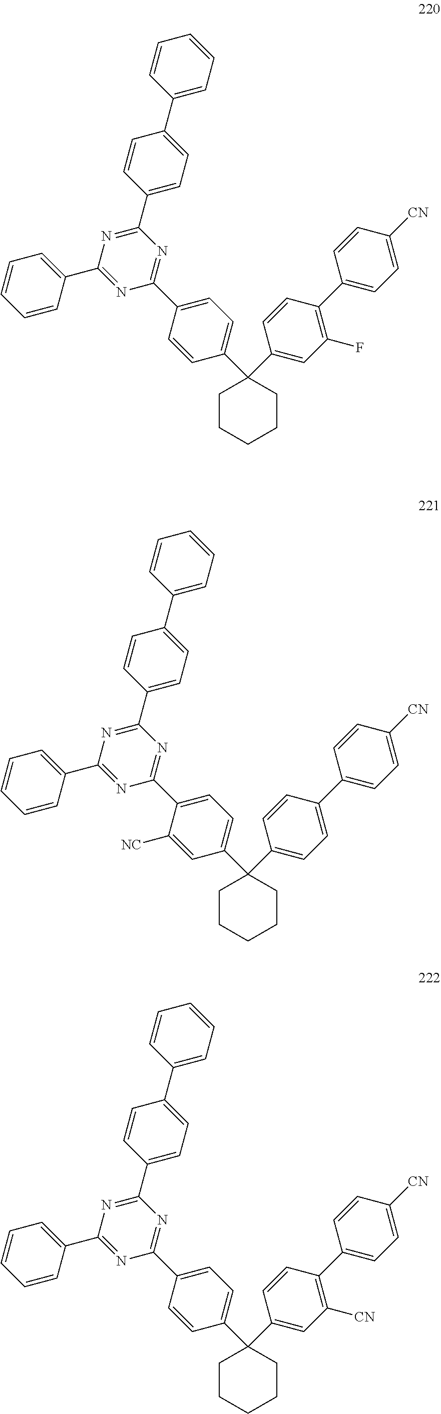 [SMILES: N#Cc1ccc(-c2ccc(C3(c4ccc(-c5nc(-c6ccccc6)nc(-c6ccc(-c7ccccc7)cc6)n5)cc4)CCCCC3)cc2F)cc1 ; N#Cc1ccc(-c2ccc(C3(c4ccc(-c5nc(-c6ccccc6)nc(-c6ccc(-c7ccccc7)cc6)n5)c(C#N)c4)CCCCC3)cc2)cc1 ; N#Cc1ccc(-c2ccc(C3(c4ccc(-c5nc(-c6ccccc6)nc(-c6ccc(-c7ccccc7)cc6)n5)cc4)CCCCC3)cc2C#N)cc1]

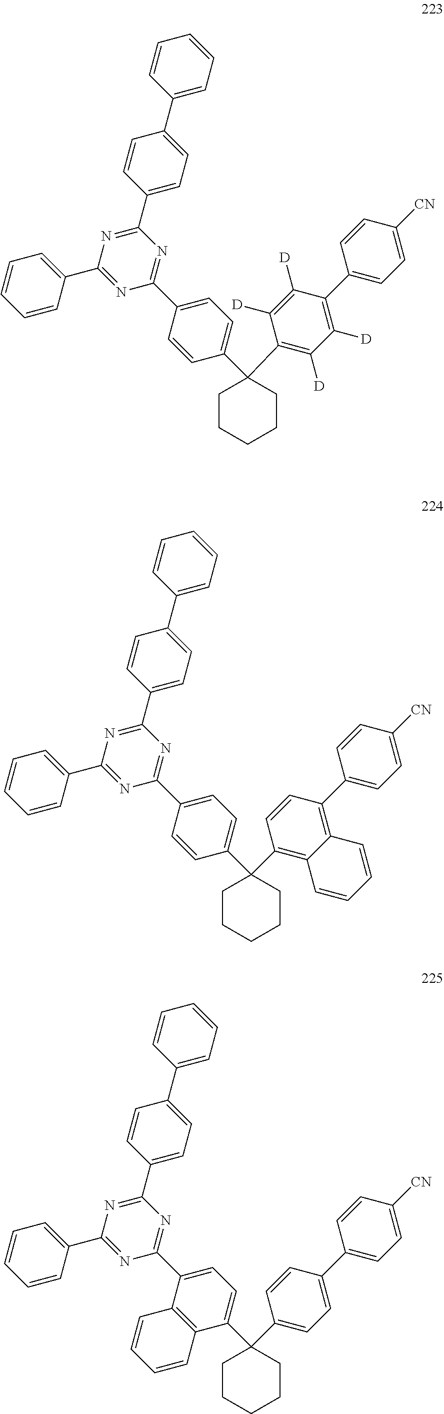 [SMILES: [2H]c1c([2H])c(C2(c3ccc(-c4nc(-c5ccccc5)nc(-c5ccc(-c6ccccc6)cc5)n4)cc3)CCCCC2)c([2H])c([2H])c1-c1ccc(C#N)cc1 ; N#Cc1ccc(-c2ccc(C3(c4ccc(-c5nc(-c6ccccc6)nc(-c6ccc(-c7ccccc7)cc6)n5)cc4)CCCCC3)c3ccccc23)cc1 ; N#Cc1ccc(-c2ccc(C3(c4ccc(-c5nc(-c6ccccc6)nc(-c6ccc(-c7ccccc7)cc6)n5)c5ccccc45)CCCCC3)cc2)cc1]

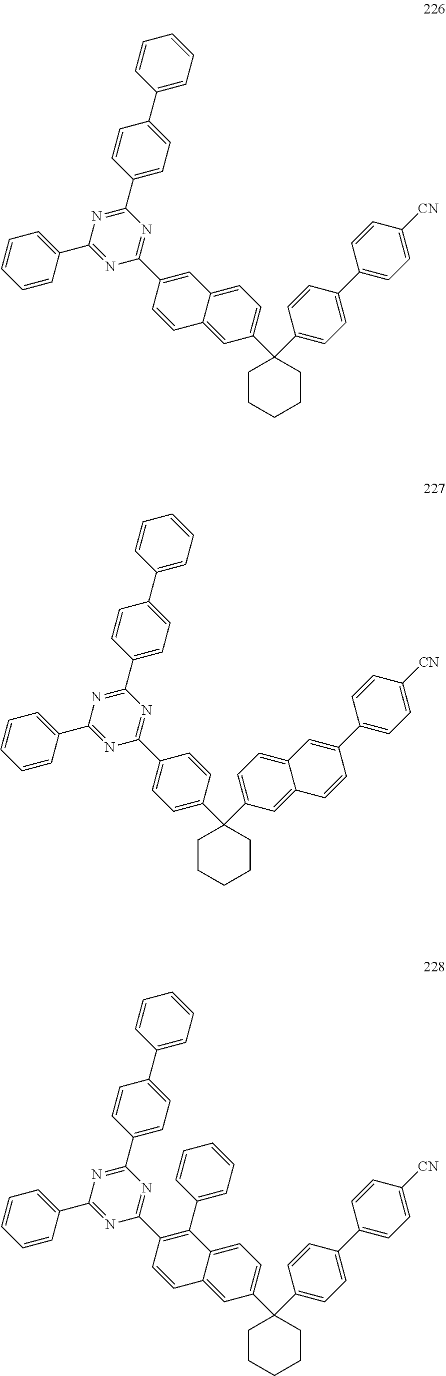 [SMILES: N#Cc1ccc(-c2ccc(C3(c4ccc5cc(-c6nc(-c7ccccc7)nc(-c7ccc(-c8ccccc8)cc7)n6)ccc5c4)CCCCC3)cc2)cc1 ; N#Cc1ccc(-c2ccc3cc(C4(c5ccc(-c6nc(-c7ccccc7)nc(-c7ccc(-c8ccccc8)cc7)n6)cc5)CCCCC4)ccc3c2)cc1 ; N#Cc1ccc(-c2ccc(C3(c4ccc5c(-c6ccccc6)c(-c6nc(-c7ccccc7)nc(-c7ccc(-c8ccccc8)cc7)n6)ccc5c4)CCCCC3)cc2)cc1]

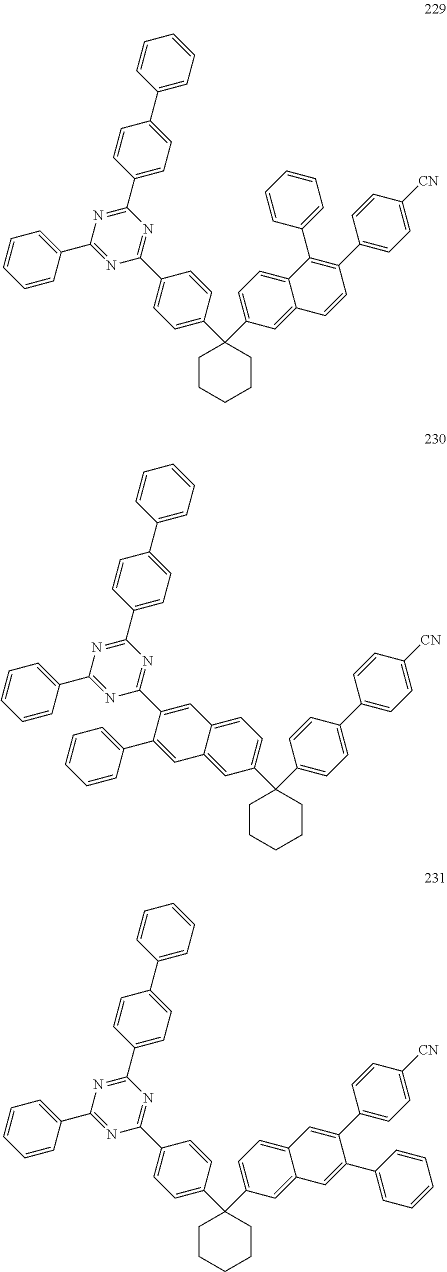 [SMILES: N#Cc1ccc(-c2ccc3cc(C4(c5ccc(-c6nc(-c7ccccc7)nc(-c7ccc(-c8ccccc8)cc7)n6)cc5)CCCCC4)ccc3c2-c2ccccc2)cc1 ; N#Cc1ccc(-c2ccc(C3(c4ccc5cc(-c6nc(-c7ccccc7)nc(-c7ccc(-c8ccccc8)cc7)n6)c(-c6ccccc6)cc5c4)CCCCC3)cc2)cc1 ; N#Cc1ccc(-c2cc3ccc(C4(c5ccc(-c6nc(-c7ccccc7)nc(-c7ccc(-c8ccccc8)cc7)n6)cc5)CCCCC4)cc3cc2-c2ccccc2)cc1]

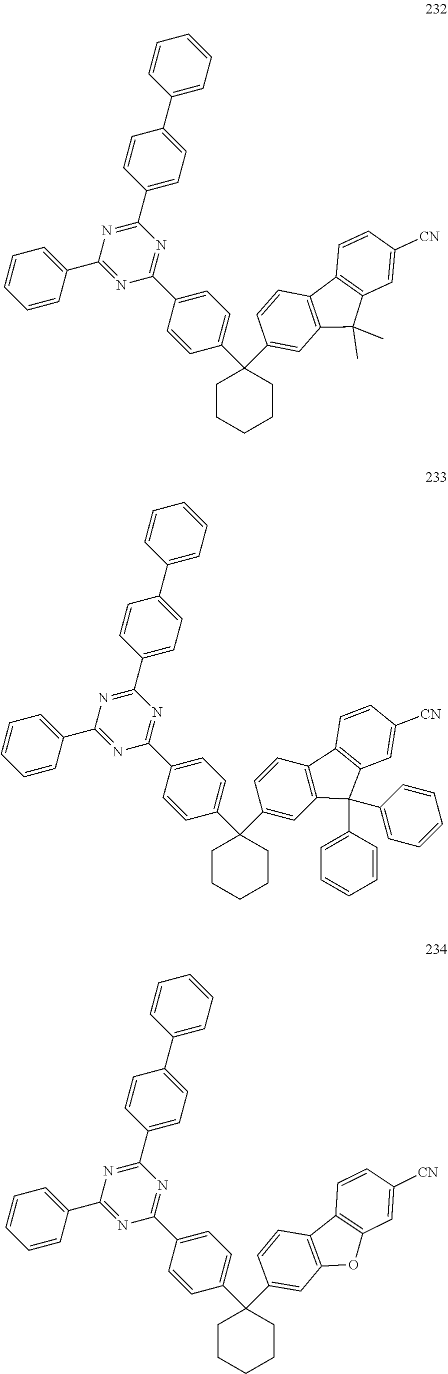 [SMILES: CC1(C)c2cc(C#N)ccc2-c2ccc(C3(c4ccc(-c5nc(-c6ccccc6)nc(-c6ccc(-c7ccccc7)cc6)n5)cc4)CCCCC3)cc21 ; N#Cc1ccc2c(c1)C(c1ccccc1)(c1ccccc1)c1cc(C3(c4ccc(-c5nc(-c6ccccc6)nc(-c6ccc(-c7ccccc7)cc6)n5)cc4)CCCCC3)ccc1-2 ; N#Cc1ccc2c(c1)oc1cc(C3(c4ccc(-c5nc(-c6ccccc6)nc(-c6ccc(-c7ccccc7)cc6)n5)cc4)CCCCC3)ccc12]

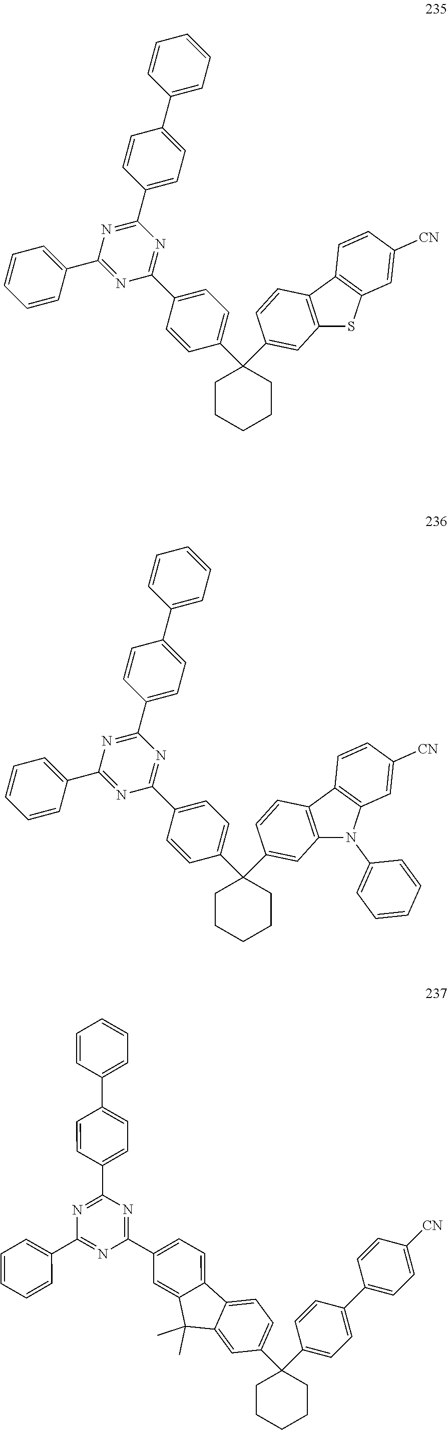 [SMILES: N#Cc1ccc2c(c1)sc1cc(C3(c4ccc(-c5nc(-c6ccccc6)nc(-c6ccc(-c7ccccc7)cc6)n5)cc4)CCCCC3)ccc12 ; N#Cc1ccc2c3ccc(C4(c5ccc(-c6nc(-c7ccccc7)nc(-c7ccc(-c8ccccc8)cc7)n6)cc5)CCCCC4)cc3n(-c3ccccc3)c2c1 ; CC1(C)c2cc(-c3nc(-c4ccccc4)nc(-c4ccc(-c5ccccc5)cc4)n3)ccc2-c2ccc(C3(c4ccc(-c5ccc(C#N)cc5)cc4)CCCCC3)cc21]

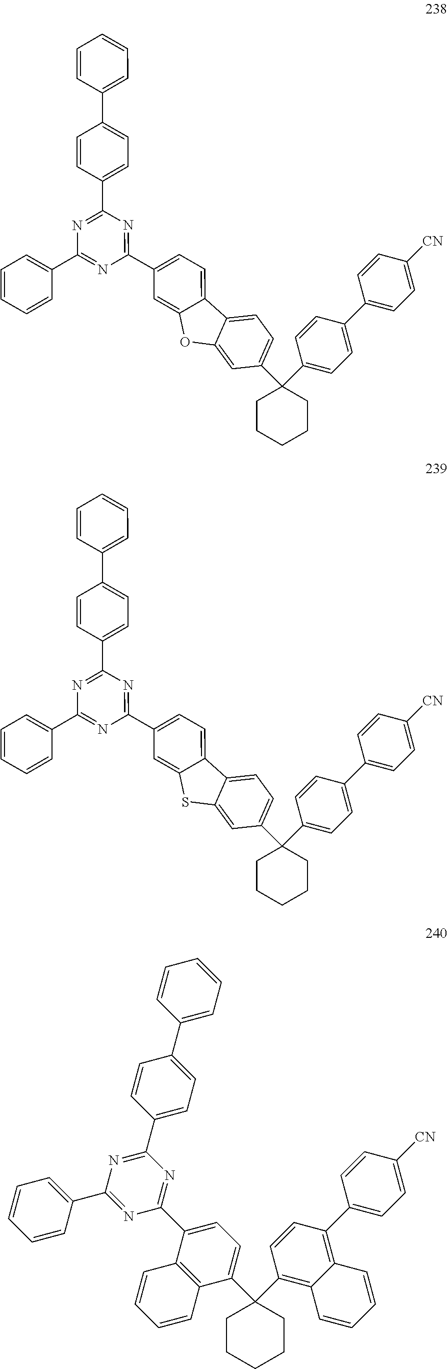 [SMILES: N#Cc1ccc(-c2ccc(C3(c4ccc5c(c4)oc4cc(-c6nc(-c7ccccc7)nc(-c7ccc(-c8ccccc8)cc7)n6)ccc45)CCCCC3)cc2)cc1 ; N#Cc1ccc(-c2ccc(C3(c4ccc5c(c4)sc4cc(-c6nc(-c7ccccc7)nc(-c7ccc(-c8ccccc8)cc7)n6)ccc45)CCCCC3)cc2)cc1 ; N#Cc1ccc(-c2ccc(C3(c4ccc(-c5nc(-c6ccccc6)nc(-c6ccc(-c7ccccc7)cc6)n5)c5ccccc45)CCCCC3)c3ccccc23)cc1]

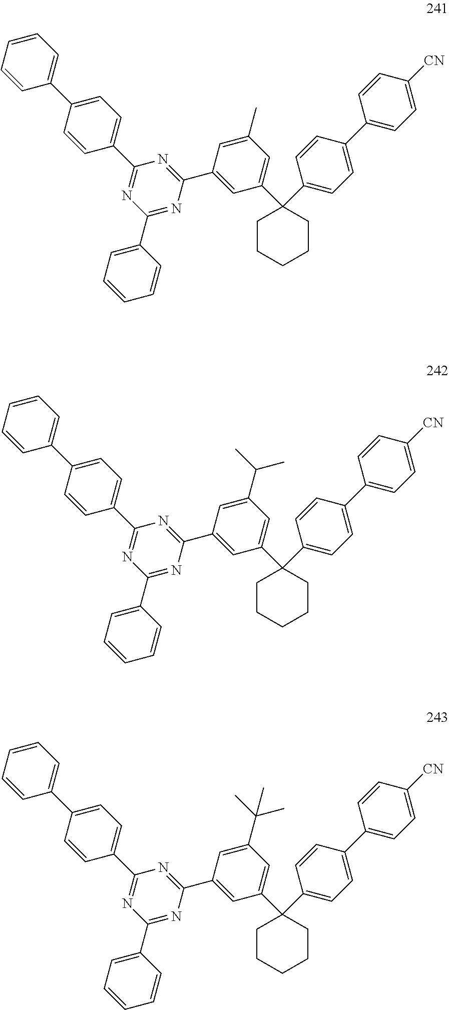 [SMILES: Cc1cc(-c2nc(-c3ccccc3)nc(-c3ccc(-c4ccccc4)cc3)n2)cc(C2(c3ccc(-c4ccc(C#N)cc4)cc3)CCCCC2)c1 ; CC(C)c1cc(-c2nc(-c3ccccc3)nc(-c3ccc(-c4ccccc4)cc3)n2)cc(C2(c3ccc(-c4ccc(C#N)cc4)cc3)CCCCC2)c1 ; CC(C)(C)c1cc(-c2nc(-c3ccccc3)nc(-c3ccc(-c4ccccc4)cc3)n2)cc(C2(c3ccc(-c4ccc(C#N)cc4)cc3)CCCCC2)c1]

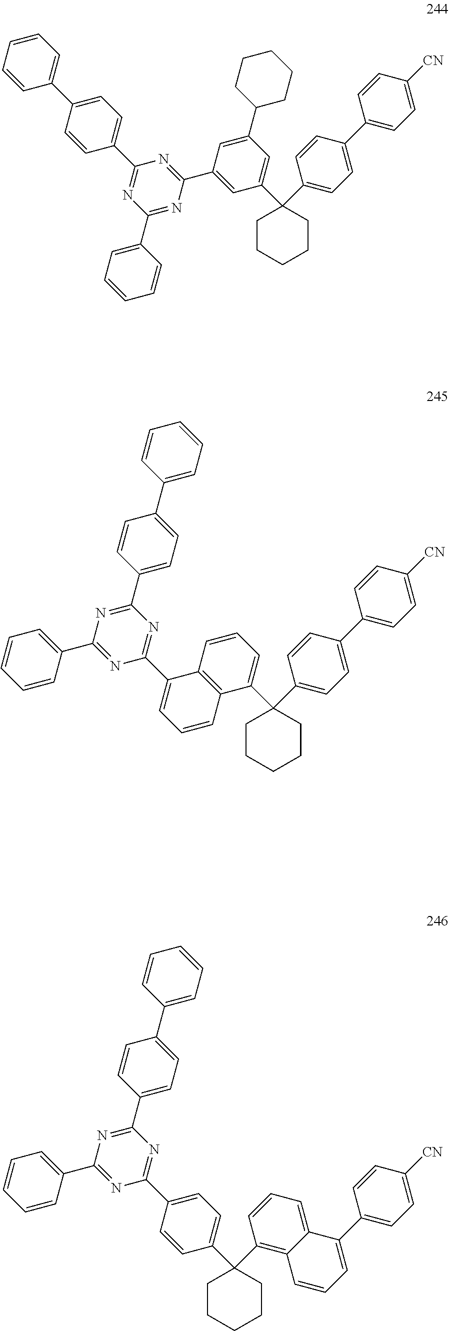 [SMILES: N#Cc1ccc(-c2ccc(C3(c4cc(-c5nc(-c6ccccc6)nc(-c6ccc(-c7ccccc7)cc6)n5)cc(C5CCCCC5)c4)CCCCC3)cc2)cc1 ; N#Cc1ccc(-c2ccc(C3(c4cccc5c(-c6nc(-c7ccccc7)nc(-c7ccc(-c8ccccc8)cc7)n6)cccc45)CCCCC3)cc2)cc1 ; N#Cc1ccc(-c2cccc3c(C4(c5ccc(-c6nc(-c7ccccc7)nc(-c7ccc(-c8ccccc8)cc7)n6)cc5)CCCCC4)cccc23)cc1]

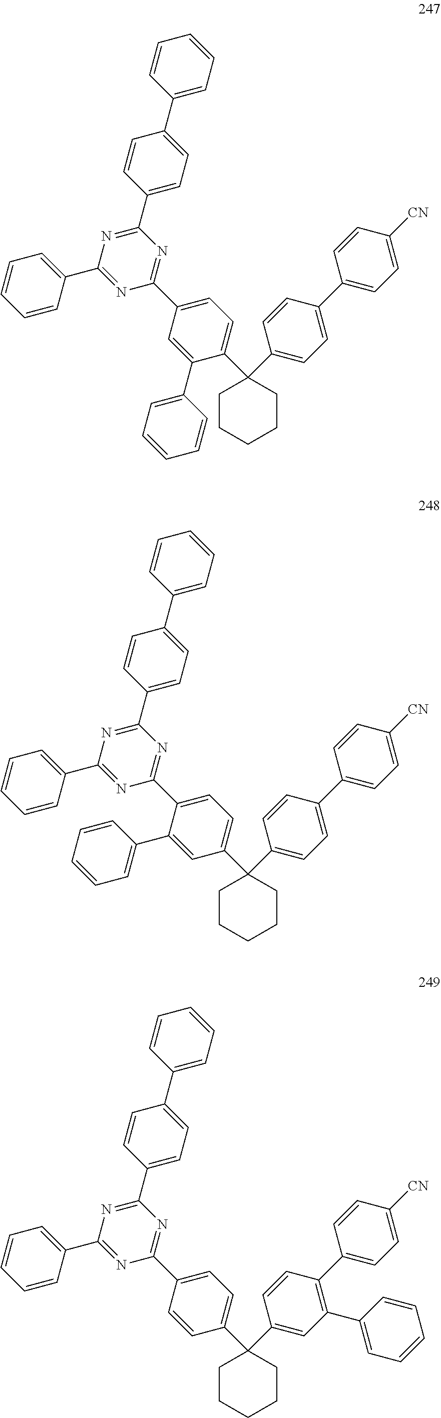 [SMILES: N#Cc1ccc(-c2ccc(C3(c4ccc(-c5nc(-c6ccccc6)nc(-c6ccc(-c7ccccc7)cc6)n5)cc4-c4ccccc4)CCCCC3)cc2)cc1 ; N#Cc1ccc(-c2ccc(C3(c4ccc(-c5nc(-c6ccccc6)nc(-c6ccc(-c7ccccc7)cc6)n5)c(-c5ccccc5)c4)CCCCC3)cc2)cc1 ; N#Cc1ccc(-c2ccc(C3(c4ccc(-c5nc(-c6ccccc6)nc(-c6ccc(-c7ccccc7)cc6)n5)cc4)CCCCC3)cc2-c2ccccc2)cc1]

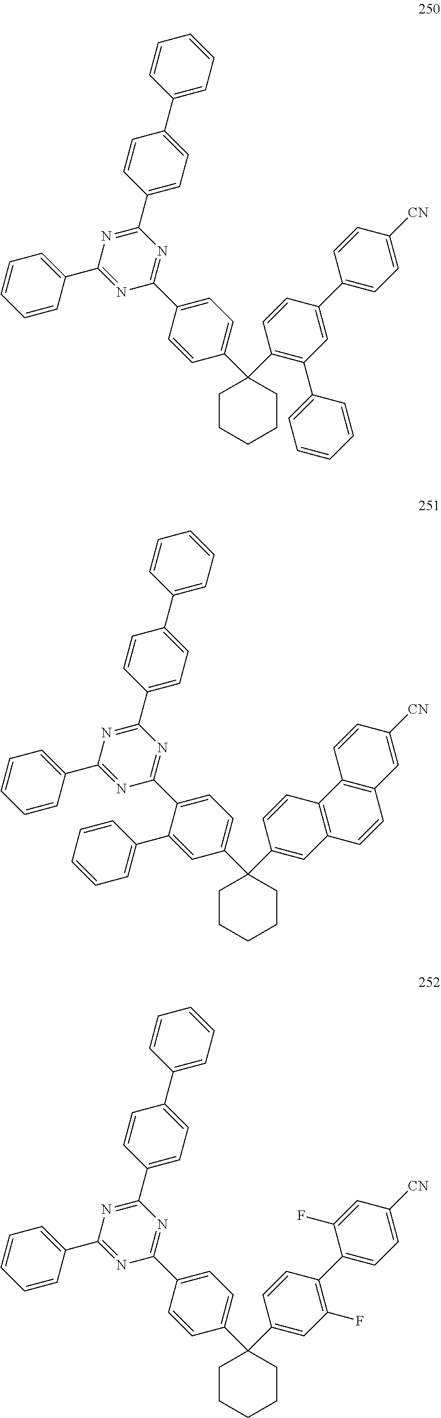 [SMILES: N#Cc1ccc(-c2ccc(C3(c4ccc(-c5nc(-c6ccccc6)nc(-c6ccc(-c7ccccc7)cc6)n5)cc4)CCCCC3)c(-c3ccccc3)c2)cc1 ; N#Cc1ccc2c(ccc3cc(C4(c5ccc(-c6nc(-c7ccccc7)nc(-c7ccc(-c8ccccc8)cc7)n6)c(-c6ccccc6)c5)CCCCC4)ccc32)c1 ; N#Cc1ccc(-c2ccc(C3(c4ccc(-c5nc(-c6ccccc6)nc(-c6ccc(-c7ccccc7)cc6)n5)cc4)CCCCC3)cc2F)c(F)c1]

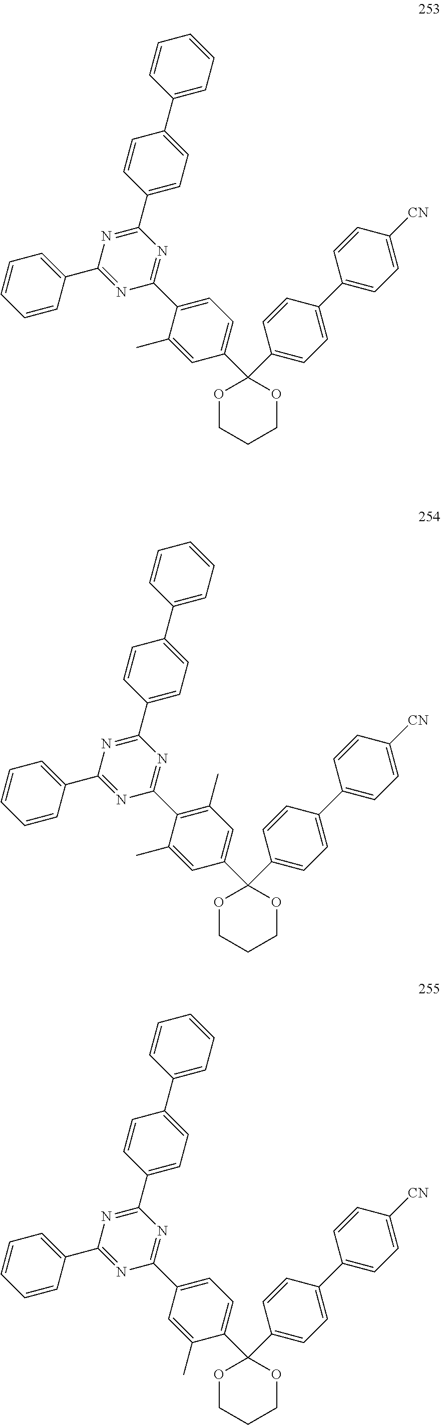 [SMILES: Cc1cc(C2(c3ccc(-c4ccc(C#N)cc4)cc3)OCCCO2)ccc1-c1nc(-c2ccccc2)nc(-c2ccc(-c3ccccc3)cc2)n1 ; Cc1cc(C2(c3ccc(-c4ccc(C#N)cc4)cc3)OCCCO2)cc(C)c1-c1nc(-c2ccccc2)nc(-c2ccc(-c3ccccc3)cc2)n1 ; Cc1cc(-c2nc(-c3ccccc3)nc(-c3ccc(-c4ccccc4)cc3)n2)ccc1C1(c2ccc(-c3ccc(C#N)cc3)cc2)OCCCO1]

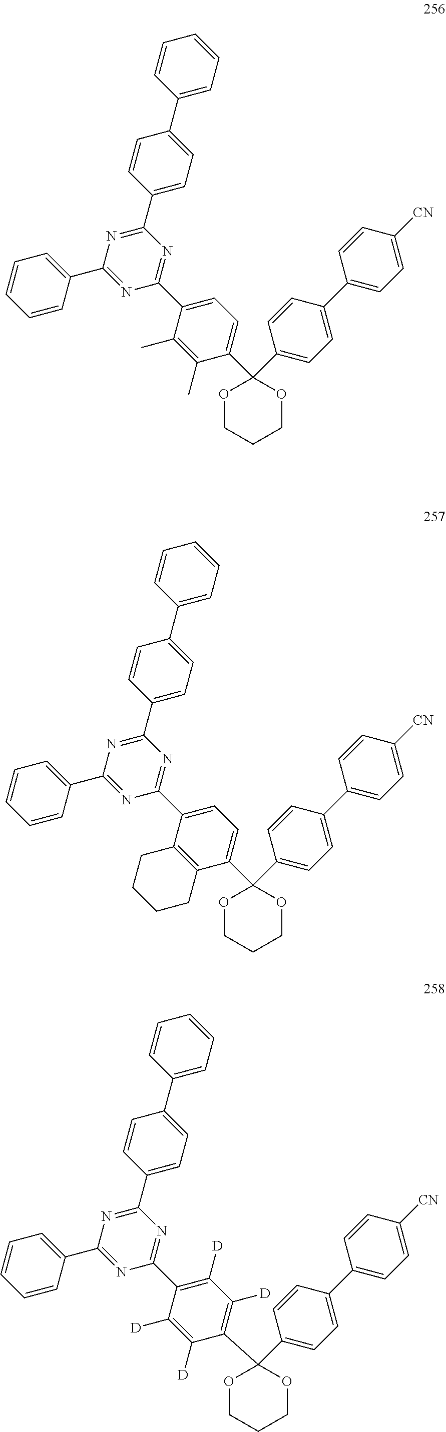 [SMILES: Cc1c(-c2nc(-c3ccccc3)nc(-c3ccc(-c4ccccc4)cc3)n2)ccc(C2(c3ccc(-c4ccc(C#N)cc4)cc3)OCCCO2)c1C ; N#Cc1ccc(-c2ccc(C3(c4ccc(-c5nc(-c6ccccc6)nc(-c6ccc(-c7ccccc7)cc6)n5)c5c4CCCC5)OCCCO3)cc2)cc1 ; [2H]c1c([2H])c(C2(c3ccc(-c4ccc(C#N)cc4)cc3)OCCCO2)c([2H])c([2H])c1-c1nc(-c2ccccc2)nc(-c2ccc(-c3ccccc3)cc2)n1]

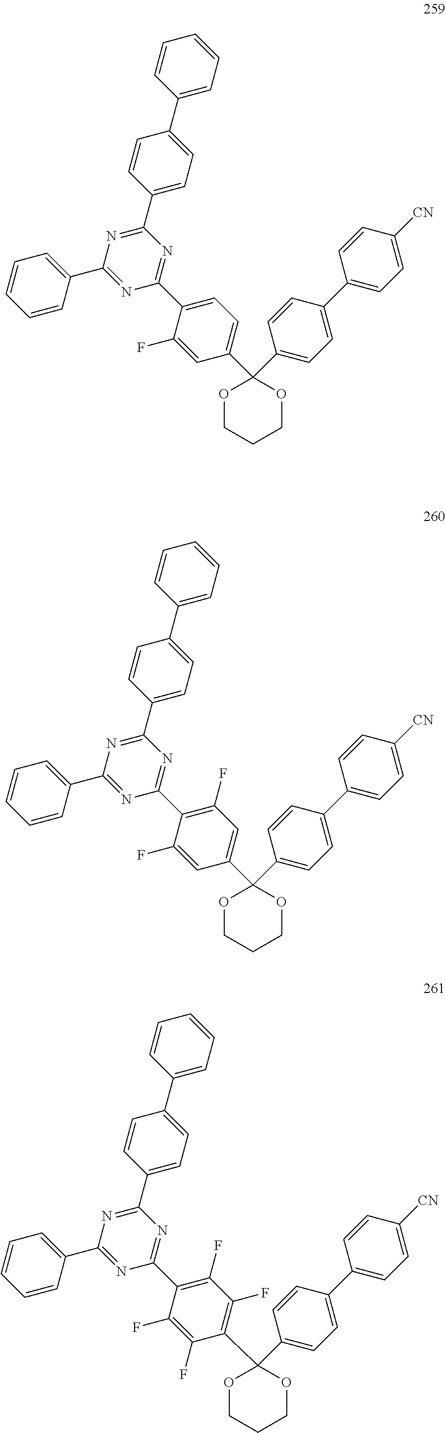 [SMILES: N#Cc1ccc(-c2ccc(C3(c4ccc(-c5nc(-c6ccccc6)nc(-c6ccc(-c7ccccc7)cc6)n5)c(F)c4)OCCCO3)cc2)cc1 ; N#Cc1ccc(-c2ccc(C3(c4cc(F)c(-c5nc(-c6ccccc6)nc(-c6ccc(-c7ccccc7)cc6)n5)c(F)c4)OCCCO3)cc2)cc1 ; N#Cc1ccc(-c2ccc(C3(c4c(F)c(F)c(-c5nc(-c6ccccc6)nc(-c6ccc(-c7ccccc7)cc6)n5)c(F)c4F)OCCCO3)cc2)cc1]

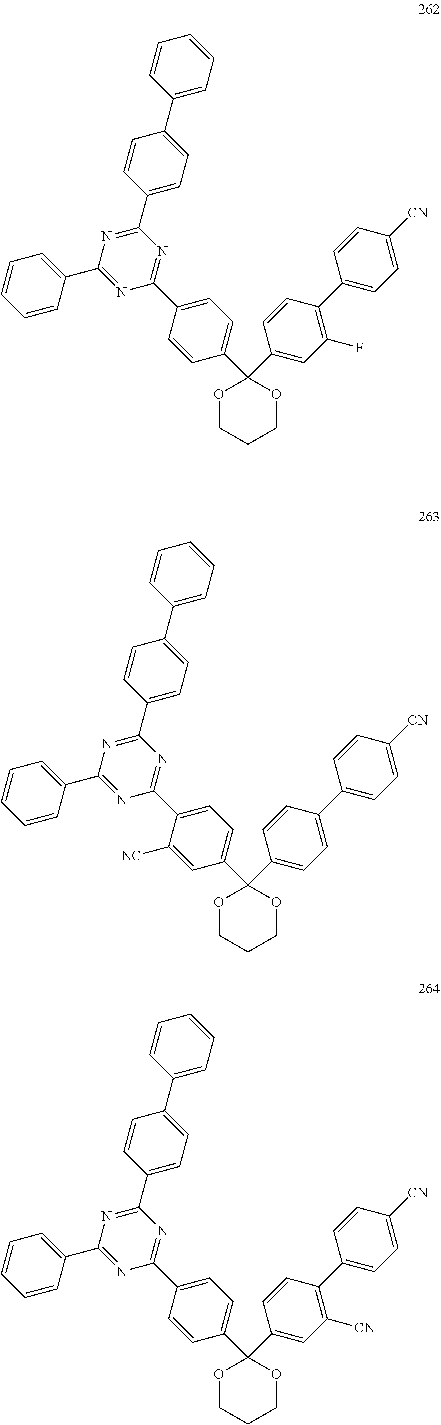 [SMILES: N#Cc1ccc(-c2ccc(C3(c4ccc(-c5nc(-c6ccccc6)nc(-c6ccc(-c7ccccc7)cc6)n5)cc4)OCCCO3)cc2F)cc1 ; N#Cc1ccc(-c2ccc(C3(c4ccc(-c5nc(-c6ccccc6)nc(-c6ccc(-c7ccccc7)cc6)n5)c(C#N)c4)OCCCO3)cc2)cc1 ; N#Cc1ccc(-c2ccc(C3(c4ccc(-c5nc(-c6ccccc6)nc(-c6ccc(-c7ccccc7)cc6)n5)cc4)OCCCO3)cc2C#N)cc1]

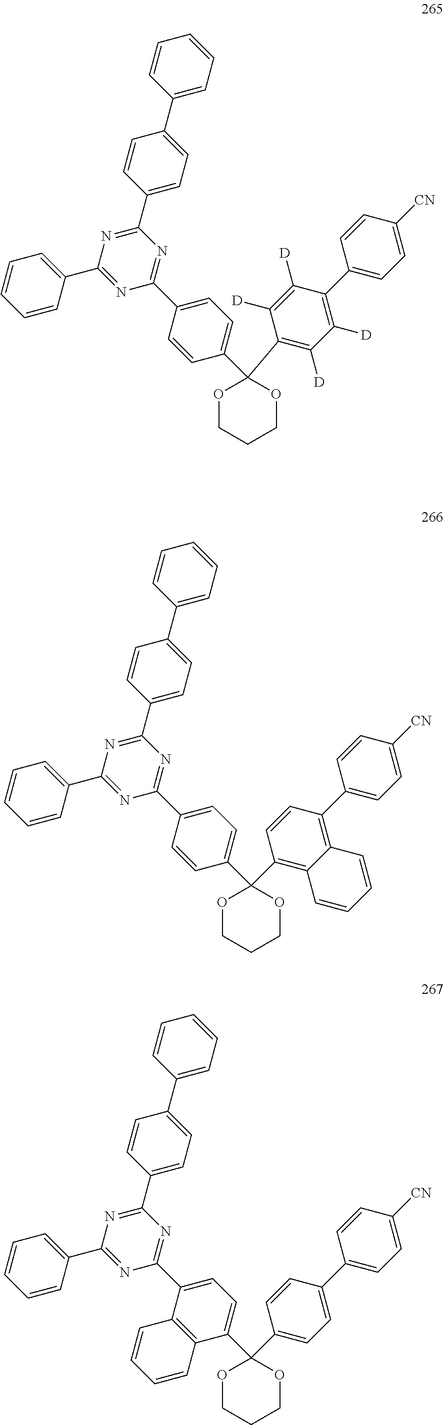 [SMILES: [2H]c1c([2H])c(C2(c3ccc(-c4nc(-c5ccccc5)nc(-c5ccc(-c6ccccc6)cc5)n4)cc3)OCCCO2)c([2H])c([2H])c1-c1ccc(C#N)cc1 ; N#Cc1ccc(-c2ccc(C3(c4ccc(-c5nc(-c6ccccc6)nc(-c6ccc(-c7ccccc7)cc6)n5)cc4)OCCCO3)c3ccccc23)cc1 ; N#Cc1ccc(-c2ccc(C3(c4ccc(-c5nc(-c6ccccc6)nc(-c6ccc(-c7ccccc7)cc6)n5)c5ccccc45)OCCCO3)cc2)cc1]

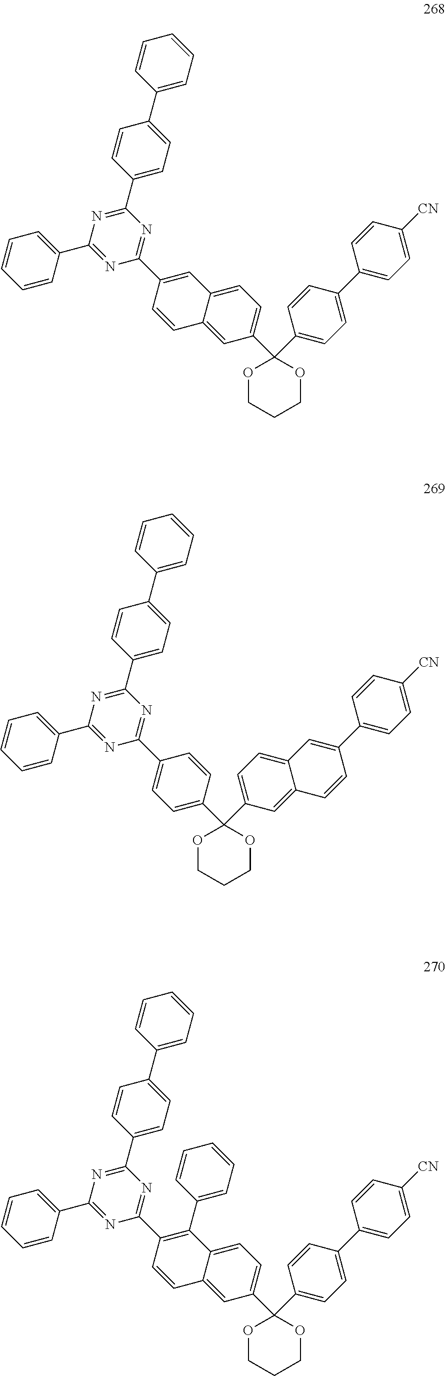 [SMILES: N#Cc1ccc(-c2ccc(C3(c4ccc5cc(-c6nc(-c7ccccc7)nc(-c7ccc(-c8ccccc8)cc7)n6)ccc5c4)OCCCO3)cc2)cc1 ; N#Cc1ccc(-c2ccc3cc(C4(c5ccc(-c6nc(-c7ccccc7)nc(-c7ccc(-c8ccccc8)cc7)n6)cc5)OCCCO4)ccc3c2)cc1 ; N#Cc1ccc(-c2ccc(C3(c4ccc5c(-c6ccccc6)c(-c6nc(-c7ccccc7)nc(-c7ccc(-c8ccccc8)cc7)n6)ccc5c4)OCCCO3)cc2)cc1]

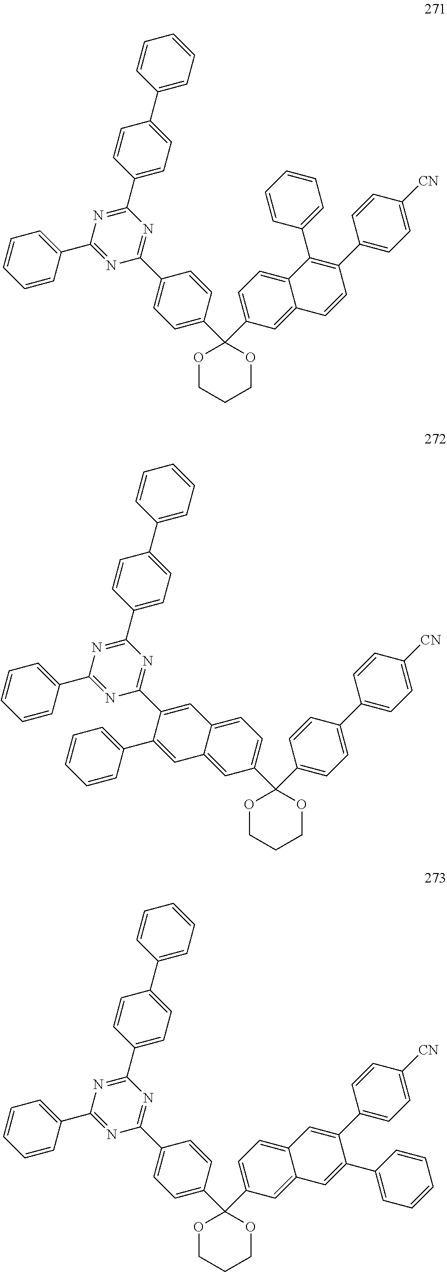 [SMILES: N#Cc1ccc(-c2ccc3cc(C4(c5ccc(-c6nc(-c7ccccc7)nc(-c7ccc(-c8ccccc8)cc7)n6)cc5)OCCCO4)ccc3c2-c2ccccc2)cc1 ; N#Cc1ccc(-c2ccc(C3(c4ccc5cc(-c6nc(-c7ccccc7)nc(-c7ccc(-c8ccccc8)cc7)n6)c(-c6ccccc6)cc5c4)OCCCO3)cc2)cc1 ; N#Cc1ccc(-c2cc3ccc(C4(c5ccc(-c6nc(-c7ccccc7)nc(-c7ccc(-c8ccccc8)cc7)n6)cc5)OCCCO4)cc3cc2-c2ccccc2)cc1]

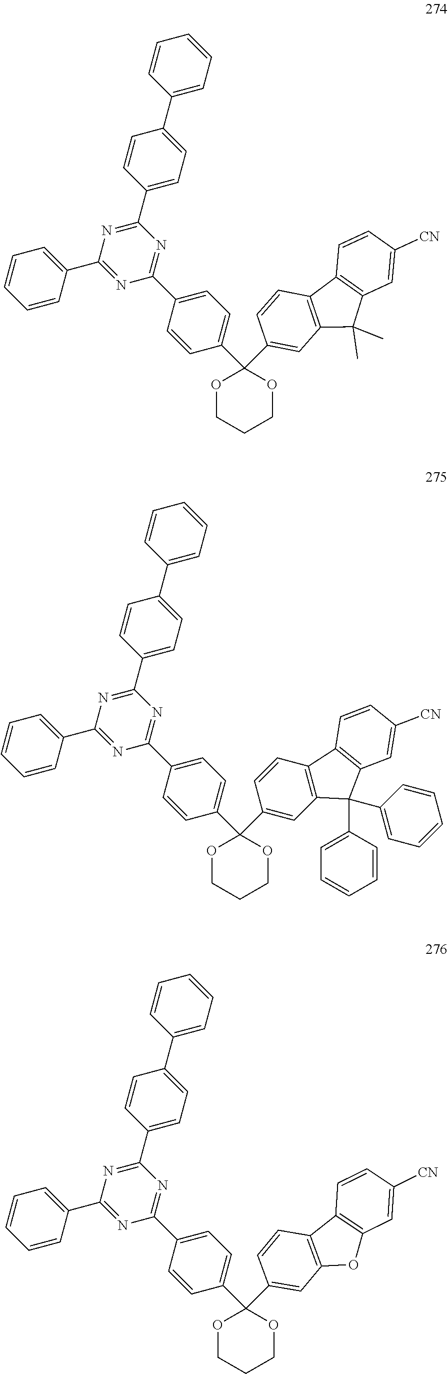 [SMILES: CC1(C)c2cc(C#N)ccc2-c2ccc(C3(c4ccc(-c5nc(-c6ccccc6)nc(-c6ccc(-c7ccccc7)cc6)n5)cc4)OCCCO3)cc21 ; N#Cc1ccc2c(c1)C(c1ccccc1)(c1ccccc1)c1cc(C3(c4ccc(-c5nc(-c6ccccc6)nc(-c6ccc(-c7ccccc7)cc6)n5)cc4)OCCCO3)ccc1-2 ; N#Cc1ccc2c(c1)oc1cc(C3(c4ccc(-c5nc(-c6ccccc6)nc(-c6ccc(-c7ccccc7)cc6)n5)cc4)OCCCO3)ccc12]

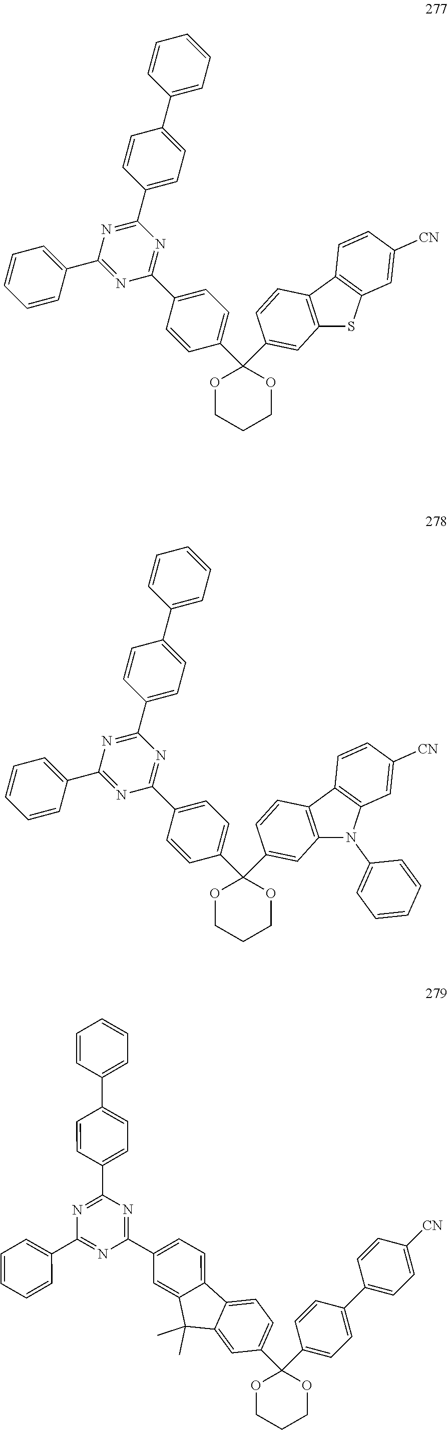 [SMILES: N#Cc1ccc2c(c1)sc1cc(C3(c4ccc(-c5nc(-c6ccccc6)nc(-c6ccc(-c7ccccc7)cc6)n5)cc4)OCCCO3)ccc12 ; N#Cc1ccc2c3ccc(C4(c5ccc(-c6nc(-c7ccccc7)nc(-c7ccc(-c8ccccc8)cc7)n6)cc5)OCCCO4)cc3n(-c3ccccc3)c2c1 ; CC1(C)c2cc(-c3nc(-c4ccccc4)nc(-c4ccc(-c5ccccc5)cc4)n3)ccc2-c2ccc(C3(c4ccc(-c5ccc(C#N)cc5)cc4)OCCCO3)cc21]

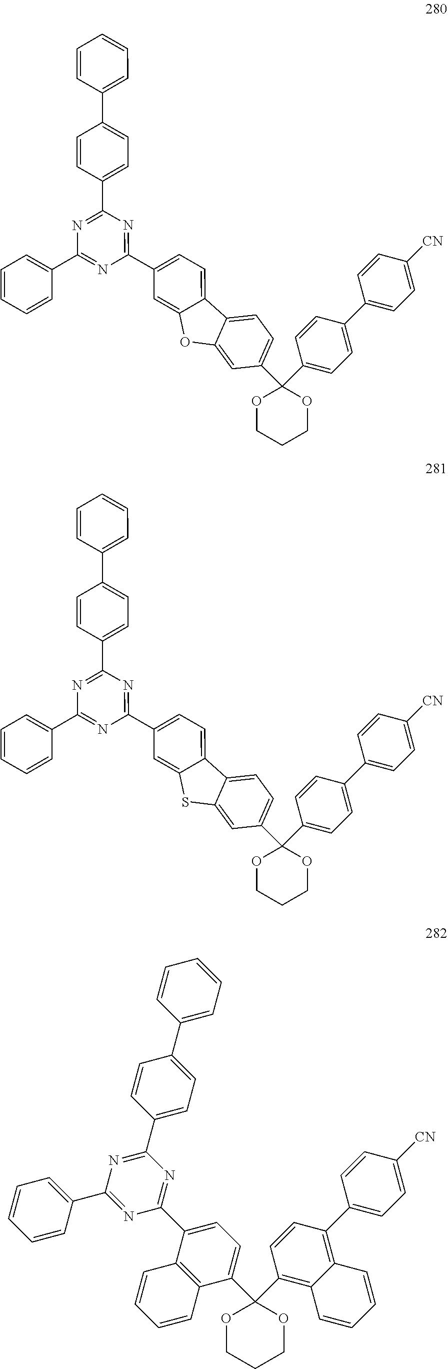 [SMILES: N#Cc1ccc(-c2ccc(C3(c4ccc5c(c4)oc4cc(-c6nc(-c7ccccc7)nc(-c7ccc(-c8ccccc8)cc7)n6)ccc45)OCCCO3)cc2)cc1 ; N#Cc1ccc(-c2ccc(C3(c4ccc5c(c4)sc4cc(-c6nc(-c7ccccc7)nc(-c7ccc(-c8ccccc8)cc7)n6)ccc45)OCCCO3)cc2)cc1 ; N#Cc1ccc(-c2ccc(C3(c4ccc(-c5nc(-c6ccccc6)nc(-c6ccc(-c7ccccc7)cc6)n5)c5ccccc45)OCCCO3)c3ccccc23)cc1]

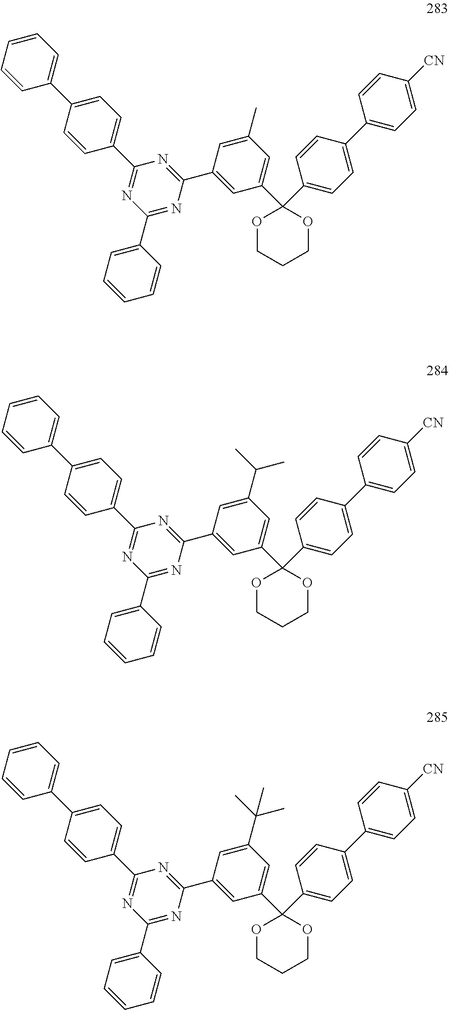 [SMILES: Cc1cc(-c2nc(-c3ccccc3)nc(-c3ccc(-c4ccccc4)cc3)n2)cc(C2(c3ccc(-c4ccc(C#N)cc4)cc3)OCCCO2)c1 ; CC(C)c1cc(-c2nc(-c3ccccc3)nc(-c3ccc(-c4ccccc4)cc3)n2)cc(C2(c3ccc(-c4ccc(C#N)cc4)cc3)OCCCO2)c1 ; CC(C)(C)c1cc(-c2nc(-c3ccccc3)nc(-c3ccc(-c4ccccc4)cc3)n2)cc(C2(c3ccc(-c4ccc(C#N)cc4)cc3)OCCCO2)c1]

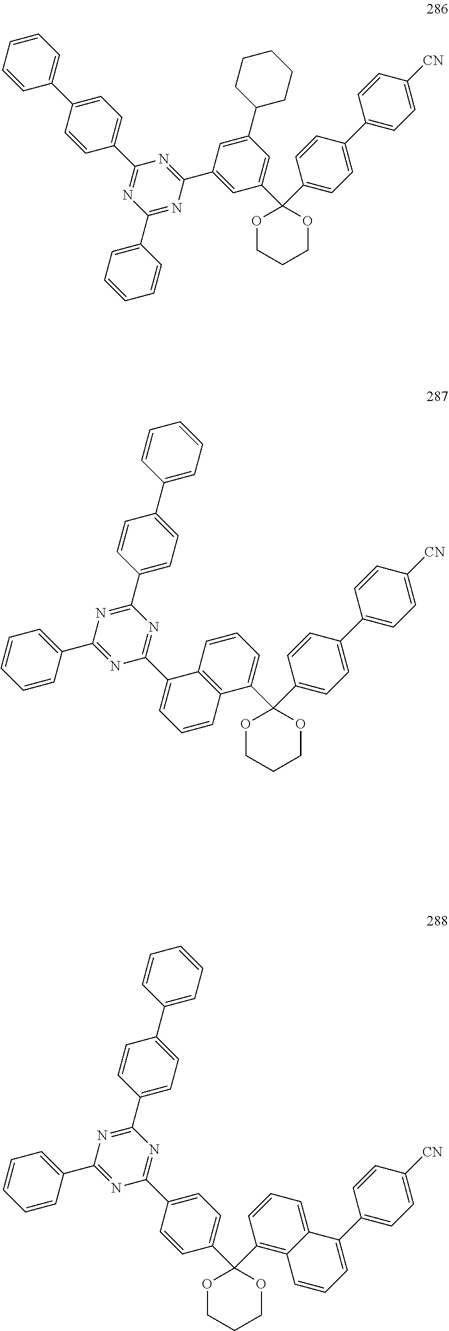 [SMILES: N#Cc1ccc(-c2ccc(C3(c4cc(-c5nc(-c6ccccc6)nc(-c6ccc(-c7ccccc7)cc6)n5)cc(C5CCCCC5)c4)OCCCO3)cc2)cc1 ; N#Cc1ccc(-c2ccc(C3(c4cccc5c(-c6nc(-c7ccccc7)nc(-c7ccc(-c8ccccc8)cc7)n6)cccc45)OCCCO3)cc2)cc1 ; N#Cc1ccc(-c2cccc3c(C4(c5ccc(-c6nc(-c7ccccc7)nc(-c7ccc(-c8ccccc8)cc7)n6)cc5)OCCCO4)cccc23)cc1]

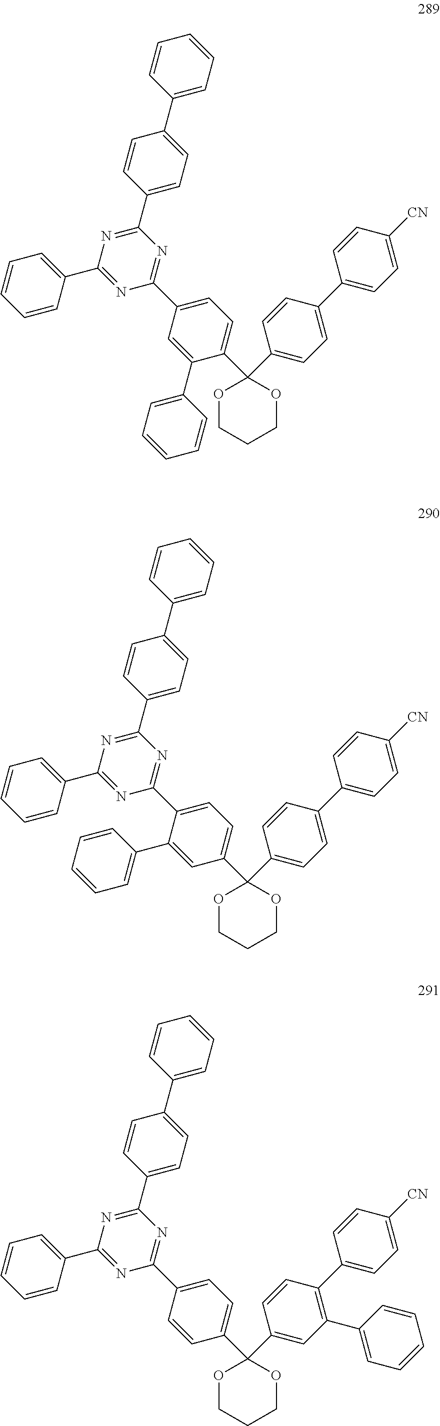 [SMILES: N#Cc1ccc(-c2ccc(C3(c4ccc(-c5nc(-c6ccccc6)nc(-c6ccc(-c7ccccc7)cc6)n5)cc4-c4ccccc4)OCCCO3)cc2)cc1 ; N#Cc1ccc(-c2ccc(C3(c4ccc(-c5nc(-c6ccccc6)nc(-c6ccc(-c7ccccc7)cc6)n5)c(-c5ccccc5)c4)OCCCO3)cc2)cc1 ; N#Cc1ccc(-c2ccc(C3(c4ccc(-c5nc(-c6ccccc6)nc(-c6ccc(-c7ccccc7)cc6)n5)cc4)OCCCO3)cc2-c2ccccc2)cc1]

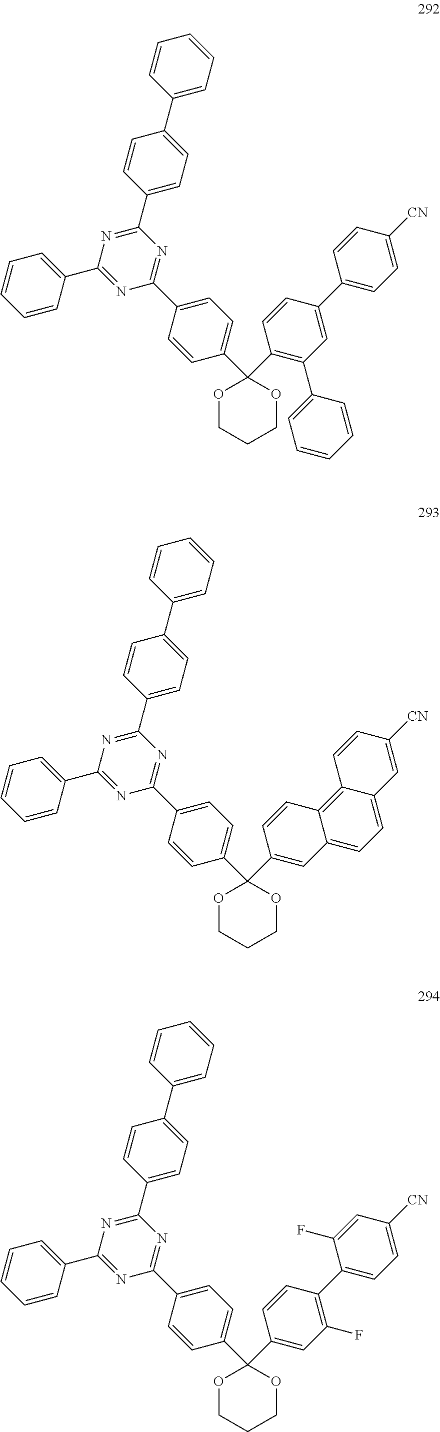 [SMILES: N#Cc1ccc(-c2ccc(C3(c4ccc(-c5nc(-c6ccccc6)nc(-c6ccc(-c7ccccc7)cc6)n5)cc4)OCCCO3)c(-c3ccccc3)c2)cc1 ; N#Cc1ccc2c(ccc3cc(C4(c5ccc(-c6nc(-c7ccccc7)nc(-c7ccc(-c8ccccc8)cc7)n6)cc5)OCCCO4)ccc32)c1 ; N#Cc1ccc(-c2ccc(C3(c4ccc(-c5nc(-c6ccccc6)nc(-c6ccc(-c7ccccc7)cc6)n5)cc4)OCCCO3)cc2F)c(F)c1]

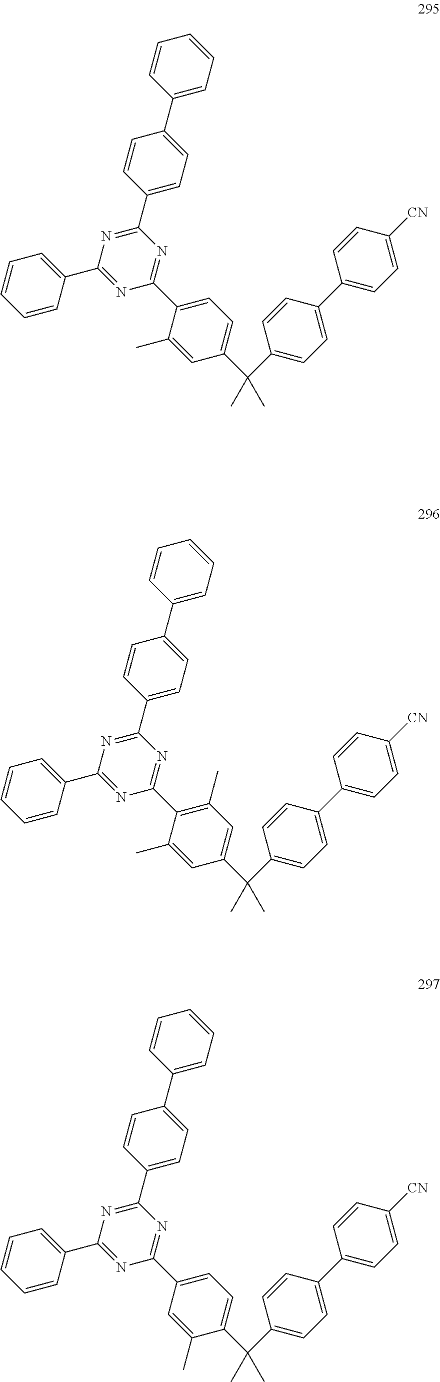 [SMILES: Cc1cc(C(C)(C)c2ccc(-c3ccc(C#N)cc3)cc2)ccc1-c1nc(-c2ccccc2)nc(-c2ccc(-c3ccccc3)cc2)n1 ; Cc1cc(C(C)(C)c2ccc(-c3ccc(C#N)cc3)cc2)cc(C)c1-c1nc(-c2ccccc2)nc(-c2ccc(-c3ccccc3)cc2)n1 ; Cc1cc(-c2nc(-c3ccccc3)nc(-c3ccc(-c4ccccc4)cc3)n2)ccc1C(C)(C)c1ccc(-c2ccc(C#N)cc2)cc1]

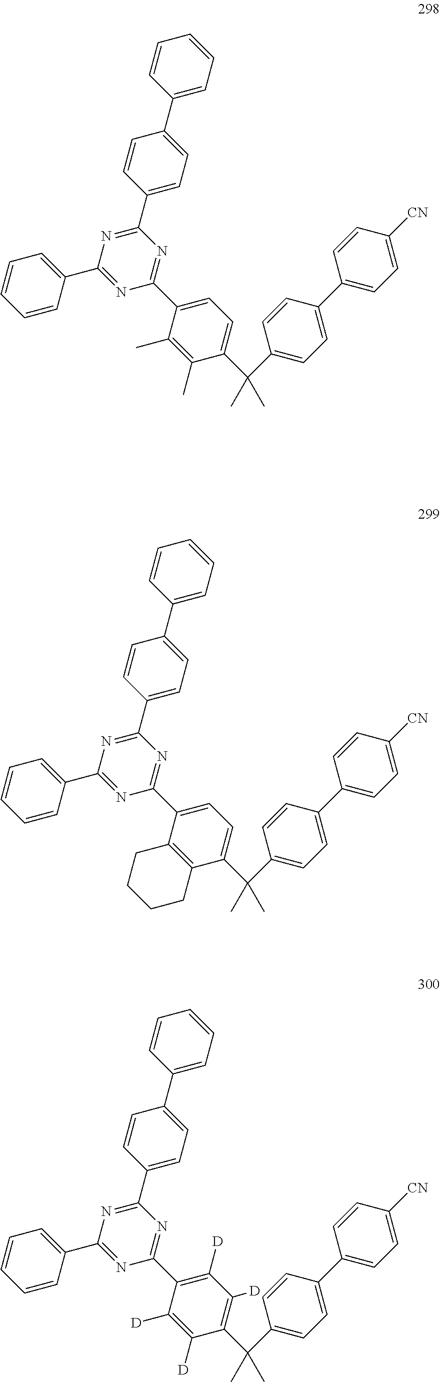 [SMILES: Cc1c(-c2nc(-c3ccccc3)nc(-c3ccc(-c4ccccc4)cc3)n2)ccc(C(C)(C)c2ccc(-c3ccc(C#N)cc3)cc2)c1C ; CC(C)(c1ccc(-c2ccc(C#N)cc2)cc1)c1ccc(-c2nc(-c3ccccc3)nc(-c3ccc(-c4ccccc4)cc3)n2)c2c1CCCC2 ; [2H]c1c([2H])c(C(C)(C)c2ccc(-c3ccc(C#N)cc3)cc2)c([2H])c([2H])c1-c1nc(-c2ccccc2)nc(-c2ccc(-c3ccccc3)cc2)n1]

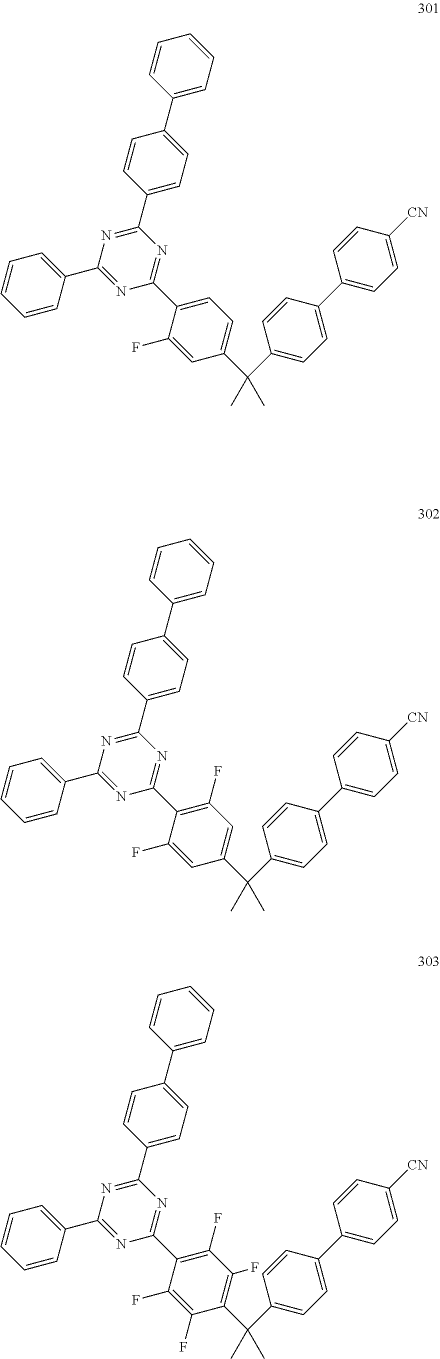 [SMILES: CC(C)(c1ccc(-c2ccc(C#N)cc2)cc1)c1ccc(-c2nc(-c3ccccc3)nc(-c3ccc(-c4ccccc4)cc3)n2)c(F)c1 ; CC(C)(c1ccc(-c2ccc(C#N)cc2)cc1)c1cc(F)c(-c2nc(-c3ccccc3)nc(-c3ccc(-c4ccccc4)cc3)n2)c(F)c1 ; CC(C)(c1ccc(-c2ccc(C#N)cc2)cc1)c1c(F)c(F)c(-c2nc(-c3ccccc3)nc(-c3ccc(-c4ccccc4)cc3)n2)c(F)c1F]

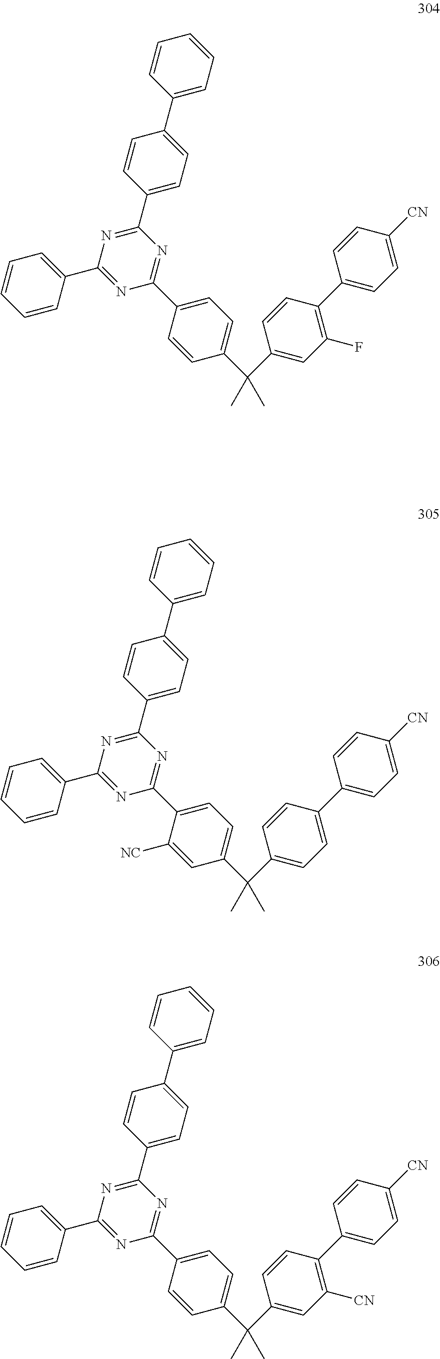 [SMILES: CC(C)(c1ccc(-c2nc(-c3ccccc3)nc(-c3ccc(-c4ccccc4)cc3)n2)cc1)c1ccc(-c2ccc(C#N)cc2)c(F)c1 ; CC(C)(c1ccc(-c2ccc(C#N)cc2)cc1)c1ccc(-c2nc(-c3ccccc3)nc(-c3ccc(-c4ccccc4)cc3)n2)c(C#N)c1 ; CC(C)(c1ccc(-c2nc(-c3ccccc3)nc(-c3ccc(-c4ccccc4)cc3)n2)cc1)c1ccc(-c2ccc(C#N)cc2)c(C#N)c1]

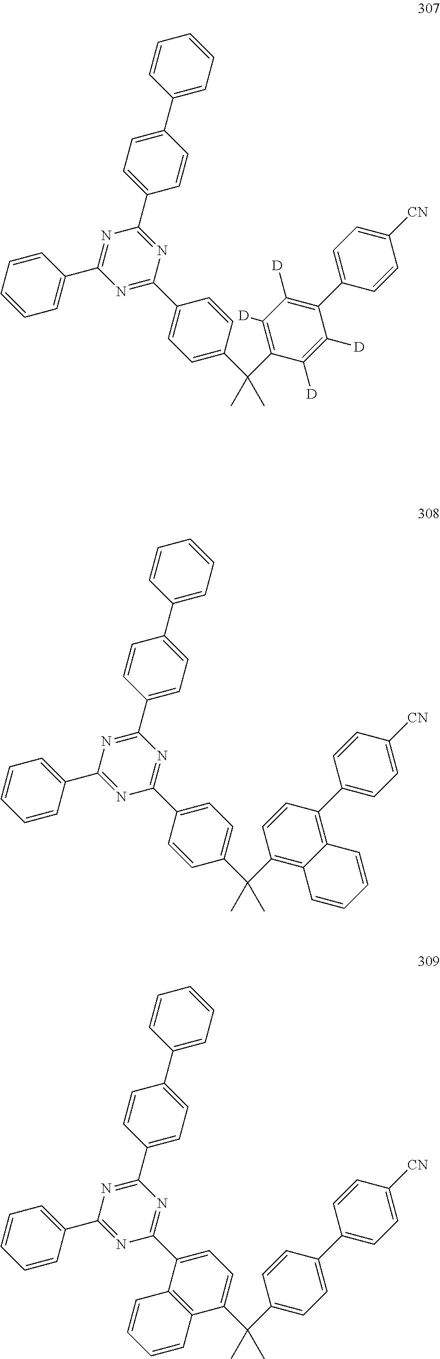 [SMILES: [2H]c1c([2H])c(C(C)(C)c2ccc(-c3nc(-c4ccccc4)nc(-c4ccc(-c5ccccc5)cc4)n3)cc2)c([2H])c([2H])c1-c1ccc(C#N)cc1 ; CC(C)(c1ccc(-c2nc(-c3ccccc3)nc(-c3ccc(-c4ccccc4)cc3)n2)cc1)c1ccc(-c2ccc(C#N)cc2)c2ccccc12 ; CC(C)(c1ccc(-c2ccc(C#N)cc2)cc1)c1ccc(-c2nc(-c3ccccc3)nc(-c3ccc(-c4ccccc4)cc3)n2)c2ccccc12]

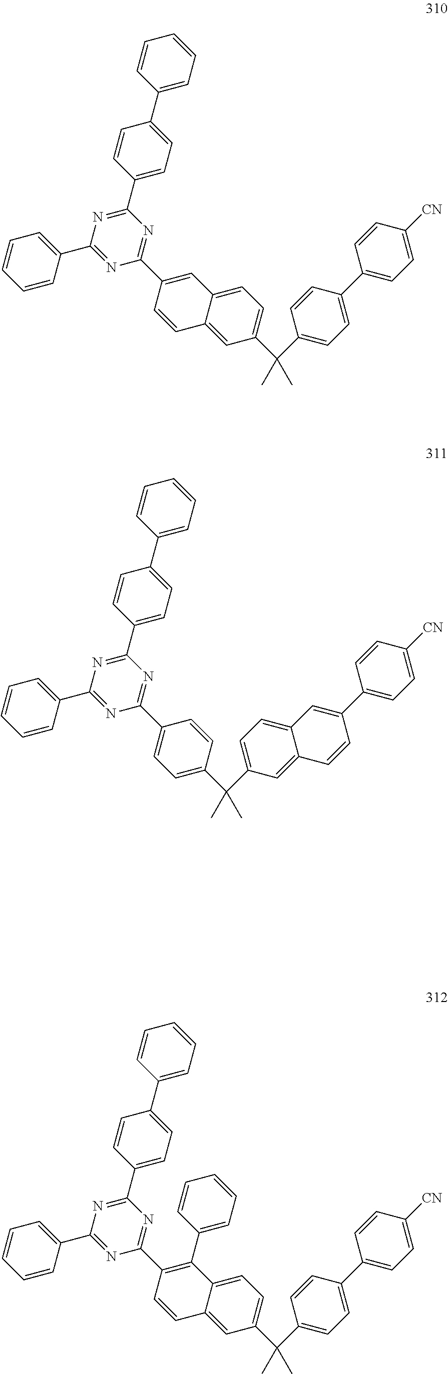 [SMILES: CC(C)(c1ccc(-c2ccc(C#N)cc2)cc1)c1ccc2cc(-c3nc(-c4ccccc4)nc(-c4ccc(-c5ccccc5)cc4)n3)ccc2c1 ; CC(C)(c1ccc(-c2nc(-c3ccccc3)nc(-c3ccc(-c4ccccc4)cc3)n2)cc1)c1ccc2cc(-c3ccc(C#N)cc3)ccc2c1 ; CC(C)(c1ccc(-c2ccc(C#N)cc2)cc1)c1ccc2c(-c3ccccc3)c(-c3nc(-c4ccccc4)nc(-c4ccc(-c5ccccc5)cc4)n3)ccc2c1]

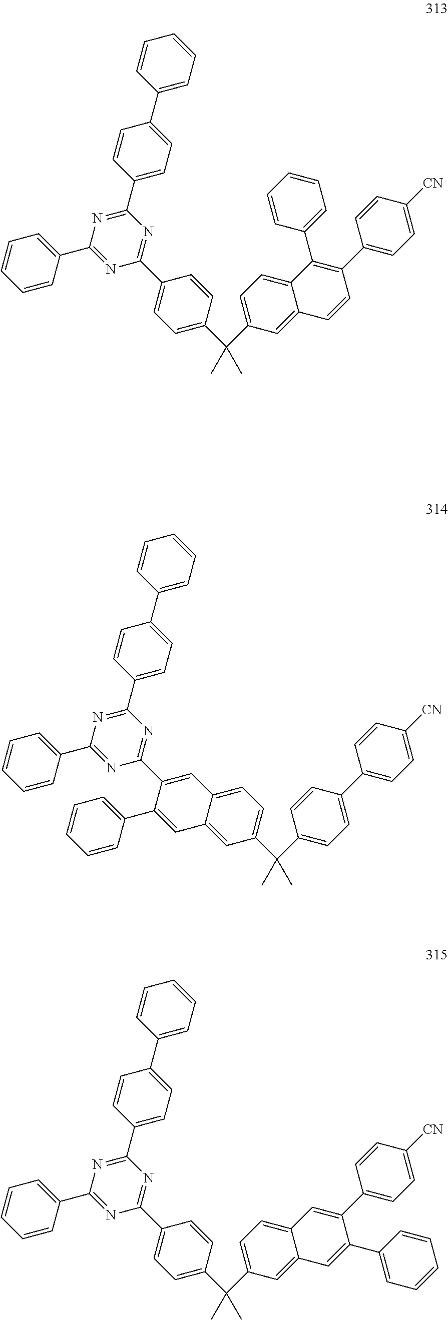 [SMILES: CC(C)(c1ccc(-c2nc(-c3ccccc3)nc(-c3ccc(-c4ccccc4)cc3)n2)cc1)c1ccc2c(-c3ccccc3)c(-c3ccc(C#N)cc3)ccc2c1 ; CC(C)(c1ccc(-c2ccc(C#N)cc2)cc1)c1ccc2cc(-c3nc(-c4ccccc4)nc(-c4ccc(-c5ccccc5)cc4)n3)c(-c3ccccc3)cc2c1 ; CC(C)(c1ccc(-c2nc(-c3ccccc3)nc(-c3ccc(-c4ccccc4)cc3)n2)cc1)c1ccc2cc(-c3ccc(C#N)cc3)c(-c3ccccc3)cc2c1]

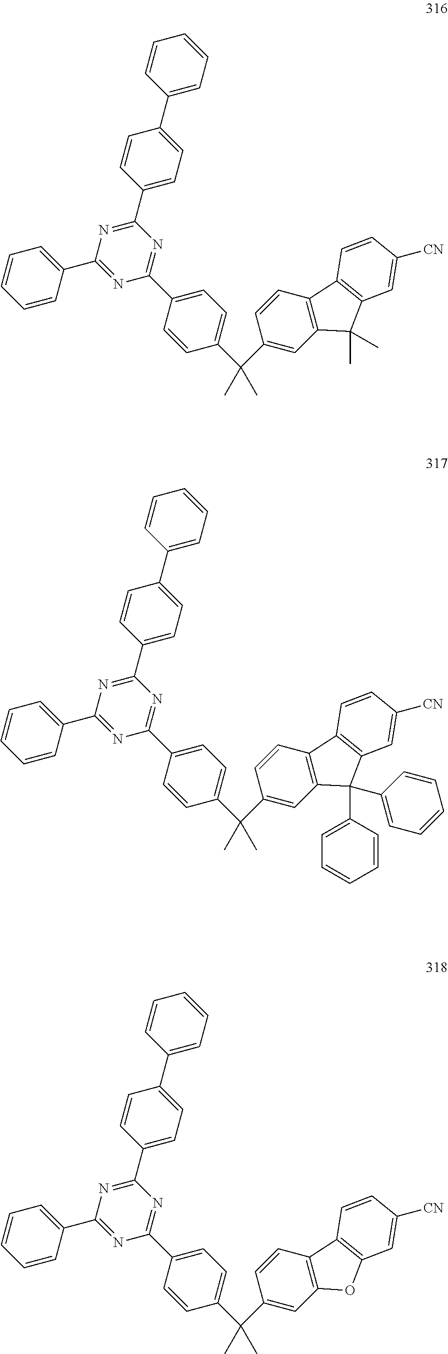 [SMILES: CC(C)(c1ccc(-c2nc(-c3ccccc3)nc(-c3ccc(-c4ccccc4)cc3)n2)cc1)c1ccc2c(c1)C(C)(C)c1cc(C#N)ccc1-2 ; CC(C)(c1ccc(-c2nc(-c3ccccc3)nc(-c3ccc(-c4ccccc4)cc3)n2)cc1)c1ccc2c(c1)C(c1ccccc1)(c1ccccc1)c1cc(C#N)ccc1-2 ; CC(C)(c1ccc(-c2nc(-c3ccccc3)nc(-c3ccc(-c4ccccc4)cc3)n2)cc1)c1ccc2c(c1)oc1cc(C#N)ccc12]

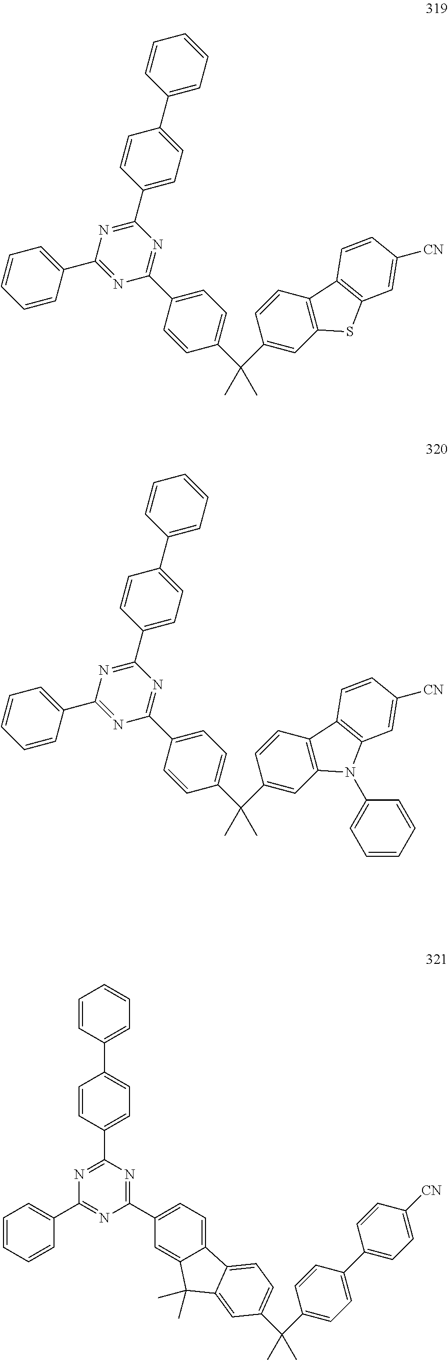 [SMILES: CC(C)(c1ccc(-c2nc(-c3ccccc3)nc(-c3ccc(-c4ccccc4)cc3)n2)cc1)c1ccc2c(c1)sc1cc(C#N)ccc12 ; CC(C)(c1ccc(-c2nc(-c3ccccc3)nc(-c3ccc(-c4ccccc4)cc3)n2)cc1)c1ccc2c3ccc(C#N)cc3n(-c3ccccc3)c2c1 ; CC(C)(c1ccc(-c2ccc(C#N)cc2)cc1)c1ccc2c(c1)C(C)(C)c1cc(-c3nc(-c4ccccc4)nc(-c4ccc(-c5ccccc5)cc4)n3)ccc1-2]

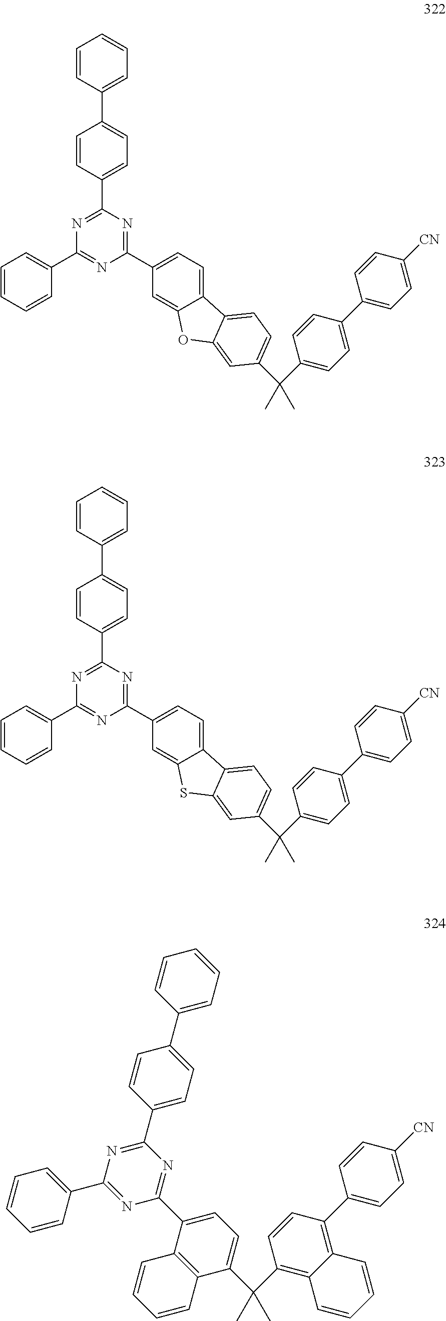 [SMILES: CC(C)(c1ccc(-c2ccc(C#N)cc2)cc1)c1ccc2c(c1)oc1cc(-c3nc(-c4ccccc4)nc(-c4ccc(-c5ccccc5)cc4)n3)ccc12 ; CC(C)(c1ccc(-c2ccc(C#N)cc2)cc1)c1ccc2c(c1)sc1cc(-c3nc(-c4ccccc4)nc(-c4ccc(-c5ccccc5)cc4)n3)ccc12 ; CC(C)(c1ccc(-c2ccc(C#N)cc2)c2ccccc12)c1ccc(-c2nc(-c3ccccc3)nc(-c3ccc(-c4ccccc4)cc3)n2)c2ccccc12]

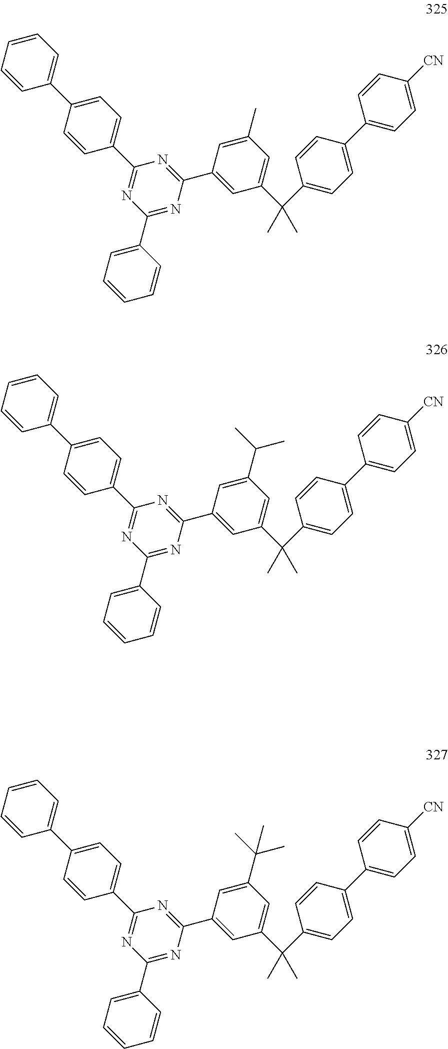 [SMILES: Cc1cc(-c2nc(-c3ccccc3)nc(-c3ccc(-c4ccccc4)cc3)n2)cc(C(C)(C)c2ccc(-c3ccc(C#N)cc3)cc2)c1 ; CC(C)c1cc(-c2nc(-c3ccccc3)nc(-c3ccc(-c4ccccc4)cc3)n2)cc(C(C)(C)c2ccc(-c3ccc(C#N)cc3)cc2)c1 ; CC(C)(C)c1cc(-c2nc(-c3ccccc3)nc(-c3ccc(-c4ccccc4)cc3)n2)cc(C(C)(C)c2ccc(-c3ccc(C#N)cc3)cc2)c1]

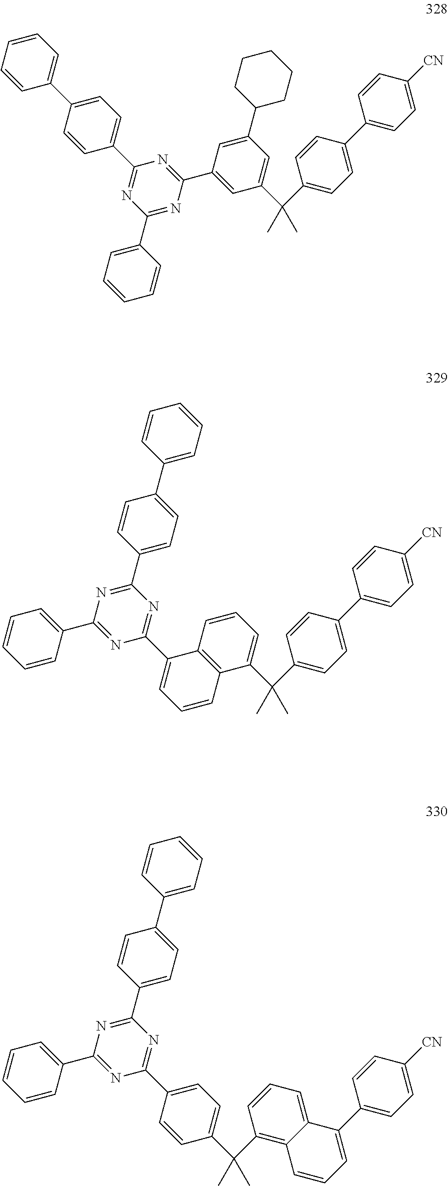 [SMILES: CC(C)(c1ccc(-c2ccc(C#N)cc2)cc1)c1cc(-c2nc(-c3ccccc3)nc(-c3ccc(-c4ccccc4)cc3)n2)cc(C2CCCCC2)c1 ; CC(C)(c1ccc(-c2ccc(C#N)cc2)cc1)c1cccc2c(-c3nc(-c4ccccc4)nc(-c4ccc(-c5ccccc5)cc4)n3)cccc12 ; CC(C)(c1ccc(-c2nc(-c3ccccc3)nc(-c3ccc(-c4ccccc4)cc3)n2)cc1)c1cccc2c(-c3ccc(C#N)cc3)cccc12]

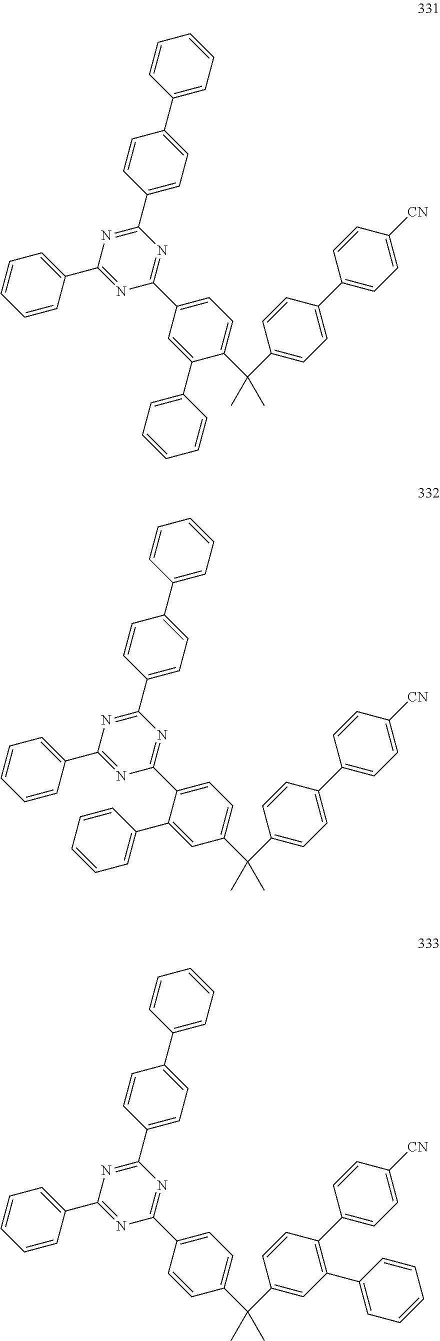 [SMILES: CC(C)(c1ccc(-c2ccc(C#N)cc2)cc1)c1ccc(-c2nc(-c3ccccc3)nc(-c3ccc(-c4ccccc4)cc3)n2)cc1-c1ccccc1 ; CC(C)(c1ccc(-c2ccc(C#N)cc2)cc1)c1ccc(-c2nc(-c3ccccc3)nc(-c3ccc(-c4ccccc4)cc3)n2)c(-c2ccccc2)c1 ; CC(C)(c1ccc(-c2nc(-c3ccccc3)nc(-c3ccc(-c4ccccc4)cc3)n2)cc1)c1ccc(-c2ccc(C#N)cc2)c(-c2ccccc2)c1]

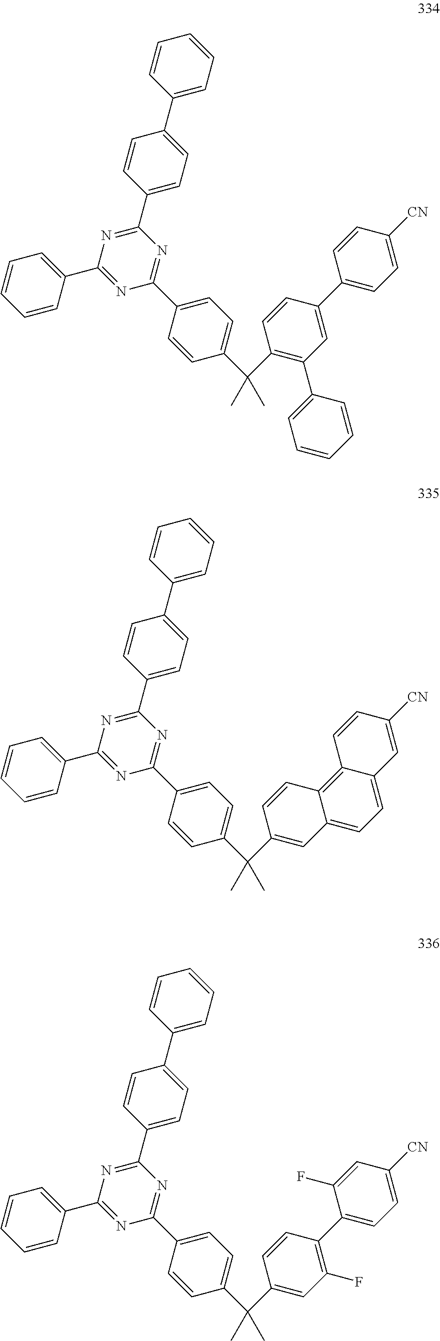 [SMILES: CC(C)(c1ccc(-c2nc(-c3ccccc3)nc(-c3ccc(-c4ccccc4)cc3)n2)cc1)c1ccc(-c2ccc(C#N)cc2)cc1-c1ccccc1 ; CC(C)(c1ccc(-c2nc(-c3ccccc3)nc(-c3ccc(-c4ccccc4)cc3)n2)cc1)c1ccc2c(ccc3cc(C#N)ccc32)c1 ; CC(C)(c1ccc(-c2nc(-c3ccccc3)nc(-c3ccc(-c4ccccc4)cc3)n2)cc1)c1ccc(-c2ccc(C#N)cc2F)c(F)c1]

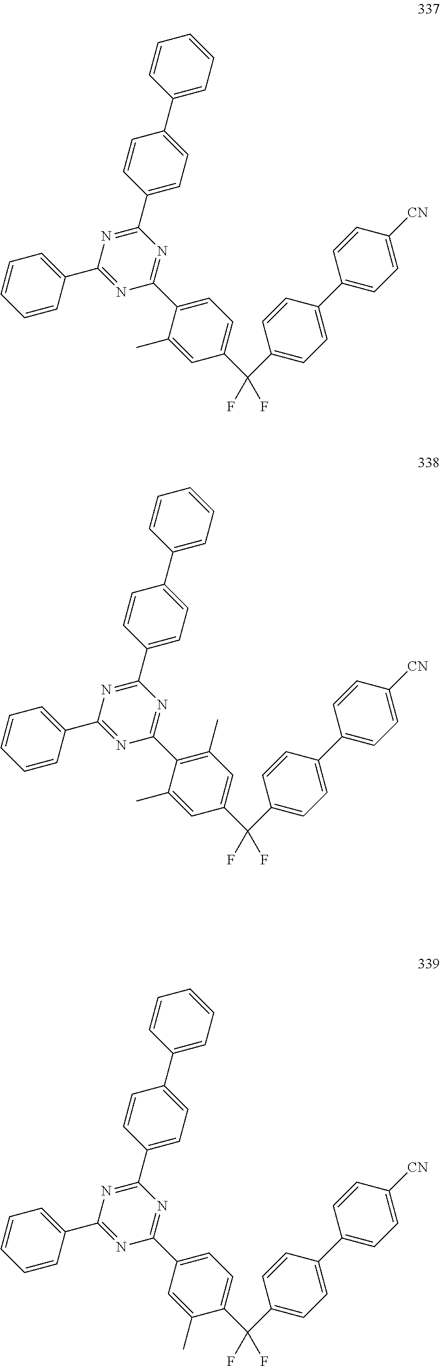 [SMILES: Cc1cc(C(F)(F)c2ccc(-c3ccc(C#N)cc3)cc2)ccc1-c1nc(-c2ccccc2)nc(-c2ccc(-c3ccccc3)cc2)n1 ; Cc1cc(C(F)(F)c2ccc(-c3ccc(C#N)cc3)cc2)cc(C)c1-c1nc(-c2ccccc2)nc(-c2ccc(-c3ccccc3)cc2)n1 ; Cc1cc(-c2nc(-c3ccccc3)nc(-c3ccc(-c4ccccc4)cc3)n2)ccc1C(F)(F)c1ccc(-c2ccc(C#N)cc2)cc1]

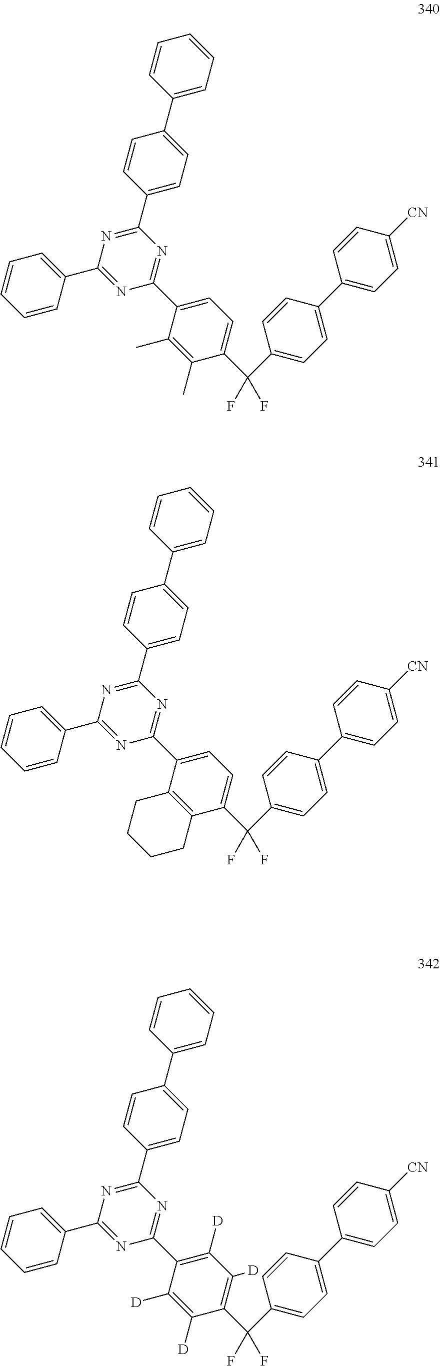 [SMILES: Cc1c(-c2nc(-c3ccccc3)nc(-c3ccc(-c4ccccc4)cc3)n2)ccc(C(F)(F)c2ccc(-c3ccc(C#N)cc3)cc2)c1C ; N#Cc1ccc(-c2ccc(C(F)(F)c3ccc(-c4nc(-c5ccccc5)nc(-c5ccc(-c6ccccc6)cc5)n4)c4c3CCCC4)cc2)cc1 ; [2H]c1c([2H])c(C(F)(F)c2ccc(-c3ccc(C#N)cc3)cc2)c([2H])c([2H])c1-c1nc(-c2ccccc2)nc(-c2ccc(-c3ccccc3)cc2)n1]

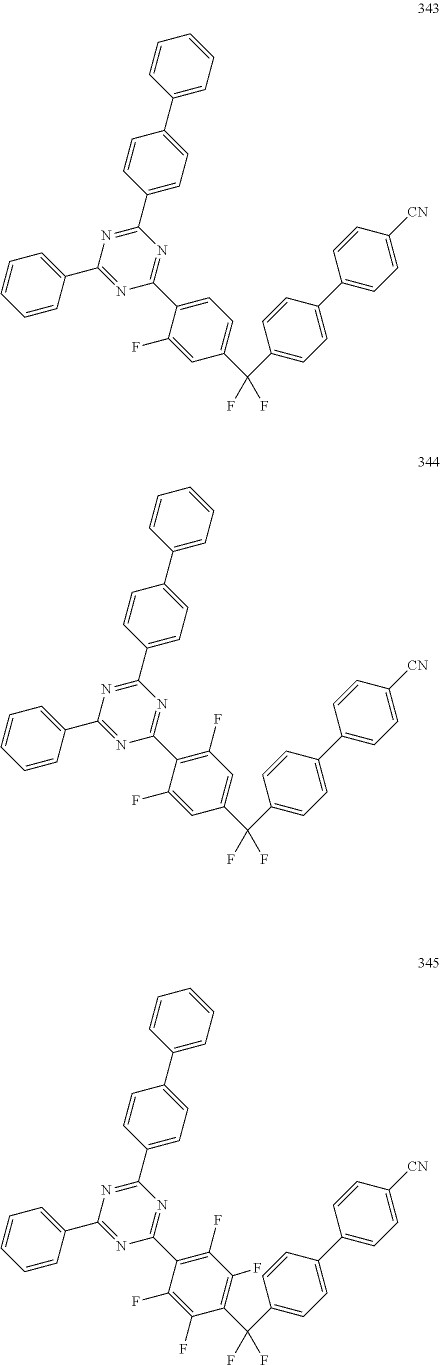 [SMILES: N#Cc1ccc(-c2ccc(C(F)(F)c3ccc(-c4nc(-c5ccccc5)nc(-c5ccc(-c6ccccc6)cc5)n4)c(F)c3)cc2)cc1 ; N#Cc1ccc(-c2ccc(C(F)(F)c3cc(F)c(-c4nc(-c5ccccc5)nc(-c5ccc(-c6ccccc6)cc5)n4)c(F)c3)cc2)cc1 ; N#Cc1ccc(-c2ccc(C(F)(F)c3c(F)c(F)c(-c4nc(-c5ccccc5)nc(-c5ccc(-c6ccccc6)cc5)n4)c(F)c3F)cc2)cc1]

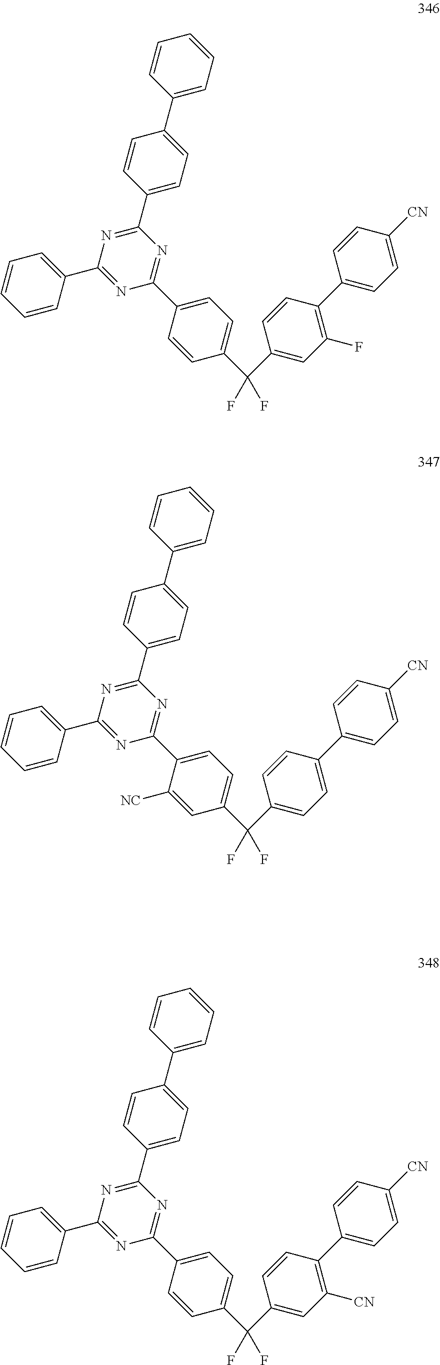 [SMILES: N#Cc1ccc(-c2ccc(C(F)(F)c3ccc(-c4nc(-c5ccccc5)nc(-c5ccc(-c6ccccc6)cc5)n4)cc3)cc2F)cc1 ; N#Cc1ccc(-c2ccc(C(F)(F)c3ccc(-c4nc(-c5ccccc5)nc(-c5ccc(-c6ccccc6)cc5)n4)c(C#N)c3)cc2)cc1 ; N#Cc1ccc(-c2ccc(C(F)(F)c3ccc(-c4nc(-c5ccccc5)nc(-c5ccc(-c6ccccc6)cc5)n4)cc3)cc2C#N)cc1]

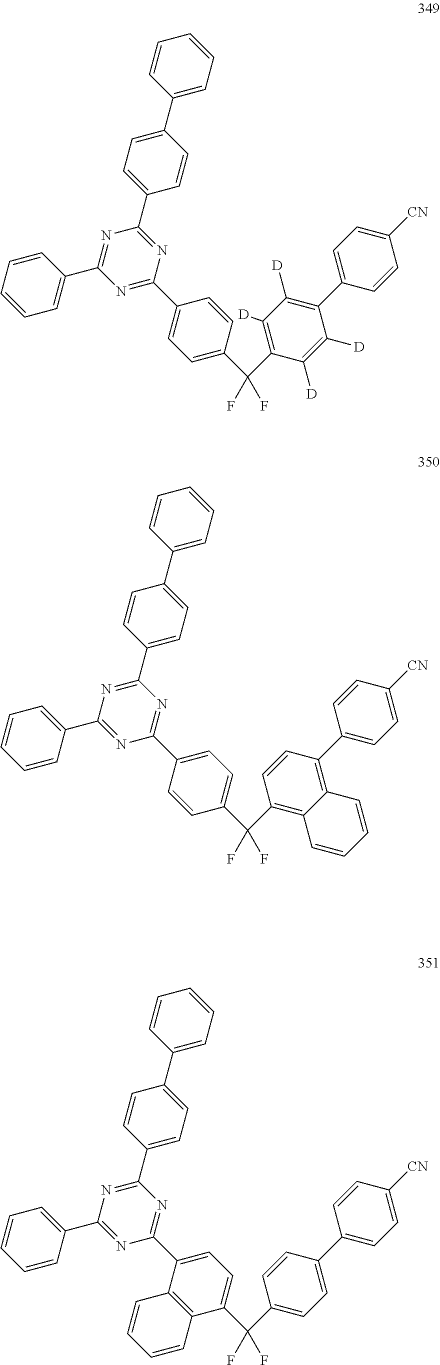 [SMILES: [2H]c1c([2H])c(C(F)(F)c2ccc(-c3nc(-c4ccccc4)nc(-c4ccc(-c5ccccc5)cc4)n3)cc2)c([2H])c([2H])c1-c1ccc(C#N)cc1 ; N#Cc1ccc(-c2ccc(C(F)(F)c3ccc(-c4nc(-c5ccccc5)nc(-c5ccc(-c6ccccc6)cc5)n4)cc3)c3ccccc23)cc1 ; N#Cc1ccc(-c2ccc(C(F)(F)c3ccc(-c4nc(-c5ccccc5)nc(-c5ccc(-c6ccccc6)cc5)n4)c4ccccc34)cc2)cc1]

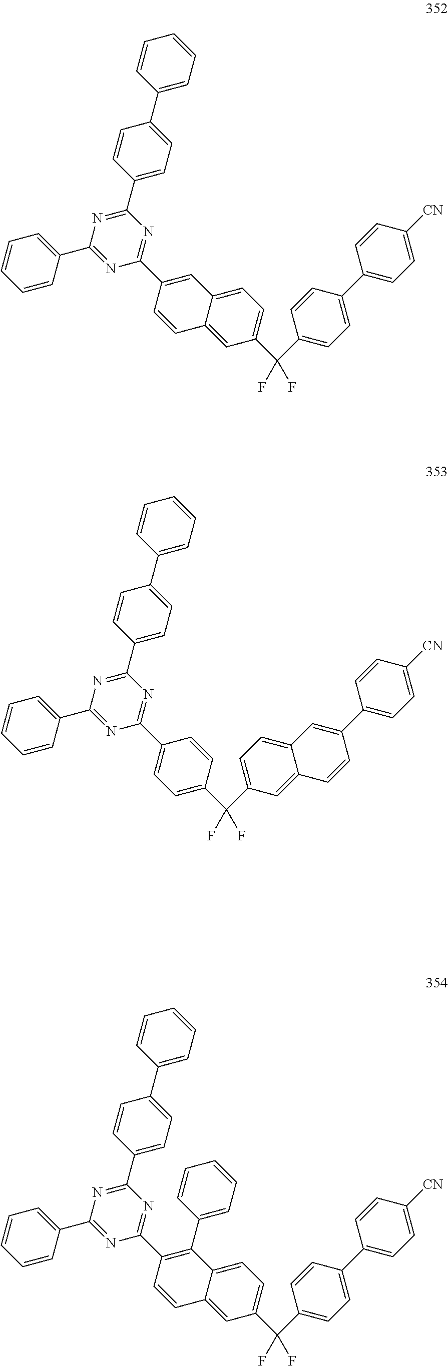 [SMILES: N#Cc1ccc(-c2ccc(C(F)(F)c3ccc4cc(-c5nc(-c6ccccc6)nc(-c6ccc(-c7ccccc7)cc6)n5)ccc4c3)cc2)cc1 ; N#Cc1ccc(-c2ccc3cc(C(F)(F)c4ccc(-c5nc(-c6ccccc6)nc(-c6ccc(-c7ccccc7)cc6)n5)cc4)ccc3c2)cc1 ; N#Cc1ccc(-c2ccc(C(F)(F)c3ccc4c(-c5ccccc5)c(-c5nc(-c6ccccc6)nc(-c6ccc(-c7ccccc7)cc6)n5)ccc4c3)cc2)cc1]

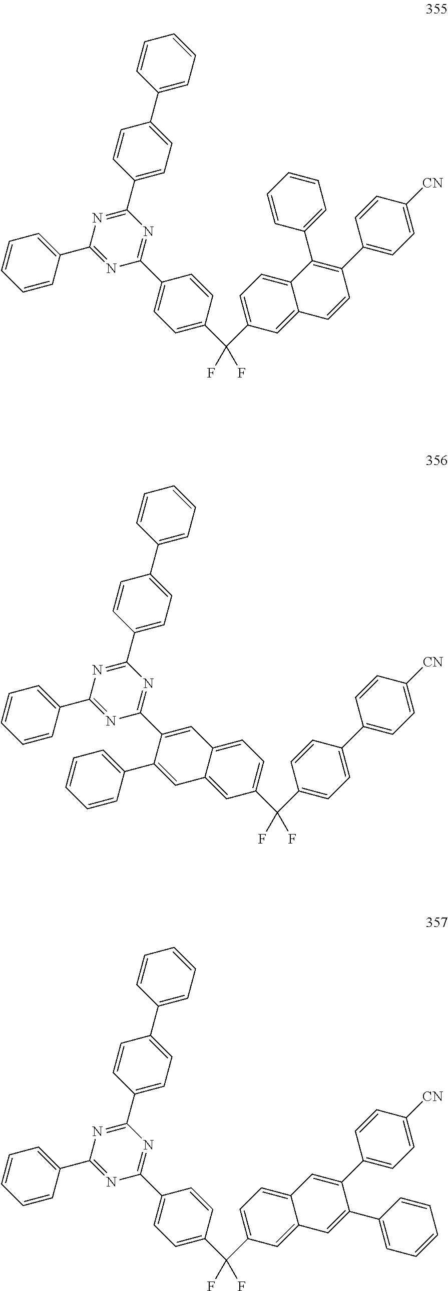 [SMILES: N#Cc1ccc(-c2ccc3cc(C(F)(F)c4ccc(-c5nc(-c6ccccc6)nc(-c6ccc(-c7ccccc7)cc6)n5)cc4)ccc3c2-c2ccccc2)cc1 ; N#Cc1ccc(-c2ccc(C(F)(F)c3ccc4cc(-c5nc(-c6ccccc6)nc(-c6ccc(-c7ccccc7)cc6)n5)c(-c5ccccc5)cc4c3)cc2)cc1 ; N#Cc1ccc(-c2cc3ccc(C(F)(F)c4ccc(-c5nc(-c6ccccc6)nc(-c6ccc(-c7ccccc7)cc6)n5)cc4)cc3cc2-c2ccccc2)cc1]

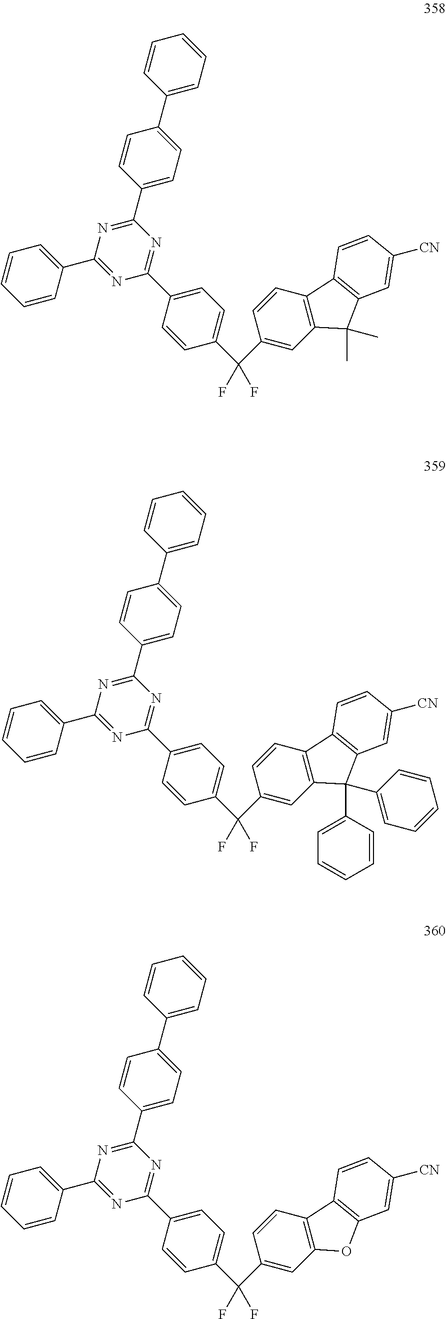 [SMILES: CC1(C)c2cc(C#N)ccc2-c2ccc(C(F)(F)c3ccc(-c4nc(-c5ccccc5)nc(-c5ccc(-c6ccccc6)cc5)n4)cc3)cc21 ; N#Cc1ccc2c(c1)C(c1ccccc1)(c1ccccc1)c1cc(C(F)(F)c3ccc(-c4nc(-c5ccccc5)nc(-c5ccc(-c6ccccc6)cc5)n4)cc3)ccc1-2 ; N#Cc1ccc2c(c1)oc1cc(C(F)(F)c3ccc(-c4nc(-c5ccccc5)nc(-c5ccc(-c6ccccc6)cc5)n4)cc3)ccc12]

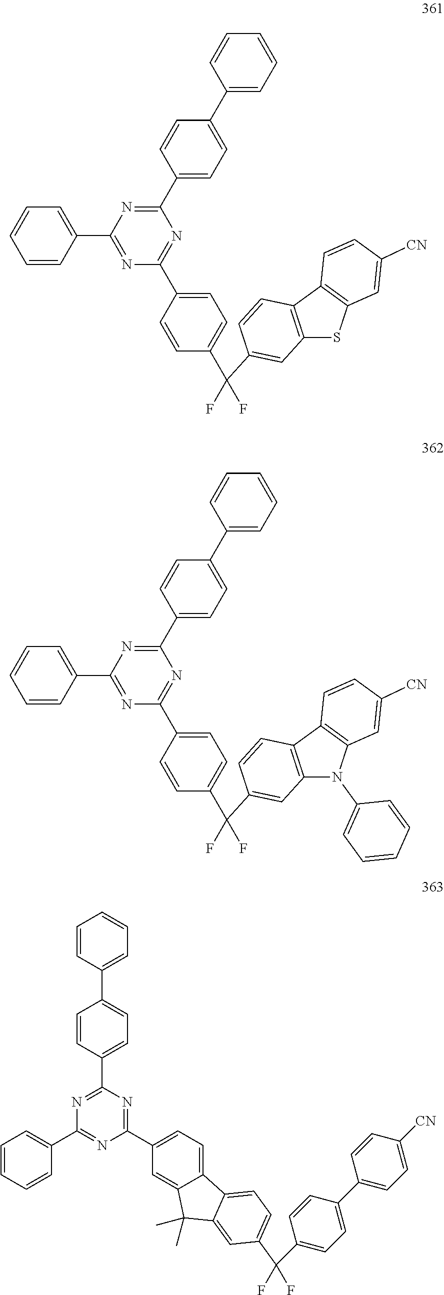

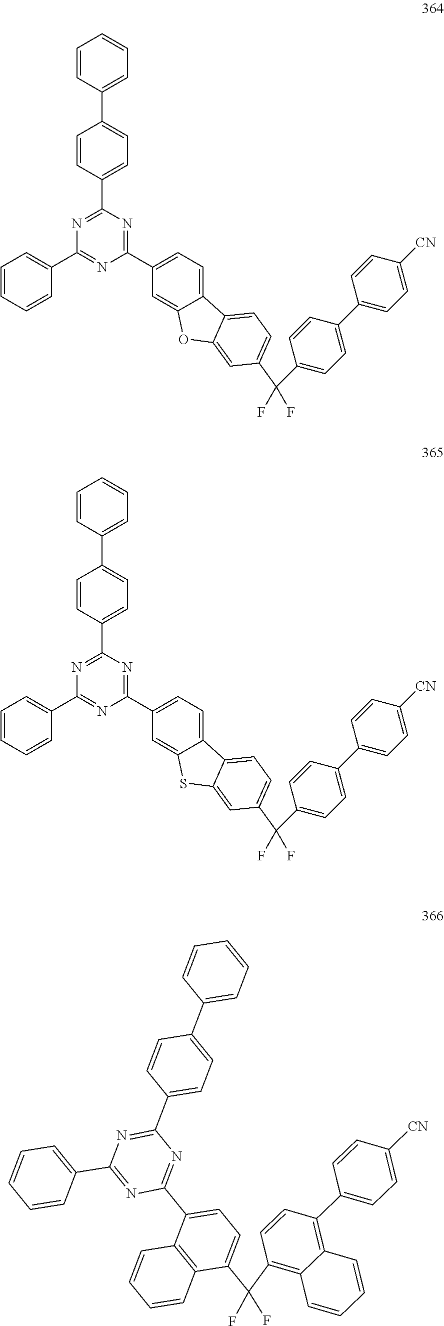 [SMILES: N#Cc1ccc(-c2ccc(C(F)(F)c3ccc4c(c3)oc3cc(-c5nc(-c6ccccc6)nc(-c6ccc(-c7ccccc7)cc6)n5)ccc34)cc2)cc1 ; N#Cc1ccc(-c2ccc(C(F)(F)c3ccc4c(c3)sc3cc(-c5nc(-c6ccccc6)nc(-c6ccc(-c7ccccc7)cc6)n5)ccc34)cc2)cc1 ; N#Cc1ccc(-c2ccc(C(F)(F)c3ccc(-c4nc(-c5ccccc5)nc(-c5ccc(-c6ccccc6)cc5)n4)c4ccccc34)c3ccccc23)cc1]

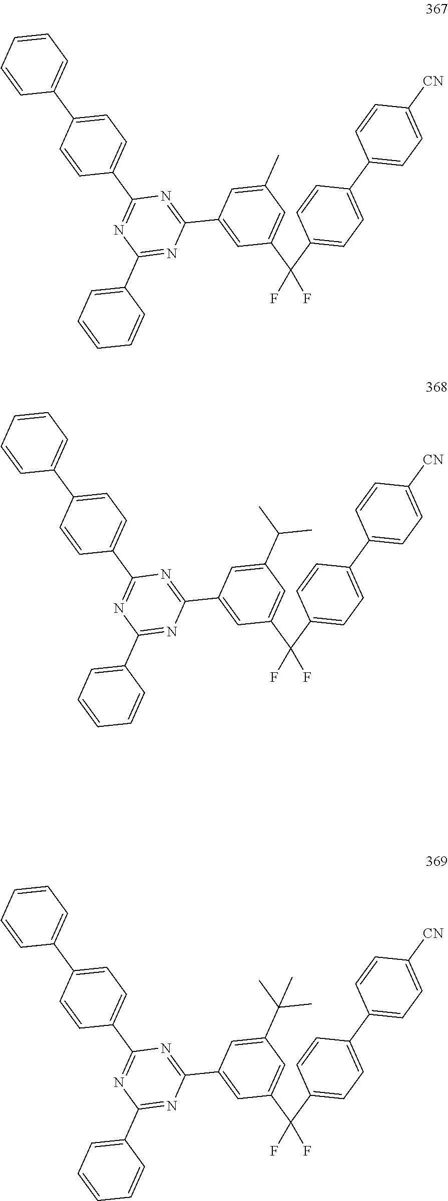 [SMILES: Cc1cc(-c2nc(-c3ccccc3)nc(-c3ccc(-c4ccccc4)cc3)n2)cc(C(F)(F)c2ccc(-c3ccc(C#N)cc3)cc2)c1 ; CC(C)c1cc(-c2nc(-c3ccccc3)nc(-c3ccc(-c4ccccc4)cc3)n2)cc(C(F)(F)c2ccc(-c3ccc(C#N)cc3)cc2)c1 ; CC(C)(C)c1cc(-c2nc(-c3ccccc3)nc(-c3ccc(-c4ccccc4)cc3)n2)cc(C(F)(F)c2ccc(-c3ccc(C#N)cc3)cc2)c1]

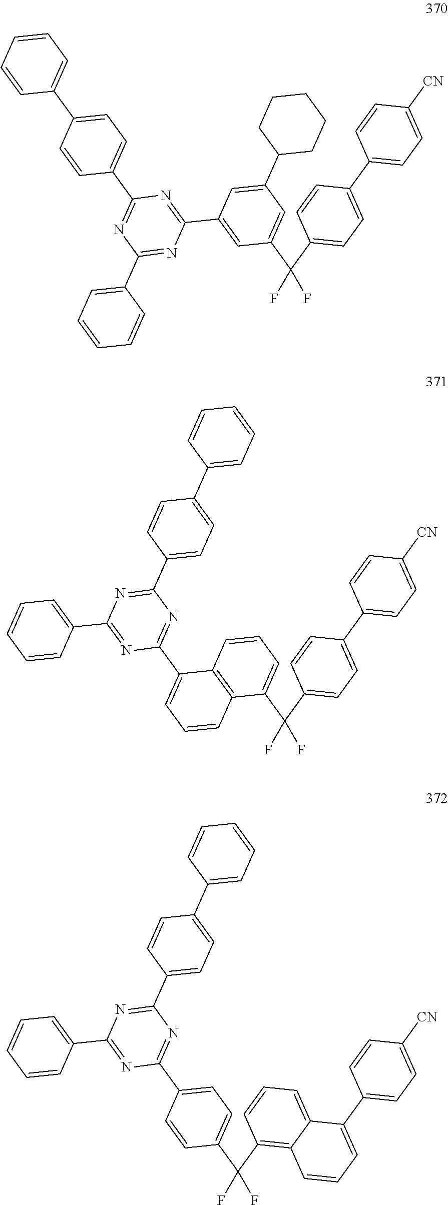 [SMILES: N#Cc1ccc(-c2ccc(C(F)(F)c3cc(-c4nc(-c5ccccc5)nc(-c5ccc(-c6ccccc6)cc5)n4)cc(C4CCCCC4)c3)cc2)cc1 ; N#Cc1ccc(-c2ccc(C(F)(F)c3cccc4c(-c5nc(-c6ccccc6)nc(-c6ccc(-c7ccccc7)cc6)n5)cccc34)cc2)cc1 ; N#Cc1ccc(-c2cccc3c(C(F)(F)c4ccc(-c5nc(-c6ccccc6)nc(-c6ccc(-c7ccccc7)cc6)n5)cc4)cccc23)cc1]

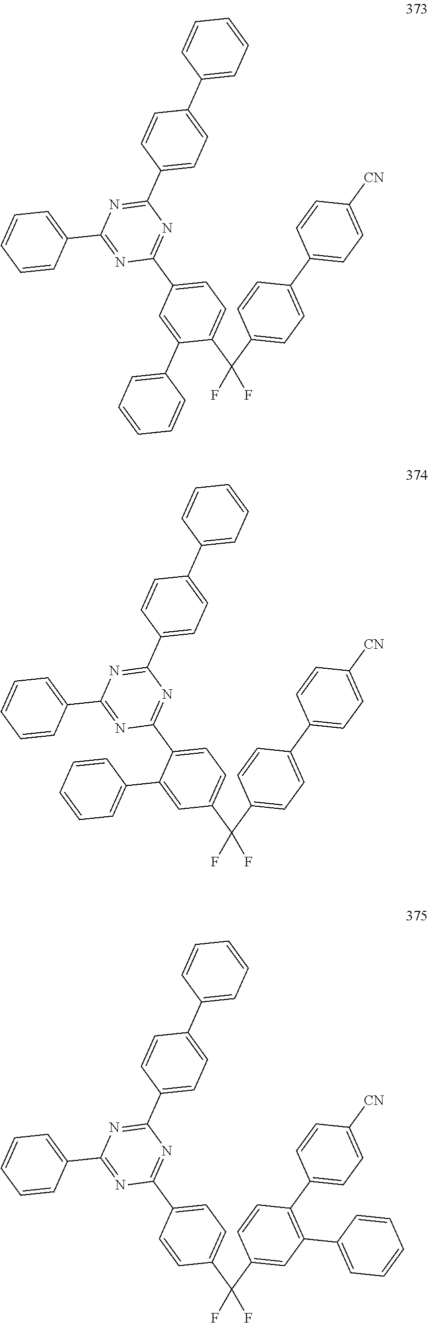 [SMILES: N#Cc1ccc(-c2ccc(C(F)(F)c3ccc(-c4nc(-c5ccccc5)nc(-c5ccc(-c6ccccc6)cc5)n4)cc3-c3ccccc3)cc2)cc1 ; N#Cc1ccc(-c2ccc(C(F)(F)c3ccc(-c4nc(-c5ccccc5)nc(-c5ccc(-c6ccccc6)cc5)n4)c(-c4ccccc4)c3)cc2)cc1 ; N#Cc1ccc(-c2ccc(C(F)(F)c3ccc(-c4nc(-c5ccccc5)nc(-c5ccc(-c6ccccc6)cc5)n4)cc3)cc2-c2ccccc2)cc1]

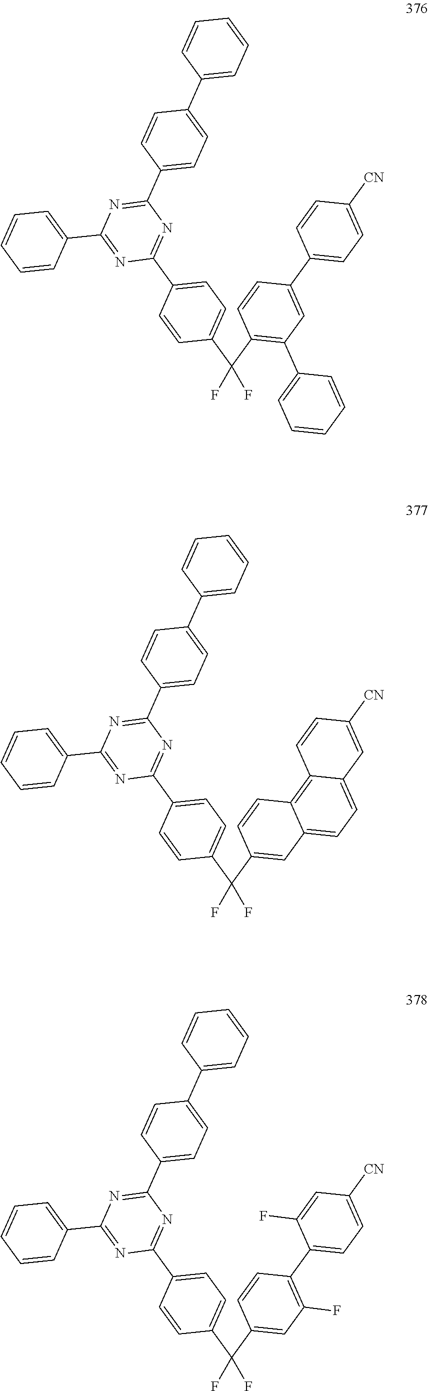 [SMILES: N#Cc1ccc(-c2ccc(C(F)(F)c3ccc(-c4nc(-c5ccccc5)nc(-c5ccc(-c6ccccc6)cc5)n4)cc3)c(-c3ccccc3)c2)cc1 ; N#Cc1ccc2c(ccc3cc(C(F)(F)c4ccc(-c5nc(-c6ccccc6)nc(-c6ccc(-c7ccccc7)cc6)n5)cc4)ccc32)c1 ; N#Cc1ccc(-c2ccc(C(F)(F)c3ccc(-c4nc(-c5ccccc5)nc(-c5ccc(-c6ccccc6)cc5)n4)cc3)cc2F)c(F)c1]

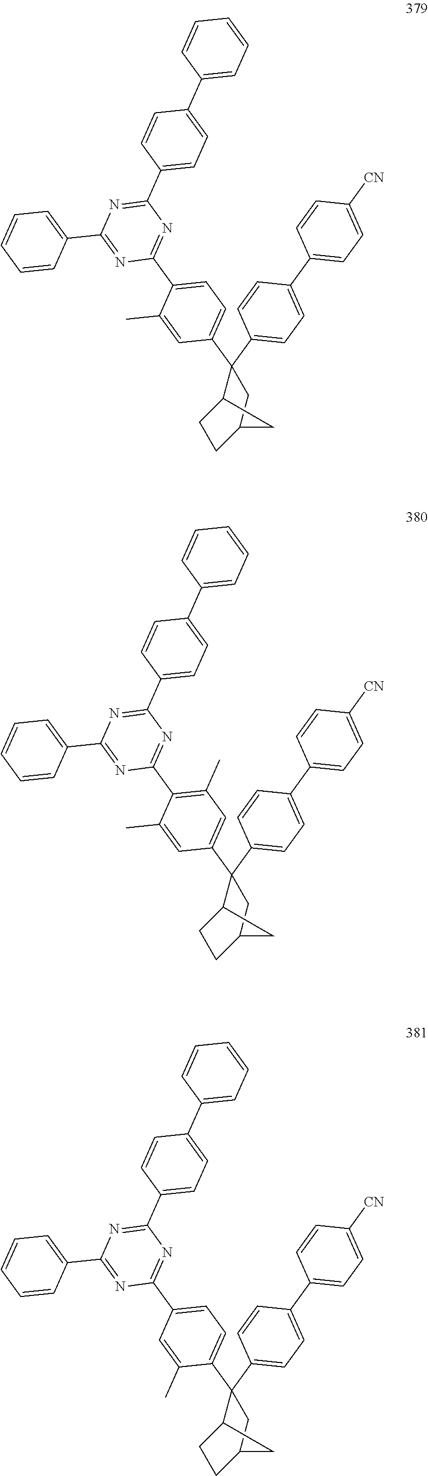 [SMILES: Cc1cc(C2(c3ccc(-c4ccc(C#N)cc4)cc3)CC3CCC2C3)ccc1-c1nc(-c2ccccc2)nc(-c2ccc(-c3ccccc3)cc2)n1 ; Cc1cc(C2(c3ccc(-c4ccc(C#N)cc4)cc3)CC3CCC2C3)cc(C)c1-c1nc(-c2ccccc2)nc(-c2ccc(-c3ccccc3)cc2)n1 ; Cc1cc(-c2nc(-c3ccccc3)nc(-c3ccc(-c4ccccc4)cc3)n2)ccc1C1(c2ccc(-c3ccc(C#N)cc3)cc2)CC2CCC1C2]

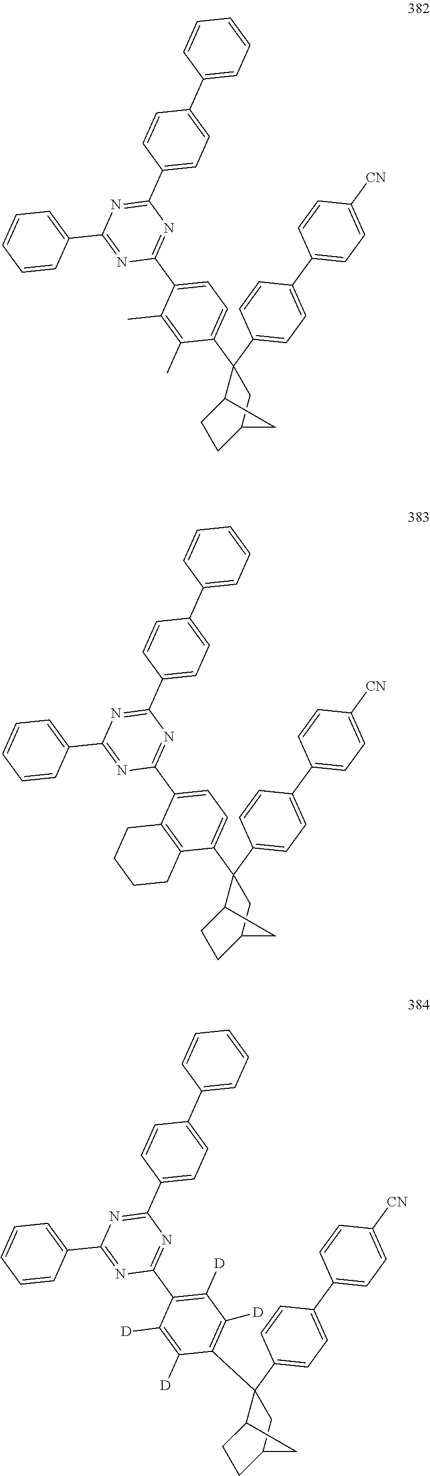 [SMILES: Cc1c(-c2nc(-c3ccccc3)nc(-c3ccc(-c4ccccc4)cc3)n2)ccc(C2(c3ccc(-c4ccc(C#N)cc4)cc3)CC3CCC2C3)c1C ; N#Cc1ccc(-c2ccc(C3(c4ccc(-c5nc(-c6ccccc6)nc(-c6ccc(-c7ccccc7)cc6)n5)c5c4CCCC5)CC4CCC3C4)cc2)cc1 ; [2H]c1c([2H])c(C2(c3ccc(-c4ccc(C#N)cc4)cc3)CC3CCC2C3)c([2H])c([2H])c1-c1nc(-c2ccccc2)nc(-c2ccc(-c3ccccc3)cc2)n1]

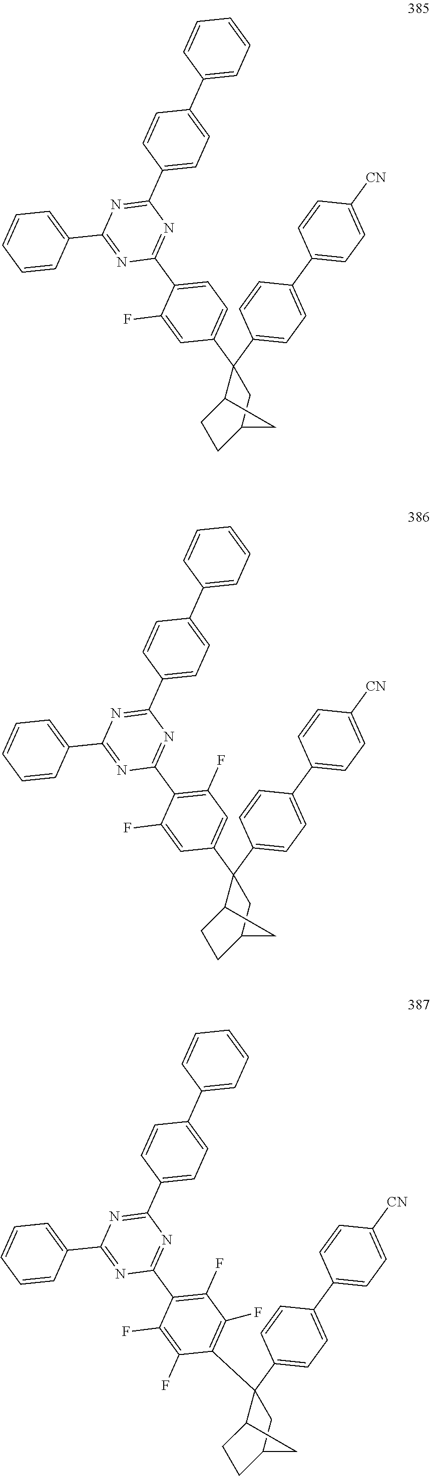 [SMILES: N#Cc1ccc(-c2ccc(C3(c4ccc(-c5nc(-c6ccccc6)nc(-c6ccc(-c7ccccc7)cc6)n5)c(F)c4)CC4CCC3C4)cc2)cc1 ; N#Cc1ccc(-c2ccc(C3(c4cc(F)c(-c5nc(-c6ccccc6)nc(-c6ccc(-c7ccccc7)cc6)n5)c(F)c4)CC4CCC3C4)cc2)cc1 ; N#Cc1ccc(-c2ccc(C3(c4c(F)c(F)c(-c5nc(-c6ccccc6)nc(-c6ccc(-c7ccccc7)cc6)n5)c(F)c4F)CC4CCC3C4)cc2)cc1]

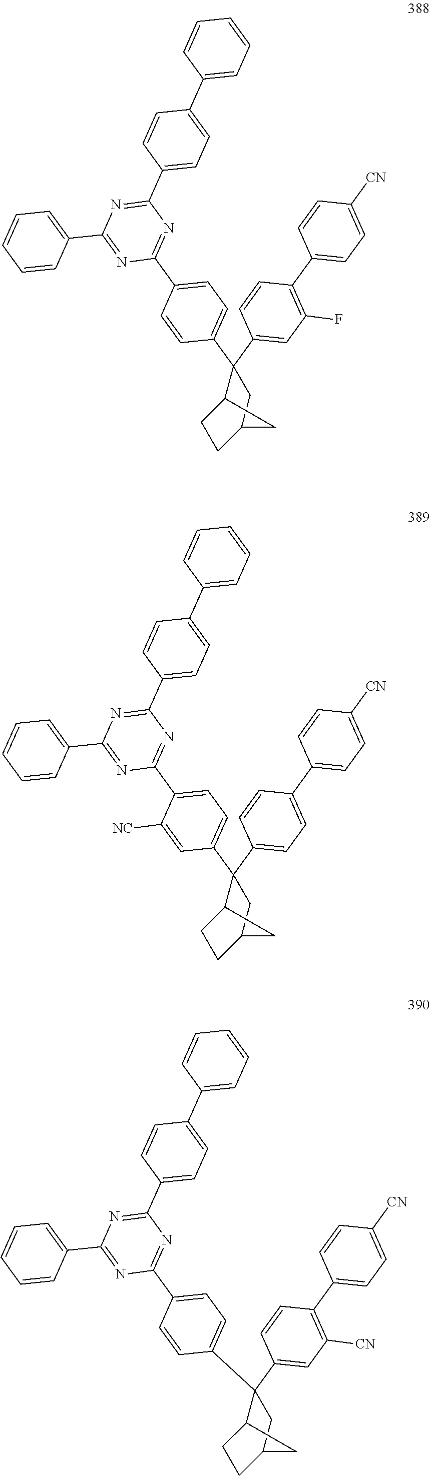 [SMILES: N#Cc1ccc(-c2ccc(C3(c4ccc(-c5nc(-c6ccccc6)nc(-c6ccc(-c7ccccc7)cc6)n5)cc4)CC4CCC3C4)cc2F)cc1 ; N#Cc1ccc(-c2ccc(C3(c4ccc(-c5nc(-c6ccccc6)nc(-c6ccc(-c7ccccc7)cc6)n5)c(C#N)c4)CC4CCC3C4)cc2)cc1 ; N#Cc1ccc(-c2ccc(C3(c4ccc(-c5nc(-c6ccccc6)nc(-c6ccc(-c7ccccc7)cc6)n5)cc4)CC4CCC3C4)cc2C#N)cc1]

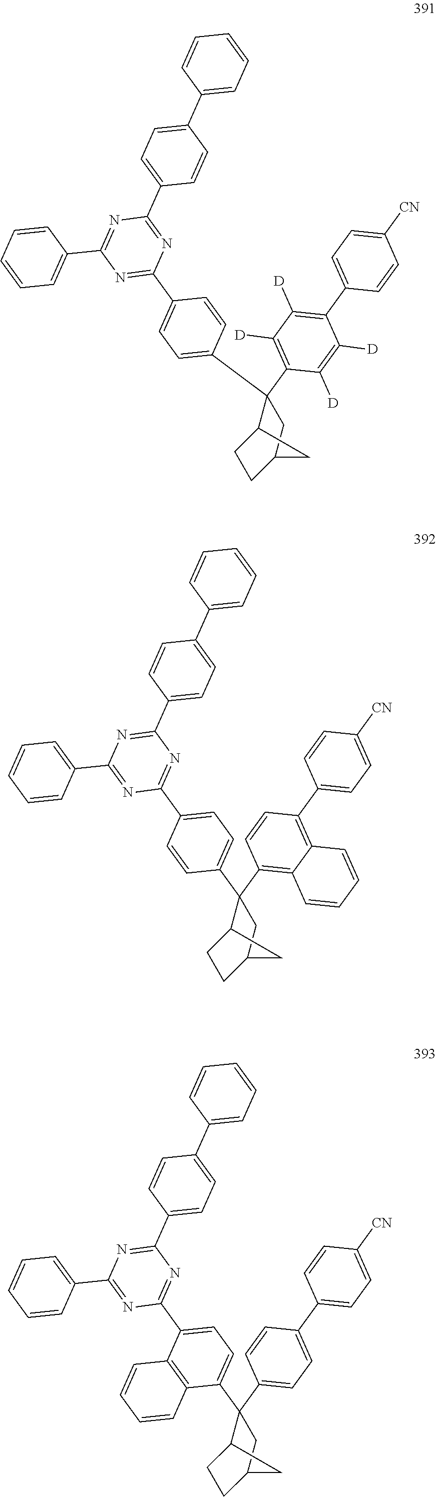 [SMILES: [2H]c1c([2H])c(C2(c3ccc(-c4nc(-c5ccccc5)nc(-c5ccc(-c6ccccc6)cc5)n4)cc3)CC3CCC2C3)c([2H])c([2H])c1-c1ccc(C#N)cc1 ; N#Cc1ccc(-c2ccc(C3(c4ccc(-c5nc(-c6ccccc6)nc(-c6ccc(-c7ccccc7)cc6)n5)cc4)CC4CCC3C4)c3ccccc23)cc1 ; N#Cc1ccc(-c2ccc(C3(c4ccc(-c5nc(-c6ccccc6)nc(-c6ccc(-c7ccccc7)cc6)n5)c5ccccc45)CC4CCC3C4)cc2)cc1]

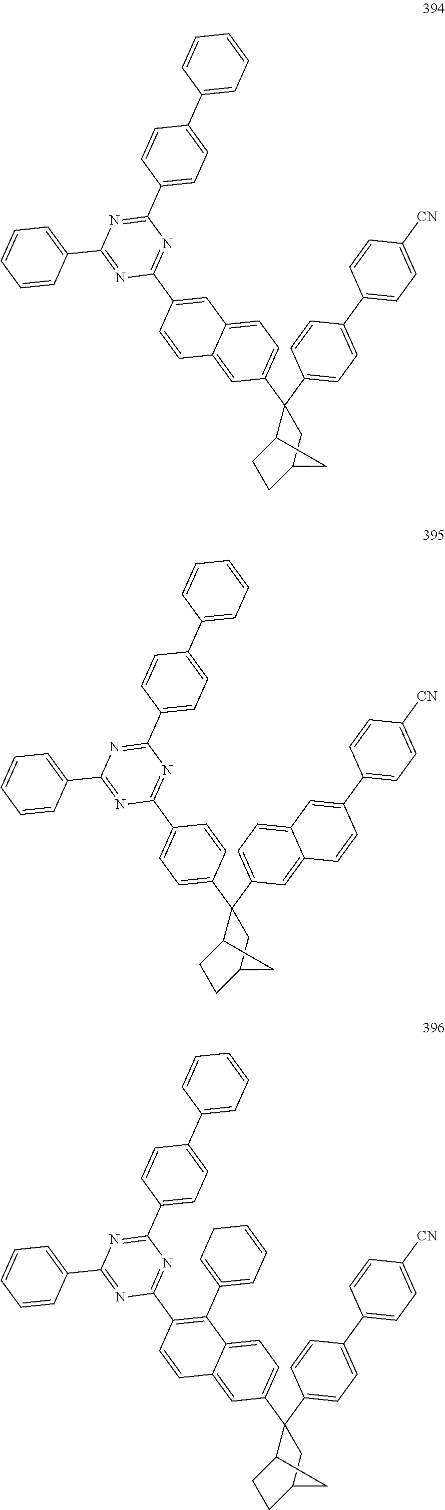

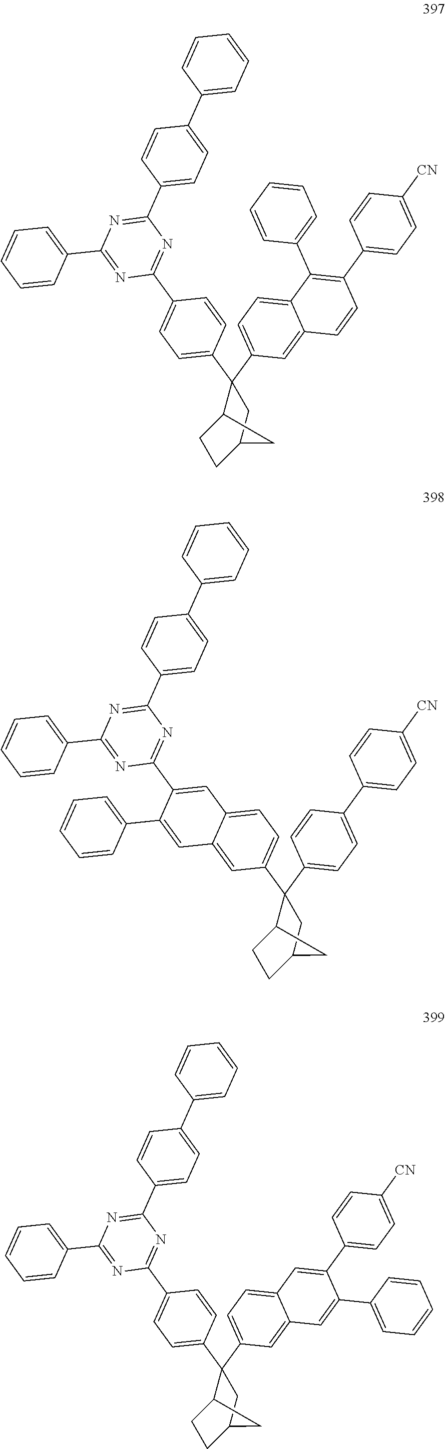 [SMILES: N#Cc1ccc(-c2ccc3cc(C4(c5ccc(-c6nc(-c7ccccc7)nc(-c7ccc(-c8ccccc8)cc7)n6)cc5)CC5CCC4C5)ccc3c2-c2ccccc2)cc1 ; N#Cc1ccc(-c2ccc(C3(c4ccc5cc(-c6nc(-c7ccccc7)nc(-c7ccc(-c8ccccc8)cc7)n6)c(-c6ccccc6)cc5c4)CC4CCC3C4)cc2)cc1 ; N#Cc1ccc(-c2cc3ccc(C4(c5ccc(-c6nc(-c7ccccc7)nc(-c7ccc(-c8ccccc8)cc7)n6)cc5)CC5CCC4C5)cc3cc2-c2ccccc2)cc1]

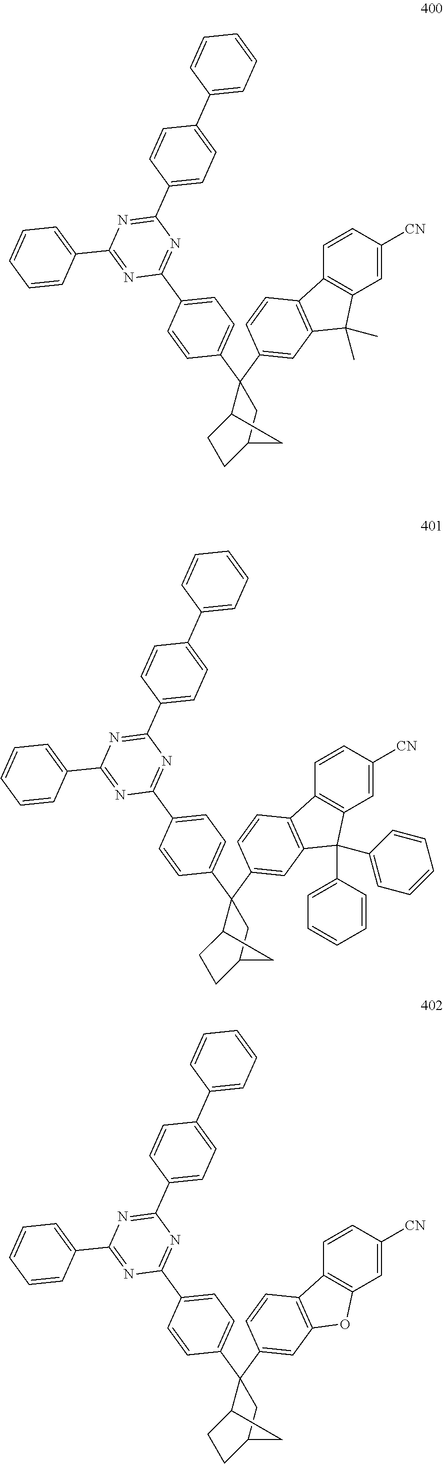 [SMILES: CC1(C)c2cc(C#N)ccc2-c2ccc(C3(c4ccc(-c5nc(-c6ccccc6)nc(-c6ccc(-c7ccccc7)cc6)n5)cc4)CC4CCC3C4)cc21 ; N#Cc1ccc2c(c1)C(c1ccccc1)(c1ccccc1)c1cc(C3(c4ccc(-c5nc(-c6ccccc6)nc(-c6ccc(-c7ccccc7)cc6)n5)cc4)CC4CCC3C4)ccc1-2 ; N#Cc1ccc2c(c1)oc1cc(C3(c4ccc(-c5nc(-c6ccccc6)nc(-c6ccc(-c7ccccc7)cc6)n5)cc4)CC4CCC3C4)ccc12]

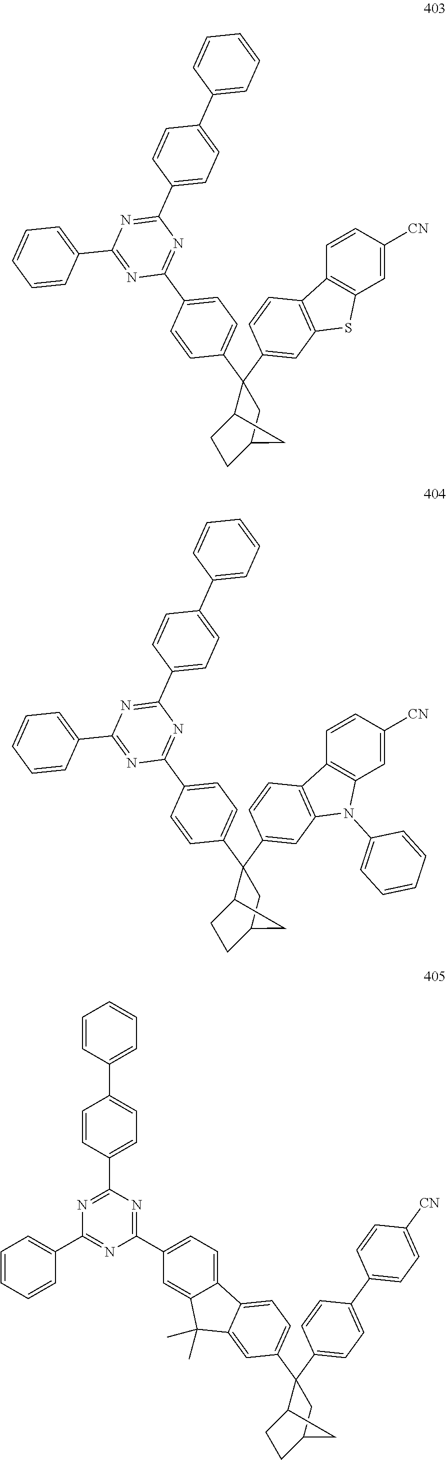 [SMILES: N#Cc1ccc2c(c1)sc1cc(C3(c4ccc(-c5nc(-c6ccccc6)nc(-c6ccc(-c7ccccc7)cc6)n5)cc4)CC4CCC3C4)ccc12 ; N#Cc1ccc2c3ccc(C4(c5ccc(-c6nc(-c7ccccc7)nc(-c7ccc(-c8ccccc8)cc7)n6)cc5)CC5CCC4C5)cc3n(-c3ccccc3)c2c1 ; CC1(C)c2cc(-c3nc(-c4ccccc4)nc(-c4ccc(-c5ccccc5)cc4)n3)ccc2-c2ccc(C3(c4ccc(-c5ccc(C#N)cc5)cc4)CC4CCC3C4)cc21]

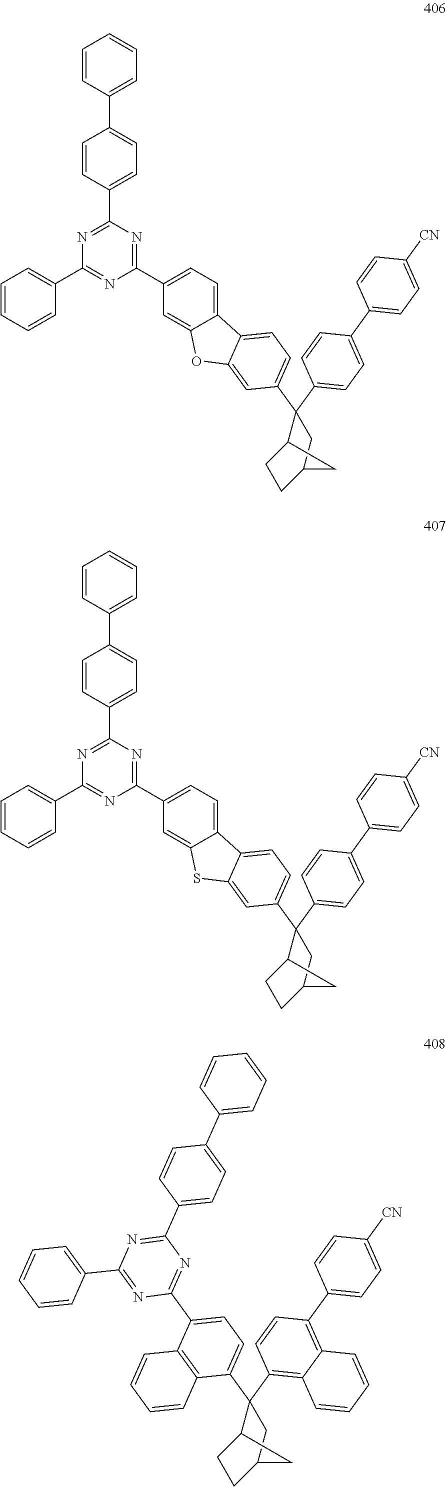 [SMILES: N#Cc1ccc(-c2ccc(C3(c4ccc5c(c4)oc4cc(-c6nc(-c7ccccc7)nc(-c7ccc(-c8ccccc8)cc7)n6)ccc45)CC4CCC3C4)cc2)cc1 ; N#Cc1ccc(-c2ccc(C3(c4ccc5c(c4)sc4cc(-c6nc(-c7ccccc7)nc(-c7ccc(-c8ccccc8)cc7)n6)ccc45)CC4CCC3C4)cc2)cc1 ; N#Cc1ccc(-c2ccc(C3(c4ccc(-c5nc(-c6ccccc6)nc(-c6ccc(-c7ccccc7)cc6)n5)c5ccccc45)CC4CCC3C4)c3ccccc23)cc1]

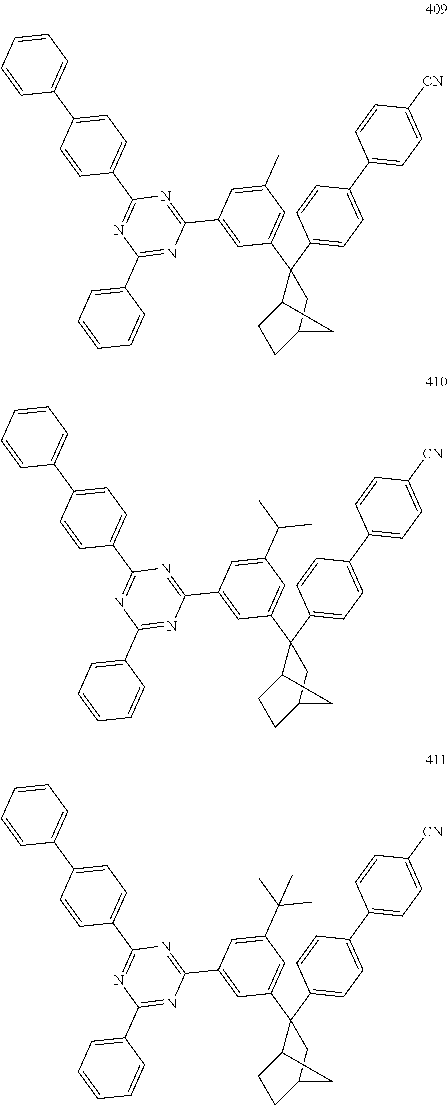 [SMILES: Cc1cc(-c2nc(-c3ccccc3)nc(-c3ccc(-c4ccccc4)cc3)n2)cc(C2(c3ccc(-c4ccc(C#N)cc4)cc3)CC3CCC2C3)c1 ; CC(C)c1cc(-c2nc(-c3ccccc3)nc(-c3ccc(-c4ccccc4)cc3)n2)cc(C2(c3ccc(-c4ccc(C#N)cc4)cc3)CC3CCC2C3)c1 ; CC(C)(C)c1cc(-c2nc(-c3ccccc3)nc(-c3ccc(-c4ccccc4)cc3)n2)cc(C2(c3ccc(-c4ccc(C#N)cc4)cc3)CC3CCC2C3)c1]

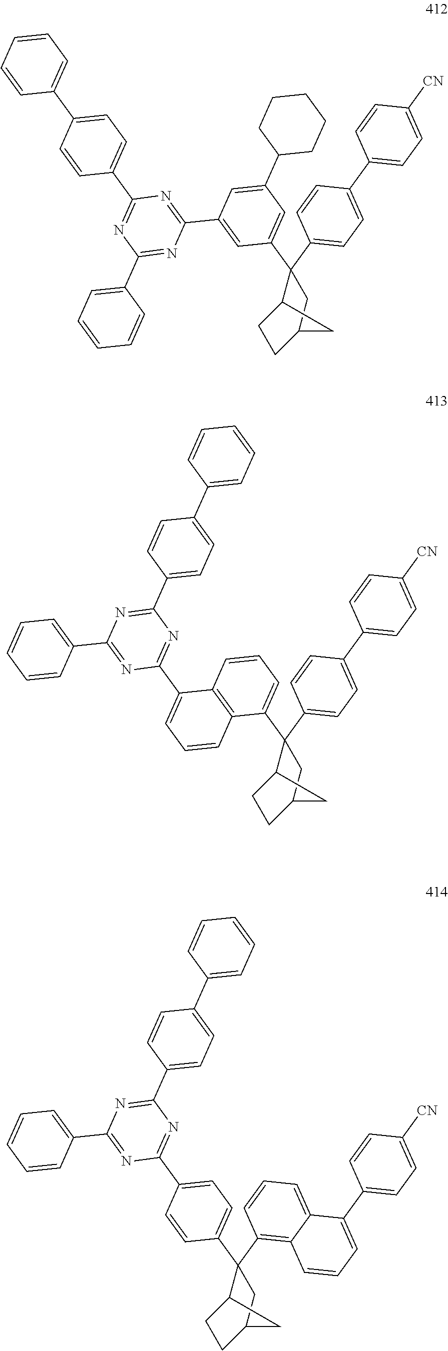 [SMILES: N#Cc1ccc(-c2ccc(C3(c4cc(-c5nc(-c6ccccc6)nc(-c6ccc(-c7ccccc7)cc6)n5)cc(C5CCCCC5)c4)CC4CCC3C4)cc2)cc1 ; N#Cc1ccc(-c2ccc(C3(c4cccc5c(-c6nc(-c7ccccc7)nc(-c7ccc(-c8ccccc8)cc7)n6)cccc45)CC4CCC3C4)cc2)cc1 ; N#Cc1ccc(-c2cccc3c(C4(c5ccc(-c6nc(-c7ccccc7)nc(-c7ccc(-c8ccccc8)cc7)n6)cc5)CC5CCC4C5)cccc23)cc1]

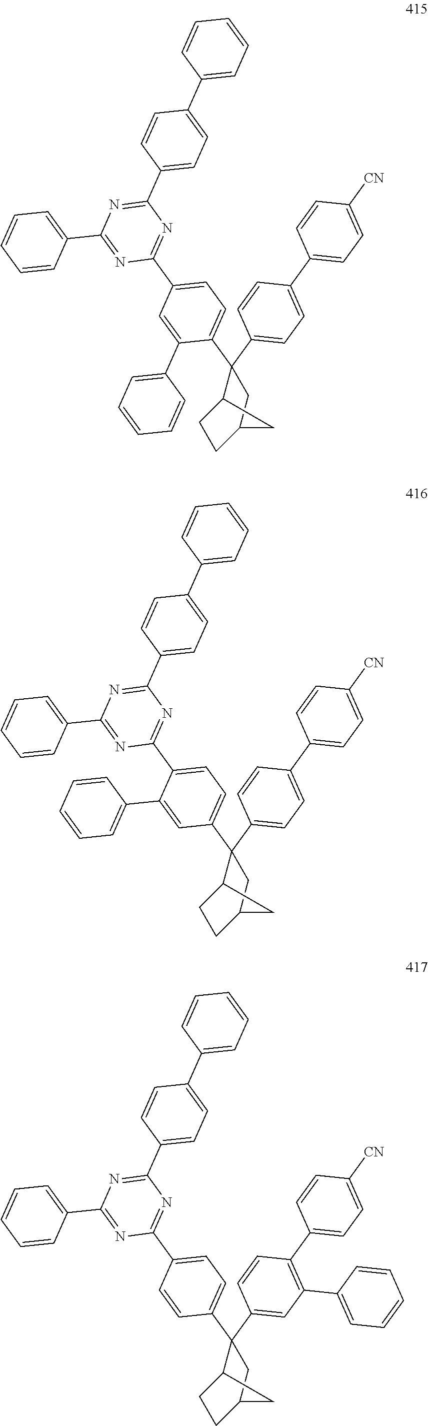 [SMILES: N#Cc1ccc(-c2ccc(C3(c4ccc(-c5nc(-c6ccccc6)nc(-c6ccc(-c7ccccc7)cc6)n5)cc4-c4ccccc4)CC4CCC3C4)cc2)cc1 ; N#Cc1ccc(-c2ccc(C3(c4ccc(-c5nc(-c6ccccc6)nc(-c6ccc(-c7ccccc7)cc6)n5)c(-c5ccccc5)c4)CC4CCC3C4)cc2)cc1 ; N#Cc1ccc(-c2ccc(C3(c4ccc(-c5nc(-c6ccccc6)nc(-c6ccc(-c7ccccc7)cc6)n5)cc4)CC4CCC3C4)cc2-c2ccccc2)cc1]

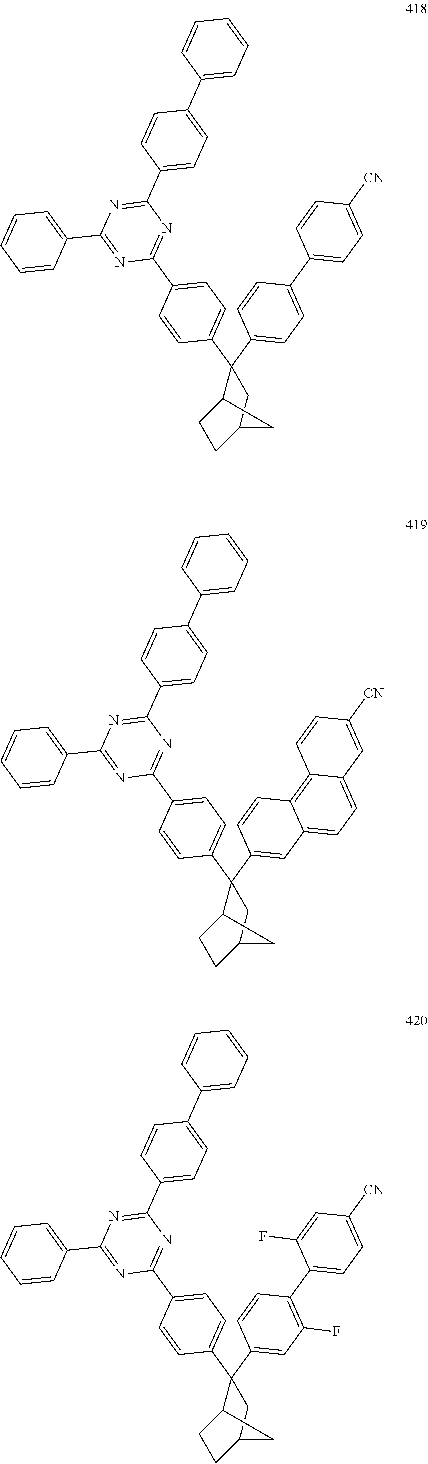 [SMILES: N#Cc1ccc(-c2ccc(C3(c4ccc(-c5nc(-c6ccccc6)nc(-c6ccc(-c7ccccc7)cc6)n5)cc4)CC4CCC3C4)cc2)cc1 ; N#Cc1ccc2c(ccc3cc(C4(c5ccc(-c6nc(-c7ccccc7)nc(-c7ccc(-c8ccccc8)cc7)n6)cc5)CC5CCC4C5)ccc32)c1 ; N#Cc1ccc(-c2ccc(C3(c4ccc(-c5nc(-c6ccccc6)nc(-c6ccc(-c7ccccc7)cc6)n5)cc4)CC4CCC3C4)cc2F)c(F)c1]

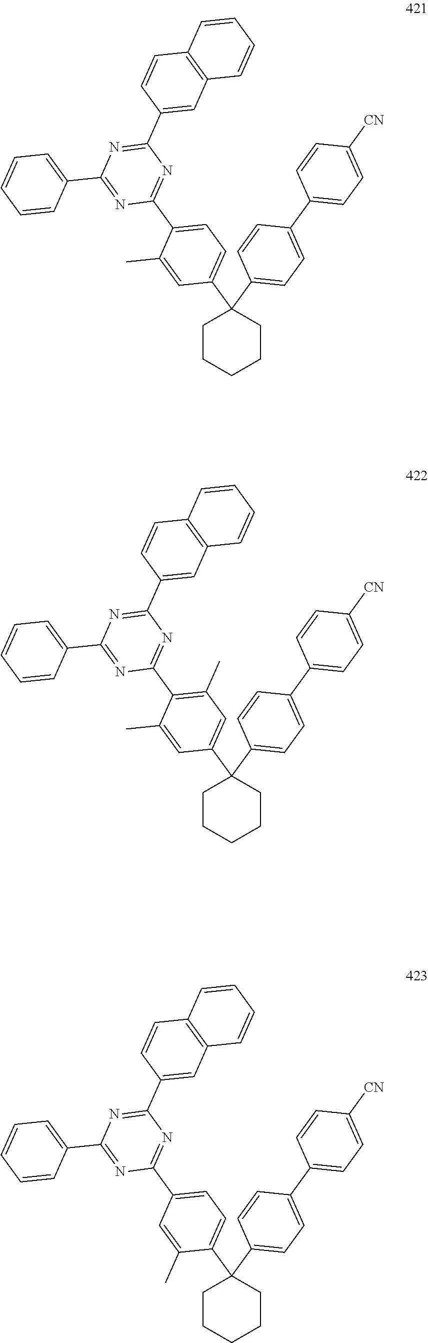 [SMILES: Cc1cc(C2(c3ccc(-c4ccc(C#N)cc4)cc3)CCCCC2)ccc1-c1nc(-c2ccccc2)nc(-c2ccc3ccccc3c2)n1 ; Cc1cc(C2(c3ccc(-c4ccc(C#N)cc4)cc3)CCCCC2)cc(C)c1-c1nc(-c2ccccc2)nc(-c2ccc3ccccc3c2)n1 ; Cc1cc(-c2nc(-c3ccccc3)nc(-c3ccc4ccccc4c3)n2)ccc1C1(c2ccc(-c3ccc(C#N)cc3)cc2)CCCCC1]

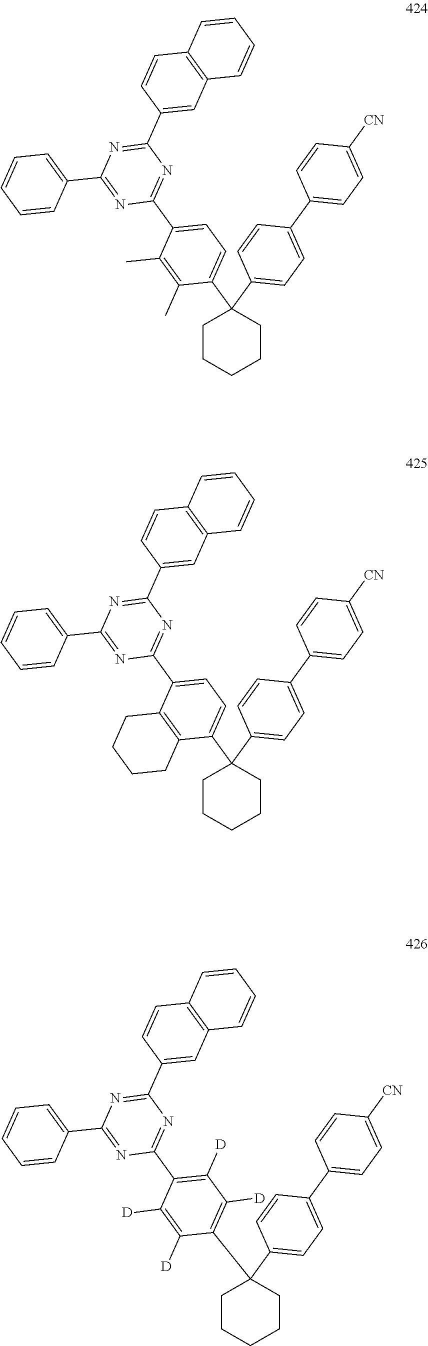 [SMILES: Cc1c(-c2nc(-c3ccccc3)nc(-c3ccc4ccccc4c3)n2)ccc(C2(c3ccc(-c4ccc(C#N)cc4)cc3)CCCCC2)c1C ; N#Cc1ccc(-c2ccc(C3(c4ccc(-c5nc(-c6ccccc6)nc(-c6ccc7ccccc7c6)n5)c5c4CCCC5)CCCCC3)cc2)cc1 ; [2H]c1c([2H])c(C2(c3ccc(-c4ccc(C#N)cc4)cc3)CCCCC2)c([2H])c([2H])c1-c1nc(-c2ccccc2)nc(-c2ccc3ccccc3c2)n1]

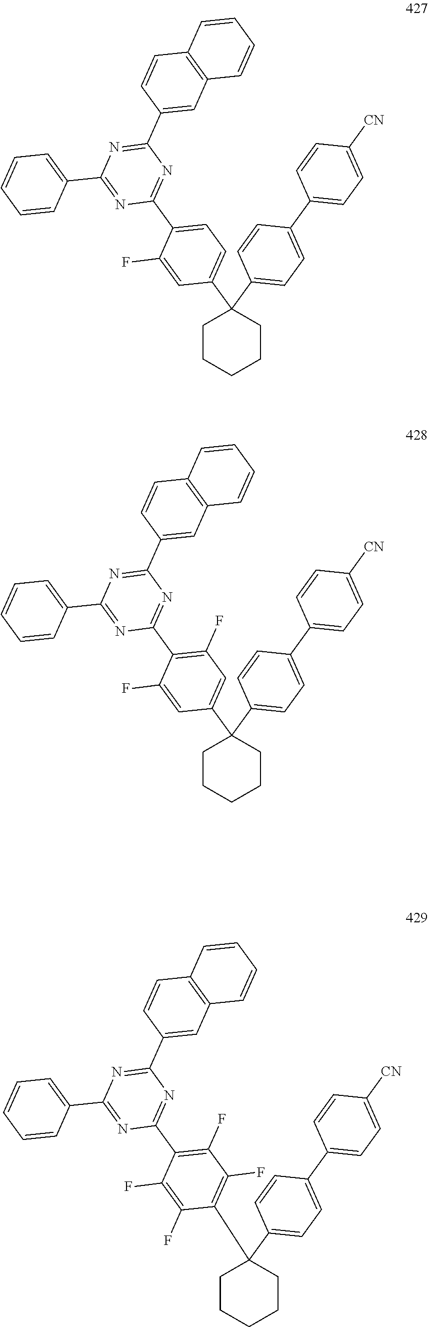 [SMILES: N#Cc1ccc(-c2ccc(C3(c4ccc(-c5nc(-c6ccccc6)nc(-c6ccc7ccccc7c6)n5)c(F)c4)CCCCC3)cc2)cc1 ; N#Cc1ccc(-c2ccc(C3(c4cc(F)c(-c5nc(-c6ccccc6)nc(-c6ccc7ccccc7c6)n5)c(F)c4)CCCCC3)cc2)cc1 ; N#Cc1ccc(-c2ccc(C3(c4c(F)c(F)c(-c5nc(-c6ccccc6)nc(-c6ccc7ccccc7c6)n5)c(F)c4F)CCCCC3)cc2)cc1]

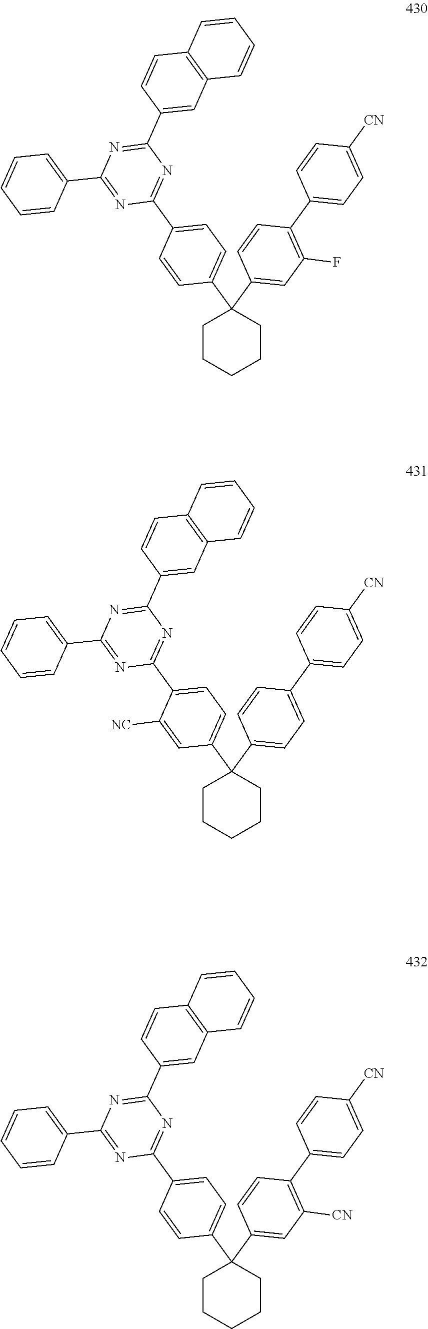 [SMILES: N#Cc1ccc(-c2ccc(C3(c4ccc(-c5nc(-c6ccccc6)nc(-c6ccc7ccccc7c6)n5)cc4)CCCCC3)cc2F)cc1 ; N#Cc1ccc(-c2ccc(C3(c4ccc(-c5nc(-c6ccccc6)nc(-c6ccc7ccccc7c6)n5)c(C#N)c4)CCCCC3)cc2)cc1 ; N#Cc1ccc(-c2ccc(C3(c4ccc(-c5nc(-c6ccccc6)nc(-c6ccc7ccccc7c6)n5)cc4)CCCCC3)cc2C#N)cc1]

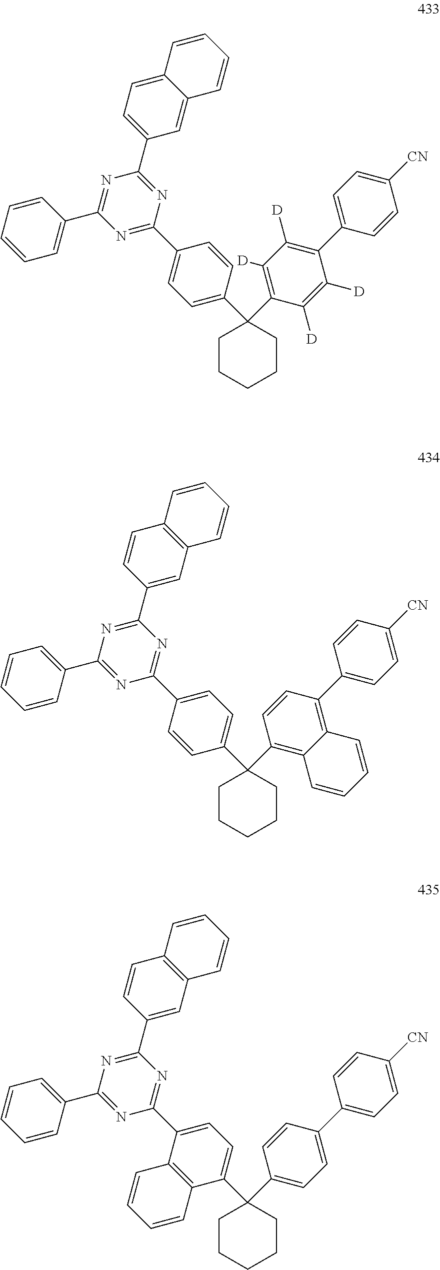 [SMILES: [2H]c1c([2H])c(C2(c3ccc(-c4nc(-c5ccccc5)nc(-c5ccc6ccccc6c5)n4)cc3)CCCCC2)c([2H])c([2H])c1-c1ccc(C#N)cc1 ; N#Cc1ccc(-c2ccc(C3(c4ccc(-c5nc(-c6ccccc6)nc(-c6ccc7ccccc7c6)n5)cc4)CCCCC3)c3ccccc23)cc1 ; N#Cc1ccc(-c2ccc(C3(c4ccc(-c5nc(-c6ccccc6)nc(-c6ccc7ccccc7c6)n5)c5ccccc45)CCCCC3)cc2)cc1]

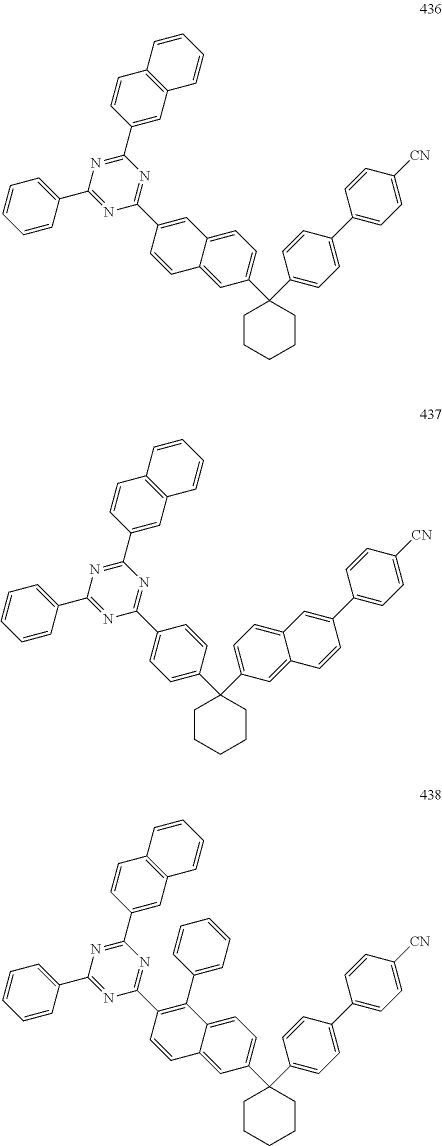 [SMILES: N#Cc1ccc(-c2ccc(C3(c4ccc5cc(-c6nc(-c7ccccc7)nc(-c7ccc8ccccc8c7)n6)ccc5c4)CCCCC3)cc2)cc1 ; N#Cc1ccc(-c2ccc3cc(C4(c5ccc(-c6nc(-c7ccccc7)nc(-c7ccc8ccccc8c7)n6)cc5)CCCCC4)ccc3c2)cc1 ; N#Cc1ccc(-c2ccc(C3(c4ccc5c(-c6ccccc6)c(-c6nc(-c7ccccc7)nc(-c7ccc8ccccc8c7)n6)ccc5c4)CCCCC3)cc2)cc1]

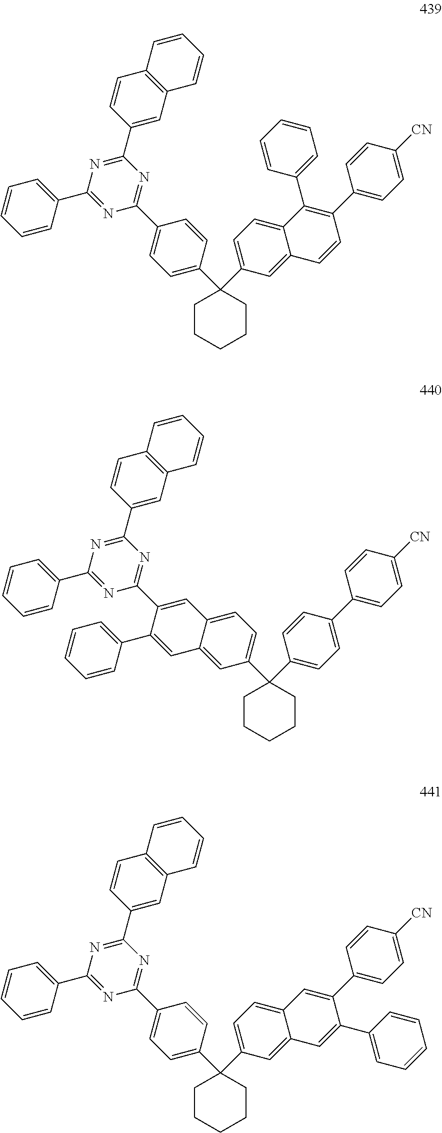 [SMILES: N#Cc1ccc(-c2ccc3cc(C4(c5ccc(-c6nc(-c7ccccc7)nc(-c7ccc8ccccc8c7)n6)cc5)CCCCC4)ccc3c2-c2ccccc2)cc1 ; N#Cc1ccc(-c2ccc(C3(c4ccc5cc(-c6nc(-c7ccccc7)nc(-c7ccc8ccccc8c7)n6)c(-c6ccccc6)cc5c4)CCCCC3)cc2)cc1 ; N#Cc1ccc(-c2cc3ccc(C4(c5ccc(-c6nc(-c7ccccc7)nc(-c7ccc8ccccc8c7)n6)cc5)CCCCC4)cc3cc2-c2ccccc2)cc1]

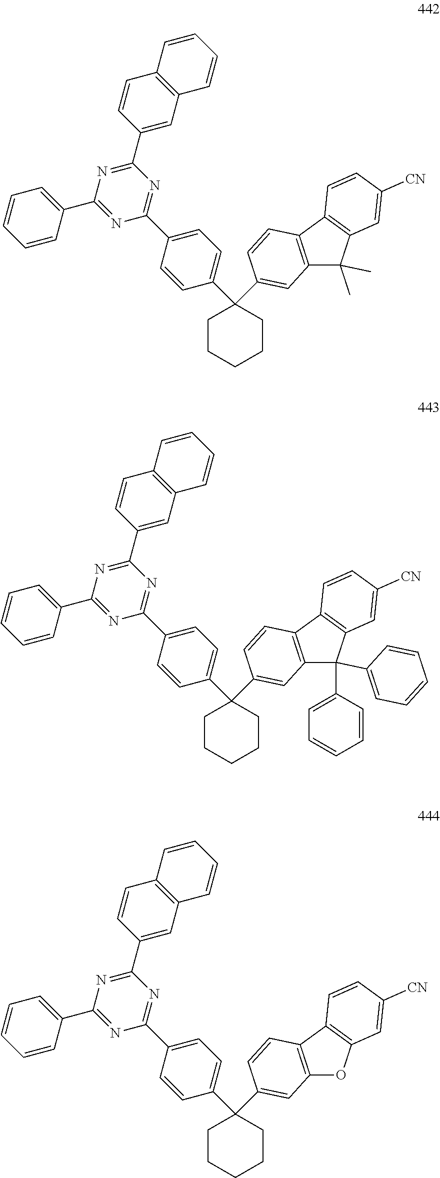 [SMILES: CC1(C)c2cc(C#N)ccc2-c2ccc(C3(c4ccc(-c5nc(-c6ccccc6)nc(-c6ccc7ccccc7c6)n5)cc4)CCCCC3)cc21 ; N#Cc1ccc2c(c1)C(c1ccccc1)(c1ccccc1)c1cc(C3(c4ccc(-c5nc(-c6ccccc6)nc(-c6ccc7ccccc7c6)n5)cc4)CCCCC3)ccc1-2 ; N#Cc1ccc2c(c1)oc1cc(C3(c4ccc(-c5nc(-c6ccccc6)nc(-c6ccc7ccccc7c6)n5)cc4)CCCCC3)ccc12]

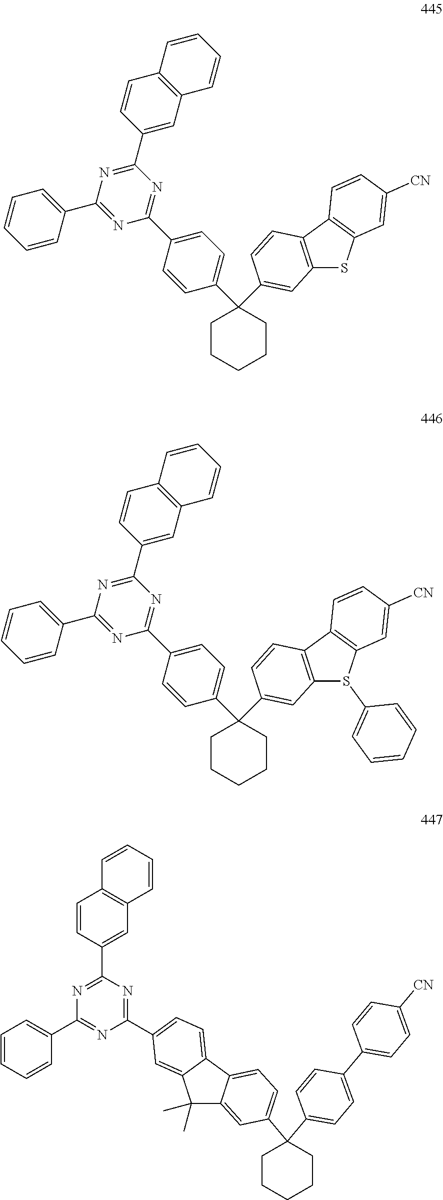

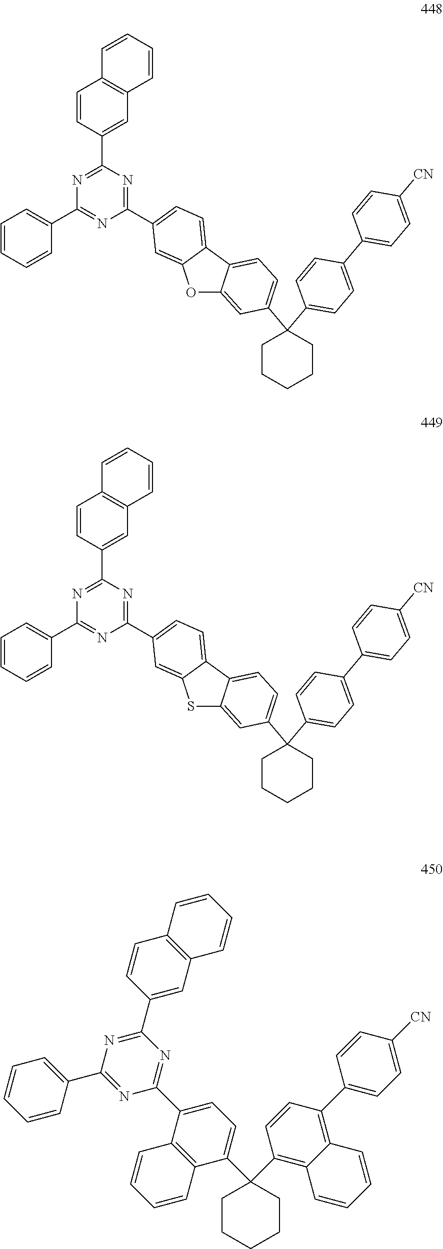 [SMILES: N#Cc1ccc(-c2ccc(C3(c4ccc5c(c4)oc4cc(-c6nc(-c7ccccc7)nc(-c7ccc8ccccc8c7)n6)ccc45)CCCCC3)cc2)cc1 ; N#Cc1ccc(-c2ccc(C3(c4ccc5c(c4)sc4cc(-c6nc(-c7ccccc7)nc(-c7ccc8ccccc8c7)n6)ccc45)CCCCC3)cc2)cc1 ; N#Cc1ccc(-c2ccc(C3(c4ccc(-c5nc(-c6ccccc6)nc(-c6ccc7ccccc7c6)n5)c5ccccc45)CCCCC3)c3ccccc23)cc1]

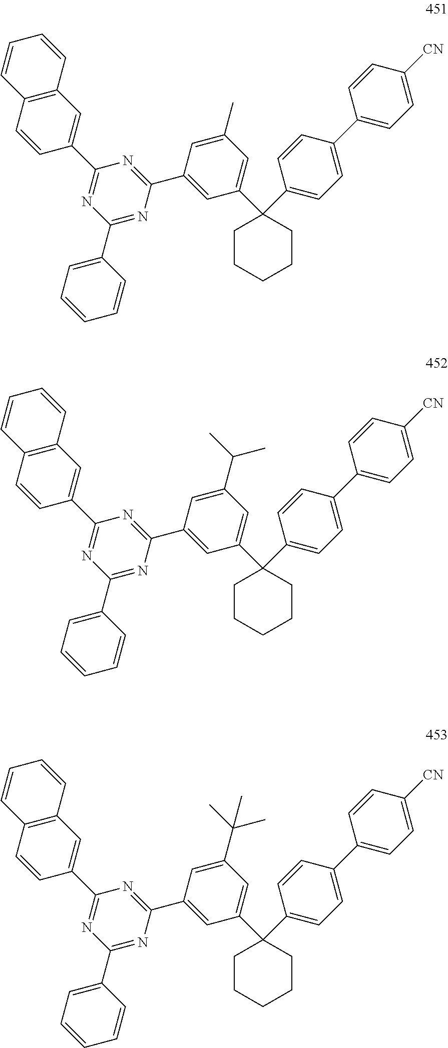 [SMILES: Cc1cc(-c2nc(-c3ccccc3)nc(-c3ccc4ccccc4c3)n2)cc(C2(c3ccc(-c4ccc(C#N)cc4)cc3)CCCCC2)c1 ; CC(C)c1cc(-c2nc(-c3ccccc3)nc(-c3ccc4ccccc4c3)n2)cc(C2(c3ccc(-c4ccc(C#N)cc4)cc3)CCCCC2)c1 ; CC(C)(C)c1cc(-c2nc(-c3ccccc3)nc(-c3ccc4ccccc4c3)n2)cc(C2(c3ccc(-c4ccc(C#N)cc4)cc3)CCCCC2)c1]

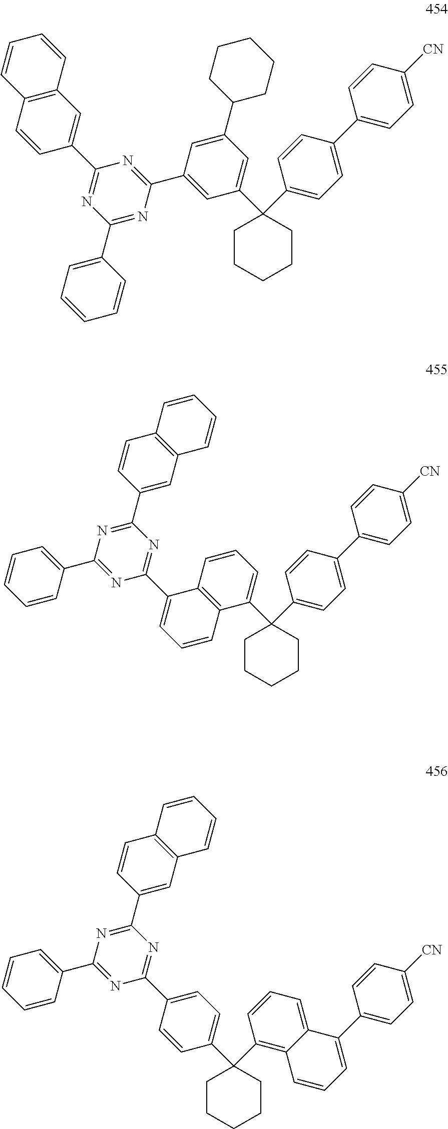 [SMILES: N#Cc1ccc(-c2ccc(C3(c4cc(-c5nc(-c6ccccc6)nc(-c6ccc7ccccc7c6)n5)cc(C5CCCCC5)c4)CCCCC3)cc2)cc1 ; N#Cc1ccc(-c2ccc(C3(c4cccc5c(-c6nc(-c7ccccc7)nc(-c7ccc8ccccc8c7)n6)cccc45)CCCCC3)cc2)cc1 ; N#Cc1ccc(-c2cccc3c(C4(c5ccc(-c6nc(-c7ccccc7)nc(-c7ccc8ccccc8c7)n6)cc5)CCCCC4)cccc23)cc1]

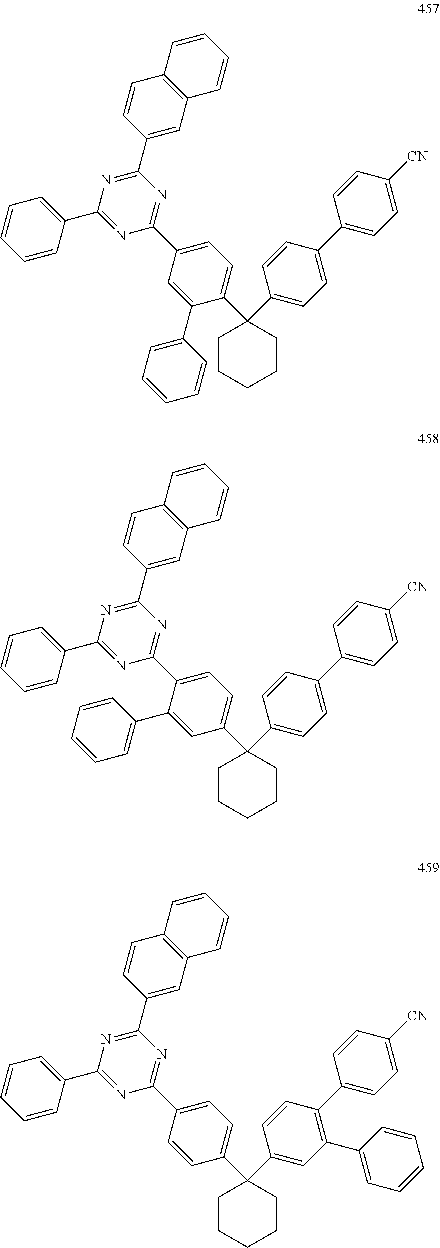 [SMILES: N#Cc1ccc(-c2ccc(C3(c4ccc(-c5nc(-c6ccccc6)nc(-c6ccc7ccccc7c6)n5)cc4-c4ccccc4)CCCCC3)cc2)cc1 ; N#Cc1ccc(-c2ccc(C3(c4ccc(-c5nc(-c6ccccc6)nc(-c6ccc7ccccc7c6)n5)c(-c5ccccc5)c4)CCCCC3)cc2)cc1 ; N#Cc1ccc(-c2ccc(C3(c4ccc(-c5nc(-c6ccccc6)nc(-c6ccc7ccccc7c6)n5)cc4)CCCCC3)cc2-c2ccccc2)cc1]

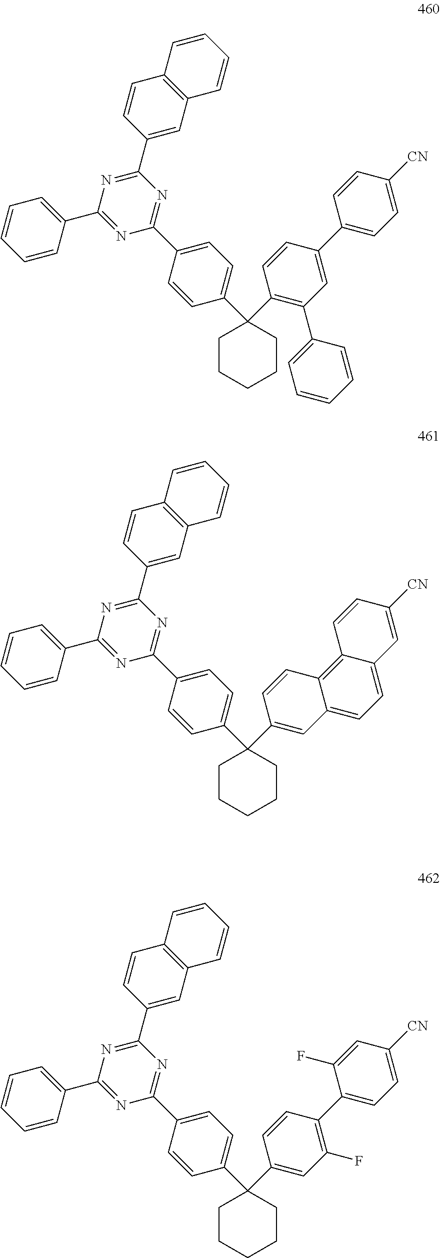 [SMILES: N#Cc1ccc(-c2ccc(C3(c4ccc(-c5nc(-c6ccccc6)nc(-c6ccc7ccccc7c6)n5)cc4)CCCCC3)c(-c3ccccc3)c2)cc1 ; N#Cc1ccc2c(ccc3cc(C4(c5ccc(-c6nc(-c7ccccc7)nc(-c7ccc8ccccc8c7)n6)cc5)CCCCC4)ccc32)c1 ; N#Cc1ccc(-c2ccc(C3(c4ccc(-c5nc(-c6ccccc6)nc(-c6ccc7ccccc7c6)n5)cc4)CCCCC3)cc2F)c(F)c1]

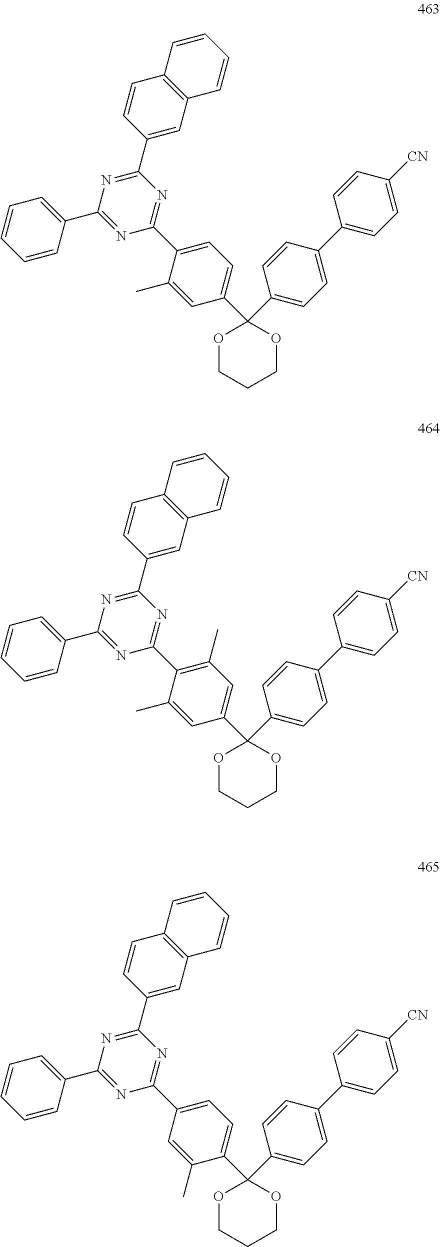 [SMILES: Cc1cc(C2(c3ccc(-c4ccc(C#N)cc4)cc3)OCCCO2)ccc1-c1nc(-c2ccccc2)nc(-c2ccc3ccccc3c2)n1 ; Cc1cc(C2(c3ccc(-c4ccc(C#N)cc4)cc3)OCCCO2)cc(C)c1-c1nc(-c2ccccc2)nc(-c2ccc3ccccc3c2)n1 ; Cc1cc(-c2nc(-c3ccccc3)nc(-c3ccc4ccccc4c3)n2)ccc1C1(c2ccc(-c3ccc(C#N)cc3)cc2)OCCCO1]

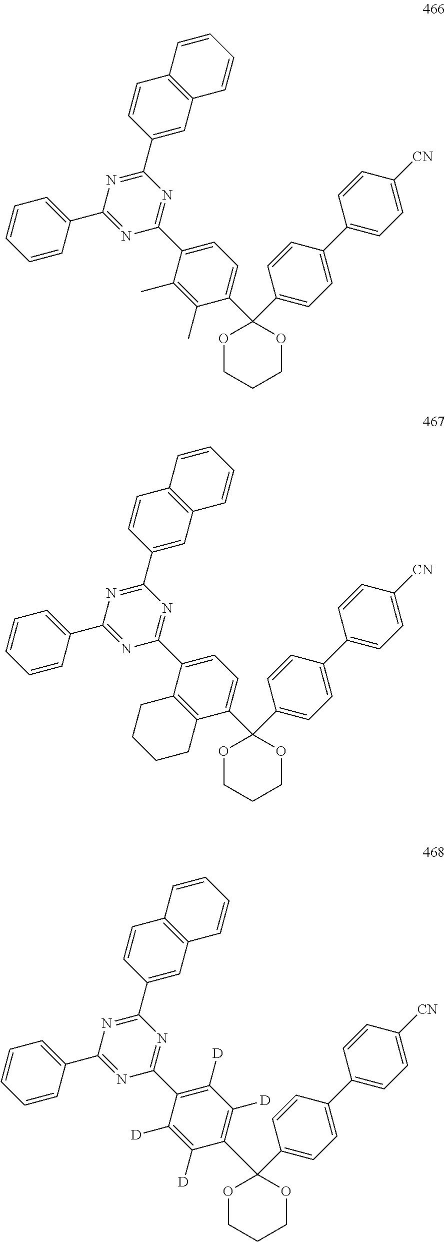 [SMILES: Cc1c(-c2nc(-c3ccccc3)nc(-c3ccc4ccccc4c3)n2)ccc(C2(c3ccc(-c4ccc(C#N)cc4)cc3)OCCCO2)c1C ; N#Cc1ccc(-c2ccc(C3(c4ccc(-c5nc(-c6ccccc6)nc(-c6ccc7ccccc7c6)n5)c5c4CCCC5)OCCCO3)cc2)cc1 ; [2H]c1c([2H])c(C2(c3ccc(-c4ccc(C#N)cc4)cc3)OCCCO2)c([2H])c([2H])c1-c1nc(-c2ccccc2)nc(-c2ccc3ccccc3c2)n1]

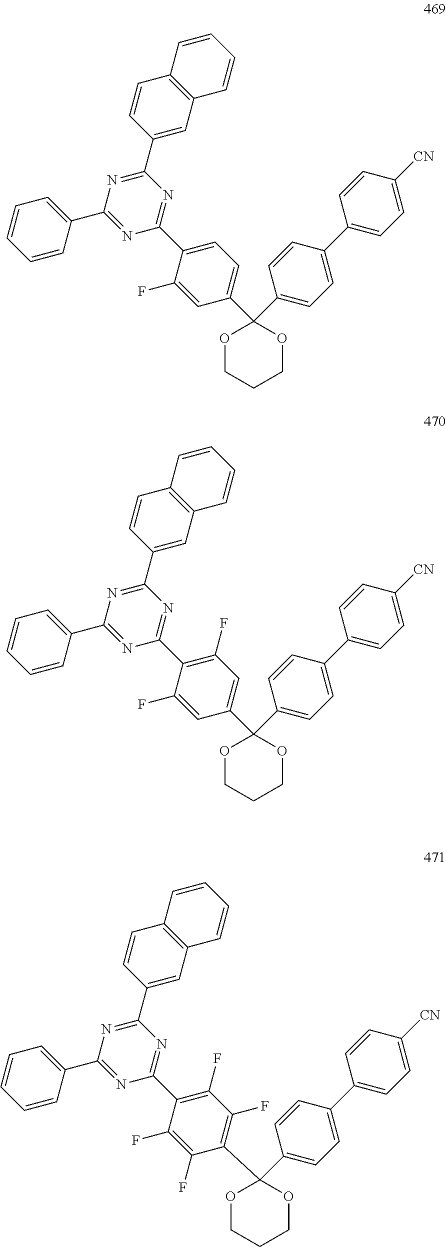 [SMILES: N#Cc1ccc(-c2ccc(C3(c4ccc(-c5nc(-c6ccccc6)nc(-c6ccc7ccccc7c6)n5)c(F)c4)OCCCO3)cc2)cc1 ; N#Cc1ccc(-c2ccc(C3(c4cc(F)c(-c5nc(-c6ccccc6)nc(-c6ccc7ccccc7c6)n5)c(F)c4)OCCCO3)cc2)cc1 ; N#Cc1ccc(-c2ccc(C3(c4c(F)c(F)c(-c5nc(-c6ccccc6)nc(-c6ccc7ccccc7c6)n5)c(F)c4F)OCCCO3)cc2)cc1]

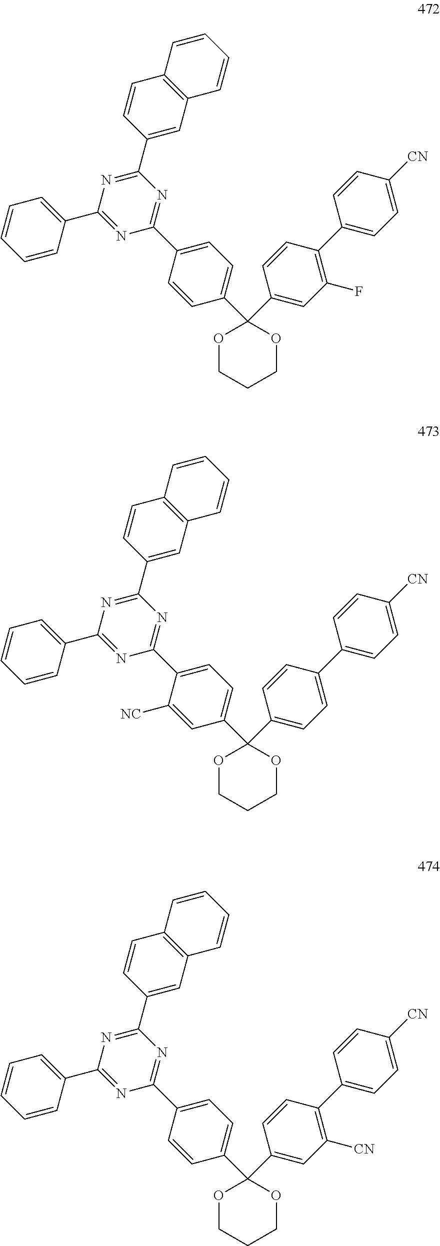 [SMILES: N#Cc1ccc(-c2ccc(C3(c4ccc(-c5nc(-c6ccccc6)nc(-c6ccc7ccccc7c6)n5)cc4)OCCCO3)cc2F)cc1 ; N#Cc1ccc(-c2ccc(C3(c4ccc(-c5nc(-c6ccccc6)nc(-c6ccc7ccccc7c6)n5)c(C#N)c4)OCCCO3)cc2)cc1 ; N#Cc1ccc(-c2ccc(C3(c4ccc(-c5nc(-c6ccccc6)nc(-c6ccc7ccccc7c6)n5)cc4)OCCCO3)cc2C#N)cc1]

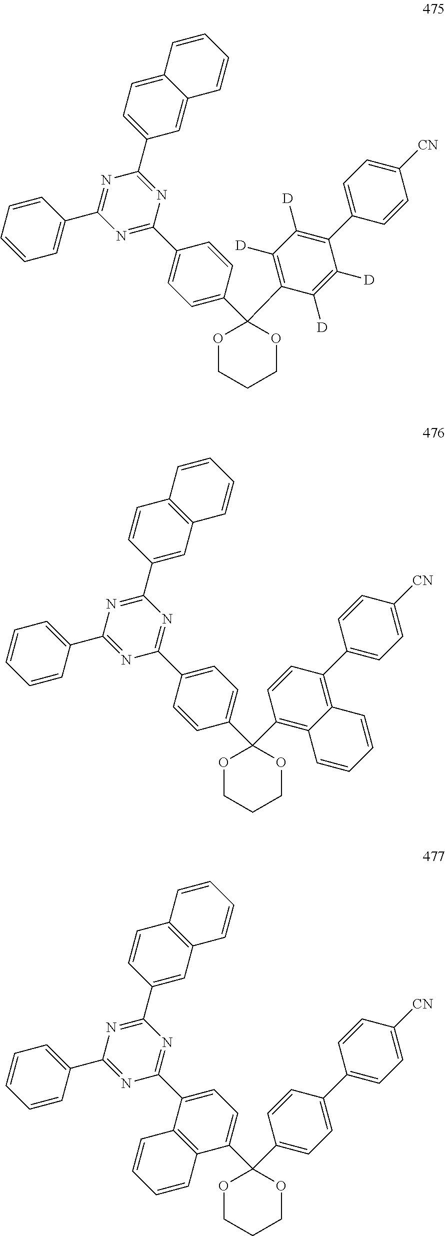 [SMILES: [2H]c1c([2H])c(C2(c3ccc(-c4nc(-c5ccccc5)nc(-c5ccc6ccccc6c5)n4)cc3)OCCCO2)c([2H])c([2H])c1-c1ccc(C#N)cc1 ; N#Cc1ccc(-c2ccc(C3(c4ccc(-c5nc(-c6ccccc6)nc(-c6ccc7ccccc7c6)n5)cc4)OCCCO3)c3ccccc23)cc1 ; N#Cc1ccc(-c2ccc(C3(c4ccc(-c5nc(-c6ccccc6)nc(-c6ccc7ccccc7c6)n5)c5ccccc45)OCCCO3)cc2)cc1]

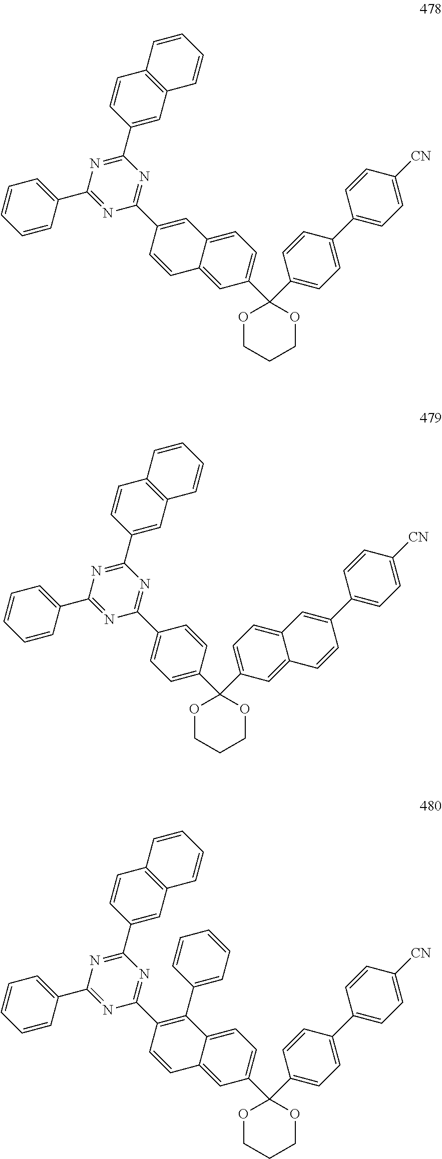 [SMILES: N#Cc1ccc(-c2ccc(C3(c4ccc5cc(-c6nc(-c7ccccc7)nc(-c7ccc8ccccc8c7)n6)ccc5c4)OCCCO3)cc2)cc1 ; N#Cc1ccc(-c2ccc3cc(C4(c5ccc(-c6nc(-c7ccccc7)nc(-c7ccc8ccccc8c7)n6)cc5)OCCCO4)ccc3c2)cc1 ; N#Cc1ccc(-c2ccc(C3(c4ccc5c(-c6ccccc6)c(-c6nc(-c7ccccc7)nc(-c7ccc8ccccc8c7)n6)ccc5c4)OCCCO3)cc2)cc1]

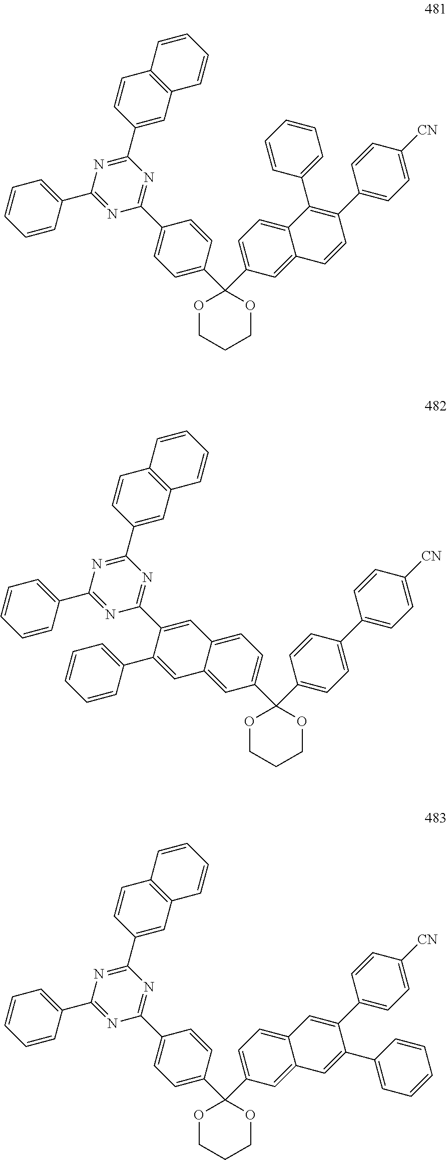 [SMILES: N#Cc1ccc(-c2ccc3cc(C4(c5ccc(-c6nc(-c7ccccc7)nc(-c7ccc8ccccc8c7)n6)cc5)OCCCO4)ccc3c2-c2ccccc2)cc1 ; N#Cc1ccc(-c2ccc(C3(c4ccc5cc(-c6nc(-c7ccccc7)nc(-c7ccc8ccccc8c7)n6)c(-c6ccccc6)cc5c4)OCCCO3)cc2)cc1 ; N#Cc1ccc(-c2cc3ccc(C4(c5ccc(-c6nc(-c7ccccc7)nc(-c7ccc8ccccc8c7)n6)cc5)OCCCO4)cc3cc2-c2ccccc2)cc1]

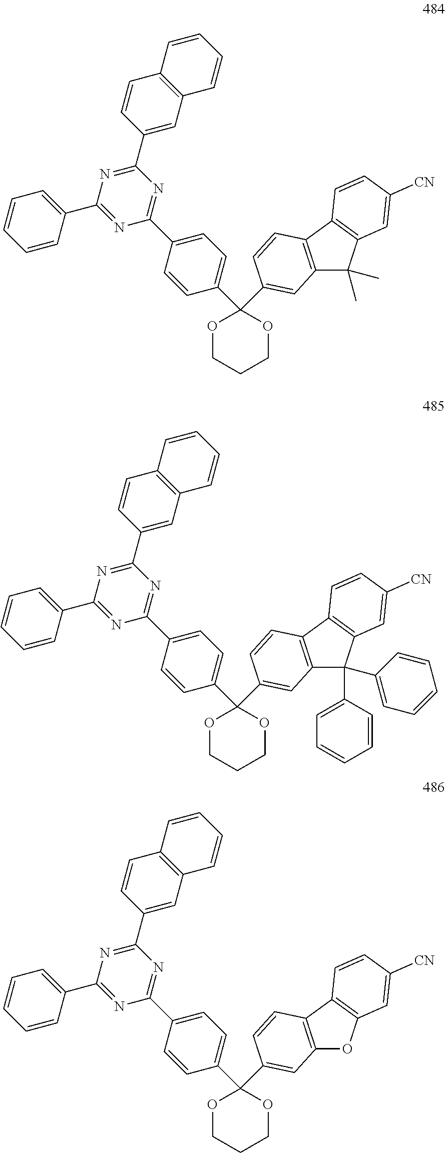 [SMILES: CC1(C)c2cc(C#N)ccc2-c2ccc(C3(c4ccc(-c5nc(-c6ccccc6)nc(-c6ccc7ccccc7c6)n5)cc4)OCCCO3)cc21 ; N#Cc1ccc2c(c1)C(c1ccccc1)(c1ccccc1)c1cc(C3(c4ccc(-c5nc(-c6ccccc6)nc(-c6ccc7ccccc7c6)n5)cc4)OCCCO3)ccc1-2 ; N#Cc1ccc2c(c1)oc1cc(C3(c4ccc(-c5nc(-c6ccccc6)nc(-c6ccc7ccccc7c6)n5)cc4)OCCCO3)ccc12]

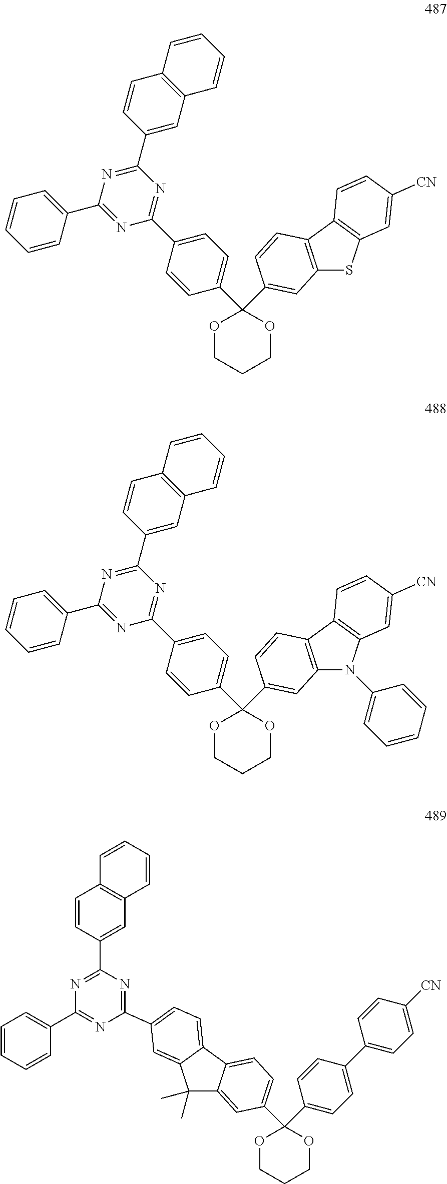 [SMILES: N#Cc1ccc2c(c1)sc1cc(C3(c4ccc(-c5nc(-c6ccccc6)nc(-c6ccc7ccccc7c6)n5)cc4)OCCCO3)ccc12 ; N#Cc1ccc2c3ccc(C4(c5ccc(-c6nc(-c7ccccc7)nc(-c7ccc8ccccc8c7)n6)cc5)OCCCO4)cc3n(-c3ccccc3)c2c1 ; CC1(C)c2cc(-c3nc(-c4ccccc4)nc(-c4ccc5ccccc5c4)n3)ccc2-c2ccc(C3(c4ccc(-c5ccc(C#N)cc5)cc4)OCCCO3)cc21]

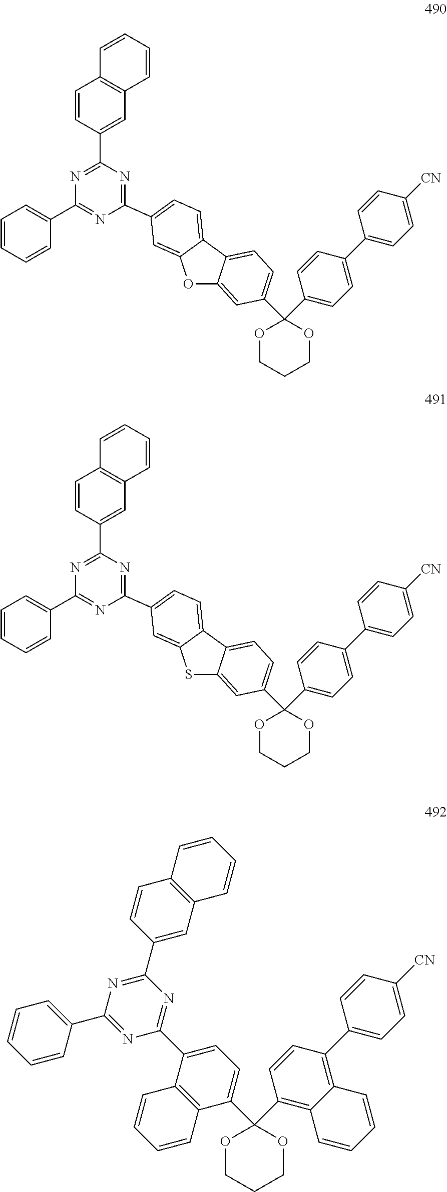 [SMILES: N#Cc1ccc(-c2ccc(C3(c4ccc5c(c4)oc4cc(-c6nc(-c7ccccc7)nc(-c7ccc8ccccc8c7)n6)ccc45)OCCCO3)cc2)cc1 ; N#Cc1ccc(-c2ccc(C3(c4ccc5c(c4)sc4cc(-c6nc(-c7ccccc7)nc(-c7ccc8ccccc8c7)n6)ccc45)OCCCO3)cc2)cc1 ; N#Cc1ccc(-c2ccc(C3(c4ccc(-c5nc(-c6ccccc6)nc(-c6ccc7ccccc7c6)n5)c5ccccc45)OCCCO3)c3ccccc23)cc1]

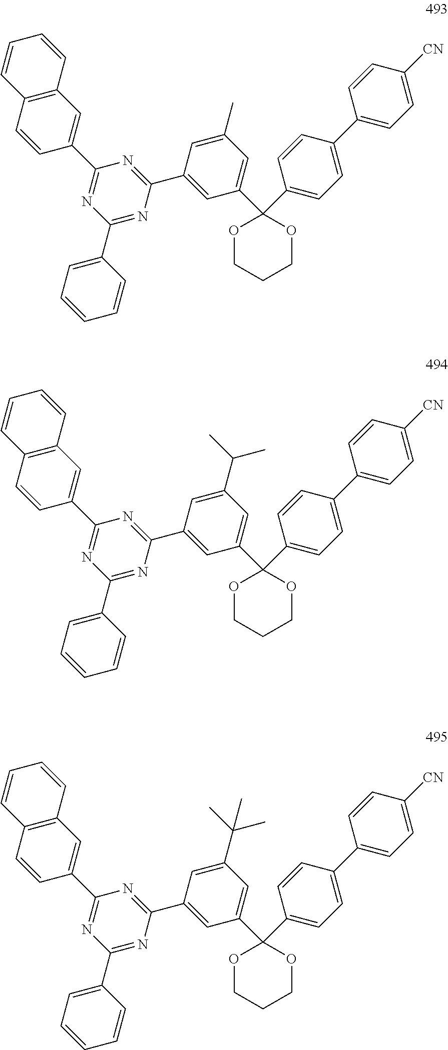 [SMILES: Cc1cc(-c2nc(-c3ccccc3)nc(-c3ccc4ccccc4c3)n2)cc(C2(c3ccc(-c4ccc(C#N)cc4)cc3)OCCCO2)c1 ; CC(C)c1cc(-c2nc(-c3ccccc3)nc(-c3ccc4ccccc4c3)n2)cc(C2(c3ccc(-c4ccc(C#N)cc4)cc3)OCCCO2)c1 ; CC(C)(C)c1cc(-c2nc(-c3ccccc3)nc(-c3ccc4ccccc4c3)n2)cc(C2(c3ccc(-c4ccc(C#N)cc4)cc3)OCCCO2)c1]

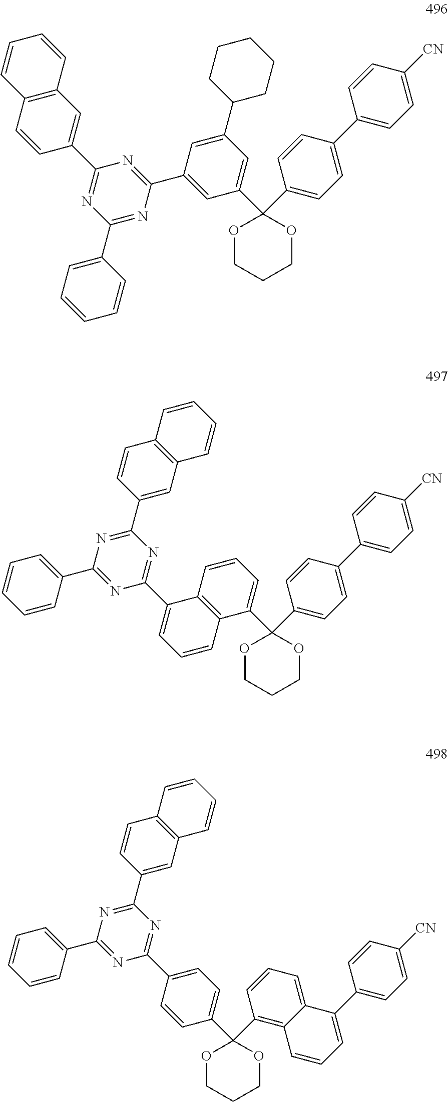 [SMILES: N#Cc1ccc(-c2ccc(C3(c4cc(-c5nc(-c6ccccc6)nc(-c6ccc7ccccc7c6)n5)cc(C5CCCCC5)c4)OCCCO3)cc2)cc1 ; N#Cc1ccc(-c2ccc(C3(c4cccc5c(-c6nc(-c7ccccc7)nc(-c7ccc8ccccc8c7)n6)cccc45)OCCCO3)cc2)cc1 ; N#Cc1ccc(-c2cccc3c(C4(c5ccc(-c6nc(-c7ccccc7)nc(-c7ccc8ccccc8c7)n6)cc5)OCCCO4)cccc23)cc1]

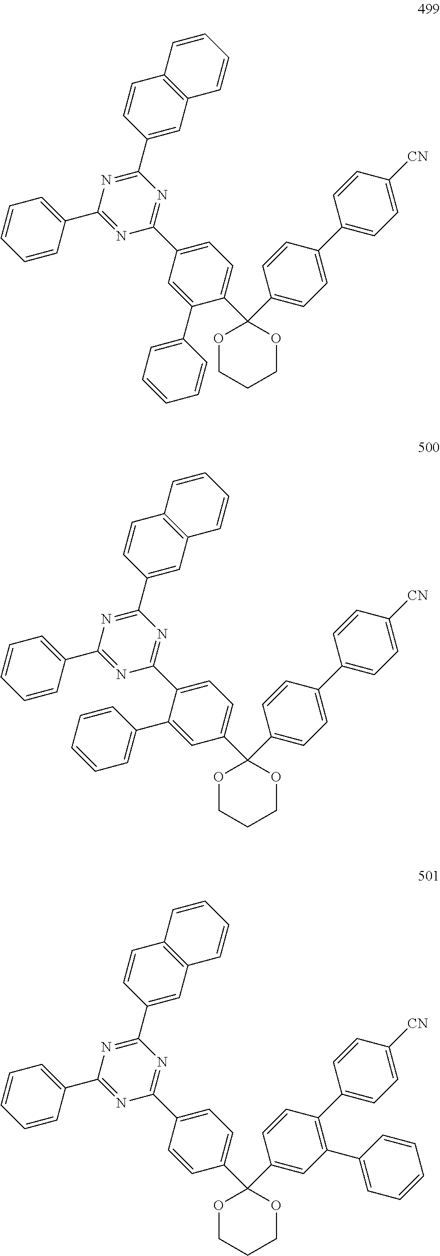 [SMILES: N#Cc1ccc(-c2ccc(C3(c4ccc(-c5nc(-c6ccccc6)nc(-c6ccc7ccccc7c6)n5)cc4-c4ccccc4)OCCCO3)cc2)cc1 ; N#Cc1ccc(-c2ccc(C3(c4ccc(-c5nc(-c6ccccc6)nc(-c6ccc7ccccc7c6)n5)c(-c5ccccc5)c4)OCCCO3)cc2)cc1 ; N#Cc1ccc(-c2ccc(C3(c4ccc(-c5nc(-c6ccccc6)nc(-c6ccc7ccccc7c6)n5)cc4)OCCCO3)cc2-c2ccccc2)cc1]

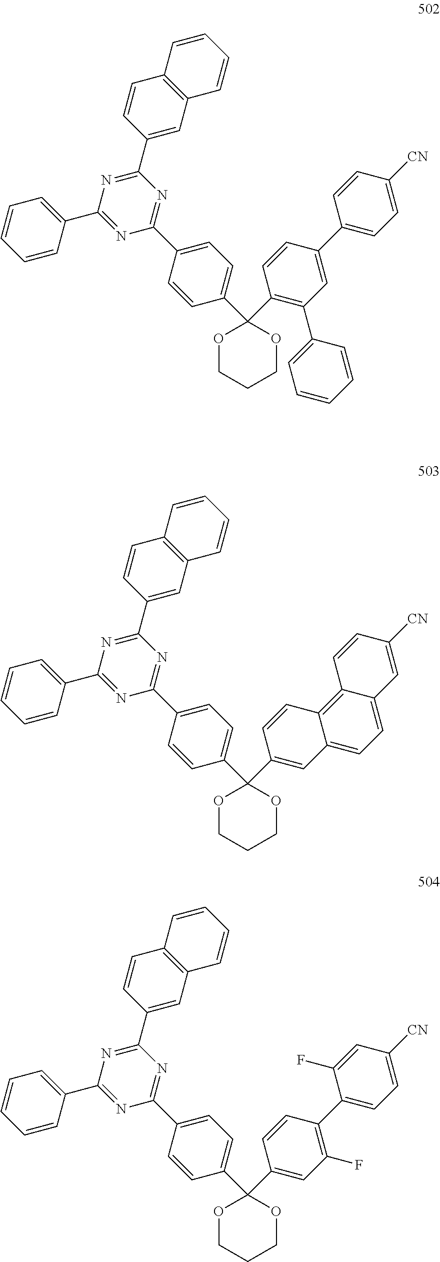 [SMILES: N#Cc1ccc(-c2ccc(C3(c4ccc(-c5nc(-c6ccccc6)nc(-c6ccc7ccccc7c6)n5)cc4)OCCCO3)c(-c3ccccc3)c2)cc1 ; N#Cc1ccc2c(ccc3cc(C4(c5ccc(-c6nc(-c7ccccc7)nc(-c7ccc8ccccc8c7)n6)cc5)OCCCO4)ccc32)c1 ; N#Cc1ccc(-c2ccc(C3(c4ccc(-c5nc(-c6ccccc6)nc(-c6ccc7ccccc7c6)n5)cc4)OCCCO3)cc2F)c(F)c1]

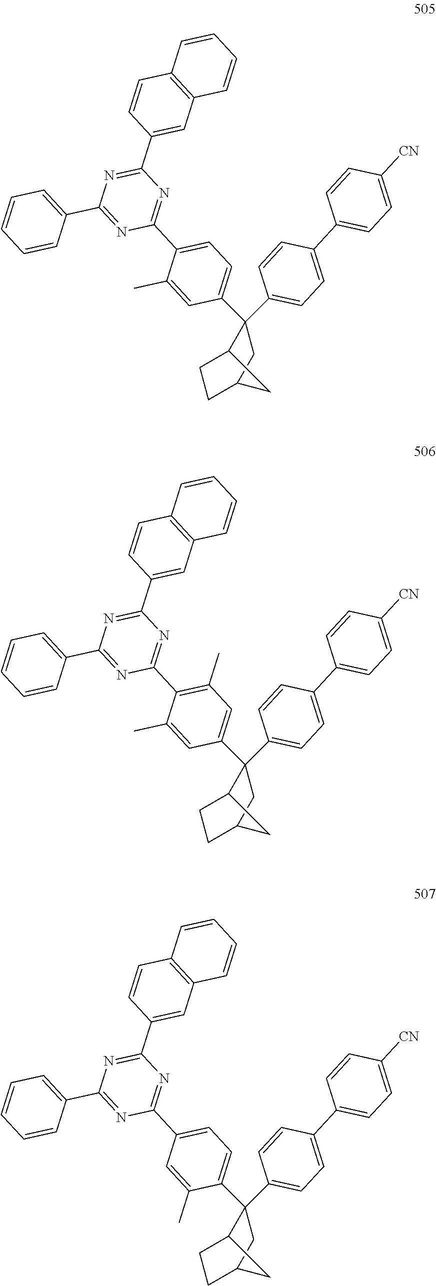 [SMILES: Cc1cc(C2(c3ccc(-c4ccc(C#N)cc4)cc3)CC3CCC2C3)ccc1-c1nc(-c2ccccc2)nc(-c2ccc3ccccc3c2)n1 ; Cc1cc(C2(c3ccc(-c4ccc(C#N)cc4)cc3)CC3CCC2C3)cc(C)c1-c1nc(-c2ccccc2)nc(-c2ccc3ccccc3c2)n1 ; Cc1cc(-c2nc(-c3ccccc3)nc(-c3ccc4ccccc4c3)n2)ccc1C1(c2ccc(-c3ccc(C#N)cc3)cc2)CC2CCC1C2]

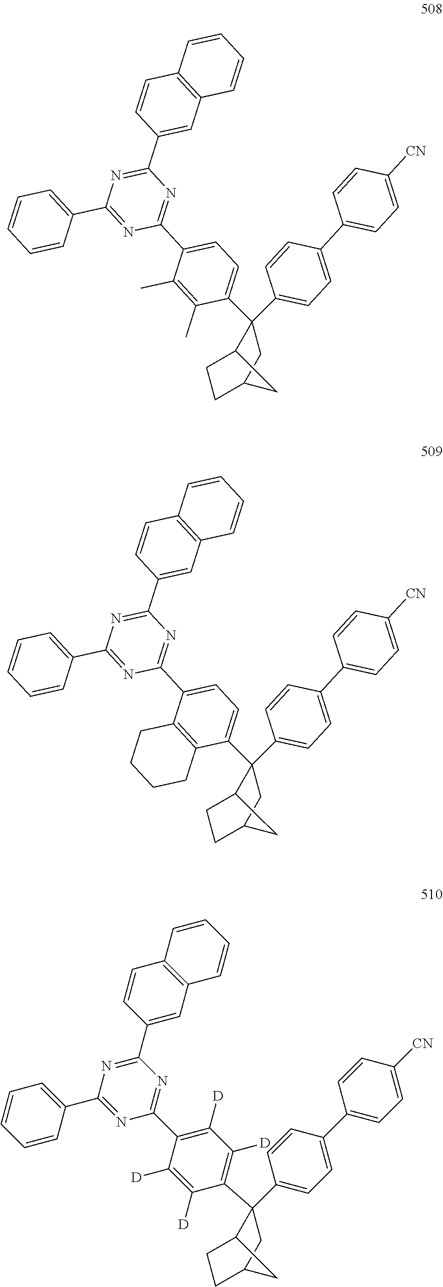 [SMILES: Cc1c(-c2nc(-c3ccccc3)nc(-c3ccc4ccccc4c3)n2)ccc(C2(c3ccc(-c4ccc(C#N)cc4)cc3)CC3CCC2C3)c1C ; N#Cc1ccc(-c2ccc(C3(c4ccc(-c5nc(-c6ccccc6)nc(-c6ccc7ccccc7c6)n5)c5c4CCCC5)CC4CCC3C4)cc2)cc1 ; [2H]c1c([2H])c(C2(c3ccc(-c4ccc(C#N)cc4)cc3)CC3CCC2C3)c([2H])c([2H])c1-c1nc(-c2ccccc2)nc(-c2ccc3ccccc3c2)n1]

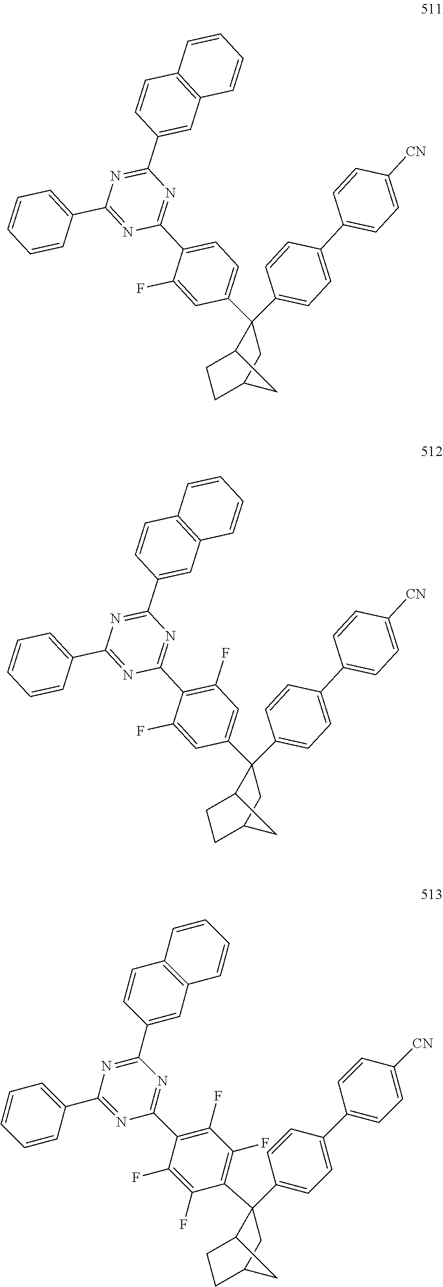 [SMILES: N#Cc1ccc(-c2ccc(C3(c4ccc(-c5nc(-c6ccccc6)nc(-c6ccc7ccccc7c6)n5)c(F)c4)CC4CCC3C4)cc2)cc1 ; N#Cc1ccc(-c2ccc(C3(c4cc(F)c(-c5nc(-c6ccccc6)nc(-c6ccc7ccccc7c6)n5)c(F)c4)CC4CCC3C4)cc2)cc1 ; N#Cc1ccc(-c2ccc(C3(c4c(F)c(F)c(-c5nc(-c6ccccc6)nc(-c6ccc7ccccc7c6)n5)c(F)c4F)CC4CCC3C4)cc2)cc1]

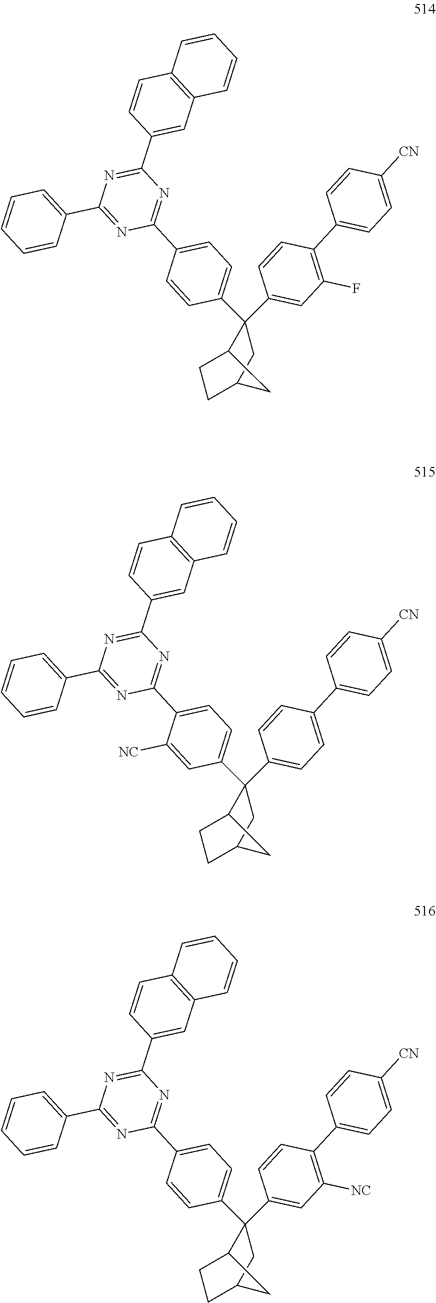

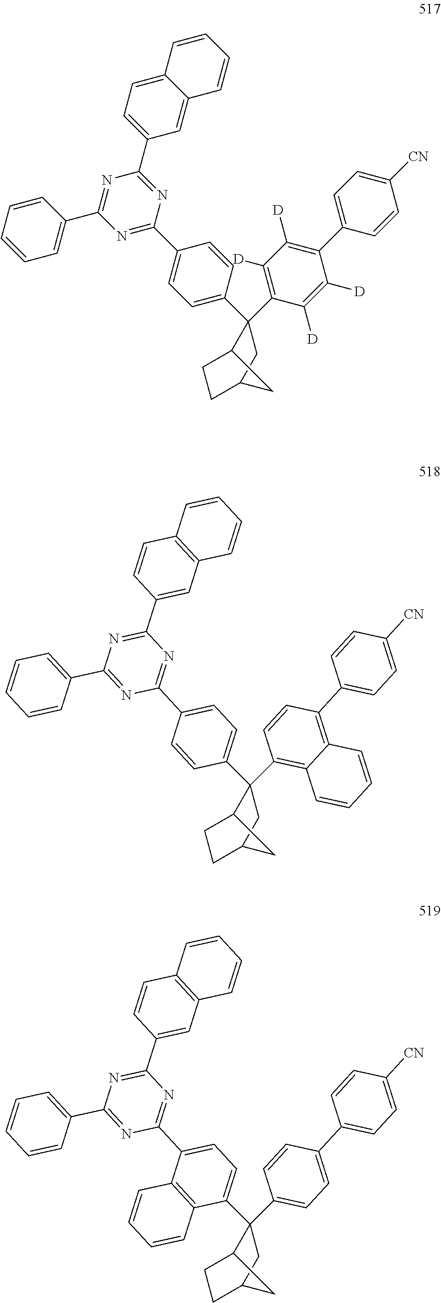 [SMILES: [2H]c1c([2H])c(C2(c3ccc(-c4nc(-c5ccccc5)nc(-c5ccc6ccccc6c5)n4)cc3)CC3CCC2C3)c([2H])c([2H])c1-c1ccc(C#N)cc1 ; N#Cc1ccc(-c2ccc(C3(c4ccc(-c5nc(-c6ccccc6)nc(-c6ccc7ccccc7c6)n5)cc4)CC4CCC3C4)c3ccccc23)cc1 ; N#Cc1ccc(-c2ccc(C3(c4ccc(-c5nc(-c6ccccc6)nc(-c6ccc7ccccc7c6)n5)c5ccccc45)CC4CCC3C4)cc2)cc1]

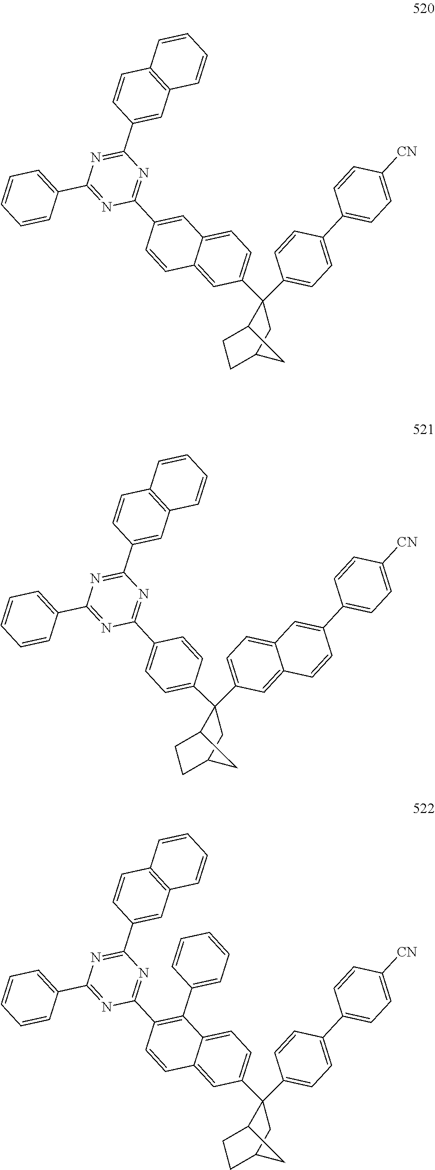 [SMILES: N#Cc1ccc(-c2ccc(C3(c4ccc5cc(-c6nc(-c7ccccc7)nc(-c7ccc8ccccc8c7)n6)ccc5c4)CC4CCC3C4)cc2)cc1 ; N#Cc1ccc(-c2ccc3cc(C4(c5ccc(-c6nc(-c7ccccc7)nc(-c7ccc8ccccc8c7)n6)cc5)CC5CCC4C5)ccc3c2)cc1 ; N#Cc1ccc(-c2ccc(C3(c4ccc5c(-c6ccccc6)c(-c6nc(-c7ccccc7)nc(-c7ccc8ccccc8c7)n6)ccc5c4)CC4CCC3C4)cc2)cc1]

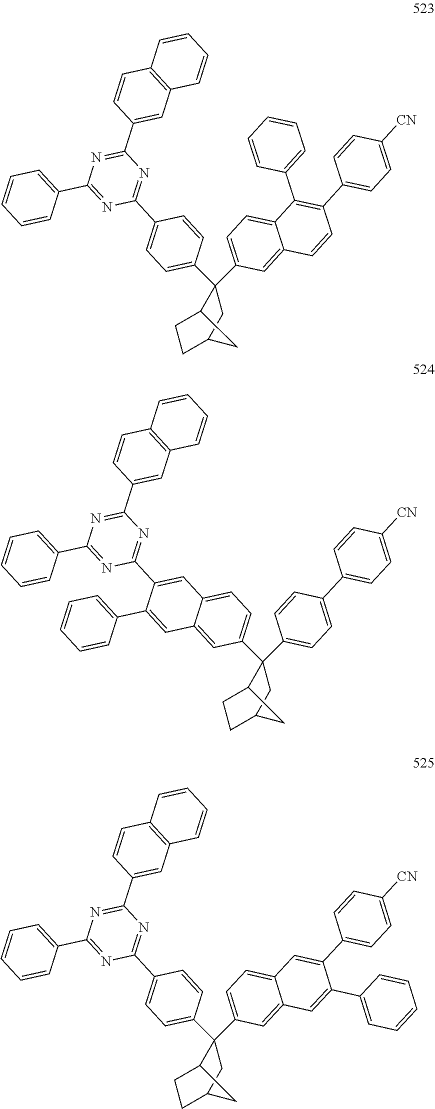 [SMILES: N#Cc1ccc(-c2ccc3cc(C4(c5ccc(-c6nc(-c7ccccc7)nc(-c7ccc8ccccc8c7)n6)cc5)CC5CCC4C5)ccc3c2-c2ccccc2)cc1 ; N#Cc1ccc(-c2ccc(C3(c4ccc5cc(-c6nc(-c7ccccc7)nc(-c7ccc8ccccc8c7)n6)c(-c6ccccc6)cc5c4)CC4CCC3C4)cc2)cc1 ; N#Cc1ccc(-c2cc3ccc(C4(c5ccc(-c6nc(-c7ccccc7)nc(-c7ccc8ccccc8c7)n6)cc5)CC5CCC4C5)cc3cc2-c2ccccc2)cc1]

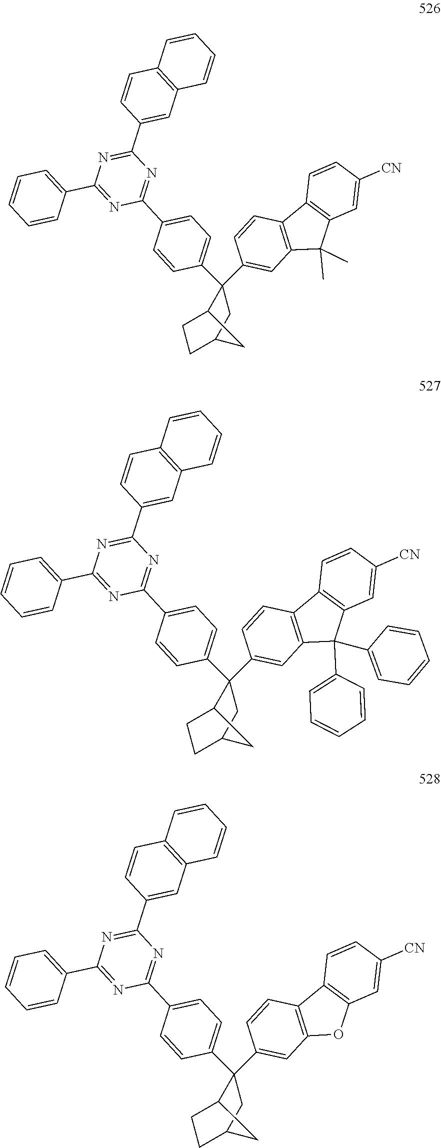 [SMILES: CC1(C)c2cc(C#N)ccc2-c2ccc(C3(c4ccc(-c5nc(-c6ccccc6)nc(-c6ccc7ccccc7c6)n5)cc4)CC4CCC3C4)cc21 ; N#Cc1ccc2c(c1)C(c1ccccc1)(c1ccccc1)c1cc(C3(c4ccc(-c5nc(-c6ccccc6)nc(-c6ccc7ccccc7c6)n5)cc4)CC4CCC3C4)ccc1-2 ; N#Cc1ccc2c(c1)oc1cc(C3(c4ccc(-c5nc(-c6ccccc6)nc(-c6ccc7ccccc7c6)n5)cc4)CC4CCC3C4)ccc12]

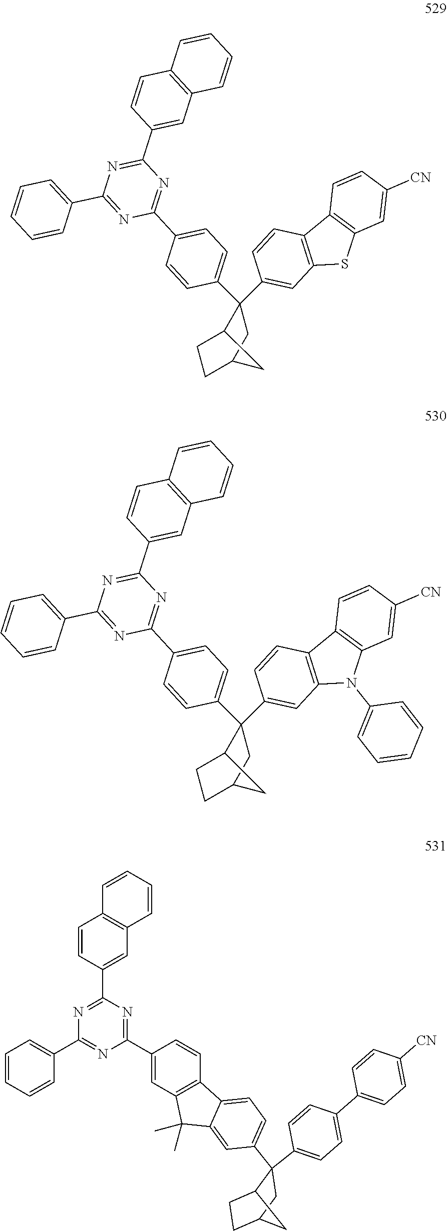 [SMILES: N#Cc1ccc2c(c1)sc1cc(C3(c4ccc(-c5nc(-c6ccccc6)nc(-c6ccc7ccccc7c6)n5)cc4)CC4CCC3C4)ccc12 ; N#Cc1ccc2c3ccc(C4(c5ccc(-c6nc(-c7ccccc7)nc(-c7ccc8ccccc8c7)n6)cc5)CC5CCC4C5)cc3n(-c3ccccc3)c2c1 ; CC1(C)c2cc(-c3nc(-c4ccccc4)nc(-c4ccc5ccccc5c4)n3)ccc2-c2ccc(C3(c4ccc(-c5ccc(C#N)cc5)cc4)CC4CCC3C4)cc21]

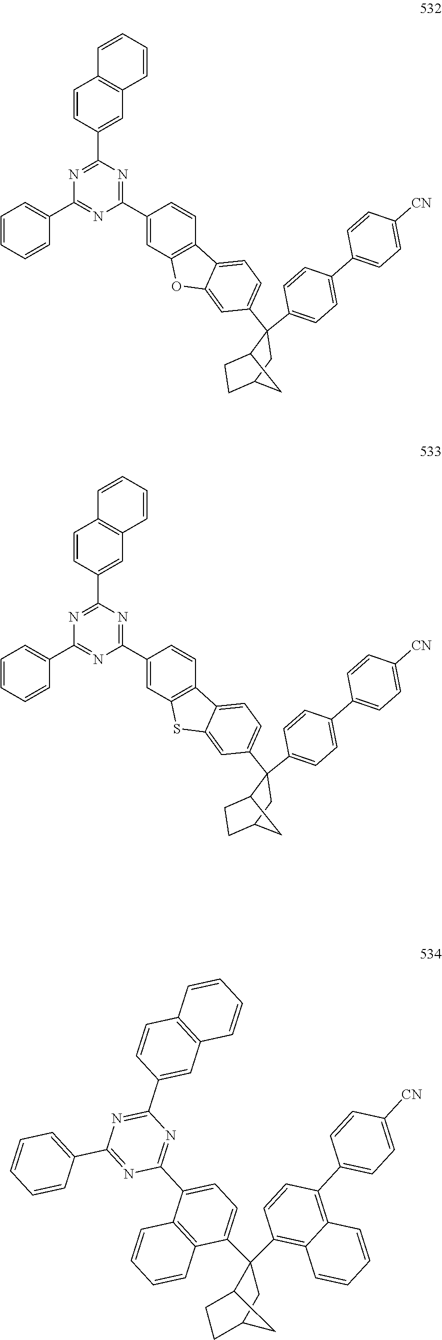 [SMILES: N#Cc1ccc(-c2ccc(C3(c4ccc5c(c4)oc4cc(-c6nc(-c7ccccc7)nc(-c7ccc8ccccc8c7)n6)ccc45)CC4CCC3C4)cc2)cc1 ; N#Cc1ccc(-c2ccc(C3(c4ccc5c(c4)sc4cc(-c6nc(-c7ccccc7)nc(-c7ccc8ccccc8c7)n6)ccc45)CC4CCC3C4)cc2)cc1 ; N#Cc1ccc(-c2ccc(C3(c4ccc(-c5nc(-c6ccccc6)nc(-c6ccc7ccccc7c6)n5)c5ccccc45)CC4CCC3C4)c3ccccc23)cc1]

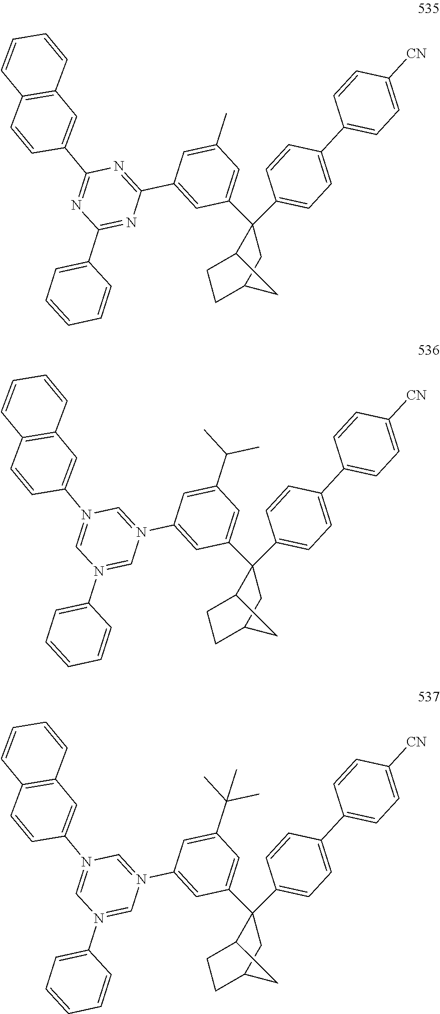

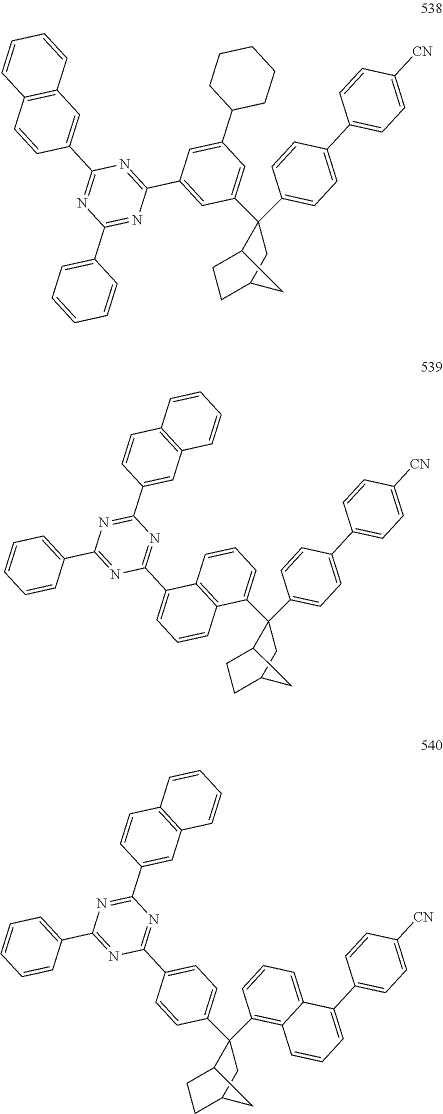 [SMILES: N#Cc1ccc(-c2ccc(C3(c4cc(-c5nc(-c6ccccc6)nc(-c6ccc7ccccc7c6)n5)cc(C5CCCCC5)c4)CC4CCC3C4)cc2)cc1 ; N#Cc1ccc(-c2ccc(C3(c4cccc5c(-c6nc(-c7ccccc7)nc(-c7ccc8ccccc8c7)n6)cccc45)CC4CCC3C4)cc2)cc1 ; N#Cc1ccc(-c2cccc3c(C4(c5ccc(-c6nc(-c7ccccc7)nc(-c7ccc8ccccc8c7)n6)cc5)CC5CCC4C5)cccc23)cc1]

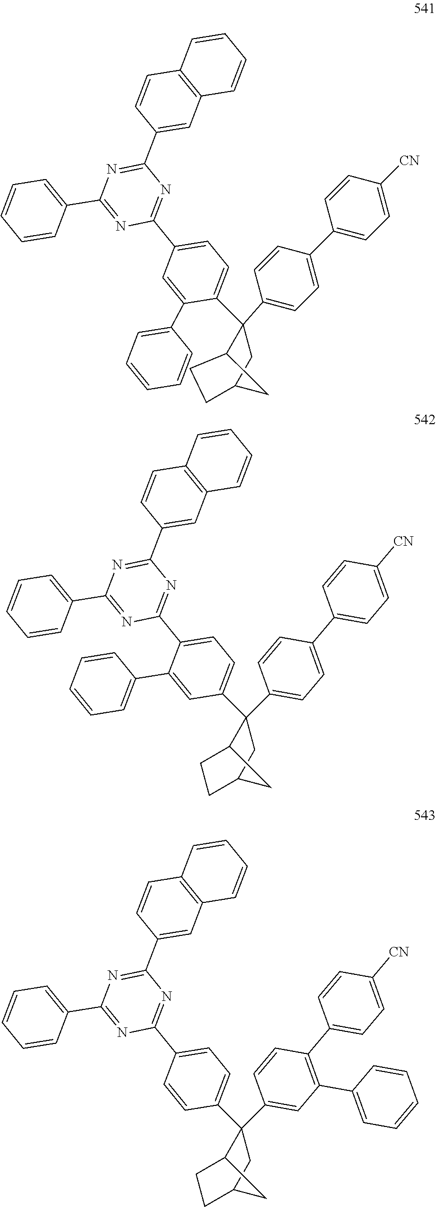

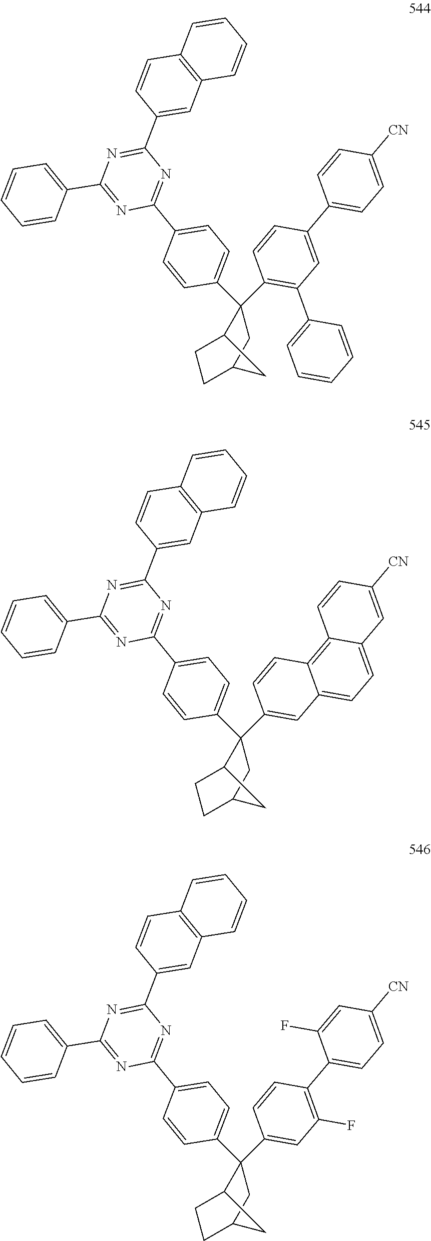 [SMILES: N#Cc1ccc(-c2ccc(C3(c4ccc(-c5nc(-c6ccccc6)nc(-c6ccc7ccccc7c6)n5)cc4)CC4CCC3C4)c(-c3ccccc3)c2)cc1 ; N#Cc1ccc2c(ccc3cc(C4(c5ccc(-c6nc(-c7ccccc7)nc(-c7ccc8ccccc8c7)n6)cc5)CC5CCC4C5)ccc32)c1 ; N#Cc1ccc(-c2ccc(C3(c4ccc(-c5nc(-c6ccccc6)nc(-c6ccc7ccccc7c6)n5)cc4)CC4CCC3C4)cc2F)c(F)c1]

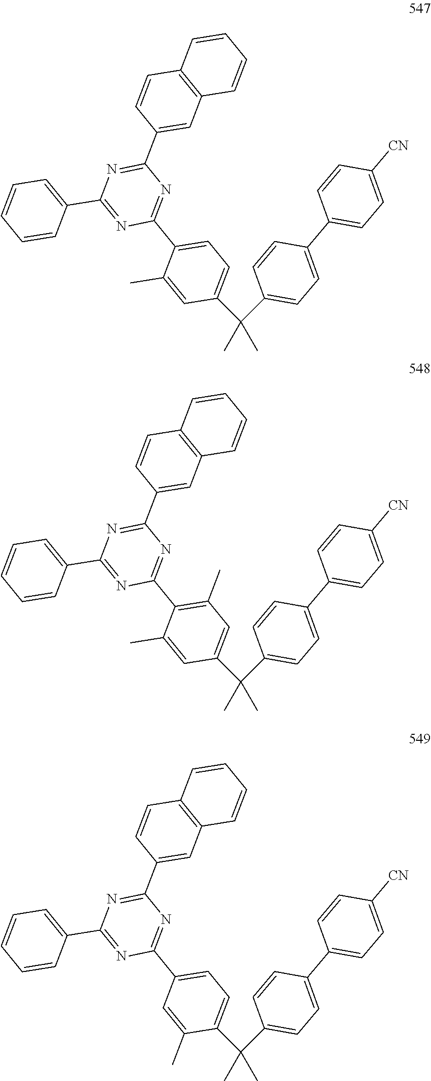

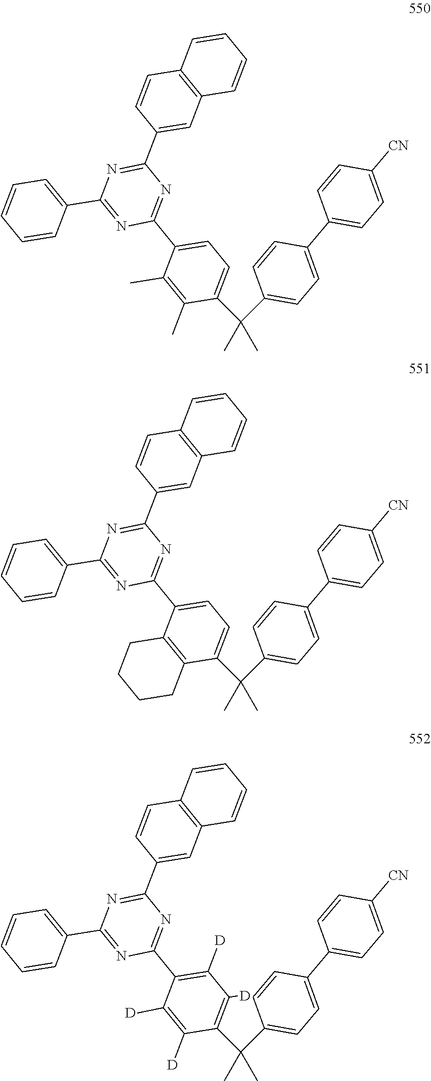

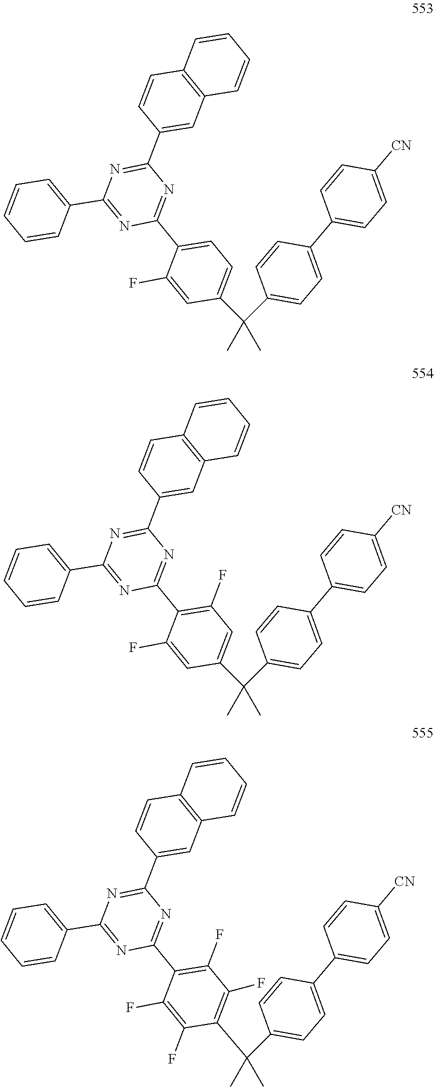

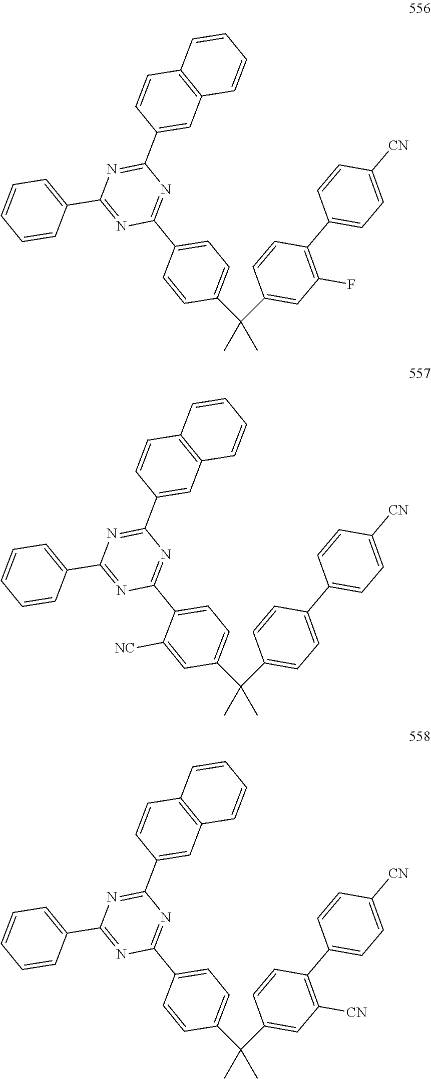

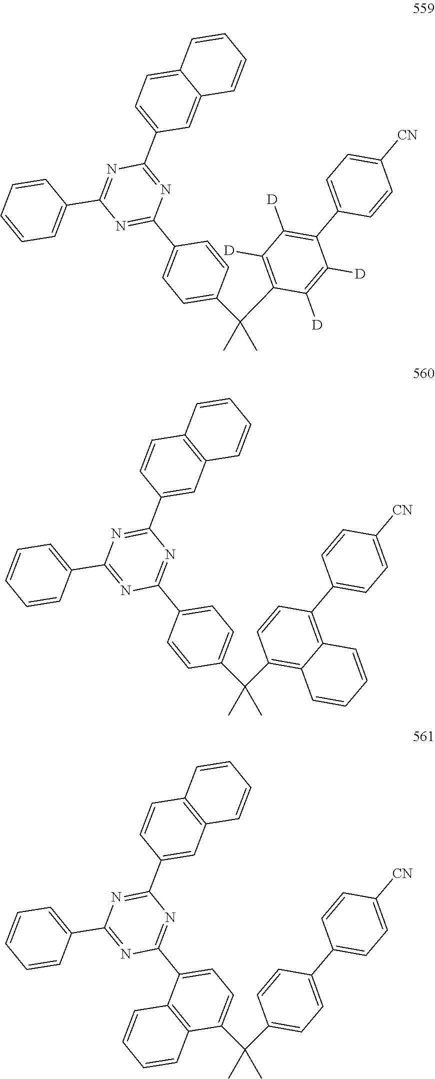

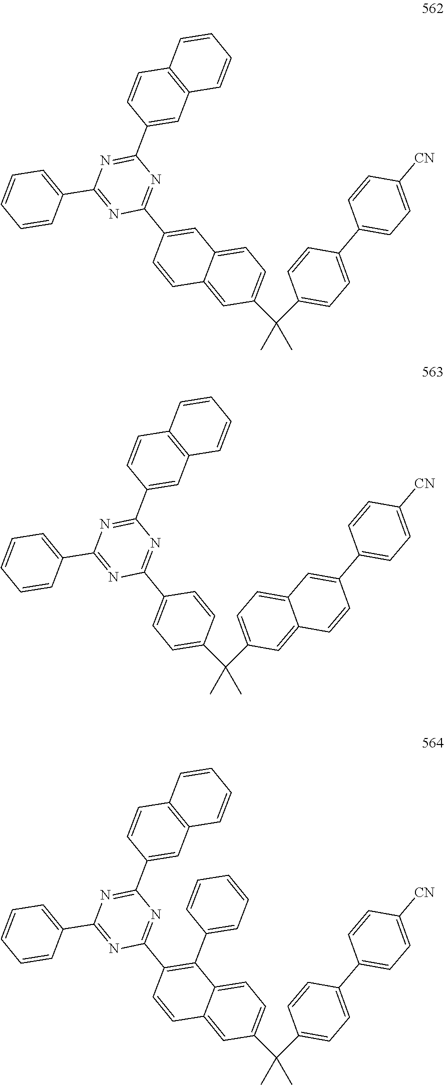 [SMILES: CC(C)(c1ccc(-c2ccc(C#N)cc2)cc1)c1ccc2cc(-c3nc(-c4ccccc4)nc(-c4ccc5ccccc5c4)n3)ccc2c1 ; CC(C)(c1ccc(-c2nc(-c3ccccc3)nc(-c3ccc4ccccc4c3)n2)cc1)c1ccc2cc(-c3ccc(C#N)cc3)ccc2c1 ; CC(C)(c1ccc(-c2ccc(C#N)cc2)cc1)c1ccc2c(-c3ccccc3)c(-c3nc(-c4ccccc4)nc(-c4ccc5ccccc5c4)n3)ccc2c1]

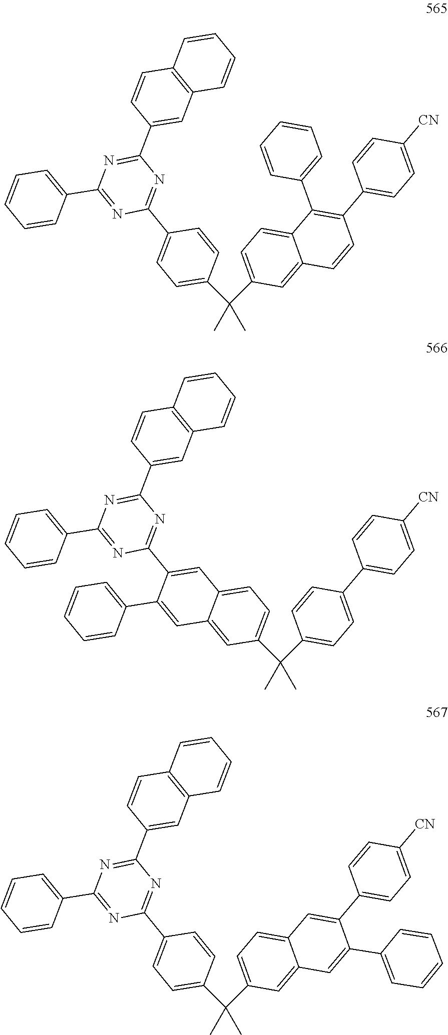

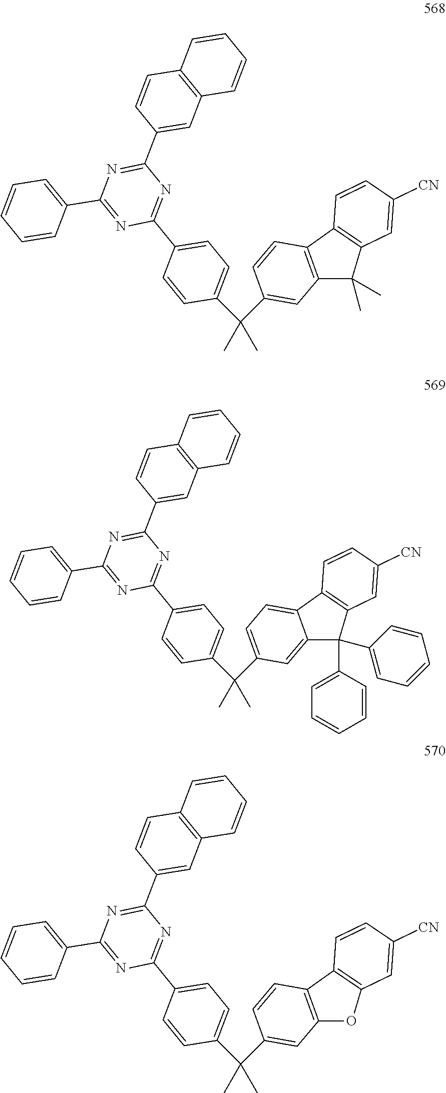 [SMILES: CC(C)(c1ccc(-c2nc(-c3ccccc3)nc(-c3ccc4ccccc4c3)n2)cc1)c1ccc2c(c1)C(C)(C)c1cc(C#N)ccc1-2 ; CC(C)(c1ccc(-c2nc(-c3ccccc3)nc(-c3ccc4ccccc4c3)n2)cc1)c1ccc2c(c1)C(c1ccccc1)(c1ccccc1)c1cc(C#N)ccc1-2 ; CC(C)(c1ccc(-c2nc(-c3ccccc3)nc(-c3ccc4ccccc4c3)n2)cc1)c1ccc2c(c1)oc1cc(C#N)ccc12]

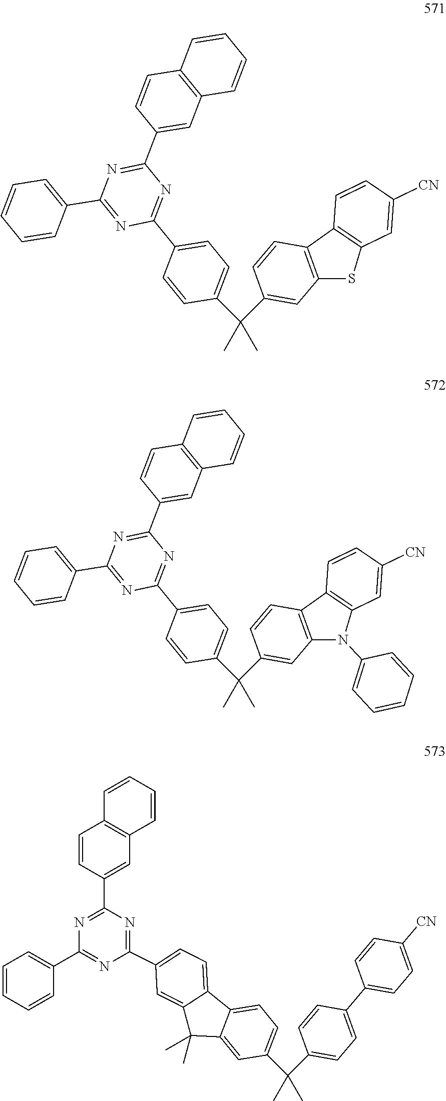 [SMILES: CC(C)(c1ccc(-c2nc(-c3ccccc3)nc(-c3ccc4ccccc4c3)n2)cc1)c1ccc2c(c1)sc1cc(C#N)ccc12 ; CC(C)(c1ccc(-c2nc(-c3ccccc3)nc(-c3ccc4ccccc4c3)n2)cc1)c1ccc2c3ccc(C#N)cc3n(-c3ccccc3)c2c1 ; CC(C)(c1ccc(-c2ccc(C#N)cc2)cc1)c1ccc2c(c1)C(C)(C)c1cc(-c3nc(-c4ccccc4)nc(-c4ccc5ccccc5c4)n3)ccc1-2]

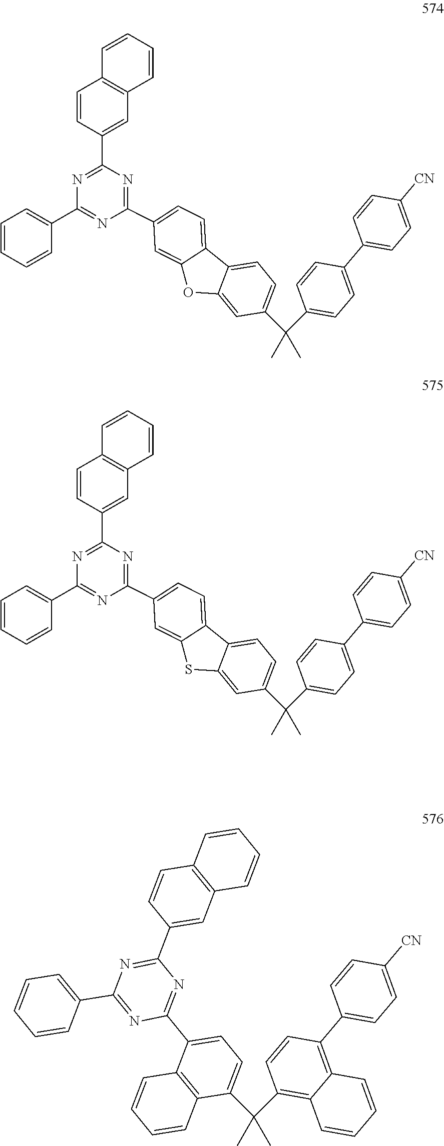 [SMILES: CC(C)(c1ccc(-c2ccc(C#N)cc2)cc1)c1ccc2c(c1)oc1cc(-c3nc(-c4ccccc4)nc(-c4ccc5ccccc5c4)n3)ccc12 ; CC(C)(c1ccc(-c2ccc(C#N)cc2)cc1)c1ccc2c(c1)sc1cc(-c3nc(-c4ccccc4)nc(-c4ccc5ccccc5c4)n3)ccc12 ; CC(C)(c1ccc(-c2ccc(C#N)cc2)c2ccccc12)c1ccc(-c2nc(-c3ccccc3)nc(-c3ccc4ccccc4c3)n2)c2ccccc12]

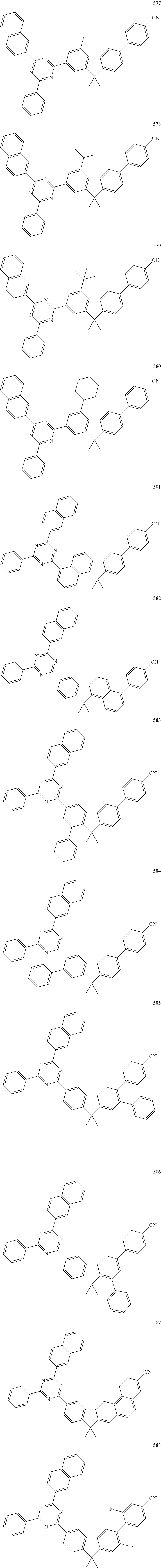

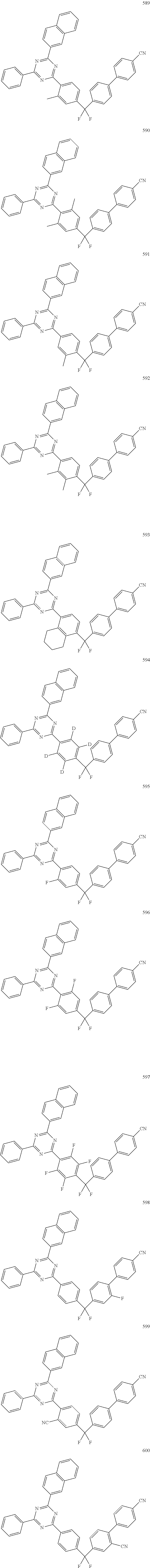

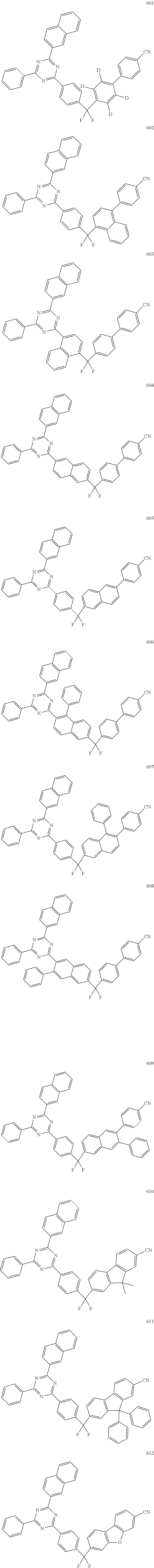

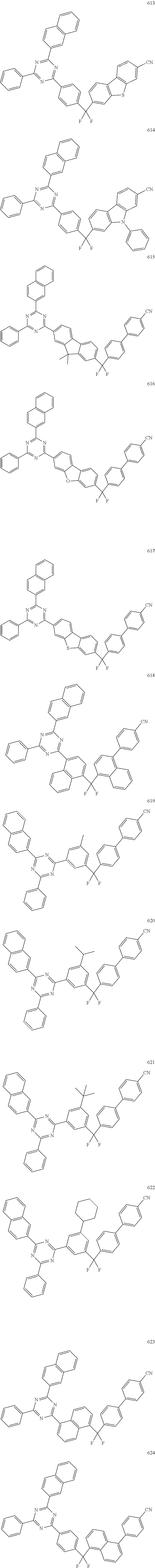

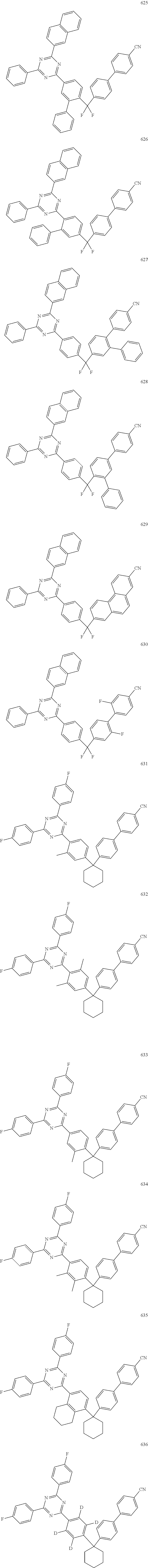

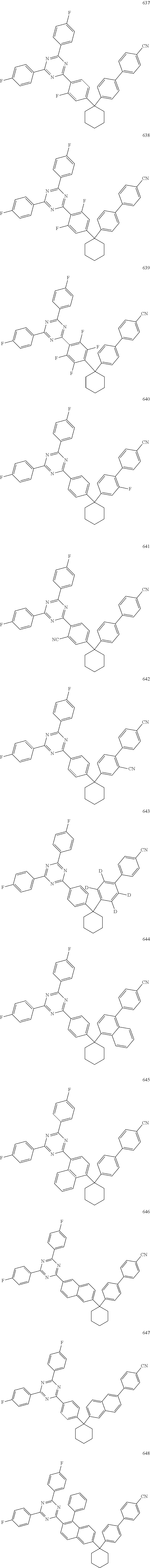

[chemical structure]

[chemical structure]

[chemical structure]

[chemical structure]

[chemical structure]

[chemical structure]

[chemical structure]

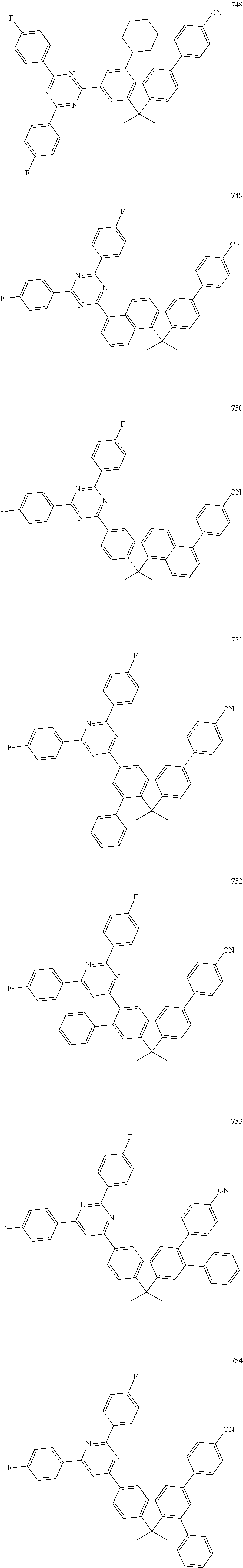

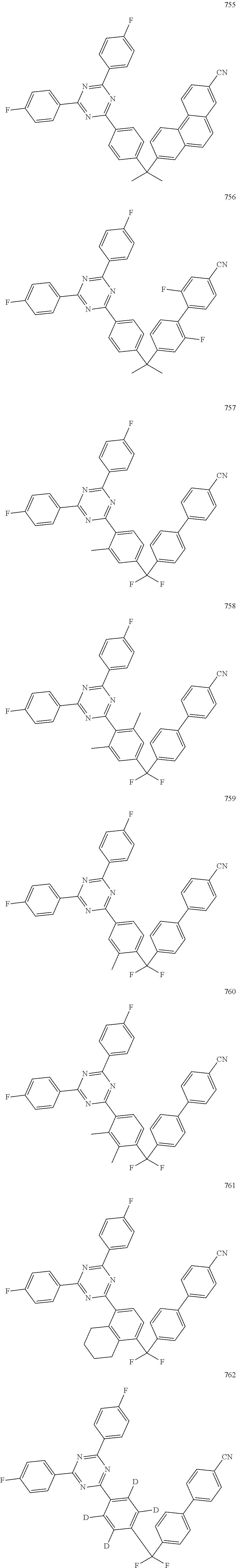

[chemical structure]

[chemical structure]

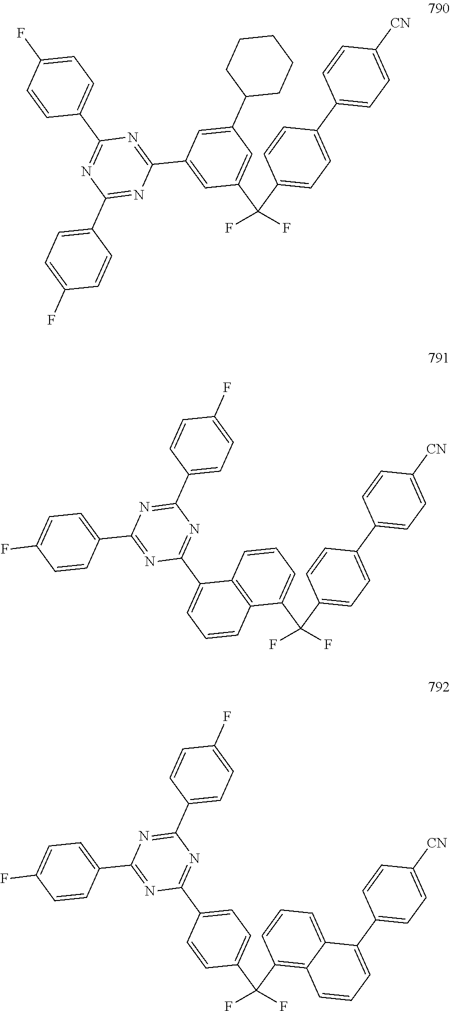 [SMILES: N#Cc1ccc(-c2ccc(C(F)(F)c3cc(-c4nc(-c5ccc(F)cc5)nc(-c5ccc(F)cc5)n4)cc(C4CCCCC4)c3)cc2)cc1 ; N#Cc1ccc(-c2ccc(C(F)(F)c3cccc4c(-c5nc(-c6ccc(F)cc6)nc(-c6ccc(F)cc6)n5)cccc34)cc2)cc1 ; N#Cc1ccc(-c2cccc3c(C(F)(F)c4ccc(-c5nc(-c6ccc(F)cc6)nc(-c6ccc(F)cc6)n5)cc4)cccc23)cc1]

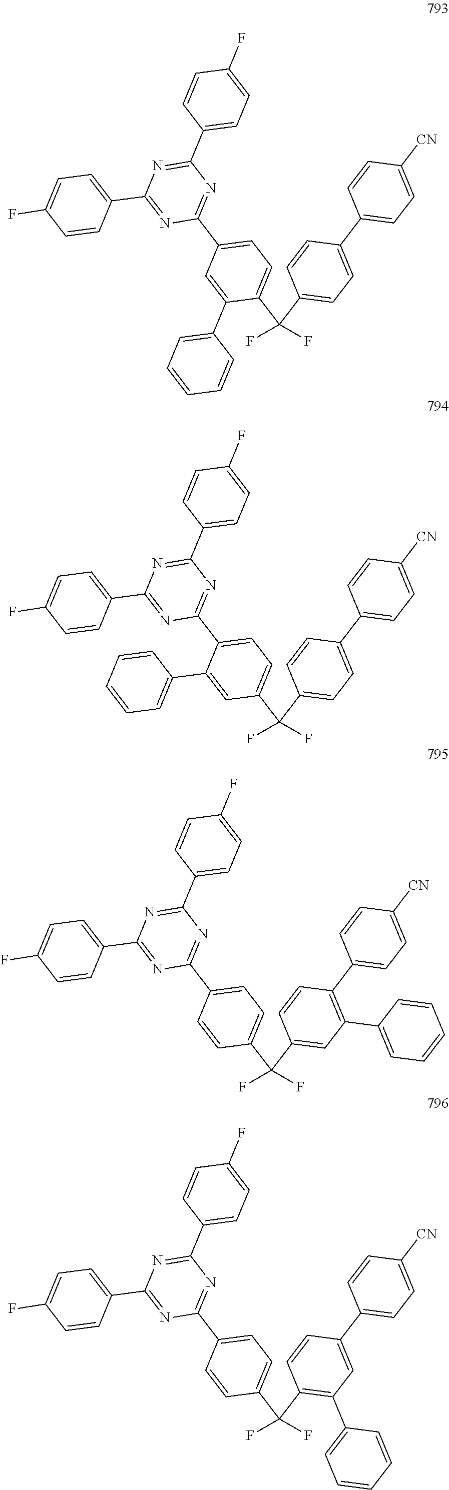

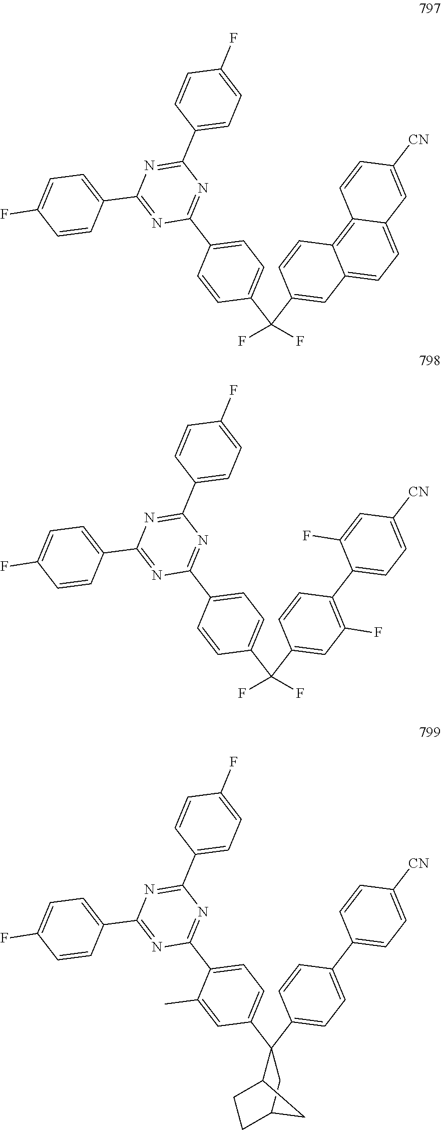 [SMILES: N#Cc1ccc2c(ccc3cc(C(F)(F)c4ccc(-c5nc(-c6ccc(F)cc6)nc(-c6ccc(F)cc6)n5)cc4)ccc32)c1 ; N#Cc1ccc(-c2ccc(C(F)(F)c3ccc(-c4nc(-c5ccc(F)cc5)nc(-c5ccc(F)cc5)n4)cc3)cc2F)c(F)c1 ; Cc1cc(C2(c3ccc(-c4ccc(C#N)cc4)cc3)CC3CCC2C3)ccc1-c1nc(-c2ccc(F)cc2)nc(-c2ccc(F)cc2)n1]

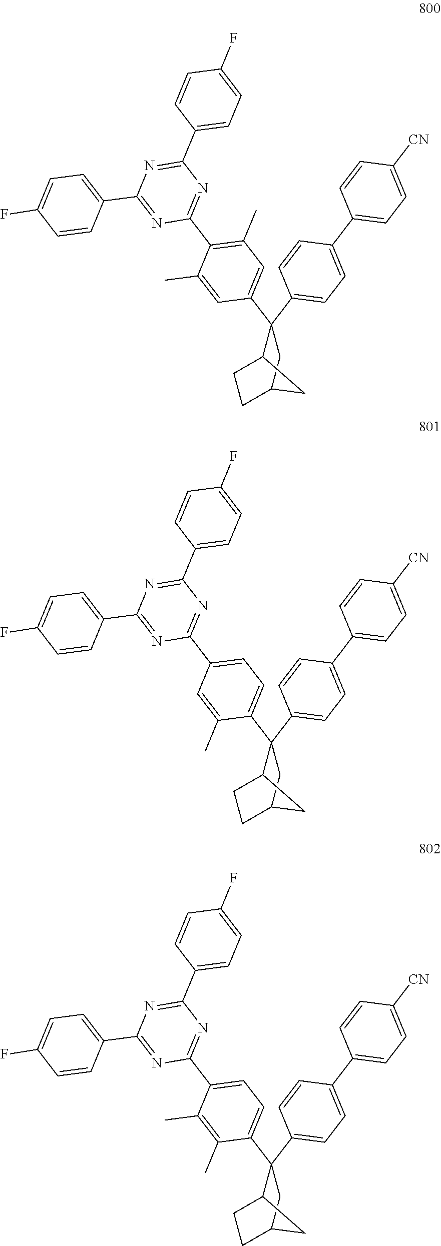 [SMILES: Cc1cc(C2(c3ccc(-c4ccc(C#N)cc4)cc3)CC3CCC2C3)cc(C)c1-c1nc(-c2ccc(F)cc2)nc(-c2ccc(F)cc2)n1 ; Cc1cc(-c2nc(-c3ccc(F)cc3)nc(-c3ccc(F)cc3)n2)ccc1C1(c2ccc(-c3ccc(C#N)cc3)cc2)CC2CCC1C2 ; Cc1c(-c2nc(-c3ccc(F)cc3)nc(-c3ccc(F)cc3)n2)ccc(C2(c3ccc(-c4ccc(C#N)cc4)cc3)CC3CCC2C3)c1C]

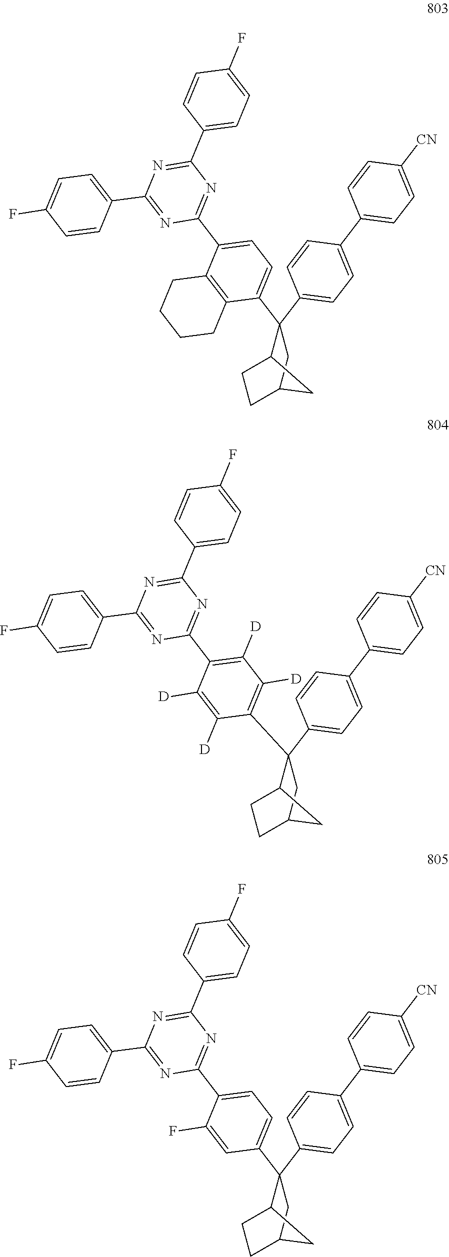 [SMILES: N#Cc1ccc(-c2ccc(C3(c4ccc(-c5nc(-c6ccc(F)cc6)nc(-c6ccc(F)cc6)n5)c5c4CCCC5)CC4CCC3C4)cc2)cc1 ; [2H]c1c([2H])c(C2(c3ccc(-c4ccc(C#N)cc4)cc3)CC3CCC2C3)c([2H])c([2H])c1-c1nc(-c2ccc(F)cc2)nc(-c2ccc(F)cc2)n1 ; N#Cc1ccc(-c2ccc(C3(c4ccc(-c5nc(-c6ccc(F)cc6)nc(-c6ccc(F)cc6)n5)c(F)c4)CC4CCC3C4)cc2)cc1]

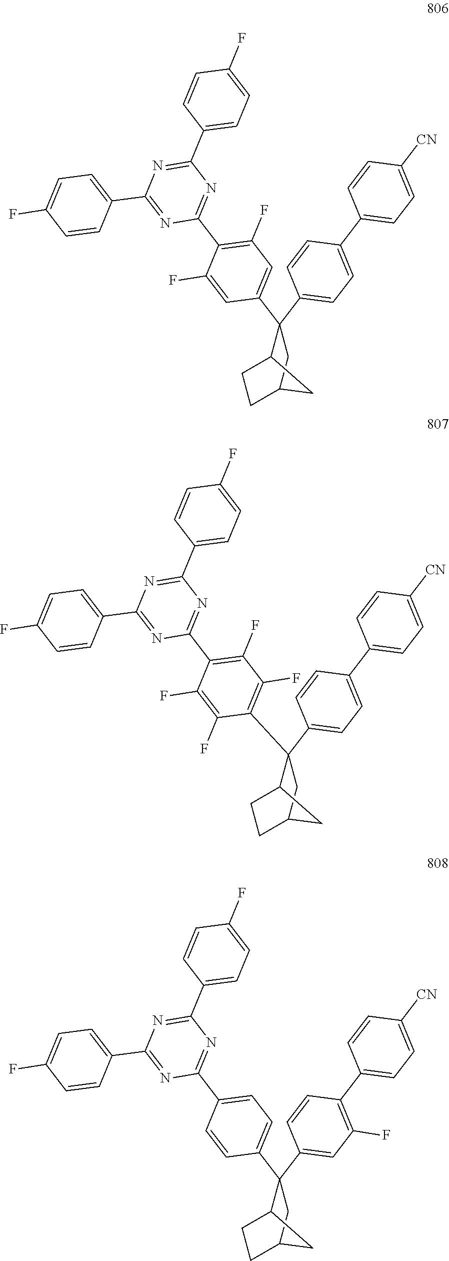 [SMILES: N#Cc1ccc(-c2ccc(C3(c4cc(F)c(-c5nc(-c6ccc(F)cc6)nc(-c6ccc(F)cc6)n5)c(F)c4)CC4CCC3C4)cc2)cc1 ; N#Cc1ccc(-c2ccc(C3(c4c(F)c(F)c(-c5nc(-c6ccc(F)cc6)nc(-c6ccc(F)cc6)n5)c(F)c4F)CC4CCC3C4)cc2)cc1 ; N#Cc1ccc(-c2ccc(C3(c4ccc(-c5nc(-c6ccc(F)cc6)nc(-c6ccc(F)cc6)n5)cc4)CC4CCC3C4)cc2F)cc1]

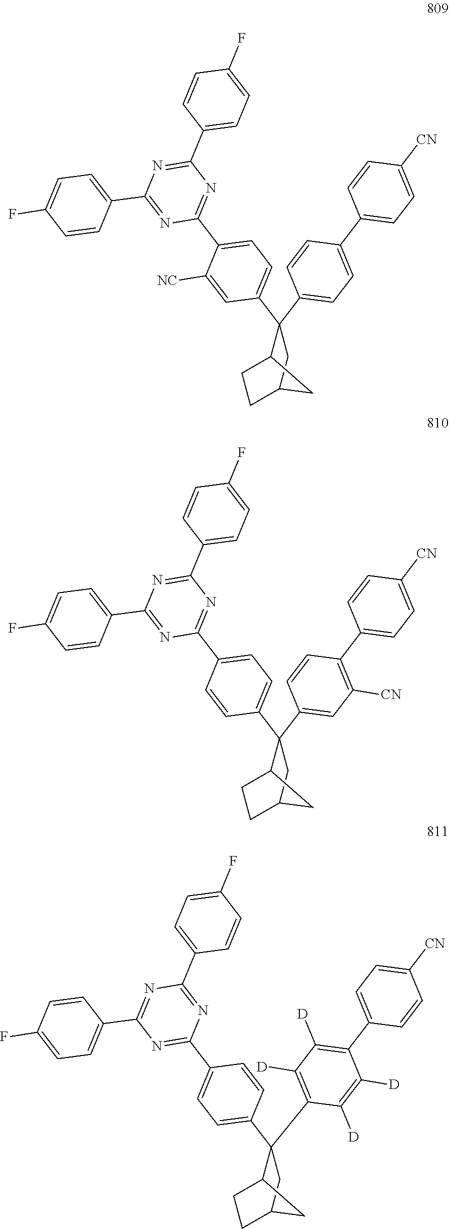

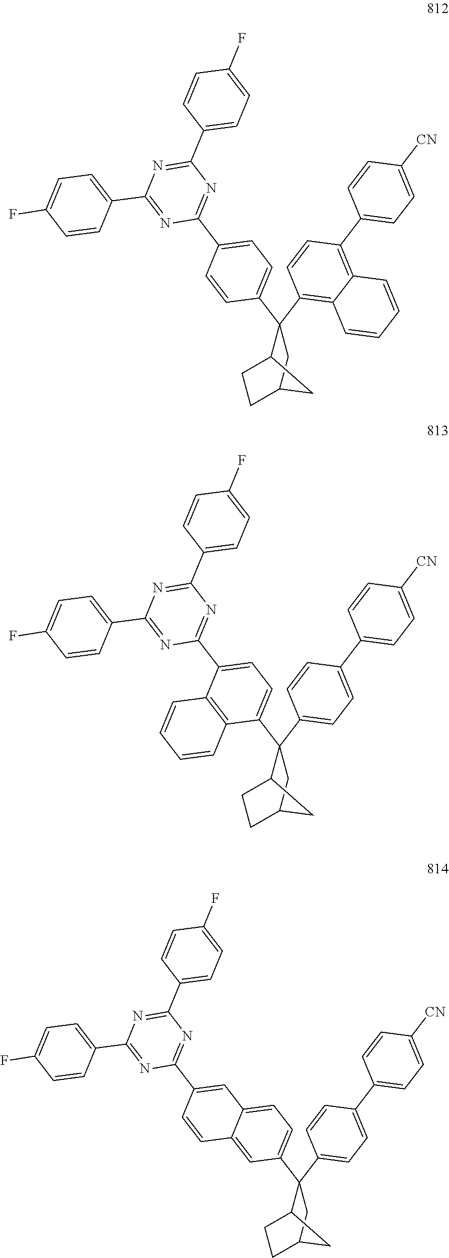 [SMILES: N#Cc1ccc(-c2ccc(C3(c4ccc(-c5nc(-c6ccc(F)cc6)nc(-c6ccc(F)cc6)n5)cc4)CC4CCC3C4)c3ccccc23)cc1 ; N#Cc1ccc(-c2ccc(C3(c4ccc(-c5nc(-c6ccc(F)cc6)nc(-c6ccc(F)cc6)n5)c5ccccc45)CC4CCC3C4)cc2)cc1 ; N#Cc1ccc(-c2ccc(C3(c4ccc5cc(-c6nc(-c7ccc(F)cc7)nc(-c7ccc(F)cc7)n6)ccc5c4)CC4CCC3C4)cc2)cc1]

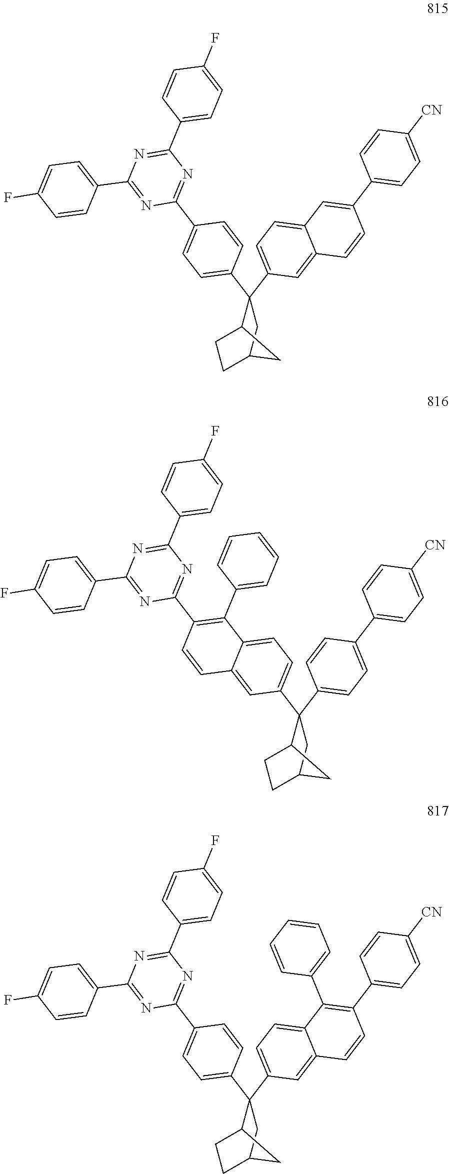 [SMILES: N#Cc1ccc(-c2ccc3cc(C4(c5ccc(-c6nc(-c7ccc(F)cc7)nc(-c7ccc(F)cc7)n6)cc5)CC5CCC4C5)ccc3c2)cc1 ; N#Cc1ccc(-c2ccc(C3(c4ccc5c(-c6ccccc6)c(-c6nc(-c7ccc(F)cc7)nc(-c7ccc(F)cc7)n6)ccc5c4)CC4CCC3C4)cc2)cc1 ; N#Cc1ccc(-c2ccc3cc(C4(c5ccc(-c6nc(-c7ccc(F)cc7)nc(-c7ccc(F)cc7)n6)cc5)CC5CCC4C5)ccc3c2-c2ccccc2)cc1]

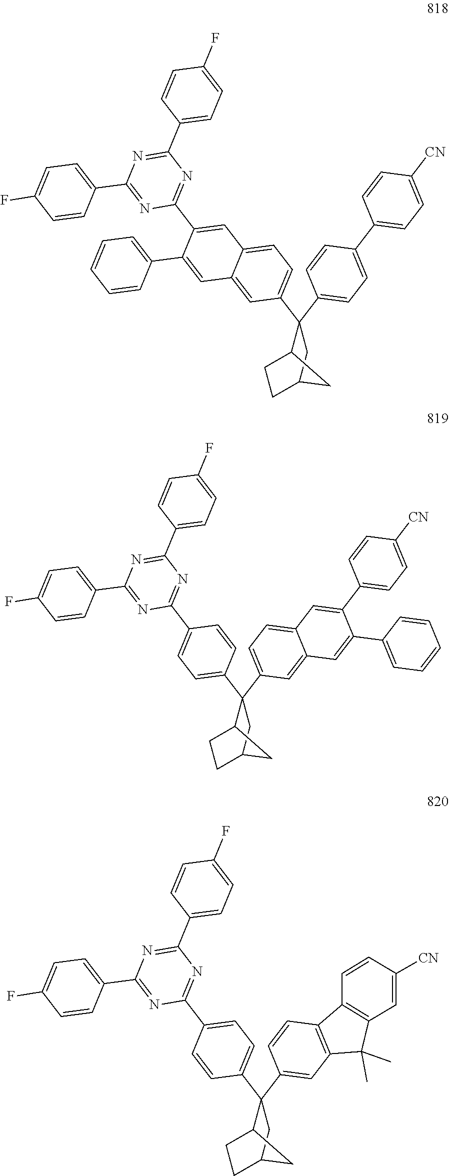 [SMILES: N#Cc1ccc(-c2ccc(C3(c4ccc5cc(-c6nc(-c7ccc(F)cc7)nc(-c7ccc(F)cc7)n6)c(-c6ccccc6)cc5c4)CC4CCC3C4)cc2)cc1 ; N#Cc1ccc(-c2cc3ccc(C4(c5ccc(-c6nc(-c7ccc(F)cc7)nc(-c7ccc(F)cc7)n6)cc5)CC5CCC4C5)cc3cc2-c2ccccc2)cc1 ; CC1(C)c2cc(C#N)ccc2-c2ccc(C3(c4ccc(-c5nc(-c6ccc(F)cc6)nc(-c6ccc(F)cc6)n5)cc4)CC4CCC3C4)cc21]

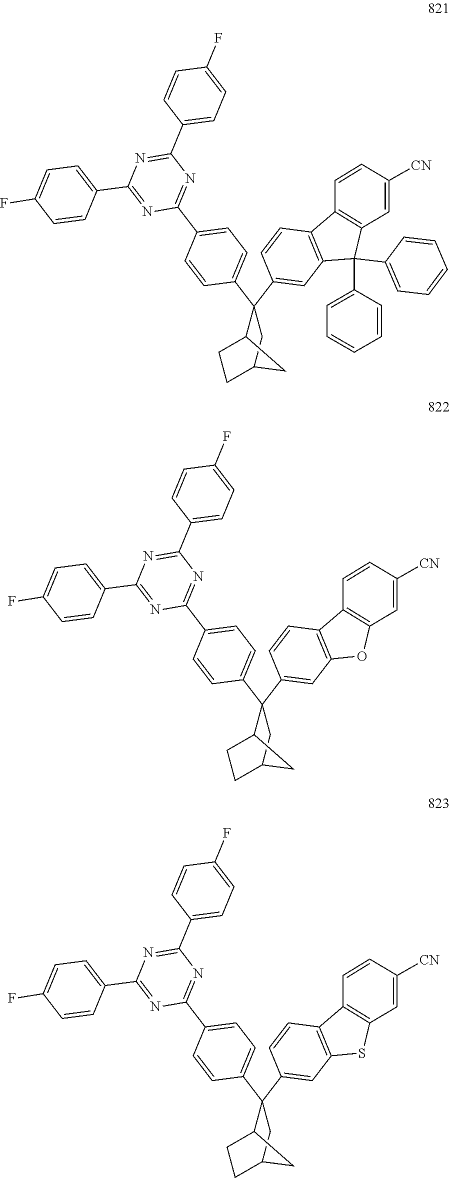 [SMILES: N#Cc1ccc2c(c1)C(c1ccccc1)(c1ccccc1)c1cc(C3(c4ccc(-c5nc(-c6ccc(F)cc6)nc(-c6ccc(F)cc6)n5)cc4)CC4CCC3C4)ccc1-2 ; N#Cc1ccc2c(c1)oc1cc(C3(c4ccc(-c5nc(-c6ccc(F)cc6)nc(-c6ccc(F)cc6)n5)cc4)CC4CCC3C4)ccc12 ; N#Cc1ccc2c(c1)sc1cc(C3(c4ccc(-c5nc(-c6ccc(F)cc6)nc(-c6ccc(F)cc6)n5)cc4)CC4CCC3C4)ccc12]

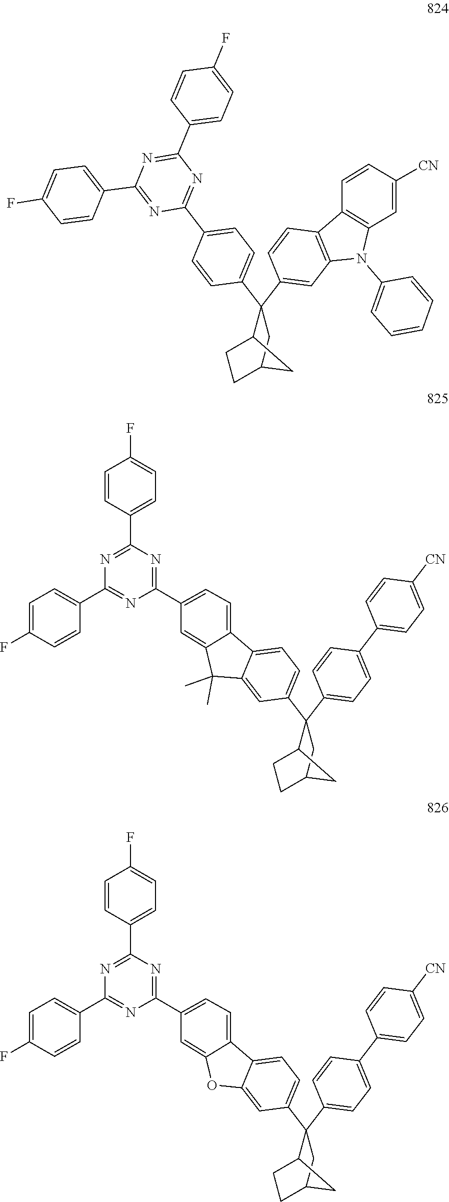 [SMILES: N#Cc1ccc2c3ccc(C4(c5ccc(-c6nc(-c7ccc(F)cc7)nc(-c7ccc(F)cc7)n6)cc5)CC5CCC4C5)cc3n(-c3ccccc3)c2c1 ; CC1(C)c2cc(-c3nc(-c4ccc(F)cc4)nc(-c4ccc(F)cc4)n3)ccc2-c2ccc(C3(c4ccc(-c5ccc(C#N)cc5)cc4)CC4CCC3C4)cc21 ; N#Cc1ccc(-c2ccc(C3(c4ccc5c(c4)oc4cc(-c6nc(-c7ccc(F)cc7)nc(-c7ccc(F)cc7)n6)ccc45)CC4CCC3C4)cc2)cc1]

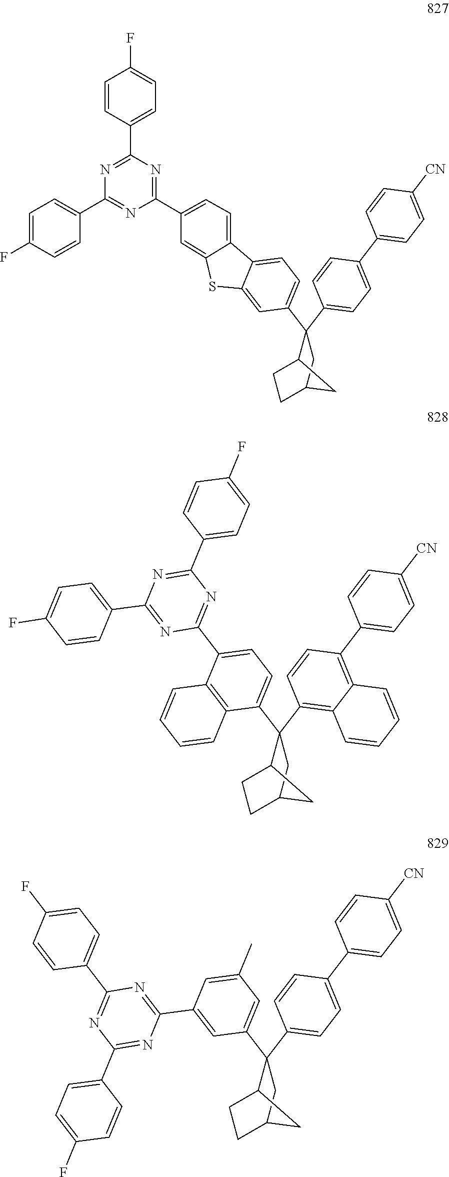 [SMILES: N#Cc1ccc(-c2ccc(C3(c4ccc5c(c4)sc4cc(-c6nc(-c7ccc(F)cc7)nc(-c7ccc(F)cc7)n6)ccc45)CC4CCC3C4)cc2)cc1 ; N#Cc1ccc(-c2ccc(C3(c4ccc(-c5nc(-c6ccc(F)cc6)nc(-c6ccc(F)cc6)n5)c5ccccc45)CC4CCC3C4)c3ccccc23)cc1 ; Cc1cc(-c2nc(-c3ccc(F)cc3)nc(-c3ccc(F)cc3)n2)cc(C2(c3ccc(-c4ccc(C#N)cc4)cc3)CC3CCC2C3)c1]

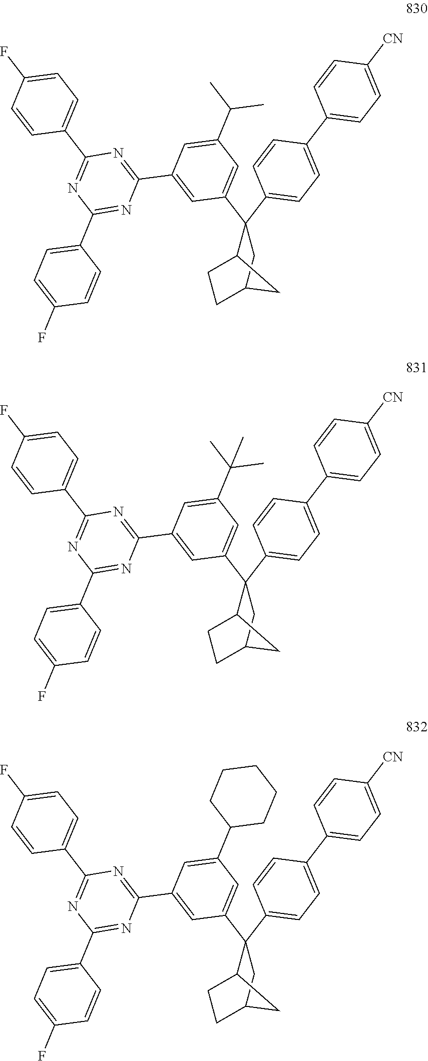 [SMILES: CC(C)c1cc(-c2nc(-c3ccc(F)cc3)nc(-c3ccc(F)cc3)n2)cc(C2(c3ccc(-c4ccc(C#N)cc4)cc3)CC3CCC2C3)c1 ; CC(C)(C)c1cc(-c2nc(-c3ccc(F)cc3)nc(-c3ccc(F)cc3)n2)cc(C2(c3ccc(-c4ccc(C#N)cc4)cc3)CC3CCC2C3)c1 ; N#Cc1ccc(-c2ccc(C3(c4cc(-c5nc(-c6ccc(F)cc6)nc(-c6ccc(F)cc6)n5)cc(C5CCCCC5)c4)CC4CCC3C4)cc2)cc1]

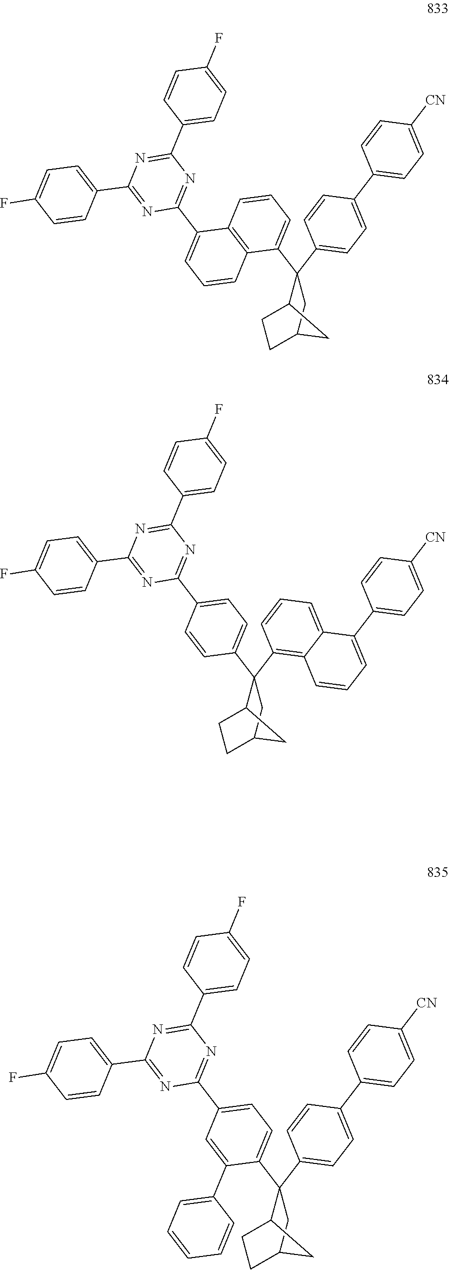 [SMILES: N#Cc1ccc(-c2ccc(C3(c4cccc5c(-c6nc(-c7ccc(F)cc7)nc(-c7ccc(F)cc7)n6)cccc45)CC4CCC3C4)cc2)cc1 ; N#Cc1ccc(-c2cccc3c(C4(c5ccc(-c6nc(-c7ccc(F)cc7)nc(-c7ccc(F)cc7)n6)cc5)CC5CCC4C5)cccc23)cc1 ; N#Cc1ccc(-c2ccc(C3(c4ccc(-c5nc(-c6ccc(F)cc6)nc(-c6ccc(F)cc6)n5)cc4-c4ccccc4)CC4CCC3C4)cc2)cc1]

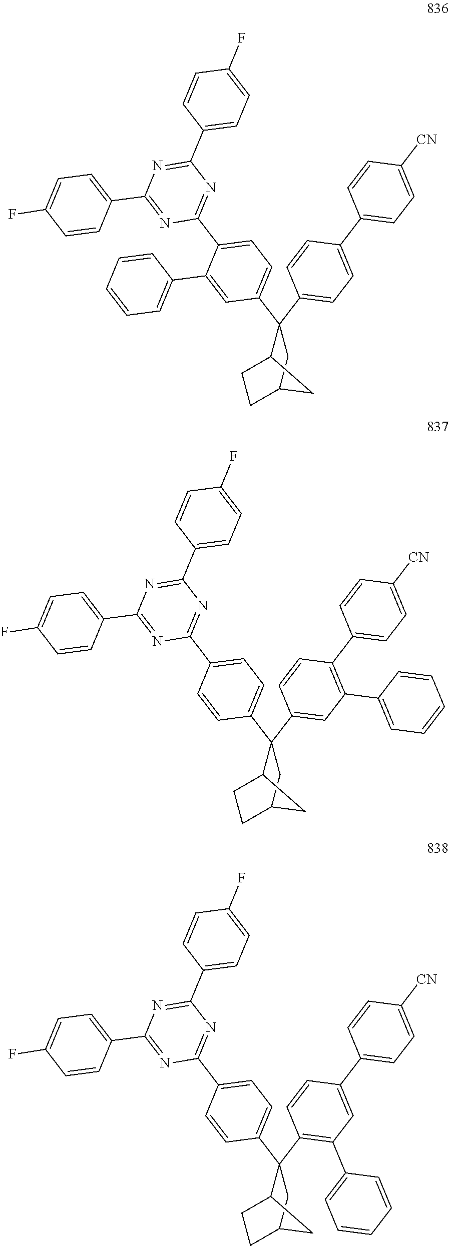 [SMILES: N#Cc1ccc(-c2ccc(C3(c4ccc(-c5nc(-c6ccc(F)cc6)nc(-c6ccc(F)cc6)n5)c(-c5ccccc5)c4)CC4CCC3C4)cc2)cc1 ; N#Cc1ccc(-c2ccc(C3(c4ccc(-c5nc(-c6ccc(F)cc6)nc(-c6ccc(F)cc6)n5)cc4)CC4CCC3C4)cc2-c2ccccc2)cc1 ; N#Cc1ccc(-c2ccc(C3(c4ccc(-c5nc(-c6ccc(F)cc6)nc(-c6ccc(F)cc6)n5)cc4)CC4CCC3C4)c(-c3ccccc3)c2)cc1]

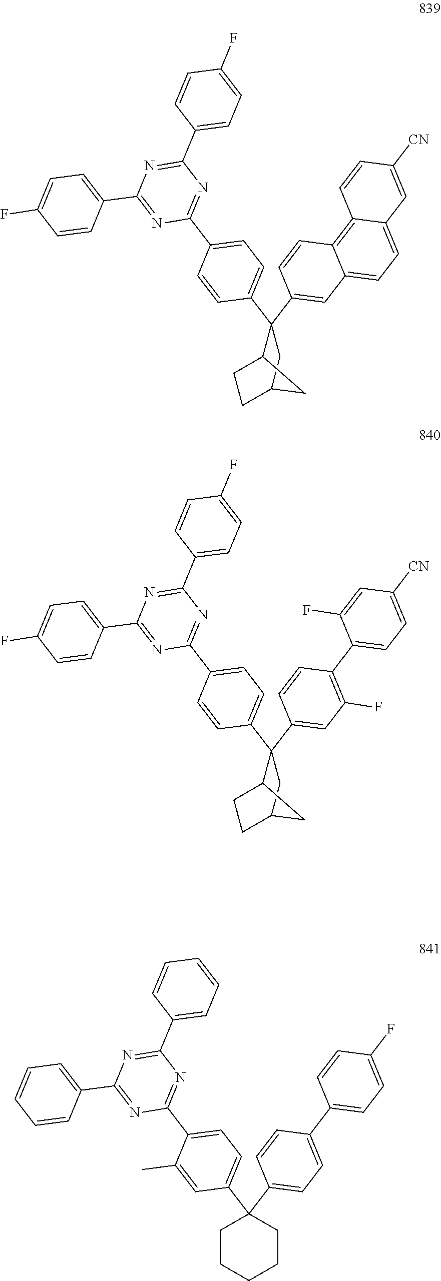 [SMILES: N#Cc1ccc2c(ccc3cc(C4(c5ccc(-c6nc(-c7ccc(F)cc7)nc(-c7ccc(F)cc7)n6)cc5)CC5CCC4C5)ccc32)c1 ; N#Cc1ccc(-c2ccc(C3(c4ccc(-c5nc(-c6ccc(F)cc6)nc(-c6ccc(F)cc6)n5)cc4)CC4CCC3C4)cc2F)c(F)c1 ; Cc1cc(C2(c3ccc(-c4ccc(F)cc4)cc3)CCCCC2)ccc1-c1nc(-c2ccccc2)nc(-c2ccccc2)n1]

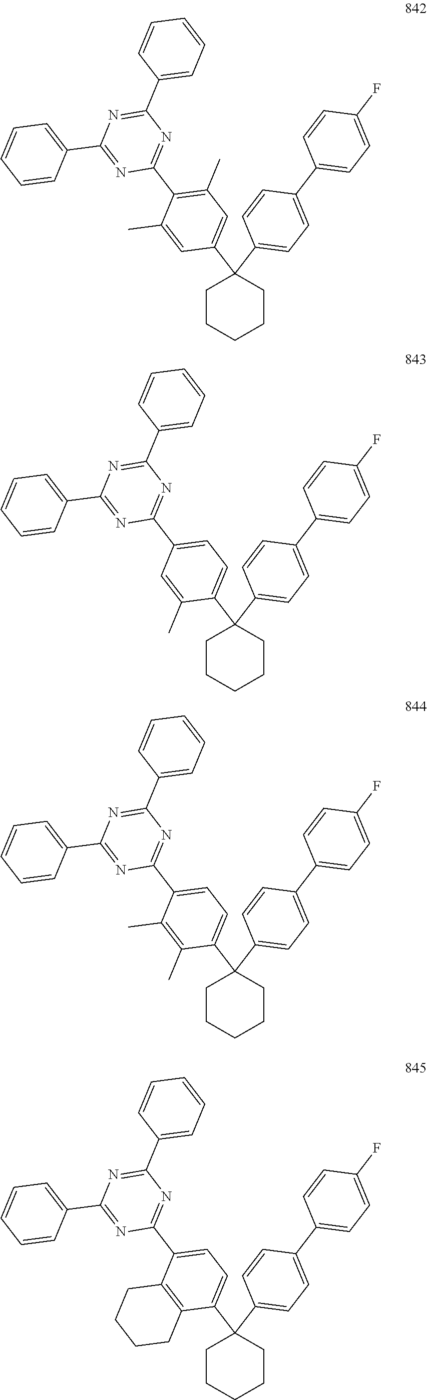 [SMILES: Cc1cc(C2(c3ccc(-c4ccc(F)cc4)cc3)CCCCC2)cc(C)c1-c1nc(-c2ccccc2)nc(-c2ccccc2)n1 ; Cc1cc(-c2nc(-c3ccccc3)nc(-c3ccccc3)n2)ccc1C1(c2ccc(-c3ccc(F)cc3)cc2)CCCCC1 ; Cc1c(-c2nc(-c3ccccc3)nc(-c3ccccc3)n2)ccc(C2(c3ccc(-c4ccc(F)cc4)cc3)CCCCC2)c1C ; Fc1ccc(-c2ccc(C3(c4ccc(-c5nc(-c6ccccc6)nc(-c6ccccc6)n5)c5c4CCCC5)CCCCC3)cc2)cc1]

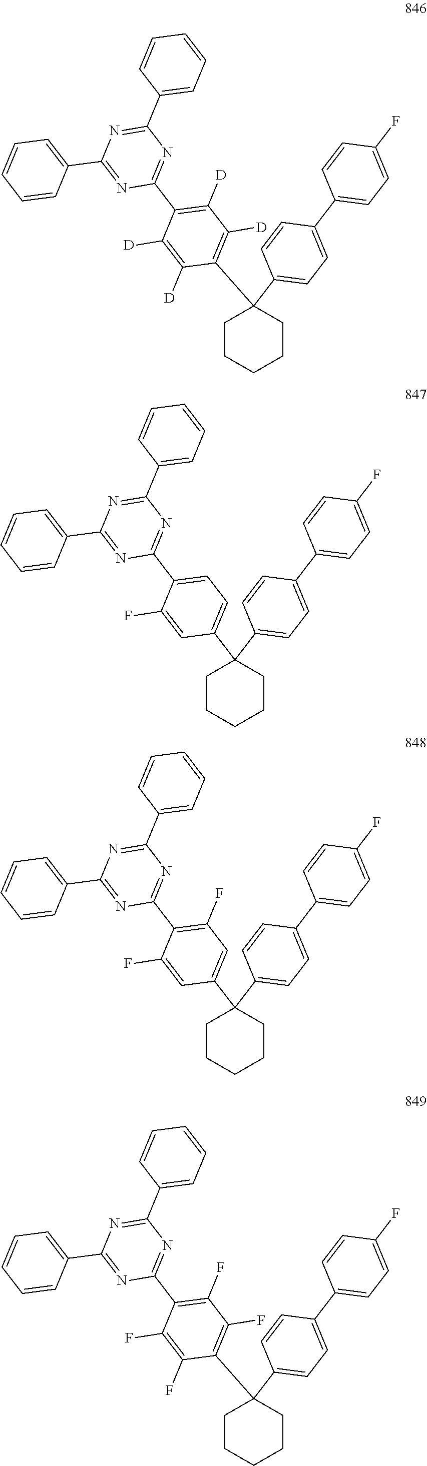 [SMILES: [2H]c1c([2H])c(C2(c3ccc(-c4ccc(F)cc4)cc3)CCCCC2)c([2H])c([2H])c1-c1nc(-c2ccccc2)nc(-c2ccccc2)n1 ; Fc1ccc(-c2ccc(C3(c4ccc(-c5nc(-c6ccccc6)nc(-c6ccccc6)n5)c(F)c4)CCCCC3)cc2)cc1 ; Fc1ccc(-c2ccc(C3(c4cc(F)c(-c5nc(-c6ccccc6)nc(-c6ccccc6)n5)c(F)c4)CCCCC3)cc2)cc1 ; Fc1ccc(-c2ccc(C3(c4c(F)c(F)c(-c5nc(-c6ccccc6)nc(-c6ccccc6)n5)c(F)c4F)CCCCC3)cc2)cc1]

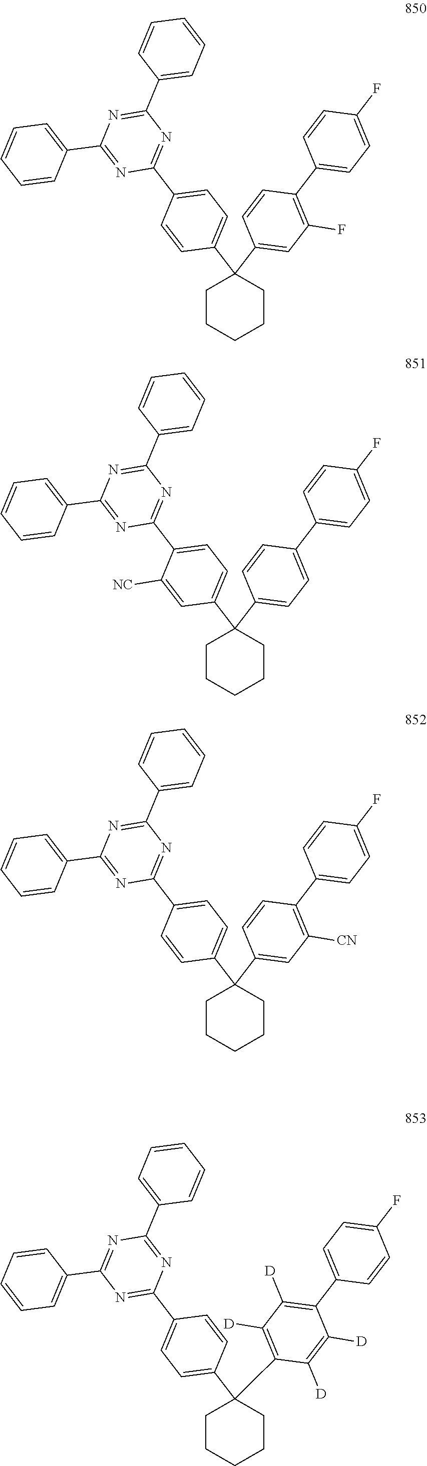 [SMILES: Fc1ccc(-c2ccc(C3(c4ccc(-c5nc(-c6ccccc6)nc(-c6ccccc6)n5)cc4)CCCCC3)cc2F)cc1 ; N#Cc1cc(C2(c3ccc(-c4ccc(F)cc4)cc3)CCCCC2)ccc1-c1nc(-c2ccccc2)nc(-c2ccccc2)n1 ; N#Cc1cc(C2(c3ccc(-c4nc(-c5ccccc5)nc(-c5ccccc5)n4)cc3)CCCCC2)ccc1-c1ccc(F)cc1 ; [2H]c1c([2H])c(C2(c3ccc(-c4nc(-c5ccccc5)nc(-c5ccccc5)n4)cc3)CCCCC2)c([2H])c([2H])c1-c1ccc(F)cc1]

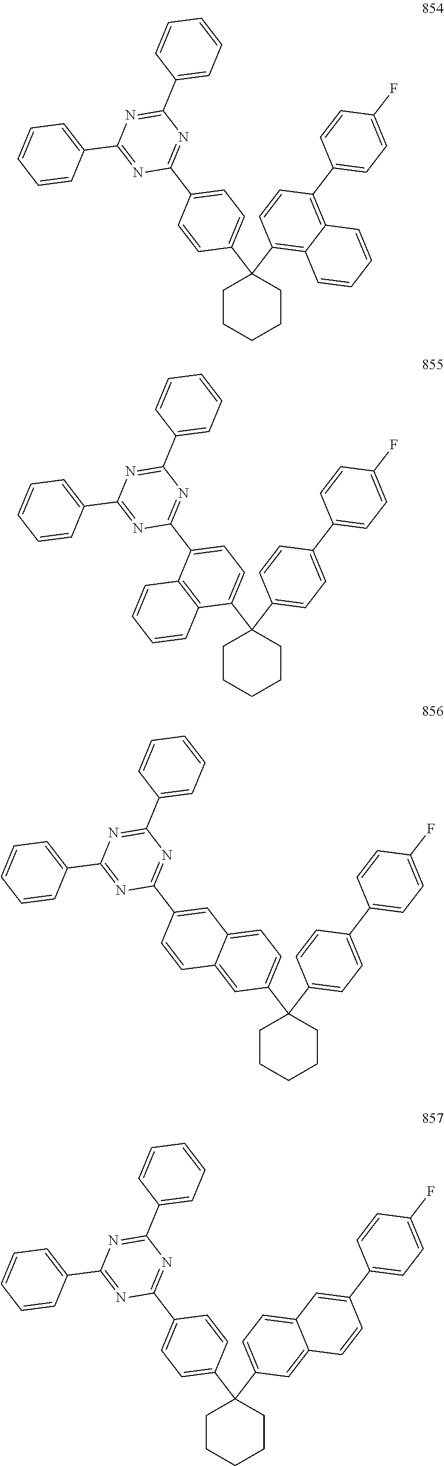 [SMILES: Fc1ccc(-c2ccc(C3(c4ccc(-c5nc(-c6ccccc6)nc(-c6ccccc6)n5)cc4)CCCCC3)c3ccccc23)cc1 ; Fc1ccc(-c2ccc(C3(c4ccc(-c5nc(-c6ccccc6)nc(-c6ccccc6)n5)c5ccccc45)CCCCC3)cc2)cc1 ; Fc1ccc(-c2ccc(C3(c4ccc5cc(-c6nc(-c7ccccc7)nc(-c7ccccc7)n6)ccc5c4)CCCCC3)cc2)cc1 ; Fc1ccc(-c2ccc3cc(C4(c5ccc(-c6nc(-c7ccccc7)nc(-c7ccccc7)n6)cc5)CCCCC4)ccc3c2)cc1]

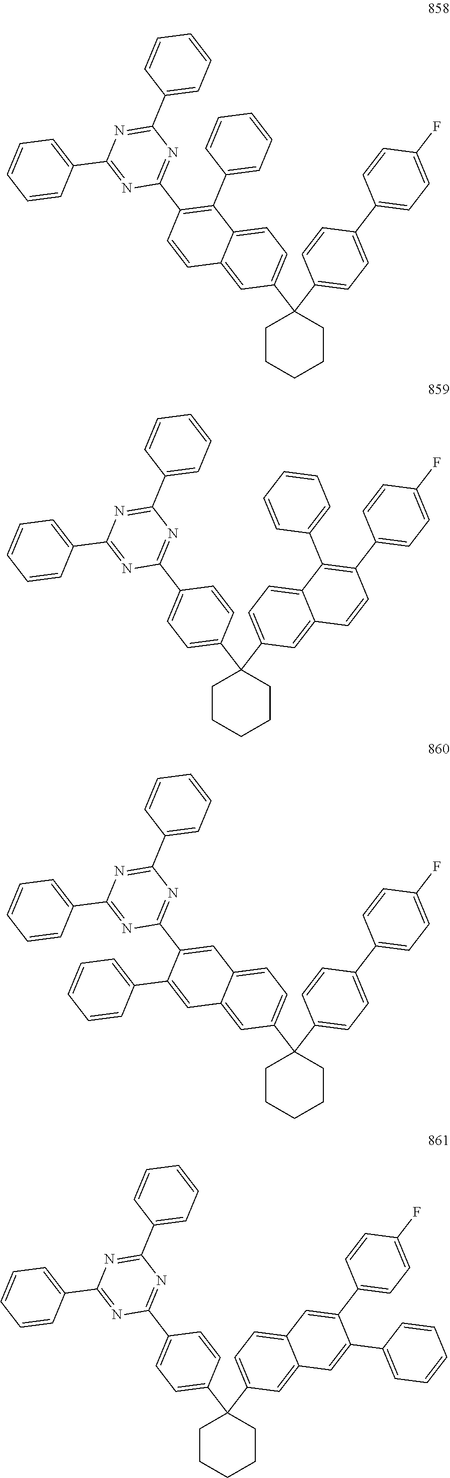 [SMILES: Fc1ccc(-c2ccc(C3(c4ccc5c(-c6ccccc6)c(-c6nc(-c7ccccc7)nc(-c7ccccc7)n6)ccc5c4)CCCCC3)cc2)cc1 ; Fc1ccc(-c2ccc3cc(C4(c5ccc(-c6nc(-c7ccccc7)nc(-c7ccccc7)n6)cc5)CCCCC4)ccc3c2-c2ccccc2)cc1 ; Fc1ccc(-c2ccc(C3(c4ccc5cc(-c6nc(-c7ccccc7)nc(-c7ccccc7)n6)c(-c6ccccc6)cc5c4)CCCCC3)cc2)cc1 ; Fc1ccc(-c2cc3ccc(C4(c5ccc(-c6nc(-c7ccccc7)nc(-c7ccccc7)n6)cc5)CCCCC4)cc3cc2-c2ccccc2)cc1]

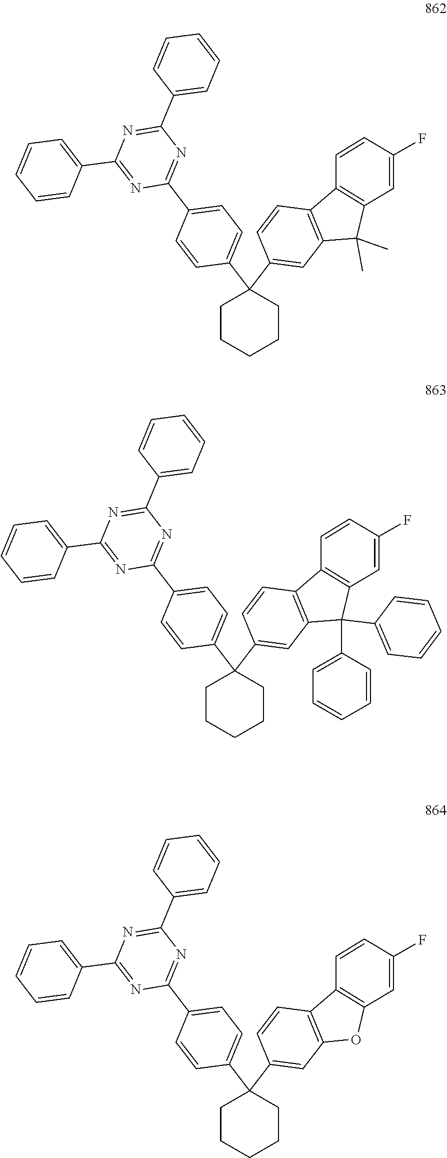 [SMILES: CC1(C)c2cc(F)ccc2-c2ccc(C3(c4ccc(-c5nc(-c6ccccc6)nc(-c6ccccc6)n5)cc4)CCCCC3)cc21 ; Fc1ccc2c(c1)C(c1ccccc1)(c1ccccc1)c1cc(C3(c4ccc(-c5nc(-c6ccccc6)nc(-c6ccccc6)n5)cc4)CCCCC3)ccc1-2 ; Fc1ccc2c(c1)oc1cc(C3(c4ccc(-c5nc(-c6ccccc6)nc(-c6ccccc6)n5)cc4)CCCCC3)ccc12]

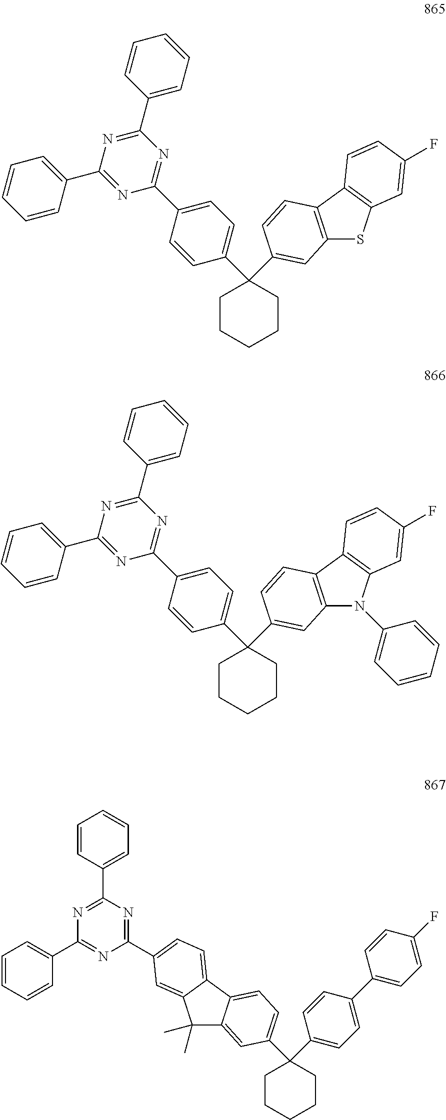 [SMILES: Fc1ccc2c(c1)sc1cc(C3(c4ccc(-c5nc(-c6ccccc6)nc(-c6ccccc6)n5)cc4)CCCCC3)ccc12 ; Fc1ccc2c3ccc(C4(c5ccc(-c6nc(-c7ccccc7)nc(-c7ccccc7)n6)cc5)CCCCC4)cc3n(-c3ccccc3)c2c1 ; CC1(C)c2cc(-c3nc(-c4ccccc4)nc(-c4ccccc4)n3)ccc2-c2ccc(C3(c4ccc(-c5ccc(F)cc5)cc4)CCCCC3)cc21]

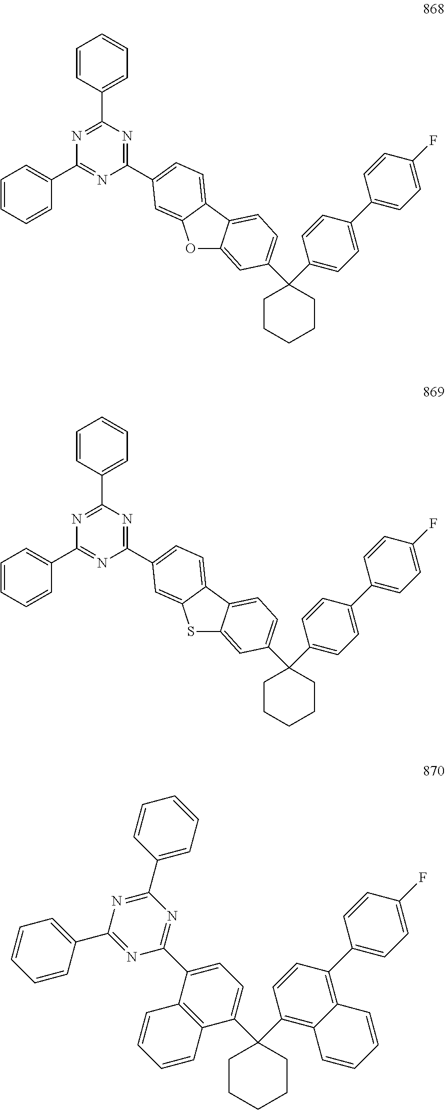 [SMILES: Fc1ccc(-c2ccc(C3(c4ccc5c(c4)oc4cc(-c6nc(-c7ccccc7)nc(-c7ccccc7)n6)ccc45)CCCCC3)cc2)cc1 ; Fc1ccc(-c2ccc(C3(c4ccc5c(c4)sc4cc(-c6nc(-c7ccccc7)nc(-c7ccccc7)n6)ccc45)CCCCC3)cc2)cc1 ; Fc1ccc(-c2ccc(C3(c4ccc(-c5nc(-c6ccccc6)nc(-c6ccccc6)n5)c5ccccc45)CCCCC3)c3ccccc23)cc1]

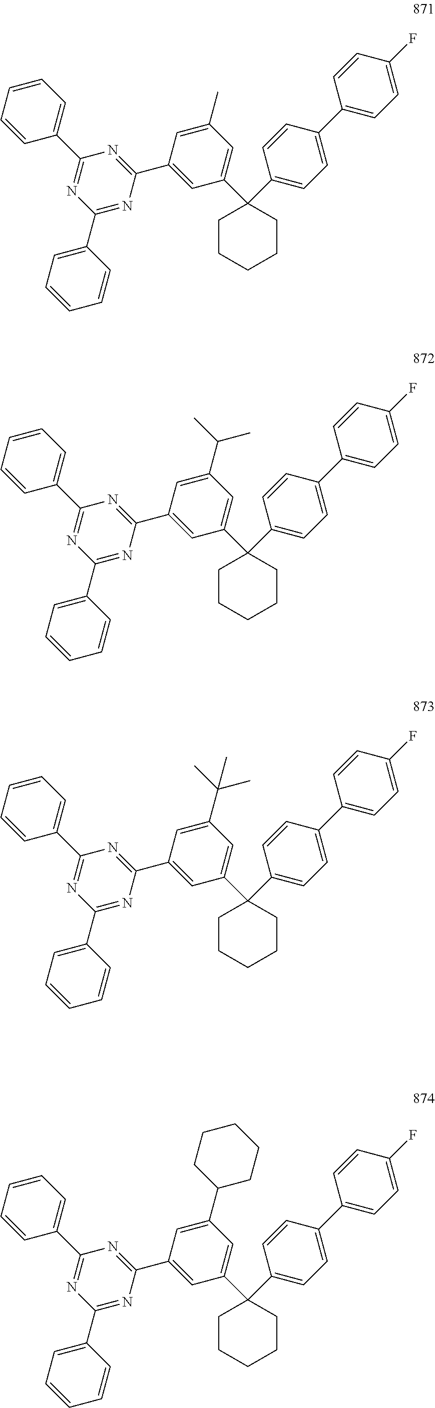 [SMILES: Cc1cc(-c2nc(-c3ccccc3)nc(-c3ccccc3)n2)cc(C2(c3ccc(-c4ccc(F)cc4)cc3)CCCCC2)c1 ; CC(C)c1cc(-c2nc(-c3ccccc3)nc(-c3ccccc3)n2)cc(C2(c3ccc(-c4ccc(F)cc4)cc3)CCCCC2)c1 ; CC(C)(C)c1cc(-c2nc(-c3ccccc3)nc(-c3ccccc3)n2)cc(C2(c3ccc(-c4ccc(F)cc4)cc3)CCCCC2)c1 ; Fc1ccc(-c2ccc(C3(c4cc(-c5nc(-c6ccccc6)nc(-c6ccccc6)n5)cc(C5CCCCC5)c4)CCCCC3)cc2)cc1]

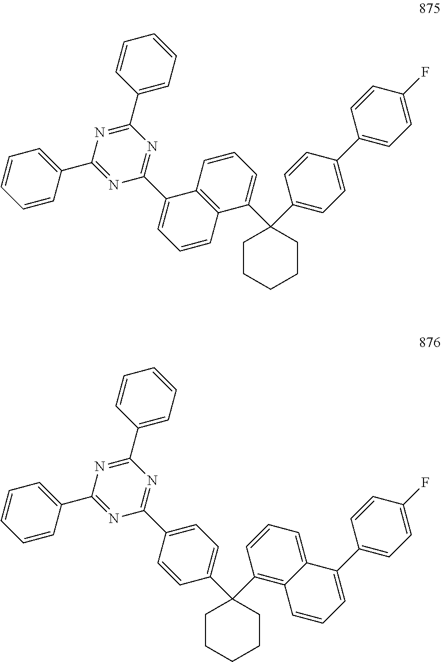 [SMILES: Fc1ccc(-c2ccc(C3(c4cccc5c(-c6nc(-c7ccccc7)nc(-c7ccccc7)n6)cccc45)CCCCC3)cc2)cc1 ; Fc1ccc(-c2cccc3c(C4(c5ccc(-c6nc(-c7ccccc7)nc(-c7ccccc7)n6)cc5)CCCCC4)cccc23)cc1]

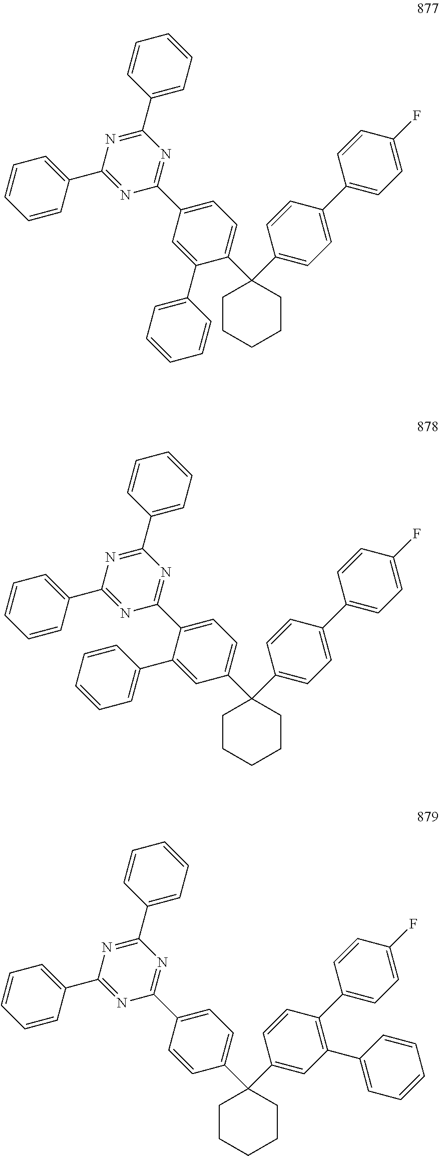 [SMILES: Fc1ccc(-c2ccc(C3(c4ccc(-c5nc(-c6ccccc6)nc(-c6ccccc6)n5)cc4-c4ccccc4)CCCCC3)cc2)cc1 ; Fc1ccc(-c2ccc(C3(c4ccc(-c5nc(-c6ccccc6)nc(-c6ccccc6)n5)c(-c5ccccc5)c4)CCCCC3)cc2)cc1 ; Fc1ccc(-c2ccc(C3(c4ccc(-c5nc(-c6ccccc6)nc(-c6ccccc6)n5)cc4)CCCCC3)cc2-c2ccccc2)cc1]

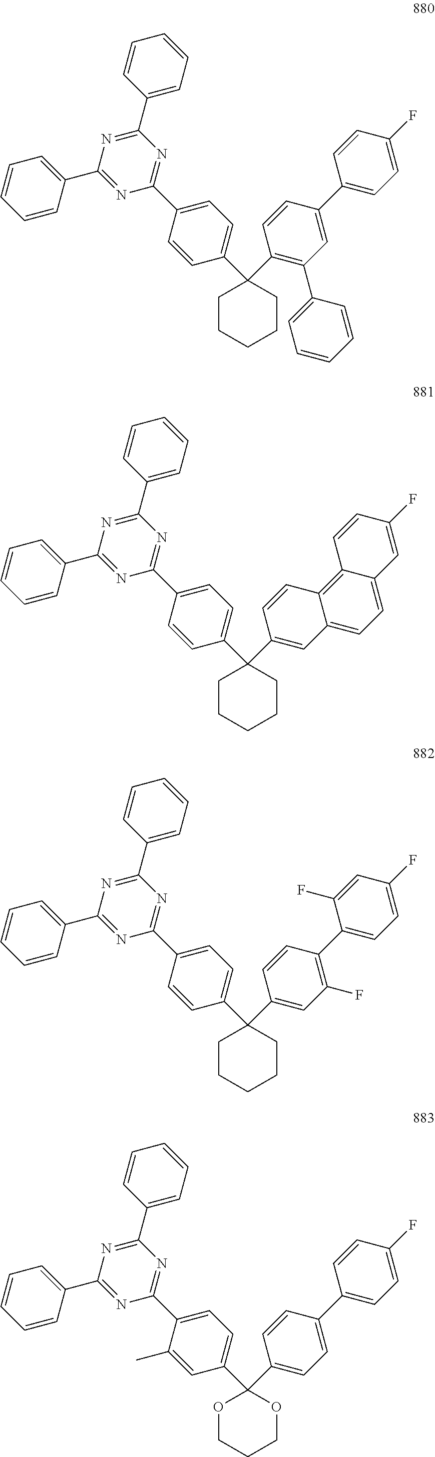 [SMILES: Fc1ccc(-c2ccc(C3(c4ccc(-c5nc(-c6ccccc6)nc(-c6ccccc6)n5)cc4)CCCCC3)c(-c3ccccc3)c2)cc1 ; Fc1ccc2c(ccc3cc(C4(c5ccc(-c6nc(-c7ccccc7)nc(-c7ccccc7)n6)cc5)CCCCC4)ccc32)c1 ; Fc1ccc(-c2ccc(C3(c4ccc(-c5nc(-c6ccccc6)nc(-c6ccccc6)n5)cc4)CCCCC3)cc2F)c(F)c1 ; Cc1cc(C2(c3ccc(-c4ccc(F)cc4)cc3)OCCCO2)ccc1-c1nc(-c2ccccc2)nc(-c2ccccc2)n1]

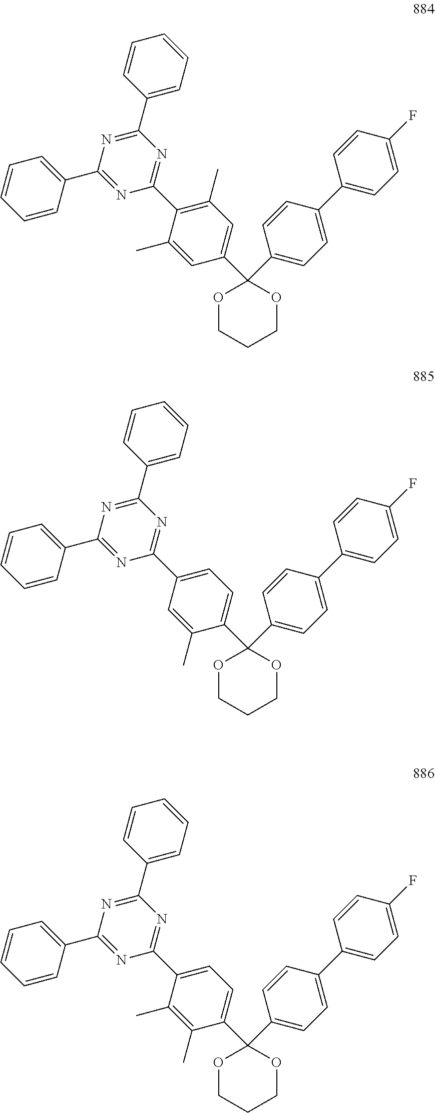 [SMILES: Cc1cc(C2(c3ccc(-c4ccc(F)cc4)cc3)OCCCO2)cc(C)c1-c1nc(-c2ccccc2)nc(-c2ccccc2)n1 ; Cc1cc(-c2nc(-c3ccccc3)nc(-c3ccccc3)n2)ccc1C1(c2ccc(-c3ccc(F)cc3)cc2)OCCCO1 ; Cc1c(-c2nc(-c3ccccc3)nc(-c3ccccc3)n2)ccc(C2(c3ccc(-c4ccc(F)cc4)cc3)OCCCO2)c1C]

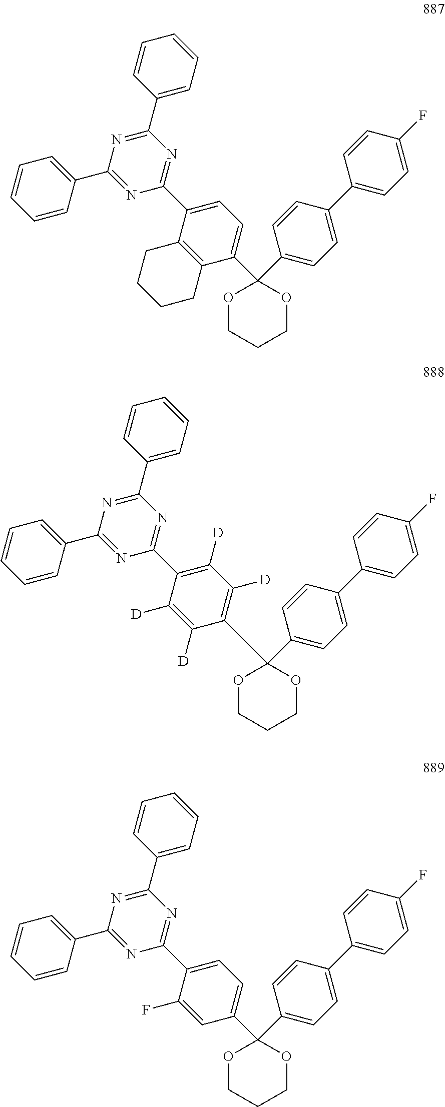 [SMILES: Fc1ccc(-c2ccc(C3(c4ccc(-c5nc(-c6ccccc6)nc(-c6ccccc6)n5)c5c4CCCC5)OCCCO3)cc2)cc1 ; [2H]c1c([2H])c(C2(c3ccc(-c4ccc(F)cc4)cc3)OCCCO2)c([2H])c([2H])c1-c1nc(-c2ccccc2)nc(-c2ccccc2)n1 ; Fc1ccc(-c2ccc(C3(c4ccc(-c5nc(-c6ccccc6)nc(-c6ccccc6)n5)c(F)c4)OCCCO3)cc2)cc1]

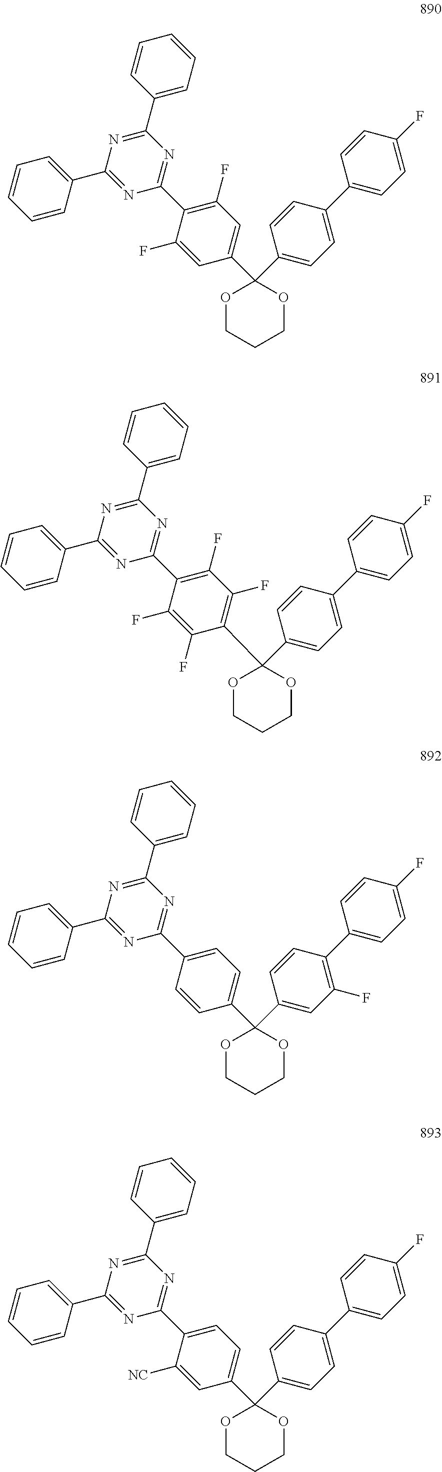 [SMILES: Fc1ccc(-c2ccc(C3(c4cc(F)c(-c5nc(-c6ccccc6)nc(-c6ccccc6)n5)c(F)c4)OCCCO3)cc2)cc1 ; Fc1ccc(-c2ccc(C3(c4c(F)c(F)c(-c5nc(-c6ccccc6)nc(-c6ccccc6)n5)c(F)c4F)OCCCO3)cc2)cc1 ; Fc1ccc(-c2ccc(C3(c4ccc(-c5nc(-c6ccccc6)nc(-c6ccccc6)n5)cc4)OCCCO3)cc2F)cc1 ; N#Cc1cc(C2(c3ccc(-c4ccc(F)cc4)cc3)OCCCO2)ccc1-c1nc(-c2ccccc2)nc(-c2ccccc2)n1]

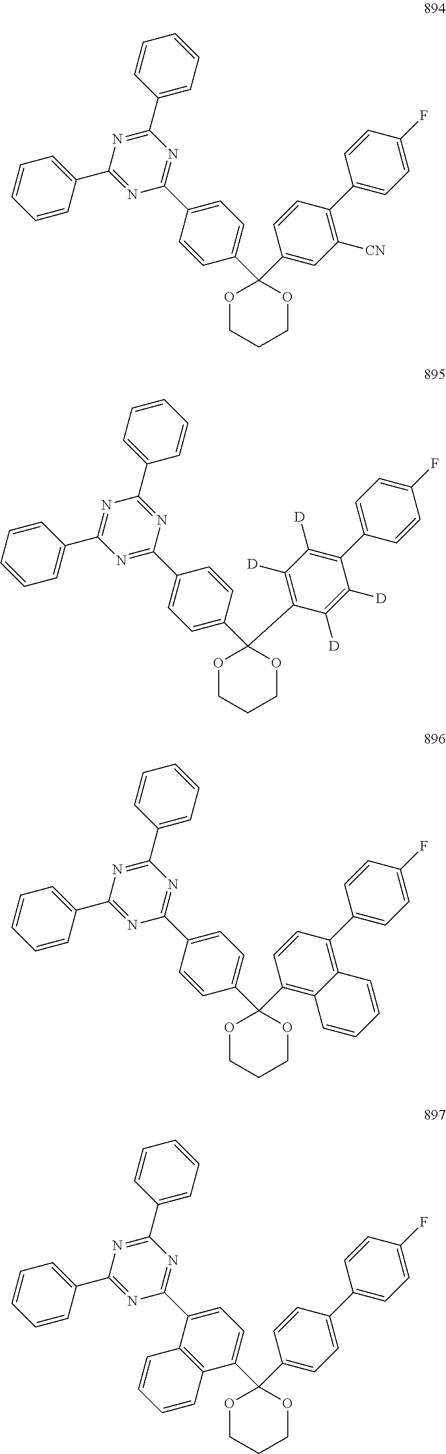 [SMILES: N#Cc1cc(C2(c3ccc(-c4nc(-c5ccccc5)nc(-c5ccccc5)n4)cc3)OCCCO2)ccc1-c1ccc(F)cc1 ; [2H]c1c([2H])c(C2(c3ccc(-c4nc(-c5ccccc5)nc(-c5ccccc5)n4)cc3)OCCCO2)c([2H])c([2H])c1-c1ccc(F)cc1 ; Fc1ccc(-c2ccc(C3(c4ccc(-c5nc(-c6ccccc6)nc(-c6ccccc6)n5)cc4)OCCCO3)c3ccccc23)cc1 ; Fc1ccc(-c2ccc(C3(c4ccc(-c5nc(-c6ccccc6)nc(-c6ccccc6)n5)c5ccccc45)OCCCO3)cc2)cc1]

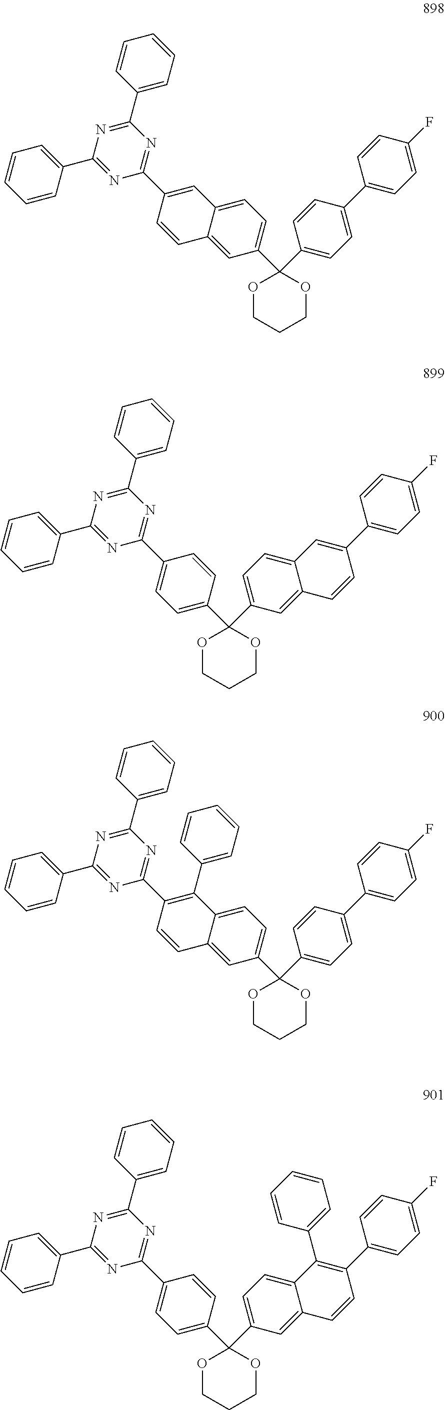 [SMILES: Fc1ccc(-c2ccc(C3(c4ccc5cc(-c6nc(-c7ccccc7)nc(-c7ccccc7)n6)ccc5c4)OCCCO3)cc2)cc1 ; Fc1ccc(-c2ccc3cc(C4(c5ccc(-c6nc(-c7ccccc7)nc(-c7ccccc7)n6)cc5)OCCCO4)ccc3c2)cc1 ; Fc1ccc(-c2ccc(C3(c4ccc5c(-c6ccccc6)c(-c6nc(-c7ccccc7)nc(-c7ccccc7)n6)ccc5c4)OCCCO3)cc2)cc1 ; Fc1ccc(-c2ccc3cc(C4(c5ccc(-c6nc(-c7ccccc7)nc(-c7ccccc7)n6)cc5)OCCCO4)ccc3c2-c2ccccc2)cc1]

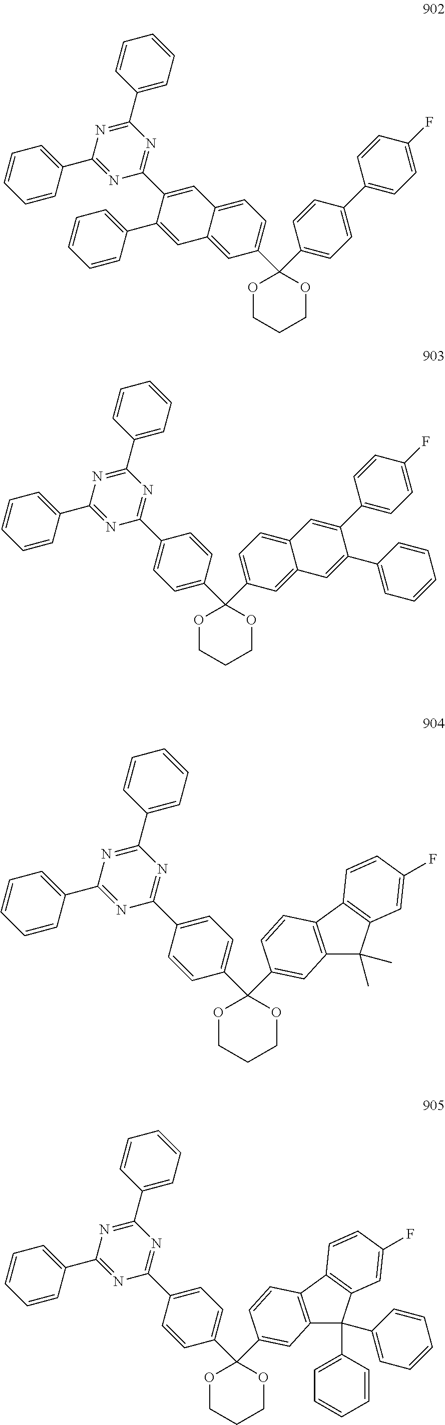 [SMILES: Fc1ccc(-c2ccc(C3(c4ccc5cc(-c6nc(-c7ccccc7)nc(-c7ccccc7)n6)c(-c6ccccc6)cc5c4)OCCCO3)cc2)cc1 ; Fc1ccc(-c2cc3ccc(C4(c5ccc(-c6nc(-c7ccccc7)nc(-c7ccccc7)n6)cc5)OCCCO4)cc3cc2-c2ccccc2)cc1 ; CC1(C)c2cc(F)ccc2-c2ccc(C3(c4ccc(-c5nc(-c6ccccc6)nc(-c6ccccc6)n5)cc4)OCCCO3)cc21 ; Fc1ccc2c(c1)C(c1ccccc1)(c1ccccc1)c1cc(C3(c4ccc(-c5nc(-c6ccccc6)nc(-c6ccccc6)n5)cc4)OCCCO3)ccc1-2]

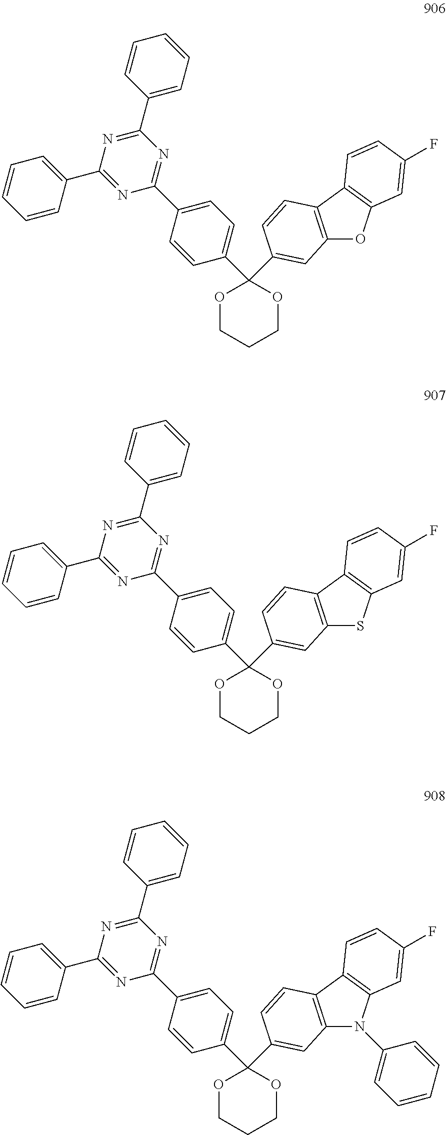 [SMILES: Fc1ccc2c(c1)oc1cc(C3(c4ccc(-c5nc(-c6ccccc6)nc(-c6ccccc6)n5)cc4)OCCCO3)ccc12 ; Fc1ccc2c(c1)sc1cc(C3(c4ccc(-c5nc(-c6ccccc6)nc(-c6ccccc6)n5)cc4)OCCCO3)ccc12 ; Fc1ccc2c3ccc(C4(c5ccc(-c6nc(-c7ccccc7)nc(-c7ccccc7)n6)cc5)OCCCO4)cc3n(-c3ccccc3)c2c1]

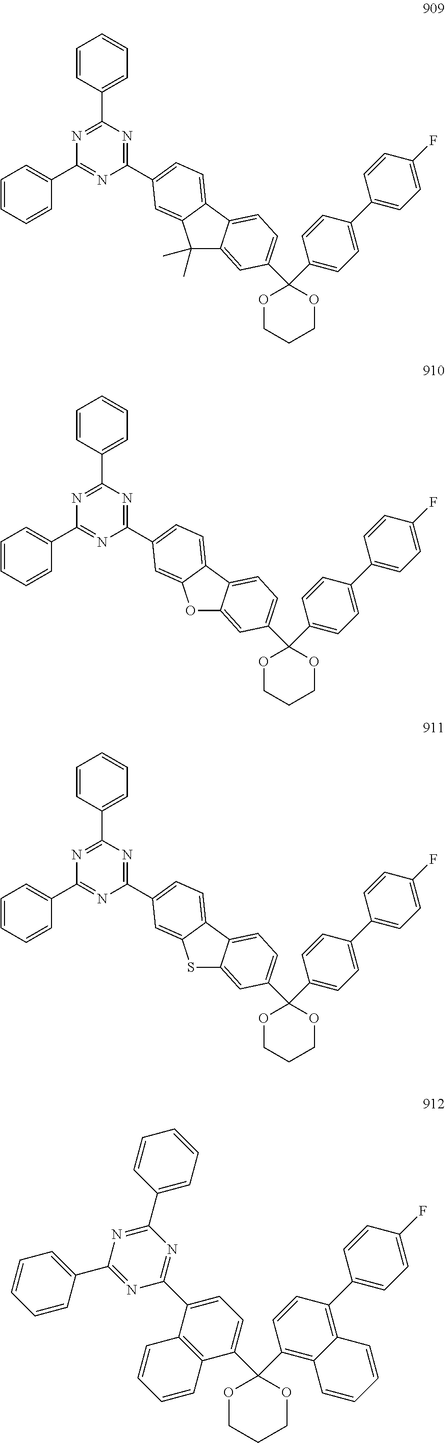 [SMILES: CC1(C)c2cc(-c3nc(-c4ccccc4)nc(-c4ccccc4)n3)ccc2-c2ccc(C3(c4ccc(-c5ccc(F)cc5)cc4)OCCCO3)cc21 ; Fc1ccc(-c2ccc(C3(c4ccc5c(c4)oc4cc(-c6nc(-c7ccccc7)nc(-c7ccccc7)n6)ccc45)OCCCO3)cc2)cc1 ; Fc1ccc(-c2ccc(C3(c4ccc5c(c4)sc4cc(-c6nc(-c7ccccc7)nc(-c7ccccc7)n6)ccc45)OCCCO3)cc2)cc1 ; Fc1ccc(-c2ccc(C3(c4ccc(-c5nc(-c6ccccc6)nc(-c6ccccc6)n5)c5ccccc45)OCCCO3)c3ccccc23)cc1]

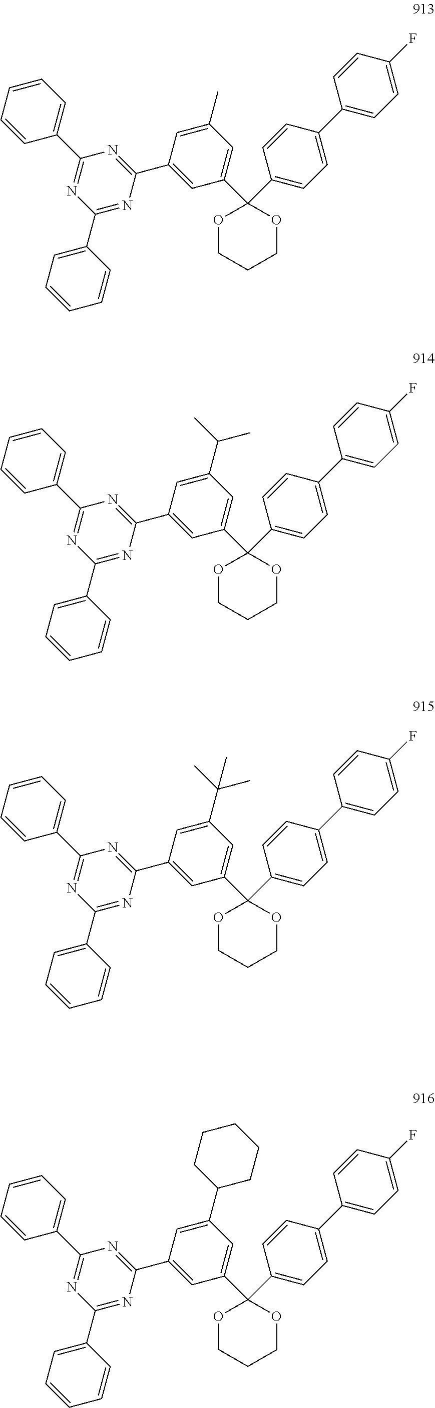 [SMILES: Cc1cc(-c2nc(-c3ccccc3)nc(-c3ccccc3)n2)cc(C2(c3ccc(-c4ccc(F)cc4)cc3)OCCCO2)c1 ; CC(C)c1cc(-c2nc(-c3ccccc3)nc(-c3ccccc3)n2)cc(C2(c3ccc(-c4ccc(F)cc4)cc3)OCCCO2)c1 ; CC(C)(C)c1cc(-c2nc(-c3ccccc3)nc(-c3ccccc3)n2)cc(C2(c3ccc(-c4ccc(F)cc4)cc3)OCCCO2)c1 ; Fc1ccc(-c2ccc(C3(c4cc(-c5nc(-c6ccccc6)nc(-c6ccccc6)n5)cc(C5CCCCC5)c4)OCCCO3)cc2)cc1]

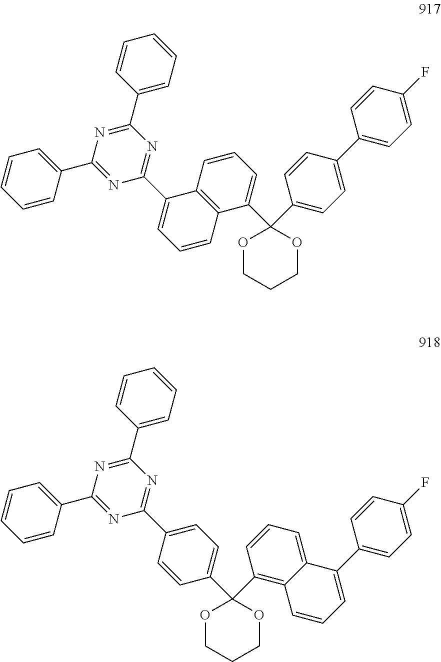 [SMILES: Fc1ccc(-c2ccc(C3(c4cccc5c(-c6nc(-c7ccccc7)nc(-c7ccccc7)n6)cccc45)OCCCO3)cc2)cc1 ; Fc1ccc(-c2cccc3c(C4(c5ccc(-c6nc(-c7ccccc7)nc(-c7ccccc7)n6)cc5)OCCCO4)cccc23)cc1]

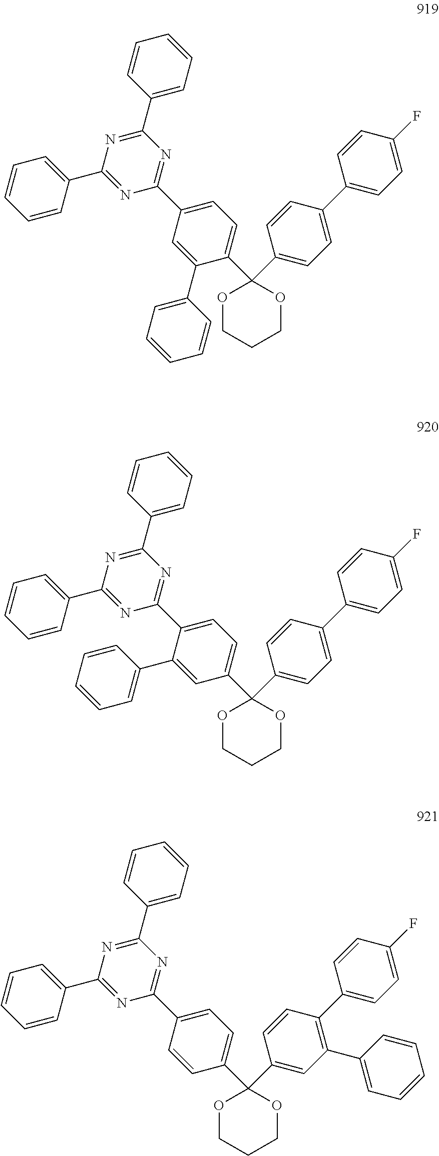 [SMILES: Fc1ccc(-c2ccc(C3(c4ccc(-c5nc(-c6ccccc6)nc(-c6ccccc6)n5)cc4-c4ccccc4)OCCCO3)cc2)cc1 ; Fc1ccc(-c2ccc(C3(c4ccc(-c5nc(-c6ccccc6)nc(-c6ccccc6)n5)c(-c5ccccc5)c4)OCCCO3)cc2)cc1 ; Fc1ccc(-c2ccc(C3(c4ccc(-c5nc(-c6ccccc6)nc(-c6ccccc6)n5)cc4)OCCCO3)cc2-c2ccccc2)cc1]

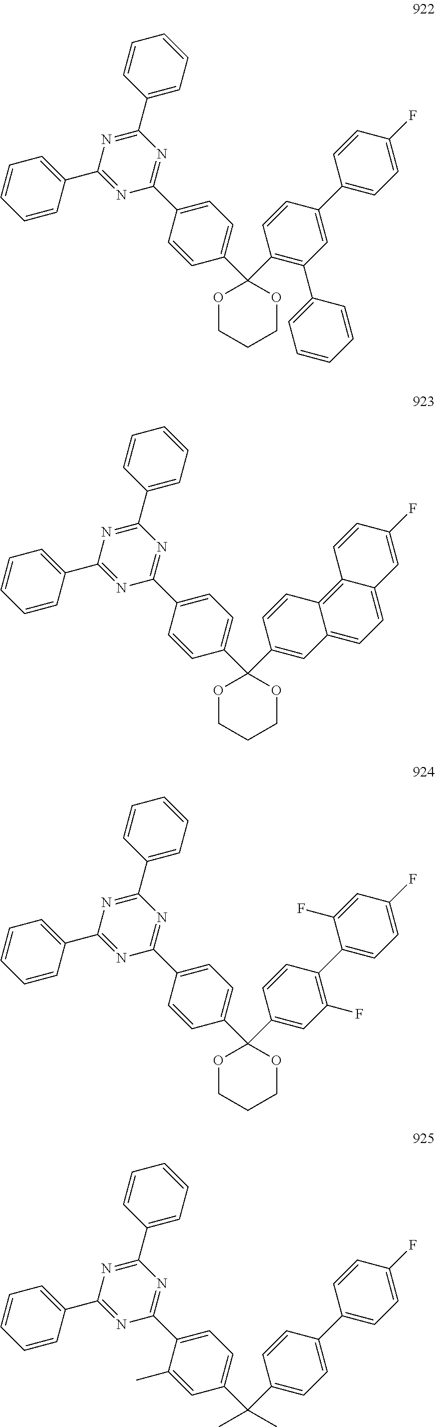 [SMILES: Fc1ccc(-c2ccc(C3(c4ccc(-c5nc(-c6ccccc6)nc(-c6ccccc6)n5)cc4)OCCCO3)c(-c3ccccc3)c2)cc1 ; Fc1ccc2c(ccc3cc(C4(c5ccc(-c6nc(-c7ccccc7)nc(-c7ccccc7)n6)cc5)OCCCO4)ccc32)c1 ; Fc1ccc(-c2ccc(C3(c4ccc(-c5nc(-c6ccccc6)nc(-c6ccccc6)n5)cc4)OCCCO3)cc2F)c(F)c1 ; Cc1cc(C(C)(C)c2ccc(-c3ccc(F)cc3)cc2)ccc1-c1nc(-c2ccccc2)nc(-c2ccccc2)n1]

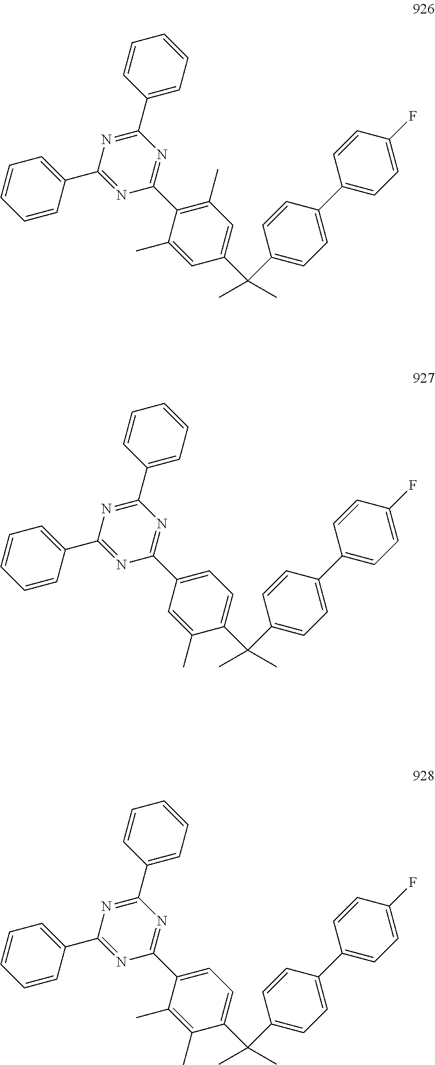 [SMILES: Cc1cc(C(C)(C)c2ccc(-c3ccc(F)cc3)cc2)cc(C)c1-c1nc(-c2ccccc2)nc(-c2ccccc2)n1 ; Cc1cc(-c2nc(-c3ccccc3)nc(-c3ccccc3)n2)ccc1C(C)(C)c1ccc(-c2ccc(F)cc2)cc1 ; Cc1c(-c2nc(-c3ccccc3)nc(-c3ccccc3)n2)ccc(C(C)(C)c2ccc(-c3ccc(F)cc3)cc2)c1C]

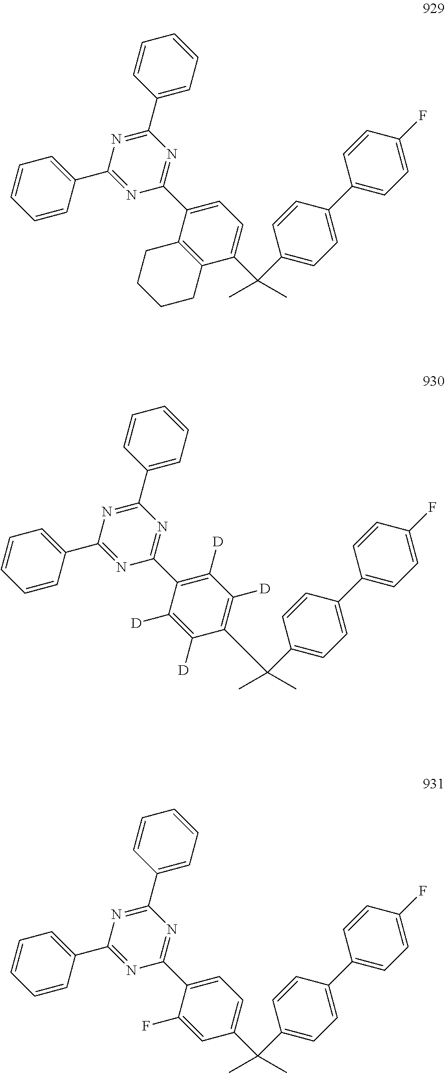 [SMILES: CC(C)(c1ccc(-c2ccc(F)cc2)cc1)c1ccc(-c2nc(-c3ccccc3)nc(-c3ccccc3)n2)c2c1CCCC2 ; [2H]c1c([2H])c(C(C)(C)c2ccc(-c3ccc(F)cc3)cc2)c([2H])c([2H])c1-c1nc(-c2ccccc2)nc(-c2ccccc2)n1 ; CC(C)(c1ccc(-c2ccc(F)cc2)cc1)c1ccc(-c2nc(-c3ccccc3)nc(-c3ccccc3)n2)c(F)c1]

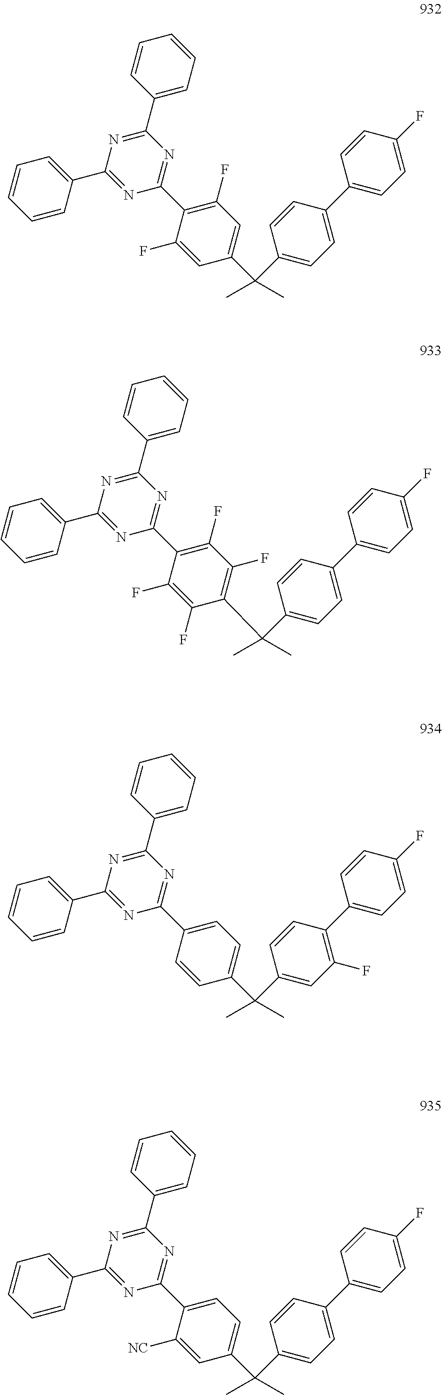 [SMILES: CC(C)(c1ccc(-c2ccc(F)cc2)cc1)c1cc(F)c(-c2nc(-c3ccccc3)nc(-c3ccccc3)n2)c(F)c1 ; CC(C)(c1ccc(-c2ccc(F)cc2)cc1)c1c(F)c(F)c(-c2nc(-c3ccccc3)nc(-c3ccccc3)n2)c(F)c1F ; CC(C)(c1ccc(-c2nc(-c3ccccc3)nc(-c3ccccc3)n2)cc1)c1ccc(-c2ccc(F)cc2)c(F)c1 ; CC(C)(c1ccc(-c2ccc(F)cc2)cc1)c1ccc(-c2nc(-c3ccccc3)nc(-c3ccccc3)n2)c(C#N)c1]

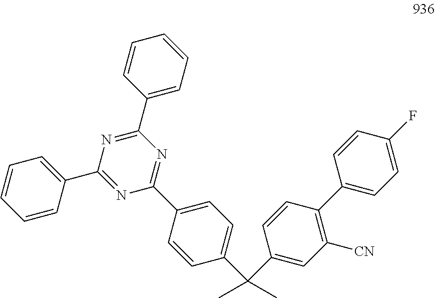 [SMILES: CC(C)(c1ccc(-c2nc(-c3ccccc3)nc(-c3ccccc3)n2)cc1)c1ccc(-c2ccc(F)cc2)c(C#N)c1]

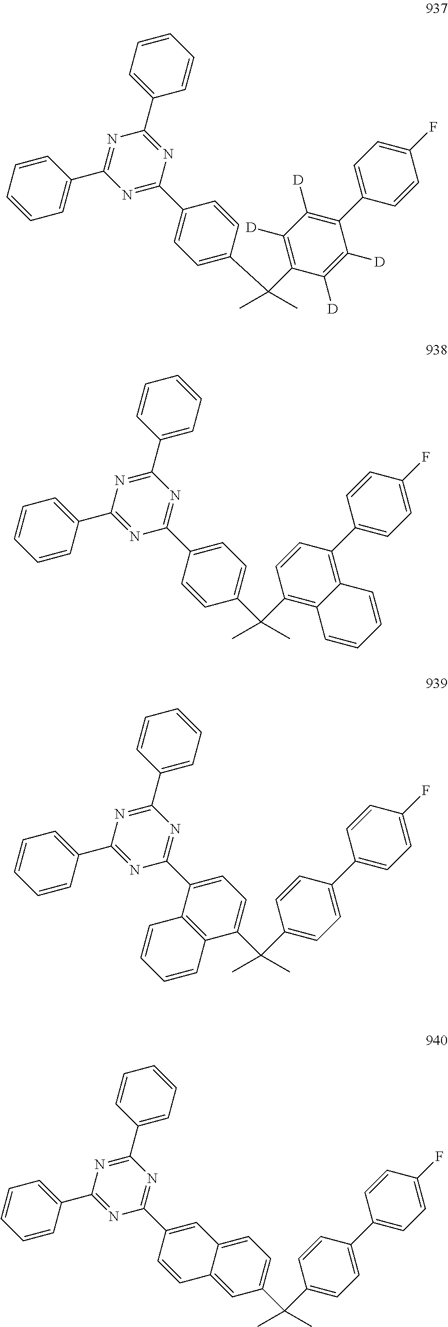

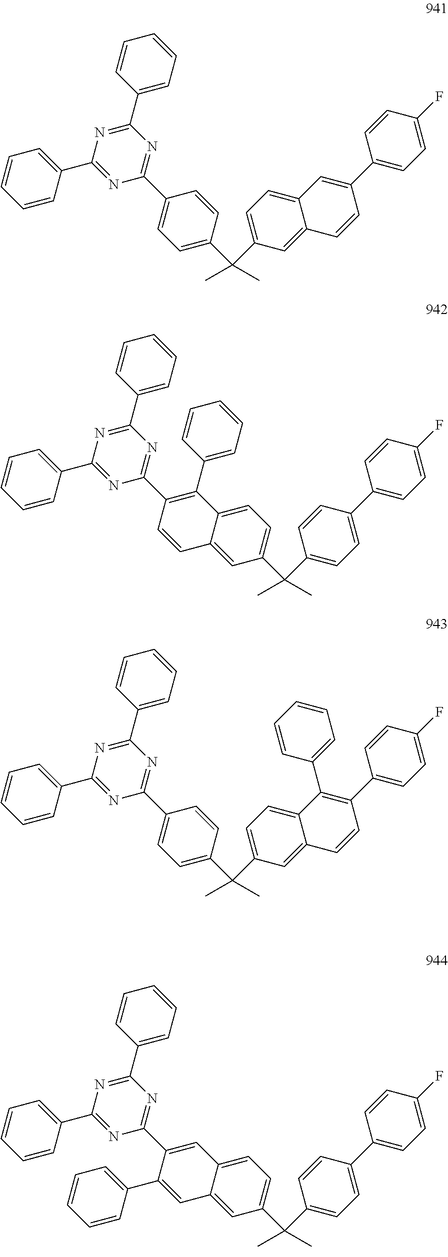

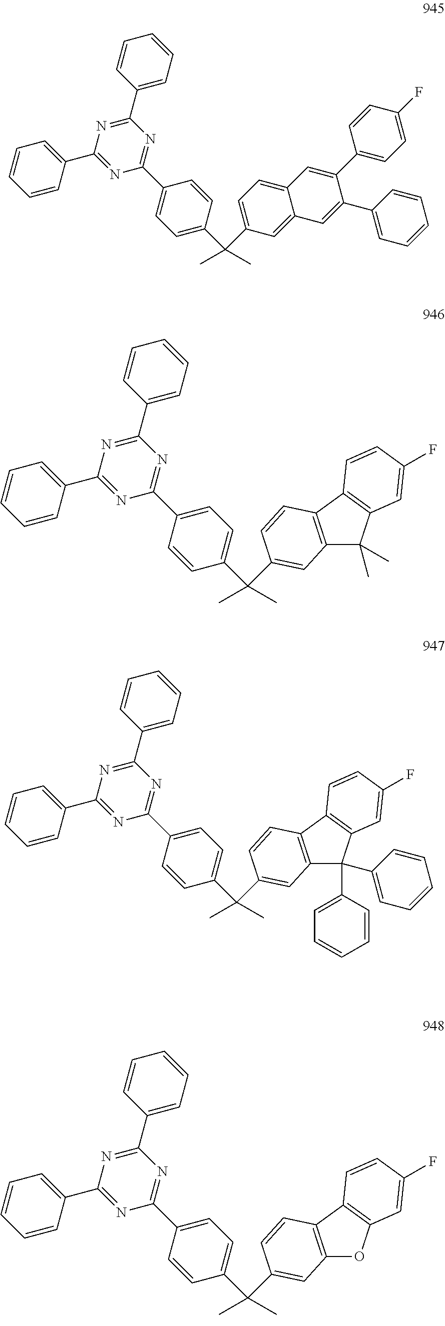

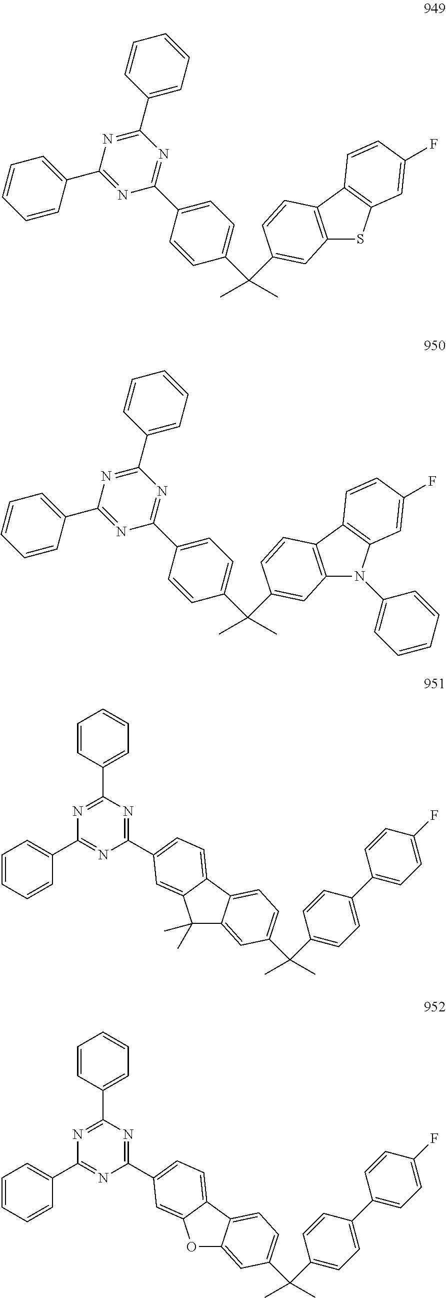

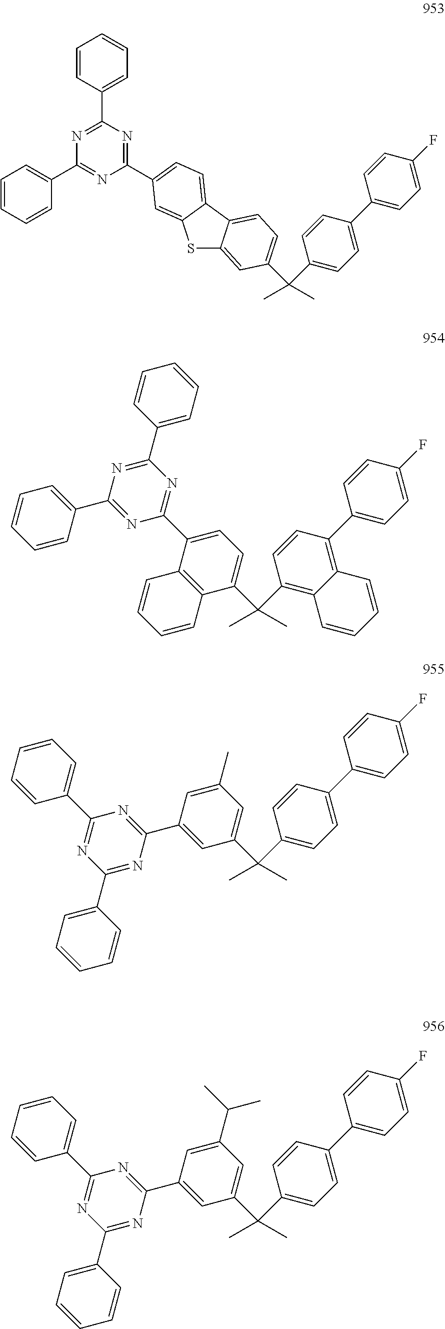 [SMILES: CC(C)(c1ccc(-c2ccc(F)cc2)cc1)c1ccc2c(c1)sc1cc(-c3nc(-c4ccccc4)nc(-c4ccccc4)n3)ccc12 ; CC(C)(c1ccc(-c2ccc(F)cc2)c2ccccc12)c1ccc(-c2nc(-c3ccccc3)nc(-c3ccccc3)n2)c2ccccc12 ; Cc1cc(-c2nc(-c3ccccc3)nc(-c3ccccc3)n2)cc(C(C)(C)c2ccc(-c3ccc(F)cc3)cc2)c1 ; CC(C)c1cc(-c2nc(-c3ccccc3)nc(-c3ccccc3)n2)cc(C(C)(C)c2ccc(-c3ccc(F)cc3)cc2)c1]

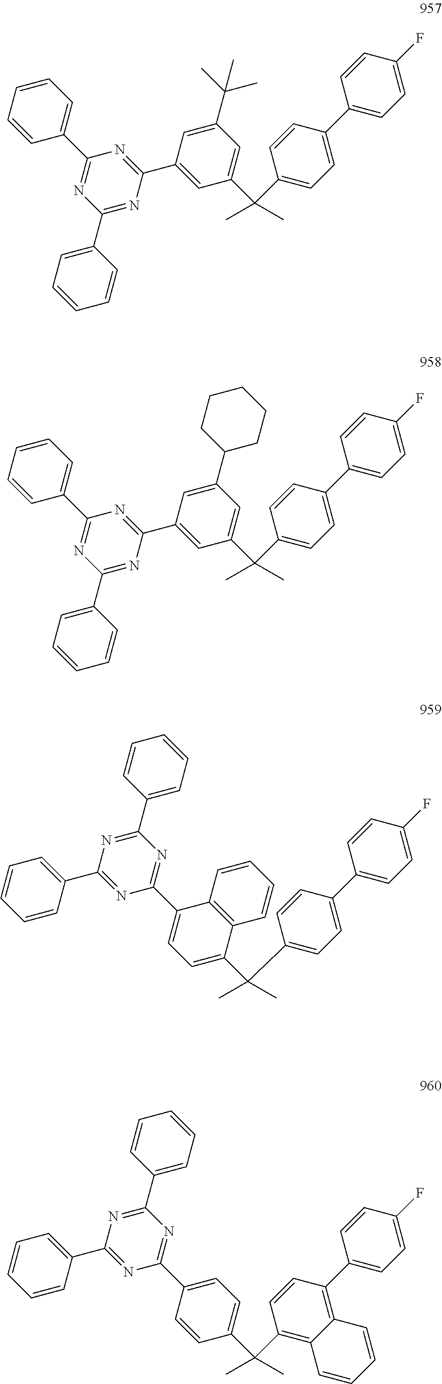 [SMILES: CC(C)(C)c1cc(-c2nc(-c3ccccc3)nc(-c3ccccc3)n2)cc(C(C)(C)c2ccc(-c3ccc(F)cc3)cc2)c1 ; CC(C)(c1ccc(-c2ccc(F)cc2)cc1)c1cc(-c2nc(-c3ccccc3)nc(-c3ccccc3)n2)cc(C2CCCCC2)c1 ; CC(C)(c1ccc(-c2ccc(F)cc2)cc1)c1ccc(-c2nc(-c3ccccc3)nc(-c3ccccc3)n2)c2ccccc12 ; CC(C)(c1ccc(-c2nc(-c3ccccc3)nc(-c3ccccc3)n2)cc1)c1ccc(-c2ccc(F)cc2)c2ccccc12]

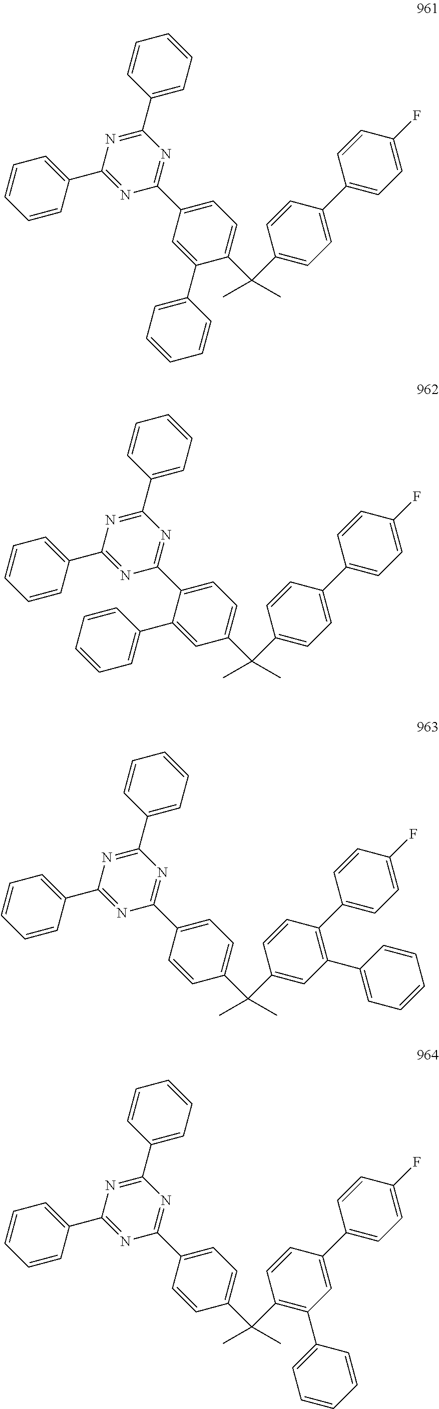 [SMILES: CC(C)(c1ccc(-c2ccc(F)cc2)cc1)c1ccc(-c2nc(-c3ccccc3)nc(-c3ccccc3)n2)cc1-c1ccccc1 ; CC(C)(c1ccc(-c2ccc(F)cc2)cc1)c1ccc(-c2nc(-c3ccccc3)nc(-c3ccccc3)n2)c(-c2ccccc2)c1 ; CC(C)(c1ccc(-c2nc(-c3ccccc3)nc(-c3ccccc3)n2)cc1)c1ccc(-c2ccc(F)cc2)c(-c2ccccc2)c1 ; CC(C)(c1ccc(-c2nc(-c3ccccc3)nc(-c3ccccc3)n2)cc1)c1ccc(-c2ccc(F)cc2)cc1-c1ccccc1]

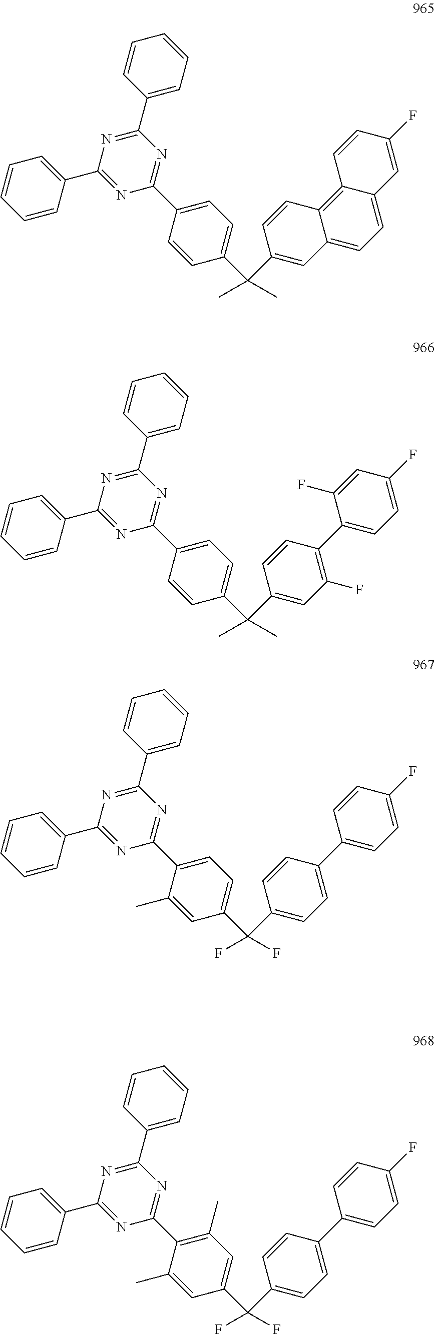 [SMILES: CC(C)(c1ccc(-c2nc(-c3ccccc3)nc(-c3ccccc3)n2)cc1)c1ccc2c(ccc3cc(F)ccc32)c1 ; CC(C)(c1ccc(-c2nc(-c3ccccc3)nc(-c3ccccc3)n2)cc1)c1ccc(-c2ccc(F)cc2F)c(F)c1 ; Cc1cc(C(F)(F)c2ccc(-c3ccc(F)cc3)cc2)ccc1-c1nc(-c2ccccc2)nc(-c2ccccc2)n1 ; Cc1cc(C(F)(F)c2ccc(-c3ccc(F)cc3)cc2)cc(C)c1-c1nc(-c2ccccc2)nc(-c2ccccc2)n1]

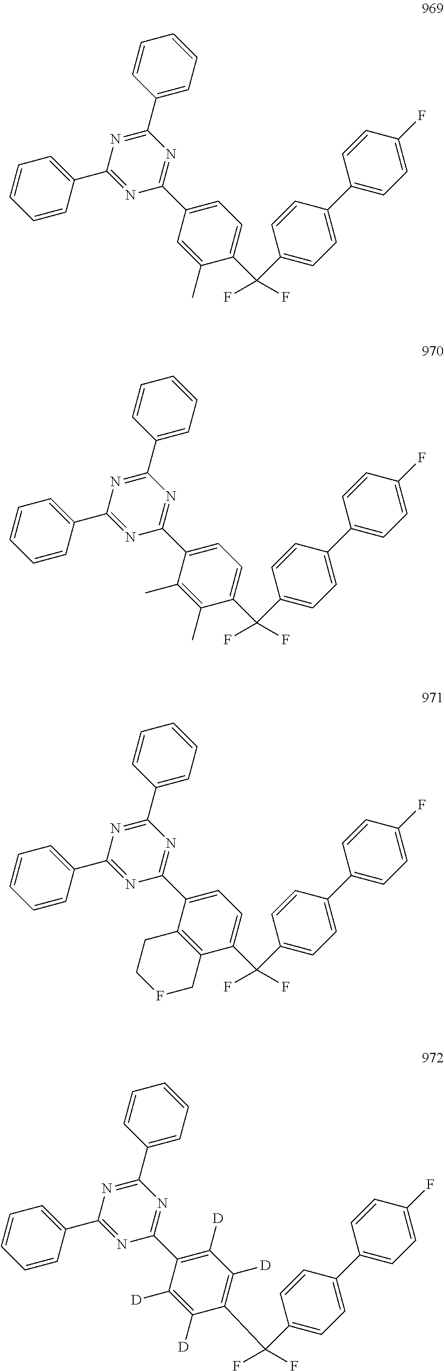

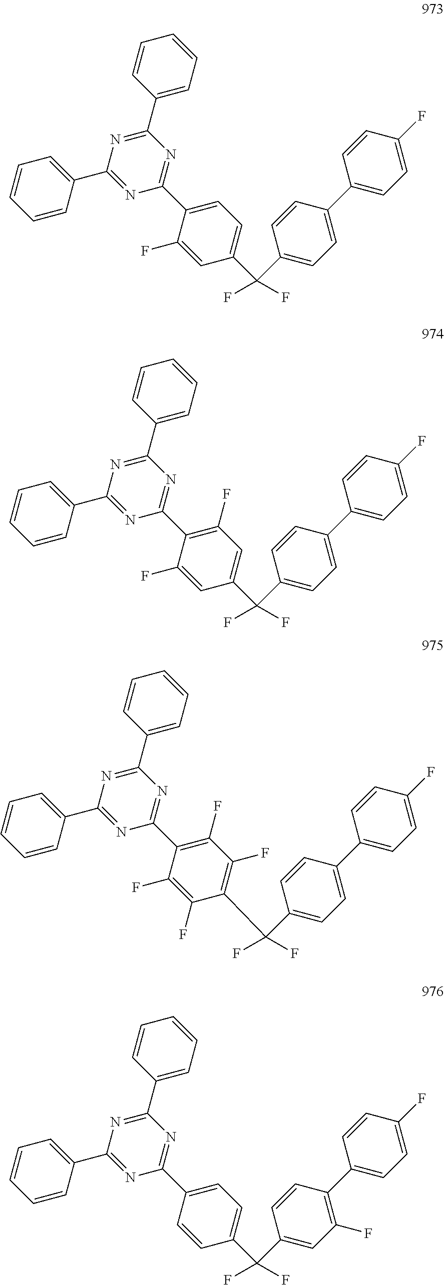 [SMILES: Fc1ccc(-c2ccc(C(F)(F)c3ccc(-c4nc(-c5ccccc5)nc(-c5ccccc5)n4)c(F)c3)cc2)cc1 ; Fc1ccc(-c2ccc(C(F)(F)c3cc(F)c(-c4nc(-c5ccccc5)nc(-c5ccccc5)n4)c(F)c3)cc2)cc1 ; Fc1ccc(-c2ccc(C(F)(F)c3c(F)c(F)c(-c4nc(-c5ccccc5)nc(-c5ccccc5)n4)c(F)c3F)cc2)cc1 ; Fc1ccc(-c2ccc(C(F)(F)c3ccc(-c4nc(-c5ccccc5)nc(-c5ccccc5)n4)cc3)cc2F)cc1]

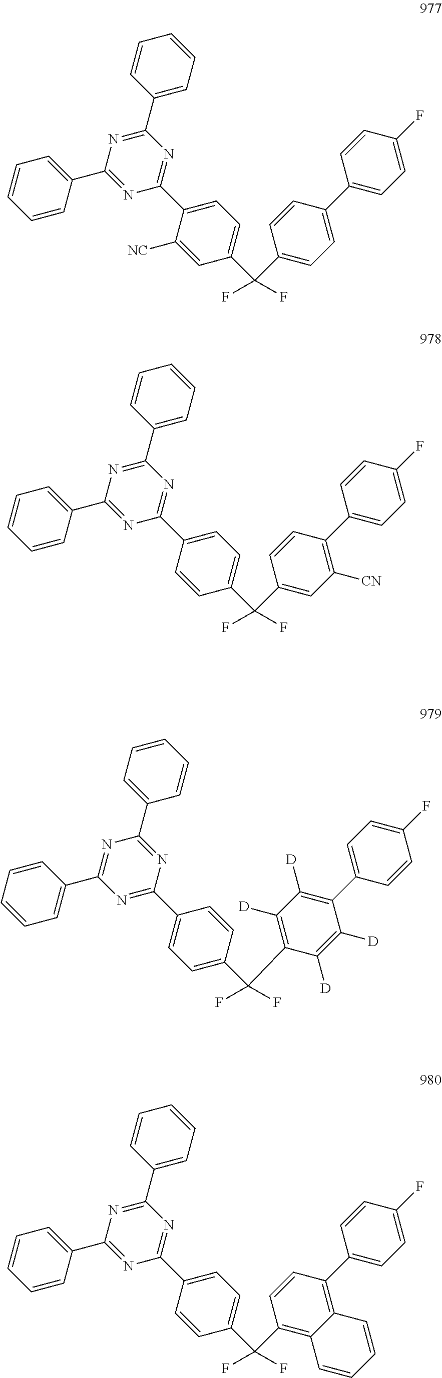 [SMILES: N#Cc1cc(C(F)(F)c2ccc(-c3ccc(F)cc3)cc2)ccc1-c1nc(-c2ccccc2)nc(-c2ccccc2)n1 ; N#Cc1cc(C(F)(F)c2ccc(-c3nc(-c4ccccc4)nc(-c4ccccc4)n3)cc2)ccc1-c1ccc(F)cc1 ; [2H]c1c([2H])c(C(F)(F)c2ccc(-c3nc(-c4ccccc4)nc(-c4ccccc4)n3)cc2)c([2H])c([2H])c1-c1ccc(F)cc1 ; Fc1ccc(-c2ccc(C(F)(F)c3ccc(-c4nc(-c5ccccc5)nc(-c5ccccc5)n4)cc3)c3ccccc23)cc1]

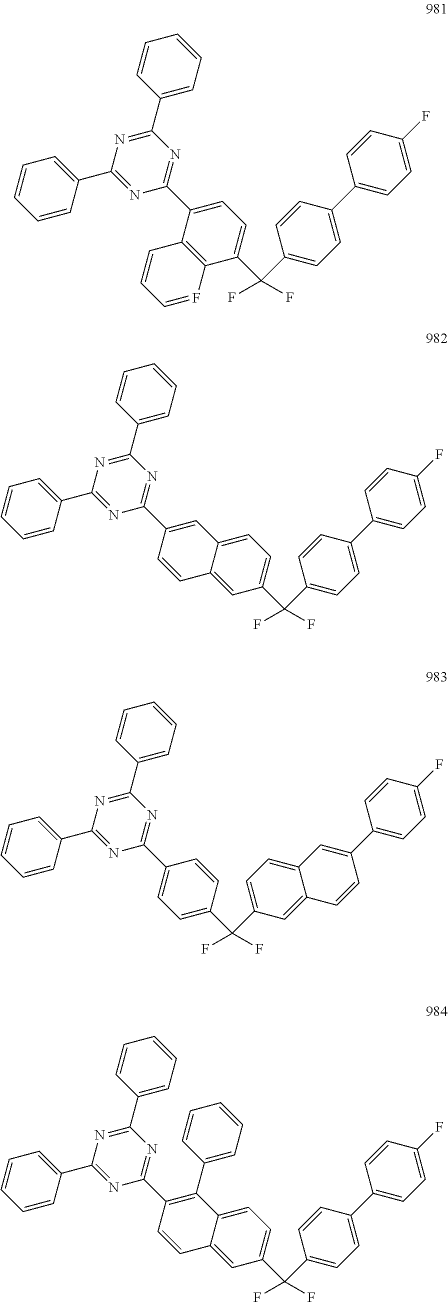

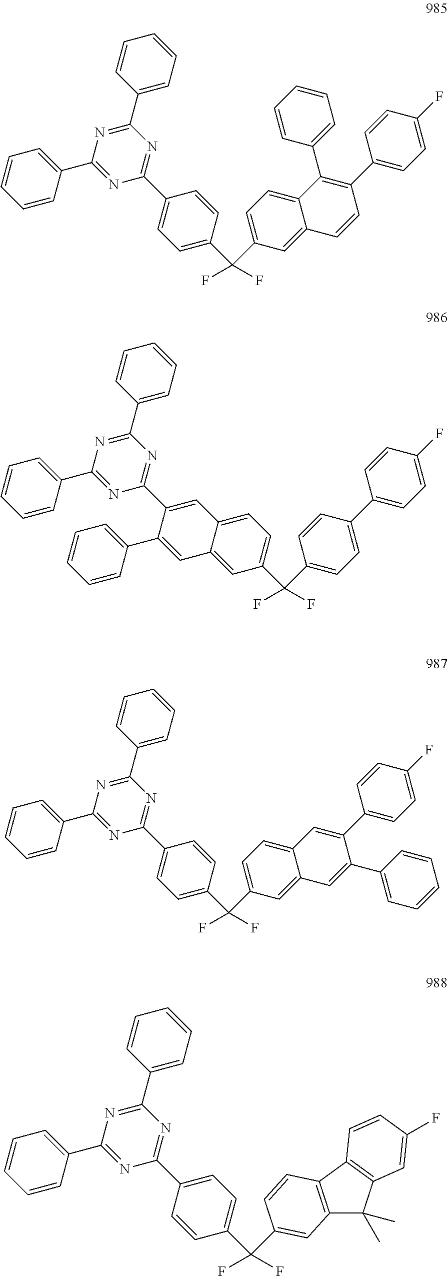 [SMILES: Fc1ccc(-c2ccc3cc(C(F)(F)c4ccc(-c5nc(-c6ccccc6)nc(-c6ccccc6)n5)cc4)ccc3c2-c2ccccc2)cc1 ; Fc1ccc(-c2ccc(C(F)(F)c3ccc4cc(-c5nc(-c6ccccc6)nc(-c6ccccc6)n5)c(-c5ccccc5)cc4c3)cc2)cc1 ; Fc1ccc(-c2cc3ccc(C(F)(F)c4ccc(-c5nc(-c6ccccc6)nc(-c6ccccc6)n5)cc4)cc3cc2-c2ccccc2)cc1 ; CC1(C)c2cc(F)ccc2-c2ccc(C(F)(F)c3ccc(-c4nc(-c5ccccc5)nc(-c5ccccc5)n4)cc3)cc21]

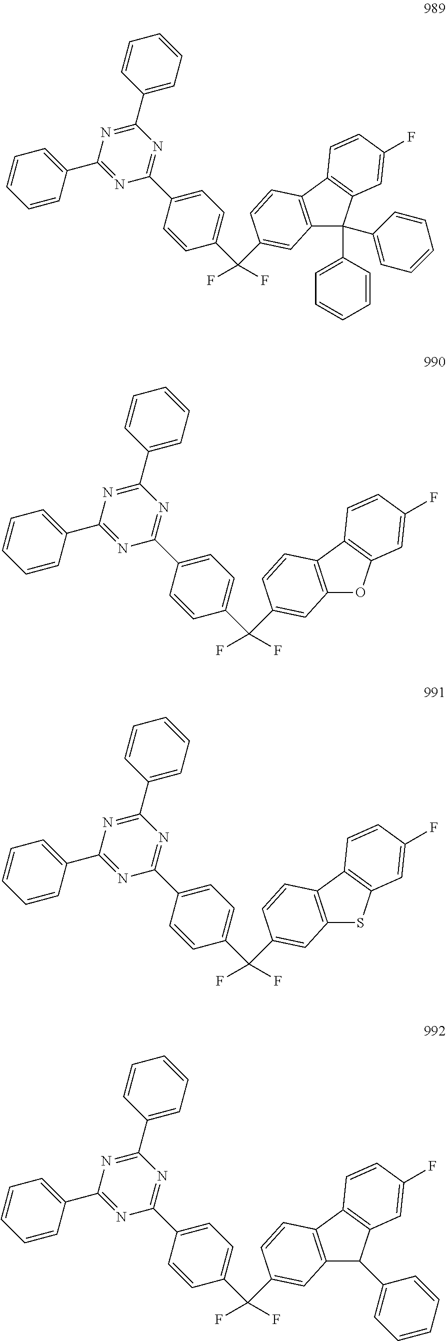 [SMILES: Fc1ccc2c(c1)C(c1ccccc1)(c1ccccc1)c1cc(C(F)(F)c3ccc(-c4nc(-c5ccccc5)nc(-c5ccccc5)n4)cc3)ccc1-2 ; Fc1ccc2c(c1)oc1cc(C(F)(F)c3ccc(-c4nc(-c5ccccc5)nc(-c5ccccc5)n4)cc3)ccc12 ; Fc1ccc2c(c1)sc1cc(C(F)(F)c3ccc(-c4nc(-c5ccccc5)nc(-c5ccccc5)n4)cc3)ccc12 ; Fc1ccc2c(c1)C(c1ccccc1)c1cc(C(F)(F)c3ccc(-c4nc(-c5ccccc5)nc(-c5ccccc5)n4)cc3)ccc1-2]

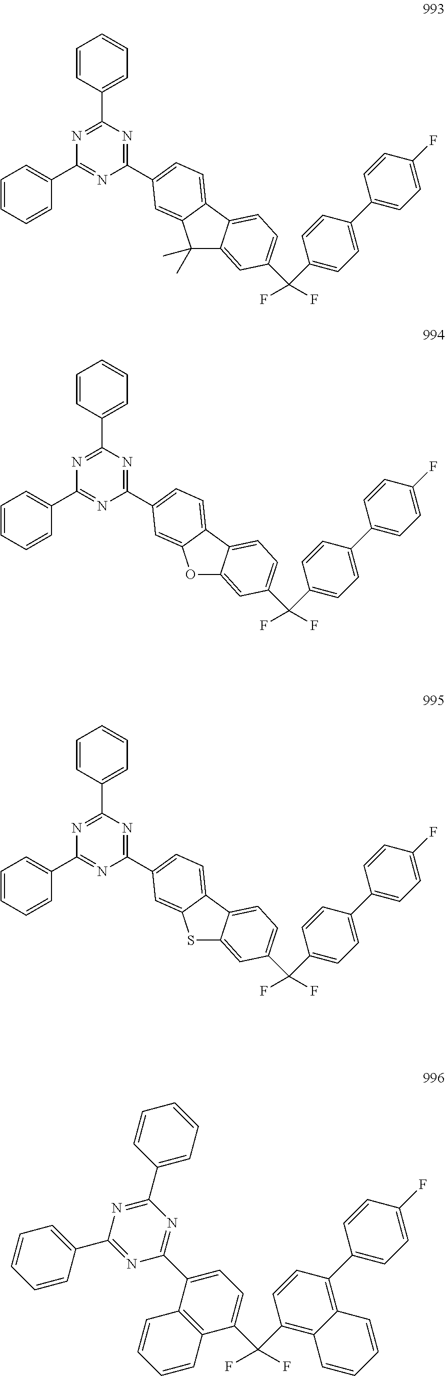 [SMILES: CC1(C)c2cc(-c3nc(-c4ccccc4)nc(-c4ccccc4)n3)ccc2-c2ccc(C(F)(F)c3ccc(-c4ccc(F)cc4)cc3)cc21 ; Fc1ccc(-c2ccc(C(F)(F)c3ccc4c(c3)oc3cc(-c5nc(-c6ccccc6)nc(-c6ccccc6)n5)ccc34)cc2)cc1 ; Fc1ccc(-c2ccc(C(F)(F)c3ccc4c(c3)sc3cc(-c5nc(-c6ccccc6)nc(-c6ccccc6)n5)ccc34)cc2)cc1 ; Fc1ccc(-c2ccc(C(F)(F)c3ccc(-c4nc(-c5ccccc5)nc(-c5ccccc5)n4)c4ccccc34)c3ccccc23)cc1]

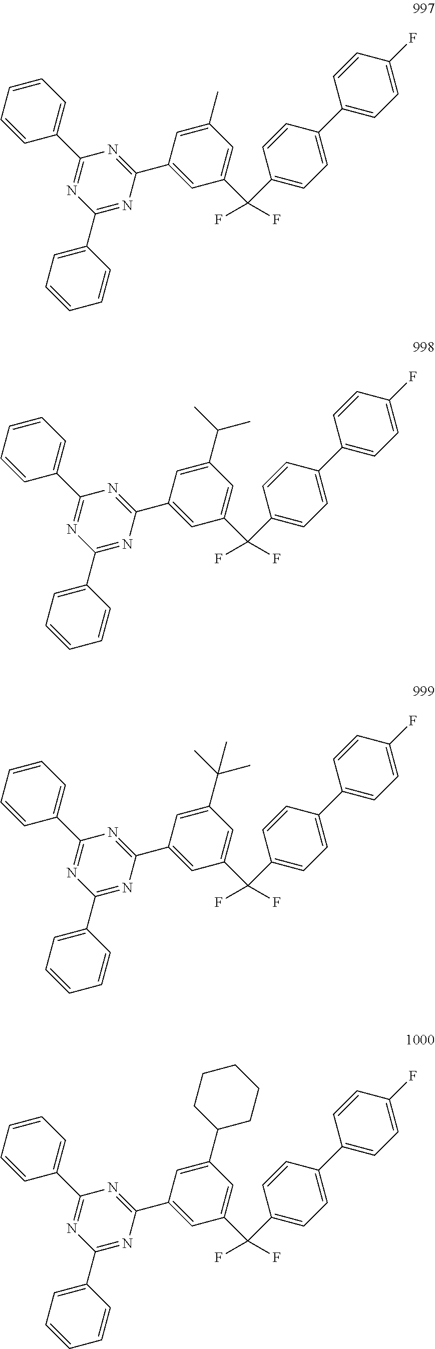 [SMILES: Cc1cc(-c2nc(-c3ccccc3)nc(-c3ccccc3)n2)cc(C(F)(F)c2ccc(-c3ccc(F)cc3)cc2)c1 ; CC(C)c1cc(-c2nc(-c3ccccc3)nc(-c3ccccc3)n2)cc(C(F)(F)c2ccc(-c3ccc(F)cc3)cc2)c1 ; CC(C)(C)c1cc(-c2nc(-c3ccccc3)nc(-c3ccccc3)n2)cc(C(F)(F)c2ccc(-c3ccc(F)cc3)cc2)c1 ; Fc1ccc(-c2ccc(C(F)(F)c3cc(-c4nc(-c5ccccc5)nc(-c5ccccc5)n4)cc(C4CCCCC4)c3)cc2)cc1]

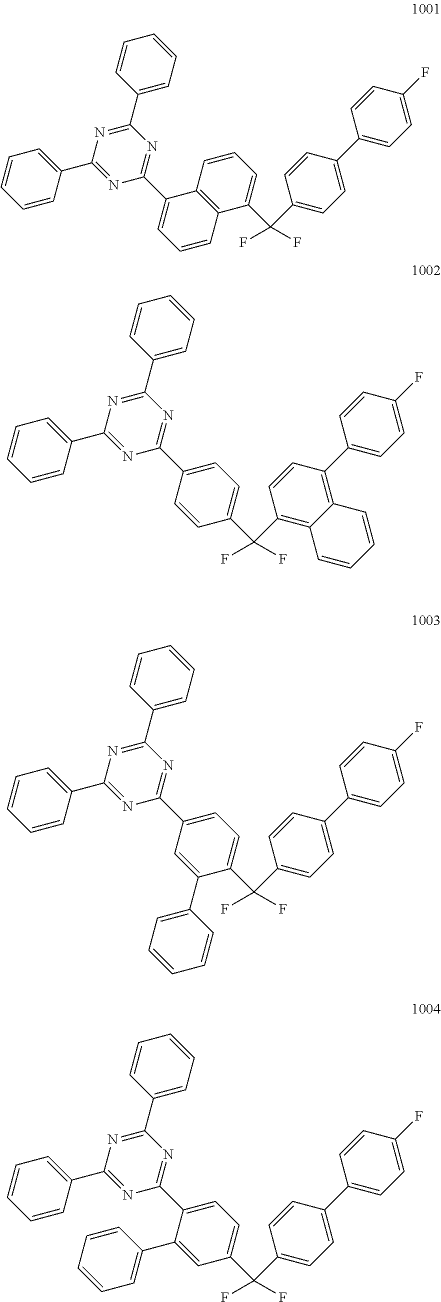

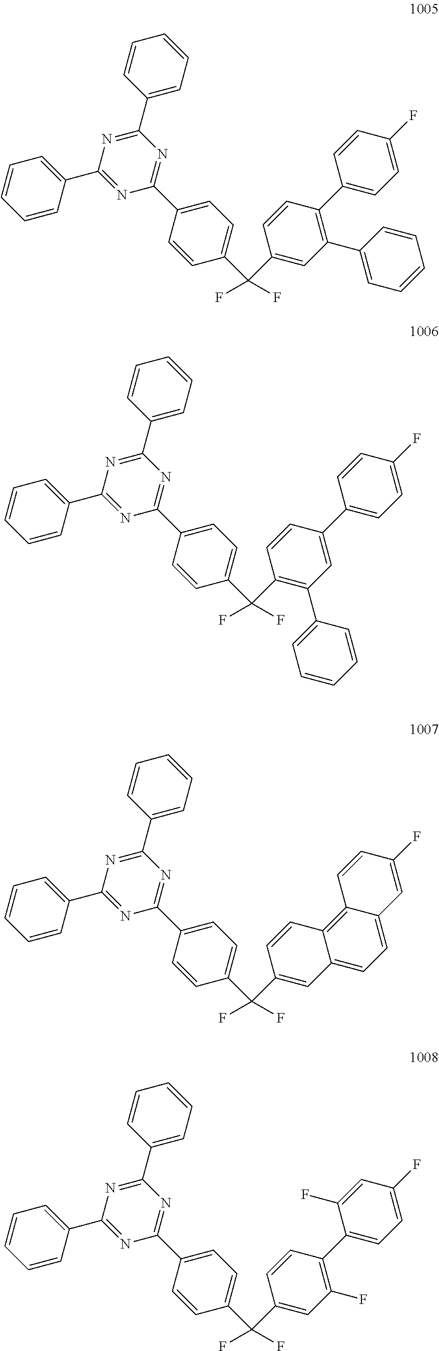 [SMILES: Fc1ccc(-c2ccc(C(F)(F)c3ccc(-c4nc(-c5ccccc5)nc(-c5ccccc5)n4)cc3)cc2-c2ccccc2)cc1 ; Fc1ccc(-c2ccc(C(F)(F)c3ccc(-c4nc(-c5ccccc5)nc(-c5ccccc5)n4)cc3)c(-c3ccccc3)c2)cc1 ; Fc1ccc2c(ccc3cc(C(F)(F)c4ccc(-c5nc(-c6ccccc6)nc(-c6ccccc6)n5)cc4)ccc32)c1 ; Fc1ccc(-c2ccc(C(F)(F)c3ccc(-c4nc(-c5ccccc5)nc(-c5ccccc5)n4)cc3)cc2F)c(F)c1]

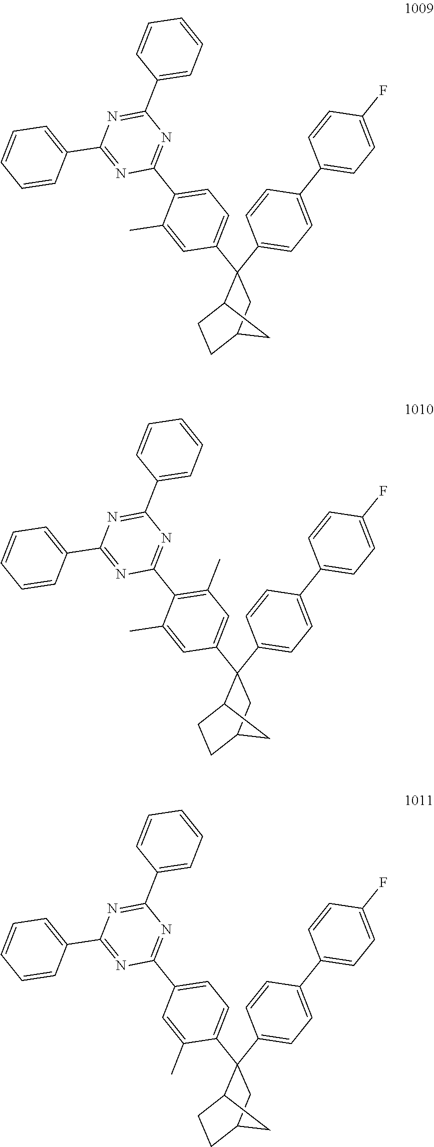 [SMILES: Cc1cc(C2(c3ccc(-c4ccc(F)cc4)cc3)CC3CCC2C3)ccc1-c1nc(-c2ccccc2)nc(-c2ccccc2)n1 ; Cc1cc(C2(c3ccc(-c4ccc(F)cc4)cc3)CC3CCC2C3)cc(C)c1-c1nc(-c2ccccc2)nc(-c2ccccc2)n1 ; Cc1cc(-c2nc(-c3ccccc3)nc(-c3ccccc3)n2)ccc1C1(c2ccc(-c3ccc(F)cc3)cc2)CC2CCC1C2]

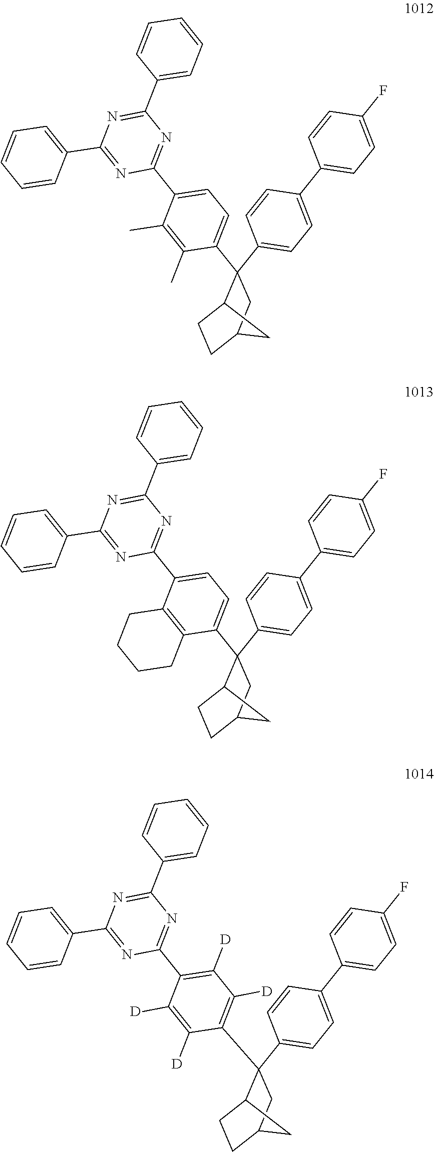 [SMILES: Cc1c(-c2nc(-c3ccccc3)nc(-c3ccccc3)n2)ccc(C2(c3ccc(-c4ccc(F)cc4)cc3)CC3CCC2C3)c1C ; Fc1ccc(-c2ccc(C3(c4ccc(-c5nc(-c6ccccc6)nc(-c6ccccc6)n5)c5c4CCCC5)CC4CCC3C4)cc2)cc1 ; [2H]c1c([2H])c(C2(c3ccc(-c4ccc(F)cc4)cc3)CC3CCC2C3)c([2H])c([2H])c1-c1nc(-c2ccccc2)nc(-c2ccccc2)n1]

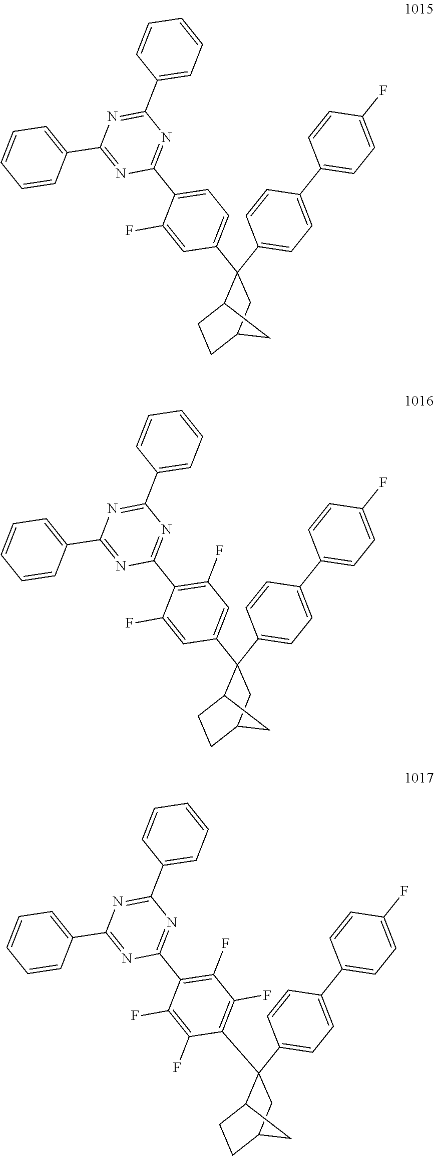 [SMILES: Fc1ccc(-c2ccc(C3(c4ccc(-c5nc(-c6ccccc6)nc(-c6ccccc6)n5)c(F)c4)CC4CCC3C4)cc2)cc1 ; Fc1ccc(-c2ccc(C3(c4cc(F)c(-c5nc(-c6ccccc6)nc(-c6ccccc6)n5)c(F)c4)CC4CCC3C4)cc2)cc1 ; Fc1ccc(-c2ccc(C3(c4c(F)c(F)c(-c5nc(-c6ccccc6)nc(-c6ccccc6)n5)c(F)c4F)CC4CCC3C4)cc2)cc1]

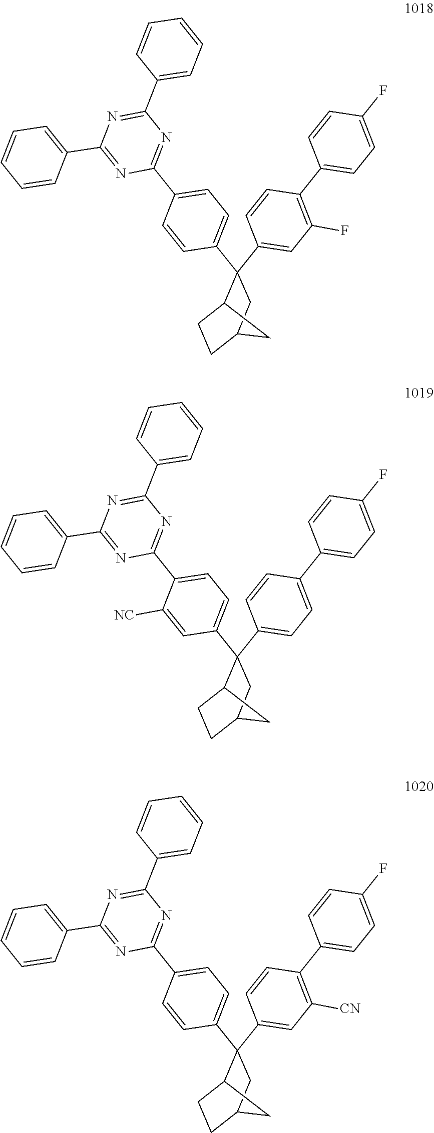 [SMILES: Fc1ccc(-c2ccc(C3(c4ccc(-c5nc(-c6ccccc6)nc(-c6ccccc6)n5)cc4)CC4CCC3C4)cc2F)cc1 ; N#Cc1cc(C2(c3ccc(-c4ccc(F)cc4)cc3)CC3CCC2C3)ccc1-c1nc(-c2ccccc2)nc(-c2ccccc2)n1 ; N#Cc1cc(C2(c3ccc(-c4nc(-c5ccccc5)nc(-c5ccccc5)n4)cc3)CC3CCC2C3)ccc1-c1ccc(F)cc1]

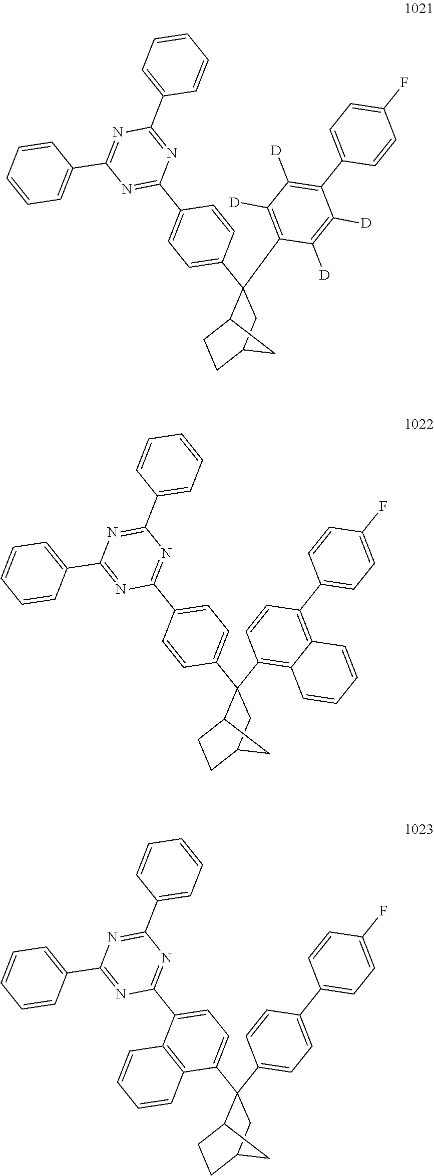 [SMILES: [2H]c1c([2H])c(C2(c3ccc(-c4nc(-c5ccccc5)nc(-c5ccccc5)n4)cc3)CC3CCC2C3)c([2H])c([2H])c1-c1ccc(F)cc1 ; Fc1ccc(-c2ccc(C3(c4ccc(-c5nc(-c6ccccc6)nc(-c6ccccc6)n5)cc4)CC4CCC3C4)c3ccccc23)cc1 ; Fc1ccc(-c2ccc(C3(c4ccc(-c5nc(-c6ccccc6)nc(-c6ccccc6)n5)c5ccccc45)CC4CCC3C4)cc2)cc1]

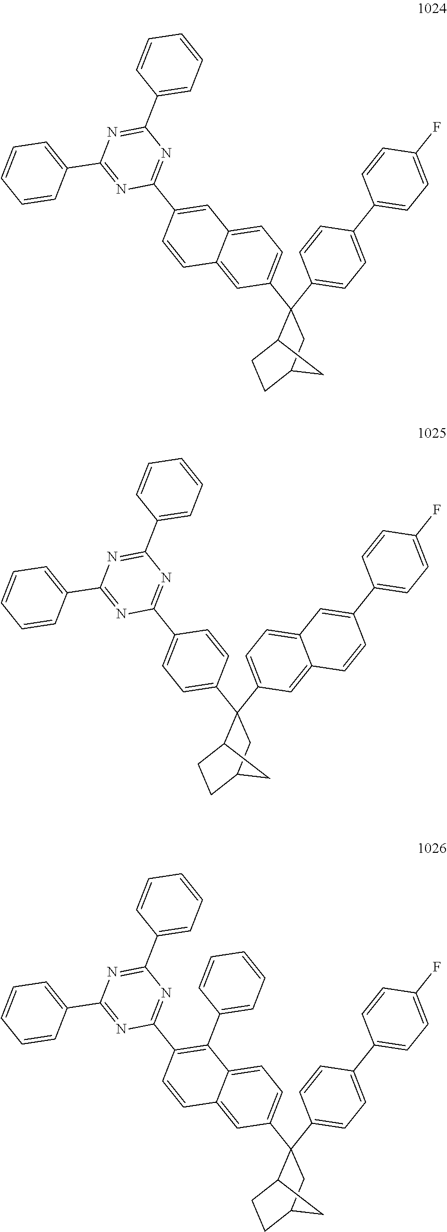 [SMILES: Fc1ccc(-c2ccc(C3(c4ccc5cc(-c6nc(-c7ccccc7)nc(-c7ccccc7)n6)ccc5c4)CC4CCC3C4)cc2)cc1 ; Fc1ccc(-c2ccc3cc(C4(c5ccc(-c6nc(-c7ccccc7)nc(-c7ccccc7)n6)cc5)CC5CCC4C5)ccc3c2)cc1 ; Fc1ccc(-c2ccc(C3(c4ccc5c(-c6ccccc6)c(-c6nc(-c7ccccc7)nc(-c7ccccc7)n6)ccc5c4)CC4CCC3C4)cc2)cc1]

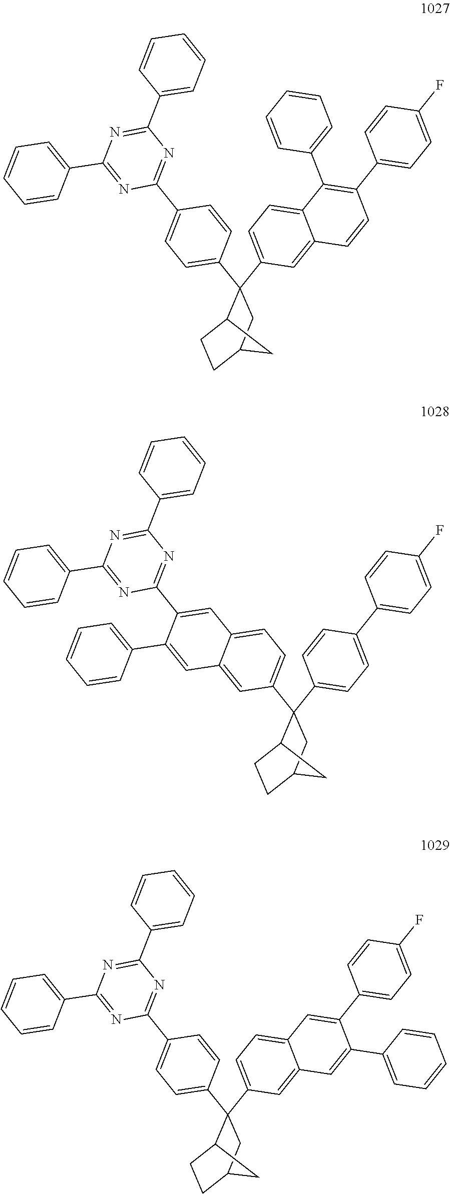 [SMILES: Fc1ccc(-c2ccc3cc(C4(c5ccc(-c6nc(-c7ccccc7)nc(-c7ccccc7)n6)cc5)CC5CCC4C5)ccc3c2-c2ccccc2)cc1 ; Fc1ccc(-c2ccc(C3(c4ccc5cc(-c6nc(-c7ccccc7)nc(-c7ccccc7)n6)c(-c6ccccc6)cc5c4)CC4CCC3C4)cc2)cc1 ; Fc1ccc(-c2cc3ccc(C4(c5ccc(-c6nc(-c7ccccc7)nc(-c7ccccc7)n6)cc5)CC5CCC4C5)cc3cc2-c2ccccc2)cc1]

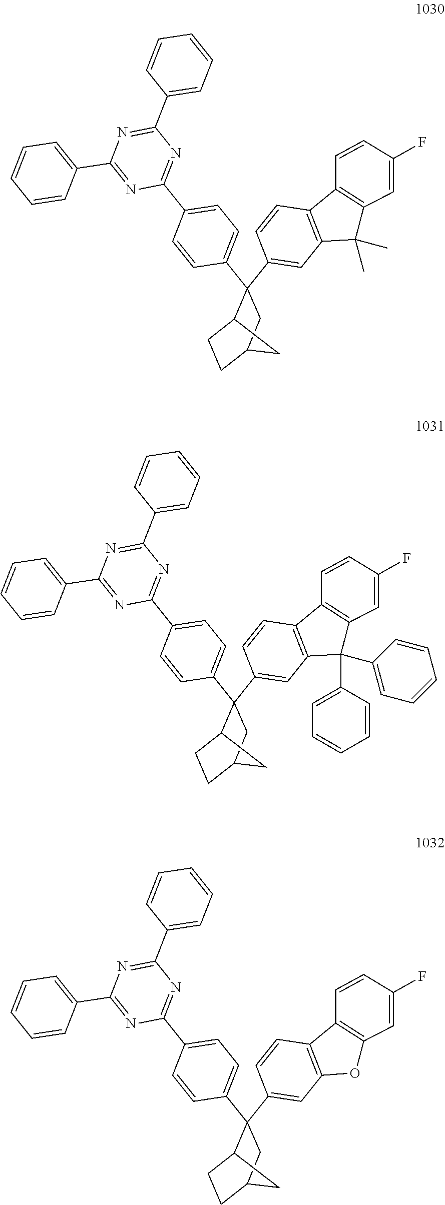 [SMILES: CC1(C)c2cc(F)ccc2-c2ccc(C3(c4ccc(-c5nc(-c6ccccc6)nc(-c6ccccc6)n5)cc4)CC4CCC3C4)cc21 ; Fc1ccc2c(c1)C(c1ccccc1)(c1ccccc1)c1cc(C3(c4ccc(-c5nc(-c6ccccc6)nc(-c6ccccc6)n5)cc4)CC4CCC3C4)ccc1-2 ; Fc1ccc2c(c1)oc1cc(C3(c4ccc(-c5nc(-c6ccccc6)nc(-c6ccccc6)n5)cc4)CC4CCC3C4)ccc12]

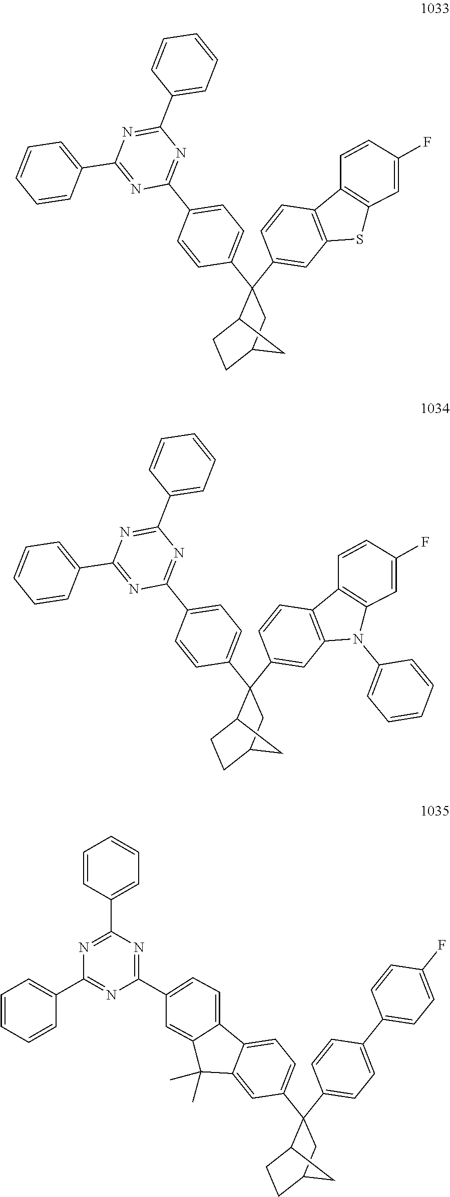 [SMILES: Fc1ccc2c(c1)sc1cc(C3(c4ccc(-c5nc(-c6ccccc6)nc(-c6ccccc6)n5)cc4)CC4CCC3C4)ccc12 ; Fc1ccc2c3ccc(C4(c5ccc(-c6nc(-c7ccccc7)nc(-c7ccccc7)n6)cc5)CC5CCC4C5)cc3n(-c3ccccc3)c2c1 ; CC1(C)c2cc(-c3nc(-c4ccccc4)nc(-c4ccccc4)n3)ccc2-c2ccc(C3(c4ccc(-c5ccc(F)cc5)cc4)CC4CCC3C4)cc21]

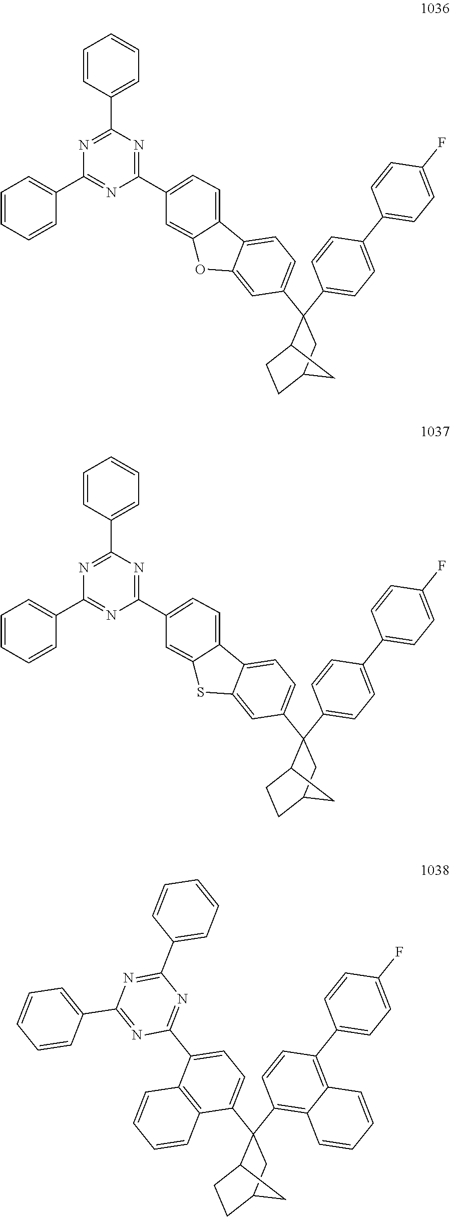 [SMILES: Fc1ccc(-c2ccc(C3(c4ccc5c(c4)oc4cc(-c6nc(-c7ccccc7)nc(-c7ccccc7)n6)ccc45)CC4CCC3C4)cc2)cc1 ; Fc1ccc(-c2ccc(C3(c4ccc5c(c4)sc4cc(-c6nc(-c7ccccc7)nc(-c7ccccc7)n6)ccc45)CC4CCC3C4)cc2)cc1 ; Fc1ccc(-c2ccc(C3(c4ccc(-c5nc(-c6ccccc6)nc(-c6ccccc6)n5)c5ccccc45)CC4CCC3C4)c3ccccc23)cc1]

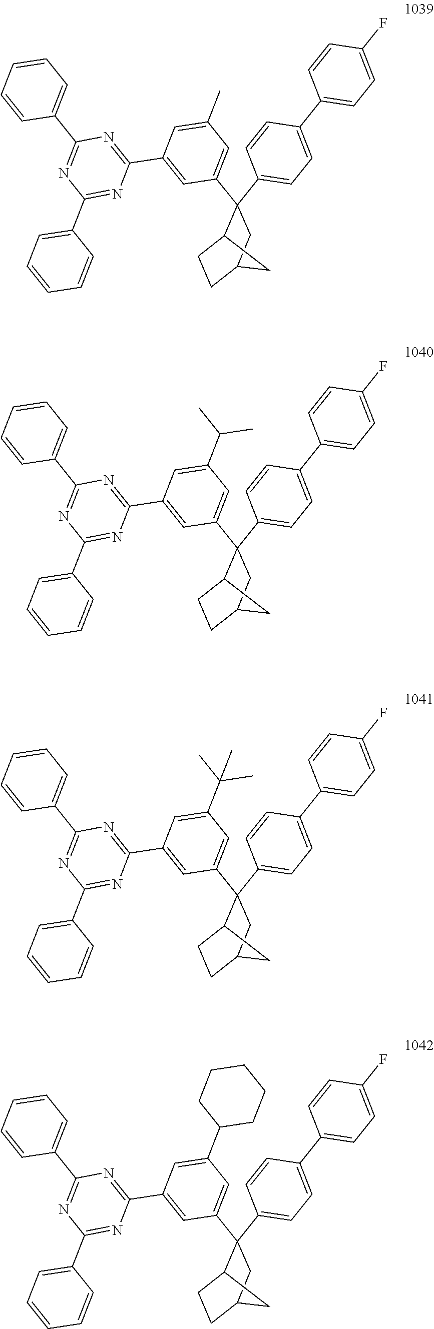 [SMILES: Cc1cc(-c2nc(-c3ccccc3)nc(-c3ccccc3)n2)cc(C2(c3ccc(-c4ccc(F)cc4)cc3)CC3CCC2C3)c1 ; CC(C)c1cc(-c2nc(-c3ccccc3)nc(-c3ccccc3)n2)cc(C2(c3ccc(-c4ccc(F)cc4)cc3)CC3CCC2C3)c1 ; CC(C)(C)c1cc(-c2nc(-c3ccccc3)nc(-c3ccccc3)n2)cc(C2(c3ccc(-c4ccc(F)cc4)cc3)CC3CCC2C3)c1 ; Fc1ccc(-c2ccc(C3(c4cc(-c5nc(-c6ccccc6)nc(-c6ccccc6)n5)cc(C5CCCCC5)c4)CC4CCC3C4)cc2)cc1]

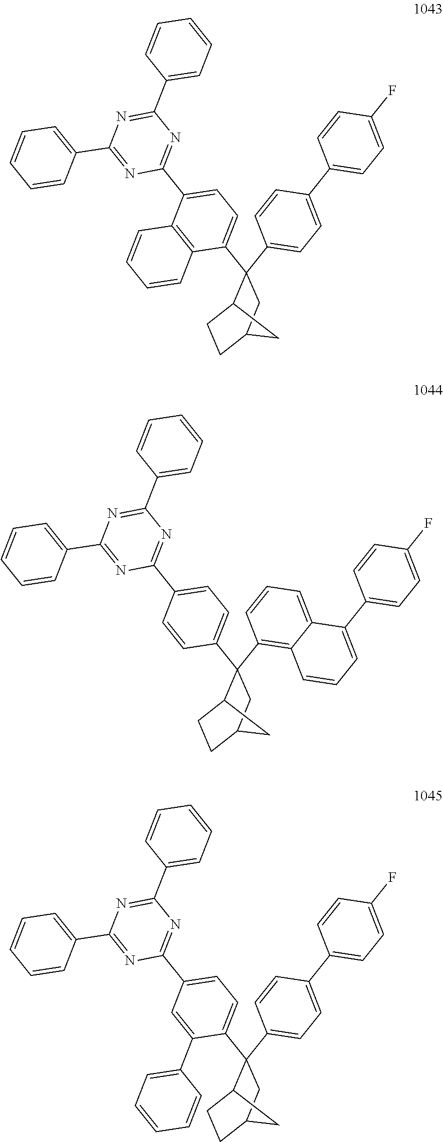 [SMILES: Fc1ccc(-c2ccc(C3(c4ccc(-c5nc(-c6ccccc6)nc(-c6ccccc6)n5)c5ccccc45)CC4CCC3C4)cc2)cc1 ; Fc1ccc(-c2cccc3c(C4(c5ccc(-c6nc(-c7ccccc7)nc(-c7ccccc7)n6)cc5)CC5CCC4C5)cccc23)cc1 ; Fc1ccc(-c2ccc(C3(c4ccc(-c5nc(-c6ccccc6)nc(-c6ccccc6)n5)cc4-c4ccccc4)CC4CCC3C4)cc2)cc1]

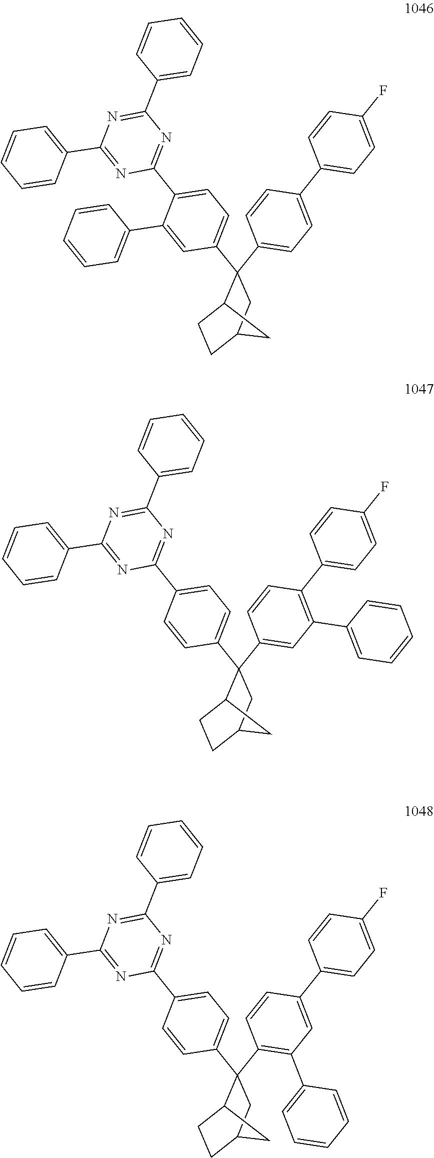 [SMILES: Fc1ccc(-c2ccc(C3(c4ccc(-c5nc(-c6ccccc6)nc(-c6ccccc6)n5)c(-c5ccccc5)c4)CC4CCC3C4)cc2)cc1 ; Fc1ccc(-c2ccc(C3(c4ccc(-c5nc(-c6ccccc6)nc(-c6ccccc6)n5)cc4)CC4CCC3C4)cc2-c2ccccc2)cc1 ; Fc1ccc(-c2ccc(C3(c4ccc(-c5nc(-c6ccccc6)nc(-c6ccccc6)n5)cc4)CC4CCC3C4)c(-c3ccccc3)c2)cc1]

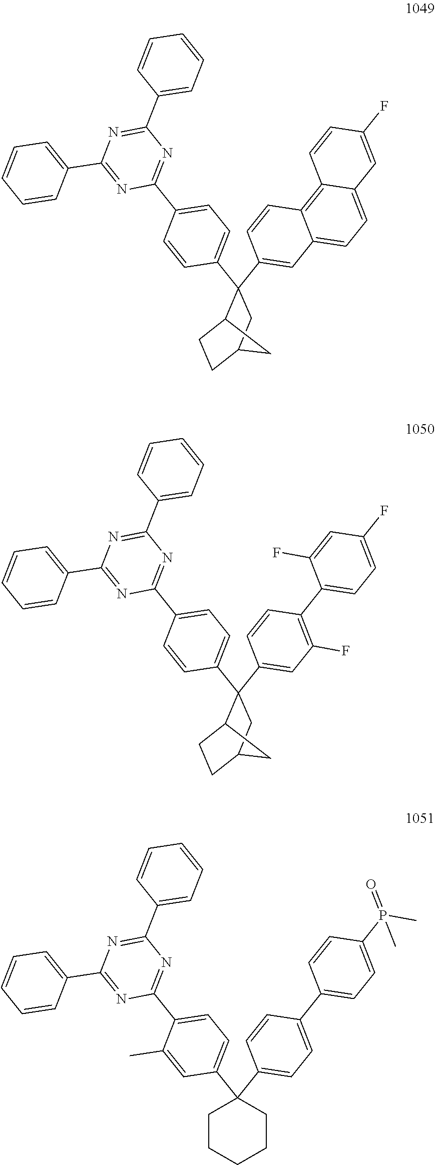 [SMILES: Fc1ccc2c(ccc3cc(C4(c5ccc(-c6nc(-c7ccccc7)nc(-c7ccccc7)n6)cc5)CC5CCC4C5)ccc32)c1 ; Fc1ccc(-c2ccc(C3(c4ccc(-c5nc(-c6ccccc6)nc(-c6ccccc6)n5)cc4)CC4CCC3C4)cc2F)c(F)c1 ; Cc1cc(C2(c3ccc(-c4ccc(P(C)(C)=O)cc4)cc3)CCCCC2)ccc1-c1nc(-c2ccccc2)nc(-c2ccccc2)n1]

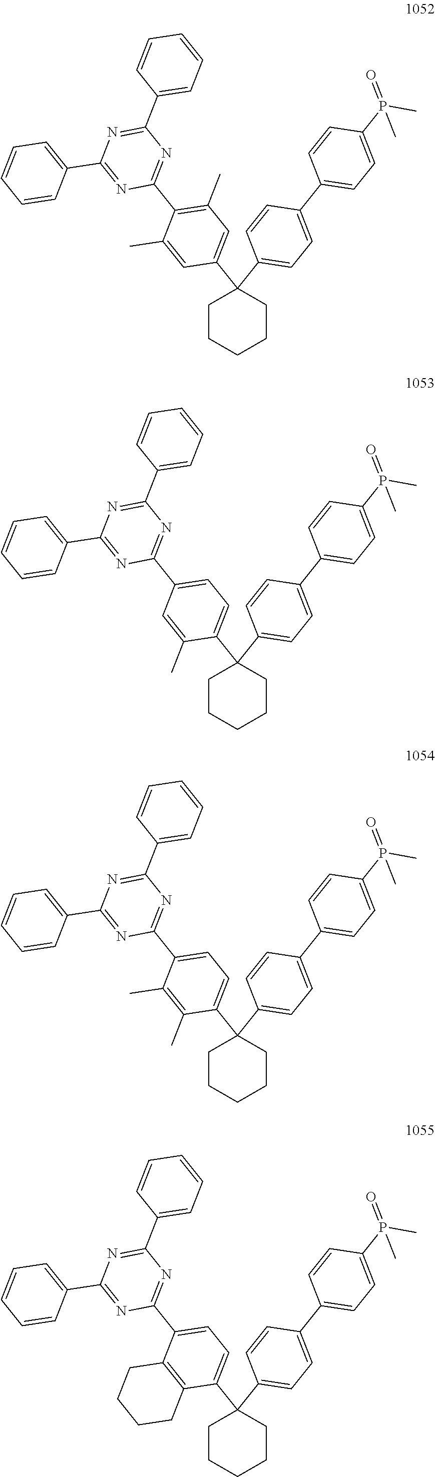 [SMILES: Cc1cc(C2(c3ccc(-c4ccc(P(C)(C)=O)cc4)cc3)CCCCC2)cc(C)c1-c1nc(-c2ccccc2)nc(-c2ccccc2)n1 ; Cc1cc(-c2nc(-c3ccccc3)nc(-c3ccccc3)n2)ccc1C1(c2ccc(-c3ccc(P(C)(C)=O)cc3)cc2)CCCCC1 ; Cc1c(-c2nc(-c3ccccc3)nc(-c3ccccc3)n2)ccc(C2(c3ccc(-c4ccc(P(C)(C)=O)cc4)cc3)CCCCC2)c1C ; CP(C)(=O)c1ccc(-c2ccc(C3(c4ccc(-c5nc(-c6ccccc6)nc(-c6ccccc6)n5)c5c4CCCC5)CCCCC3)cc2)cc1]

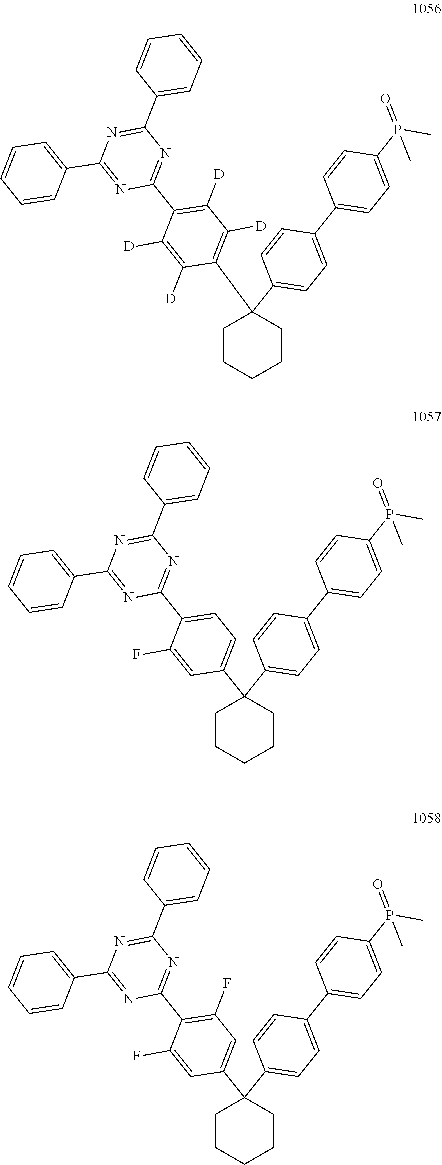 [SMILES: [2H]c1c([2H])c(C2(c3ccc(-c4ccc(P(C)(C)=O)cc4)cc3)CCCCC2)c([2H])c([2H])c1-c1nc(-c2ccccc2)nc(-c2ccccc2)n1 ; CP(C)(=O)c1ccc(-c2ccc(C3(c4ccc(-c5nc(-c6ccccc6)nc(-c6ccccc6)n5)c(F)c4)CCCCC3)cc2)cc1 ; CP(C)(=O)c1ccc(-c2ccc(C3(c4cc(F)c(-c5nc(-c6ccccc6)nc(-c6ccccc6)n5)c(F)c4)CCCCC3)cc2)cc1]

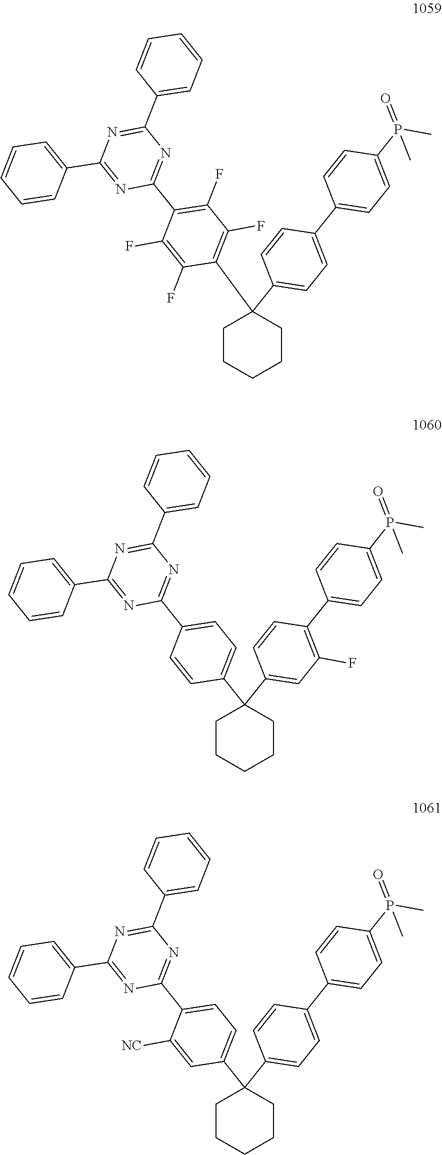 [SMILES: CP(C)(=O)c1ccc(-c2ccc(C3(c4c(F)c(F)c(-c5nc(-c6ccccc6)nc(-c6ccccc6)n5)c(F)c4F)CCCCC3)cc2)cc1 ; CP(C)(=O)c1ccc(-c2ccc(C3(c4ccc(-c5nc(-c6ccccc6)nc(-c6ccccc6)n5)cc4)CCCCC3)cc2F)cc1 ; CP(C)(=O)c1ccc(-c2ccc(C3(c4ccc(-c5nc(-c6ccccc6)nc(-c6ccccc6)n5)c(C#N)c4)CCCCC3)cc2)cc1]

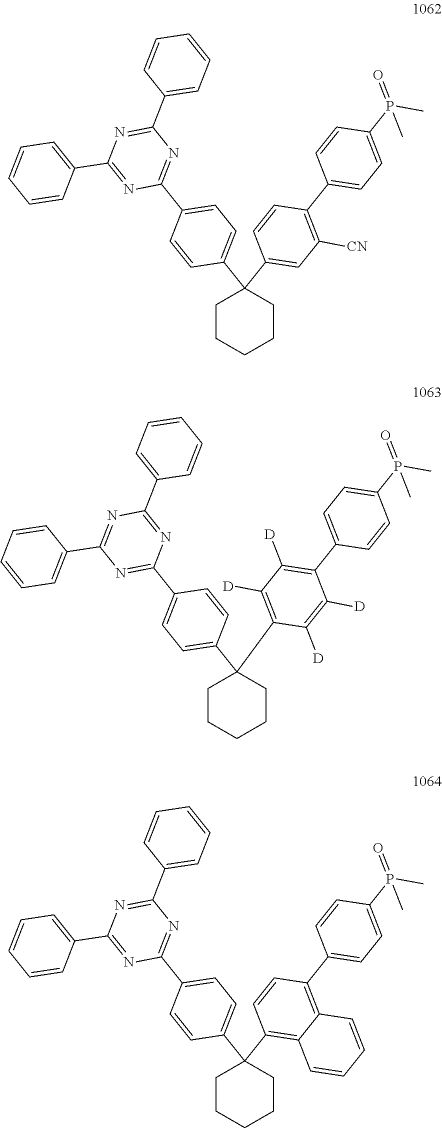 [SMILES: CP(C)(=O)c1ccc(-c2ccc(C3(c4ccc(-c5nc(-c6ccccc6)nc(-c6ccccc6)n5)cc4)CCCCC3)cc2C#N)cc1 ; [2H]c1c([2H])c(C2(c3ccc(-c4nc(-c5ccccc5)nc(-c5ccccc5)n4)cc3)CCCCC2)c([2H])c([2H])c1-c1ccc(P(C)(C)=O)cc1 ; CP(C)(=O)c1ccc(-c2ccc(C3(c4ccc(-c5nc(-c6ccccc6)nc(-c6ccccc6)n5)cc4)CCCCC3)c3ccccc23)cc1]

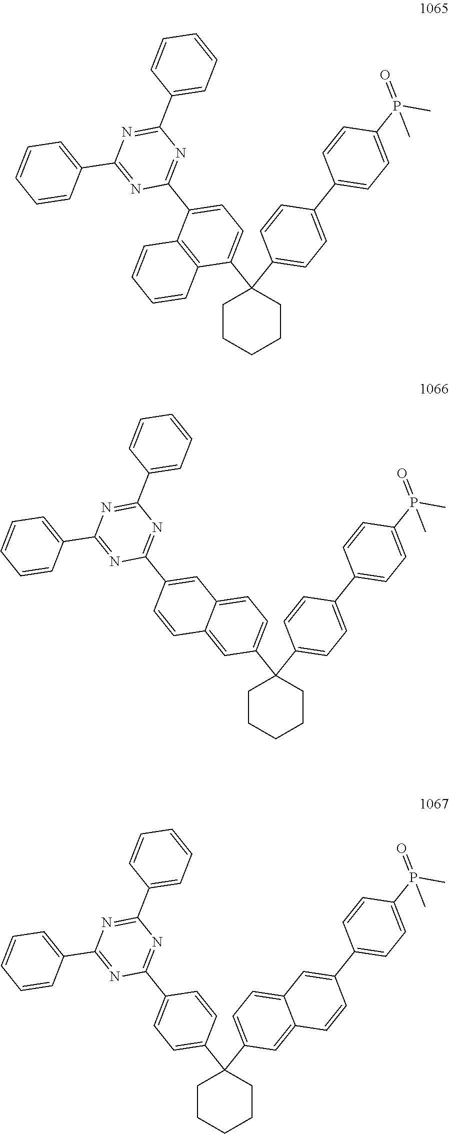 [SMILES: CP(C)(=O)c1ccc(-c2ccc(C3(c4ccc(-c5nc(-c6ccccc6)nc(-c6ccccc6)n5)c5ccccc45)CCCCC3)cc2)cc1 ; CP(C)(=O)c1ccc(-c2ccc(C3(c4ccc5cc(-c6nc(-c7ccccc7)nc(-c7ccccc7)n6)ccc5c4)CCCCC3)cc2)cc1 ; CP(C)(=O)c1ccc(-c2ccc3cc(C4(c5ccc(-c6nc(-c7ccccc7)nc(-c7ccccc7)n6)cc5)CCCCC4)ccc3c2)cc1]

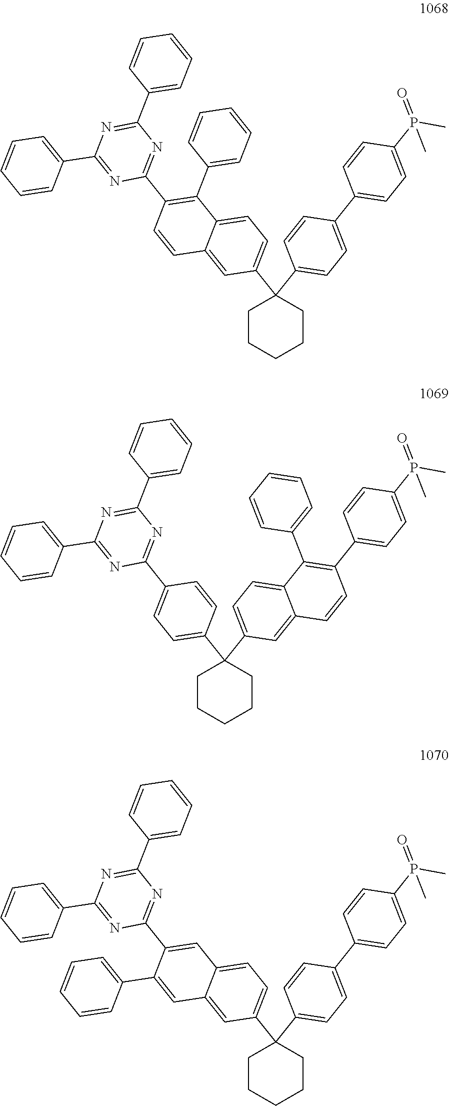 [SMILES: CP(C)(=O)c1ccc(-c2ccc(C3(c4ccc5c(-c6ccccc6)c(-c6nc(-c7ccccc7)nc(-c7ccccc7)n6)ccc5c4)CCCCC3)cc2)cc1 ; CP(C)(=O)c1ccc(-c2ccc3cc(C4(c5ccc(-c6nc(-c7ccccc7)nc(-c7ccccc7)n6)cc5)CCCCC4)ccc3c2-c2ccccc2)cc1 ; CP(C)(=O)c1ccc(-c2ccc(C3(c4ccc5cc(-c6nc(-c7ccccc7)nc(-c7ccccc7)n6)c(-c6ccccc6)cc5c4)CCCCC3)cc2)cc1]

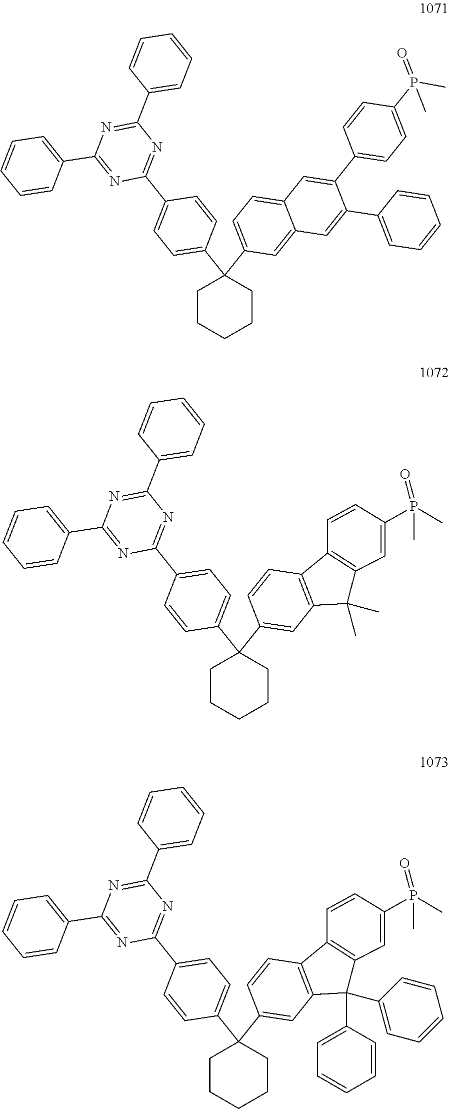 [SMILES: CP(C)(=O)c1ccc(-c2cc3ccc(C4(c5ccc(-c6nc(-c7ccccc7)nc(-c7ccccc7)n6)cc5)CCCCC4)cc3cc2-c2ccccc2)cc1 ; CC1(C)c2cc(C3(c4ccc(-c5nc(-c6ccccc6)nc(-c6ccccc6)n5)cc4)CCCCC3)ccc2-c2ccc(P(C)(C)=O)cc21 ; CP(C)(=O)c1ccc2c(c1)C(c1ccccc1)(c1ccccc1)c1cc(C3(c4ccc(-c5nc(-c6ccccc6)nc(-c6ccccc6)n5)cc4)CCCCC3)ccc1-2]

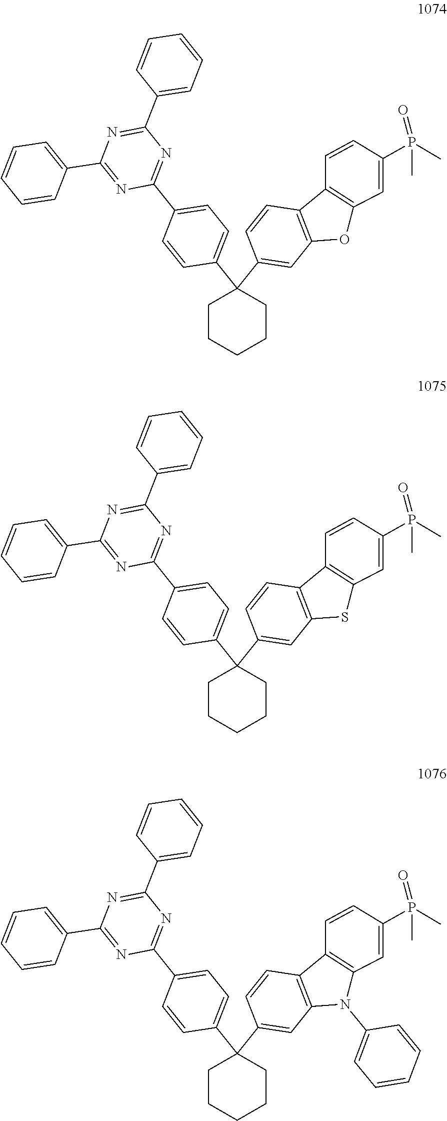 [SMILES: CP(C)(=O)c1ccc2c(c1)oc1cc(C3(c4ccc(-c5nc(-c6ccccc6)nc(-c6ccccc6)n5)cc4)CCCCC3)ccc12 ; CP(C)(=O)c1ccc2c(c1)sc1cc(C3(c4ccc(-c5nc(-c6ccccc6)nc(-c6ccccc6)n5)cc4)CCCCC3)ccc12 ; CP(C)(=O)c1ccc2c3ccc(C4(c5ccc(-c6nc(-c7ccccc7)nc(-c7ccccc7)n6)cc5)CCCCC4)cc3n(-c3ccccc3)c2c1]

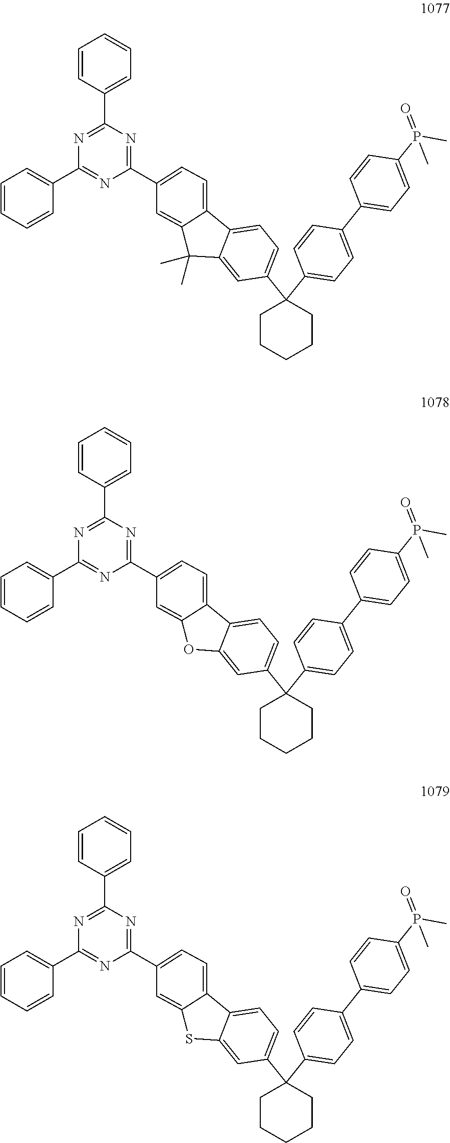 [SMILES: CC1(C)c2cc(-c3nc(-c4ccccc4)nc(-c4ccccc4)n3)ccc2-c2ccc(C3(c4ccc(-c5ccc(P(C)(C)=O)cc5)cc4)CCCCC3)cc21 ; CP(C)(=O)c1ccc(-c2ccc(C3(c4ccc5c(c4)oc4cc(-c6nc(-c7ccccc7)nc(-c7ccccc7)n6)ccc45)CCCCC3)cc2)cc1 ; CP(C)(=O)c1ccc(-c2ccc(C3(c4ccc5c(c4)sc4cc(-c6nc(-c7ccccc7)nc(-c7ccccc7)n6)ccc45)CCCCC3)cc2)cc1]

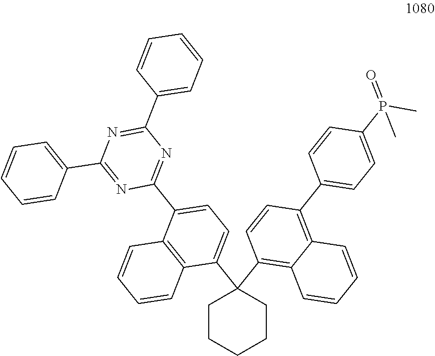 [SMILES: CP(C)(=O)c1ccc(-c2ccc(C3(c4ccc(-c5nc(-c6ccccc6)nc(-c6ccccc6)n5)c5ccccc45)CCCCC3)c3ccccc23)cc1]

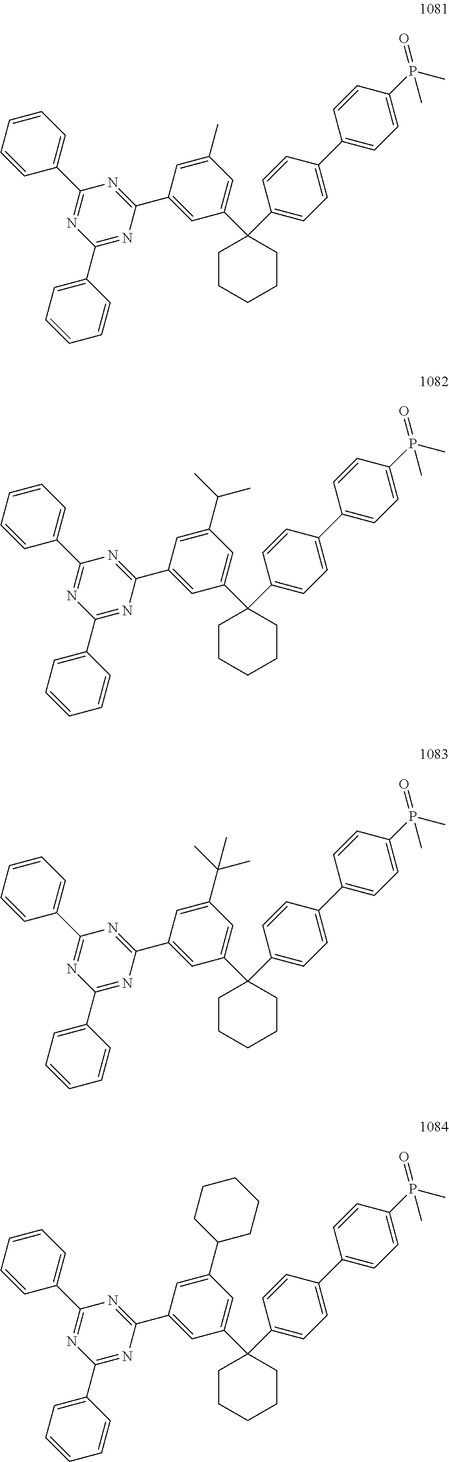 [SMILES: Cc1cc(-c2nc(-c3ccccc3)nc(-c3ccccc3)n2)cc(C2(c3ccc(-c4ccc(P(C)(C)=O)cc4)cc3)CCCCC2)c1 ; CC(C)c1cc(-c2nc(-c3ccccc3)nc(-c3ccccc3)n2)cc(C2(c3ccc(-c4ccc(P(C)(C)=O)cc4)cc3)CCCCC2)c1 ; CC(C)(C)c1cc(-c2nc(-c3ccccc3)nc(-c3ccccc3)n2)cc(C2(c3ccc(-c4ccc(P(C)(C)=O)cc4)cc3)CCCCC2)c1 ; CP(C)(=O)c1ccc(-c2ccc(C3(c4cc(-c5nc(-c6ccccc6)nc(-c6ccccc6)n5)cc(C5CCCCC5)c4)CCCCC3)cc2)cc1]

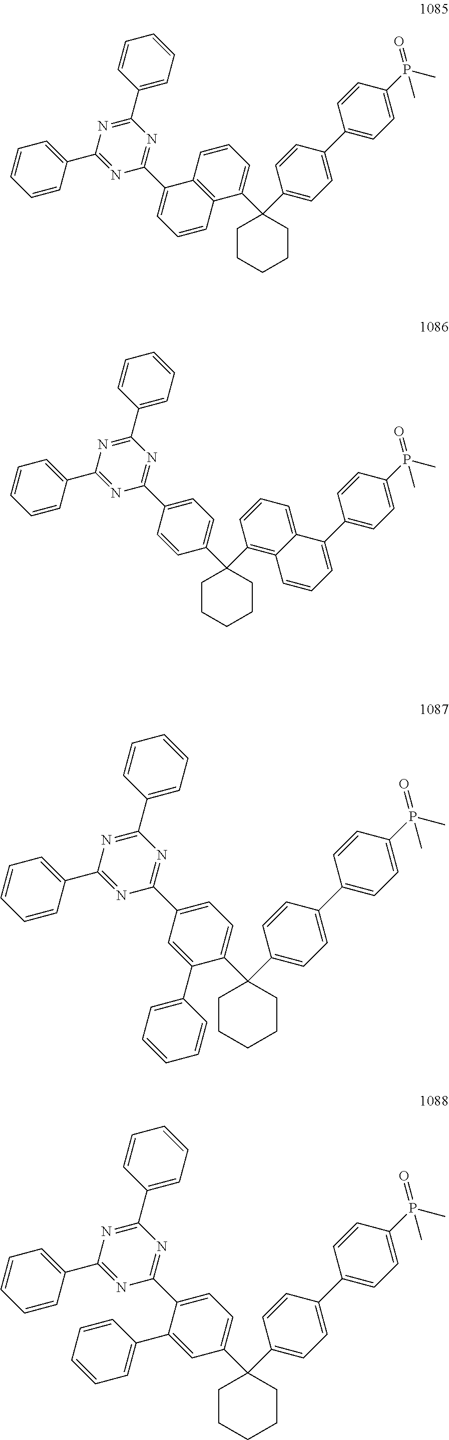 [SMILES: CP(C)(=O)c1ccc(-c2ccc(C3(c4cccc5c(-c6nc(-c7ccccc7)nc(-c7ccccc7)n6)cccc45)CCCCC3)cc2)cc1 ; CP(C)(=O)c1ccc(-c2cccc3c(C4(c5ccc(-c6nc(-c7ccccc7)nc(-c7ccccc7)n6)cc5)CCCCC4)cccc23)cc1 ; CP(C)(=O)c1ccc(-c2ccc(C3(c4ccc(-c5nc(-c6ccccc6)nc(-c6ccccc6)n5)cc4-c4ccccc4)CCCCC3)cc2)cc1 ; CP(C)(=O)c1ccc(-c2ccc(C3(c4ccc(-c5nc(-c6ccccc6)nc(-c6ccccc6)n5)c(-c5ccccc5)c4)CCCCC3)cc2)cc1]

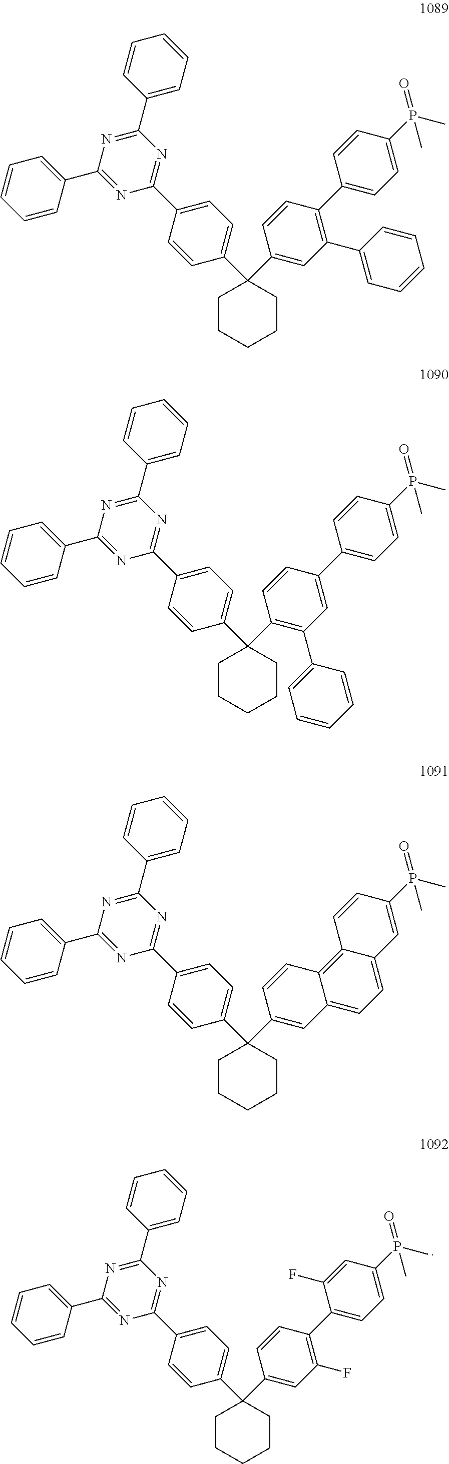 [SMILES: CP(C)(=O)c1ccc(-c2ccc(C3(c4ccc(-c5nc(-c6ccccc6)nc(-c6ccccc6)n5)cc4)CCCCC3)cc2-c2ccccc2)cc1 ; CP(C)(=O)c1ccc(-c2ccc(C3(c4ccc(-c5nc(-c6ccccc6)nc(-c6ccccc6)n5)cc4)CCCCC3)c(-c3ccccc3)c2)cc1 ; CP(C)(=O)c1ccc2c(ccc3cc(C4(c5ccc(-c6nc(-c7ccccc7)nc(-c7ccccc7)n6)cc5)CCCCC4)ccc32)c1 ; CP(C)(=O)c1ccc(-c2ccc(C3(c4ccc(-c5nc(-c6ccccc6)nc(-c6ccccc6)n5)cc4)CCCCC3)cc2F)c(F)c1]

The heterocyclic compound represented by Formula 1 may have a structure including triazine or pyrimidine, thereby having high intermolecular interaction due to increased π-π interaction. As a result, the heterocyclic compound represented by Formula 1 may have high electron transport ability.

In addition, in the heterocyclic compound represented by Formula 1, the electron mobility and refractive index may be controlled or selected by increasing the intermolecular distance by introducing sp³ carbon, which may inhibit or reduce π-π interaction, and the lowest unoccupied molecular orbital (LUMO) energy level of the heterocyclic compound may be variously changed by changing the position of the sp³ carbon. As a result, an appropriate or suitable energy level may be obtained between an electron transport layer and an emission layer, so that the exciton generation efficiency in the emission layer may be increased.

In addition, the heterocyclic compound represented by Formula 1 may not include an (e.g., may exclude any) adamantane group in Y₁, thereby having high electron transport ability and thermal rigidity compared to a compound including adamantane.

In addition, in the heterocyclic compound represented by Formula 1, the sum of a4 and b4 may be 1 or more if (e.g., when) Z₁ is a group represented by Formula 2A, and thus, the electron transport ability may be controlled or selected by adjusting substituents of R₁ and/or R₂, so that the charge balance may be effectively improved, compared to a compound in which Z₁ is a group represented by Formula 2A and the sum of a4 and b4 is 0.

Accordingly, if (e.g., when) the heterocyclic compound represented by Formula 1 is applied to an organic light-emitting device (for example, to an electron transport region of the organic light-emitting device), high efficiency and long lifespan may be achieved.

Synthesis methods of the heterocyclic compound represented by Formula 1 may be recognizable by one of ordinary skill in the art by referring to Synthesis Examples and/or Examples provided herein.

According to one or more embodiments of the present disclosure, at least one heterocyclic compound represented by Formula 1 may be used in a light-emitting device (e.g., an organic light-emitting device). Accordingly, provided is a light-emitting device including: a first electrode; a second electrode opposite to (e.g., facing) the first electrode; an interlayer between the first electrode and the second electrode and including an emission layer; and the heterocyclic compound represented by Formula 1.

In one or more embodiments,
the first electrode of the light-emitting device may be an anode,
the second electrode of the light-emitting device may be a cathode,
the interlayer may further include a hole transport region between the first electrode and the emission layer and an electron transport region between the emission layer and the second electrode,
the hole transport region may include a hole injection layer, a hole transport layer, an emission auxiliary layer, an electron blocking layer, or any combination thereof, and
the electron transport region may include a buffer layer, a hole blocking layer, an electron control layer, an electron transport layer, an electron injection layer, or any combination thereof.

In one or more embodiments, the heterocyclic compound may be included between the first electrode and the second electrode of the light-emitting device. Accordingly, the heterocyclic compound may be included in the interlayer of the light-emitting device, for example, in the electron transport region of the interlayer.

In one or more embodiments, the electron transport layer may include the heterocyclic compound.

In one or more embodiments, the emission layer in the interlayer of the light-emitting device may include a dopant and a host. The emission layer may be to emit red light, green light, blue light, and/or white light (e.g., combined white light). For example, in one or more embodiments, the emission layer may be to emit blue light.

The blue light may have a maximum emission wavelength (e.g., wavelength of maximum emission peak) in a range of, for example, about 400 nanometers (nm) to about 490 nm.

In one or more embodiments, the blue light may have a maximum emission wavelength in a range of about 430 nm to about 480 nm, about 430 nm to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, about 450 nm to about 465 nm, about 430 nm to about 460 nm, about 440 nm to about 460 nm, or about 450 nm to about 460 nm.

In one or more embodiments, the heterocyclic compound may be included in the host. For example, in one or more embodiments, the heterocyclic compound may act as a host.

In one or more embodiments, the emission layer in the interlayer of the light-emitting device may include a dopant and a host, the dopant may include a transition metal-containing compound, the transition metal-containing compound may include a transition metal and ligand(s) in the number of m, m may be an integer from 1 to 6, the ligand(s) in the number of m may be identical to or different from each other, at least one of the ligand(s) in the number of m and the transition metal may be linked to each other via a carbon-transition metal bond, and the carbon-transition metal bond may be a coordinate bond. For example, in one or more embodiments, at least one of (e.g., selected from among) the ligand(s) in the number of m may be a carbene ligand (e.g., Ir(pmp)₃, and/or the like). The transition metal may be, for example, iridium, platinum, osmium, palladium, rhodium, gold, and/or the like. The dopant may be to emit blue light. More details on the emission layer and the dopant may each independently be the same as described herein.

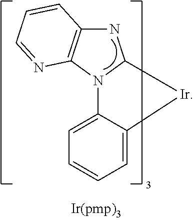

In one or more embodiments, the emission layer in the interlayer of the light-emitting device may include a dopant and a host, the host may include a second compound including at least one π electron-deficient nitrogen-containing C₁-C₆₀ heterocyclic group, and a third compound including a group represented by Formula 32 described herein, and the dopant may be to emit blue light. The second compound and the third compound in the light-emitting device may be different from each other.

In one or more embodiments, the second compound and the third compound may form an exciplex.

In one or more embodiments, the second compound may include a pyridine group, a pyrimidine group, a pyrazine group, a pyridazine group, a triazine group, or any combination thereof.

In one or more embodiments, the second compound may include a compound represented by Formula 31:

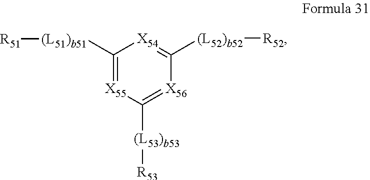

wherein, in Formula 31,
L₅₁ to L₅₃ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
b51 to b53 may each independently be an integer from 1 to 5,
X₅₄ may be N or C(R₅₄), X₅₅ may be N or C(R₅₅), X₅₆ may be N or C(R₅₆), and at least one selected from among X₅₄ to X₅₆ may be N, and
R₅₁ to R₅₆ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).
R₁₀ₐ and Q₁ to Q₃ are each the same as described herein.

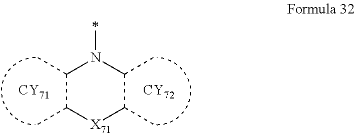

In Formula 32,
ring CY₇₁ and ring CY₇₂ may each independently be a Ir electron-rich C₃-C₆₀ cyclic group or a pyridine group,
X₇₁ may be a single bond, or a linking group including O, S, N, B, C, Si, or any combination thereof, and
* indicates a binding site to any atom included in the remaining part other than the group represented by Formula 32 in the third compound.

In one or more embodiments, the third compound may not include (e.g., may exclude) a compound represented by Formula 3A described herein.

In one or more embodiments, the following compounds may be excluded from the third compound:

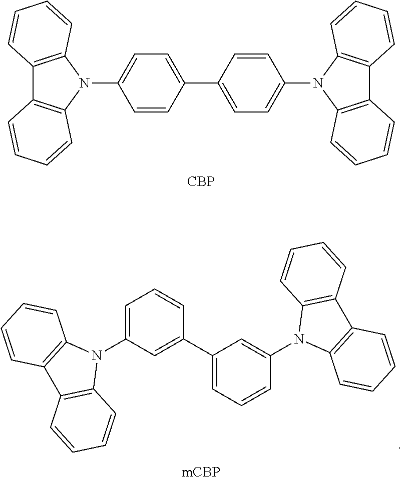 [SMILES: c1ccc2c(c1)c1ccccc1n2-c1ccc(-c2ccc(-n3c4ccccc4c4ccccc43)cc2)cc1 ; "CBP" ; c1cc(-c2cccc(-n3c4ccccc4c4ccccc43)c2)cc(-n2c3ccccc3c3ccccc32)c1]

In one or more embodiments, the third compound may include a compound represented by Formula 3A, a compound represented by Formula 3B, a compound represented by Formula 3C, a compound represented by Formula 3D, a compound represented by Formula 3E. or any combination thereof:

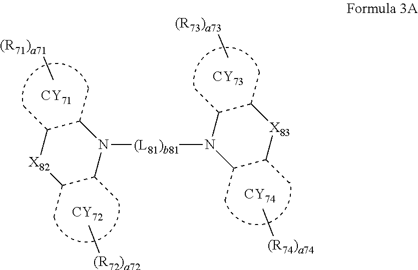

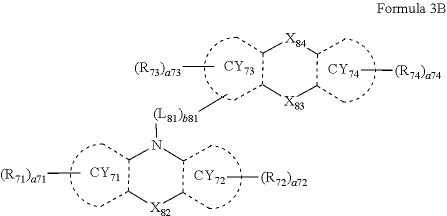

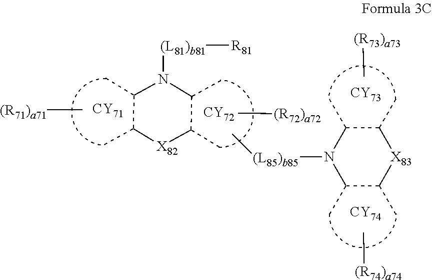

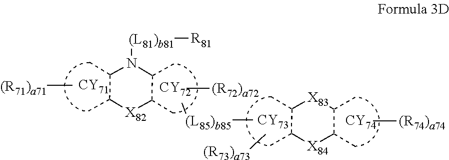

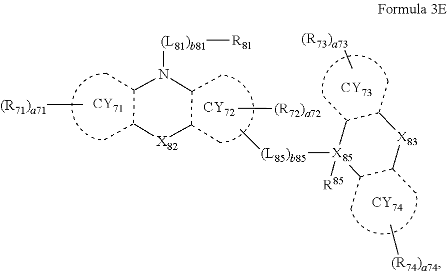

wherein, in Formulae 3A to 3E,
ring CY₇₁ to ring CY₇₄ may each independently be a π electron-rich C₃-C₆₀ cyclic group or a pyridine group,
X₈₂ may be a single bond, O, S, N[(L₈₂)_{b82}-R₈₂], C(R₈₂ₐ)(R_{82b}), or Si(R₈₂ₐ)(R_{82b}),
X₈₃ may be a single bond, O, S, N[(L₈₃)_{b83}-R₈₃], C(R₈₃ₐ)(R_{83b}), or Si(R₈₃ₐ)(R_{83b}),
X₈₄ may be O, S, N[(L₈₄)_{b84}-R₈₄], C(R₈₄ₐ)(R_{84b}), or Si(R₈₄ₐ)(R₈₄₆),
X₈₅ may be C or Si,
L₈₁ to L₈₅ may each independently be a single bond, *—C(Q₄)(Q₅)-*′, *—Si(Q₄)(Q₅)-*′, a π electron-rich C₃-C₆₀ cyclic group unsubstituted or substituted with at least one R₁₀ₐ, or a pyridine group unsubstituted or substituted with at least one R₁₀ₐ, wherein Q₄ and Q₅ may each independently the same as described with respect to Q₁,
b81 to b85 may each independently be an integer from 1 to 5,
R₇₁ to R₇₄, R₈₁ to R₈₅, R₈₂ₐ, R_{82b}, R₈₃ₐ, R_{83b}, R₈₄ₐ, and R_{84b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a71 to a74 may each independently be an integer from 0 to 20, and
R₁₀ₐ and Q₁ to Q₃ are each the same as described herein.

In one or more embodiments, the emission layer in the interlayer of the light-emitting device may include a dopant and a host, and the dopant may include a transition metal-containing compound, a delayed fluorescence material, or any combination thereof. The delayed fluorescence material may be a compound in which a difference between a triplet energy level (eV) of the delayed fluorescence material and a singlet energy level (eV) of the delayed fluorescence material is at least 0 eV but not more than about 0.5 eV (or at least 0 eV but not more than about 0.3 eV).

In one or more embodiments, the delayed fluorescence material may be a compound including at least one cyclic group including both (e.g., simultaneously) boron (B) and nitrogen (N) as ring-forming atoms.

In one or more embodiments, the delayed fluorescence material may be a C₈-C₆₀ polycyclic group-containing compound including two or more cyclic groups condensed to each other while sharing boron (B) (e.g., one being a first ring and the other being a second ring). In other words, the delayed fluorescence material may be a C₈-C₆₀ polycyclic compound. In one or more embodiments, this C₈-C₆₀ polycyclic compound includes two or more cyclic groups that are condensed together and share a boron (B) atom.

In one or more embodiments, the delayed fluorescence material may include a condensed ring in which at least one third ring is condensed with at least one fourth ring, for example, to form the condensed ring including four or more rings,
the third ring of the delayed fluorescence material may be a cyclopentane group, a cyclohexane group, a cycloheptane group, a cyclooctane group, a cyclopentene group, a cyclohexene group, a cycloheptene group, a cyclooctene group, an adamantane group, a norbornene group, a norbornane group, a bicyclo[1.1.1]pentane group, a bicyclo[2.1.1]hexane group, a bicyclo[2.2.2]octane group, a benzene group, a pyridine group, a pyrimidine group, a pyridazine group, a pyrazine group, or a triazine group, and
the fourth ring of the delayed fluorescence material may be a 1,2-azaborinine group, a 1,3-azaborinine group, a 1,4-azaborinine group, a 1,2-dihydro-1,2-azaborinine group, a 1,4-oxaborinine group, a 1,4-thiaborinine group, or a 1,4-dihydroborinine group. In other words, the delayed fluorescence material described in one or more embodiments may feature a condensed ring structure, where at least one third ring is combined with at least one fourth ring, forming a structure with four or more rings. The third ring may be any one (e.g., one) selected from among variety of groups, such as cyclopentane, cyclohexane, cycloheptane, cyclooctane, cyclopentene, cyclohexene, cycloheptene, cyclooctene, adamantane, norbornene, norbornane, bicyclo[1.1.1]pentane, bicyclo[2.1.1]hexane, bicyclo[2.2.2]octane, benzene, pyridine, pyrimidine, pyridazine, pyrazine, and/or triazine. The fourth ring may be a 1,2-azaborinine, 1,3-azaborinine, 1,4-azaborinine, 1,2-dihydro-1,2-azaborinine, 1,4-oxaborinine, 1,4-thiaborinine, or 1,4-dihydroborinine group.

In one or more embodiments, the delayed fluorescence material may include a compound represented by Formula 502, a compound represented by Formula 503, or any combination thereof:

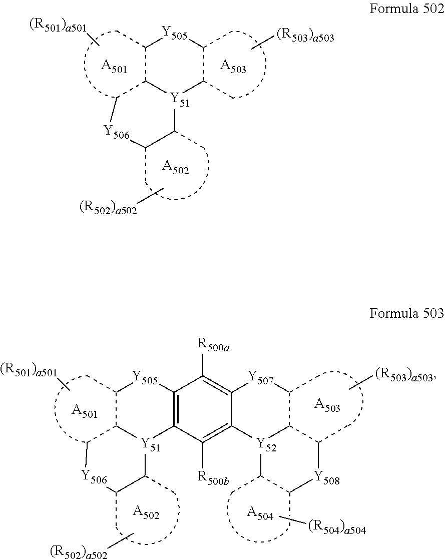

wherein, in Formulae 502 and 503,
ring A₅₀₁ to ring A₅₀₄ may each independently be a C₃-C₆₀ carbocyclic group or a C₁-C₆₀ heterocyclic group,
Y₅₀₅ may be O, S, N(R₅₀₅), B(R₅₀₅), C(R₅₀₅ₐ)(R_{505b}), or Si(R₅₀₅ₐ)(R_{505b}),
Y₅₀₆ may be O, S, N(R₅₀₆), B(R₅₀₆), C(R₅₀₆ₐ)(R_{506b}), or Si(R₅₀₆ₐ)(R_{506b}),
Y₅₀₇ may be O, S, N(R₅₀₇), B(R₅₀₇), C(R₅₀₇ₐ)(R_{507b}), or Si(R₅₀₇ₐ)(R_{507b}),
Y₅₀₈ may be O, S, N(R₅₀₈), B(R₅₀₈), C(R₅₀₈ₐ)(R_{508b}), or Si(R₅₀₈ₐ)(R_{508b}),
Y₅₁ and Y₅₂ may each independently be B, P(═O), or S(═O),
R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
a501 to a504 may each independently be an integer from 0 to 20.
R₁₀ₐ and Q₁ to Q₃ are each the same as described herein.

In one or more embodiments, the light-emitting device may satisfy at least one selected from among Conditions 1 to 4:

### Condition 1

lowest unoccupied molecular orbital (LUMO) energy level (eV) of third compound>LUMO energy level (eV) of transition metal-containing compound

### Condition 2

LUMO energy level (eV) of transition metal-containing compound>LUMO energy level (eV) of second compound

### Condition 3

highest occupied molecular orbital (HOMO) energy level (eV) of transition metal-containing compound>HOMO energy level (eV) of third compound

### Condition 4

HOMO energy level (eV) of third compound>HOMO energy level (eV) of second compound.

In the present disclosure, each of the HOMO energy level and LUMO energy level of each of the transition metal-containing compound, the second compound, and the third compound may be a negative value, and may be measured according to a suitable method.

In one or more embodiments, an absolute value of a difference between the LUMO energy level of the transition metal-containing compound and the LUMO energy level of the second compound may be at least about 0.1 eV but at most, e.g., not more than, about 1.0 eV, an absolute value of a difference between the LUMO energy level of the transition metal-containing compound and the LUMO energy level of the third compound may be at least about 0.1 eV but at most, e.g., not more than, about 1.0 eV, an absolute value of a difference between the HOMO energy level of the transition metal-containing compound and the HOMO energy level of the second compound may be about 1.25 eV or less (e.g., at least about 0.2 eV but at most, e.g., not more than, about 1.25 eV), and an absolute value of a difference between the HOMO energy level of the transition metal-containing compound and the HOMO energy level of the third compound may be about 1.25 eV or less (e.g., at least about 0.2 eV but at most, e.g., not more than, about 1.25 eV).

When the relationships between LUMO energy level and HOMO energy level satisfy the conditions as described above, a balance between holes and electrons injected into the emission layer may be achieved.

In one or more embodiments, the electron transport region of the light-emitting device may include a hole blocking layer, and the hole blocking layer may include a phosphine oxide-containing compound, a silicon-containing compound, or any combination thereof. For example, the hole blocking layer may directly contact the emission layer.

In one or more embodiments, the light-emitting device may include a capping layer arranged outside (e.g., on) the first electrode and/or a capping layer outside (e.g., on) the second electrode.

In one or more embodiments, the light-emitting device may further include at least one of a first capping layer on (e.g., arranged on) a surface of the first electrode and/or a second capping layer on (e.g., arranged on) a surface of the second electrode, and at least one of the first capping layer and/or the second capping layer may include the heterocyclic compound represented by Formula 1. More details on the first capping layer and/or the second capping layer may each independently be the same as described herein.

In one or more embodiments, the light-emitting device may include:
a first capping layer on (e.g., arranged on) a surface of the first electrode and including the heterocyclic compound represented by Formula 1;
a second capping layer on (e.g., arranged on) a surface of the second electrode and including the heterocyclic compound represented by Formula 1; or
the first capping layer and the second capping layer.

The expression “(an interlayer and/or a capping layer) includes at least one heterocyclic compound” as used herein may include an embodiment in which “(an interlayer and/or a capping layer) includes identical heterocyclic compounds represented by Formula 1” and an embodiment in which “(an interlayer and/or a capping layer) includes two or more different heterocyclic compounds each represented by Formula 1.”

In one or more embodiments, the interlayer and/or the capping layer may include, as the heterocyclic compound, only Compound 1. In this regard, Compound 1 may be present in the electron transport region of the light-emitting device. In one or more embodiments, the interlayer may include, as the heterocyclic compound, Compound 1 and Compound 2. In this regard, Compound 1 and Compound 2 may be present in an identical layer (e.g., both (e.g., simultaneously) Compound 1 and Compound 2 may be present in the electron transport region) or in different layers (e.g., Compound 1 may be present in the electron transport region, and Compound 2 may be present in the hole transport region).

The term “interlayer” as used herein refers to a single layer and/or all of multiple layers arranged between the first electrode and the second electrode of the light-emitting device.

According to one or more embodiments of the present disclosure, an electronic apparatus may include the light-emitting device. The electronic apparatus may further include a thin-film transistor. For example, in one or more embodiments, the electronic apparatus may further include a thin-film transistor including a source electrode and a drain electrode, and the first electrode of the light-emitting device may be electrically connected to the source electrode or the drain electrode. In one or more embodiments, the electronic apparatus may further include a color filter, a color conversion layer, a touch screen layer, a polarizing layer, or any combination thereof. More details on the electronic apparatus may be the same as described herein.

According to one or more embodiments of the present disclosure, electronic equipment may include the light-emitting device. For example, the electronic equipment may be at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard. More details on the electronic equipment may be the same as described herein.

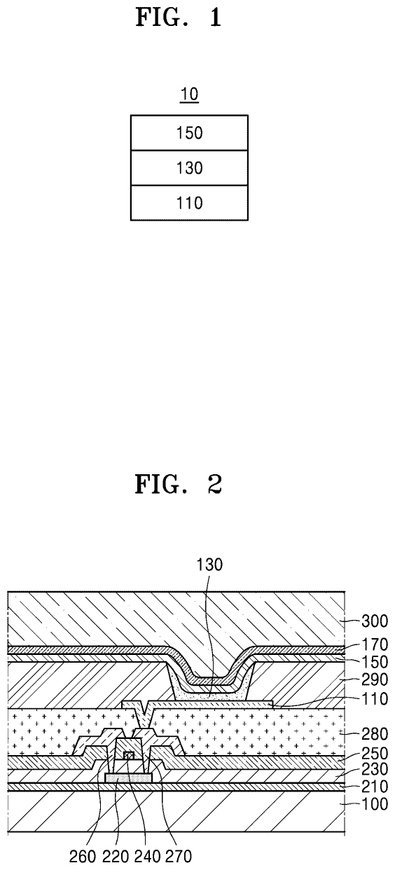

### Description of FIG. 1

FIG. 1 is a schematic cross-sectional view of a light-emitting device 10 according to one or more embodiments. The light-emitting device 10 may include a first electrode 110, an interlayer 130, and a second electrode 150.

Hereinafter, the structure of the light-emitting device 10 according to one or more embodiments and a method of manufacturing the light-emitting device 10 will be described with reference to FIG. 1.

First electrode 110

In FIG. 1, in one or more embodiments, a substrate may be additionally provided and arranged under the first electrode 110 and/or on the second electrode 150. As the substrate, a glass substrate or a plastic substrate may be used. In one or more embodiments, the substrate may be a flexible substrate, and may include plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a transflective electrode, or a transmissive electrode. In one or more embodiments, if (e.g., when) the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, if (e.g., when) the first electrode 110 is a transflective electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure including (e.g., consisting of) a single layer or a multi-layer structure including multiple layers. For example, in some embodiments, the first electrode 110 may have a three-layer structure of ITO/Ag/ITO.

### Interlayer 130

The interlayer 130 may be arranged on the first electrode 110. The interlayer 130 may include an emission layer.

In one or more embodiments, the interlayer 130 may further include a hole transport region between the first electrode 110 and the emission layer and an electron transport region between the emission layer and the second electrode 150.

In one or more embodiments, the interlayer 130 may further include, in addition to one or more suitable organic materials, for example, the heterocyclic compound represented by Formula 1, a metal-containing compound such as an organometallic compound, an inorganic material such as a quantum dot, and/or the like.

In one or more embodiments, the interlayer 130 may include i) two or more emitting units sequentially stacked between the first electrode 110 and the second electrode 150, and ii) a charge generation layer arranged between the two or more emitting units. When the interlayer 130 includes the two or more emitting units and the charge generation layer as described above, the light-emitting device 10 may be a tandem light-emitting device.

### Hole Transport Region in Interlayer 130

The hole transport region may have i) a single-layer structure including (e.g., consisting of) a single layer including (e.g., consisting of) a single material, ii) a single-layer structure including (e.g., consisting of) a single layer including multiple materials that are different from each other, or iii) a multi-layer structure including multiple layers including multiple materials that are different from each other.

The hole transport region may include a hole injection layer, a hole transport layer, an emission auxiliary layer, an electron blocking layer, or any combination thereof.

In one or more embodiments, the hole transport region may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein constituent layers of each structure are stacked sequentially from the first electrode 110 in the stated order.

In one or more embodiments, the hole transport region may include a compound represented by Formula 201, a compound represented by Formula 202, or any combination thereof:

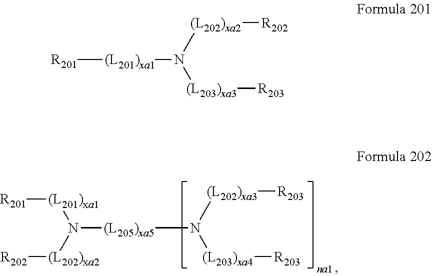

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group, and/or the like) unsubstituted or substituted with at least one R₁₀ₐ (e.g., see Compound HT16, and/or the like),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In one or more embodiments, each of Formulae 201 and 202 may include at least one selected from among groups represented by Formulae CY₂₀₁ to CY₂₁₇:

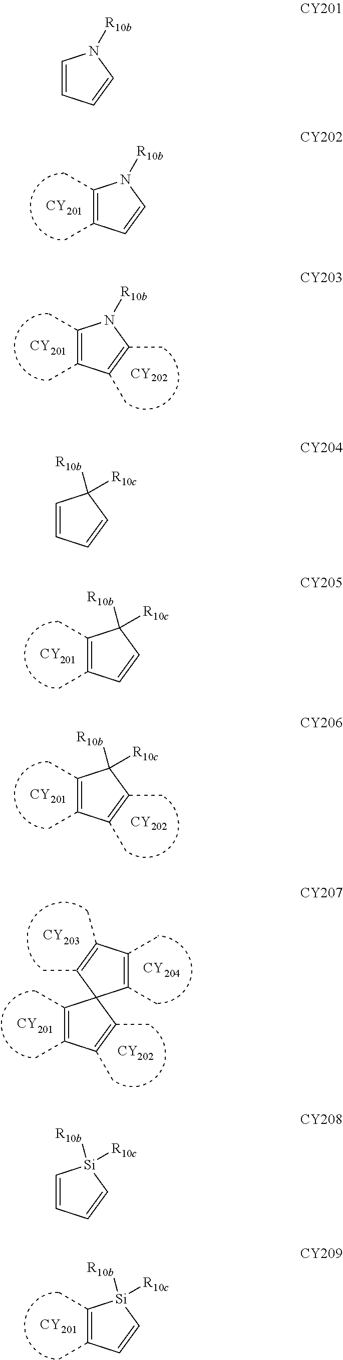

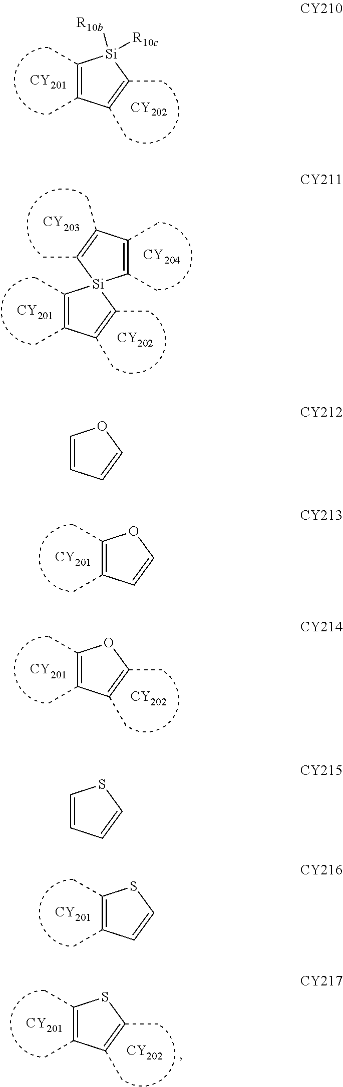

wherein, in Formulae CY201 to CY217, R_{10b} and R_{10c} may each independently be the same as described with respect to R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, in Formulae CY201 to CY217, ring CY201 to ring CY204 may each independently be a benzene group, a naphthalene group, a phenanthrene group, or an anthracene group.

In one or more embodiments, each of Formulae 201 and 202 may include at least one selected from among groups represented by Formulae CY201 to CY203.

In one or more embodiments, Formula 201 may include at least one selected from among groups represented by Formulae CY201 to CY203 and at least one selected from among groups represented by Formulae CY204 to CY217.

In one or more embodiments, in Formula 201, xa1 may be 1, R₂₀₁ may be a group represented by any one selected from among Formulae CY201 to CY203, xa2 may be 0, and R₂₀₂ may be a group represented by any one selected from among Formulae CY204 to CY207.

In one or more embodiments, each of Formulae 201 and 202 may not include (e.g., may exclude any of) groups represented by Formulae CY201 to CY203.

In one or more embodiments, each of Formulae 201 and 202 may not include (e.g., may exclude any of) groups represented by Formulae CY201 to CY203, and may include at least one selected from among groups represented by Formulae CY204 to CY217.

In one or more embodiments, each of Formulae 201 and 202 may not include (e.g., may exclude any of) groups represented by Formulae CY201 to CY217.

In one or more embodiments, the hole transport region may include: at least one of (e.g., selected from among) Compounds HT1 to HT46; 4,4′,4″-[tris(3-methylphenyl)phenylamino]triphenylamine (m-MTDATA); 4,4′,4″-tris(N,N-diphenylamino)triphenylamine (TDATA); 4,4′,4″-tris[N-(2-naphthyl)-N-phenylamino]-triphenylamine (2-TNATA); N,N′-di(naphthalen-1-yl)-N, N′-diphenyl-benzidine (NPB(NPD)); B—NPB; N,N′-bis(3-methylphenyl)-N,N′-diphenyl-[1,1′-biphenyl]-4,4′-diamine (TPD); spiro-TPD; spiro-NPB; methylated NPB; 4,4′-cyclohexylidene bis[N,N-bis(4-methylphenyl)benzenamine] (TAPC); 4,4′-bis[N,N′-(3-tolyl)amino]-3,3′-dimethylbiphenyl (HMTPD); 4,4′,4″-tris(N-carbazolyl)triphenylamine (TCTA); polyaniline/dodecylbenzenesulfonic acid (PANI/DBSA); poly(3,4-ethylenedioxythiophene)/poly(4-styrenesulfonate) (PEDOT/PSS); polyaniline/camphor sulfonic acid (PANI/CSA); polyaniline/poly(4-styrenesulfonate) (PANI/PSS); or any combination thereof:

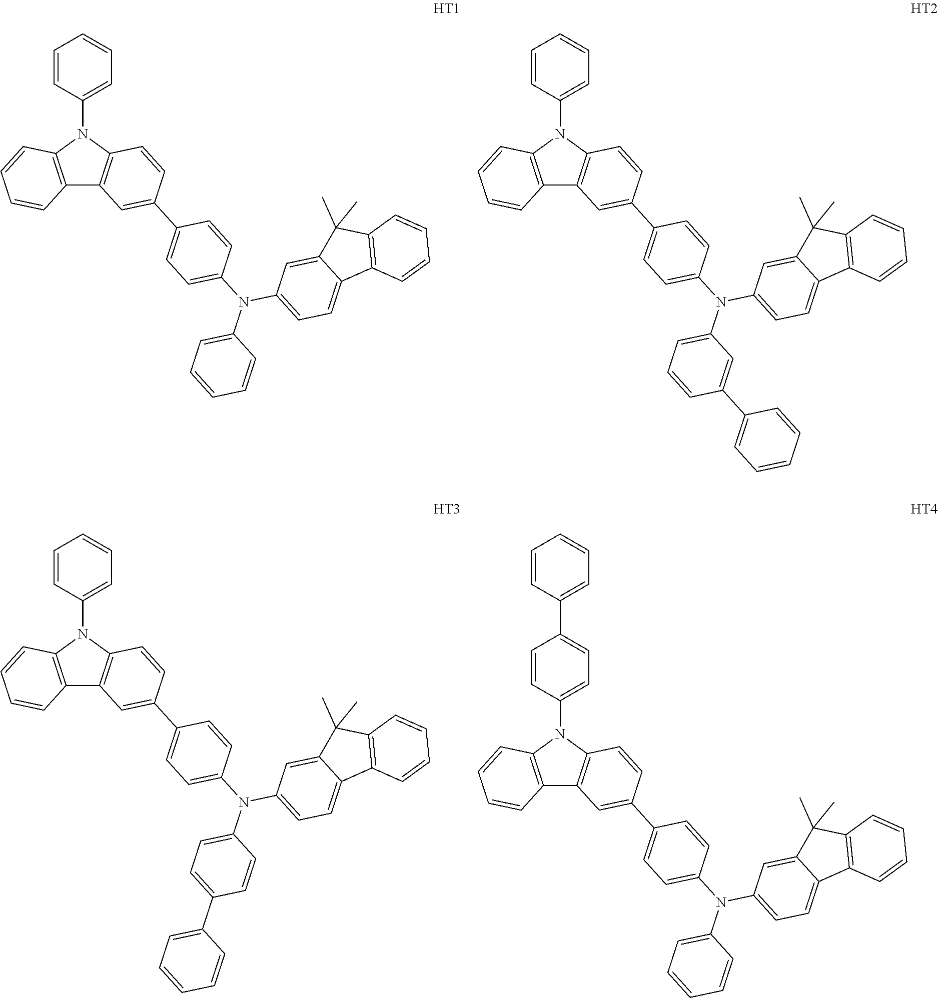 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

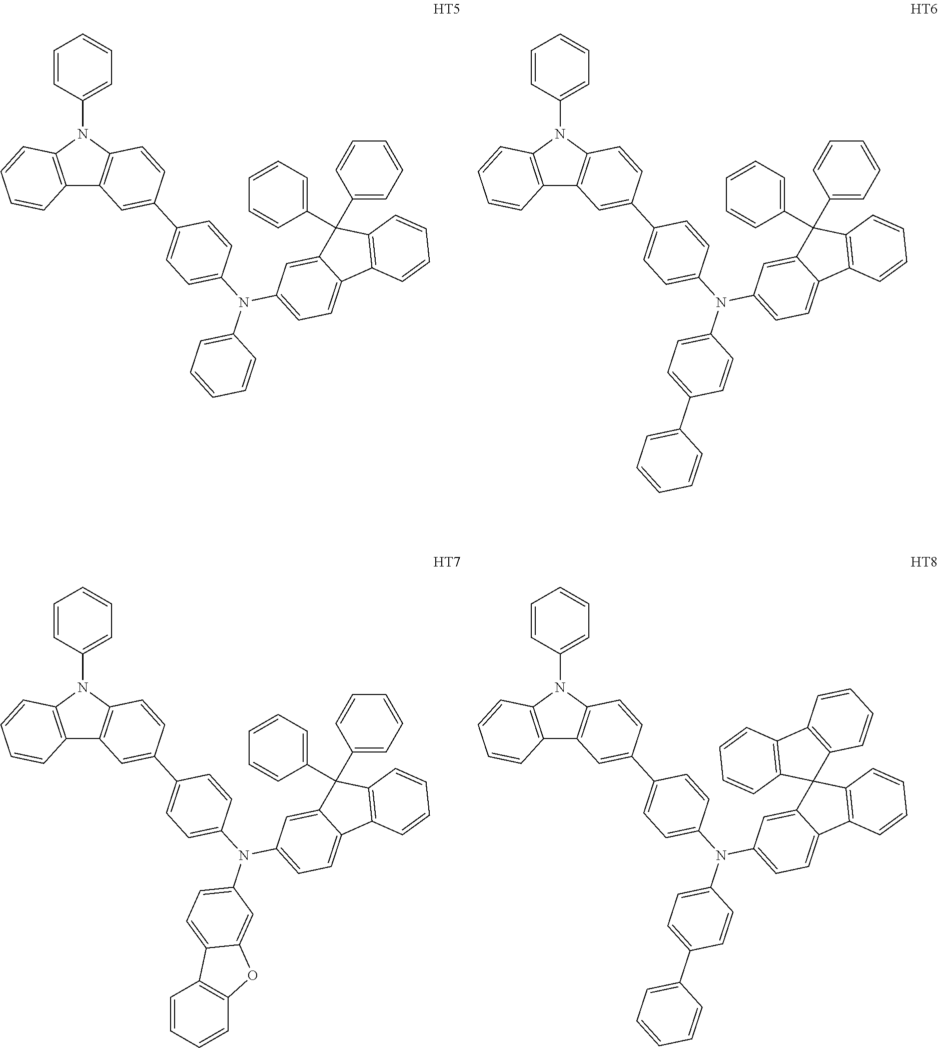 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

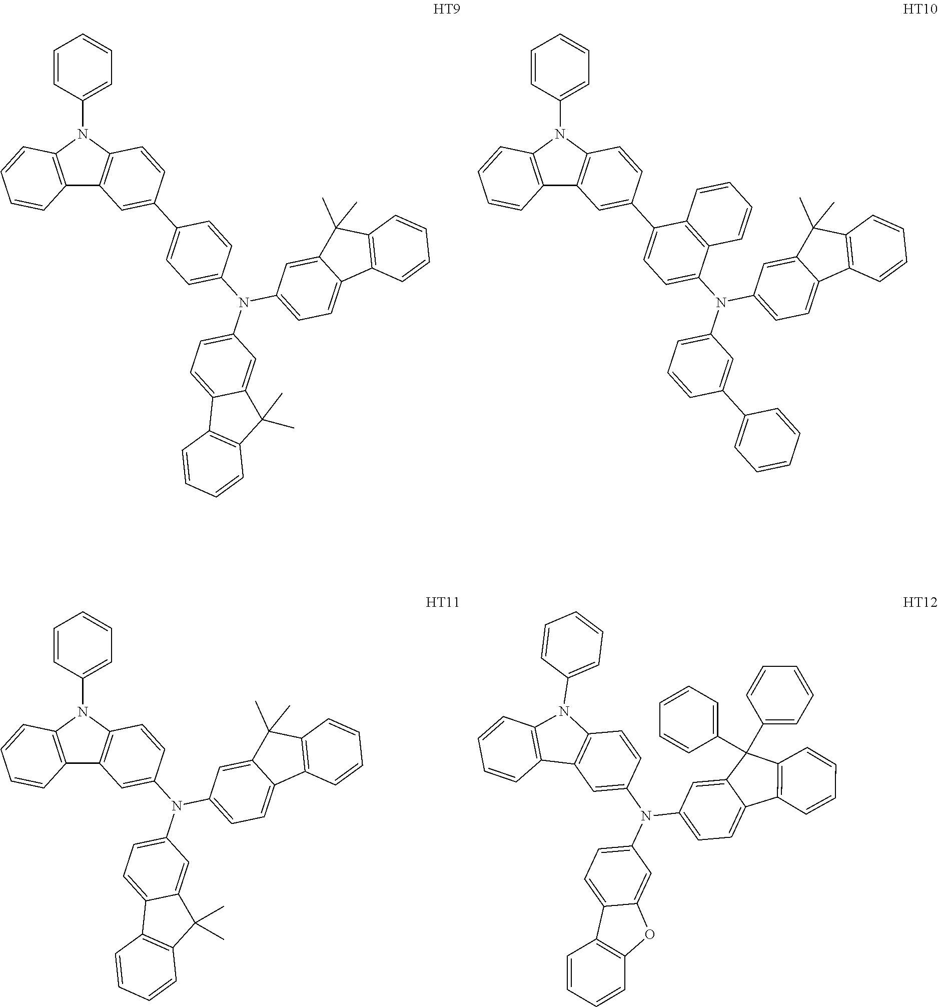 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

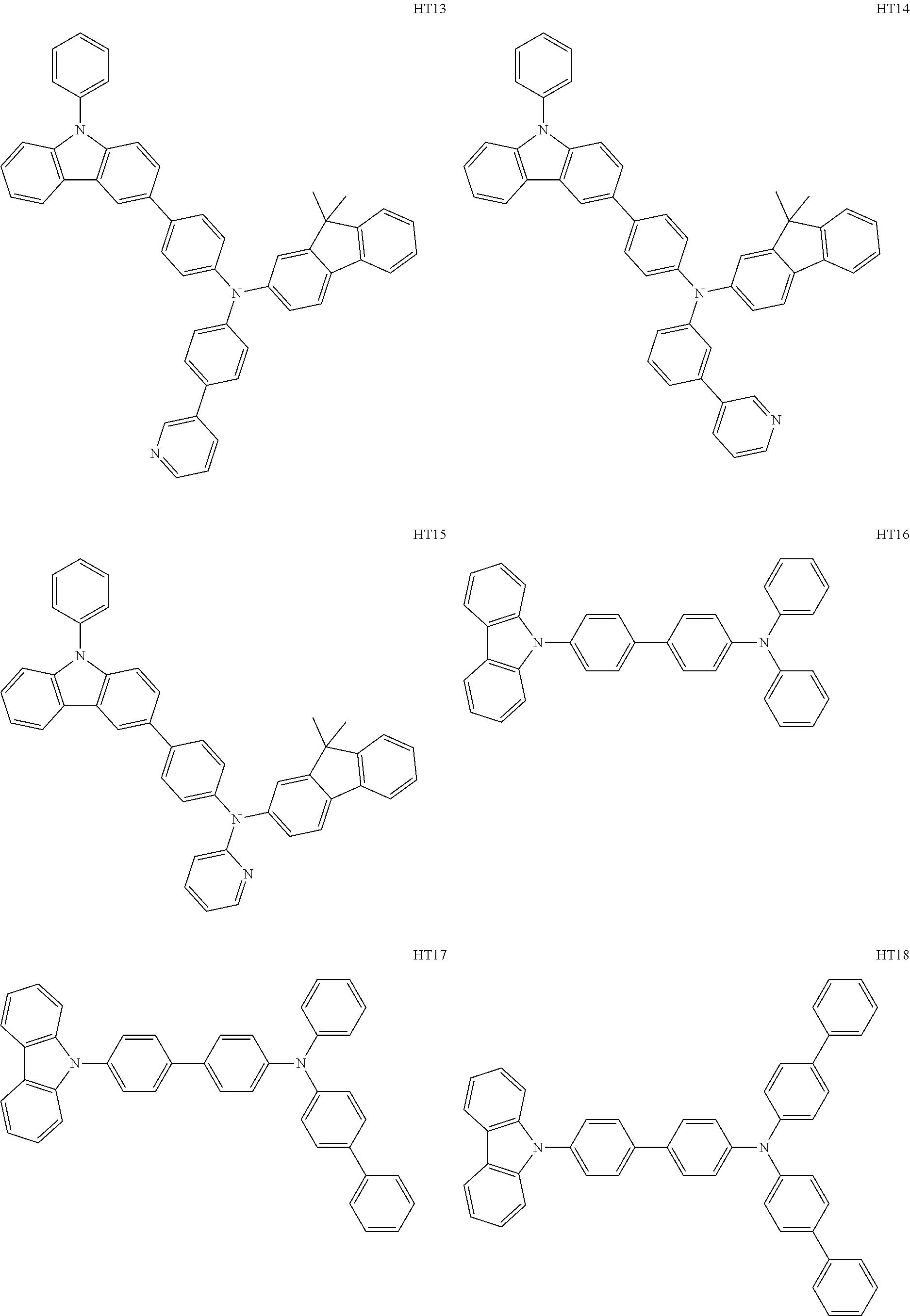 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

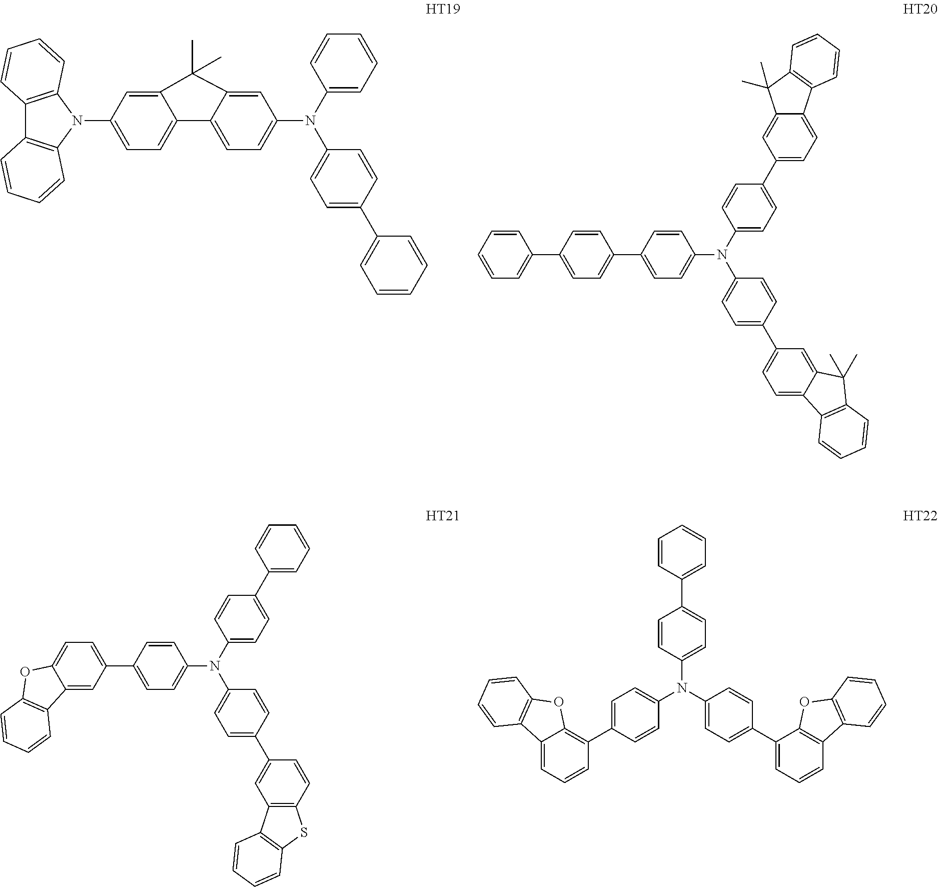 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1]

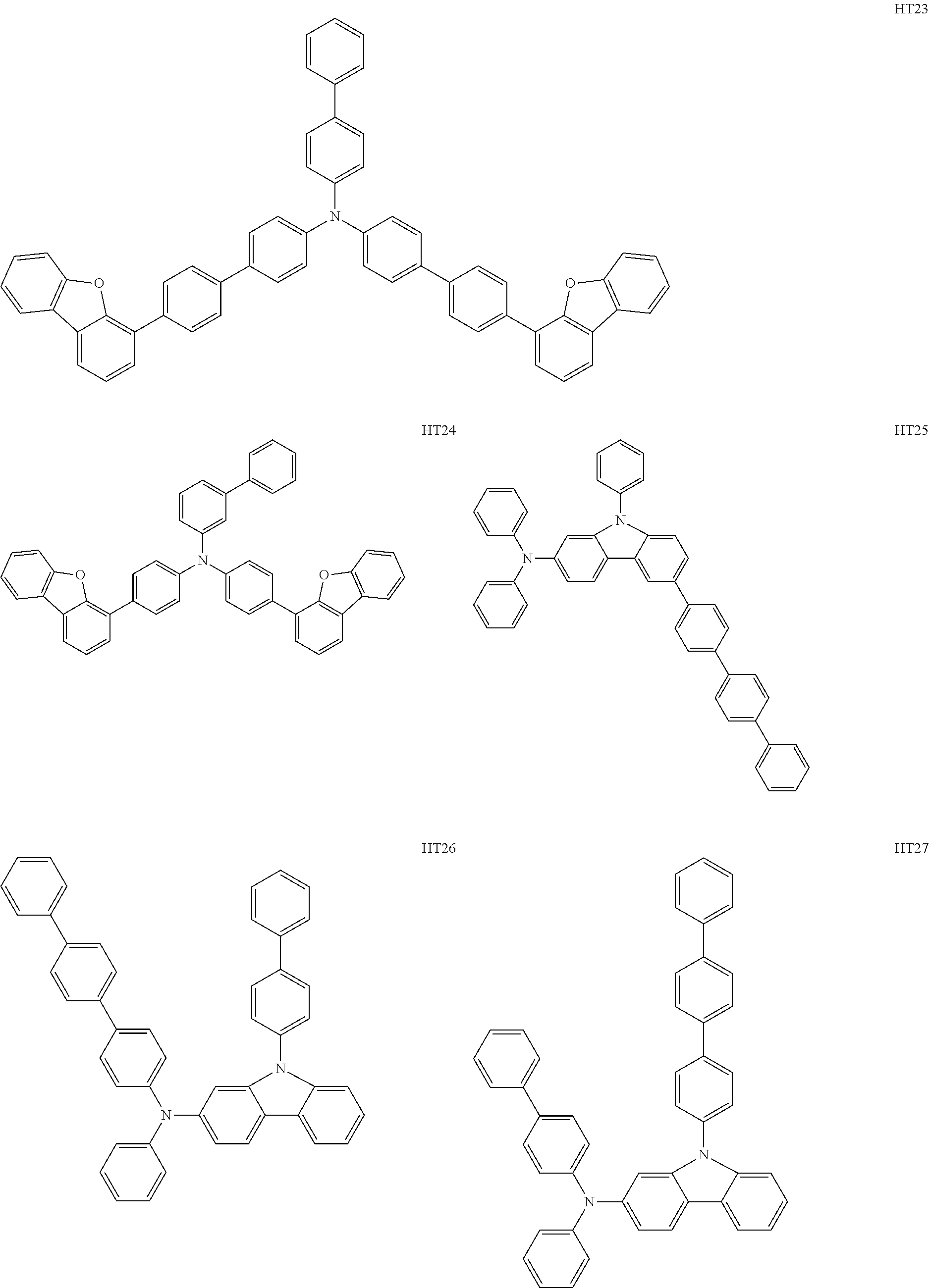 [SMILES: c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

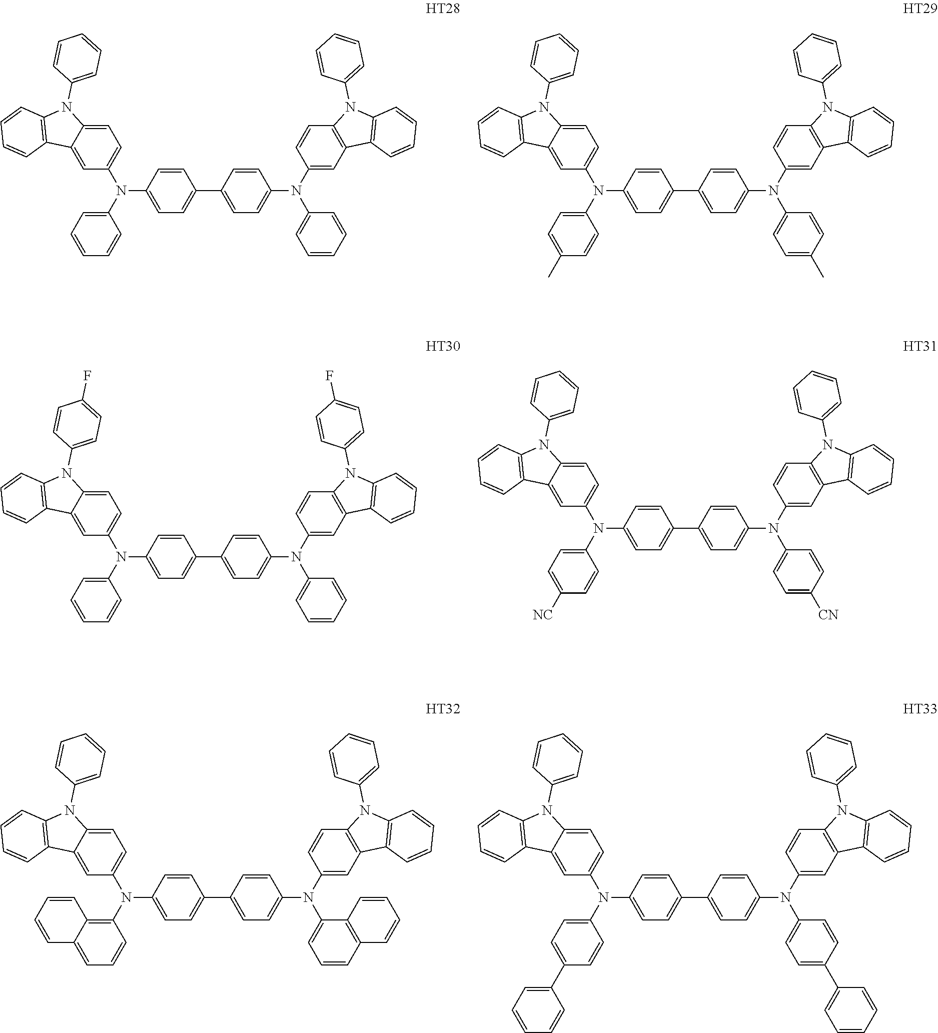

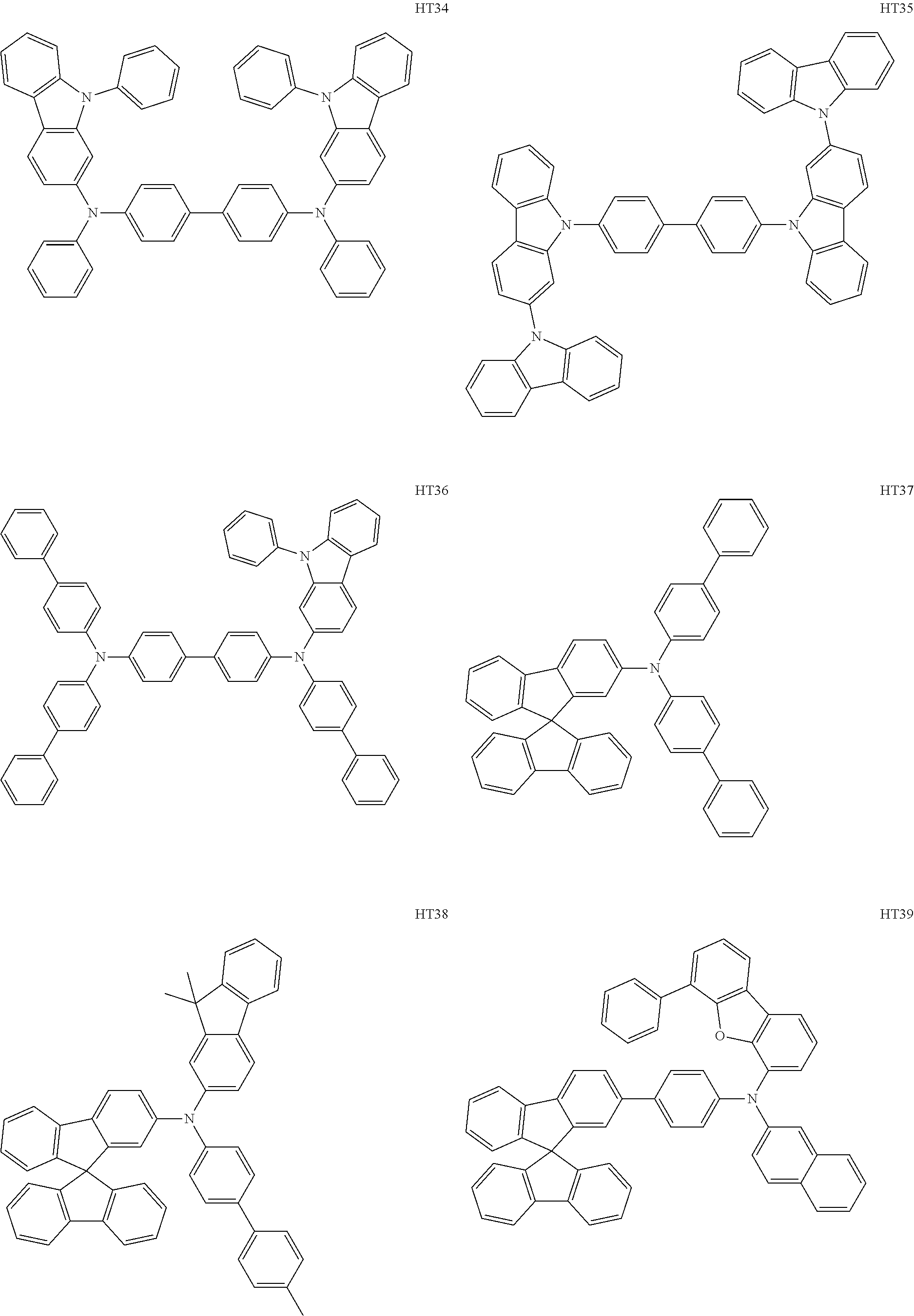

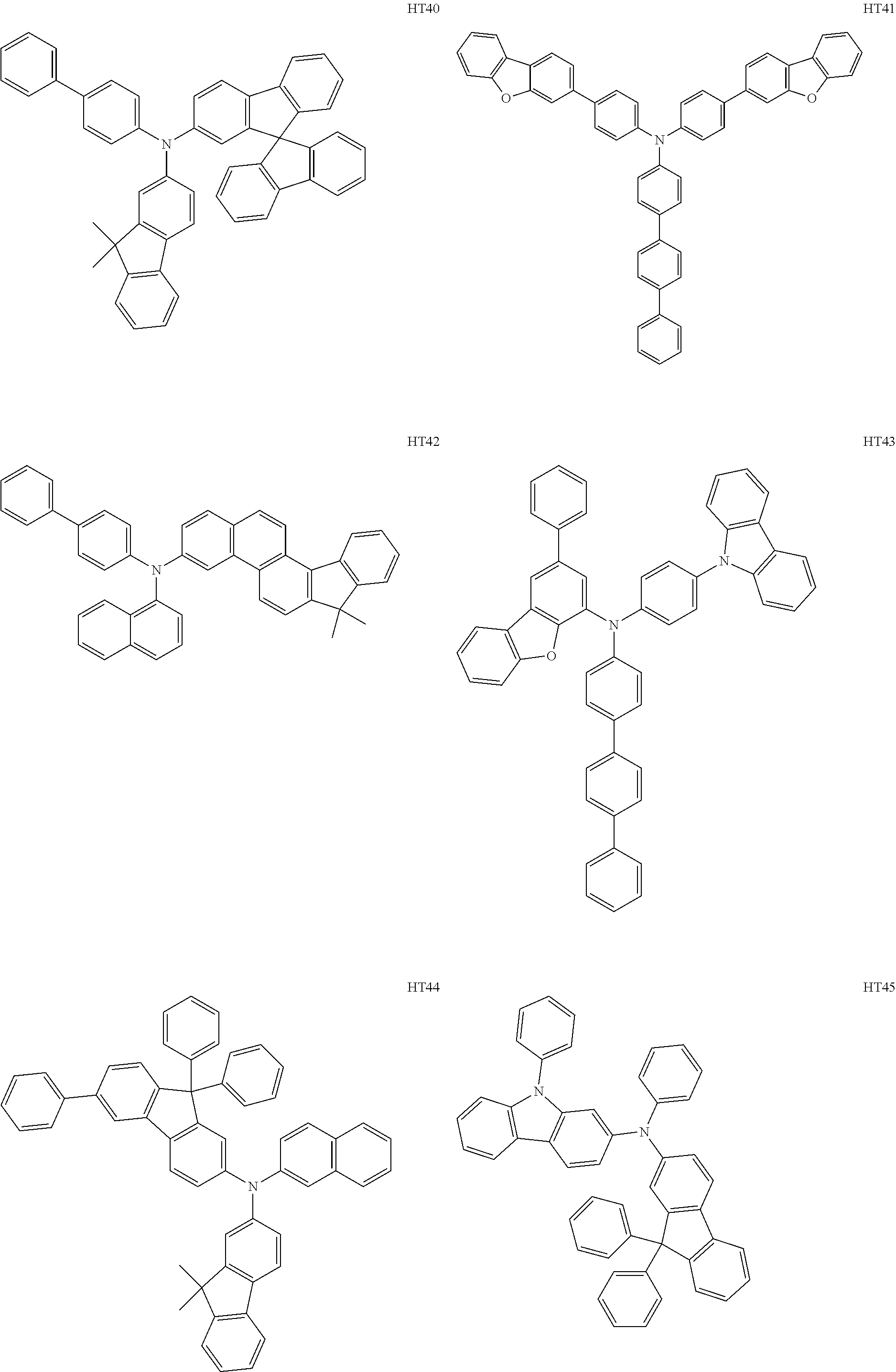

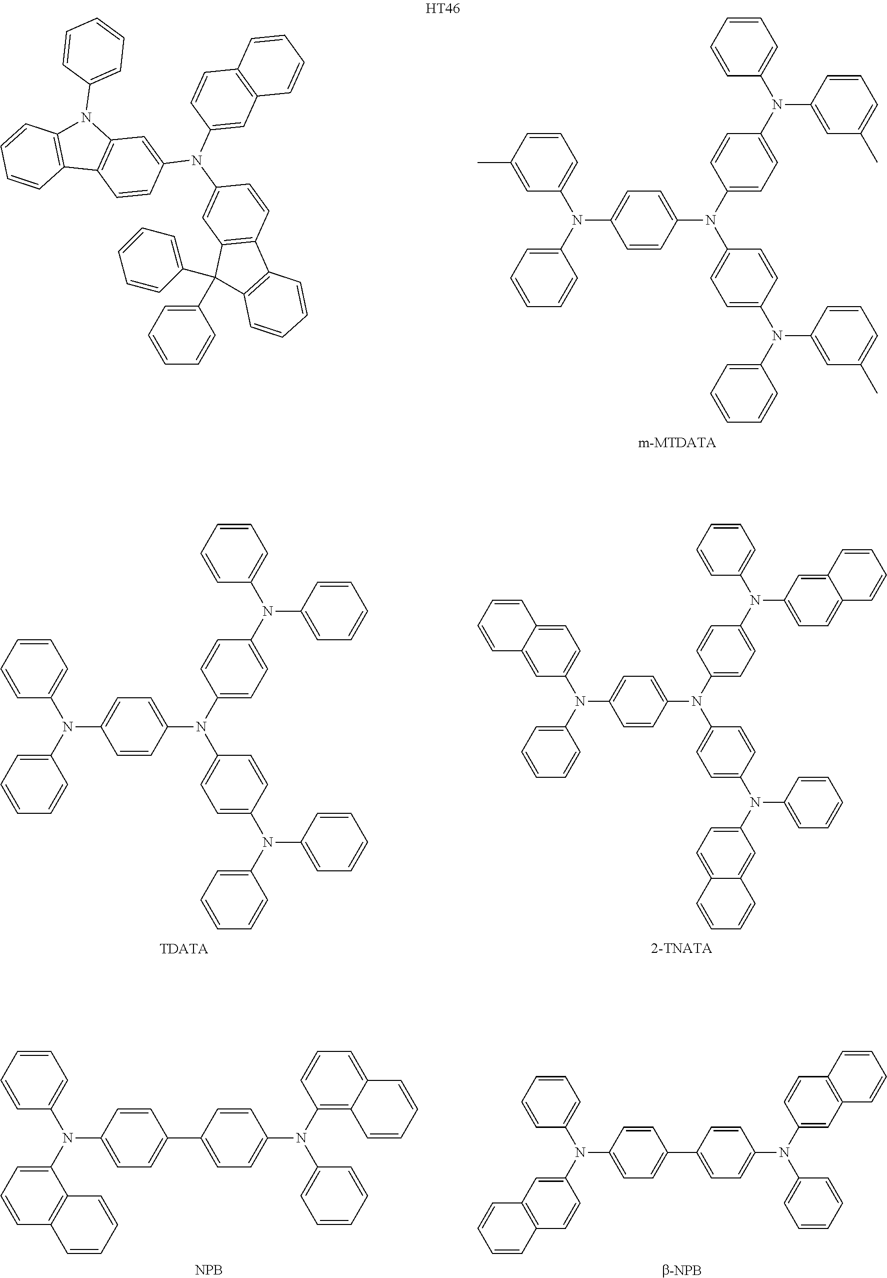

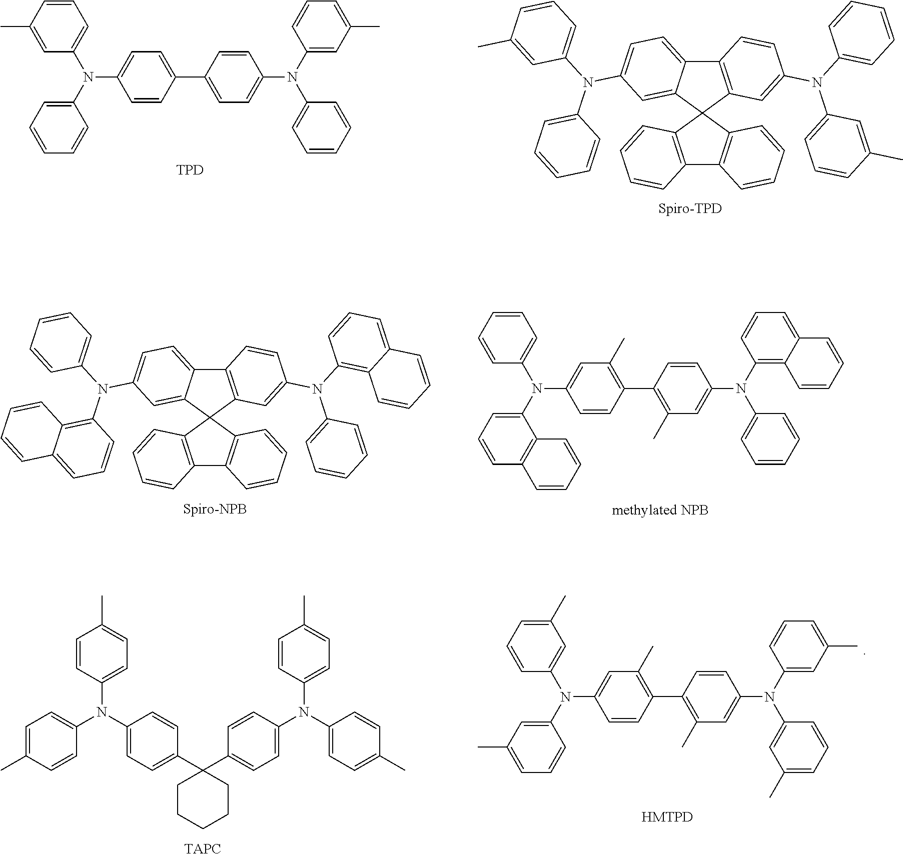

A thickness of the hole transport region may be in a range of about 50 Angstroms (Å) to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within the ranges described above, satisfactory hole transporting characteristics may be obtained without a substantial increase in driving voltage.

The emission auxiliary layer may increase light emission efficiency by compensating for an optical resonance distance according to the wavelength of light emitted by the emission layer, and the electron blocking layer may block the leakage of electrons from the emission layer to the hole transport region. Materials that may be included in the hole transport region may be included in the emission auxiliary layer and the electron blocking layer.

p-Dopant

In one or more embodiments, the hole transport region may further include, in addition to one or more of the materials described above, a charge-generation material for the improvement of conductive properties. The charge-generation material may be uniformly (e.g., substantially uniformly) or non-uniformly dispersed in the hole transport region (e.g., in the form of a single layer including (e.g., consisting of) a charge-generation material).

The charge-generation material may be, for example, a p-dopant.

In one or more embodiments, the p-dopant may have a LUMO energy level of −3.5 eV or less.

In one or more embodiments, the p-dopant may include a quinone derivative, a cyano group-containing compound, a compound including element EL1 and element EL2, or any combination thereof.

Non-limiting examples of the quinone derivative may include tetracyanoquinodimethane (TCNQ), 2,3,5,6-tetrafluoro-7,7,8,8-tetracyanoquinodimethane (F₄-TCNQ), and/or the like.

Non-limiting examples of the cyano group-containing compound may include dipyrazino[2,3-f: 2′,3′-h] quinoxaline-2,3,6,7,10,11-hexacarbonitrile (HAT-CN), a compound represented by Formula 221, and/or the like:

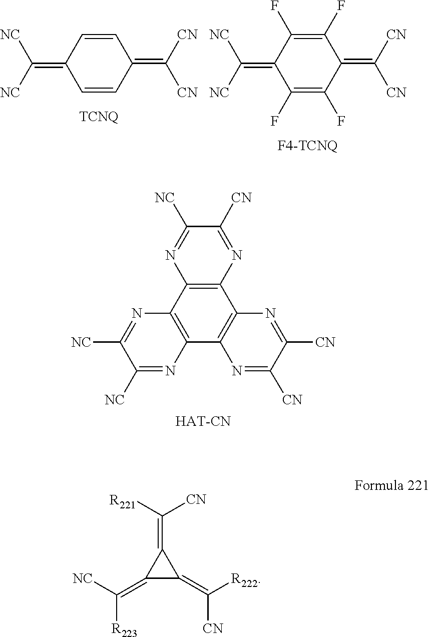

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Non-limiting examples of the metal may include: an alkali metal (e.g., lithium (Li), sodium (Na), potassium (K), rubidium (Rb), cesium (Cs), and/or the like); an alkaline earth metal (e.g., beryllium (Be), magnesium (Mg), calcium (Ca), strontium (Sr), barium (Ba), and/or the like); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (e.g., zinc (Zn), indium (In), tin (Sn), and/or the like); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and/or the like.

Non-limiting examples of the metalloid may include silicon (Si), antimony (Sb), tellurium (Te), and/or the like.

Non-limiting examples of the non-metal may include oxygen (O), a halogen (e.g., F, Cl, Br, I, and/or the like), and/or the like.

Non-limiting examples of the compound including element EL1 and element EL2 may include a metal oxide, a metal halide (e.g., a metal fluoride, a metal chloride, a metal bromide, a metal iodide, and/or the like), a metalloid halide (e.g., a metalloid fluoride, a metalloid chloride, a metalloid bromide, a metalloid iodide, and/or the like), a metal telluride, or any combination thereof.

Non-limiting examples of the metal oxide may include a tungsten oxide (e.g., WO, W₂O₃, WO₂, WO₃, W₂O₅, and/or the like), a vanadium oxide (e.g., VO, V₂O₃, VO₂, V₂O₅, and/or the like), a molybdenum oxide (e.g., MoO, Mo₂O₃, MoO₂, MoO₃, Mo₂O₅, and/or the like), a rhenium oxide (e.g., ReO₃, and/or the like), and/or the like.

Non-limiting examples of the metal halide may include an alkali metal halide, an alkaline earth metal halide, a transition metal halide, a post-transition metal halide, a lanthanide metal halide, and/or the like.

Non-limiting examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Non-limiting examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and/or the like.

Non-limiting examples of the transition metal halide may include a titanium halide (e.g., TiF₄, TiCl₄, TiBr₄, TiI₄, and/or the like), a zirconium halide (e.g., ZrF₄, ZrCl₄, ZrBr₄, ZrI₄, and/or the like), a hafnium halide (e.g., HfF₄, HfCl₄, HfBr₄, HfI₄, and/or the like), a vanadium halide (e.g., VF₃, VCl₃, VBr₃, VI₃, and/or the like), a niobium halide (e.g., NbF₃, NbCl₃, NbBr₃, NbI₃, and/or the like), a tantalum halide (e.g., TaF₃, TaCl₃, TaBr₃, TaI₃, and/or the like), a chromium halide (e.g., CrF₃, CrCl₃, CrBr₃, CrI₃, and/or the like), a molybdenum halide (e.g., MoF₃, MoCl₃, MoBr₃, MoI₃, and/or the like), a tungsten halide (e.g., WF₃, WCl₃, WBr₃, WI₃, and/or the like), a manganese halide (e.g., MnF₂, MnCl₂, MnBr₂, MnI₂, and/or the like), a technetium halide (e.g., TcF₂, TcCl₂, TcBr₂, TcI₂, and/or the like), a rhenium halide (e.g., ReF₂, ReCl₂, ReBr₂, ReI₂, and/or the like), an iron (II) halide (e.g., FeF₂, FeCl₂, FeBr₂, FeI₂, and/or the like), a ruthenium halide (e.g., RuF₂, RuCl₂, RuBr₂, RuI₂, and/or the like), an osmium halide (e.g., OsF₂, OsCl₂, OsBr₂, OsI₂, and/or the like), a cobalt halide (e.g., CoF₂, CoCl₂, CoBr₂, CoI₂, and/or the like), a rhodium halide (e.g., RhF₂, RhCl₂, RhBr₂, RhI₂, and/or the like), an iridium halide (e.g., IrF₂, IrCl₂, IrBr₂, IrI₂, and/or the like), a nickel halide (e.g., NiF₂, NiCl₂, NiBr₂, NiI₂, and/or the like), a palladium halide (e.g., PdF₂, PdCl₂, PdBr₂, PdI₂, and/or the like), a platinum halide (e.g., PtF₂, PtCl₂, PtBr₂, PtI₂, and/or the like), a copper(I) halide (e.g., CuF, CuCl, CuBr, CuI, and/or the like), a silver halide (e.g., AgF, AgCl, AgBr, AgI, and/or the like), a gold halide (e.g., AuF, AuCl, AuBr, AuI, and/or the like), and/or the like.

Non-limiting examples of the post-transition metal halide may include a zinc halide (e.g., ZnF₂, ZnCl₂, ZnBr₂, ZnI₂, and/or the like), an indium halide (e.g., InI₃, and/or the like), a tin halide (e.g., SnI₂, and/or the like), and/or the like.

Non-limiting examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Non-limiting examples of the metalloid halide may include an antimony halide (e.g., SbCl₅, and/or the like) and/or the like.

Non-limiting examples of the metal telluride may include an alkali metal telluride (e.g., Li₂Te, Na₂Te, K₂Te, Rb₂Te, Cs₂Te, and/or the like), an alkaline earth metal telluride (e.g., BeTe, MgTe, CaTe, SrTe, BaTe, and/or the like), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), a post-transition metal telluride (e.g., ZnTe, and/or the like), a lanthanide metal telluride (e.g., LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer in Interlayer 130

When the light-emitting device 10 is a full-color light-emitting device, the emission layer may be patterned into a red emission layer, a green emission layer, and/or a blue emission layer, according to a subpixel. In one or more embodiments, the emission layer may have a stacked structure of two or more layers selected from among a red emission layer, a green emission layer, and a blue emission layer, in which the two or more layers contact each other or are separated from each other, to emit white light (e.g., combined white light). In one or more embodiments, the emission layer may include two or more materials selected from among a red light-emitting material, a green light-emitting material, and a blue light-emitting material, in which the two or more materials are mixed with each other in a single layer, to emit white light (e.g., combined white light).

The emission layer may include a host and a dopant. The dopant may include a phosphorescent dopant, a fluorescent dopant, or any combination thereof.

an amount of the dopant in the emission layer may be in a range of about 0.01 parts by weight to about 15 parts by weight based on 100 parts by weight of the host.

In one or more embodiments, the emission layer may include a quantum dot.

In one or more embodiments, the emission layer may include a delayed fluorescence material. The delayed fluorescence material may act as a host or a dopant in the emission layer.

A thickness of the emission layer may be in a range of about 100 Å to about 1,000 Å, for example, about 200 Å to about 600 Å. When the thickness of the emission layer is within the range described above, excellent or suitable luminescence characteristics may be obtained without a substantial increase in driving voltage.

### Host

In one or more embodiments, the host may include a compound represented by Formula 301:

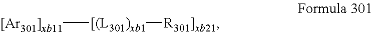

wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described with respect to Q₁.

In one or more embodiments, if (e.g., when) xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or any combination thereof:

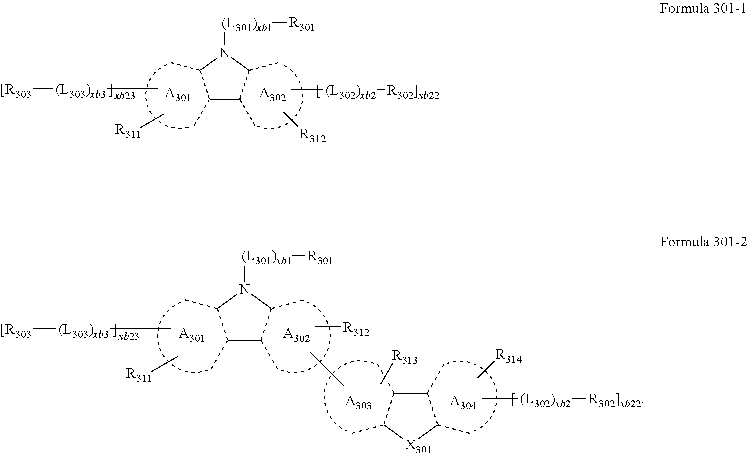

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ are each the same as described herein,
L₃₀₂ to L₃₀₄ may each independently be the same as described with respect to L₃₀₁,
xb2 to xb4 may each independently be the same as described with respect to xb1, and
R₃₀₂ to R₃₀₅ and R₃₁₁ to R₃₁₄ may each independently be the same as described with respect to R₃₀₁.

In one or more embodiments, the host may include an alkaline earth metal complex, a post-transition metal complex, or any combination thereof. For example, in some embodiments, the host may include a Be complex (e.g., Compound H55), a Mg complex, a Zn complex, or any combination thereof.

In one or more embodiments, the host may include: at least one of (e.g., selected from among) Compounds H1 to H128; 9,10-di(2-naphthyl)anthracene (ADN); 2-methyl-9,10-bis(naphthalen-2-yl)anthracene (MADN); 9,10-di-(2-naphthyl)-2-t-butyl-anthracene (TBADN); 4,4′-bis(N-carbazolyl)-1,1′-biphenyl (CBP); 1,3-di(9H-carbazol-9-yl)benzene (mCP); 1,3,5-tri(carbazol-9-yl)benzene (TCP); or any combination thereof:

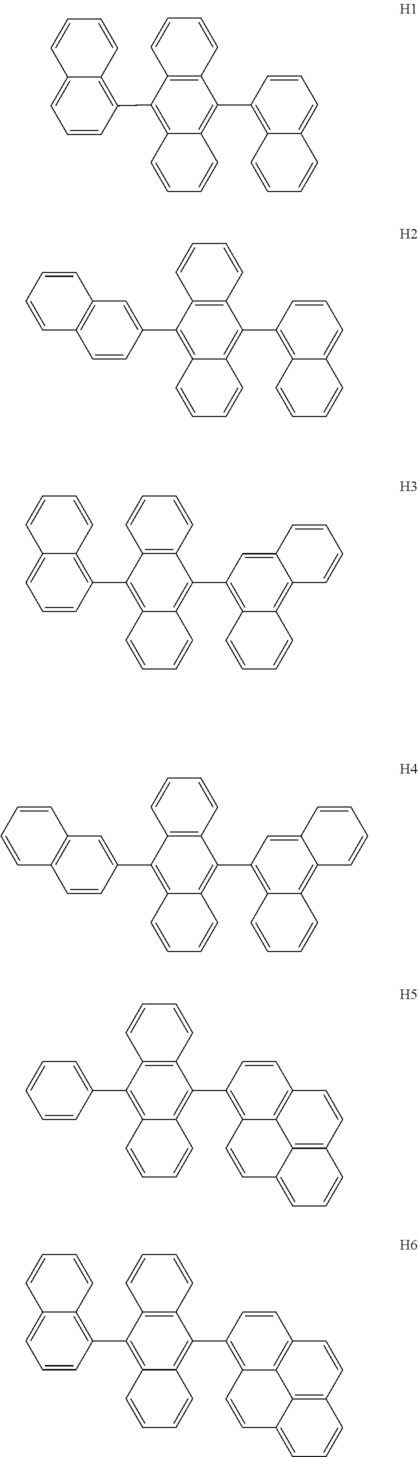

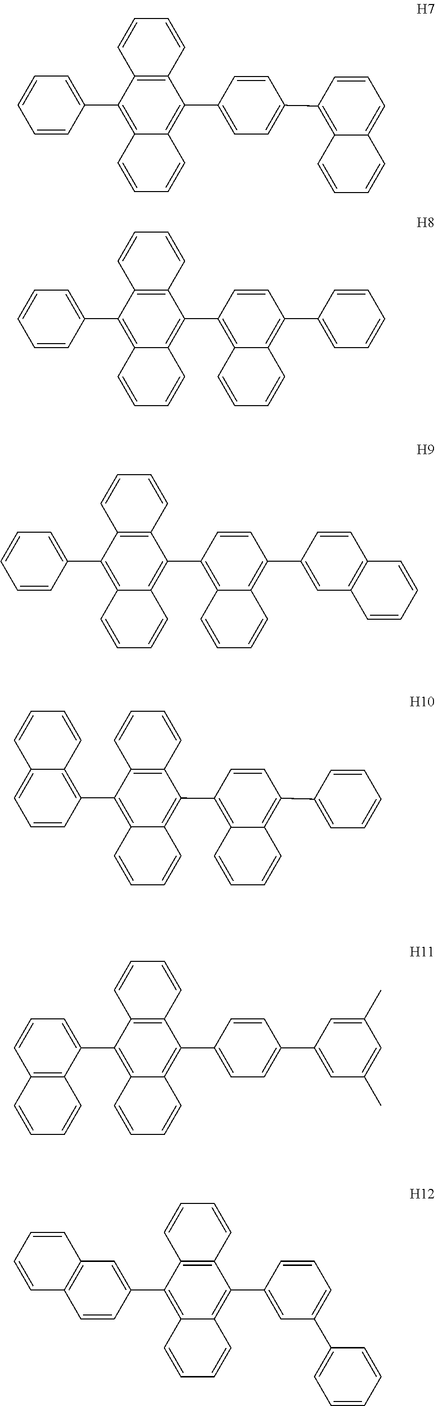

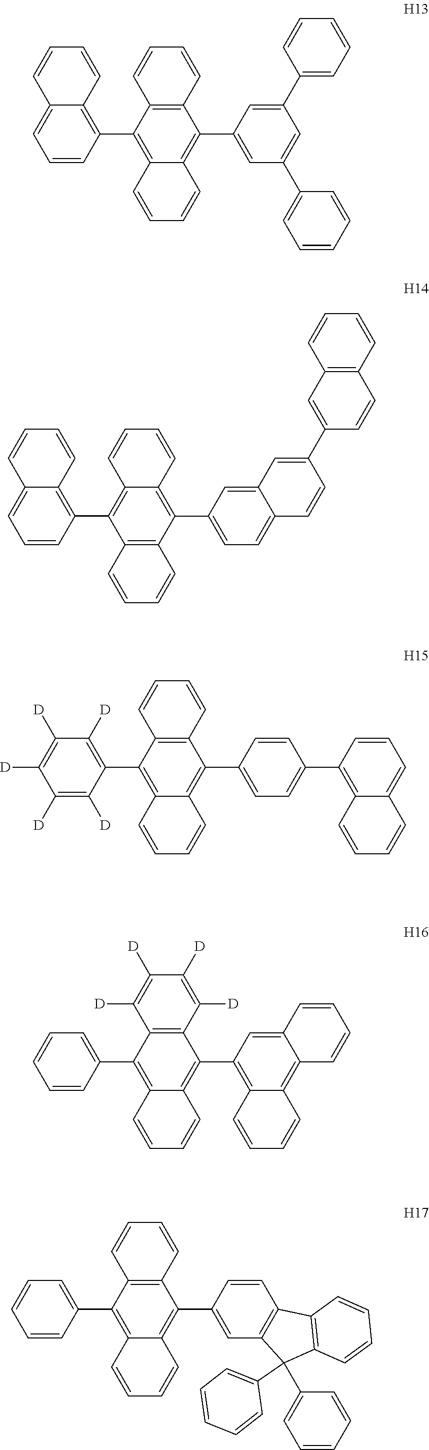

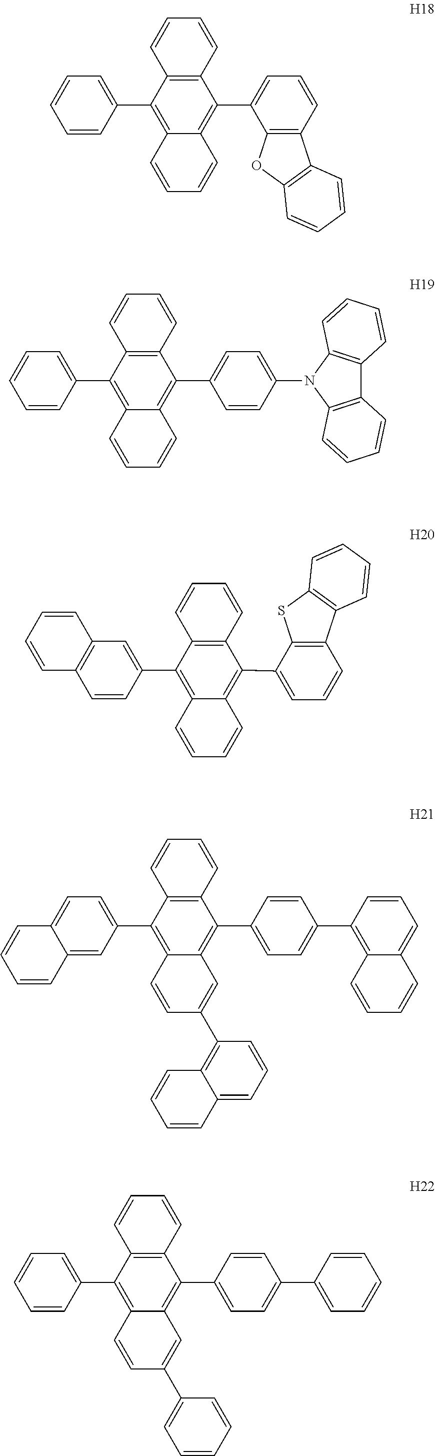

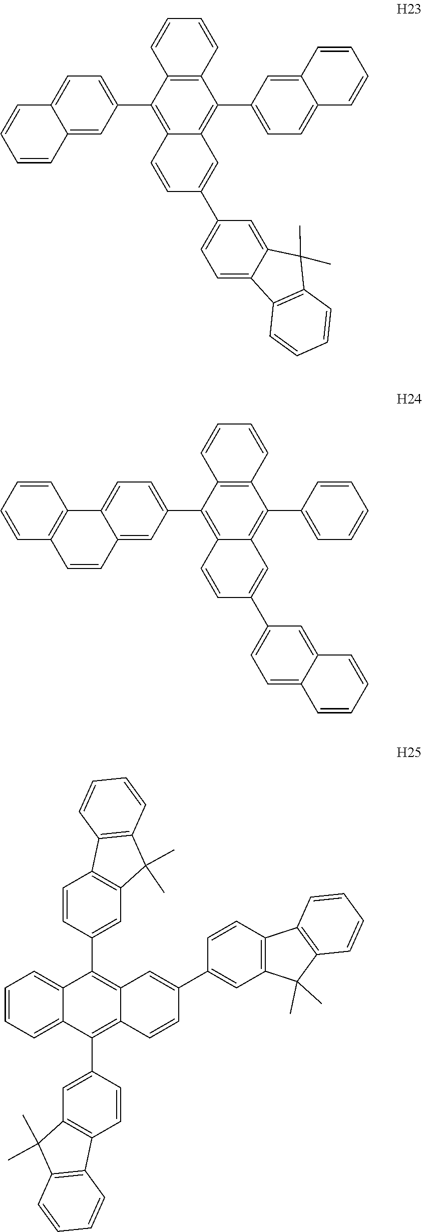

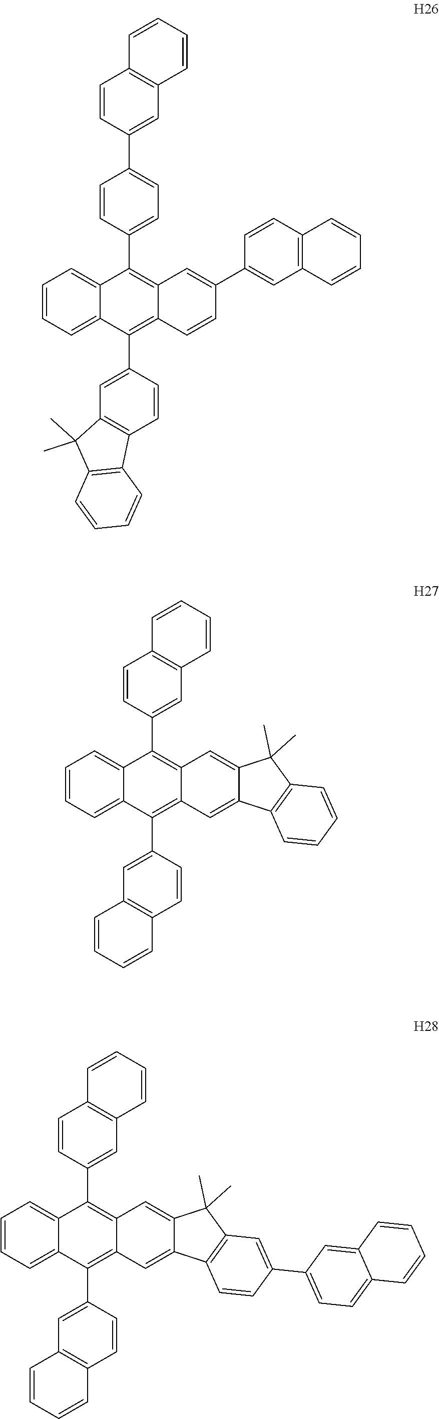

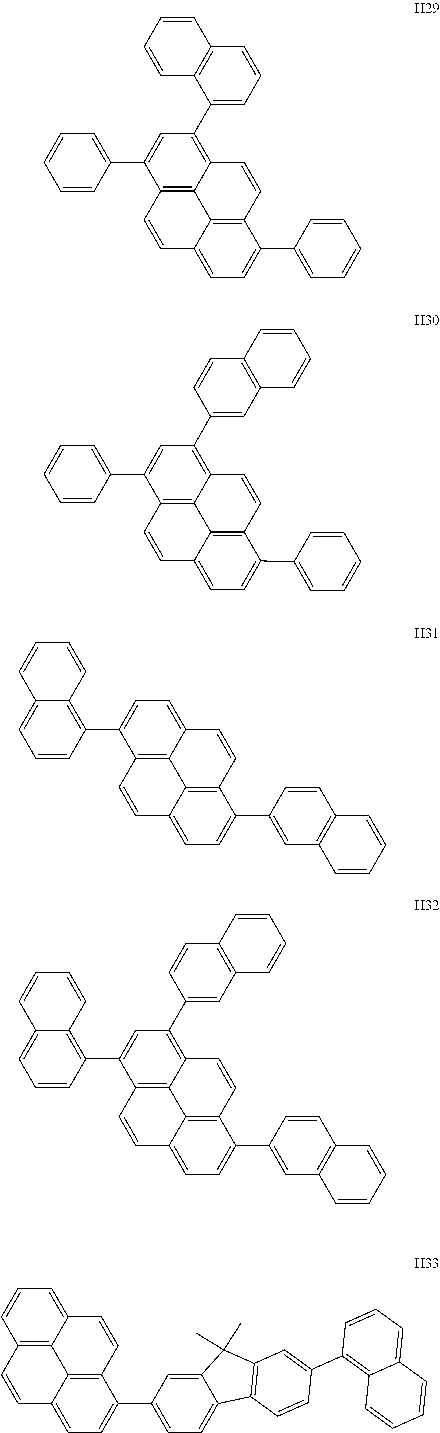

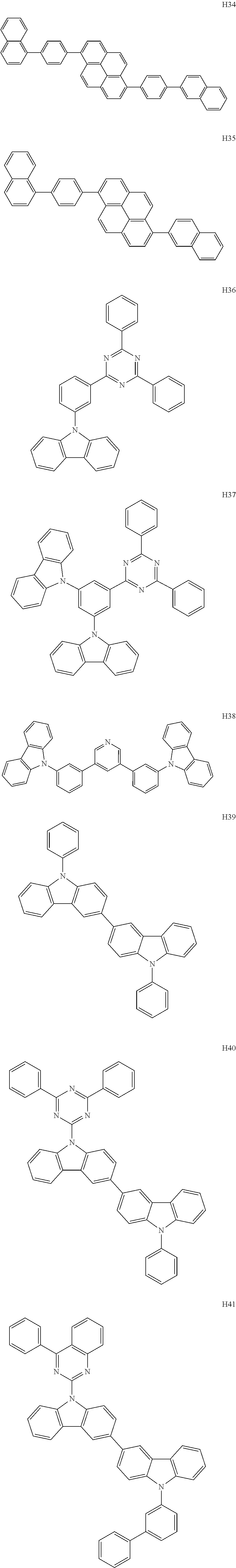

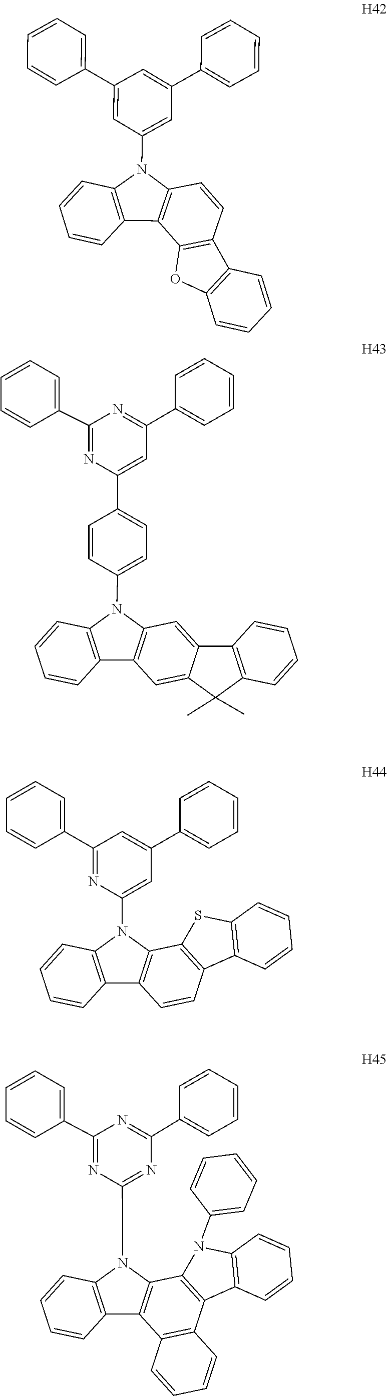

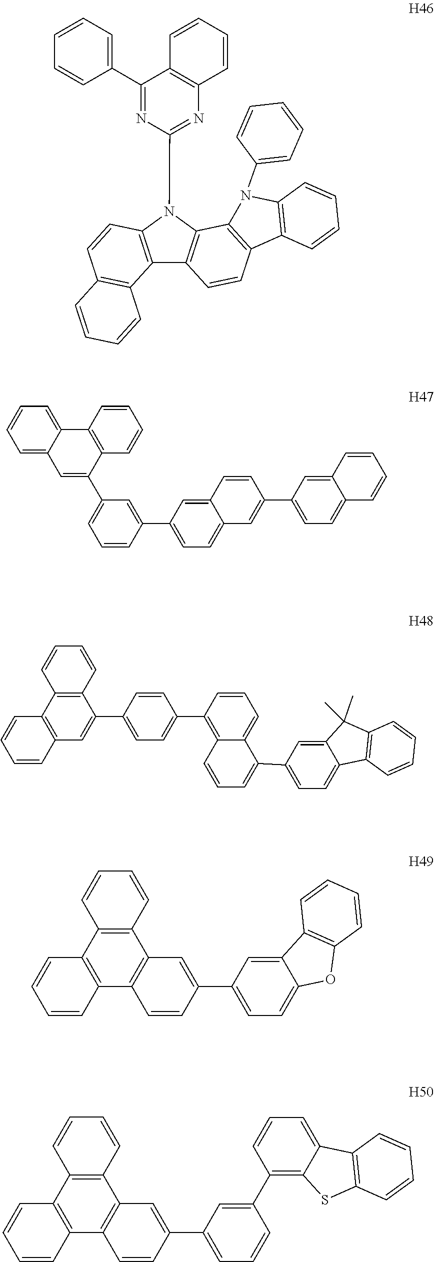

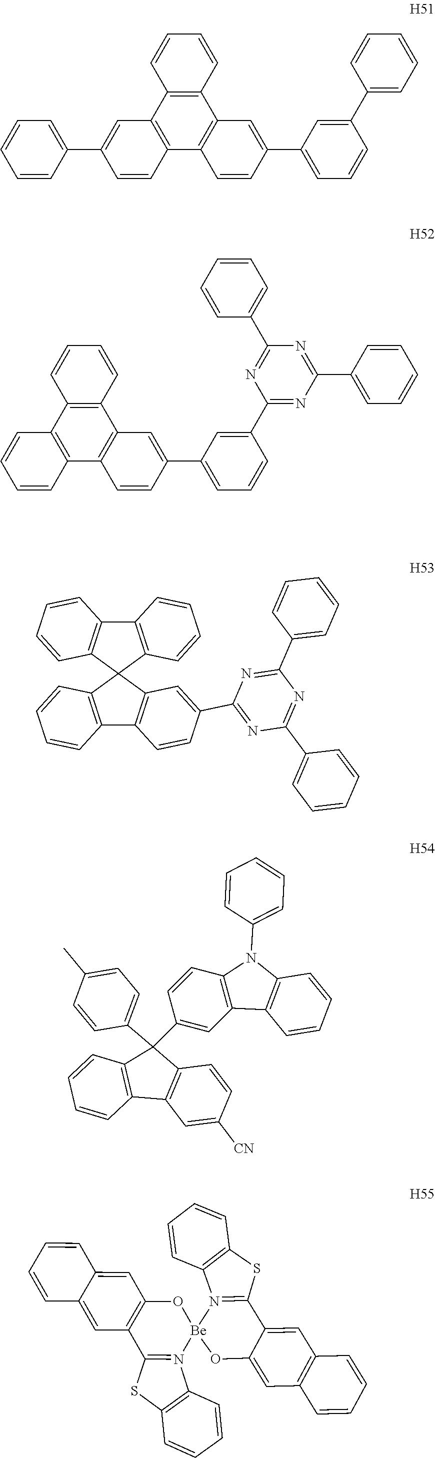

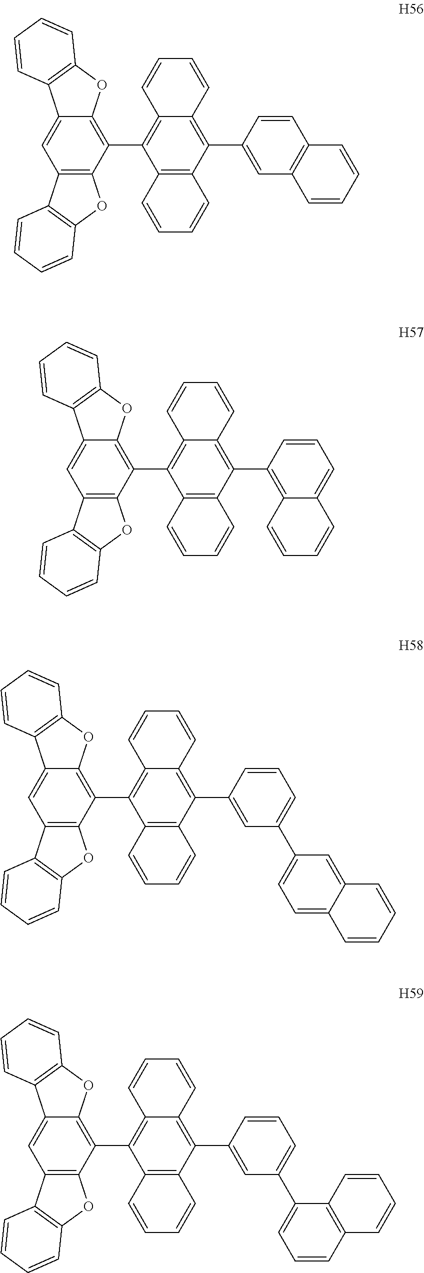

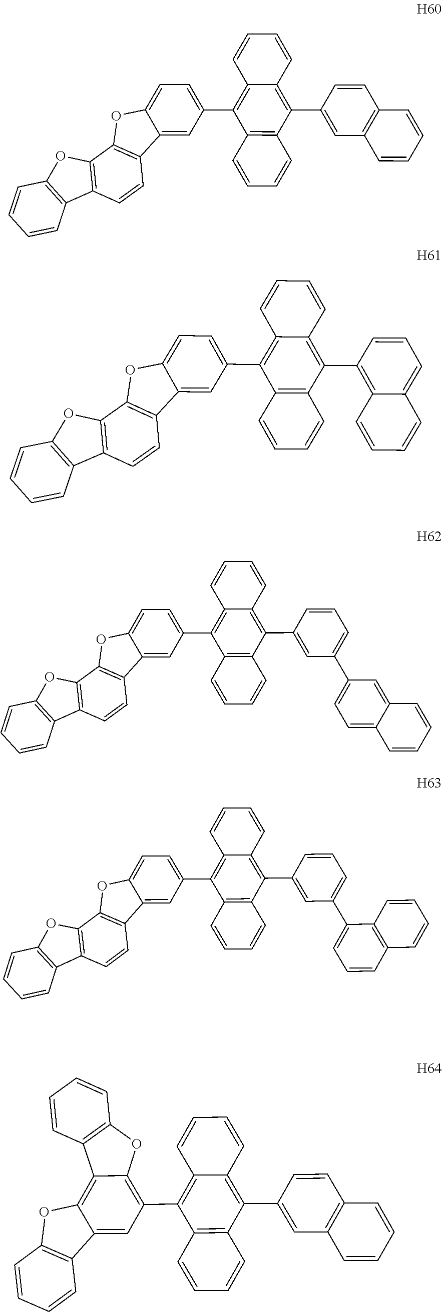 [SMILES: c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

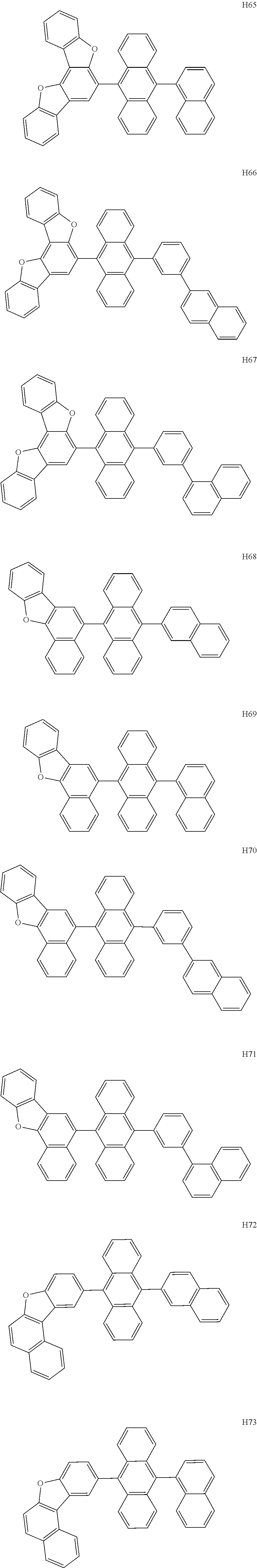

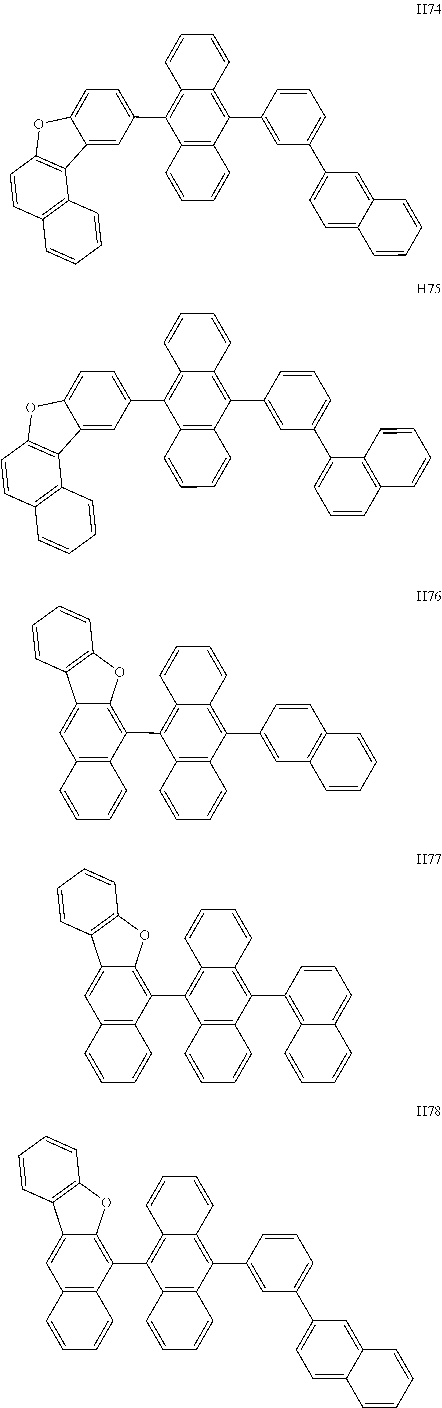 [SMILES: c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1]

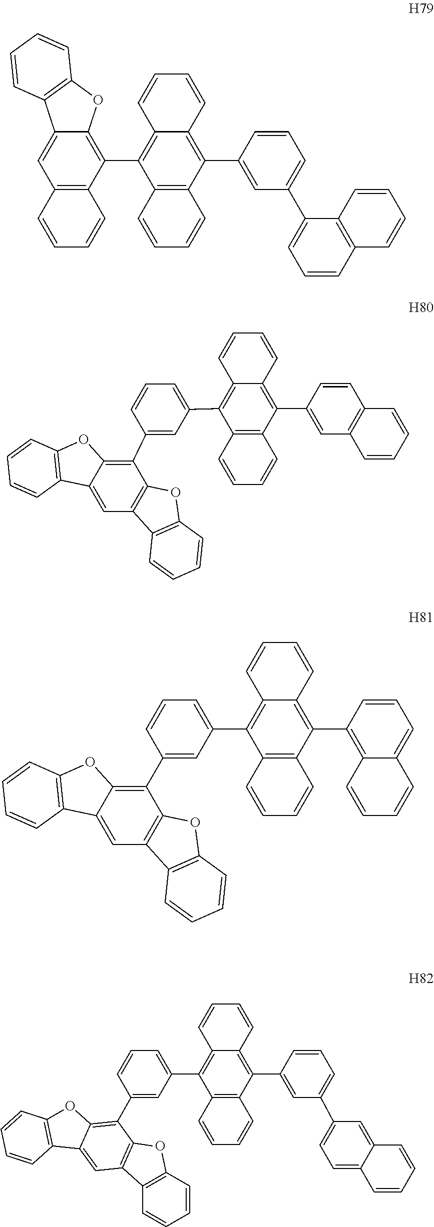 [SMILES: c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1]

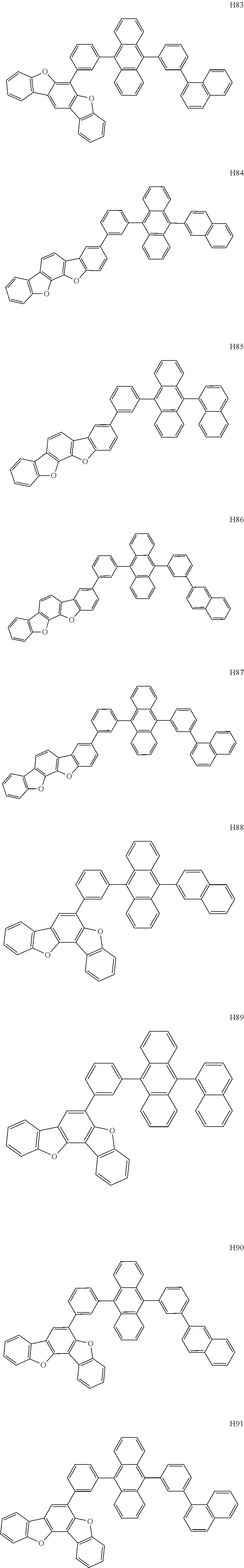

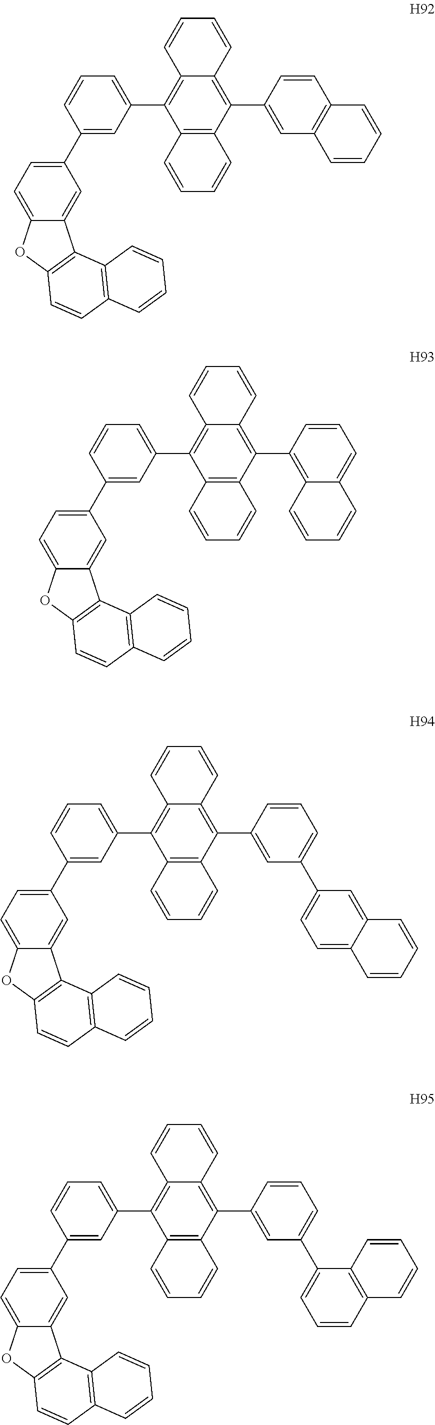 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1]

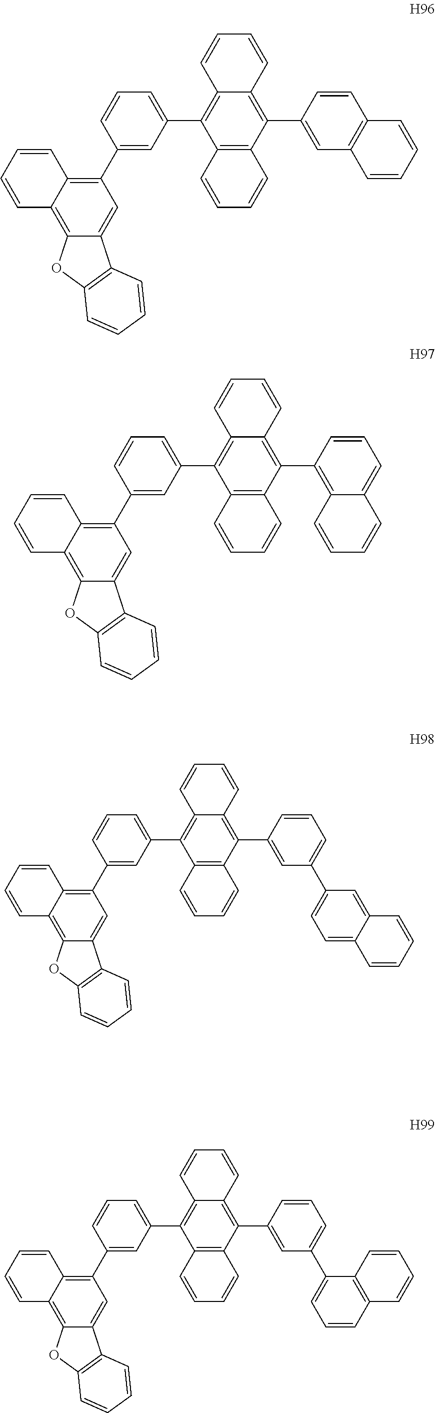 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

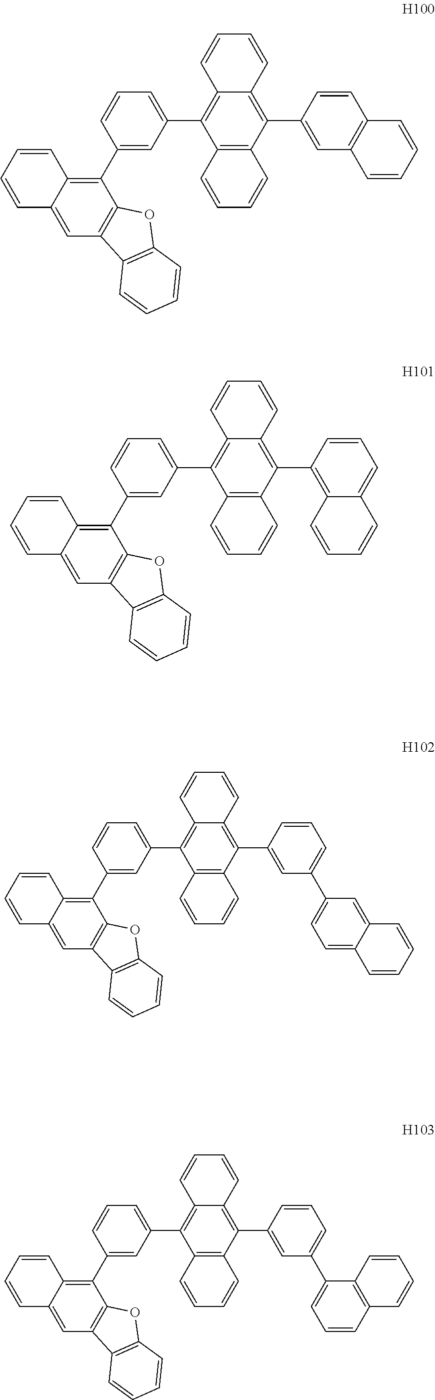 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

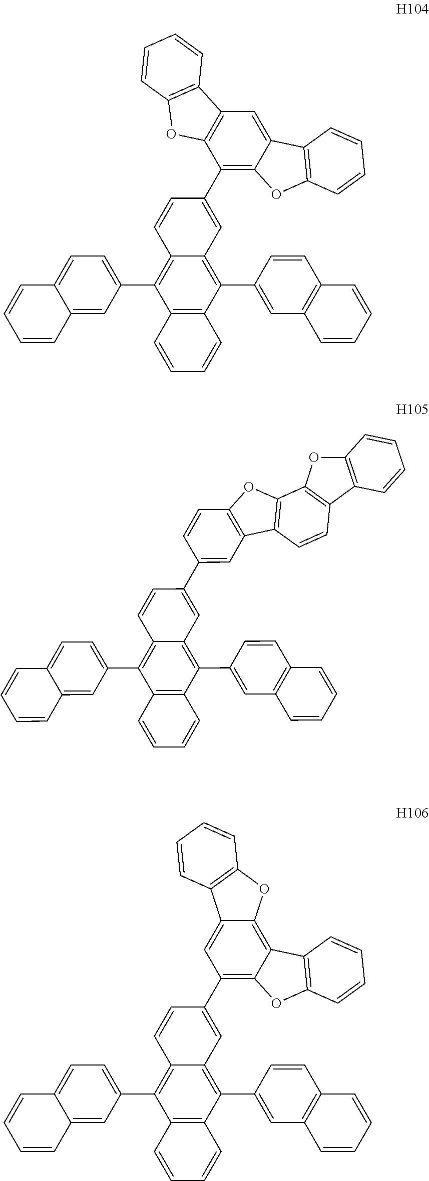 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

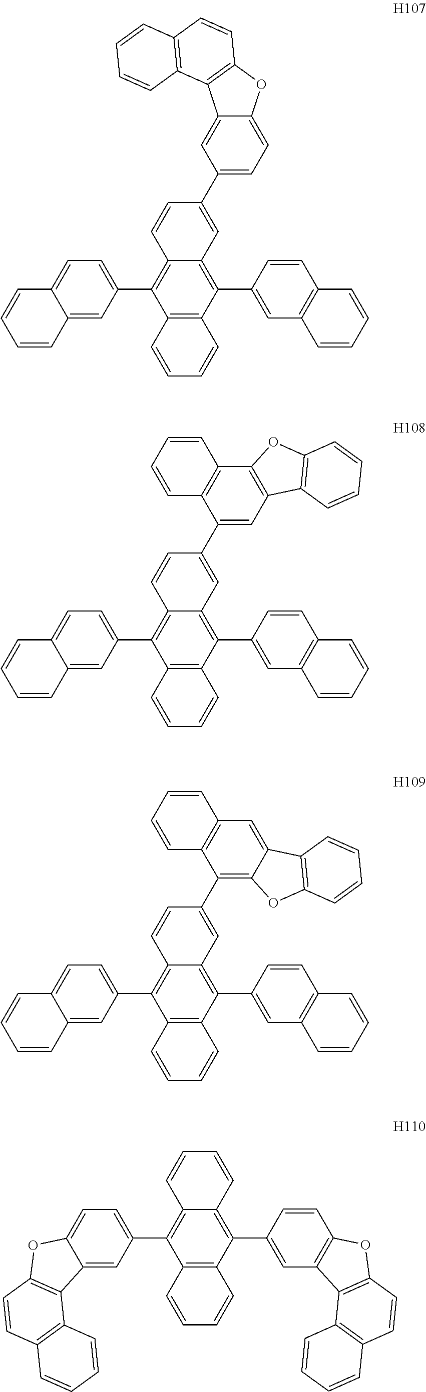 [SMILES: c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12]

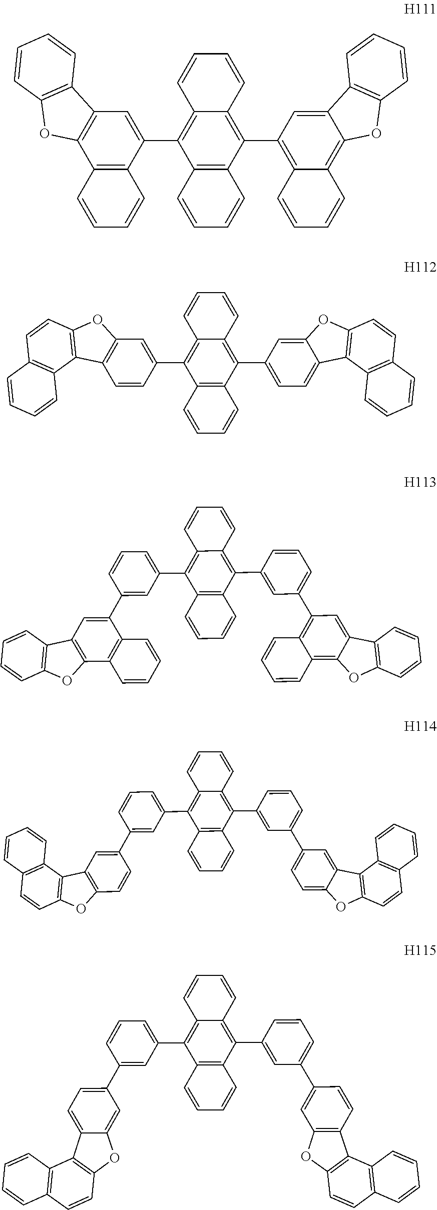 [SMILES: c1ccc2c(c1)oc1c3ccccc3c(-c3c4ccccc4c(-c4cc5c6ccccc6oc5c5ccccc45)c4ccccc34)cc21 ; c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1]

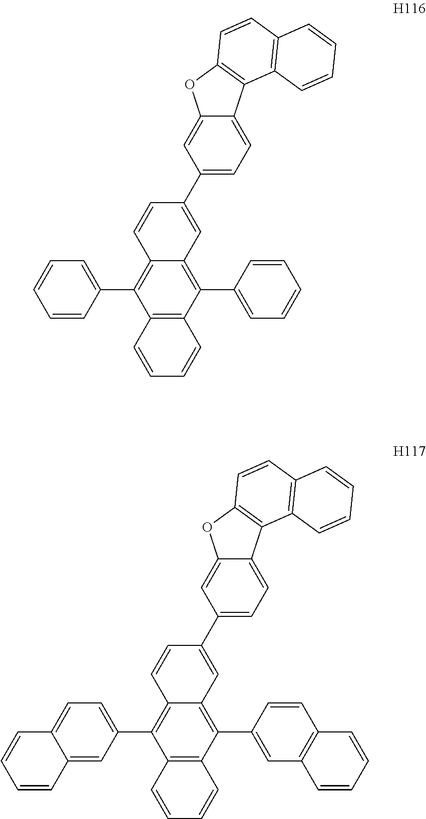 [SMILES: c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

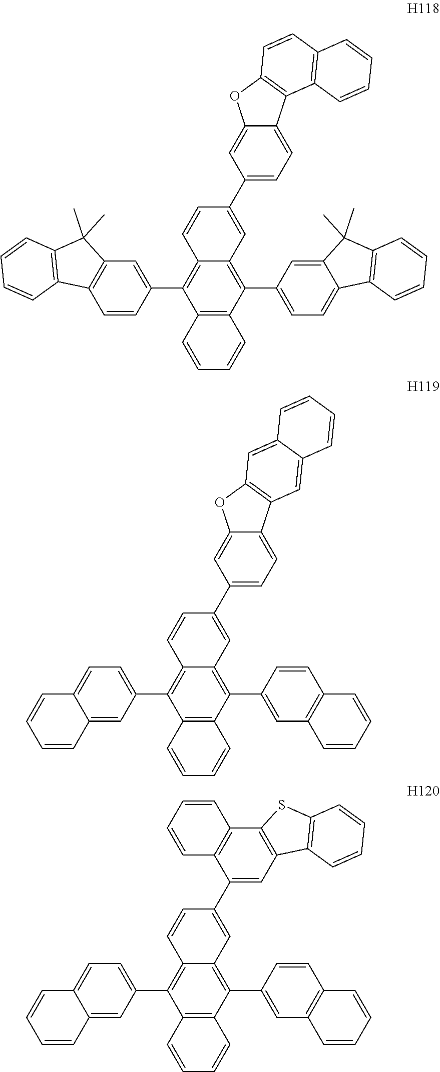

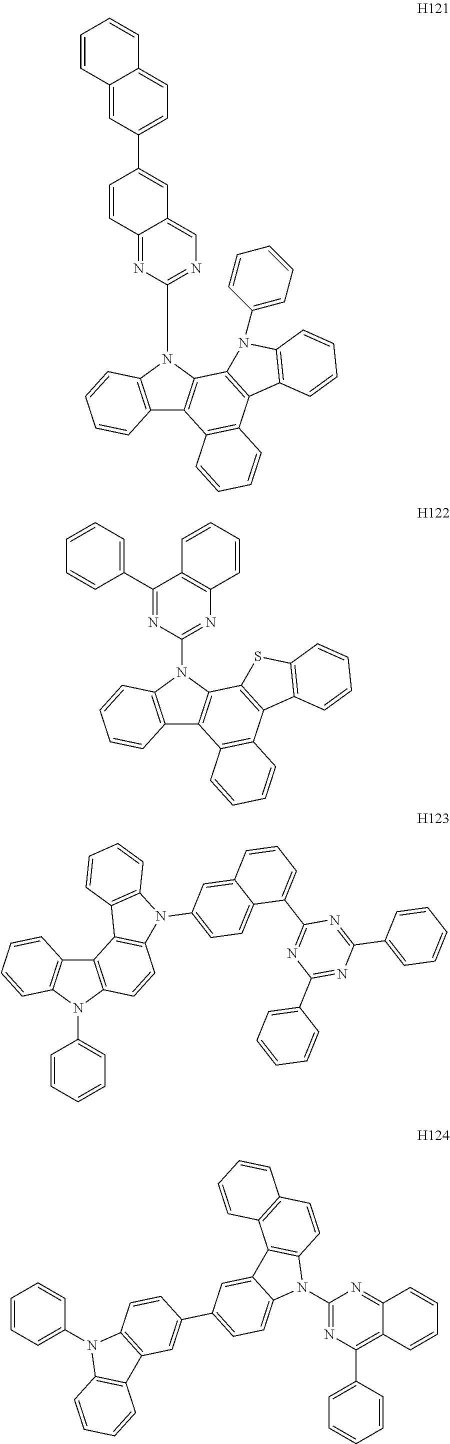

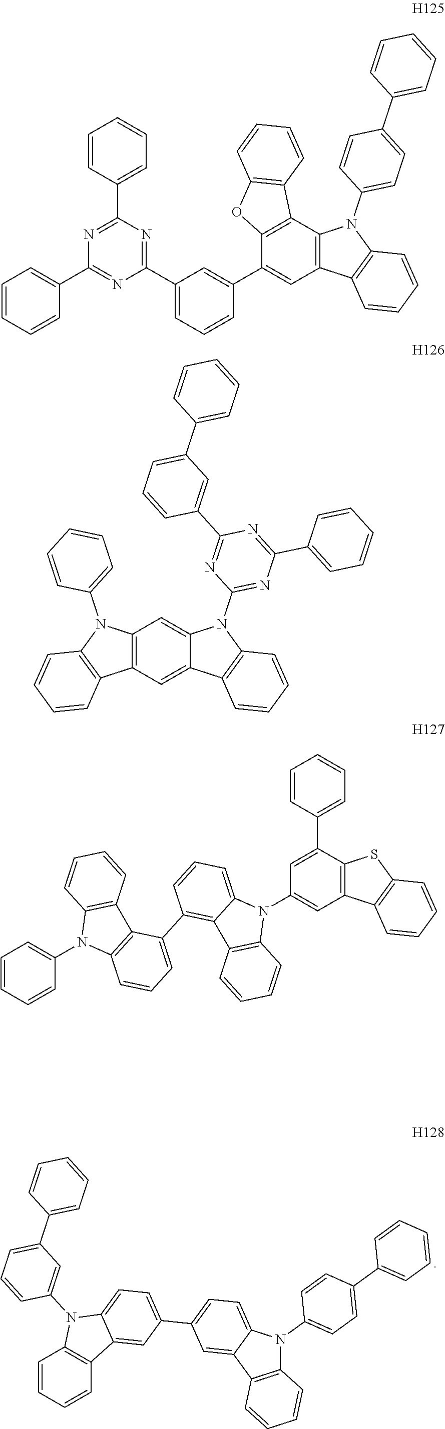

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In one or more embodiments, the phosphorescent dopant may include an organometallic compound represented by Formula 401:

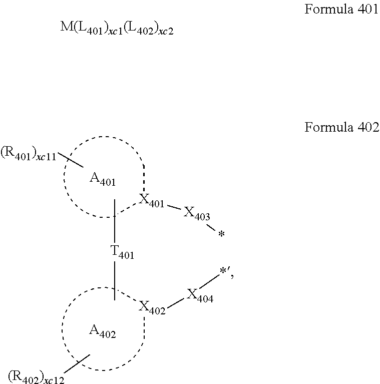

wherein, in Formulae 401 and 402,
M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, if (e.g., when) xc1 is 2 or more, two or more of L₄₀₁(s) may be substantially identical to or different from each other,
L₄₀₂ may be an organic ligand, and xc2 may be 0, 1, 2, 3, or 4, wherein, if (e.g., when) xc2 is 2 or more, two or more of L₄₀₂(s) may be substantially identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)=*′, or *═C═*′,
X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described with respect to Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described with respect to Q₁,
xc11 and xc12 may each independently be an integer from 0 to 10, and
* and *′ in Formula 402 each indicate a binding site to M in Formula 401.

In one or more embodiments, in Formula 402, i) X₄₀₁ may be nitrogen, and X₄₀₂ may be carbon, or ii) each of X₄₀₁ and X₄₀₂ may be nitrogen.

In one or more embodiments, if (e.g., when) xc1 in Formula 401 is 2 or more, two of ring A₄₀₁(s) among two or more of L₄₀₁(s) may optionally be linked to each other via T₄₀₂, which is a linking group, and/or two of ring A₄₀₂(s) among two or more of L₄₀₁(s) may optionally be linked to each other via T₄₀₃, which is a linking group (see Compounds PD1 to PD4 and PD7). T₄₀₂ and T₄₀₃ are each the same as described in connection with T₄₀₁.

In Formula 401, L₄₀₂ may be an organic ligand. For example, L₄₀₂ may include a halogen, a diketone group (e.g., an acetylacetonate group), a carboxylic acid group (e.g., a picolinate group), —C(═O), an isonitrile group, a-CN group, a phosphorus-containing group (e.g., a phosphine group, a phosphite group, and/or the like), or any combination thereof.

The phosphorescent dopant may include, for example, at least one of (e.g., may be any one selected from among) Compounds PD1 to PD39, or any combination thereof:

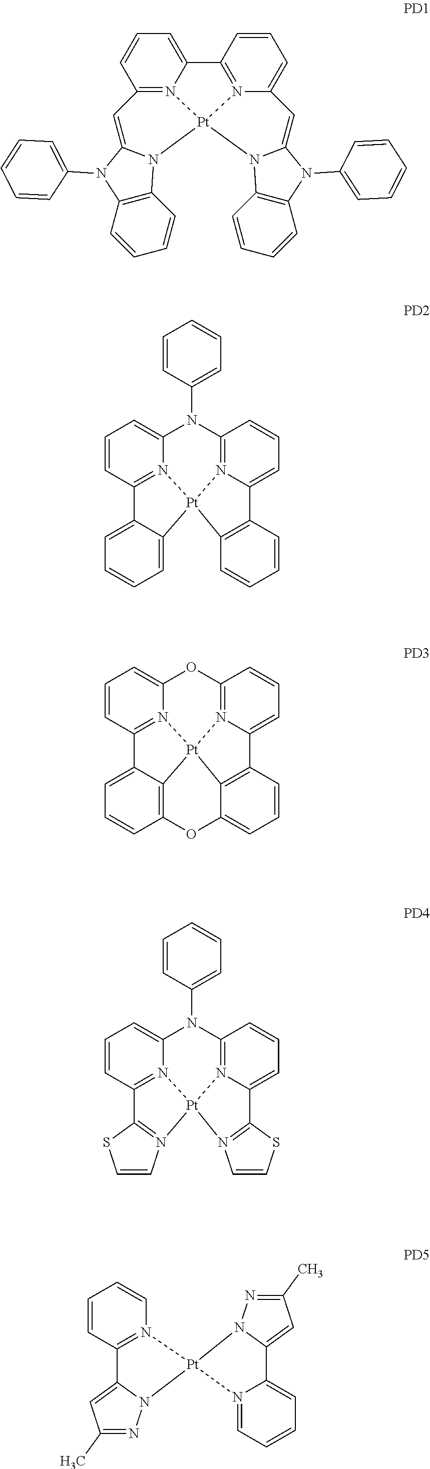

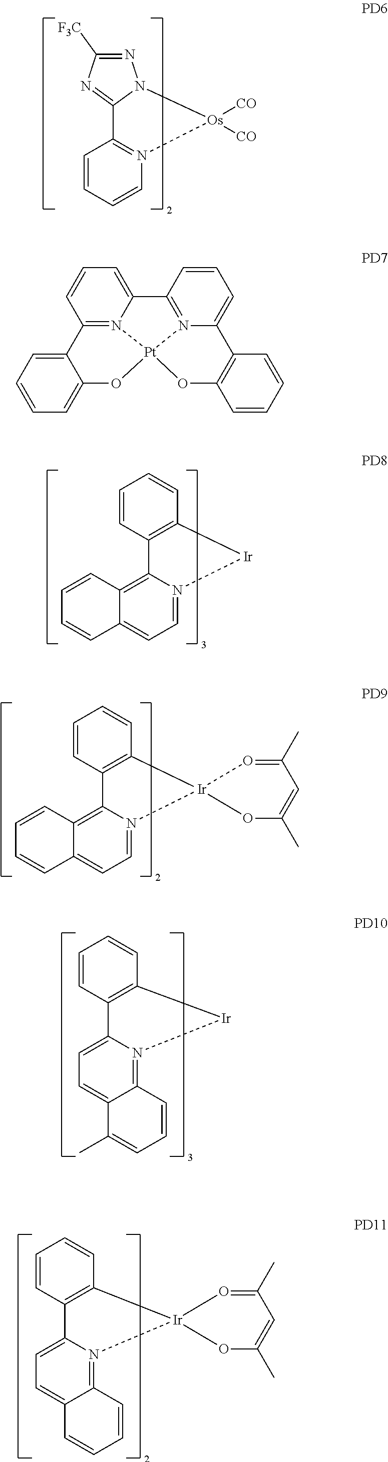

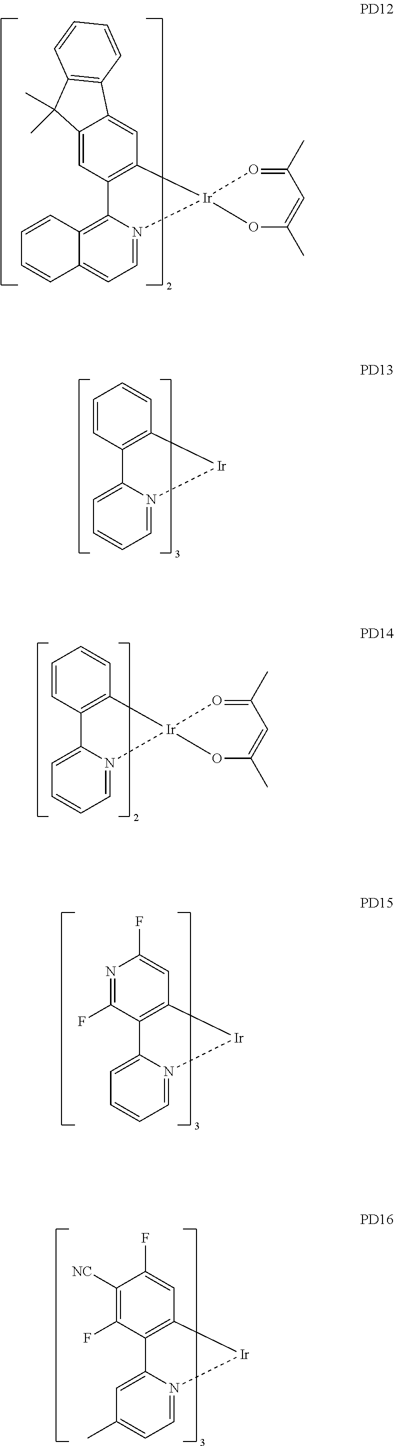

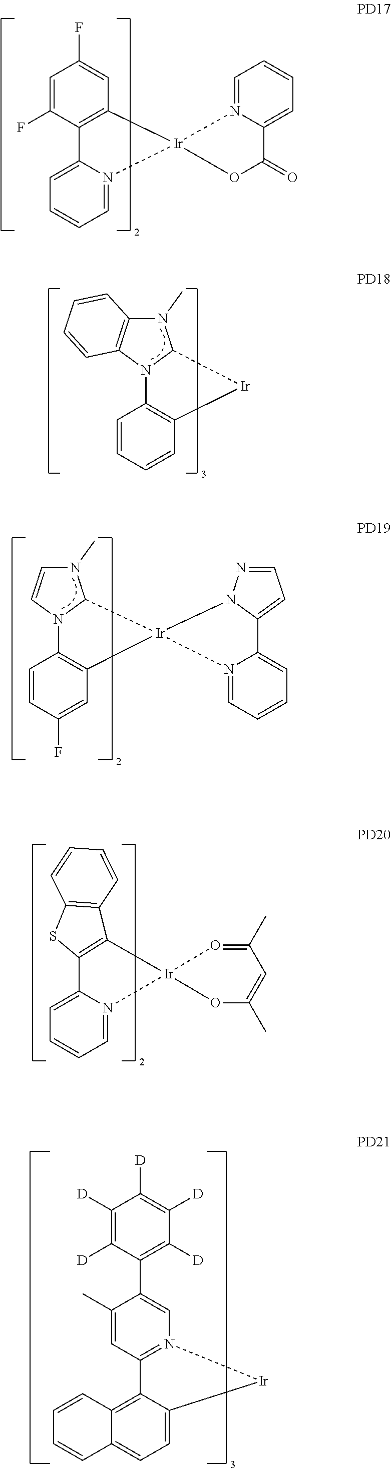

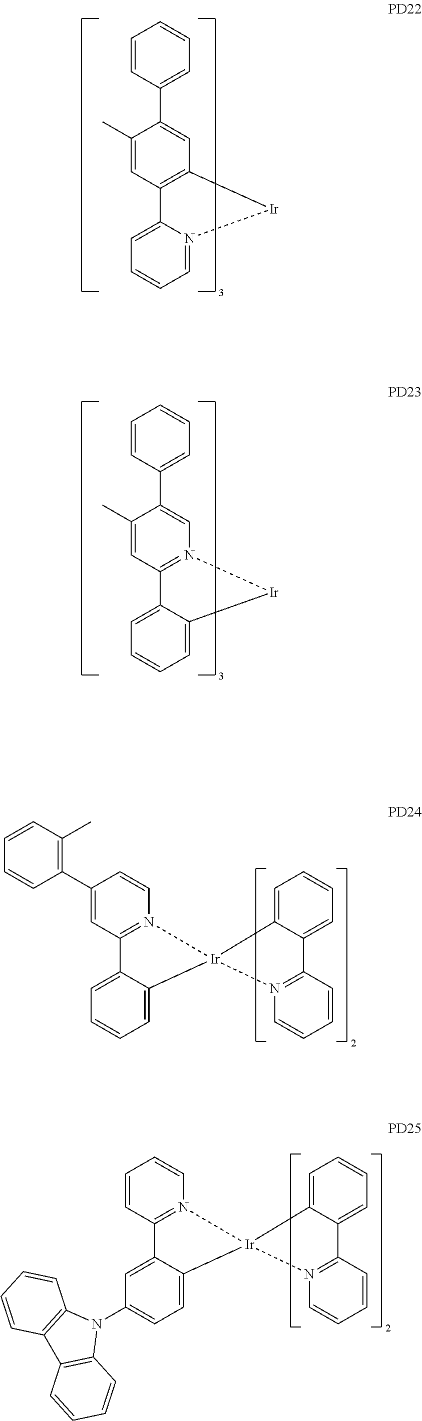

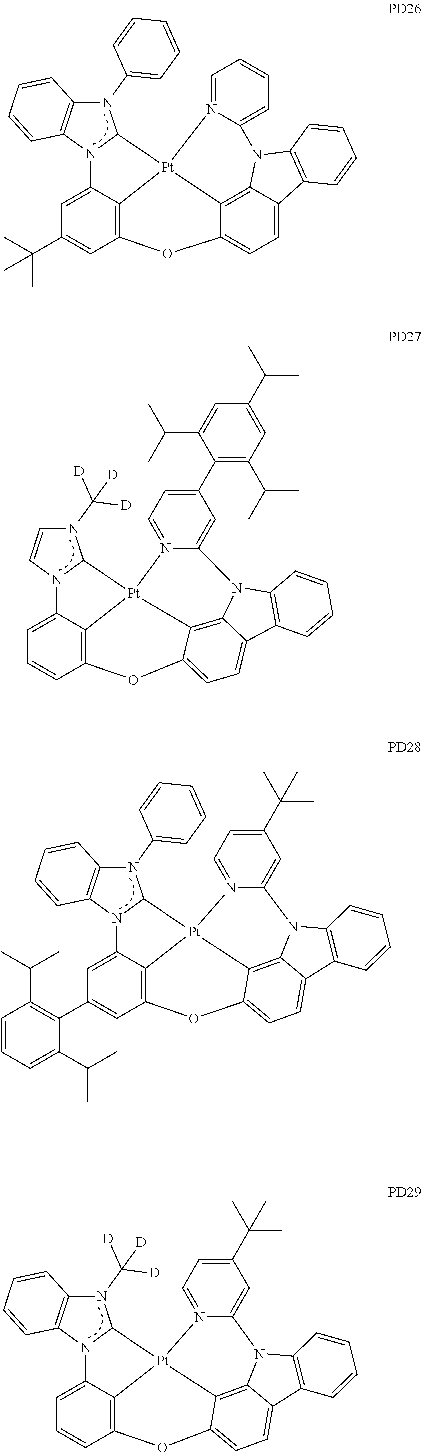

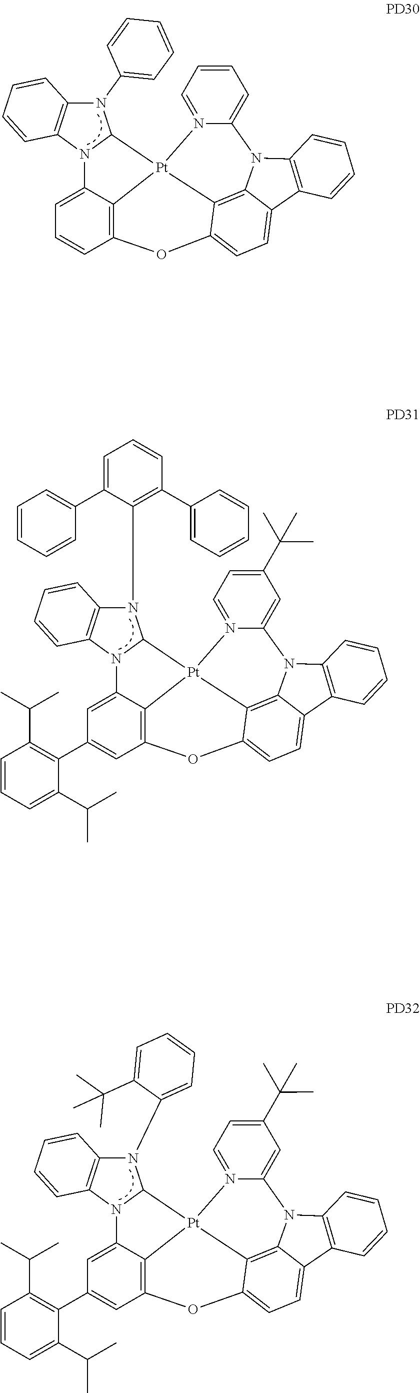

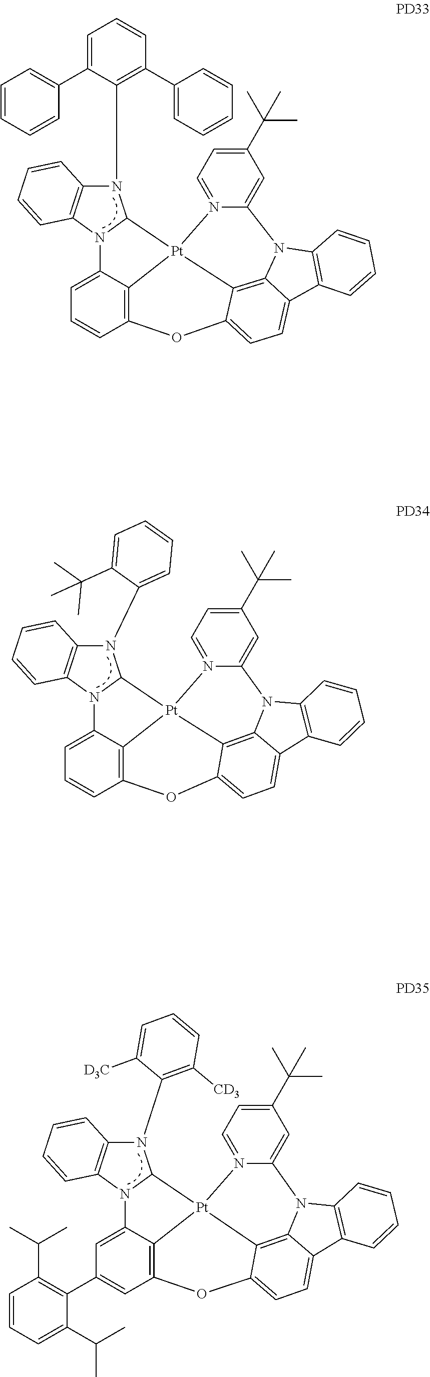

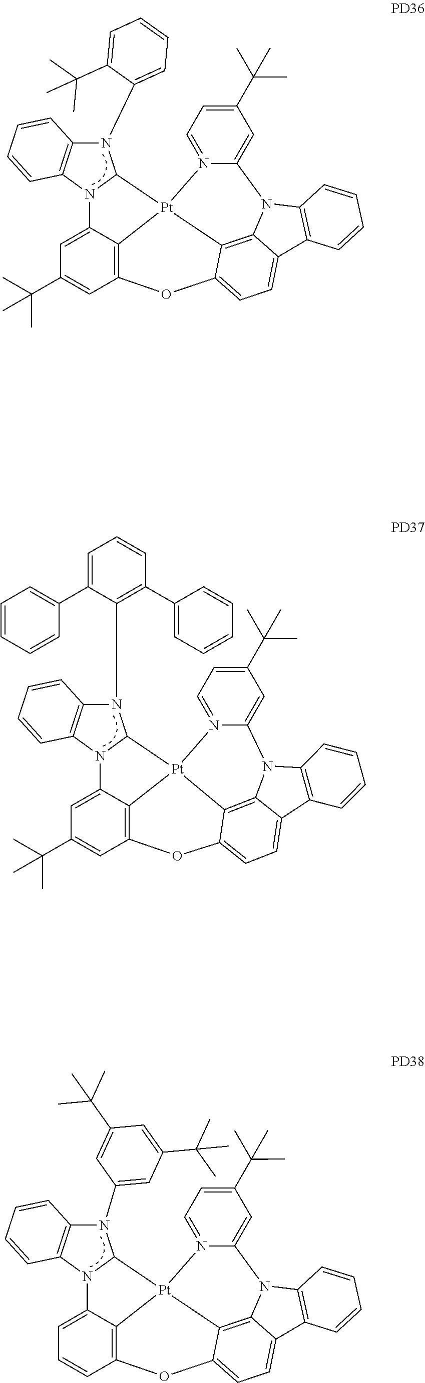

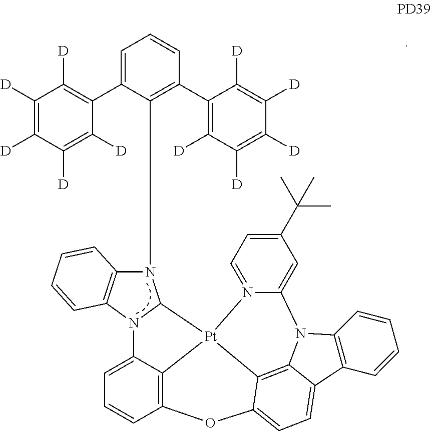

### Fluorescent Dopant

In one or more embodiments, the fluorescent dopant may include an amine group-containing compound, a styryl group-containing compound, or any combination thereof.

In one or more embodiments, the fluorescent dopant may include a compound represented by Formula 501.

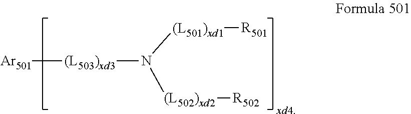

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In one or more embodiments, Ar₅₀₁ in Formula 501 may be a condensed cyclic group (e.g., an anthracene group, a chrysene group, a pyrene group, and/or the like) in which three or more monocyclic groups are condensed with each other.

In one or more embodiments, xd4 in Formula 501 may be 2.

In one or more embodiments, the fluorescent dopant may include: at least one of (e.g., may be any one selected from among) Compounds FD1 to FD37; 4,4′-bis(2,2-diphenylvinyl)-1,1′-biphenyl (DPVBi); 4,4′-bis[4-(N,N-diphenylamino)styryl]biphenyl (DPAVBi); or any combination thereof:

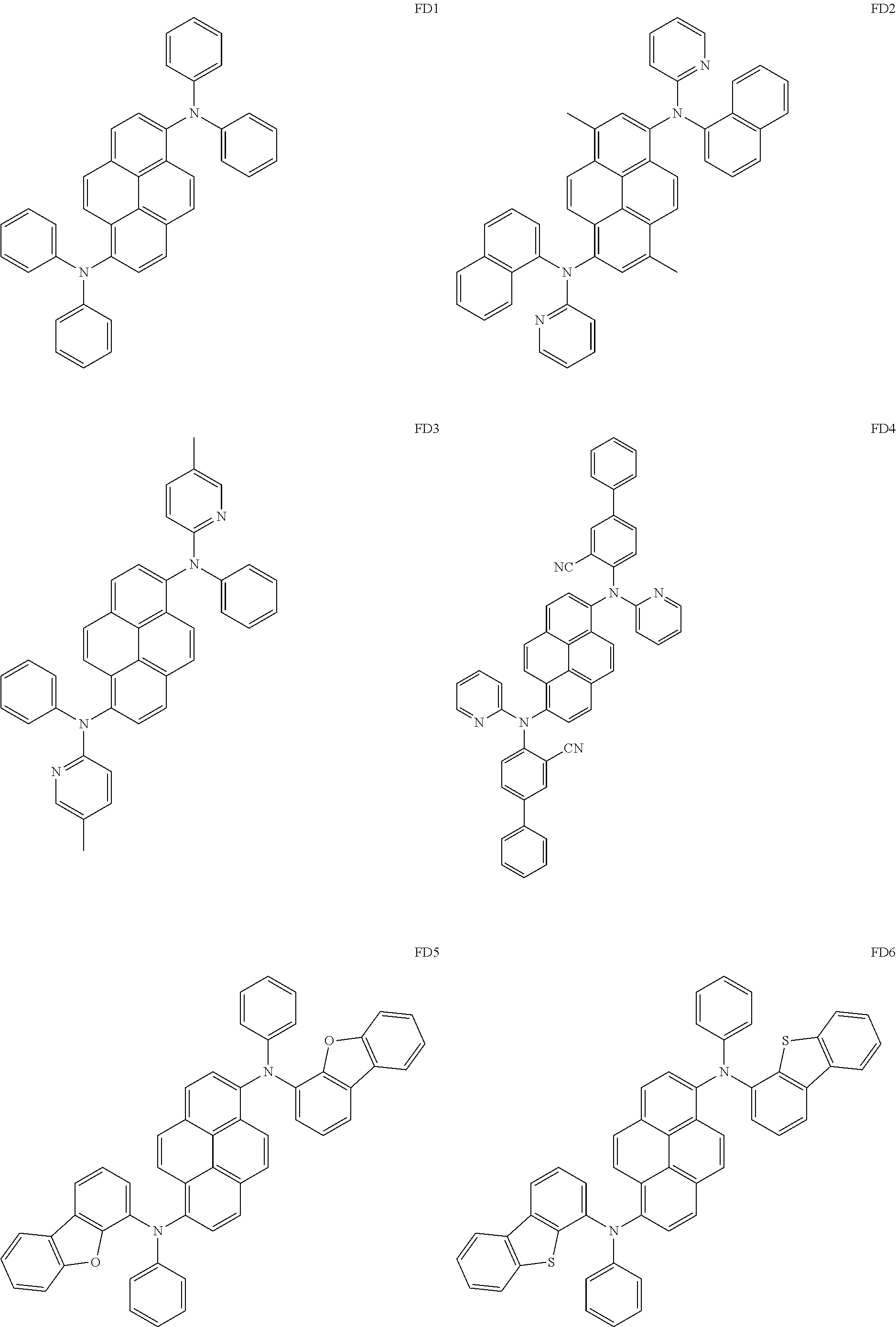

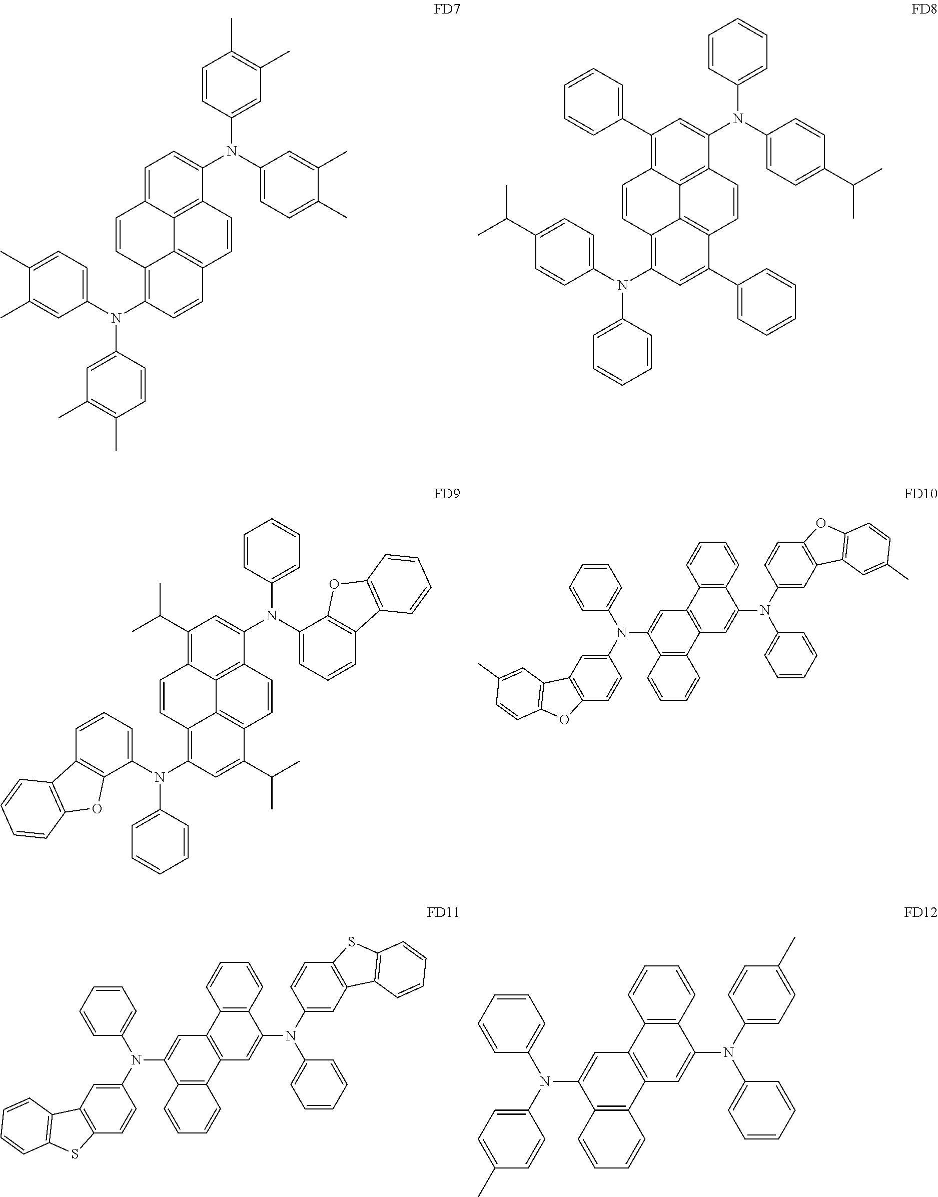

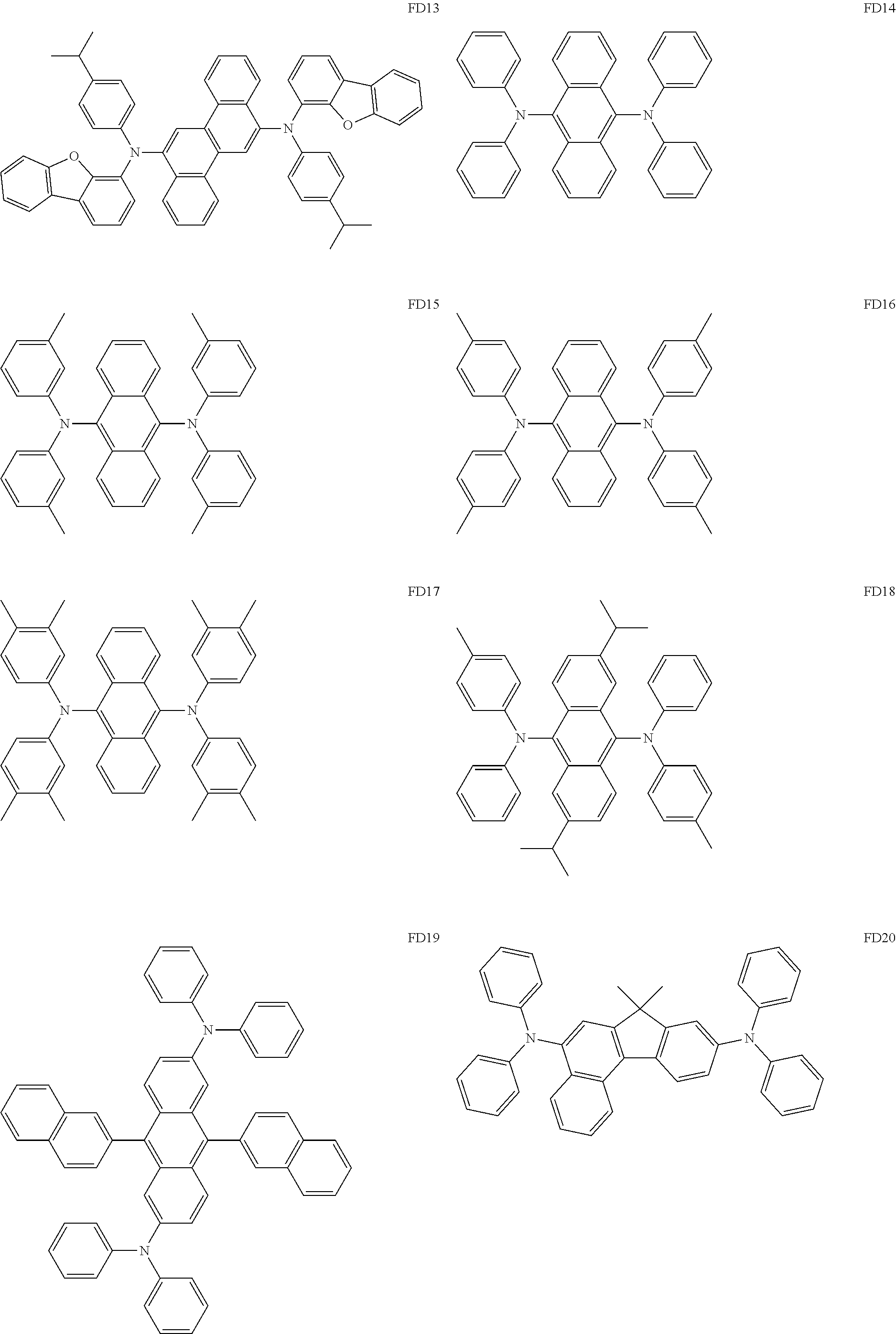

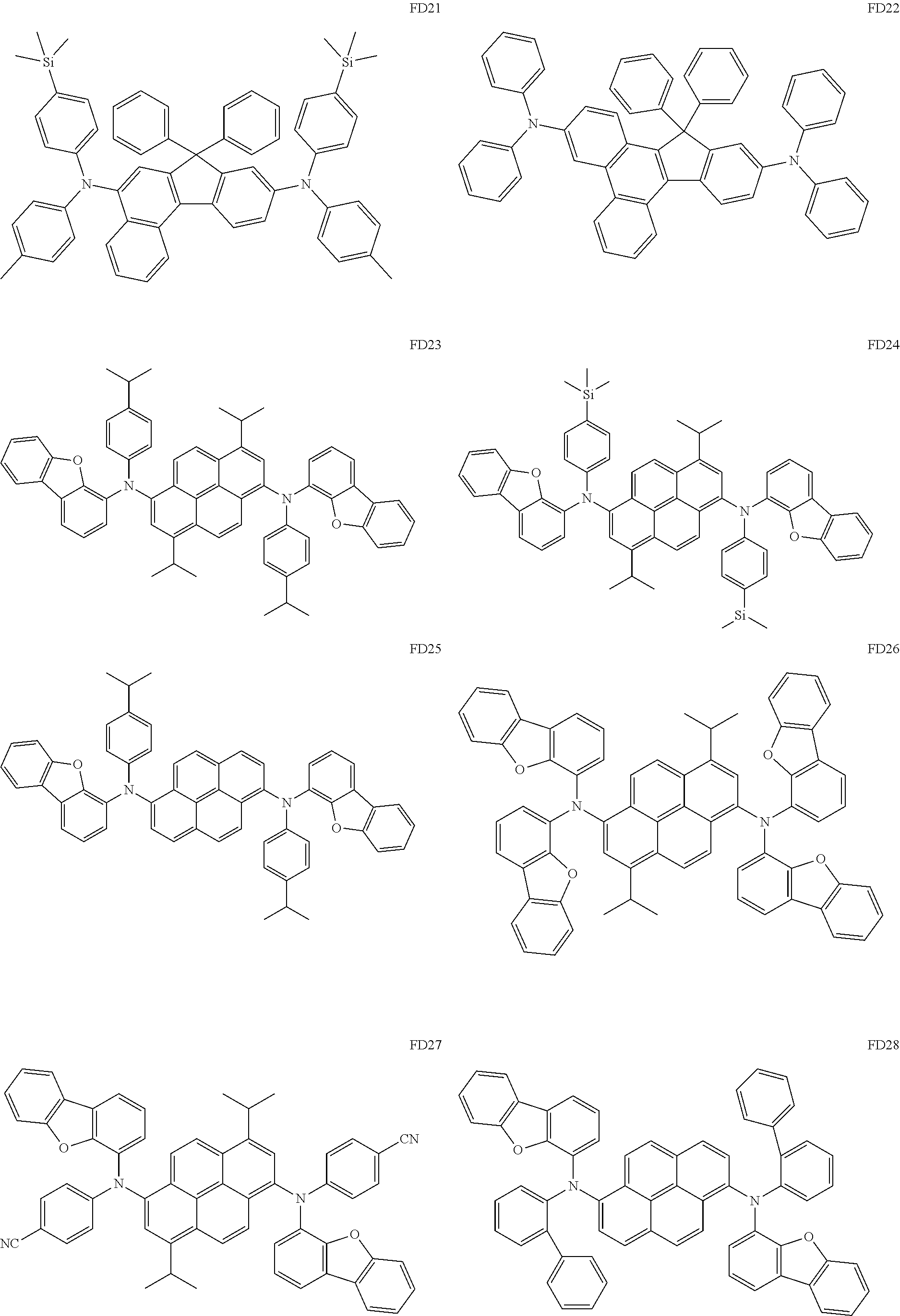

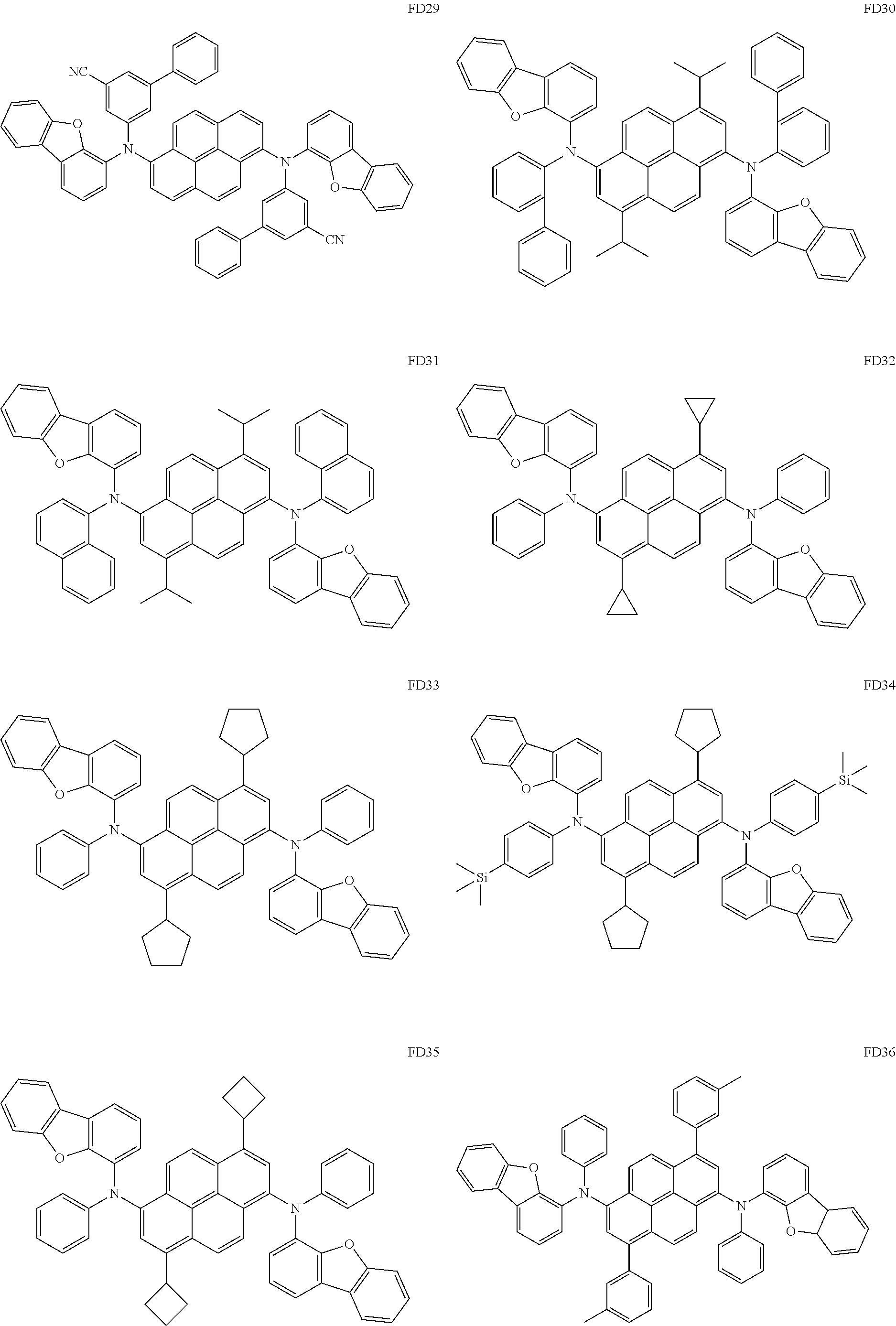

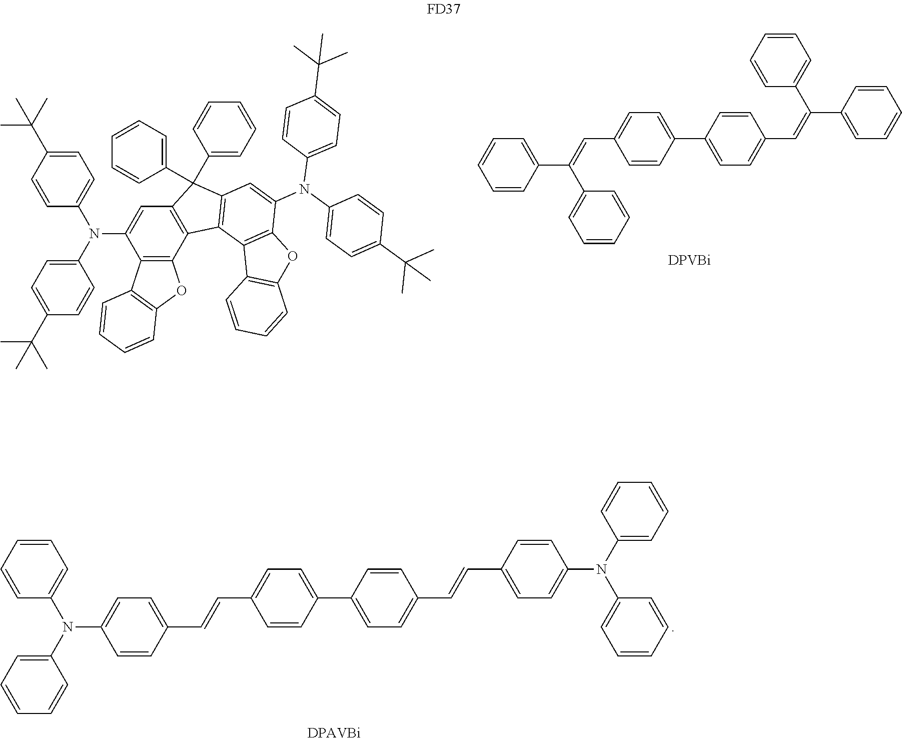

### Delayed Fluorescence Material

In one or more embodiments, the emission layer may include a delayed fluorescence material.

Herein, the delayed fluorescence material may be selected from among compounds capable of emitting delayed fluorescence based on a delayed fluorescence emission mechanism.

The delayed fluorescence material included in the emission layer may act as a host or a dopant depending on the type or kind of other materials included in the emission layer.

In one or more embodiments, a difference (e.g., an absolute value of the difference) between a triplet energy level (eV) of the delayed fluorescence material and a singlet energy level (eV) of the delayed fluorescence material may be at least 0 eV but at most (e.g., not more than) about 0.5 eV. When the difference between the triplet energy level (eV) of the delayed fluorescence material and the singlet energy level (eV) of the delayed fluorescence material is within the range described above, up-conversion from the triplet state to the singlet state of the delayed fluorescence material may effectively occur, and thus, the light-emitting device 10 may have improved luminescence efficiency.

In one or more embodiments, the delayed fluorescence material may include i) a material including at least one electron donor (e.g., a π electron-rich C₃-C₆₀ cyclic group, such as a carbazole group, and/or the like) and at least one electron acceptor (e.g., a sulfoxide group, a cyano group, a Ir electron-deficient nitrogen-containing C₁-C₆₀ cyclic group, and/or the like), ii) a material including a C₈-C₆₀ polycyclic group including two or more cyclic groups condensed to each other while sharing boron (B), and/or iii) the like.

Non-limiting examples of the delayed fluorescence material may include at least one of (e.g., selected from among) Compounds DF1 to DF14:

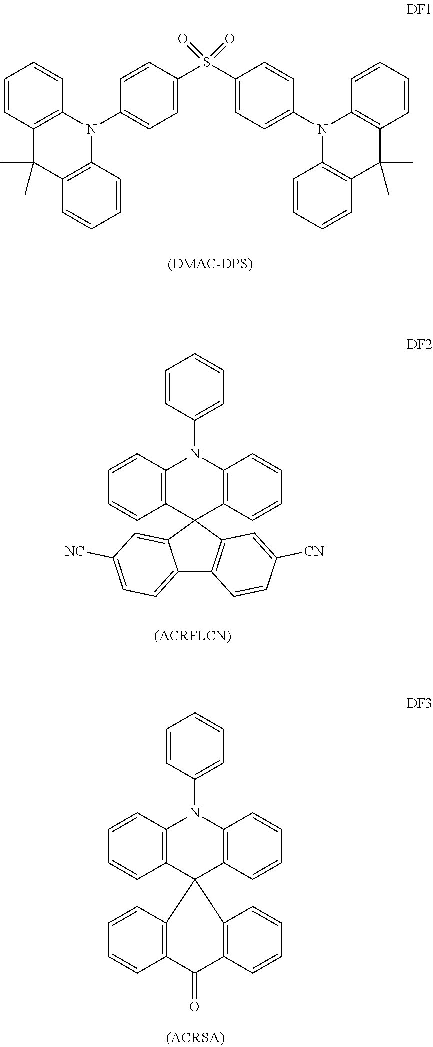

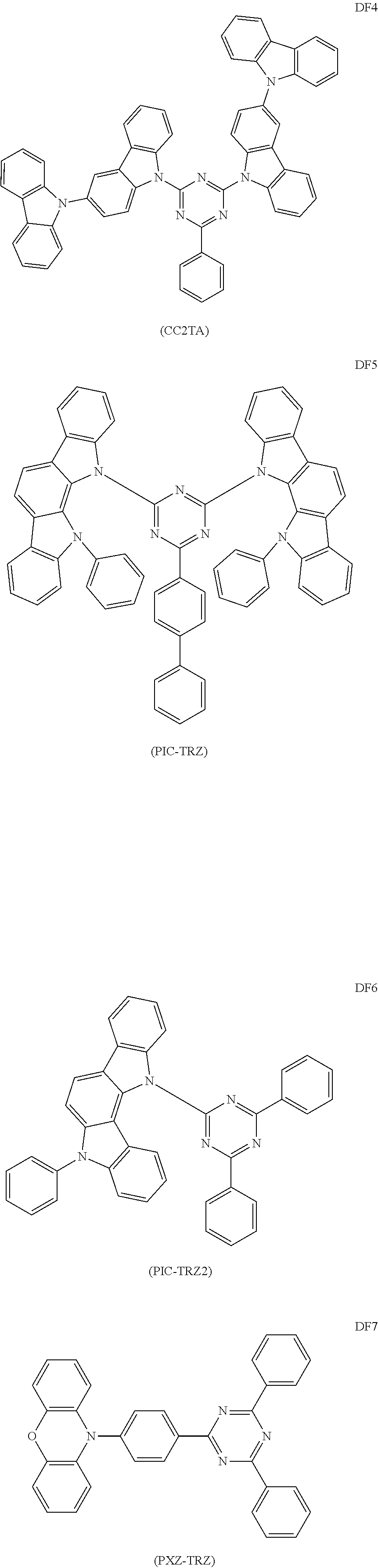 [SMILES: c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1 ; c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

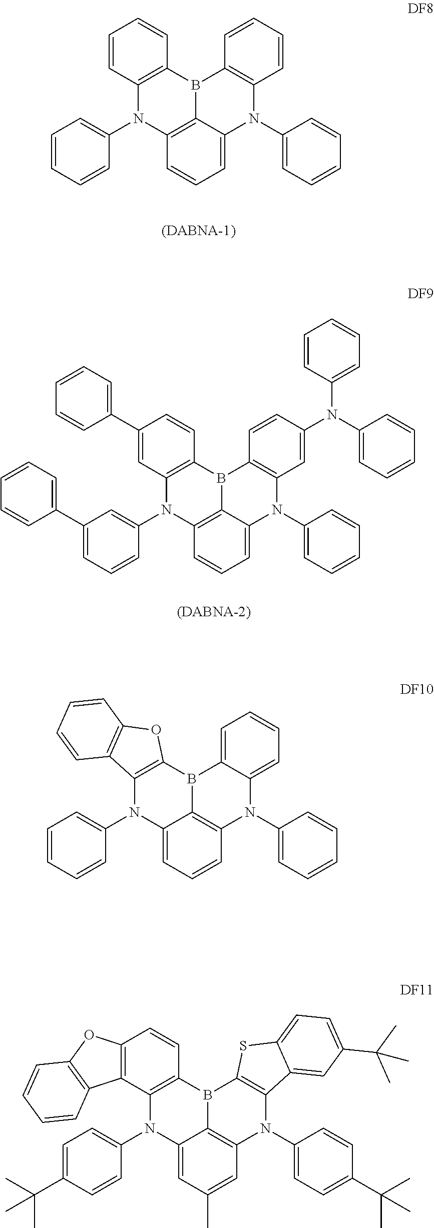

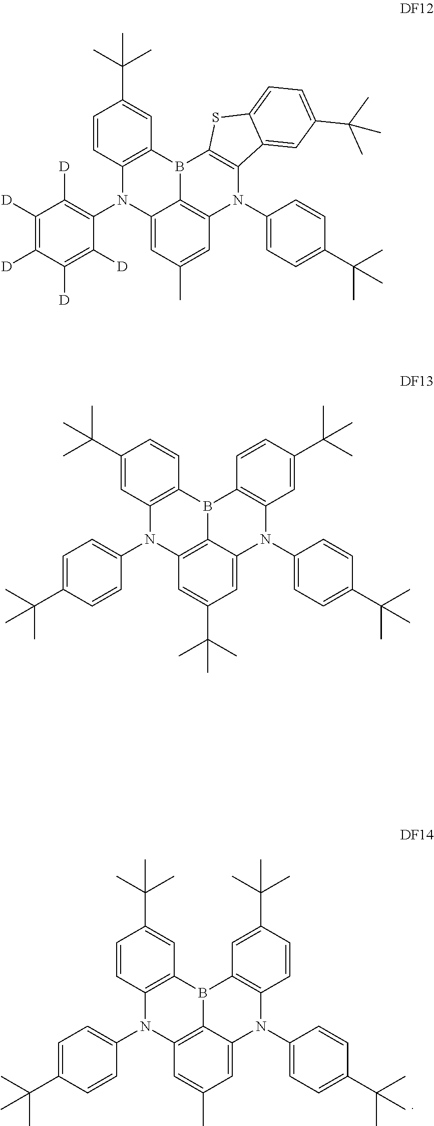

### Quantum Dot

In one or more embodiments, the emission layer may include a quantum dot.

The term “quantum dot” as used herein refers to a crystal of a semiconductor compound, and may include any material capable of emitting light of one or more suitable emission wavelengths according to the size of the crystal.

The diameter of the quantum dot may be, for example, in a range of about 1 nm to about 10 nm. In the present disclosure, when dot, dots, or dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a wet chemical process, a metal organic chemical vapor deposition process, a molecular beam epitaxy process, or any process similar thereto.

The wet chemical process is a method including mixing a precursor material of a quantum dot with an organic solvent and then growing a quantum dot particle crystal. When the crystal grows, the organic solvent naturally acts as a dispersant coordinated on the surface of the quantum dot crystal and controls the growth of the crystal so that the growth of quantum dot particles may be controlled or selected through a process which costs less, and is easier than vapor deposition methods, such as metal organic chemical vapor deposition (MOCVD) or molecular beam epitaxy (MBE).

The quantum dot may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Non-limiting examples of the Group II-VI semiconductor compound may include: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; or any combination thereof.

Non-limiting examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; or any combination thereof. In one or more embodiments, the Group III-V semiconductor compound may further include a Group II element. Non-limiting examples of the Group III-V semiconductor compound further including a Group II element may include InZnP, InGaZnP, InAlZnP, and/or the like.

Non-limiting examples of the Group III-VI semiconductor compound may include: a binary compound, such as GaS, GaSe, Ga₂Se₃, GaTe, InS, InSe, In₂S₃, In₂Se₃, InTe, and/or the like; a ternary compound, such as InGaS₃, InGaSe₃, and/or the like; or any combination thereof.

Non-limiting examples of the Group I-III-VI semiconductor compound may include: a ternary compound, such as AgInS, AgInS₂, CuInS, CuInS₂, CuGaO₂, AgGaO₂, AgAlO₂, and/or the like; or any combination thereof.

Non-limiting examples of the Group IV-VI semiconductor compound may include: a binary compound, such as SnS, SnSe, SnTe, PbS, PbSe, PbTe, and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; or any combination thereof.

The Group IV element or compound may include: a single element compound, such as Si, Ge, and/or the like; a binary compound, such as SiC, SiGe, and/or the like; or any combination thereof.

Each element included in a multi-element compound, such as the binary compound, the ternary compound, and the quaternary compound, may be present at a substantially uniform concentration or non-uniform concentration in a particle.

In one or more embodiments, the quantum dot may have a single structure in which the concentration of each element in the quantum dot is substantially uniform, or may have a core-shell dual structure. For example, a material included in the core and a material included in the shell may be different from each other.

The shell of the quantum dot may act as a protective layer that prevents chemical degeneration of the core to maintain semiconductor characteristics, and/or as a charging layer that imparts electrophoretic characteristics to the quantum dot. The shell may be a single layer or a multi-layer. The interface between the core and the shell may have a concentration gradient in which the concentration of an element existing in the shell decreases toward the center of the core.

Examples of the shell of the quantum dot may include an oxide of a metal, a metalloid, or a non-metal, a semiconductor compound, and/or a (e.g., any suitable) combination thereof. Non-limiting examples of the oxide of a metal, a metalloid, or a non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like; a ternary compound, such as MgAl₂O₄, CoFe₂O₄, NiFe₂O₄, CoMn₂O₄, and/or the like; or any combination thereof. Examples of the semiconductor compound may include: as described herein, a Group II-VI semiconductor compound; a Group III-V semiconductor compound; a Group III-VI semiconductor compound; a Group I-III-VI semiconductor compound; a Group IV-VI semiconductor compound; or any combination thereof. For example, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The quantum dot may have a full width at half maximum (FWHM) of the emission spectrum of about 45 nm or less, about 40 nm or less, or for example, about 30 nm or less. When the FWHM of the emission spectrum of the quantum dot is within these ranges, the quantum dot may have improved color purity or improved color reproducibility. In addition, because light emitted through the quantum dot is emitted in all directions, the wide viewing angle may be improved.

In addition, the quantum dot may be in the form of a spherical particle, a pyramidal particle, a multi-arm particle, a cubic nanoparticle, a nanotube particle, a nanowire particle, a nanofiber particle, a nanoplate particle, and/or the like.

Because an energy band gap of the quantum dot may be adjusted by controlling the size of the quantum dot, light having one or more suitable wavelength bands may be obtained from a quantum dot emission layer. Accordingly, by using quantum dots of different sizes, a light-emitting device that emits light of one or more suitable wavelengths may be implemented. For example, the size of the quantum dot may be selected to enable the quantum dots to emit red light, green light, and/or blue light. In addition, the quantum dots with suitable sizes (diameters) may be configured to emit white light by combination of light of one or more suitable colors.

### Electron Transport Region in Interlayer 130

The electron transport region may have i) a single-layer structure including (e.g., consisting of) a single layer including (e.g., consisting of) a single material, ii) a single-layer structure including (e.g., consisting of) a single layer including multiple materials that are different from each other, or iii) a multi-layer structure including multiple layers including multiple materials that are different from each other.

The electron transport region may include a buffer layer, a hole blocking layer, an electron control layer, an electron transport layer, an electron injection layer, or any combination thereof.

In one or more embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers of each structure are sequentially stacked from the emission layer in the stated order.

In one or more embodiments, the electron transport region (e.g., the buffer layer, the hole blocking layer, the electron control layer, or the electron transport layer in the electron transport region) may include a metal-free compound including at least one π electron-deficient nitrogen-containing C₁-C₆₀ cyclic group.

In one or more embodiments, the electron transport region may include a compound represented by Formula 601:

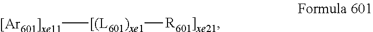

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described with respect to Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ cyclic group unsubstituted or substituted with at least one R₁₀ₐ.

In one or more embodiments, if (e.g., when) xe11 in Formula 601 is 2 or more, two or more of Ar₆₀₁(s) may be linked to each other via a single bond.

In one or more embodiments, Ar₆₀₁ in Formula 601 may be an anthracene group unsubstituted or substituted with at least one R₁₀ₐ.

In one or more embodiments, the electron transport region may include a compound represented by Formula 601-1:

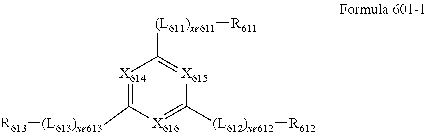

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ may each independently be the same as described with respect to L₆₀₁,
xe611 to xe613 may each independently be the same as described with respect to xe1,
R₆₁₁ to R₆₁₃ may each independently be the same as described with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In one or more embodiments, xe1 and xe611 to xe613 in Formulae 601 and 601-1 may each independently be 0, 1, or 2.

In one or more embodiments, the electron transport region may include: at least one of (e.g., selected from among) Compounds ET1 to ET45; 2,9-dimethyl-4,7-diphenyl-1,10-phenanthroline (BCP); 4,7-diphenyl-1,10-phenanthroline (Bphen); tris(8-hydroxyquinolinato)aluminum (Alq3); bis(2-methyl-8-quinolinolato-N1,O8)-(1,1′-biphenyl-4-olato)aluminum (BAlq); 3-(4-biphenyl)-4-phenyl-5-tert-butylphenyl-1,2,4-triazole (TAZ); 4-(naphthalen-1-yl)-3,5-diphenyl-4H-1,2,4-triazole (NTAZ); or any combination thereof:

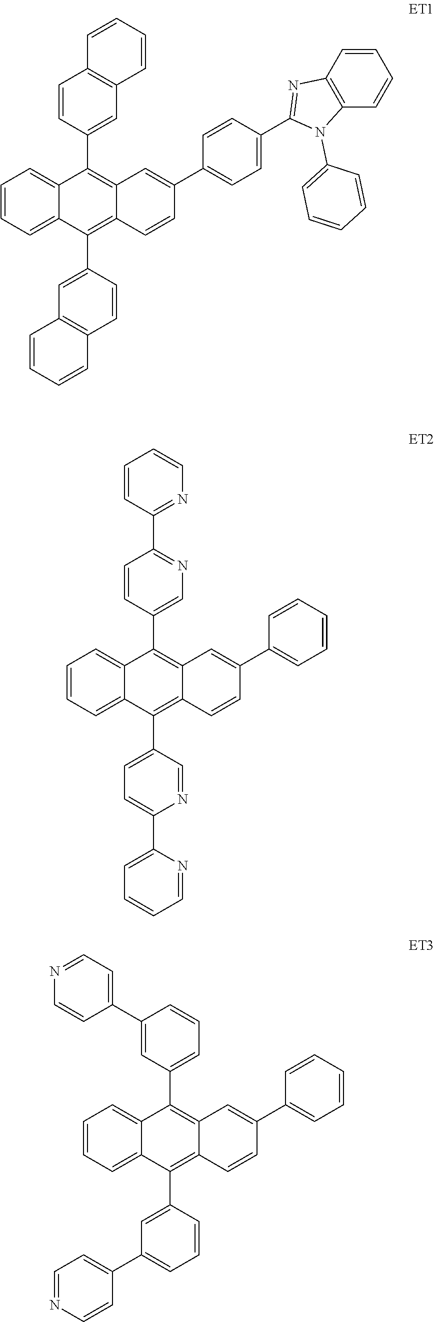 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

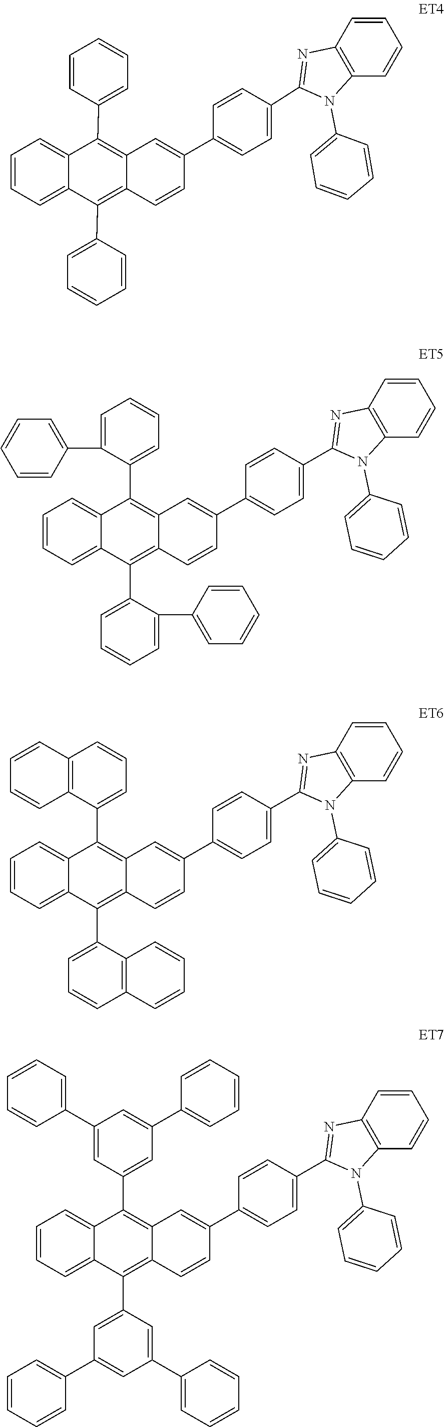 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

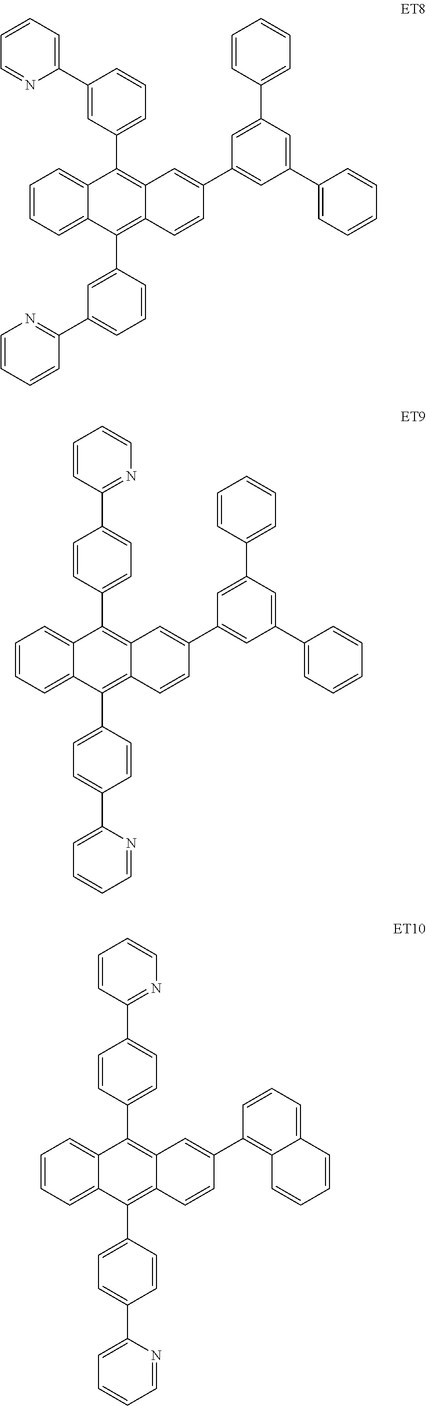 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

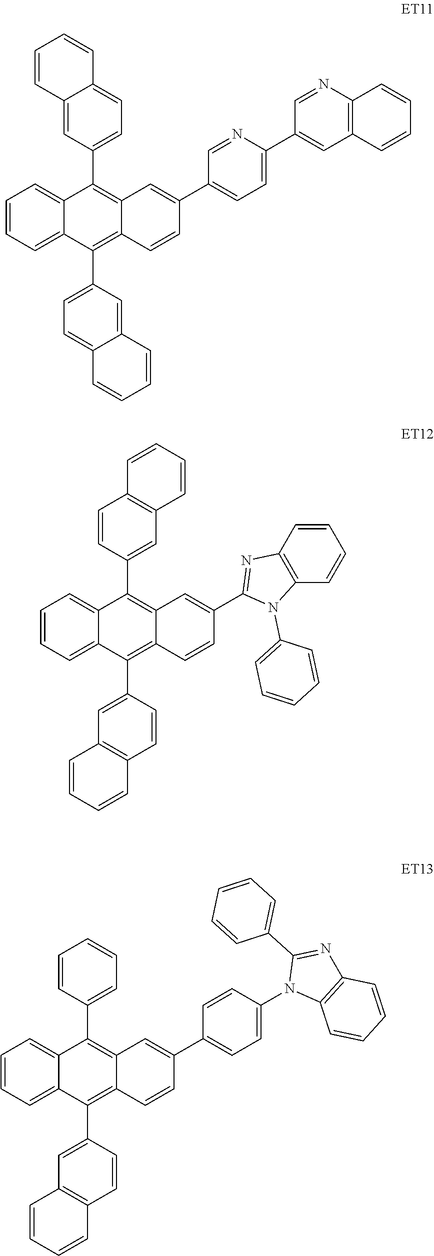 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

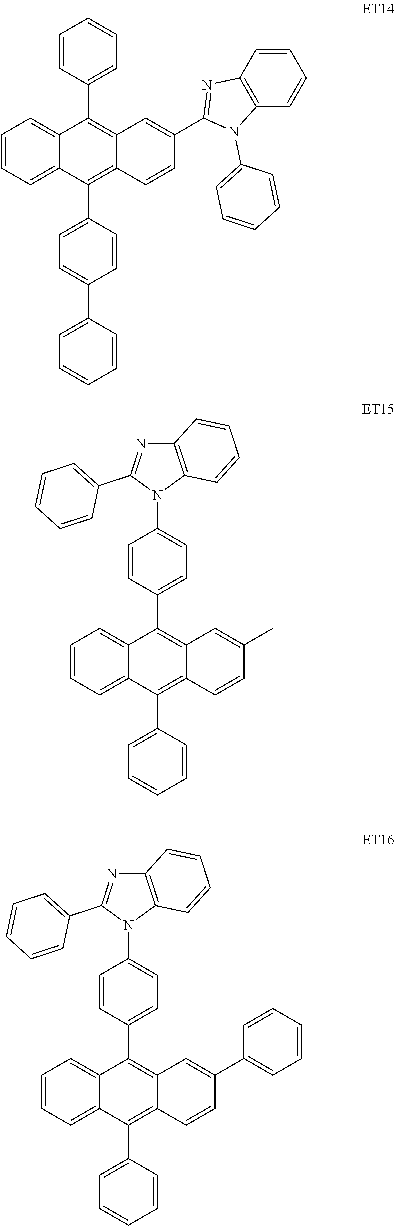 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

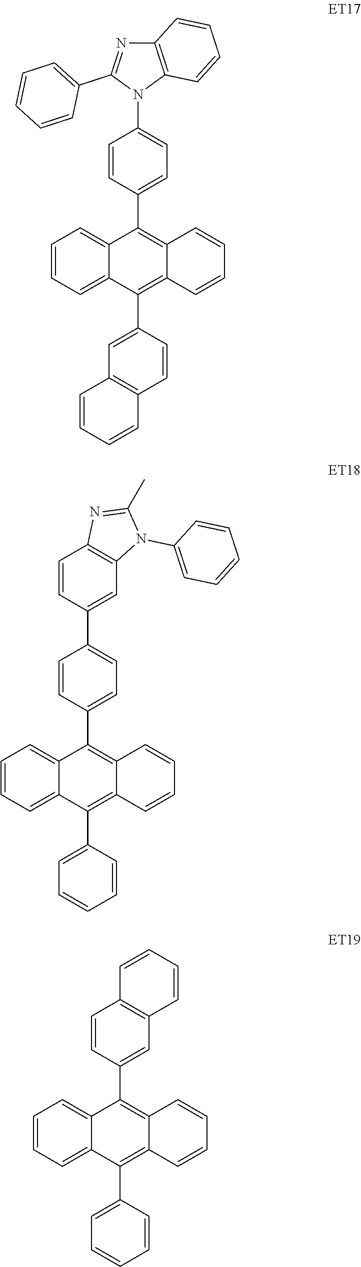

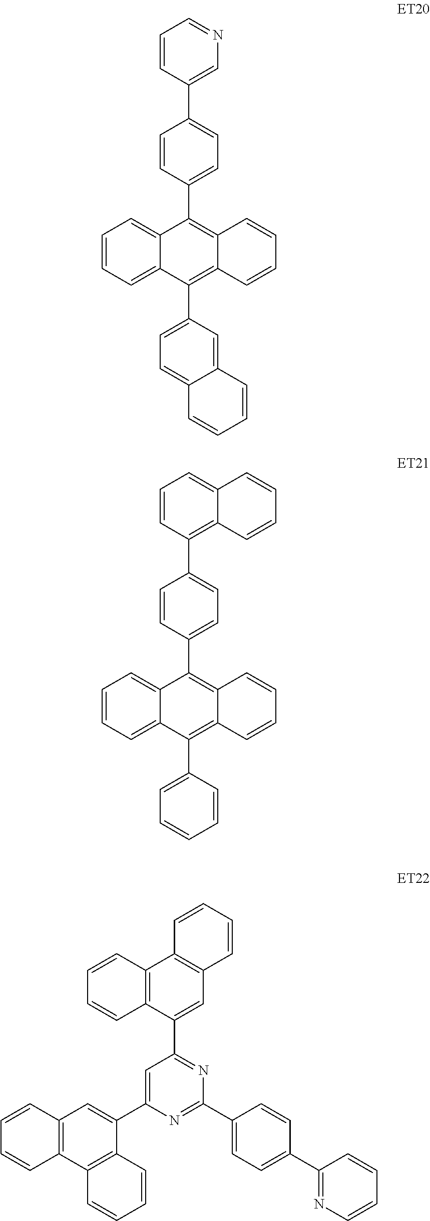

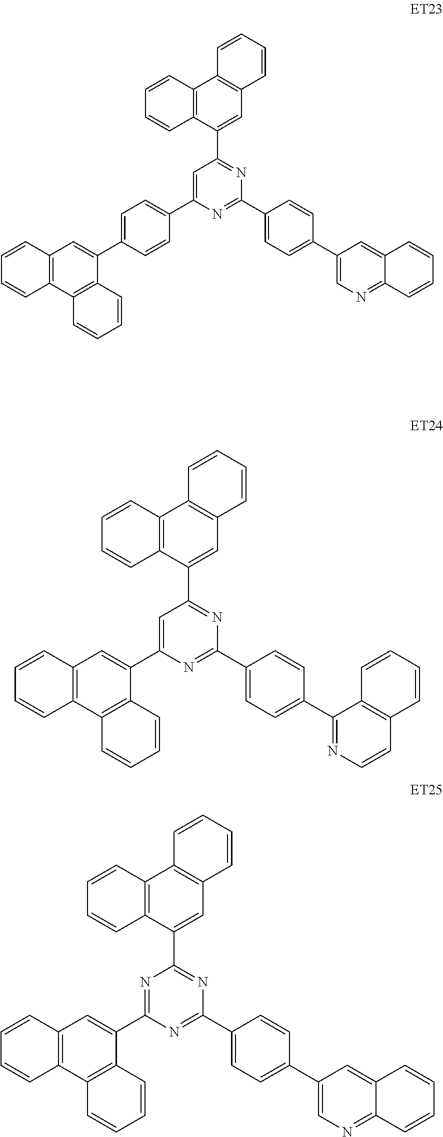 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

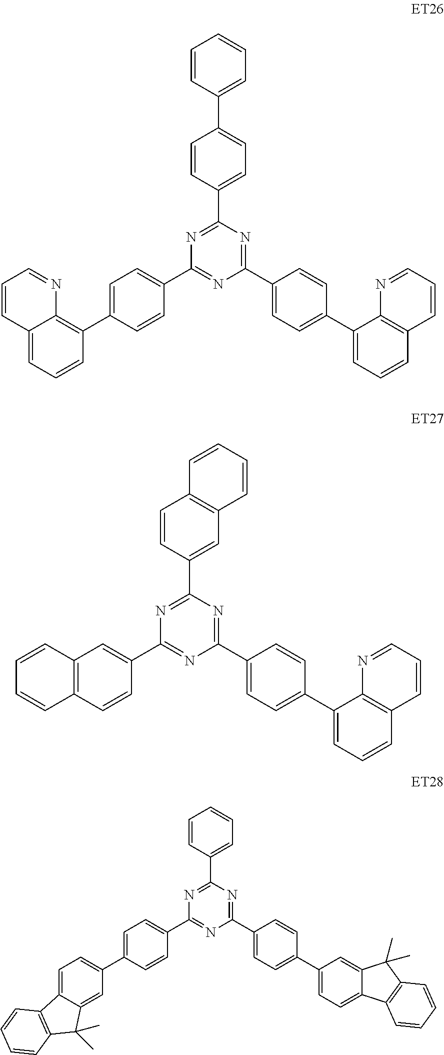 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

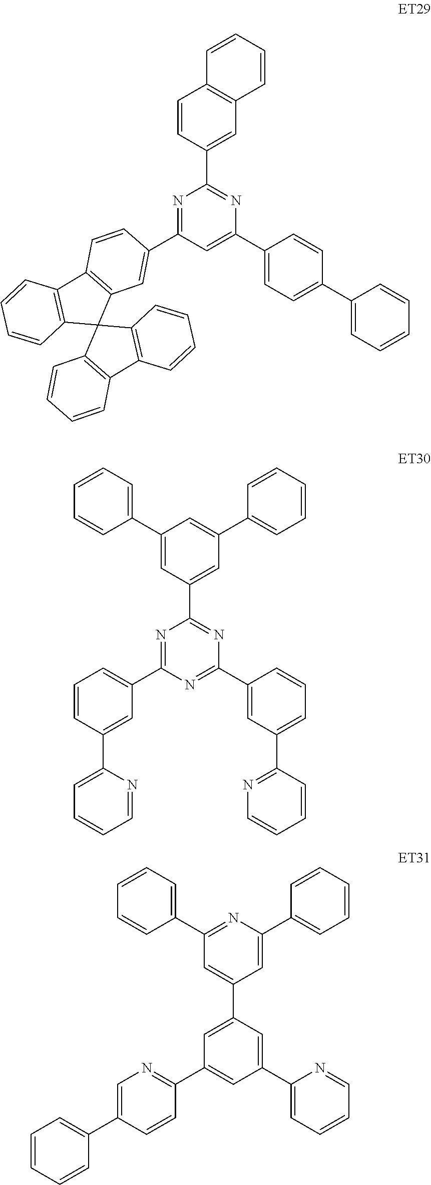 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

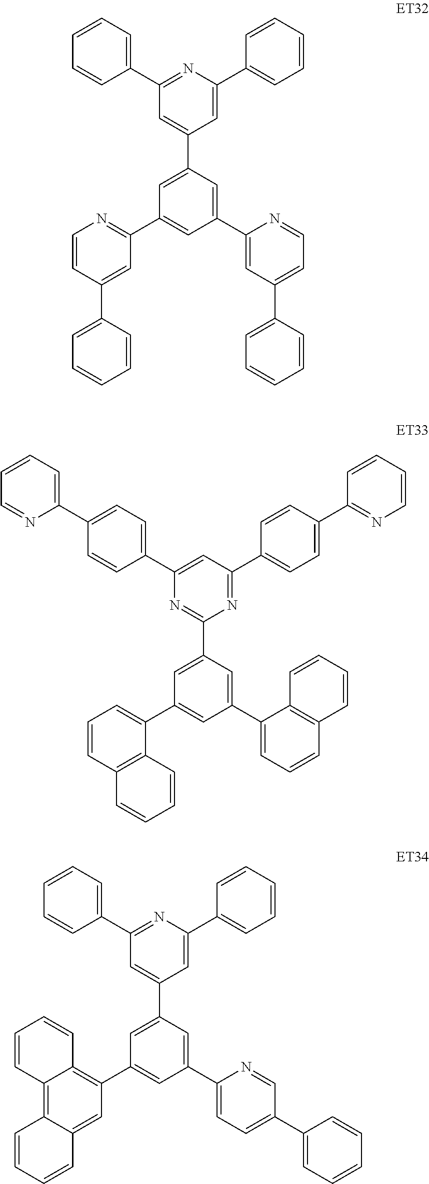 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

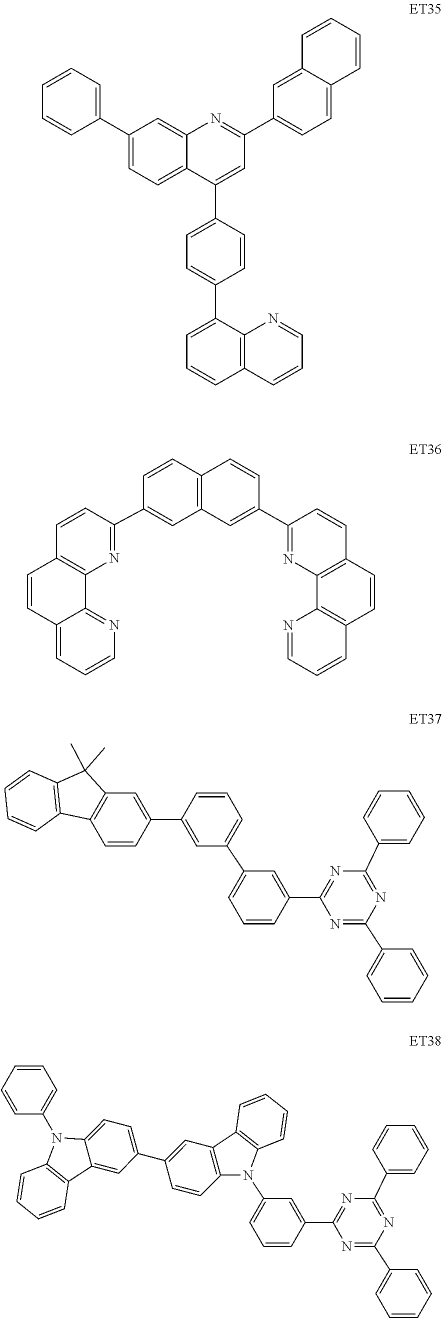 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

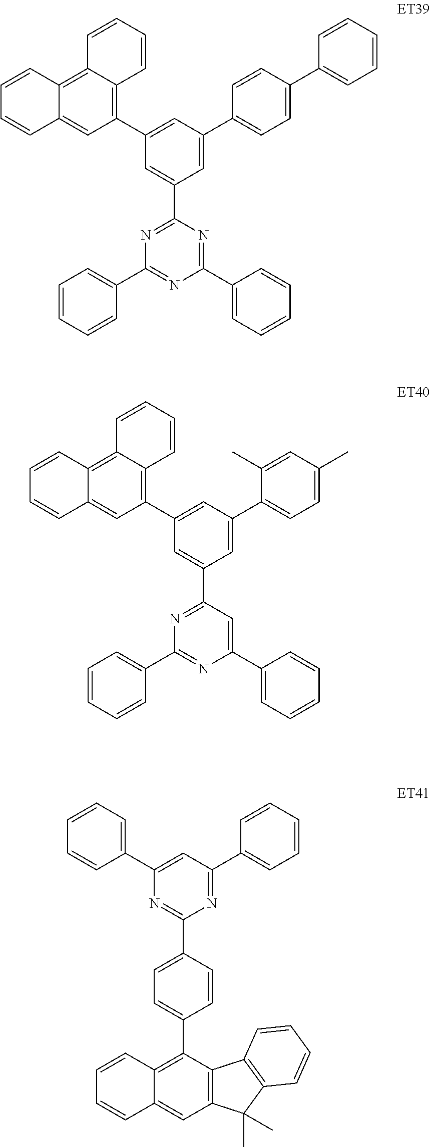 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

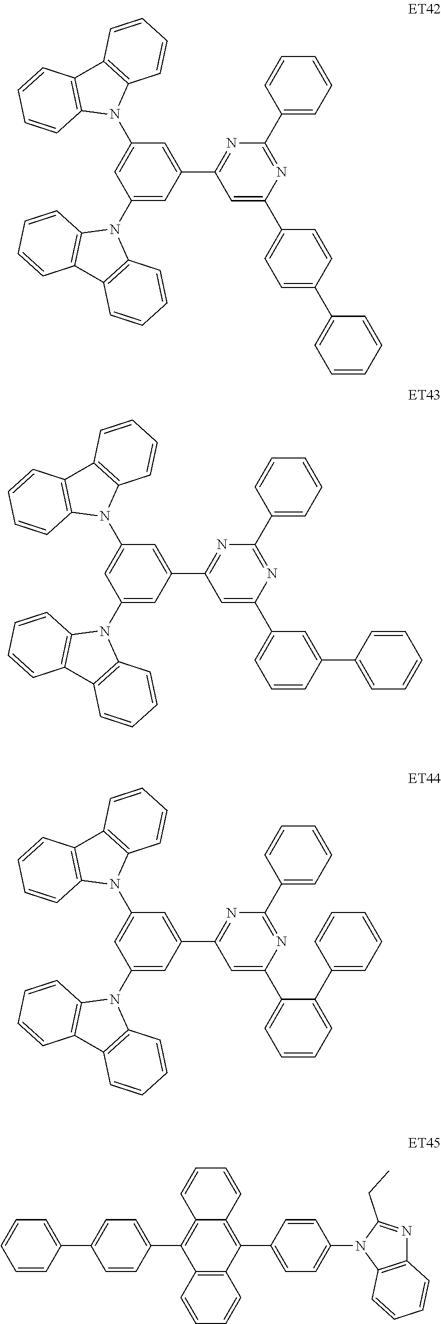 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

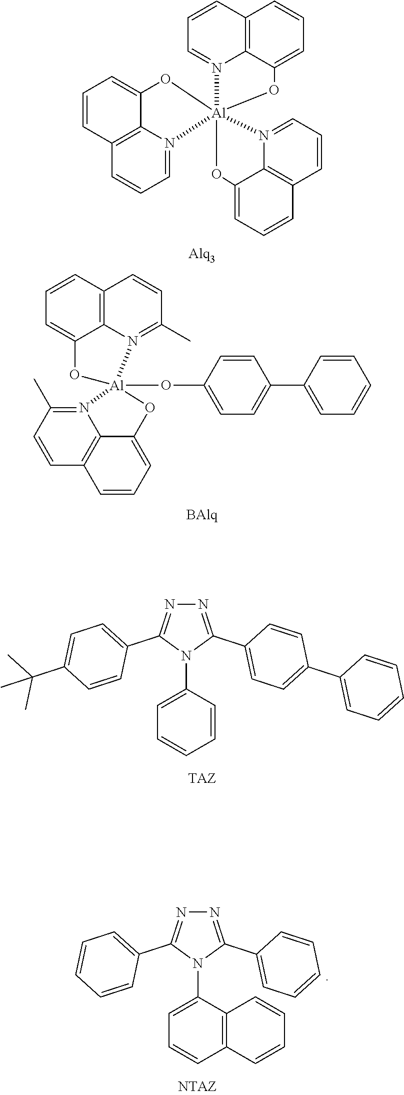

A thickness of the electron transport region may be in a range of about 100 Å to about 5,000 Å, for example, about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thicknesses of the buffer layer, the hole blocking layer, the electron control layer, the electron transport layer, and/or the electron transport region are within the ranges described above, satisfactory electron transporting characteristics may be obtained without a substantial increase in driving voltage.

In one or more embodiments, the electron transport region (e.g., the electron transport layer in the electron transport region) may further include, in addition to one or more of the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In one or more embodiments, the metal-containing material may include a Li complex. The Li complex may include, for example. Compound ET-D1 (LiQ) or ET-D2:

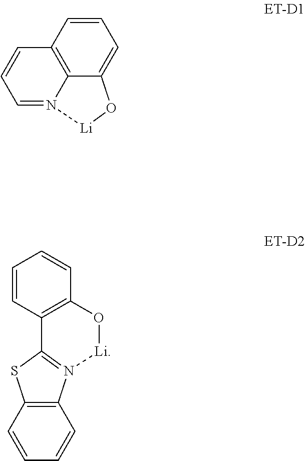

In one or more embodiments, the electron transport region may include an electron injection layer that facilitates the injection of electrons from the second electrode 150. The electron injection layer may directly contact the second electrode 150.

The electron injection layer may have i) a single-layer structure including (e.g., consisting of) a single layer including (e.g., consisting of) a single material, ii) a single-layer structure including (e.g., consisting of) a single layer including multiple materials that are different from each other, or iii) a multi-layer structure including multiple layers including multiple materials that are different from each other.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (e.g., fluorides, chlorides, bromides, iodides, and/or the like), or tellurides of the alkali metal, the alkaline earth metal, and the rare earth metal, respectively, or any combination thereof.

The alkali metal-containing compound may include: an alkali metal oxide, such as Li₂O, Cs₂O, K₂O, and/or the like; an alkali metal halide, such as LiF, NaF, CsF, KF, LiI, NaI, CsI, KI, and/or the like; or any combination thereof. The alkaline earth metal-containing compound may include an alkaline earth metal compound, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include a lanthanide metal telluride. Non-limiting examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, HO₂Te₃, Er₂Te₃, Tm₂Te₃, Yb₂Te₃, Lu₂Te₃, and/or the like.

The alkali metal complex, the alkaline earth-metal complex, and the rare earth metal complex may include i) one of metal ions of the alkali metal, one of metal ions of the alkaline earth metal, and one of metal ions of the rare earth metal, respectively, and ii) a ligand bonded to the metal ion (e.g., the respective metal ion), for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (e.g., a compound represented by Formula 601).

In one or more embodiments, the electron injection layer may include (e.g., consist of) i) an alkali metal-containing compound (e.g., an alkali metal halide), or ii) a) an alkali metal-containing compound (e.g., an alkali metal halide), and b) an alkali metal, an alkaline earth metal, a rare earth metal, or any combination thereof. For example, in one or more embodiments, the electron injection layer may be a KI:Yb co-deposited layer, an RbI:Yb co-deposited layer, a LiF:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly (e.g., substantially uniformly) or non-uniformly dispersed in a matrix including the organic material.

A thickness of the electron injection layer may be in a range of about 1 Å to about 100 Å, and, for example, about 3 Å to about 90 Å. When the thickness of the electron injection layer is within the range described above, satisfactory electron injection characteristics may be obtained without a substantial increase in driving voltage.

### Second Electrode 150

The second electrode 150 may be arranged on the interlayer 130 having a structure as described above. The second electrode 150 may be a cathode, which is an electron injection electrode, and as a material for forming the second electrode 150, a metal, an alloy, an electrically conductive compound, or any combination thereof, each having a low-work function, may be used.

The second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layer structure or a multi-layer structure including multiple layers.

### Capping Layer

A first capping layer may be arranged outside (e.g., on) the first electrode 110, and/or a second capping layer may be arranged outside (e.g., on) the second electrode 150. For example, in one or more embodiments, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

In one or more embodiments, light generated in the emission layer of the interlayer 130 of the light-emitting device 10 may be extracted toward the outside through the first electrode 110, which is a transflective electrode or a transmissive electrode, and the first capping layer. In one or more embodiments, light generated in the emission layer of the interlayer 130 of the light-emitting device 10 may be extracted toward the outside through the second electrode 150, which is a transflective electrode or a transmissive electrode, and the second capping layer.

The first capping layer and the second capping layer may increase external emission efficiency according to the principle of constructive interference. Accordingly, the light extraction efficiency of the light-emitting device 10 may be increased, so that the luminescence efficiency of the light-emitting device 10 may be improved.

Each of the first capping layer and the second capping layer may include a material having a refractive index of 1.6 or more (e.g., at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and/or the second capping layer may (e.g., the first capping layer and the second capping layer may each independently) include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each optionally be substituted with a substituent including O, N, S, Se, Si, F, Cl, Br, I, or any combination thereof. In one or more embodiments, at least one of the first capping layer and/or the second capping layer may (e.g., the first capping layer and the second capping layer may each independently) include an amine group-containing compound.

In one or more embodiments, at least one of the first capping layer and/or the second capping layer may (e.g., the first capping layer and the second capping layer may each independently) include a compound represented by Formula 201, a compound represented by Formula 202, or any combination thereof.

In one or more embodiments, at least one of the first capping layer and/or the second capping layer may (e.g., the first capping layer and the second capping layer may each independently) include: at least one of (e.g., selected from among) Compounds HT28 to HT33; at least one of (e.g., selected from among) Compounds CP1 to CP6; β-NPB; or any combination thereof:

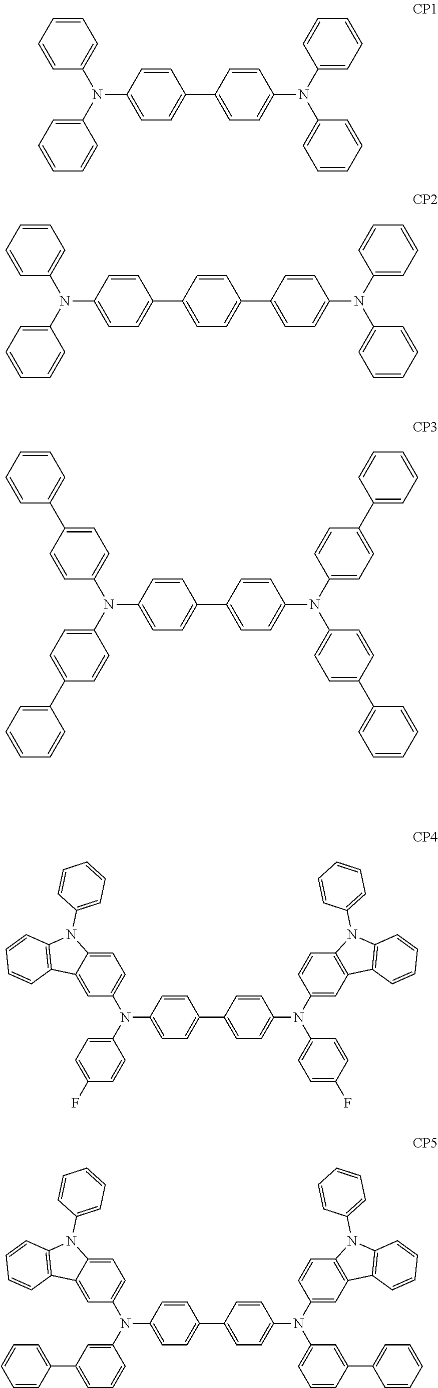 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

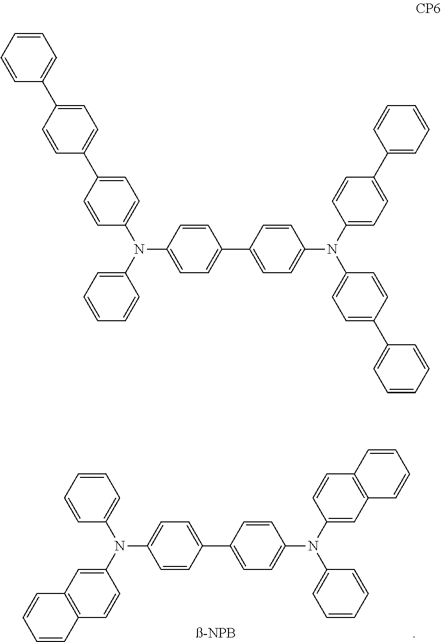 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Film

The heterocyclic compound represented by Formula 1 may be included in one or more suitable films. Accordingly, one or more aspects of embodiments of the present disclosure are directed toward a film including the heterocyclic compound represented by Formula 1. The film may be, for example, an optical member (or a light control element) (e.g., a color filter, a color conversion member, a capping layer, a light extraction efficiency enhancement layer, a selective light absorbing layer, a polarizing layer, a quantum dot-containing layer, and/or the like), a light blocking member (e.g., a light reflective layer, a light absorbing layer, and/or the like), a protective member (e.g., an insulating layer, a dielectric layer, and/or the like), and/or the like.

### Electronic Apparatus

The light-emitting device may be included in one or more suitable electronic apparatuses. For example, the electronic apparatus including the light-emitting device may be a light-emitting apparatus, an authentication apparatus, and/or the like.

In one or more embodiments, the electronic apparatus (e.g., a light-emitting apparatus) may further include, in addition to the light-emitting device, i) a color filter, ii) a color conversion layer, or iii) a color filter and a color conversion layer. The color filter and/or the color conversion layer may be arranged in at least one direction in which light emitted from the light-emitting device travels. For example, in one or more embodiments, the light emitted from the light-emitting device may be blue light or white light (e.g., combined white light). Details on the light-emitting device may be the same as described herein. In one or more embodiments, the color conversion layer may include a quantum dot. The quantum dot may be, for example, a quantum dot as described herein.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

In one or more embodiments, the color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include: a first area configured to emit first color light; a second area configured to emit second color light; and/or a third area configured to emit third color light, wherein the first color light, the second color light, and/or the third color light may have different maximum emission wavelengths. For example, in one or more embodiments, the first color light may be red light, the second color light may be green light, and the third color light may be blue light. For example, in one or more embodiments, the plurality of color filter areas (or the plurality of color conversion areas) may include quantum dots. For example, the first area may include a red quantum dot to emit red light, the second area may include a green quantum dot to emit green light, and the third area may not include (e.g., may exclude) a quantum dot. Details on the quantum dot may be the same as described herein. Each of the first area, the second area, and/or the third area may further include a scatter.

In one or more embodiments, the light-emitting device may be to emit first light, the first area may be to absorb the first light to emit first-first color light, the second area may be to absorb the first light to emit second-first color light, and the third area may be to absorb the first light to emit third-first color light. In this regard, the first-first color light, the second-first color light, and the third-first color light may have different maximum emission wavelengths. For example, the first light may be blue light, the first-first color light may be red light, the second-first color light may be green light, and the third-first color light may be blue light.

In one or more embodiments, the electronic apparatus may further include a thin-film transistor, in addition to the light-emitting device as described above. The thin-film transistor may include a source electrode, a drain electrode, and an active layer, wherein one selected from among the source electrode and the drain electrode may be electrically connected to the first electrode or the second electrode of the light-emitting device.

The thin-film transistor may further include a gate electrode, a gate insulating film, and/or the like.

The active layer may include crystalline silicon, amorphous silicon, an organic semiconductor, an oxide semiconductor, and/or the like.

In one or more embodiments, the electronic apparatus may further include a sealing portion for sealing the light-emitting device. The sealing portion may be arranged between the color filter and/or the color conversion layer and the light-emitting device. The sealing portion allows light from the light-emitting device to be extracted to the outside, and concurrently (e.g., simultaneously) prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin-film encapsulation layer, the electronic apparatus may be flexible.

In one or more embodiments, various functional layers may be additionally arranged on the sealing portion, in addition to the color filter and/or the color conversion layer, according to the use of the electronic apparatus. Non-limiting examples of the functional layers may include a touch screen layer, a polarizing layer, and/or the like. The touch screen layer may be a pressure-sensitive touch screen layer, a capacitive touch screen layer, or an infrared touch screen layer.

The authentication apparatus may be, for example, a biometric authentication apparatus that authenticates an individual by using biometric information of a living body (e.g., fingertips, pupils, and/or the like). The authentication apparatus may further include, in addition to the light-emitting device as described above, a biometric information collector.

The electronic apparatus (for example, a light-emitting apparatus) may be applied to various electronic equipment. In one or more embodiments, the electronic apparatus may be applied to one or more of displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (e.g., meters for a vehicle, an aircraft, and a vessel), projectors, and/or the like.

### Electronic Equipment

The electronic apparatus may be applied to various electronic equipment. Thus, the light-emitting device may be included in one or more suitable electronic equipment.

In one or more embodiments, the light-emitting apparatus may be applied to various electronic equipment. The electronic equipment may include the light-emitting apparatus, and may further include modules or apparatuses with additional functions besides the light-emitting apparatus.

In one or more embodiments, the electronic equipment including the light-emitting device may be at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a mobile phone, a tablet, a phablet, a PDA, a wearable device, a laptop computer, a digital camera, a camcorder, a viewfinder, a micro display, a 3D display, a virtual reality display, an augmented reality display, a vehicle, a video wall with multiple displays tiled together, a theater screen, a stadium screen, a phototherapy device, or a signboard.

The light-emitting device may have excellent or suitable luminescence efficiency and long lifetime, and thus, the electronic equipment including the light-emitting device may have characteristics such as high luminance, high resolution, and low power consumption.

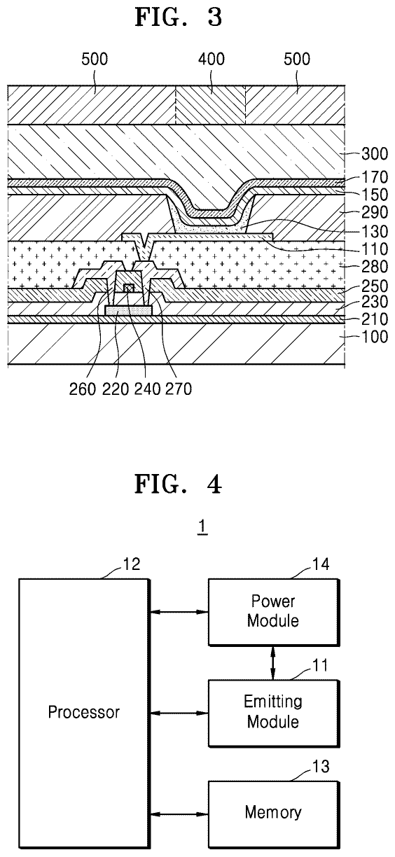

### Descriptions of FIGS. 2 and 3

FIG. 2 is a cross-sectional view of a light-emitting apparatus according to one or more embodiments of the present disclosure.

The light-emitting apparatus of FIG. 2 may include a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be on the substrate 100. The buffer layer 210 may prevent or reduce penetration of impurities through the substrate 100, and may provide a flat surface on the substrate 100.

The TFT may be on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be on the active layer 220, and the gate electrode 240 may be on the gate insulating film 230.

An interlayer insulating film 250 may be on the gate electrode 240. The interlayer insulating film 250 may be arranged between the gate electrode 240 and the source electrode 260 and between the gate electrode 240 and the drain electrode 270, to insulate from one another.

The source electrode 260 and the drain electrode 270 may be on the interlayer insulating film 250. The interlayer insulating film 250 and the gate insulating film 230 may be formed to expose the source region and the drain region of the active layer 220, and the source electrode 260 and the drain electrode 270 may be arranged in contact with the exposed portions of the source region and the drain region of the active layer 220, respectively.

The TFT may be electrically connected to the light-emitting device to drive the light-emitting device, and may be covered and protected by a passivation layer 280. The passivation layer 280 may include an inorganic insulating film, an organic insulating film, or any combination thereof. The light-emitting device may be provided on the passivation layer 280. The light-emitting device may include a first electrode 110, an interlayer 130, and a second electrode 150.

The first electrode 110 may be on the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel-defining film 290 including an insulating material may be on the first electrode 110. The pixel-defining film 290 may expose a certain region of the first electrode 110, and the interlayer 130 may be formed in the exposed region of the first electrode 110. The pixel-defining film 290 may be a polyimide-based organic film or a polyacrylic organic film. In one or more embodiments, at least some layers of the interlayer 130 may extend beyond the upper portion of the pixel-defining film 290 to be arranged in the form of a common layer. For example, at least some layers of the interlayer 130 may extend beyond the top of the pixel-defining film 290, forming a common layer.

The second electrode 150 may be on the interlayer 130, and a capping layer 170 may be additionally formed on the second electrode 150. The capping layer 170 may be formed to cover the second electrode 150.

The encapsulation portion 300 may be on the capping layer 170. The encapsulation portion 300 may be arranged on the light-emitting device to protect the light-emitting device from moisture and/or oxygen. The encapsulation portion 300 may include: an inorganic film including silicon nitride (SiNₓ, e.g., Si₃N₄), silicon oxide (SiOₓ, e.g., SiO₂), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (e.g., polymethyl methacrylate, polyacrylic acid, and/or the like), an epoxy-based resin (e.g., aliphatic glycidyl ether (AGE), and/or the like), or any combination thereof; or any combination of the inorganic film and the organic film.

FIG. 3 is a cross-sectional view of a light-emitting apparatus according to one or more embodiments of the present disclosure.

The light-emitting apparatus of FIG. 3 is substantially the same as the light-emitting apparatus of FIG. 2, except that a light-shielding pattern 500 and a functional region 400 are additionally arranged on the encapsulation portion 300. The functional region 400 may be i) a color filter area, ii) a color conversion area, or iii) a combination of the color filter area and the color conversion area. In one or more embodiments, the light-emitting device included in the light-emitting apparatus of FIG. 3 may be a tandem light-emitting device.

### Description of FIG. 4

FIG. 4 is a block diagram of an electronic equipment 1 according to one or more embodiments. Referring to FIG. 4, the electronic equipment 1 according to one or more embodiments may include a light-emitting (i.e., emitting) module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information necessary for an operation of the processor 12 and/or the light-emitting module 11. When the processor 12 executes an application stored in the memory 13, video data signals and/or input control signals are transmitted to the light-emitting module 11, which processes the received signals to output video information through a display screen.

The power module 14 may include a power supply module, such as a power adapter and/or a battery, and a power conversion module that converts power supplied by the power supply module to generate power required for the operation of the electronic equipment 1.

At least one of the components of the above-described electronic equipment may be included in the light-emitting apparatus according to the aforementioned embodiments. Furthermore, some of the individual modules functionally included in a single module may be incorporated into the light-emitting apparatus, while others may be provided separately from the light-emitting apparatus. For example, the light-emitting apparatus may include the light-emitting module 11, and the processor 12, memory 13, and power module 14 may be provided as other apparatuses within the electronic equipment 1 rather than being part of the light-emitting apparatus.

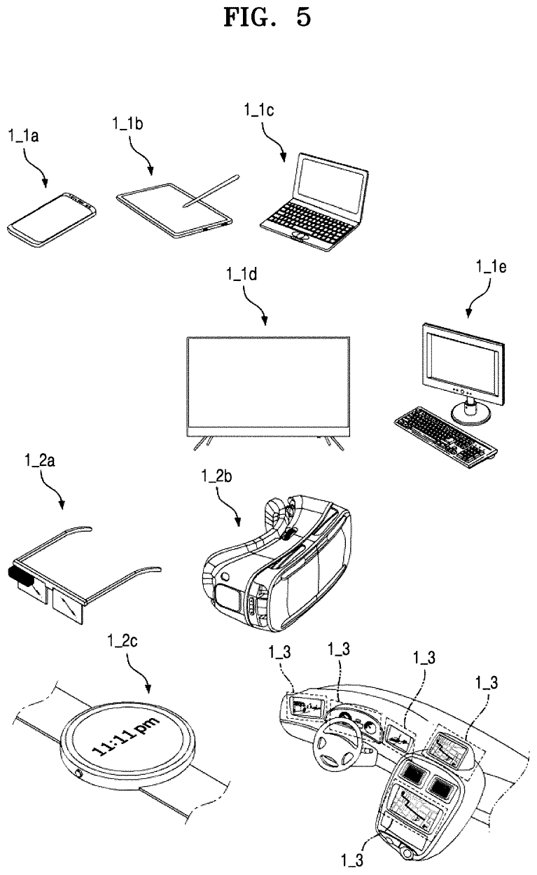

### Description of FIG. 5

FIG. 5 is a schematic diagram of electronic equipment according to one or more embodiments of the present disclosure.

Referring to FIG. 5, electronic equipment to which an electronic apparatus (for example, a light-emitting apparatus) is applied may include not only image display electronic equipment such as a smartphone 1_1a, a tablet PC 1_1b, a laptop 1_1c, a TV 1_1d, and a desktop monitor 1_1e, but also wearable electronic equipment including light-emitting modules such as smart glasses 1_2a, a head-mounted displays 1_2b, and a smartwatch 1_2c, as well as vehicle electronic equipment 1_3 including light-emitting modules such as an instrument panel, a center fascia, a center information display (CID) placed on the dashboard, and a room mirror display.

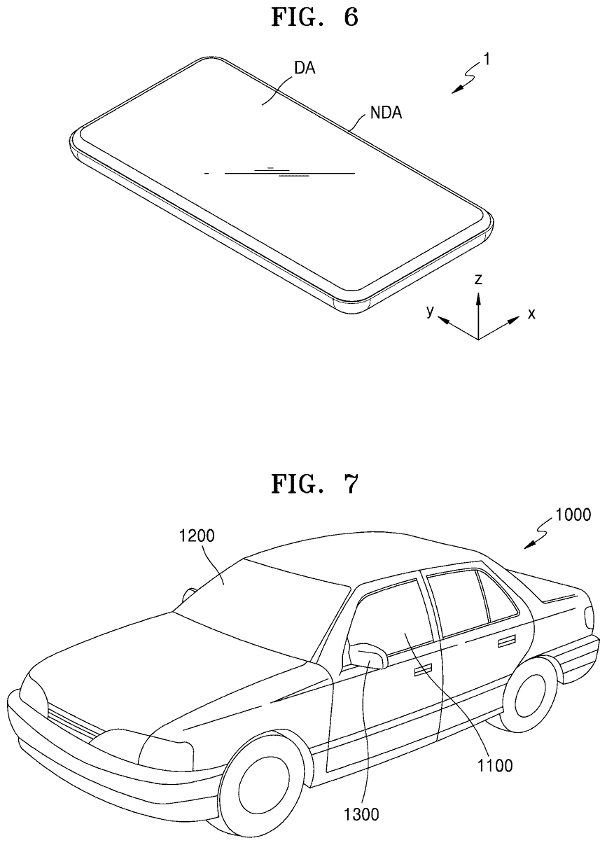

### Description of FIG. 6

FIG. 6 is a schematic perspective view of electronic equipment 1 including a light-emitting device according to one or more embodiments of the present disclosure. The electronic equipment 1 may be, as an electronic apparatus that displays a moving image or a still image, a portable electronic equipment, such as a mobile phone, a smartphone, a tablet personal computer (PC), a mobile communication terminal, an electronic notebook, an electronic book, a portable multimedia player (PMP), a navigation, or an ultra-mobile PC (UMPC), as well as one or more suitable products, such as a television, a laptop, a monitor, a billboard, or an Internet of things (IoT) device. The electronic equipment 1 may be such a product above or a part thereof. In one or more embodiments, the electronic equipment 1 may be a wearable device, such as a smart watch, a watch phone, a glasses-type or kind display, or a head mounted display (HMD), or a part of the wearable device. However, embodiments of the present disclosure are not limited thereto. For example, in one or more embodiments, the electron equipment 1 may include a dashboard of a vehicle, a center information display (CID) arranged on a center fascia or dashboard of a vehicle, a room mirror display that replaces a side mirror of a vehicle, an entertainment display for a rear seat of a vehicle, a display arranged on the back of a front seat thereof, a head-up display (HUD) installed in the front of a vehicle or projected on a front window glass thereof, or a computer generated hologram augmented reality head up display (CGH AR HUD). FIG. 6 illustrates one or more embodiments in which the electronic equipment 1 is a smartphone for convenience of explanation.

The electronic equipment 1 may include a display area DA and a non-display area NDA outside the display area DA. A display apparatus of the electronic equipment may implement an image through an array of a plurality of pixels that are two-dimensionally arranged in the display area DA.

The non-display area NDA is an area that does not display an image, and may entirely be around (e.g., surround) the display area DA. On the non-display area NDA, a driver for providing electrical signals or power to display devices arranged on the display area DA may be arranged. On the non-display area NDA, a pad, which is an area to which an electronic element or a printed circuit board may be electrically connected, may be arranged.

In the electronic equipment 1, a length in the x-axis direction and a length (e.g., a width) in the y-axis direction may be different from each other. In one or more embodiments, as shown in FIG. 6, the length in the x-axis direction may be less than the length (e.g., the width) in the y-axis direction. In one or more embodiments, the length in the x-axis direction may be substantially the same as the length (e.g., the width) in the y-axis direction. In one or more embodiments, the length in the x-axis direction may be greater than the length (e.g., the width) in the y-axis direction.

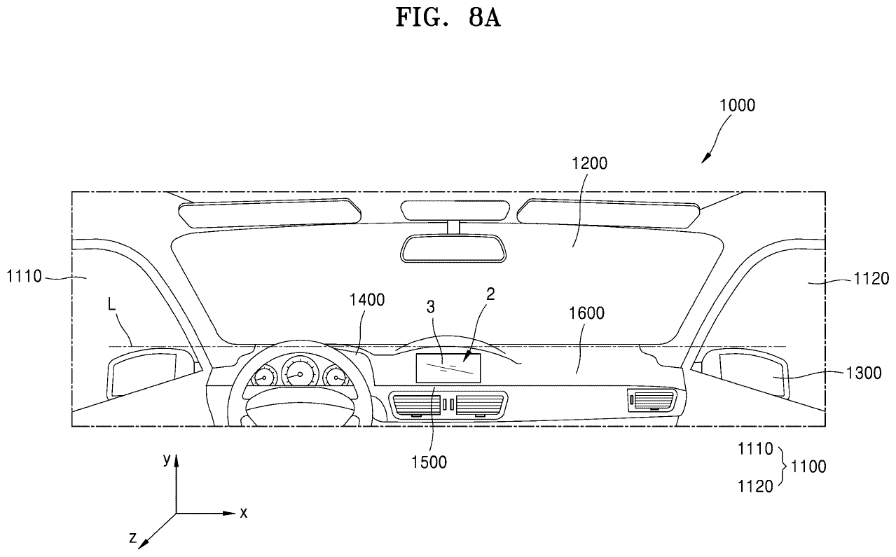

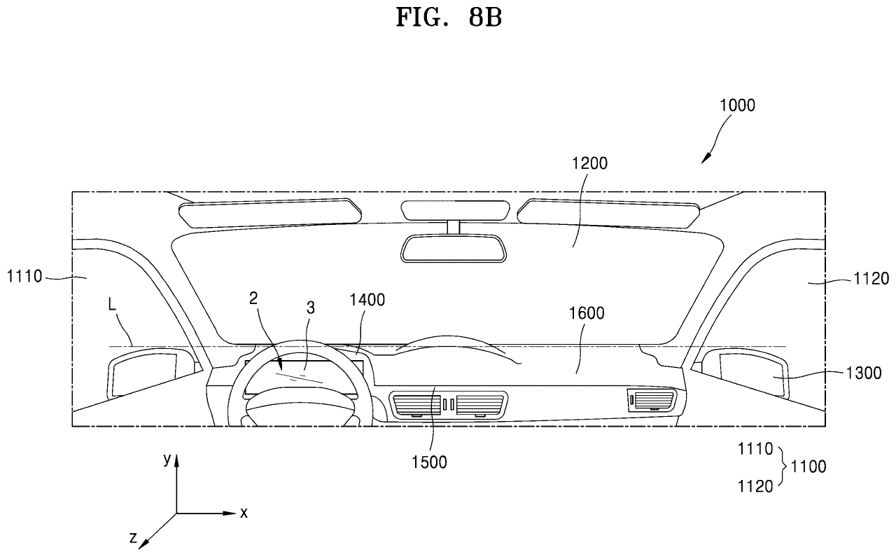

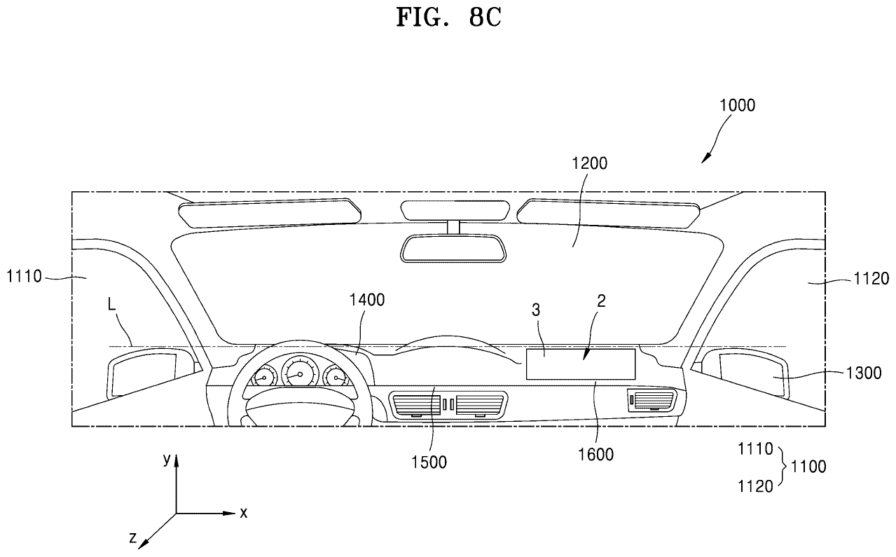

### Descriptions of FIGS. 7 and 8A to 8C

FIG. 7 is a schematic view of an exterior of a vehicle 1000 as electronic equipment including a light-emitting device according to one or more embodiments. FIGS. 8A to 8C are each a schematic view of an interior of the vehicle 1000 according to one or more embodiments.

Referring to FIGS. 7, 8A, 8B, and 8C, the vehicle 1000 may refer to one or more suitable apparatuses for moving an object to be transported, such as a human, an object, or an animal, from a departure point to a destination point. The vehicle 1000 may include a vehicle traveling on a road or a track, a vessel moving over the sea or a river, an airplane flying in the sky using the action of air, and/or the like.

In one or more embodiments, the vehicle 1000 may travel on a road or a track. The vehicle 1000 may move in a certain direction according to rotation of at least one wheel thereof. For example, the vehicle 1000 may include a three-wheeled or four-wheeled vehicle, a construction machine, a two-wheeled vehicle, a prime mover device, a bicycle, or a train running on a track.

The vehicle 1000 may include a body of the vehicle 1000 having an interior and an exterior, and a chassis in which mechanical apparatuses necessary for driving are installed as other parts except for the body of the vehicle 1000. The exterior of the body of the vehicle may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear left and right wheels, and/or the like.

The vehicle 1000 may include a side window glass 1100, a front window glass 1200, a side mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on a side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart (e.g., spaced apart or separated) from each other in the x-direction or the −x-direction (the direction opposite the x-direction). For example, the first side window glass 1110 and the second side window glass 1120 may be spaced and/or apart (e.g., spaced apart or separated) from each other in the x-direction or the −x-direction. For example, an imaginary straight line L connecting the side window glasses 1100 may extend in the x-direction or the −x-direction. For example, in one or more embodiments, an imaginary straight line L connecting the first side window glass 1110 and the second side window glass 1120 to each other may extend in the x-direction or the −x-direction.

The front window glass 1200 may be installed in the front of the vehicle 1000. The front window glass 1200 may be arranged between the side window glasses 1100 opposite to (e.g., facing) each other.

The side mirror 1300 may provide a rear view of the vehicle 1000. The side mirror 1300 may be installed on the exterior of the body of the vehicle 1000. In one or more embodiments, a plurality of side mirrors 1300 may be provided. Any one of the plurality of side mirrors 1300 may be arranged outside the first side window glass 1110. The other one of the plurality of side mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons for adjusting an audio device, an air conditioning device, and/or a seat heater are arranged. The center fascia 1500 may be arranged on one side of the cluster 1400.

The passenger seat dashboard 1600 may be spaced and/or apart (e.g., spaced apart or separated) from the cluster 1400, and the center fascia 1500 may be arranged between the cluster 1400 and the passenger seat dashboard 1600. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display apparatus 2 may include a display panel 3, and the display panel 3 may display an image. The display apparatus 2 may be arranged inside the vehicle 1000. In one or more embodiments, the display apparatus 2 may be arranged between the side window glasses 1100 opposite to (e.g., facing) each other. The display apparatus 2 may be arranged on at least one of the cluster 1400, the center fascia 1500, or the passenger seat dashboard 1600.

The display apparatus 2 may include an organic light-emitting display apparatus, an inorganic light-emitting display apparatus, a quantum dot display apparatus, and/or the like. Hereinafter, as the display apparatus 2 according to one or more embodiments, an organic light-emitting display apparatus including the light-emitting device according to the disclosure will be described as an example, but one or more suitable types (kinds) of display apparatuses as described above may be used in embodiments.

Referring to FIG. 8A, in one or more embodiments, the display apparatus 2 may be arranged on the center fascia 1500. In one or more embodiments, the display apparatus 2 may display navigation information. In one or more embodiments, the display apparatus 2 may display information regarding audio settings, video setting, or vehicle settings.

Referring to FIG. 8B, in one or more embodiments, the display apparatus 2 may be arranged on the cluster 1400. In these embodiments, the cluster 1400 may display driving information and/or the like through the display apparatus 2. For example, the cluster 1400 may digitally implement driving information and/or the like. In one or more embodiments, the cluster 1400 may digitally display vehicle information and driving information as images. For example, a needle and a gauge of a tachometer and one or more suitable warning light icons may be displayed by a digital signal.

Referring to FIG. 8C, in one or more embodiments, the display apparatus 2 may be arranged on the passenger seat dashboard 1600. The display apparatus 2 may be embedded in the passenger seat dashboard 1600 or arranged on the passenger seat dashboard 1600. In one or more embodiments, the display apparatus 2 arranged on the passenger seat dashboard 1600 may display an image related to information displayed on the cluster 1400 and/or information displayed on the center fascia 1500. In one or more embodiments, the display apparatus 2 arranged on the passenger seat dashboard 1600 may display information different from information displayed on the cluster 1400 and/or information displayed on the center fascia 1500.

### Manufacturing Method

The layers constituting the hole transport region, the emission layer, and the layers constituting the electron transport region may each be formed in a certain region by using one or more suitable methods such as vacuum deposition, spin coating, casting, Langmuir-Blodgett (LB) deposition, ink-jet printing, laser-printing, laser-induced thermal imaging, and/or the like.

When the layers constituting the hole transport region, the emission layer, and the layers constituting the electron transport region are each formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### Definition of Terms

The term “C₃-C₆₀ carbocyclic group” as used herein refers to a cyclic group including (e.g., consisting of) carbon atoms as the only ring-forming atoms and having 3 to 60 carbon atoms, and the term “C₁-C₆₀ heterocyclic group” as used herein refers to a cyclic group that has 1 to 60 carbon atoms and further includes, in addition to a carbon atom, a heteroatom as a ring-forming atom. The C₃-C₆₀ carbocyclic group and the C₁-C₆₀ heterocyclic group may each be: a monocyclic group including (e.g., consisting of) one (e.g., exactly one) ring; or a polycyclic group in which two or more rings are condensed with each other. For example, the number of ring-forming atoms of the C₁-C₆₀ heterocyclic group may be from 3 to 61.

The term “cyclic group” as used herein may include both (e.g., simultaneously) the C₃-C₆₀ carbocyclic group and the C₁-C₆₀ heterocyclic group.

The term “π electron-rich C₃-C₆₀ cyclic group” as used herein refers to a cyclic group that has 3 to 60 carbon atoms and does not include *—N═*′ as a ring-forming moiety, and the term “π electron-deficient nitrogen-containing C₁-C₆₀ cyclic group” as used herein refers to a heterocyclic group that has 1 to 60 carbon atoms and includes *—N═*′ as a ring-forming moiety.

For example,
the C₃-C₆₀ carbocyclic group may be i) Group T1 or ii) a condensed cyclic group in which two or more of Group T1 are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T₃ and at least one Group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ cyclic group may be i) Group T4, ii) a condensed cyclic group in which two or more of Group T4 are condensed with each other, iii) a condensed cyclic group in which at least one Group T₄ and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and
Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group,” “C₃-C₆₀ carbocyclic group,” “C₁-C₆₀ heterocyclic group,” “π electron-rich C₅-C₆₀ cyclic group,” and “π electron-deficient nitrogen-containing C₁-C₆₀ cyclic group” as used herein each refer to a group condensed to any cyclic group, a monovalent group, or a polyvalent group (e.g., a divalent group, a trivalent group, a tetravalent group, and/or the like) according to the structure of a formula for which the corresponding term is used. For example, the “benzene group” may be a benzo group, a phenyl group, a phenylene group, and/or the like, which may be easily understood by one of ordinary skill in the art according to the structure of a formula including the “benzene group.”

Non-limiting examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and non-limiting examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has 1 to 60 carbon atoms, and non-limiting examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and/or the like. The term “C₁-C₆₀ alkylene group” as used herein refers to a divalent group having substantially the same structure as the C₁-C₆₀ alkyl group.

The term “C₂-C₆₀ alkenyl group” as used herein refers to a monovalent hydrocarbon group having at least one carbon-carbon double bond in the middle or at the terminus of a C₂-C₆₀ alkyl group, and non-limiting examples thereof may include an ethenyl group, a propenyl group, a butenyl group, and/or the like. The term “C₂-C₆₀ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of a C₂-C₆₀ alkyl group, and non-limiting examples thereof may include an ethynyl group, a propynyl group, and/or the like. The term “C₂-C₆₀ alkynylene group” as used herein refers to a divalent group having substantially the same structure as the

C₂-C₆₀ alkynyl group.

The term “C₁-C₆₀ alkoxy group” as used herein refers to a monovalent group represented by —OA₁₀₁ (wherein A₁₀₁ is a C₁-C₆₀ alkyl group), and non-limiting examples thereof may include a methoxy group, an ethoxy group, an isopropyloxy group, and/or the like.

The term “C₃-C₁₀ cycloalkyl group” as used herein refers to a monovalent saturated hydrocarbon cyclic group having 3 to 10 carbon atoms, and non-limiting examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and/or the like. The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a monovalent cyclic group that 1 one to 10 carbon atoms and further includes, in addition to a carbon atom, at least one heteroatom as a ring-forming atom, and non-limiting examples thereof may include a 1,2,3,4-oxatriazolidinyl group, a tetrahydrofuranyl group, a tetrahydrothiophenyl group, and/or the like. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent cyclic group that has 3 to 10 carbon atoms and at least one carbon-carbon double bond in the ring thereof and no aromaticity, and non-limiting examples thereof may include a cyclopentenyl group, a cyclohexenyl group, a cycloheptenyl group, and/or the like. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group that has 1 to 10 carbon atoms, further includes, in addition to a carbon atom, at least one heteroatom as a ring-forming atom, and has at least one double bond in the ring thereof. Non-limiting examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and/or the like. The term “C₁-C₁₀ heterocycloalkenylene group” as used herein refers to a divalent group having substantially the same structure as the C₁-C₁₀ heterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Non-limiting examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like. When the C₆-C₆₀ aryl group and the C₆-C₆₀ arylene group each include two or more rings, the two or more rings may be condensed with each other.

The term “C₁-C₆₀ heteroaryl group” as used herein refers to a monovalent group having a heterocyclic aromatic system of 1 to 60 carbon atoms, further including, in addition to a carbon atom, at least one heteroatom as a ring-forming atom. The term “C₁-C₆₀ heteroarylene group” as used herein refers to a divalent group having a heterocyclic aromatic system of 1 to 60 carbon atoms, further including, in addition to a carbon atom, at least one heteroatom as a ring-forming atom. Non-limiting examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and/or the like. When the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group (e.g., having 8 to 60 carbon atoms) having two or more rings condensed to each other, only carbon atoms as ring-forming atoms, and no aromaticity in its entire molecular structure as a whole. Non-limiting examples of the monovalent non-aromatic condensed polycyclic group may include an indenyl group, a fluorenyl group, a spiro-bifluorenyl group, a benzofluorenyl group, an indenophenanthrenyl group, an indeno anthracenyl group, and/or the like. The term “divalent non-aromatic condensed polycyclic group” as used herein refers to a divalent group having substantially the same structure as the monovalent non-aromatic condensed polycyclic group.

The term “monovalent non-aromatic condensed heteropolycyclic group” as used herein refers to a monovalent group (e.g., having 1 to 60 carbon atoms) having two or more rings condensed to each other, further including, in addition to a carbon atom, at least one heteroatom as a ring-forming atom, and having no aromaticity in its entire molecular structure as a whole. Non-limiting examples of the monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and/or the like. The term “divalent non-aromatic condensed heteropolycyclic group” as used herein refers to a divalent group having substantially the same structure as the monovalent non-aromatic condensed heteropolycyclic group.

The term “C₆-C₆₀ aryloxy group” as used herein refers to —OA₁₀₂ (wherein A₁₀₂ is a C₆-C₆₀ aryl group), and the term “C₆-C₆₀ arylthio group” as used herein refers to —SA₁₀₃ (wherein A₁₀₃ is a C₆-C₆₀ aryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ as used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₅-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as used herein refers to any atom other than a carbon atom. non-limiting examples of the heteroatom may include O, S, N, P, Si, B, Ge, Se, or any combination thereof.

The term “transition metal” as used herein may include hafnium (Hf), tantalum (Ta), tungsten (W), rhenium (Re), osmium (Os), iridium (Ir), platinum (Pt), gold (Au), and/or the like.

The term “Ph” as used herein refers to a phenyl group, the term “Me” as used herein refers to a methyl group, the term “Et” as used herein refers to an ethyl group, the term “tert-Bu” or “But” as used herein refers to a tert-butyl group, and the term “OMe” as used herein refers to a methoxy group.

The term “biphenyl group” as used herein refers to “a phenyl group substituted with a phenyl group.” For example, the “biphenyl group” may be a substituted phenyl group having a C₆-C₆₀ aryl group as a substituent.

The term “terphenyl group” as used herein refers to “a phenyl group substituted with a biphenyl group.” For example, the “terphenyl group” may be a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula or moiety.

The terms “x-axis,” “y-axis,” and “z-axis” as used herein are not limited to three axes in an orthogonal coordinate system, and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, heterocyclic compounds according to one or more embodiments and light-emitting devices according to one or more embodiments will be described in more detail with reference to Synthesis Examples and Examples. The wording “B was used instead of A” used in describing Synthesis Examples refers to that an substantially identical molar equivalent of B was used in place of A.

### EXAMPLES

### Synthesis Example 1: Synthesis of Compound 1

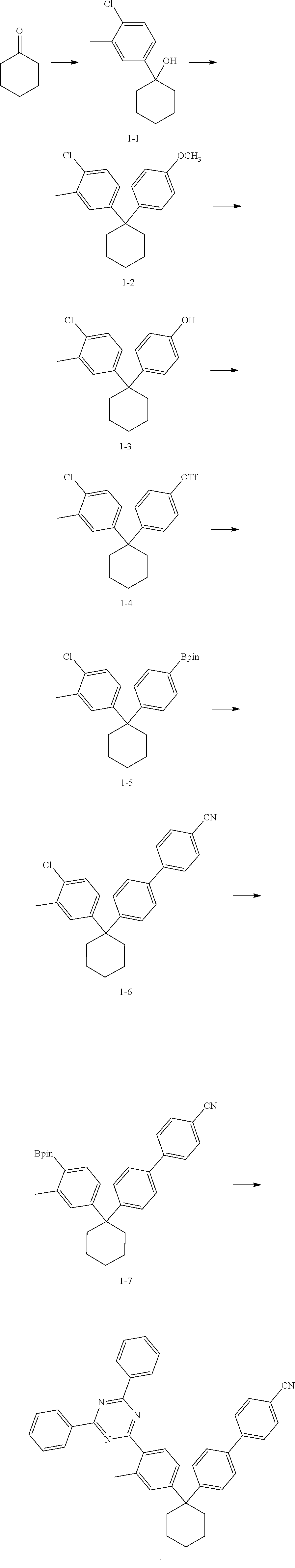

### Synthesis of Intermediate Compound 1-1

Tetrahydrofuran (THF) was added to 4-bromo-1-chloro-2-methylbenzene (1.0 eq.), and the resultant reaction solution was cooled to −78° C. N-butyllithium (1.05 eq.) was slowly added dropwise to the reaction solution under a nitrogen atmosphere, followed by stirring at −78° C. for 1 hour. Cyclohexanone (1.1 eq.) dissolved in THF was slowly added dropwise to the reaction solution at −78° C., followed by stirring at room temperature for 4 hours. Then, the reaction product was washed three times with ethyl acetate and water (e.g., 1) The reaction mixture was combined with ethyl acetate (an organic solvent) and water. This created two layers: an organic layer (containing ethyl acetate and the desired product) and an aqueous layer (containing water and water-soluble impurities); 2) The two layers were separated. The organic layer, which contains the product, was kept, while the aqueous layer, which contains impurities, was discarded; and 3) This washing process was repeated three times to ensure that as many impurities as possible were removed from the organic layer), and the resulting organic layer was dried over MgSO₄ (a drying agent) first and then dried again under reduced pressure. Compound 1-1 was obtained by column chromatography. (Yield: 67%)

### Synthesis of Intermediate Compound 1-2

Anisole was added to Compound 1-1 (1.0 eq.), and the resultant reaction solution was cooled to 0° C. Trifluoroacetic acid (3.0 eq.) was added dropwise to the reaction solution, followed by stirring at room temperature for 2 hours. The reaction product was then washed three times with ethyl acetate and water, and the resulting organic layer was dried over MgSO₄ first and then dried again under reduced pressure. Compound 1-2 was obtained by column chromatography. (Yield: 91%)

### Synthesis of Intermediate Compound 1-3

Dichloromethane (DCM) was added to Compound 1-2 (1.0 eq.), and the resultant reaction solution was cooled to 0° C. Tribromoborane (5.0 eq.) was slowly added dropwise to the reaction solution, followed by stirring at 0° C. for 4 hours. Diisopropylethylamine (5.0 eq.) was slowly added dropwise to the reaction solution at −78° C., followed by stirring at room temperature for 1 hour. A sodium bicarbonate aqueous solution was cooled to 0° C., and the reaction solution was slowly added dropwise thereto to perform neutralization thereon. Then, the reaction product was washed three times with ethyl acetate and water, and the resulting organic layer was dried over MgSO₄ first and then dried again under reduced pressure. Compound 1-3 was obtained by column chromatography. (Yield: 81%)

### Synthesis of Intermediate Compound 1-4

DCM was added to Compound 1-3 (1.0 eq.), and the resultant reaction solution was cooled to 0° C. Diisopropylethylamine (3.0 eq.) was added to the reaction solution, and trifluoromethanesulfonic anhydride (2.0 eq.) was slowly added dropwise thereto at 0° C., followed by stirring at room temperature for 4 hours. The reaction product was then washed three times with ethyl acetate and water, and the resulting organic layer was dried over MgSO₄ first and then dried again under reduced pressure. Compound 1-4 was obtained by column chromatography. (Yield: 85%)

### Synthesis of Intermediate Compound 1-5

Compound 1-4 (1.0 eq.), 4,4,4′,4′,5,5,5′,5′-octamethyl-2,2′-bi(1,3,2-dioxaborolane) (1.2 eq.), [1,1′-bis(diphenylphosphino)ferrocene]dichloropalladium (0.05 eq.), and potassium acetate (3.0 eq.) were dissolved in 1,4-dioxane, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 1-5 was obtained by column chromatography. (Yield: 72%)

### Synthesis of Intermediate Compound 1-6

Compound 1-5 (1.0 eq.), 4-bromobenzonitrile (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 1-6 was obtained by column chromatography. (Yield: 74%)

### Synthesis of Intermediate Compound 1-7

Compound 1-6 (1.0 eq.), 4,4,4′,4′,5,5,5′,5′-octamethyl-2,2′-bi(1,3,2-dioxaborolane) (1.2 eq.), palladium(II)acetate (0.05 eq.), 2-dicyclohexylphosphino-2′,6′-dimethoxybiphenyl (Sphos) (0.06 eq.), and potassium acetate (3.0 eq.) were dissolved in xylene, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 1-7 was obtained by column chromatography. (Yield: 52%)

### Synthesis of Intermediate Compound 1

Compound 1-7 (1.0 eq.), 2-chloro-4,6-diphenyl-1,3,5-triazine (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 1 was obtained by column chromatography. (Yield: 80%) By Fast atom bombardment-Mass spectroscopy (FAB-MS), mass number m/z=582.28 was observed as a molecular ion peak. Thus, Compound 1 was identified.

### Synthesis Example 2: Synthesis of Compound 3

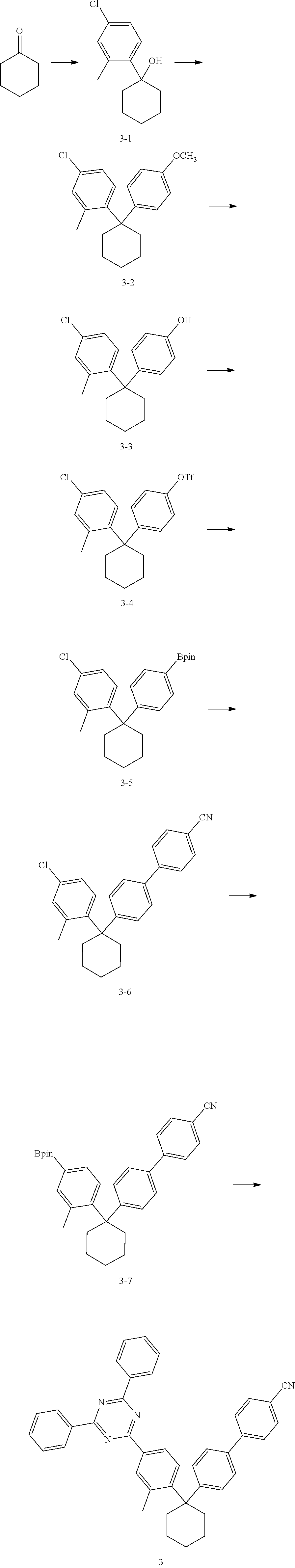

### Synthesis of Intermediate Compound 3-1

THF was added to 1-bromo-4-chloro-2-methylbenzene (1.0 eq.), and the resultant reaction solution was cooled to −78° C. N-butyllithium (1.05 eq.) was slowly added dropwise to the reaction solution under a nitrogen atmosphere, followed by stirring at −78° C. for 1 hour. Cyclohexanone (1.1 eq.) dissolved in THF was slowly added dropwise to the reaction solution at −78° C., followed by stirring at room temperature for 4 hours. Then, the reaction product was washed three times with ethyl acetate and water, and the resulting organic layer was dried over MgSO₄ first and then dried again under reduced pressure. Compound 3-1 was obtained by column chromatography. (Yield: 60%)

### Synthesis of Intermediate Compound 3-2

Anisole was added to Compound 3-1 (1.0 eq.), and the resultant reaction solution was cooled to 0° C. Trifluoroacetic acid (3.0 eq.) was added dropwise to the reaction solution, followed by stirring at room temperature for 2 hours. The reaction product was then washed three times with ethyl acetate and water, and the resulting organic layer was dried over MgSO₄ first and then dried again under reduced pressure. Compound 3-2 was obtained by column chromatography. (Yield: 90%)

### Synthesis of Intermediate Compound 3-3

DCM was added to Compound 3-2 (1.0 eq.), and the resultant reaction solution was cooled to 0° C. Tribromoborane (5.0 eq.) was slowly added dropwise to the reaction solution, followed by stirring at 0° C. for 4 hours. Diisopropylethylamine (5.0 eq.) was slowly added dropwise to the reaction solution at −78° C., followed by stirring at room temperature for 1 hour. A sodium bicarbonate aqueous solution was cooled to 0° C., and the reaction solution was slowly added dropwise thereto to perform neutralization thereon. Then, the reaction product was washed three times with ethyl acetate and water, and the resulting organic layer was dried over MgSO₄ first and then dried again under reduced pressure. Compound 3-3 was obtained by column chromatography. (Yield: 83%)

### Synthesis of Intermediate Compound 3-4

DCM was added to Compound 3-3 (1.0 eq.), and the resultant reaction solution was cooled to 0° C. Diisopropylethylamine (3.0 eq.) was added to the reaction solution, and trifluoromethanesulfonic anhydride (2.0 eq.) was slowly added dropwise thereto at 0° C., followed by stirring at room temperature for 4 hours. The reaction product was then washed three times with ethyl acetate and water, and the resulting organic layer was dried over MgSO₄ first and then dried again under reduced pressure. Compound 3-4 was obtained by column chromatography. (Yield: 88%)

### Synthesis of Intermediate Compound 3-5

Compound 3-4 (1.0 eq.), 4,4,4′,4′,5,5,5′,5′-octamethyl-2,2′-bi(1,3,2-dioxaborolane) (1.2 eq.), [1,1′-bis(diphenylphosphino)ferrocene]dichloropalladium (0.05 eq.), and potassium acetate (3.0 eq.) were dissolved in 1,4-dioxane, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 3-5 was obtained by column chromatography. (Yield: 80%)

### Synthesis of Intermediate Compound 3-6

Compound 3-5 (1.0 eq.), 4-bromobenzonitrile (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 3-6 was obtained by column chromatography. (Yield: 71%)

### Synthesis of Intermediate Compound 3-7

Compound 3-6 (1.0 eq.), 4,4,4′,4′,5,5,5′,5′-octamethyl-2,2′-bi(1,3,2-dioxaborolane) (1.2 eq.), palladium(II)acetate (0.05 eq.), Sphos (0.06 eq.), and potassium acetate (3.0 eq.) were dissolved in xylene, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 3-7 was obtained by column chromatography. (Yield: 50%)

### Synthesis of Intermediate Compound 3

Compound 3-7 (1.0 eq.), 2-chloro-4,6-diphenyl-1,3,5-triazine (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 3 was obtained by column chromatography. (Yield: 77%) By FAB-MS, mass number m/z=582.28 was observed as a molecular ion peak. Thus, Compound 3 was identified.

### Synthesis Example 3: Synthesis of Compound 16

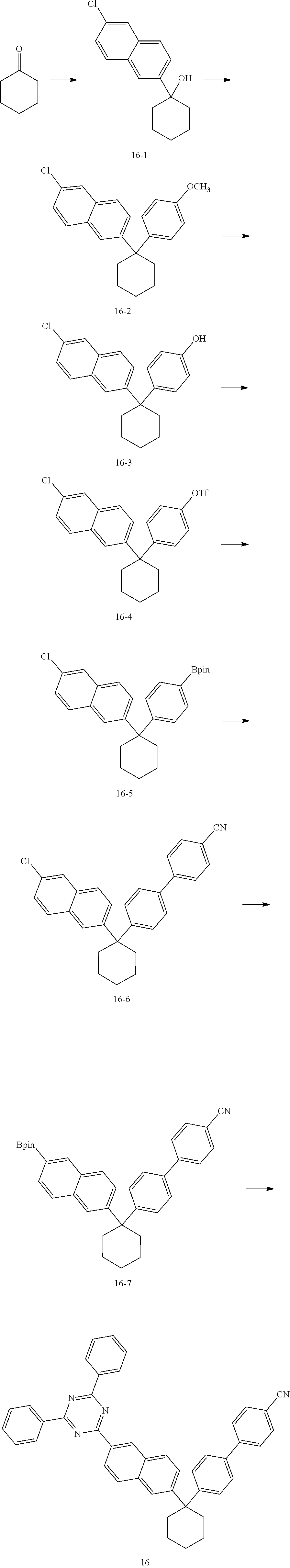

### Synthesis of Intermediate Compound 16-1

THF was added to 2-bromo-6-chloronaphthalene (1.0 eq.), and the resultant reaction solution was cooled to −78° C. N-butyllithium (1.05 eq.) was slowly added dropwise to the reaction solution under a nitrogen atmosphere, followed by stirring at −78° C. for 1 hour. Cyclohexanone (1.1 eq.) dissolved in THF was slowly added dropwise to the reaction solution at −78° C., followed by stirring at room temperature for 4 hours. Then, the reaction product was washed three times with ethyl acetate and water, and the resulting organic layer was dried over MgSO₄ first and then dried again under reduced pressure. Compound 16-1 was obtained by column chromatography. (Yield: 67%)

### Synthesis of Intermediate Compound 16-2

Anisole was added to Compound 16-1 (1.0 eq.), and the resultant reaction solution was cooled to 0° C. Trifluoroacetic acid (3.0 eq.) was added dropwise to the reaction solution, followed by stirring at room temperature for 2 hours. The reaction product was then washed three times with ethyl acetate and water, and the resulting organic layer was dried over MgSO₄ first and then dried again under reduced pressure. Compound 16-2 was obtained by column chromatography. (Yield: 80%)

### Synthesis of Intermediate Compound 16-3

DCM was added to Compound 16-2 (1.0 eq.), and the resultant reaction solution was cooled to 0° C. Tribromoborane (5.0 eq.) was slowly added dropwise to the reaction solution, followed by stirring at 0° C. for 4 hours. Diisopropylethylamine (5.0 eq.) was slowly added dropwise to the reaction solution at −78° C., followed by stirring at room temperature for 1 hour. A sodium bicarbonate aqueous solution was cooled to 0° C., and the reaction solution was slowly added dropwise thereto to perform neutralization thereon. Then, the reaction product was washed three times with ethyl acetate and water, and the resulting organic layer was dried over MgSO₄ first and then dried again under reduced pressure. Compound 16-3 was obtained by column chromatography. (Yield: 85%)

### Synthesis of Intermediate Compound 16-4

DCM was added to Compound 16-3 (1.0 eq.), and the resultant reaction solution was cooled to 0° C. Diisopropylethylamine (3.0 eq.) was added to the reaction solution, and trifluoromethanesulfonic anhydride (2.0 eq.) was slowly added dropwise thereto at 0° C., followed by stirring at room temperature for 4 hours. The reaction product was then washed three times with ethyl acetate and water, and the resulting organic layer was dried over MgSO₄ first and then dried again under reduced pressure. Compound 16-4 was obtained by column chromatography. (Yield: 87%)

### Synthesis of Intermediate Compound 16-5

Compound 16-4 (1.0 eq.), 4,4,4′,4′,5,5,5′,5′-octamethyl-2,2′-bi(1,3,2-dioxaborolane) (1.2 eq.), [1,1′-bis(diphenylphosphino)ferrocene]dichloropalladium (0.05 eq.), and potassium acetate (3.0 eq.) were dissolved in 1,4-dioxane, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 16-5 was obtained by column chromatography. (Yield: 82%)

### Synthesis of Intermediate Compound 16-6

Compound 16-5 (1.0 eq.), 4-bromobenzonitrile (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 16-6 was obtained by column chromatography. (Yield: 72%)

### Synthesis of Intermediate Compound 16-7

Compound 16-6 (1.0 eq.), 4,4,4′,4′,5,5,5′,5′-octamethyl-2,2′-bi(1,3,2-dioxaborolane) (1.2 eq.), palladium(II)acetate (0.05 eq.), Sphos (0.06 eq.), and potassium acetate (3.0 eq.) were dissolved in xylene, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 16-7 was obtained by column chromatography. (Yield: 55%)

### Synthesis of Compound 16

Compound 1-7 (1.0 eq.), 2-chloro-4,6-diphenyl-1,3,5-triazine (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 16 was obtained by column chromatography. (Yield: 84%) By FAB-MS, mass number m/z=618.28 was observed as a molecular ion peak. Thus, Compound 16 was identified.

### Synthesis Example 4: Synthesis of Compound 17

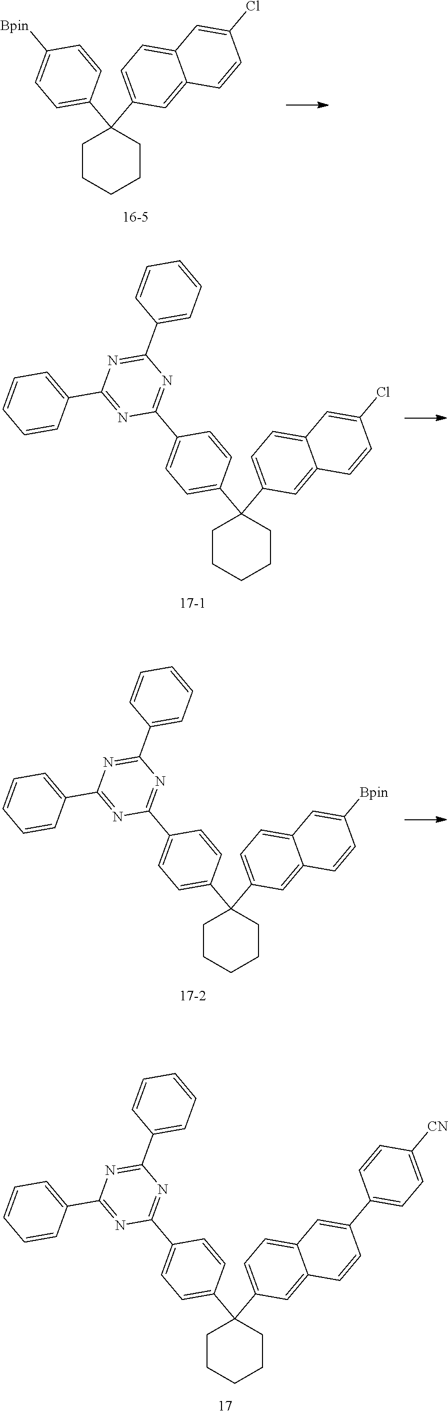

### Synthesis of Intermediate Compound 17-1

Compound 16-5 (1.0 eq.), 2-chloro-4,6-diphenyl-1,3,5-triazine (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 17-1 was obtained by column chromatography. (Yield: 75%)

### Synthesis of Intermediate Compound 17-2

Compound 17-1 (1.0 eq.), 4,4,4′,4′,5,5,5′,5′-octamethyl-2,2′-bi(1,3,2-dioxaborolane) (1.2 eq.), palladium(II)acetate (0.05 eq.), Sphos (0.06 eq.), and potassium acetate (3.0 eq.) were dissolved in xylene, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 17-2 was obtained by column chromatography. (Yield: 65%)

### Synthesis of Intermediate Compound 17

Compound 17-2 (1.0 eq.), 4-bromobenzonitrile (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 17 was obtained by column chromatography. (Yield: 84%) By FAB-MS, mass number m/z=618.28 was observed as a molecular ion peak. Thus, Compound 17 was identified.

### Synthesis Example 5: Synthesis of Compound 21

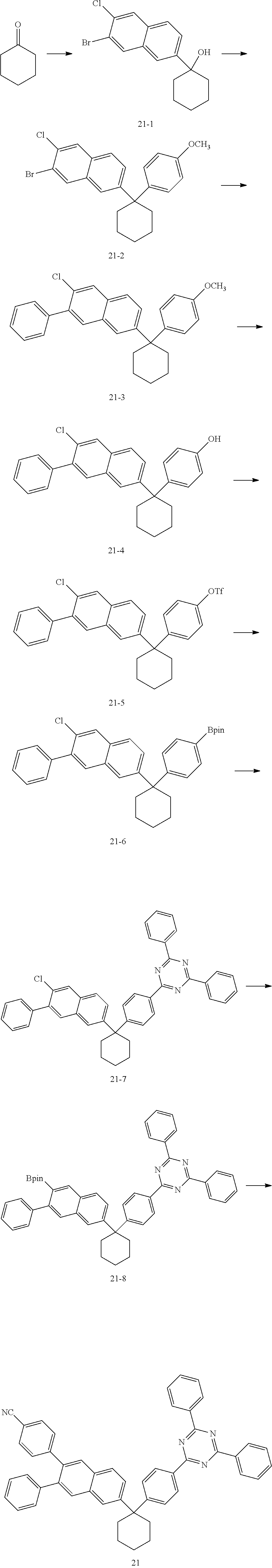

### Synthesis of Intermediate Compound 21-1

THF was added to 3-bromo-2-chloro-6-iodonaphthalene (1.0 eq.), and the resultant reaction solution was cooled to −78° C. N-butyllithium (1.05 eq.) was slowly added dropwise to the reaction solution under a nitrogen atmosphere, followed by stirring at −78° C. for 1 hour. Cyclohexanone (1.1 eq.) dissolved in THF was slowly added dropwise to the reaction solution at −78° C., followed by stirring at room temperature for 4 hours. Then, the reaction product was washed three times with ethyl acetate and water, and the resulting organic layer was dried over MgSO₄ first and then dried again under reduced pressure. Compound 21-1 was obtained by column chromatography. (Yield: 77%)

### Synthesis of Intermediate Compound 21-2

Anisole was added to Compound 21-1 (1.0 eq.), and the resultant reaction solution was cooled to 0° C. Trifluoroacetic acid (3.0 eq.) was added dropwise to the reaction solution, followed by stirring at room temperature for 2 hours. The reaction product was then washed three times with ethyl acetate and water, and the resulting organic layer was dried over MgSO₄ first and then dried again under reduced pressure. Compound 21-2 was obtained by column chromatography. (Yield: 91%)

### Synthesis of Intermediate Compound 21-3

Compound 21-2 (1.0 eq.), phenylboronic acid (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 21-3 was obtained by column chromatography. (Yield: 74%)

### Synthesis of Intermediate Compound 21-4

DCM was added to Compound 21-3 (1.0 eq.), and the resultant reaction solution was cooled to 0° C. Tribromoborane (5.0 eq.) was slowly added dropwise to the reaction solution, followed by stirring at 0° C. for 4 hours. Diisopropylethylamine (5.0 eq.) was slowly added dropwise to the reaction solution at −78° C., followed by stirring at room temperature for 1 hour. A sodium bicarbonate aqueous solution was cooled to 0° C., and the reaction solution was slowly added dropwise thereto to perform neutralization thereon. Then, the reaction product was washed three times with ethyl acetate and water, and the resulting organic layer was dried over MgSO₄ first and then dried again under reduced pressure. Compound 21-4 was obtained by column chromatography. (Yield: 81%)

### Synthesis of Intermediate Compound 21-5

DCM was added to Compound 21-4 (1.0 eq.), and the resultant reaction solution was cooled to 0° C. Diisopropylethylamine (3.0 eq.) was added to the reaction solution, and trifluoromethanesulfonic anhydride (2.0 eq.) was slowly added dropwise thereto at 0° C., followed by stirring at room temperature for 4 hours. The reaction product was then washed three times with ethyl acetate and water, and the resulting organic layer was dried over MgSO₄ first and then dried again under reduced pressure. Compound 21-5 was obtained by column chromatography. (Yield: 85%)

### Synthesis of Intermediate Compound 21-6

Compound 21-5 (1.0 eq.), 4,4,4′,4′,5,5,5′,5′-octamethyl-2,2′-bi(1,3,2-dioxaborolane) (1.2 eq.), [1,1′-bis(diphenylphosphino)ferrocene]dichloropalladium (0.05 eq.), and potassium acetate (3.0 eq.) were dissolved in 1,4-dioxane, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 21-6 was obtained by column chromatography. (Yield: 72%)

### Synthesis of Intermediate Compound 21-7

Compound 21-6 (1.0 eq.), 2-chloro-4,6-diphenyl-1,3,5-triazine (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 21-7 was obtained by column chromatography. (Yield: 74%)

### Synthesis of Intermediate Compound 21-8

Compound 21-7 (1.0 eq.), 4,4,4′,4′,5,5,5′,5′-octamethyl-2,2′-bi(1,3,2-dioxaborolane) (1.2 eq.), palladium(II)acetate (0.05 eq.), Sphos (0.06 eq.), and potassium acetate (3.0 eq.) were dissolved in xylene, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 21-8 was obtained by column chromatography. (Yield: 52%)

### Synthesis of Intermediate Compound 21

Compound 21-8 (1.0 eq.), 4-bromobenzonitrile (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 21 was obtained by column chromatography. (Yield: 80%) By FAB-MS, mass number m/z=694.31 was observed as a molecular ion peak. Thus, Compound 21 was identified.

### Synthesis Example 6: Synthesis of Compound 22

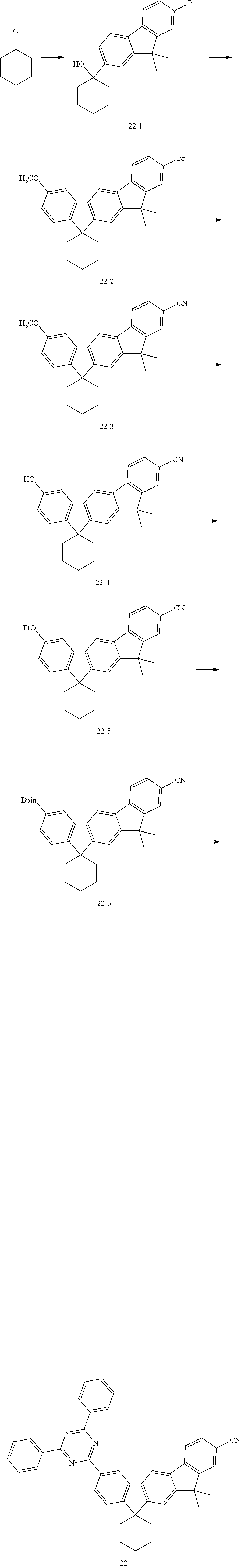

### Synthesis of Intermediate Compound 22-1

THF was added to 2,7-dibromo-9,9-dimethyl-9H-fluorene (1.0 eq.), and the resultant reaction solution was cooled to −78° C. N-butyllithium (1.05 eq.) was slowly added dropwise to the reaction solution under a nitrogen atmosphere, followed by stirring at −78° C. for 1 hour. Cyclohexanone (1.1 eq.) dissolved in THF was slowly added dropwise to the reaction solution at −78° C., followed by stirring at room temperature for 4 hours. Then, the reaction product was washed three times with ethyl acetate and water, and the resulting organic layer was dried over MgSO₄ first and then dried again under reduced pressure. Compound 22-1 was obtained by column chromatography. (Yield: 67%)

### Synthesis of Intermediate Compound 22-2

Anisole was added to Compound 22-1 (1.0 eq.), and the resultant reaction solution was cooled to 0° C. Trifluoroacetic acid (3.0 eq.) was added dropwise to the reaction solution, followed by stirring at room temperature for 2 hours. The reaction product was then washed three times with ethyl acetate and water, and the resulting organic layer was dried over MgSO₄ first and then dried again under reduced pressure. Compound 22-2 was obtained by column chromatography. (Yield: 91%)

### Synthesis of Intermediate Compound 22-3

Compound 22-2 (1.0 eq.) and copper(I) cyanide (1.0 eq.) were dissolved in dimethylformamide (DMF), and the resultant reaction solution was stirred at 160° C. for 24 hours under a nitrogen atmosphere. After cooling, the reaction product was washed three times with ethyl acetate and water, and the resulting organic layer was dried over MgSO₄ first and then dried again under reduced pressure. Compound 22-3 was obtained by column chromatography. (Yield: 72%)

### Synthesis of Intermediate Compound 22-4

DCM was added to Compound 22-3 (1.0 eq.), and the resultant reaction solution was cooled to 0° C. Tribromoborane (5.0 eq.) was slowly added dropwise to the reaction solution, followed by stirring at 0° C. for 4 hours. Diisopropylethylamine (5.0 eq.) was slowly added dropwise to the reaction solution at −78° C., followed by stirring at room temperature for 1 hour. A sodium bicarbonate aqueous solution was cooled to 0° C., and the reaction solution was slowly added dropwise thereto to perform neutralization thereon. Then, the reaction product was washed three times with ethyl acetate and water, and the resulting organic layer was dried over MgSO₄ first and then dried again under reduced pressure. Compound 22-4 was obtained by column chromatography. (Yield: 81%)

### Synthesis of Intermediate Compound 22-5

DCM was added to Compound 22-4 (1.0 eq.), and the resultant reaction solution was cooled to 0° C. Diisopropylethylamine (3.0 eq.) was added to the reaction solution, and trifluoromethanesulfonic anhydride (2.0 eq.) was slowly added dropwise thereto at 0° C., followed by stirring at room temperature for 4 hours. The reaction product was then washed three times with ethyl acetate and water, and the resulting organic layer was dried with MgSO₄ first and then dried again under reduced pressure.

### Synthesis of Intermediate Compound 22-6

Compound 22-5 was obtained by column chromatography. (Yield: 85%) Compound 22-5 (1.0 eq.), 4,4,4′,4′,5,5,5′,5′-octamethyl-2,2′-bi(1,3,2-dioxaborolane) (1.2 eq.), [1,1′-bis(diphenylphosphino)ferrocene]dichloropalladium (0.05 eq.), and potassium acetate (3.0 eq.) were dissolved in 1,4-dioxane, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 22-6 was obtained by column chromatography. (Yield: 72%)

### Synthesis of Compound 22

Compound 22-6 (1.0 eq.), 2-chloro-4,6-diphenyl-1,3,5-triazine (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 22 was obtained by column chromatography. (Yield: 74%) By FAB-MS, mass number m/z=608.29 was observed as a molecular ion peak. Thus, Compound 22 was identified.

### Synthesis Example 7: Synthesis of Compound 45

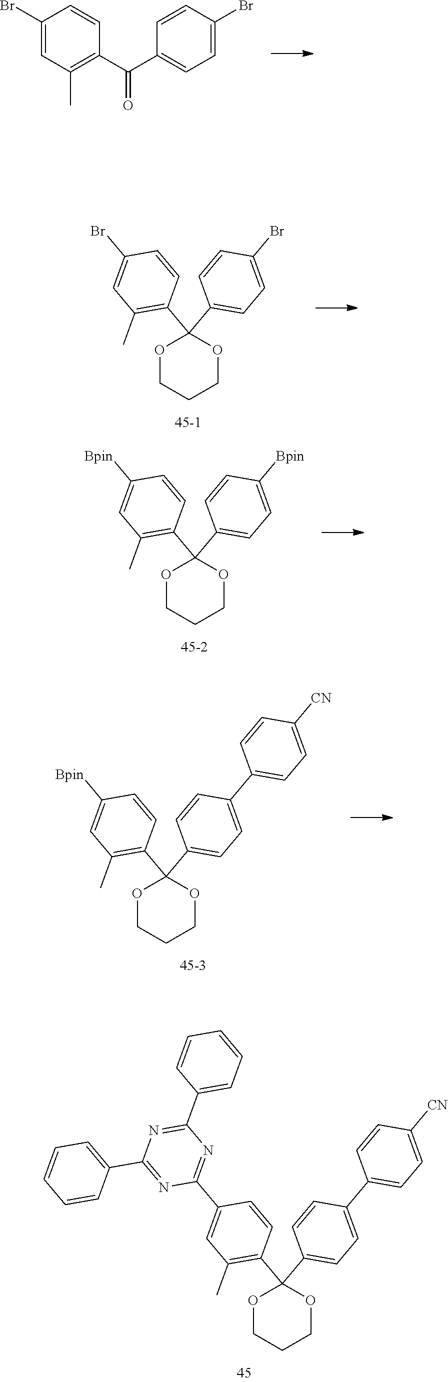

### Synthesis of Intermediate Compound 45-1

Toluene, propane-1,3-diol (1.5 eq.), and 4-methylbenzenesulfonic acid (1.0 eq.) were added to (4-bromo-2-methylphenyl) (4-bromophenyl) methanone (1.0 eq.), and the resultant reaction solution was stirred for 6 hours. Then, the reaction product was washed three times with ethyl acetate and water, and the resulting organic layer was dried over MgSO₄ first and then dried again under reduced pressure. Compound 45-1 was obtained by column chromatography. (Yield: 45%)

### Synthesis of Intermediate Compound 45-2

Compound 45-1 (1.0 eq.), 4,4,4′,4′,5,5,5′,5′-octamethyl-2,2′-bi(1,3,2-dioxaborolane) (2.5 eq.), palladium(II)acetate (0.05 eq.), Sphos (0.06 eq.), and potassium acetate (3.0 eq.) were dissolved in toluene, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 45-2 was obtained by column chromatography. (Yield: 47%)

### Synthesis of Intermediate Compound 45-3

Compound 45-2 (1.0 eq.), 4-bromobenzonitrile (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 45-3 was obtained by column chromatography. (Yield: 40%)

### Synthesis of Compound 45

Compound 45-3 (1.0 eq.), 2-chloro-4,6-diphenyl-1,3,5-triazine (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 45 was obtained by column chromatography. (Yield: 40%) By FAB-MS, mass number m/z=586.24 was observed as a molecular ion peak. Thus, Compound 45 was identified.

### Synthesis Example 8: Synthesis of Compound 227

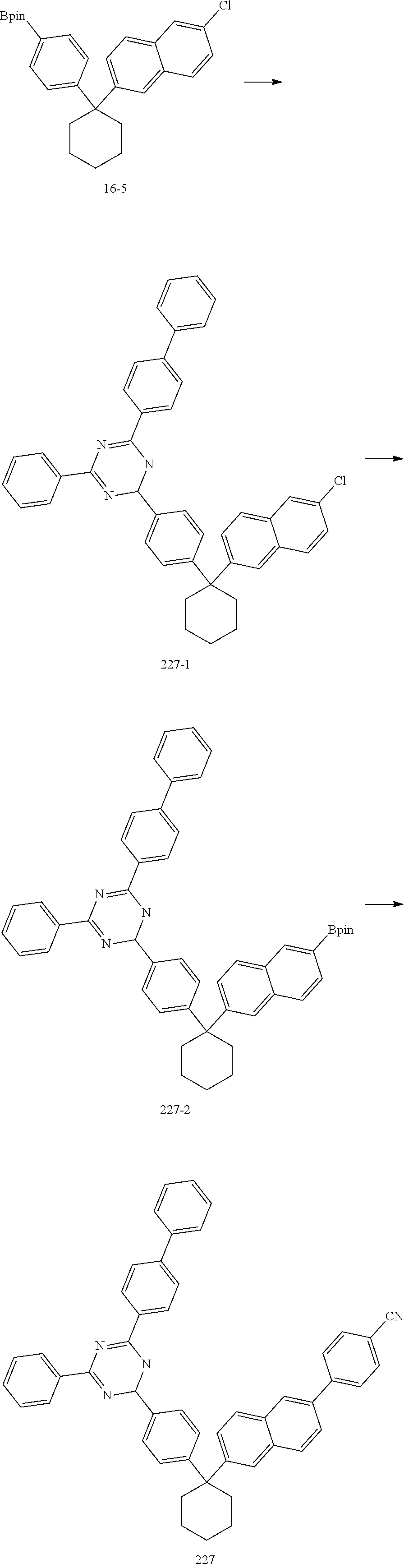

### Synthesis of Intermediate Compound 227-1

Compound 16-5 (1.0 eq.), 2-([1,1′-biphenyl]-4-yl)-4-chloro-6-phenyl-1,3,5-triazine (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 227-1 was obtained by column chromatography. (Yield: 72%)

### Synthesis of Intermediate Compound 227-2

Compound 227-1 (1.0 eq.), 4,4,4′,4′,5,5,5′,5′-octamethyl-2,2′-bi(1,3,2-dioxaborolane) (1.2 eq.), palladium(II)acetate (0.05 eq.), Sphos (0.06 eq.), and potassium acetate (3.0 eq.) were dissolved in xylene, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 227-2 was obtained by column chromatography. (Yield: 55%)

### Synthesis of Compound 227

Compound 227-2 (1.0 eq.), 4-bromobenzonitrile (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 227 was obtained by column chromatography. (Yield: 84%) By FAB-MS, mass number m/z=694.31 was observed as a molecular ion peak. Thus, Compound 227 was identified.

### Synthesis Example 9: Synthesis of Compound 647

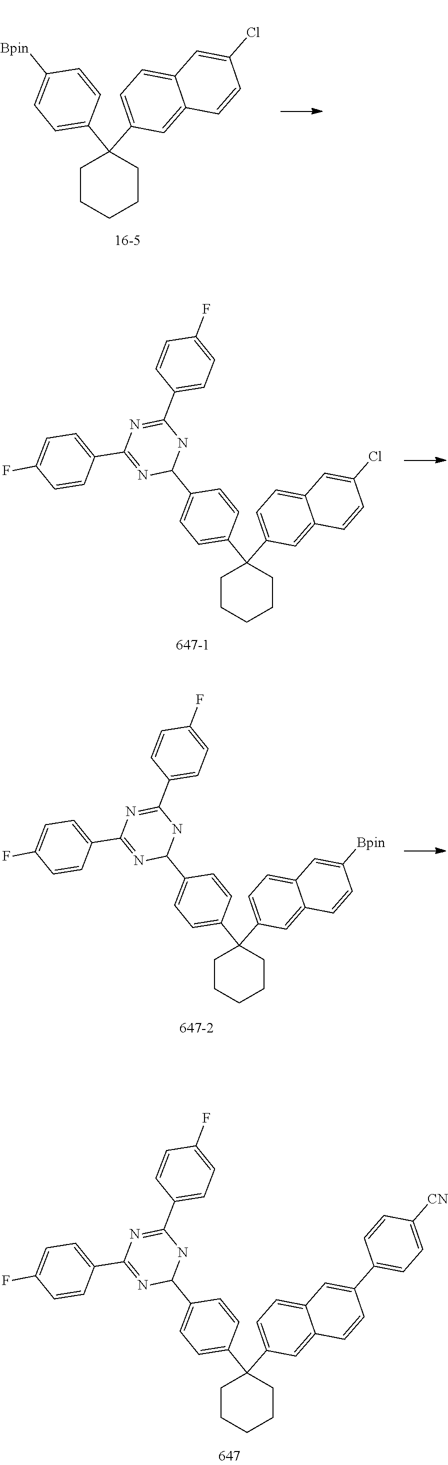

### Synthesis of Intermediate Compound 647-1

Compound 16-5 (1.0 eq.), 2-chloro-4,6-bis(4-fluorophenyl)-1,3,5-triazine (1.1 eq.), bis(triphenylphosphine)palladium(II)dichloride (0.02 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 647-1 was obtained by column chromatography. (Yield: 72%)

### Synthesis of Intermediate Compound 647-2

Compound 647-1 (1.0 eq.), 4,4,4′,4′,5,5,5′,5′-octamethyl-2,2′-bi(1,3,2-dioxaborolane) (1.2 eq.), palladium(II)acetate (0.05 eq.), Sphos (0.06 eq.), and potassium acetate (3.0 eq.) were dissolved in xylene, and the resultant reaction solution was stirred at 100° C. for 12 hours under a nitrogen atmosphere. After cooling, the reaction product was washed three times with ethyl acetate and water, and the resulting organic layer was dried over MgSO₄ first and then dried again under reduced pressure. Compound 647-2 was obtained by column chromatography. (Yield: 55%)

### Synthesis of Compound 647

Compound 647-2 (1.0 eq.), 4-bromobenzonitrile (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 647 was obtained by column chromatography. (Yield: 84%) By FAB-MS, mass number m/z=654.2 was observed as a molecular ion peak. Thus, Compound 647 was identified.

### Synthesis Example 10: Synthesis of Compound 857

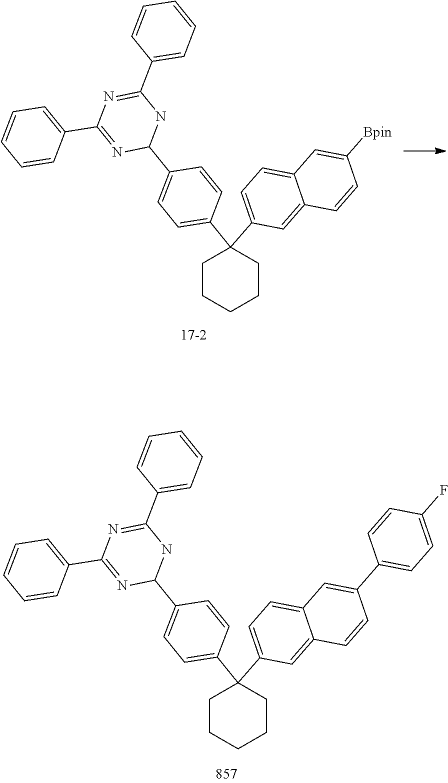

### Synthesis of Compound 857

Compound 17-2 (1.0 eq.), 1-bromo-4-fluorobenzene (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried over MgSO₄ first and then dried again under reduced pressure. Compound 857 was obtained by column chromatography. (Yield: 84%) By FAB-MS, mass number m/z=611.27 was observed as a molecular ion peak. Thus, Compound 857 was identified.

### Synthesis Example 11: Synthesis of Compound 1067

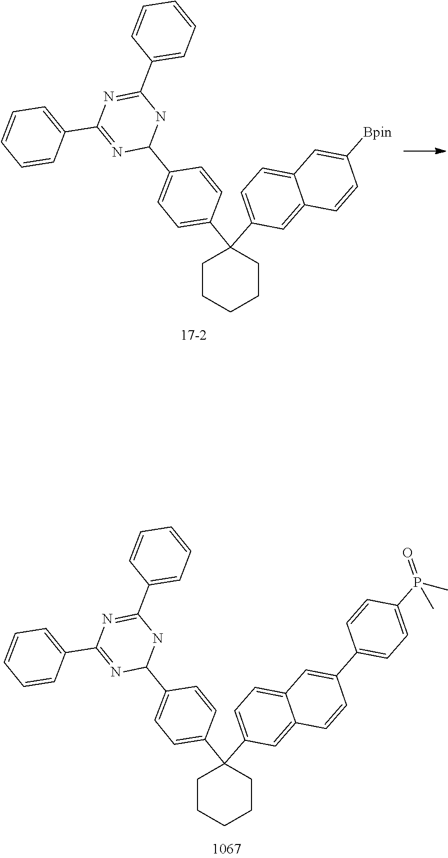

### Synthesis of Compound 1067

Compound 17-2 (1.0 eq.), (4-bromophenyl)dimethylphosphine oxide (1.2 eq.), tetrakis(triphenylphosphine)palladium (0.05 eq.), and potassium carbonate (2.0 eq.) were dissolved in a solution containing toluene, EtOH, and H₂O at a volume ratio of 4:1:1, and the resultant reaction solution was stirred at 100° C. for 5 hours under a nitrogen atmosphere. After cooling, the reaction product was washed three times with ethyl acetate and water, and the resulting organic layer was dried with MgSO₄ first and then dried again under reduced pressure. Compound 1067 was obtained by column chromatography. (Yield: 84%) By FAB-MS, mass number m/z=669.29 was observed as a molecular ion peak. Thus, Compound 1067 was identified.

Synthesis methods of other compounds in addition to the compound synthesized in Synthesis Examples may be easily recognized by those skilled in the art by referring to the synthesis paths and source materials.

### Example 1

As an anode, a glass substrate (product of Corning Inc.) with a 15 Ω/cm² (1,200 Å) ITO electrode formed thereon was cut to a size of 50 mm×50 mm×0.7 mm, sonicated with isopropyl alcohol and (then with) pure water each for 5 minutes, cleaned by irradiation of ultraviolet rays and exposure of ozone thereto for 30 minutes, and then mounted on a vacuum deposition apparatus.

NPD was deposited on the anode to form a hole injection layer having a thickness of 300 Å, HTL3 was deposited on the hole injection layer to form a hole transport layer having a thickness of 200 Å, and CzSi was deposited on the hole transport layer to form an emission auxiliary layer having a thickness of 100 Å.

HT+ET (host), PS (phosphorescent sensitizer), and t-DABNA were co-deposited at a weight ratio of 42:42:15:1 on the emission auxiliary layer to form an emission layer having a thickness of 200 Å, TSPO1 was deposited on the emission layer to form a hole blocking layer having a thickness of 200 Å, Compound 1 was deposited on the hole blocking layer to form an electron transport layer having a thickness of 300 Å, LiF was deposited on the electron transport layer to form an electron injection layer having a thickness of 10 Å, and Al was deposited on the electron injection layer to form a cathode having a thickness of 3,000 Å, thereby completing the manufacture of a light-emitting device.

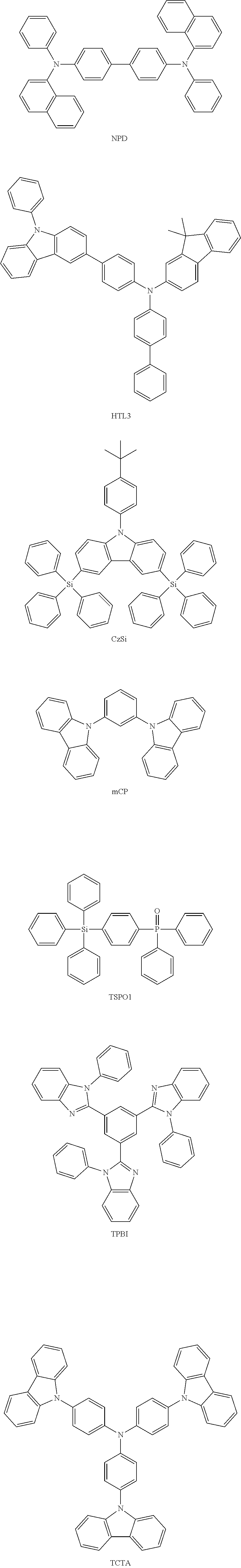

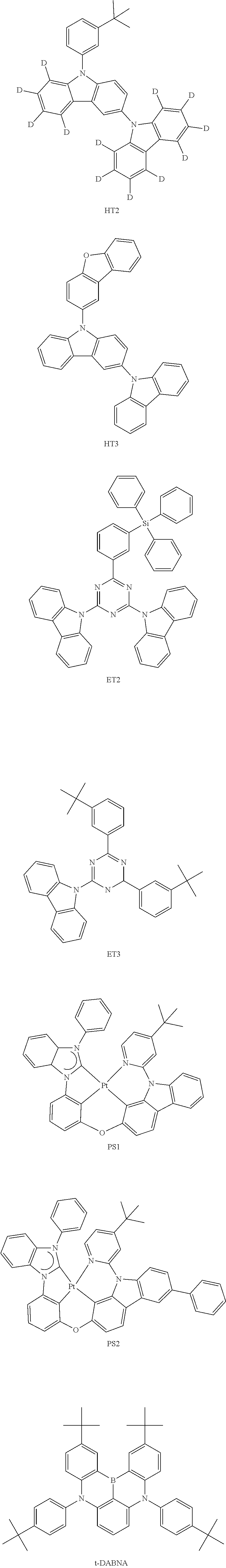

### Examples 2 to 11 and Comparative Examples 1 to 13

Light-emitting devices were each manufactured in substantially the same manner as in Example 1, except that the compounds used in forming the emission layer and the electron transport layer were changed as shown in Table 1.

### Evaluation Example 1

The driving voltage (V) at the luminance of 1,000 cd/m², efficiency (cd/A), and lifespan ratio (T₉₅) of each of the light-emitting devices manufactured in Examples to 11 and Comparative Examples 1 to 13 were measured by using Keithley SMU 236 and luminance meter PR650, and the results are shown in Table 1. The lifespan ratio (T₉₅) in Table 1 was obtained by measuring the time (device lifespan, hr) taken for the luminance to reach 95% of the initial luminance in each of Examples and Comparative Examples, and then expressing the measured value as a relative ratio with respect to the device lifespan of Comparative Example 1, which was set to 1.

TABLE 1

| | | Phosphorescent | | | | | |
|---|---|---|---|---|---|---|---|
| | Exciplex | sensitizer | Boron | ETL | | | |
| | host | (E is a | dopant | (electron | Driving | | Lifespan |
| | (HT:ET = | fluorescent | (t- | transport | voltage | Efficiency | ratio |
| | 5:5) | dopant) | DABNA1) | layer) | (V) | (cd/A) | (T₉₅) |
| Example 1 | HT3/ET2 | PS2 | t-DABNA | Compound | 4.5 | 29.5 | 4.5 |
| | | | | 1 | | | |
| Example 2 | HT3/ET2 | PS2 | t-DABNA | Compound | 4.4 | 26.8 | 4.8 |
| | | | | 3 | | | |
| Example 3 | HT3/ET2 | PS2 | t-DABNA | Compound | 4.2 | 28.1 | 4.7 |
| | | | | 16 | | | |
| Example 4 | HT3/ET2 | PS2 | t-DABNA | Compound | 4.1 | 30.2 | 5.7 |
| | | | | 17 | | | |
| Example 5 | HT3/ET2 | PS2 | t-DABNA | Compound | 4.2 | 27.2 | 5.1 |
| | | | | 21 | | | |
| Example 6 | HT3/ET2 | PS2 | t-DABNA | Compound | 4.1 | 26.8 | 4.8 |
| | | | | 22 | | | |
| Example 7 | HT3/ET2 | PS2 | t-DABNA | Compound | 4.4 | 27.8 | 5.5 |
| | | | | 45 | | | |
| Example 8 | HT2/ET3 | PS1 | t-DABNA | Compound | 4.1 | 28.2 | 5.7 |
| | | | | 227 | | | |
| Example 9 | HT2/ET3 | PS1 | t-DABNA | Compound | 4.3 | 26.6 | 4.3 |
| | | | | 647 | | | |
| Example 10 | HT2/ET3 | PS1 | t-DABNA | Compound | 4.2 | 26.3 | 4.5 |
| | | | | 857 | | | |
| Example 11 | HT2/ET3 | PS1 | t-DABNA | Compound | 4.4 | 29.3 | 5.7 |
| | | | | 1067 | | | |
| Comparative | HT3/ET2 | PS2 | t-DABNA | TPBI | 5.6 | 18.8 | 1 |
| Example 1 | | | | | | | |
| Comparative | HT3/ET2 | PS2 | t-DABNA | A | 4.9 | 22.3 | 3.1 |
| Example 2 | | | | | | | |
| Comparative | HT3/ET2 | PS2 | t-DABNA | B | 5.2 | 21.1 | 3.4 |
| Example 3 | | | | | | | |
| Comparative | HT3/ET2 | PS2 | t-DABNA | C | 5.7 | 20.3 | 2.3 |
| Example 4 | | | | | | | |
| Comparative | HT3/ET2 | PS2 | t-DABNA | F | 4.9 | 22.2 | 3.2 |
| Example 5 | | | | | | | |
| Comparative | HT3/ET2 | PS2 | t-DABNA | G | 5.7 | 26.2 | 3.3 |
| Example 6 | | | | | | | |
| Comparative | HT3/ET2 | PS2 | t-DABNA | H | 5.7 | 26.2 | 3.3 |
| Example 7 | | | | | | | |
| Comparative | HT3/ET2 | PS2 | t-DABNA | I | 5.8 | 26.8 | 3.3 |
| Example 8 | | | | | | | |
| Comparative | HT3/ET2 | PS2 | t-DABNA | J | 5.2 | 24.8 | 3.2 |
| Example 9 | | | | | | | |
| Comparative | HT3/ET2 | PS2 | t-DABNA | K | 5.8 | 26.8 | 3.2 |
| Example 10 | | | | | | | |
| Comparative | HT3/ET2 | PS2 | t-DABNA | L | 5.3 | 26.1 | 3.2 |
| Example 11 | | | | | | | |
| Comparative | HT3/ET2 | PS2 | t-DABNA | M | 4.9 | 23.2 | 3.1 |
| Example 12 | | | | | | | |
| Comparative | D | E | — | B | 5.0 | 13.7 | 3.9 |
| Example 13 | | | | | | | |

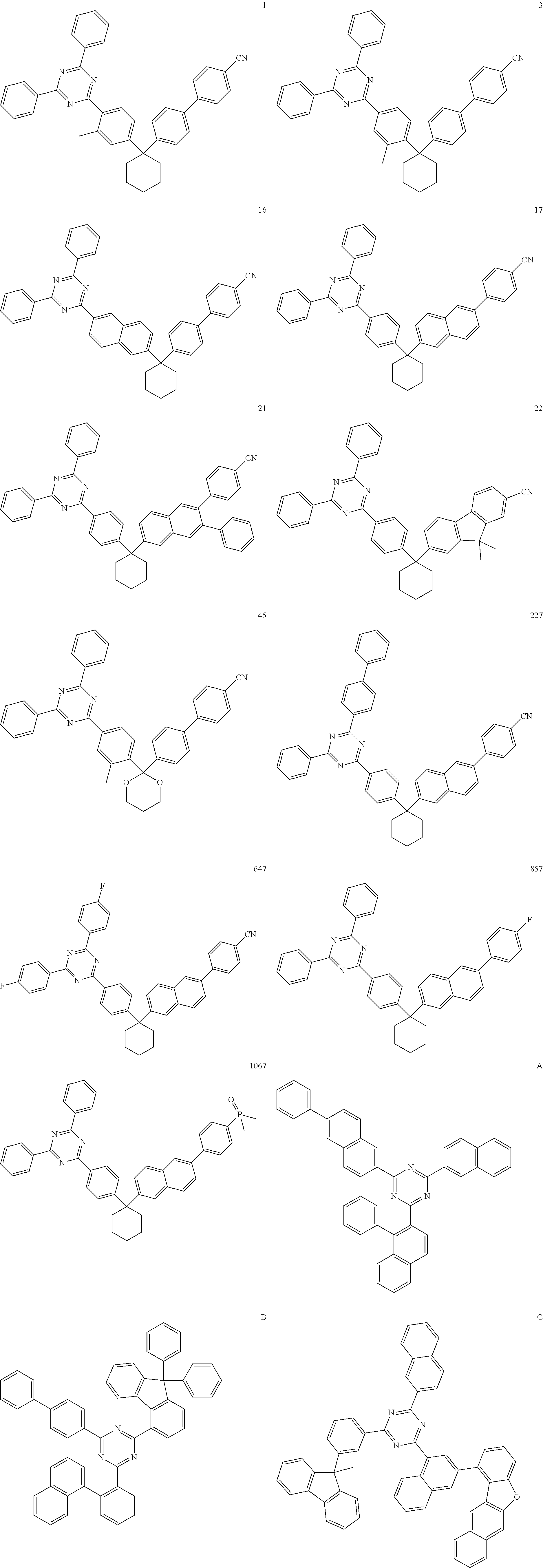

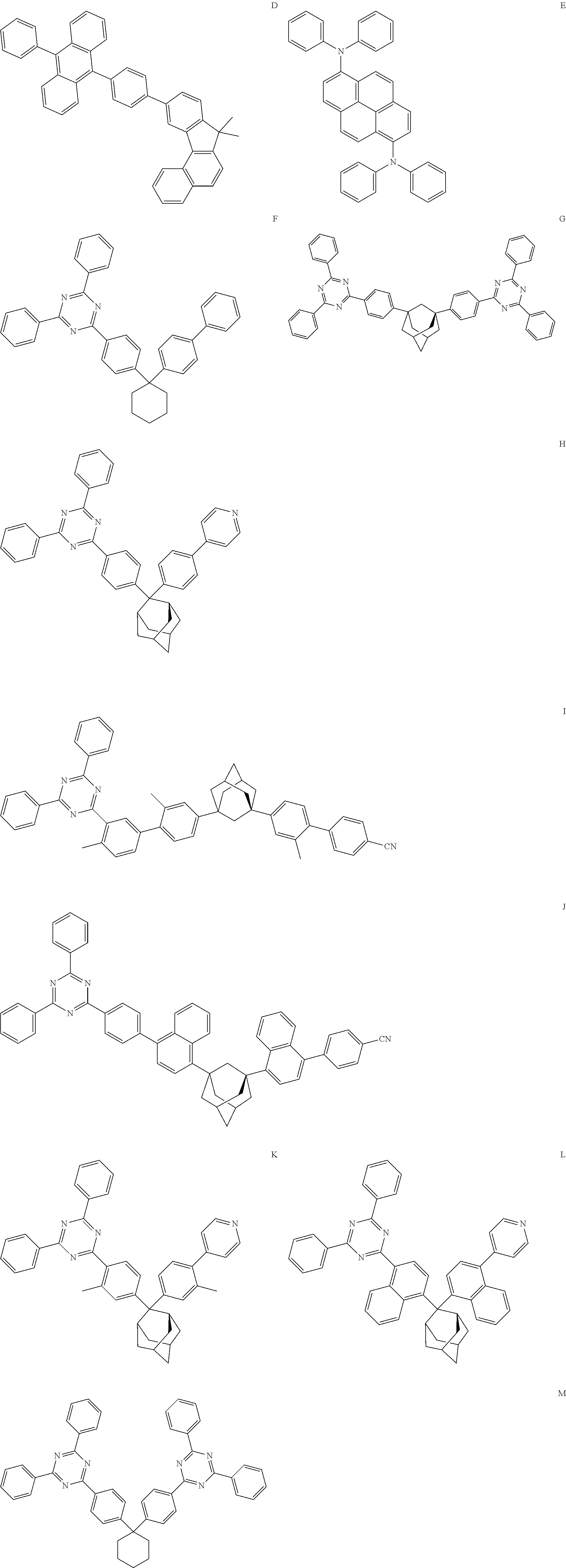

From Table 1, it was confirmed that each of the light-emitting devices according to Examples 1 to 11 had superior driving voltage, efficiency, and device lifespan compared to those of the light-emitting devices according to Comparative Examples 1 to 13.

According to the one or more embodiments, a light-emitting device including a heterocyclic compound of the present disclosure may have low driving voltage, high efficiency, and long lifespan. In addition, a high-quality electronic apparatus and consumer product may be manufactured by using the light-emitting device.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light-emitting device, the light-emitting apparatus, the display device, the electronic apparatus, the electronic device, the manufacturing apparatus thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the appended claims and equivalents thereof.

What is claimed is:

1. A light-emitting device comprising:
a first electrode;
a second electrode opposite to the first electrode;
an interlayer between the first electrode and the second electrode and comprising an emission layer; and
a heterocyclic compound represented by Formula 1: 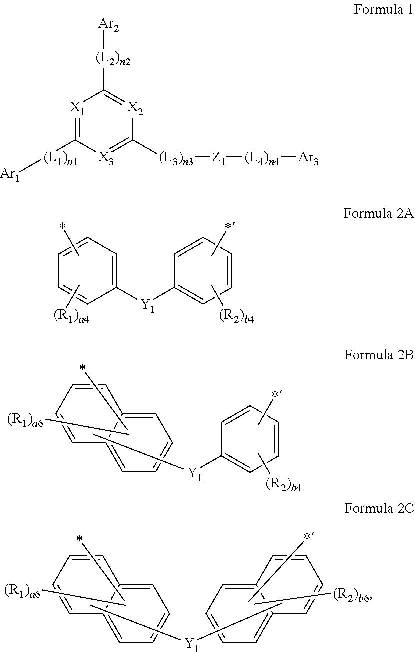
wherein, in Formulae 1, 2A, 2B, and 2C,
X₁ is C(R₁₁) or N, X₂ is C(R₁₂) or N, and X₃ is C(R₁₃) or N,
Z₁ is a group represented by any one selected from among Formulae 2A, 2B, and 2C,
Y₁ is a C₁-C₃₀ alkylene group unsubstituted or substituted with at least one R₁₀ₐ, a C₃-C₃₀ cycloalkylene group unsubstituted or substituted with at least one R₁₀ₐ, or a C₁-C₃₀ heterocycloalkylene group unsubstituted or substituted with at least one R₁₀ₐ, wherein Y₁ does not comprise an unsubstituted or substituted adamantane group,
Ar₁ to Ar₃ are each independently deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
L₁ to L₄ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
n1 to n4 are each independently an integer from 0 to 4, wherein, when n1 is 0, then *-(L₁)ₙ₁-*′ is a single bond, when n2 is 0, then *-(L₂)ₙ₂-*′ is a single bond, when n3 is 0, then *-(L₃)ₙ₃-*′ is a single bond, and when n4 is 0, then *-(L₄)ₙ₄-*′ is a single bond,
R₁ and R₂ are each independently deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a4 and b4 are each independently an integer from 0 to 4, and a6 and b6 are each independently an integer from 0 to 6,
when Z₁ is a group represented by Formula 2A, then the sum of a4 and b4 is 1 or more,
when a4 is 2 or more or when a6 is 2 or more, then two or more of R₁(s) are optionally bonded to each other to form a C₃-C₃₀ carbocyclic group unsubstituted or substituted with at least one R₁₀ₐ or a C₁-C₃₀ heterocyclic group unsubstituted or substituted with at least one R₁₀ₐ,
when b4 is 2 or more or when b6 is 2 or more, then two or more of R₂(s) are optionally bonded to each other to form a C₃-C₃₀ carbocyclic group unsubstituted or substituted with at least one R₁₀ₐ or a C₁-C₃₀ heterocyclic group unsubstituted or substituted with at least one R₁₀ₐ,
R₁ and R₂ are each independently optionally bonded to L₃ or L₄ or Ar₃ to form a C₃-C₃₀ carbocyclic group unsubstituted or substituted with at least one R₁₀ₐ or a C₁-C₃₀ heterocyclic group unsubstituted or substituted with at least one R₁₀ₐ,
R₁₁ to R₁₃ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ is:
hydrogen, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₅-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
* and *′ each indicate a binding site to a neighboring atom.

2. The light-emitting device of claim 1, wherein the first electrode is an anode,
the second electrode is a cathode,
the interlayer further comprises a hole transport region between the first electrode and the emission layer and an electron transport region between the emission layer and the second electrode,
the hole transport region comprises a hole injection layer, a hole transport layer, an emission auxiliary layer, an electron blocking layer, or any combination thereof, and
the electron transport region comprises a hole blocking layer, an electron transport layer, an electron injection layer, or any combination thereof.

3. The light-emitting device of claim 2, wherein the electron transport region comprises the heterocyclic compound.

4. The light-emitting device of claim 2, further comprising a first capping layer and/or a second capping layer,
wherein the first capping layer is on a surface of the first electrode,
the second capping layer is on a surface of the second electrode, and
at least one of the first capping layer or the second capping layer comprises the heterocyclic compound represented by Formula 1.

5. The light-emitting device of claim 1, wherein the emission layer is to emit blue light.

6. An electronic apparatus comprising the light-emitting device of claim 1.

7. The electronic apparatus of claim 6, further comprising a thin-film transistor,
wherein the thin-film transistor comprises a source electrode and a drain electrode, and
the first electrode of the light-emitting device is electrically connected to the source electrode or the drain electrode of the thin-film transistor.

8. The electronic apparatus of claim 6, further comprising a color filter, a color conversion layer, a touch screen layer, a polarizing layer, or any combination thereof.

9. An electronic equipment comprising the light-emitting device of claim 1.

10. The electronic equipment of claim 9, wherein the electronic equipment is at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

11. A heterocyclic compound represented by Formula 1: 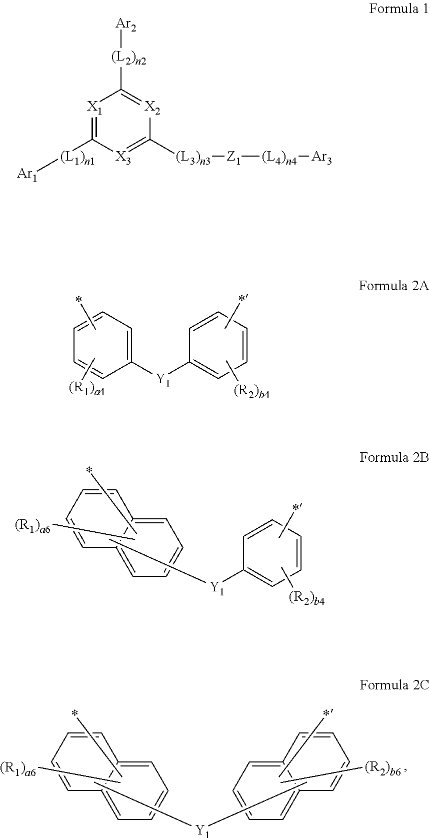
wherein, in Formulae 1, 2A, 2B, and 2C,
X₁ is C(R₁₁) or N, X₂ is C(R₁₂) or N, and X₃ is C(R₁₃) or N,
Z₁ is a group represented by any one selected from among Formulae 2A, 2B, and 2C,
Y₁ is a C₁-C₃₀ alkylene group unsubstituted or substituted with at least one R₁₀ₐ, a C₃-C₃₀ cycloalkylene group unsubstituted or substituted with at least one R₁₀ₐ, or a C₁-C₃₀ heterocycloalkylene group unsubstituted or substituted with at least one R₁₀ₐ, wherein Y₁ does not comprise an unsubstituted or substituted adamantane group,
Ar₁ to Ar₃ are each independently deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
L₁ to L₄ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
n1 to n4 are each independently an integer from 0 to 4, wherein, when n1 is 0, then *-(L₁)ₙ₁-*′ is a single bond, when n2 is 0, then *-(L₂)ₙ₂-*′ is a single bond, when n3 is 0, then *-(L₃)ₙ₃-*′ is a single bond, and when n4 is 0, then *-(L₄)ₙ₄-*′ is a single bond,
R₁ and R₂ are each independently deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a4 and b4 are each independently an integer from 0 to 4, and a6 and b6 are each independently an integer from 0 to 6,
when Z₁ is a group represented by Formula 2A, then the sum of a4 and b4 is 1 or more,
when a4 is 2 or more or when a6 is 2 or more, then two or more of R₁(s) are optionally bonded to each other to form a C₃-C₃₀ carbocyclic group unsubstituted or substituted with at least one R₁₀ₐ or a C₁-C₃₀ heterocyclic group unsubstituted or substituted with at least one R₁₀ₐ,
when b4 is 2 or more or when b6 is 2 or more, then two or more of R₂(s) are optionally bonded to each other to form a C₃-C₃₀ carbocyclic group unsubstituted or substituted with at least one R₁₀ₐ or a C₁-C₃₀ heterocyclic group unsubstituted or substituted with at least one R₁₀ₐ,
R₁ and R₂ are each independently optionally bonded to L₃ or L₄ or Ar₃ to form a C₃-C₃₀ carbocyclic group unsubstituted or substituted with at least one R₁₀ₐ or a C₁-C₃₀ heterocyclic group unsubstituted or substituted with at least one R₁₀ₐ,
R₁₁ to R₁₃ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ is:
hydrogen, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —C₁, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
* and *′ each indicate a binding site to a neighboring atom.

12. The heterocyclic compound of claim 11, wherein at least two selected from among X₁ to X₃ are each N.

13. The heterocyclic compound of claim 11, wherein Y₁ is a C₁-C₁₀ alkylene group unsubstituted or substituted with at least one R₁₀ₐ, a C₃-C₉ cycloalkylene group unsubstituted or substituted with at least one R₁₀ₐ, or a C₁-C₉ heterocycloalkylene group unsubstituted or substituted with at least one R₁₀ₐ.

14. The heterocyclic compound of claim 11, wherein Y₁ is a C₁-C₁₀ alkylene group unsubstituted or substituted with at least one R₁₀ₐ or is a group represented by any one selected from among Formulae 3-1 to 3-15: 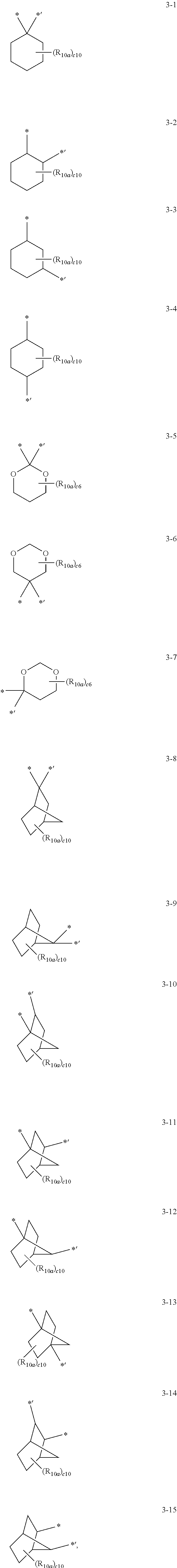
in Formulae 3-1 to 3-15,
R₁₀ₐ being the same as defined in Formula 1,
c6 being an integer from 0 to 6,
c10 being an integer from 0 to 10, and
* and *′ each indicating a binding site to a neighboring atom.

15. The heterocyclic compound of claim 11, wherein Ar₁ to Ar₃ are each independently:
a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —P(═O)(Q₃₁)(Q₃₂), or any combination thereof; or
—C(Q₁)(Q₂)(Q₃), —Si(Q₁)(Q₂)(Q₃), —N(Q₁)(Q₂), or —P(═O)(Q₁)(Q₂), and
Q₁ to Q₃ and Q₃₁ to Q₃₃ are each independently: hydrogen; deuterium; —F; —Cl; —Br; —I; a C₁-C₆₀ alkyl group; a C₂-C₆₀ alkenyl group; a C₂-C₆₀ alkynyl group; a C₁-C₆₀ alkoxy group; a C₁-C₆₀ alkylthio group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

16. The heterocyclic compound of claim 11, wherein Ar₁ to Ar₃ are each independently a group represented by any one selected from among Formulae 4-1 to 4-6: 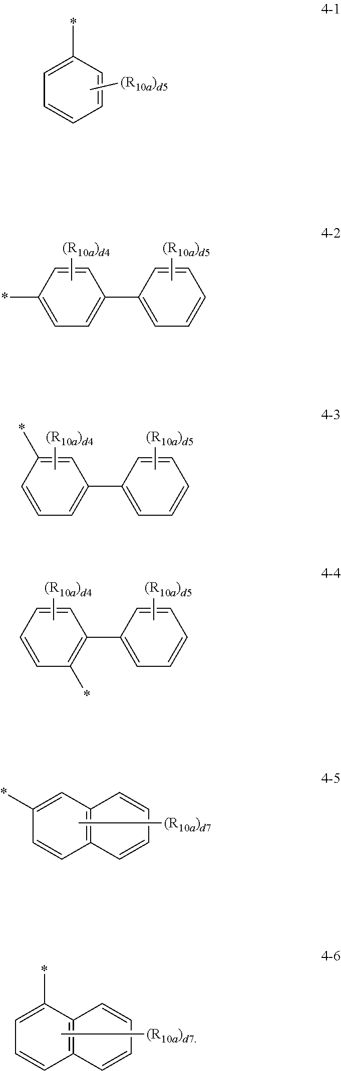
in Formulae 4-1 to 4-6,
R₁₀ₐ being the same as defined in Formula 1,
d4 being an integer from 0 to 4,
d5 being an integer from 0 to 5,
d7 being an integer from 0 to 7, and
* indicating a binding site to a neighboring atom.

17. The heterocyclic compound of claim 11, wherein at least one selected from among Ar₁ to Ar₃ is substituted with —F, a cyano group, —P(═O)(Q₁)(Q₂), or any combination thereof.

18. The heterocyclic compound of claim 11, wherein L₁ to L₄ are each independently a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phthalazine group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzooxasiline group, a dibenzothiasiline group, a dibenzodihydroazasiline group, a dibenzodihydrodisiline group, a dibenzodihydrosiline group, a dibenzodioxin group, a dibenzooxathiin group, a dibenzooxazine group, a dibenzopyran group, a dibenzodithiin group, a dibenzothiazine group, a dibenzothiopyran group, a dibenzocyclohexadiene group, a dibenzodihydropyridine group, or a dibenzodihydropyrazine group, each unsubstituted or substituted with at least one R₁₀ₐ.

19. The heterocyclic compound of claim 11, wherein R₁ and R₂ are each independently:
deuterium, —F, —Cl, —Br, —I, a cyano group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, a C₁-C₂₀ alkylthio group, a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —P(═O)(Q₃₁)(Q₃₂), or any combination thereof; or
—C(Q₁)(Q₂)(Q₃), —Si(Q₁)(Q₂)(Q₃), —N(Q₁)(Q₂), or —P(═O)(Q₁)(Q₂), and
Q₁ to Q₃ and Q₃₁ to Q₃₃ are each independently: hydrogen; deuterium; —F; —Cl; —Br; —I; a cyano group; a C₁-C₆₀ alkyl group; a C₂-C₆₀ alkenyl group; a C₂-C₆₀ alkynyl group; a C₁-C₆₀ alkoxy group; a C₁-C₆₀ alkylthio group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

20. The heterocyclic compound of claim 11, wherein a group represented by *-(L₃)ₙ₃-Z₁-(L₄)ₙ₄-* in Formula 1 is a group represented by any one selected from among Formulae 5-1 to 5-10: 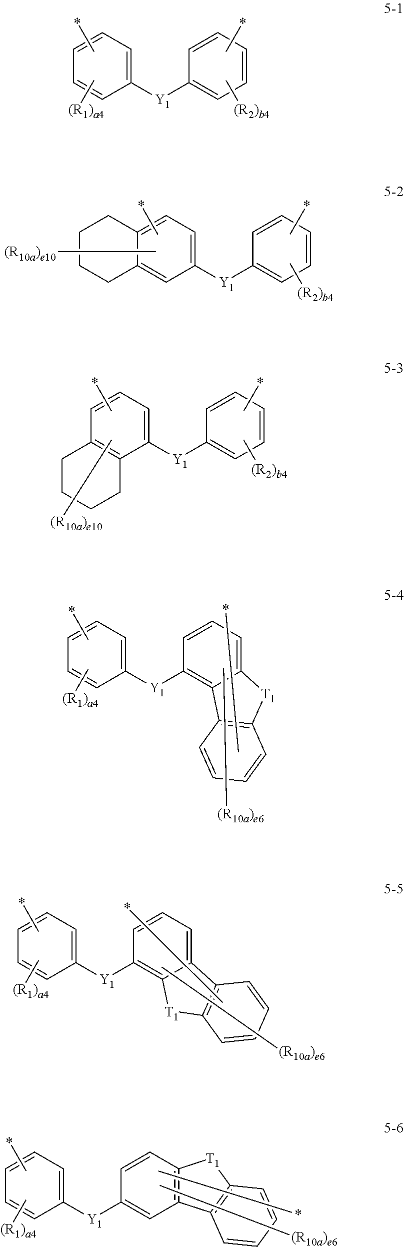 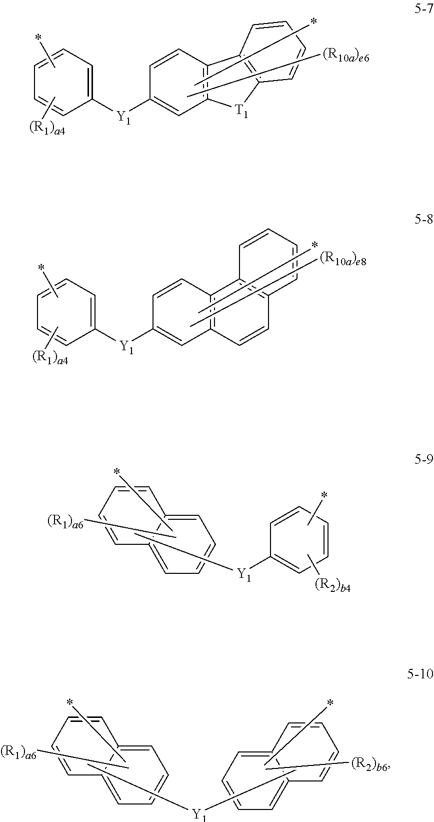
in Formulae 5-1 to 5-10,
T₁ being O, S, N(R_{10b}), or C(R_{10b})(R_{10c}),
e6 being an integer from 0 to 6,
e8 being an integer from 0 to 8,
e10 being an integer from 0 to 10,
R_{10b} and R_{10c} being each independently the same as defined with respect to R₁₀ₐ in Formula 1,
Y₁, R₁, R₂, a4, b4, a6, b6, and R₁₀ₐ being each the same as defined in Formula 1, and
* indicating a binding site to a neighboring atom.
